(19) United States
(12) Patent Application Publication
(10) Pub. No.: US 2026/0040569 A1
(43) Pub. Date: Feb. 5, 2026

(54) THREE-DIMENSIONAL MEMORY DEVICE WITH TUBULAR CHANNELS AND INTEGRATED ACCESS TRANSISTORS AND METHOD OF MAKING THE SAME

(71) Applicant: SANDISK TECHNOLOGIES LLC, ADDISON, TX (US)

(72) Inventors: Adarsh RAJASHEKHAR, Santa Clara, CA (US); Senaka KANAKAMEDALA, San Jose, CA (US); Joyeeta NAG, San Jose, CA (US); Johann ALSMEIER, San Jose, CA (US)

(21) Appl. No.: 18/794,873

(22) Filed: Aug. 5, 2024

(51) Int. Cl. H10B 51/20; H01L 29/66; H01L 29/78; H10B 51/10

(52) U.S. Cl. CPC H10B 51/20; H10B 51/10; H10D 30/0415; H10D 30/701

(57) ABSTRACT

A device structure includes a three-dimensional array of unit cells. Each of the unit cells includes an access field effect transistor including a horizontally-extending semiconductor channel, a first gate dielectric, and a first gate electrode, and a memory field effect transistor including a tubular-portion-containing channel, a second gate dielectric, and a second gate electrode. The second gate dielectric includes a memory dielectric material having at least two programmable states.

### FIELD

The present disclosure relates generally to the field of semiconductor devices, and particularly to three-dimensional memory devices with laterally integrated access transistors and methods of manufacturing the same.

### BACKGROUND

NAND memory devices provide high memory cell density at a low per-bit cost. As the number of layers in NAND memory devices increases, the length of vertical channels increases and the memory latency of the NAND memory devices increases.

### SUMMARY

According to an aspect of the present disclosure, a device structure includes a three-dimensional array of unit cells. Each of the unit cells comprises: an access field effect transistor comprising a horizontally-extending semiconductor channel, a first gate dielectric, and a first gate electrode; and a memory field effect transistor comprising a tubular-portion-containing channel, a second gate dielectric, and a second gate electrode, wherein the second gate dielectric comprises a memory dielectric material having at least two programmable states.

According to another aspect of the present disclosure, a method of forming a device structure comprises: forming a three-dimensional array of horizontally-extending semiconductor rails supported by a three-dimensional array of horizontally-extending sacrificial rails; removing first portions of horizontally-extending sacrificial rails to expose sidewalls and horizontal surfaces of first portions of the horizontally-extending semiconductor rails; depositing a first gate dielectric material and a first gate electrode material around the first portions of the horizontally-extending semiconductor channels; removing second portions of horizontally-extending sacrificial rails to expose sidewalls and horizontal surfaces of second portions of the horizontally-extending semiconductor rails; forming tubular-portion-containing channels on the second portions of the horizontally-extending semiconductor rails; depositing a second gate dielectric material and a second gate electrode material around the tubular-portion-containing channels; and patterning the first gate electrode material, the second gate electrode material, the first gate dielectric material, and the second gate dielectric material, wherein patterned portions of the first gate electrode material comprise first word lines, patterned portions of the second gate electrode material comprise second word lines, patterned portions of the first gate dielectric material comprise first gate dielectrics, and patterned portions of the second gate dielectric material comprise second gate dielectrics.

According to yet another aspect of the present disclosure, a method of forming a device structure comprises: forming a three-dimensional array of horizontally-extending semiconductor rails supported by a three-dimensional array of horizontally-extending sacrificial rails; removing first portions of horizontally-extending sacrificial rails to expose sidewalls and horizontal surfaces of first portions of the horizontally-extending semiconductor rails; depositing a first gate dielectric material and a first gate electrode material around the first portions of the horizontally-extending semiconductor channels; removing second portions of horizontally-extending sacrificial rails to expose sidewalls and horizontal surfaces of second portions of the horizontally-extending semiconductor rails; depositing a second gate dielectric material and a second gate electrode material around the second portions of the horizontally-extending semiconductor channels; forming elongated cavities by removing the second portions of the horizontally-extending semiconductor rails; forming tubular-portion-containing channels in the elongated cavities on surfaces of the second gate dielectric material; and patterning the first gate electrode material, the second gate electrode material, the first gate dielectric material, and the second gate dielectric material, wherein patterned portions of the first gate electrode material comprise first word lines, patterned portions of the second gate electrode material comprise second word lines, patterned portions of the first gate dielectric material comprise first gate dielectrics, and patterned portions of the second gate dielectric material comprise second gate dielectrics.

### BRIEF DESCRIPTION OF THE DRAWINGS

For all figures between FIG. 1A and FIG. 27G or between FIGS. 30A and 48G which are labeled with a combination of a figure numeral and a letter figure suffix, each figure with a figure label including a letter figure suffix of “A” is a first vertical cross-sectional view; each figure with a figure label including a letter figure suffix of “B” is a second vertical cross-sectional view; each figure with a figure label including a letter figure suffix of “C” is a first horizontal cross-sectional view along the horizontal plane C-C′ within the figures with the same figure numeral and the letter figure suffix of “A” or “B”; each figure with a figure label including a letter figure suffix of “D” is a second horizontal cross-sectional view along the horizontal plane D-D′ within the figure with the same figure numeral and the letter figure suffix of “A” or “B”; each figure with a figure label including a letter figure suffix of “E” is a vertical cross-sectional view along the vertical plane E-E′ within the figures with the same figure numeral and the letter figure suffix of “C” or “D”; each figure with a figure label including a letter figure suffix of “F” is a vertical cross-sectional view along the vertical plane F-F′ within the figures with the same figure numeral and the letter figure suffix of “C” or “D”; and each figure with a figure label including a letter figure suffix of “G” is a vertical cross-sectional view along the vertical plane G-G′ within the figures with the same figure numeral and the letter figure suffix of “C” or “D”. The vertical plane A-A′ shown in figures with a respective letter figure suffix of “C,” “D,” “E,” “F,” or “G” corresponds to the cut plane for the first vertical cross-sectional view of the figure with the same figure numeral and the letter figure suffix of “A.” The vertical plane B-B′ shown in figures with a respective letter figure suffix of “C,” “D,” “E,” “F,” or “G” corresponds to the cut plane for the first vertical cross-sectional view of the figure with the same figure numeral and the letter figure suffix of “B.”

FIGS. 1A, 1B, 1C, 1D, 1E, 1F, and 1G are various views of a first exemplary structure after formation of an etch-stop structure and a vertically alternating sequence of sacrificial layers and semiconductor layers according to a first embodiment of the present disclosure.

FIGS. 2A, 2B, 2C, 2D, 2E, 2F, and 2G are various views of the first exemplary structure after formation of lateral isolation trenches including periodically laterally bulging portions according to the first embodiment of the present disclosure.

FIGS. 3A, 3B, 3C, 3D, 3E, 3F, and 3G are various views of the first exemplary structure after formation of sacrificial isolation trench fill structures according to the first embodiment of the present disclosure.

FIGS. 4A, 4B, 4C, 4D, 4E, 4F, and 4G are various views of the first exemplary structure after isotropic recessing of the sacrificial isolation trench fill structures and formation of a two-dimensional array of pillar cavities according to the first embodiment of the present disclosure.

FIGS. 5A, 5B, 5C, 5D, 5E, 5F, and 5G are various views of the first exemplary structure after formation of a one-dimensional array of bridges-encircling cavities according to the first embodiment of the present disclosure.

FIGS. 6A, 6B, 6C, 6D, 6E, 6F, and 6G are various views of the first exemplary structure after formation of a three-dimensional array of doped semiconductor material portions according to the first embodiment of the present disclosure.

FIGS. 7A, 7B, 7C, 7D, 7E, 7F, and 7G are various views of the first exemplary structure after formation of a one-dimensional array of sacrificial perforated wall structures according to the first embodiment of the present disclosure.

FIGS. 8A, 8B, 8C, 8D, 8E, 8F, and 8G are various views of the first exemplary structure after formation of bit-line trenches and source trenches according to the first embodiment of the present disclosure.

FIGS. 9A, 9B, 9C, 9D, 9E, 9F, and 9G are various views of the first exemplary structure after formation of sacrificial bit-line trench fill structures and sacrificial source trench fill structures according to the first embodiment of the present disclosure.

FIGS. 10A, 10B, 10C, 10D, 10E, 10F, and 10G are various views of the first exemplary structure after removal of first portions of the sacrificial isolation trench fill structures and sacrificial bit-line trench fill structures according to the first embodiment of the present disclosure.

FIGS. 11A, 11B, 11C, 11D, 11E, 11F, and 11G are various views of the first exemplary structure after formation of first inter-rail cavities according to the first embodiment of the present disclosure.

FIGS. 12A, 12B, 12C, 12D, 12E, 12F, and 12G are various views of the first exemplary structure after formation of a first gate dielectric material layer and a continuous first gate electrode material layer according to the first embodiment of the present disclosure.

FIGS. 13A, 13B, 13C, 13D, 13E, 13F, and 13G are various views of the first exemplary structure after formation of a two-dimensional array of first dielectric plates according to the first embodiment of the present disclosure.

FIGS. 14A, 14B, 14C, 14D, 14E, 14F, and 14G are various views of the first exemplary structure after patterning the continuous first gate electrode material layer into first gate electrode material layers according to the first embodiment of the present disclosure.

FIGS. 15A, 15B, 15C, 15D, 15E, 15F, and 15G are various views of the first exemplary structure after formation of bit-line trench isolation structures according to the first embodiment of the present disclosure.

FIGS. 16A, 16B, 16C, 16D, 16E, 16F, and 16G are various views of the first exemplary structure after removal of second portions of the sacrificial isolation trench fill structures and sacrificial source trench fill structures according to the first embodiment of the present disclosure.

FIGS. 17A, 17B, 17C, 17D, 17E, 17F, and 17G are various views of the first exemplary structure after formation of second inter-rail cavities according to the first embodiment of the present disclosure.

FIGS. 18A, 18B, 18C, 18D, 18E, 18F, and 18G are various views of the first exemplary structure after formation of a channel material layer according to the first embodiment of the present disclosure.

FIGS. 19A, 19B, 19C, 19D, 19E, 19F, and 19G are various views of the first exemplary structure after formation of a second gate dielectric material layer and a continuous second gate electrode material layer according to the first embodiment of the present disclosure.

FIGS. 20A, 20B, 20C, 20D, 20E, 20F, and 20G are various views of the first exemplary structure after formation of a two-dimensional array of second dielectric plates according to the first embodiment of the present disclosure.

FIGS. 21A, 21B, 21C, 21D, 21E, 21F, and 21G are various views of the first exemplary structure after patterning the continuous second gate electrode material layer into second gate electrode material layers and after patterning the second gate dielectric material layer according to the first embodiment of the present disclosure.

FIGS. 22A, 22B, 22C, 22D, 22E, 22F, and 22G are various views of the first exemplary structure after formation of source trench isolation structures according to the first embodiment of the present disclosure.

FIGS. 23A, 23B, 23C, 23D, 23E, 23F, and 23G are various views of the first exemplary structure after formation of bit-line via cavities and source-line via cavities according to the first embodiment of the present disclosure.

FIGS. 24A, 24B, 24C, 24D, 24E, 24F, and 24G are various views of the first exemplary structure after formation of drain regions, source regions, vertical bit lines, and vertical source lines according to the first embodiment of the present disclosure.

FIGS. 25A, 25B, 25C, 25D, 25E, 25F, and 25G are various views of the first exemplary structure after formation of a one dimensional array of bridges-encircling cavities through removal of the one-dimensional array of sacrificial perforated wall structures according to the first embodiment of the present disclosure.

FIGS. 26A, 26B, 26C, 26D, 26E, 26F, and 26G are various views of the first exemplary structure after recessing the first gate dielectric material layers, the first gate electrode material layers, the second gate dielectric material layers, and the second gate electrode material layers according to the first embodiment of the present disclosure.

FIGS. 27A, 27B, 27C, 27D, 27E, 27F, and 27G are various views of the first exemplary structure after formation of a one-dimensional array of perforated dielectric walls according to the first embodiment of the present disclosure.

FIG. 28 is a vertical cross-sectional view of a selectively deposited channel material layer according to an alternative embodiment.

FIGS. 29A, 29B and 29C are vertical cross-sectional views of respective first, second and third alternative configurations of the first exemplary structure.

FIGS. 30A, 30B, 30C, 30D, 30E, 30F, and 30G are various views of a second exemplary structure after formation of an etch-stop layer, a second gate dielectric material layer, and a continuous second gate electrode material layer according to a second embodiment of the present disclosure.

FIGS. 31A, 31B, 31C, 31D, 31E, 31F, and 31G are various views of the second exemplary structure after formation of a two-dimensional array of second dielectric plates, after patterning the continuous second gate electrode material layer into second gate electrode material layers, and after patterning the second gate dielectric material layer according to the second embodiment of the present disclosure.

FIGS. 32A, 32B, 32C, 32D, 32E, 32F, and 32G are various views of the second exemplary structure after laterally recessing the second dielectric plates according to the second embodiment of the present disclosure.

FIGS. 33A, 33B, 33C, 33D, 33E, 33F, and 33G are various views of the second exemplary structure after formation of perforated passivation walls according to the second embodiment of the present disclosure.

FIGS. 34A, 34B, 34C, 34D, 34E, 34F, and 34G are various views of the second exemplary structure after removal of unmasked portions of the etch-stop layer according to the second embodiment of the present disclosure.

FIGS. 35A, 35B, 35C, 35D, 35E, 35F, and 35G are various views of the second exemplary structure after removal of second portions of horizontally-extending semiconductor rails and formation of elongated cavities according to the second embodiment of the present disclosure.

FIGS. 36A, 36B, 36C, 36D, 36E, 36F, and 36G are various views of the second exemplary structure after physically exposed portions of the etch-stop layer around the elongated cavities according to the second embodiment of the present disclosure.

FIGS. 37A, 37B, 37C, 37D, 37E, 37F, and 37G are various views of the second exemplary structure after formation of metallic material portions on physically exposed surfaces of the doped semiconductor material portions according to the second embodiment of the present disclosure.

FIGS. 38A, 38B, 38C, 38D, 38E, 38F, and 38G are various views of the second exemplary structure after deposition of a channel material layer according to the second embodiment of the present disclosure.

FIGS. 39A, 39B, 39C, 39D, 39E, 39F, and 39G are various views of the second exemplary structure after formation of dielectric core structures according to the second embodiment of the present disclosure.

FIGS. 40A, 40B, 40C, 40D, 40E, 40F, and 40G are various views of the second exemplary structure after patterning the channel material layer into a three-dimensional array of tubular-portion-containing channels according to the second embodiment of the present disclosure.

FIGS. 41A, 41B, 41C, 41D, 41E, 41F, and 41G are various views of the second exemplary structure after formation of source trench isolation structures according to the second embodiment of the present disclosure.

FIGS. 42A, 42B, 42C, 42D, 42E, 42F, and 42G are various views of the second exemplary structure after formation of bit-line via cavities and source-line via cavities according to the second embodiment of the present disclosure.

FIGS. 43A, 43B, 43C, 43D, 43E, 43F, and 43G are various views of the second exemplary structure after formation of drain regions, vertical bit lines, and vertical source lines according to the second embodiment of the present disclosure.

FIGS. 44A, 44B, 44C, 44D, 44E, 44F, and 44G are various views of the second exemplary structure after formation of a one dimensional array of bridges-encircling cavities through removal of the one-dimensional array of sacrificial perforated wall structures according to the second embodiment of the present disclosure.

FIGS. 45A, 45B, 45C, 45D, 45E, 45F, and 45G are various views of the second exemplary structure after recessing the first gate dielectric material layers, the first gate electrode material layers, the second gate dielectric material layers, and the second gate electrode material layers according to the second embodiment of the present disclosure.

FIGS. 46A, 46B, 46C, 46D, 46E, 46F, and 46G are various views of the second exemplary structure after formation of a one-dimensional array of perforated dielectric walls according to the second embodiment of the present disclosure.

FIGS. 47A, 47B, 47C, 47D, 47E, 47F, and 47G are various views of a first alternative configuration of the second exemplary structure according to the second embodiment of the present disclosure.

FIGS. 48A, 48B, 48C, 48D, 48E, 48F, and 48G are various views of a second alternative configuration of the second exemplary structure according to the second embodiment of the present disclosure.

FIG. 49 is a vertical cross-sectional view of a third alternative configuration of the second exemplary structure according to the second embodiment of the present disclosure.

FIG. 50 is a schematic circuit diagram of an exemplary circuit that may be employed to implement a three-dimensional memory device including the first exemplary structure or the second exemplary structure.

FIG. 51 is a vertical cross-sectional view of a first semiconductor die containing the three-dimensional memory array of the embodiments of the present disclosure.

FIG. 52 is a vertical cross-sectional view of a second semiconductor containing the three-dimensional memory array of the embodiments of the present disclosure.

FIG. 53 is a vertical cross-sectional view of a third semiconductor die containing the three-dimensional memory array of the embodiments of the present disclosure.

FIG. 54 is a vertical cross-sectional view of a fourth semiconductor die containing the three-dimensional memory array of the embodiments of the present disclosure.

FIG. 55 is a vertical cross-sectional view of a fifth semiconductor die containing the three-dimensional memory array of the embodiments of the present disclosure.

FIG. 56 is a vertical cross-sectional view of a sixth semiconductor die containing the three-dimensional memory array of the embodiments of the present disclosure.

### DETAILED DESCRIPTION

As discussed above, the embodiments of the present disclosure are directed to three-dimensional memory devices within laterally integrated access transistors and methods of manufacturing the same, various aspects of which are described below. The embodiments of the disclosure may be employed to form various multilevel memory structures, non-limiting examples of which include non-volatile memory arrays and volatile memory arrays that can be implemented as three-dimensional memory arrays. Each unit cell may comprise a combination of an access transistor and an impedance element (such as a capacitive element or a resistive element), or may comprise a combination of an access transistor and a memory transistor.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The same reference numerals refer to the same element or similar element. Unless otherwise indicated, elements having the same reference numerals are presumed to have the same composition and the same function.

Unless otherwise indicated, a “contact” between elements refers to a direct contact between elements that provides an edge or a surface shared by the elements. As used herein, a first element located “on” a second element may be located on the exterior side of a surface of the second element or on the interior side of the second element. As used herein, a first element is located “directly on” a second element if there exists a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded thereamongst, for example, by flip-chip bonding or another chip-to-chip bonding. A package or a chip may include a single semiconductor die (or a “die”) or a plurality of semiconductor dies. A die is the smallest unit that can independently execute external commands or report status. Typically, a package or a chip with multiple dies is capable of simultaneously executing as many external commands as the total number of planes therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

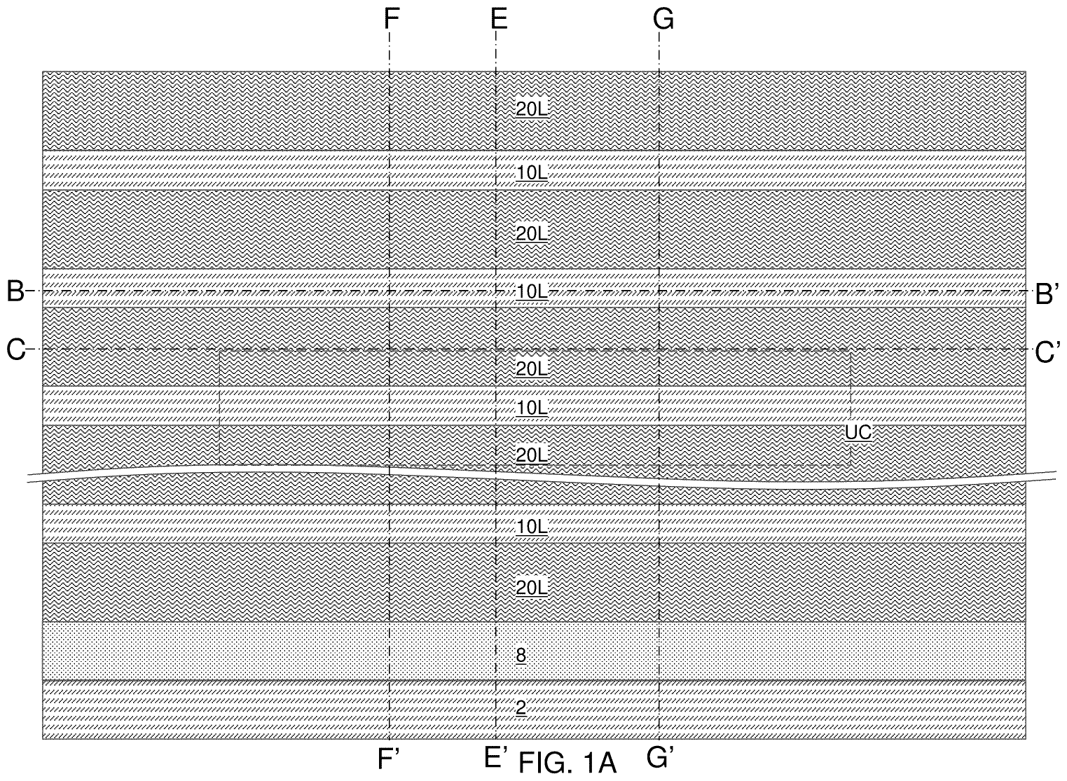

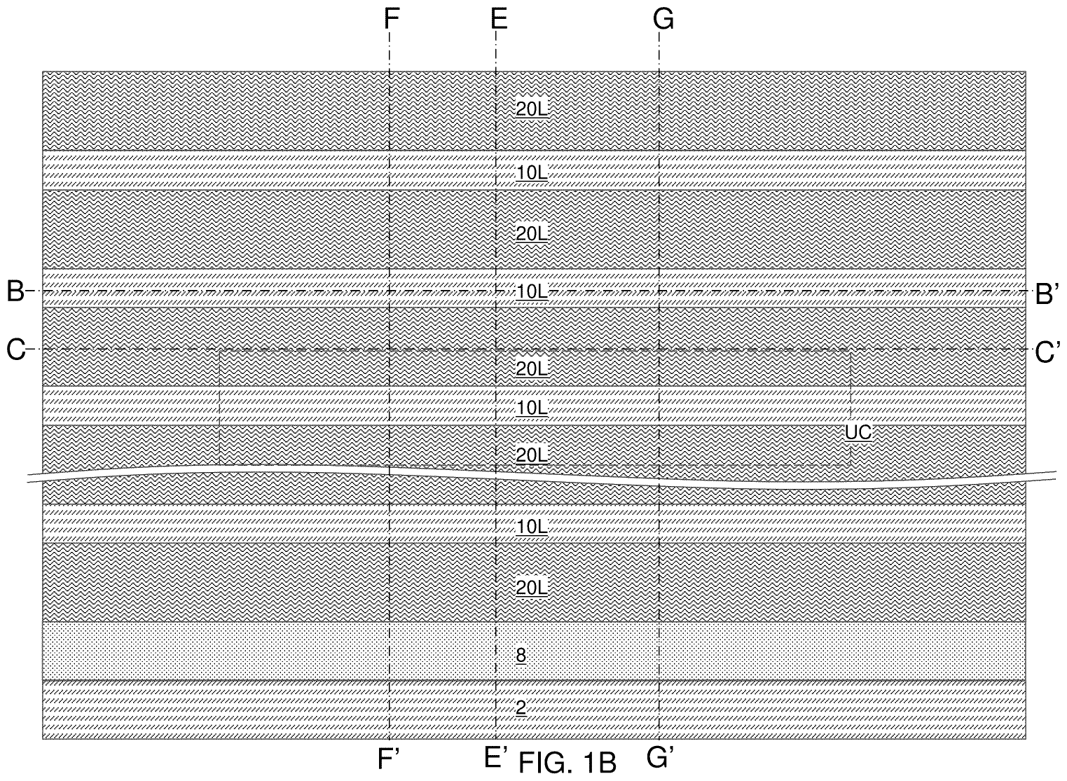

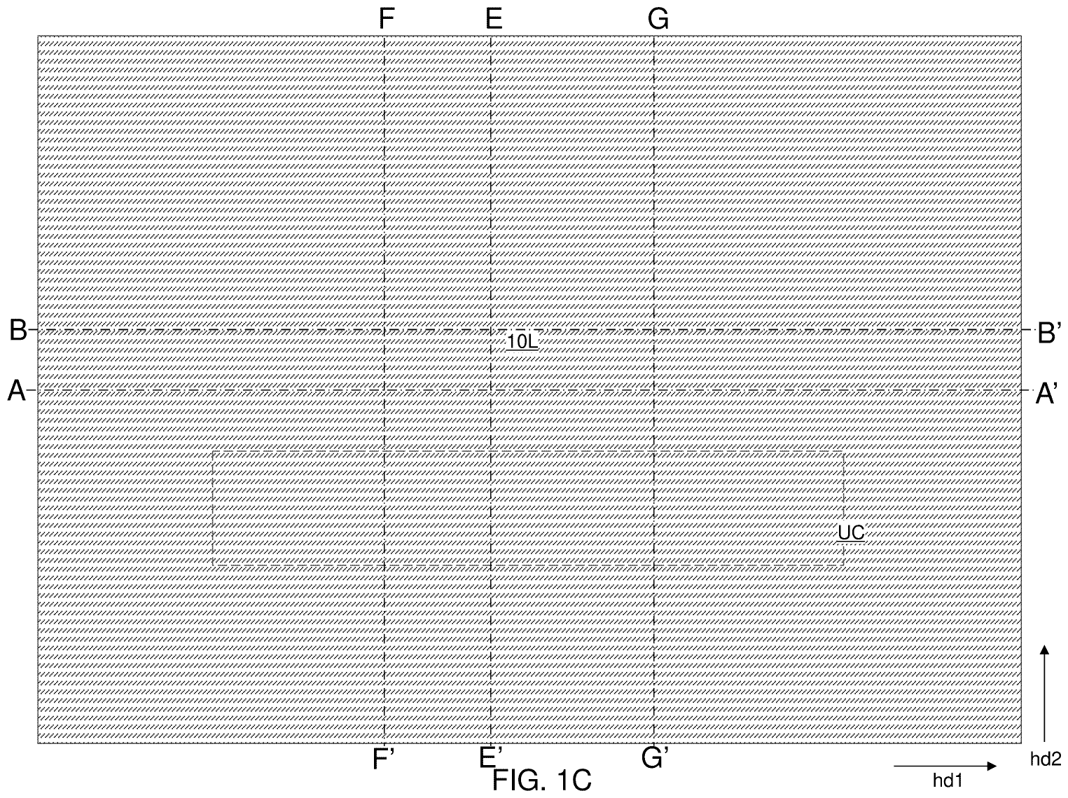

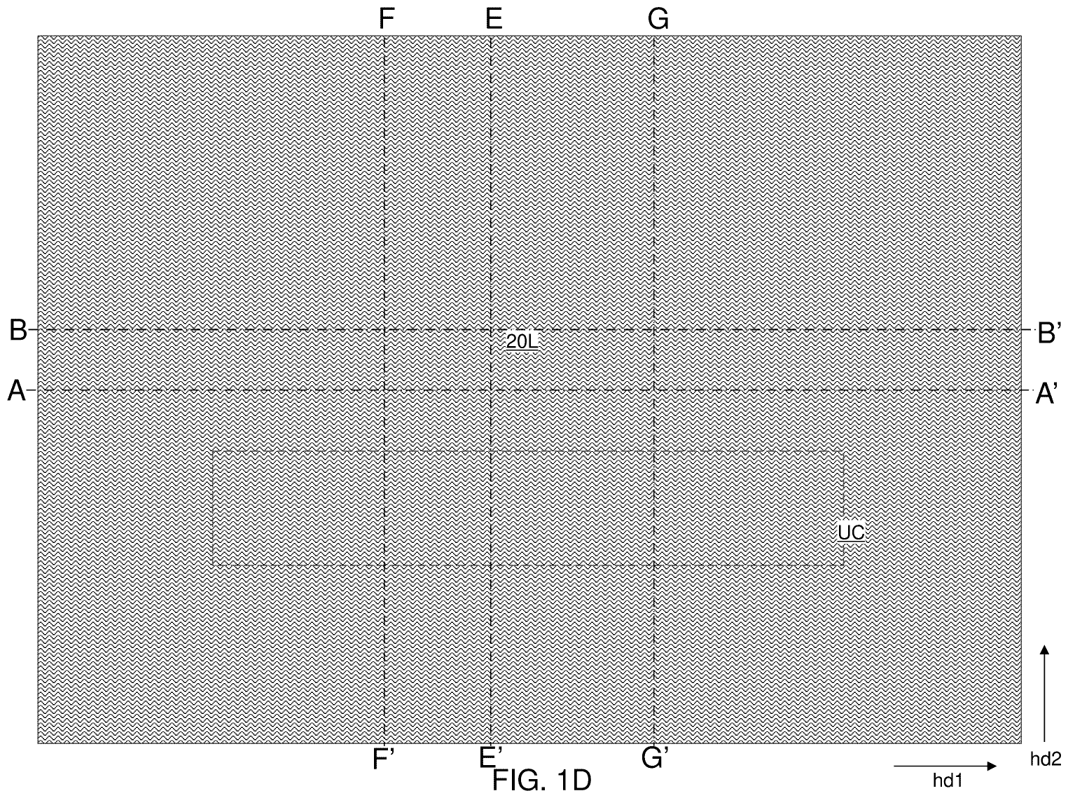

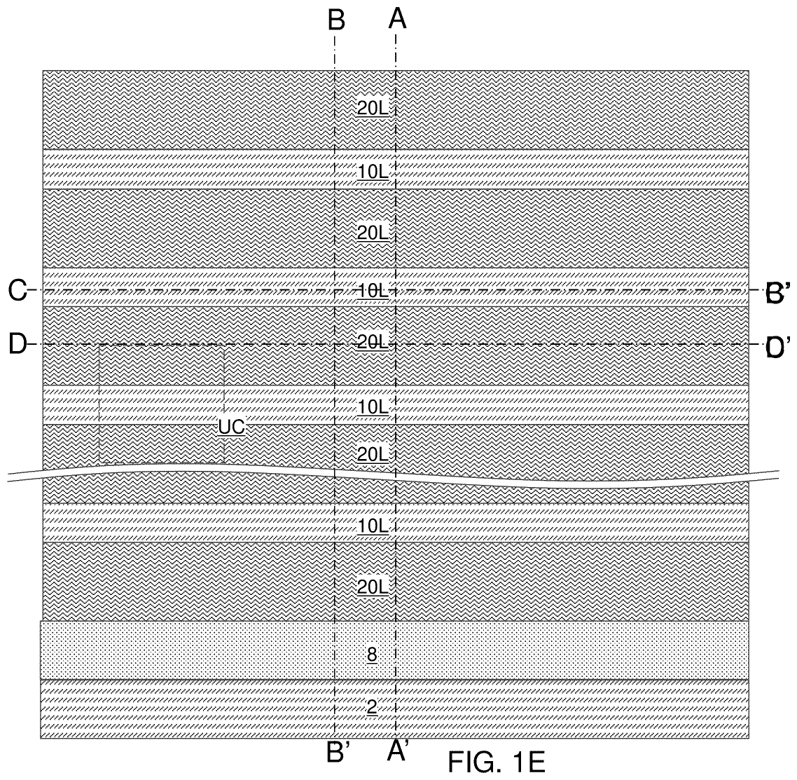

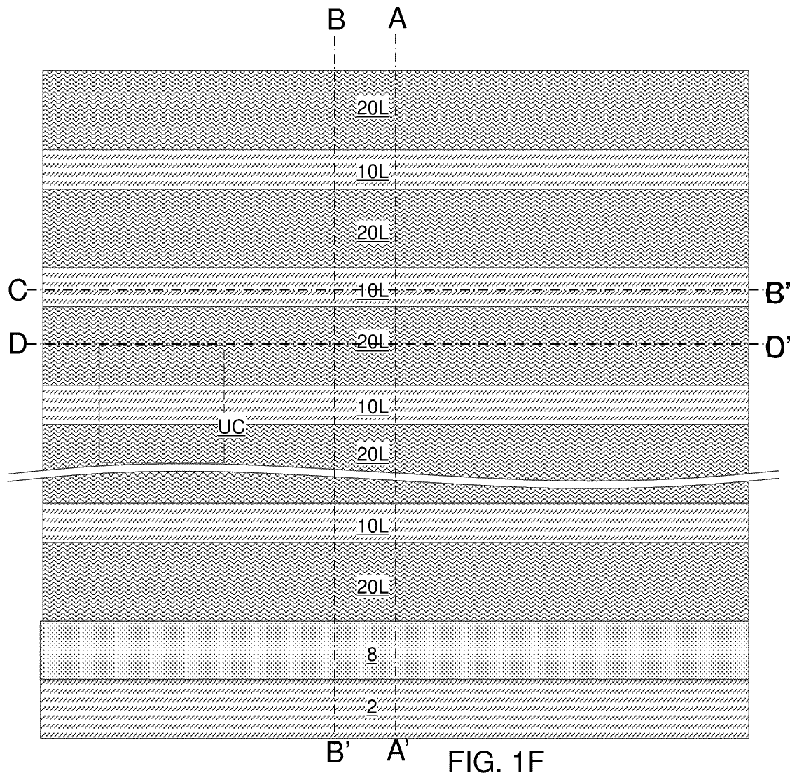

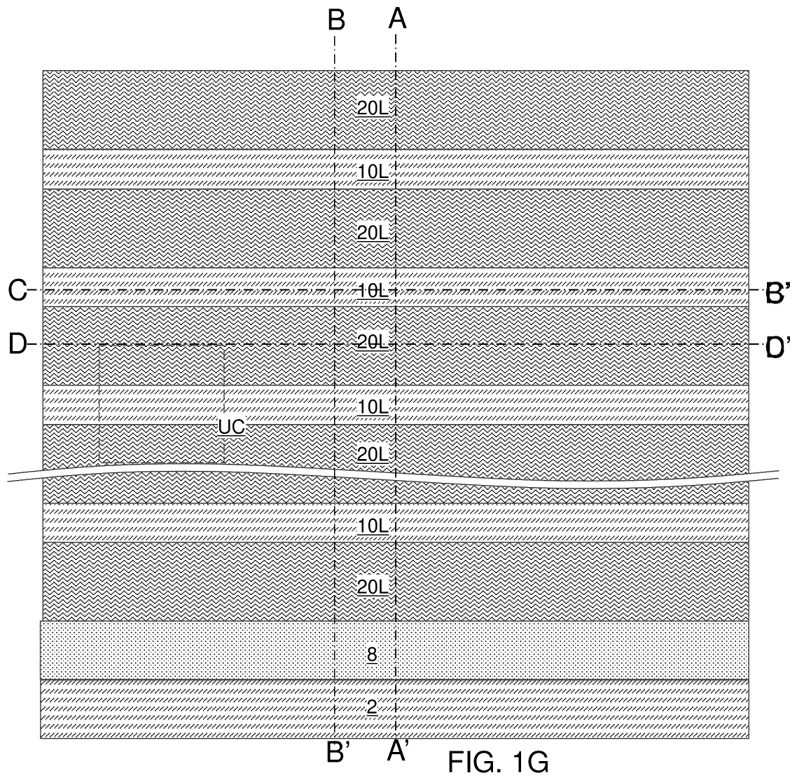

Referring to FIGS. 1A, 1B, 1C, 1D, 1E, 1F, and 1G, a first exemplary structure according to a first embodiment of the present disclosure is illustrated. The first exemplary structure comprises a substrate 2, which may be a semiconductor substrate, an insulating substrate, a conductive substrate, or a composite substrate including a stack of multiple layers. In some embodiments, the substrate 2 may comprise a single crystalline semiconductor substrate, such as a commercially available single crystalline silicon wafer.

Preferably, but not necessarily, an etch stop structure 8 can be formed on the top surface of the substrate 2. The etch stop structure 8 may comprise at least one etch stop material layer and/or may comprise patterned discrete etch stop structures. Generally, any material layer and/or patterned material portions may be employed as the etch stop structure 8. In some embodiments, the etch stop structure 8 may comprise a single crystalline carbon doped silicon layer or a single crystalline nitrogen doped silicon layer. In some other embodiments, the etch stop structure 8 may comprise at least one dielectric material layer, such as a silicon oxide layer, a silicon nitride layer, a silicon carbonitride layer, a silicon oxynitride layer, a dielectric metal oxide layer, or a combination thereof. Alternatively, the etch stop structure 8 comprises patterned dielectric material portions that are embedded in an upper portion of the substrate 2.

A vertically alternating sequence of sacrificial layers 20L and semiconductor layers 10L can be formed over the etch stop structure 8. In one embodiment, the sacrificial layers 20L and the semiconductor layers 10L may comprise nanolayers comprising an unpatterned layer having a thickness greater than 1 nm and less than 1 micron. Each sacrificial layer 20L comprises a sacrificial material, and each semiconductor layer 10L comprises a semiconductor material. The sacrificial material of the sacrificial layers 20L is a material that may be subsequently removed selectively to the material of the semiconductor layers 10L and selectively to the material of the etch stop structure 8. For example, the semiconductor layers 10L may comprise silicon (such as single crystalline silicon, polycrystalline silicon, or amorphous silicon that may be subsequently crystallized into polycrystalline silicon), and the sacrificial layers 20L may comprise a silicon germanium compound semiconductor material including germanium atoms at an atomic percentage in a range from 10% to 40%, silicon nitride, organosilicate glass, or a polymer material. Each semiconductor layer 10L may have a first thickness in a range from 10 nm to 200 nm (such as from 20 nm to 100 nm), although lesser and greater first thicknesses may also be employed. In one embodiment, the semiconductor layers 10L may comprise single crystalline silicon that are epitaxially aligned to a single crystalline semiconductor material within the substrate 2, and the sacrificial layers 20L may comprise single crystalline silicon-germanium compound semiconductor layers that are epitaxially aligned to the single crystalline silicon in the semiconductor layers 10L and to the single crystalline semiconductor material within the substrate 2. In this case, the entire set of the substrate 2, the semiconductor layers 10L, and the sacrificial layers 20L may be single crystalline, and may be epitaxially aligned to each other. Each sacrificial layer 20L may have a second thickness in a range from 20 nm to 300 nm (such as from 30 nm to 150 nm), although lesser and greater second thicknesses may also be employed.

The vertically alternating sequence (20L, 10L) may be formed by an alternating sequence of deposition steps that each deposit a respective sacrificial layer 20L or a respective semiconductor layer 10L. For example, each semiconductor layer 10L may be deposited by a first-type chemical vapor deposition or atomic layer deposition process, and each sacrificial layer 20L may be deposited by a second-type chemical vapor deposition or atomic layer deposition process. The bottommost layer of the vertically alternating sequence (20L, 10L) may be a sacrificial layer 20L or a semiconductor layer 10L. The topmost layer of the vertically alternating sequence (20L, 10L) may be a sacrificial layer 20L or a semiconductor layer 10L. The (N+1) pairs of a sacrificial layer 20L and a semiconductor layer 10L can be present in the vertically alternating sequence (20L, 10L). The number N may be in a range from 2 to 210, such as from 8 to 28, although lesser and greater numbers of pairs may also be employed. The three-dimensional array of unit cells UC is a subsequently formed within the volume of the vertically alternating sequence (20L, 10L). A volume of a unit cell UC is a schematically illustrated in each of FIGS. 1A, 1B, 1C, 1D, and 1E. The three-dimensional array of unit cells UC comprises a three-dimensional memory array. The three-dimensional array of unit cells UC may have a first periodicity along a first horizontal direction hd1, a second periodicity along a second horizontal direction hd2 that is perpendicular to the first horizontal direction hd1, and the third periodicity along the vertical direction. The third periodicity may equal the sum of the first thickness and the second thickness.

The thickness of the bottommost sacrificial layer 20L and the topmost sacrificial layer 20L may be adjusted as needed, i.e., to ensure that peripheral structures formed at these levels do not interfere with final devices that are formed at the levels of the semiconductor layers 10L. Each of the (N+1) semiconductor layers 10L may have the same thickness throughout. Each of the N sacrificial layers 20L except the topmost sacrificial layer 20L and the bottommost sacrificial layer 20L may have the same thickness.

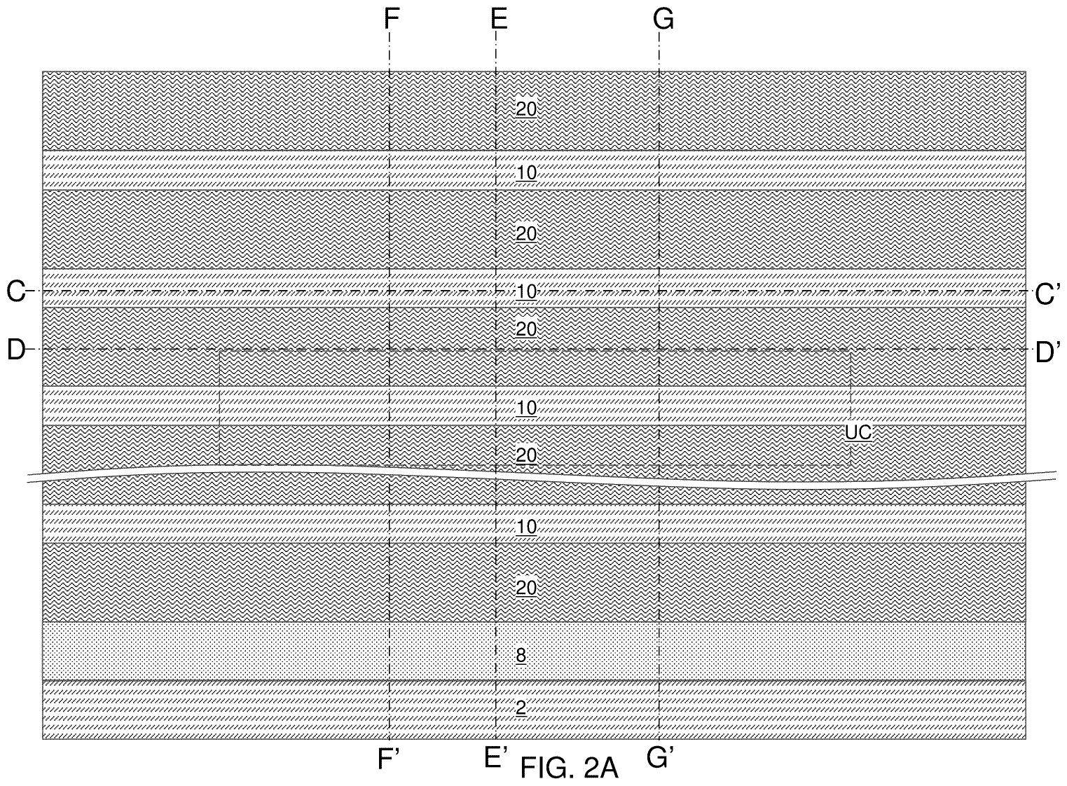

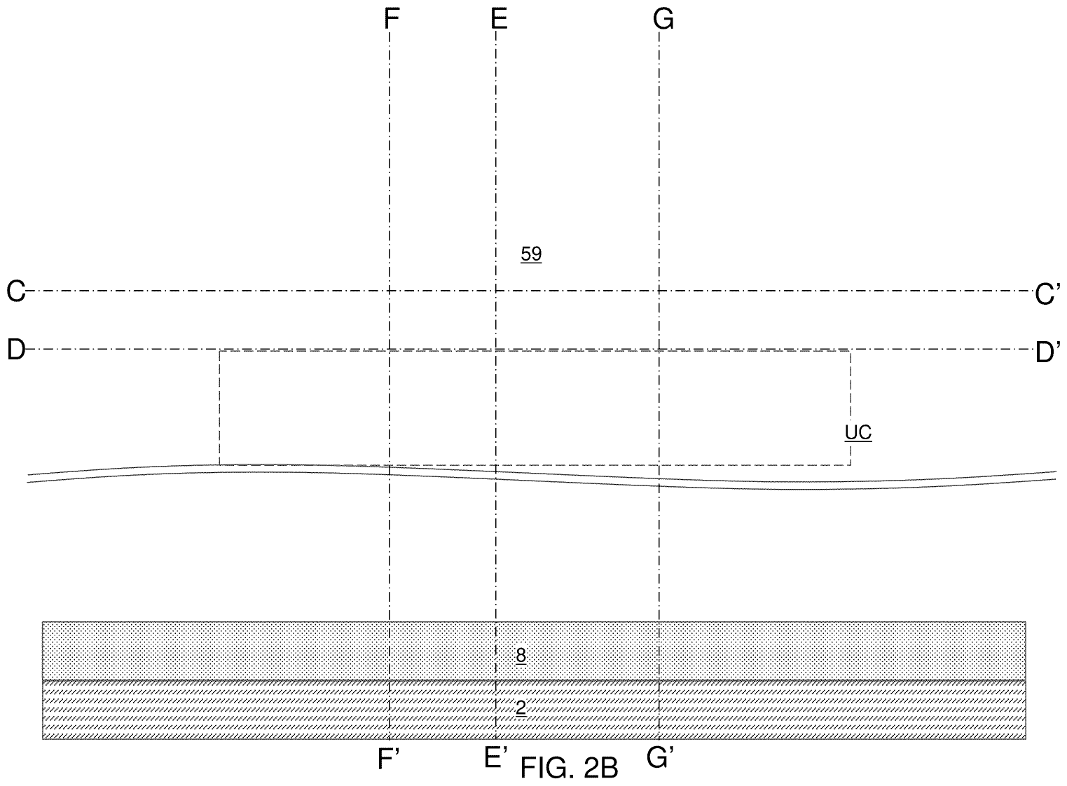

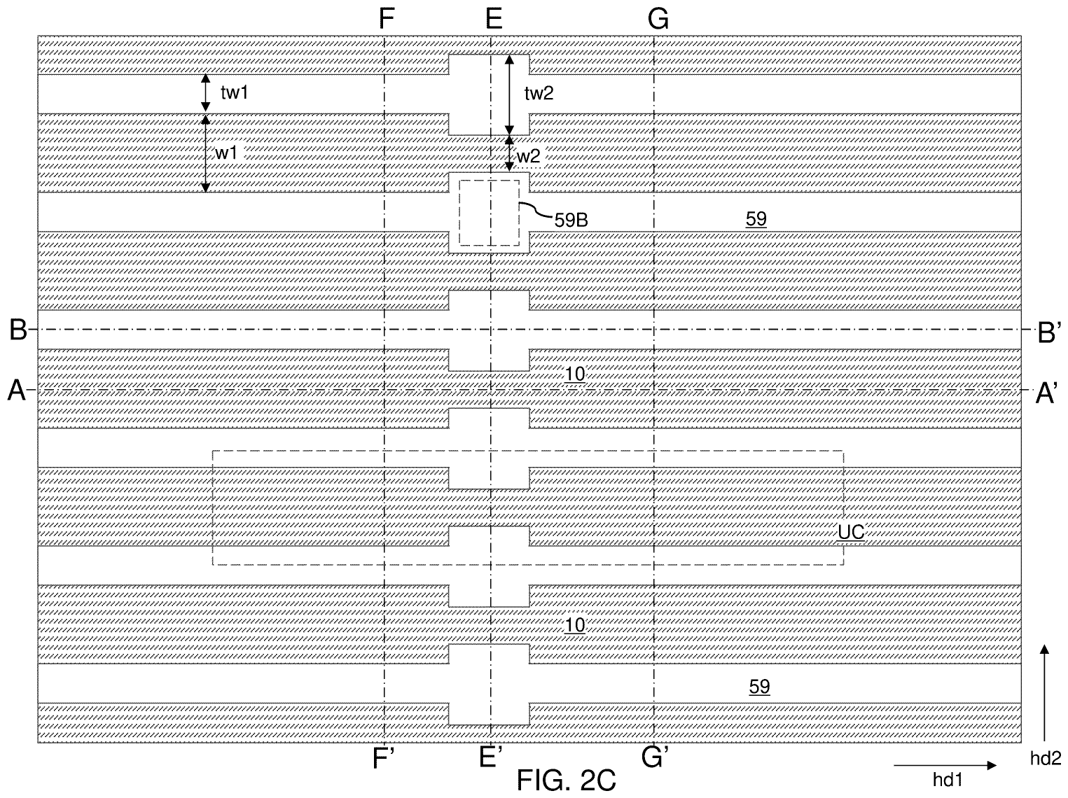

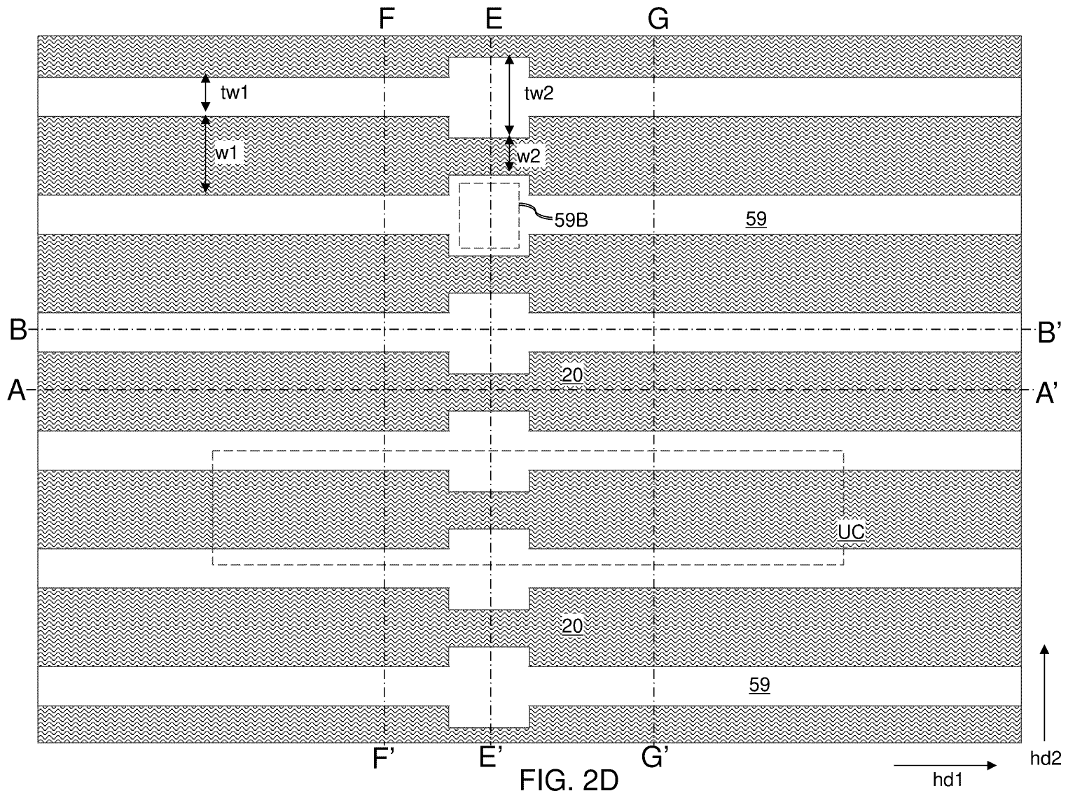

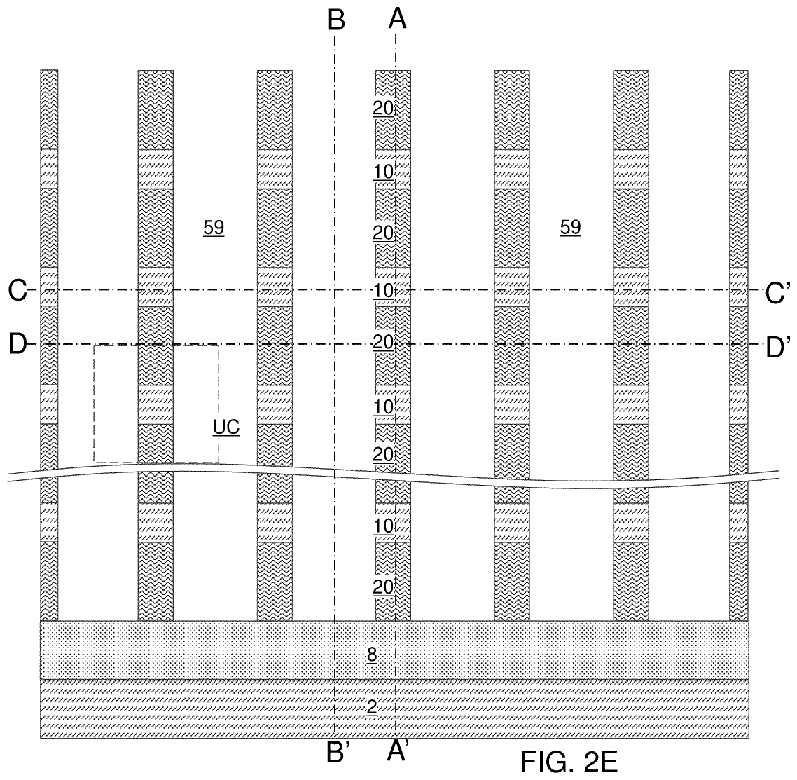

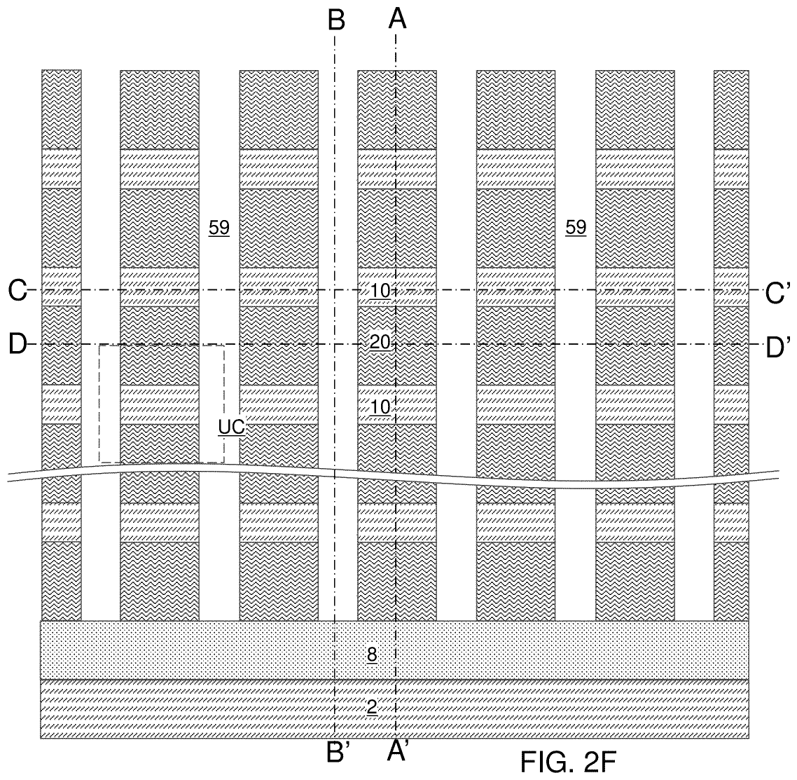

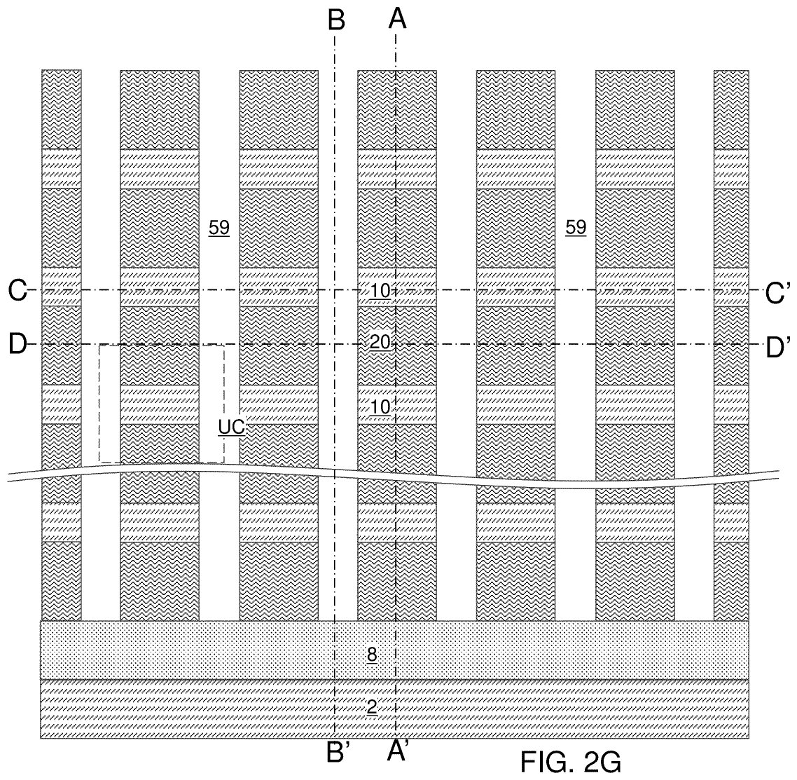

Referring to FIGS. 2A, 2B, 2C, 2D, 2E, 2F, and 2G, the vertically alternating sequence (20L, 10L) of sacrificial layers 20L and semiconductor layers 10L can be patterned. Specifically, a photoresist layer (not shown) can be applied over the vertically alternating sequence (20L, 10L) of sacrificial layers 20L and semiconductor layers 10L, and can be lithographically patterned to form a modified line and space pattern in which each space pattern has a periodic widening along a first horizontal direction hd1. In this case, the pattern of periodic widening may be a two-dimensional periodic pattern of rectangular shapes or rounded rectangular shapes which is juxtaposed with a one-dimensional periodic space pattern. As a corollary, each line pattern is modified to include a periodic bulging region.

An anisotropic etch process can be performed to form transfer the pattern in the photoresist layer through the vertically alternating sequence (20L, 10L) of sacrificial layers 20L and semiconductor layers 10L. The vertically alternating sequence (20L, 10L) of sacrificial layers 20L and semiconductor layers 10L is patterned into vertically alternating stacks of in-process horizontally-extending semiconductor rails 10′ and in-process horizontally-extending sacrificial rails 20′. Each in-process horizontally-extending semiconductor rail 10′ is a patterned portion of a semiconductor layer 10L, and laterally extends along the first horizontal direction hd1 with a uniform height and a periodically modulating width. Each in-process horizontally-extending sacrificial rail 20′ is a patterned portion of a sacrificial layer 20L, and laterally extends along the first horizontal direction hd1 with a uniform height and a periodically modulating width. A two-dimensional M×(N+1) array of in-process horizontally-extending semiconductor rails 10′ and a two-dimensional M×(N+2) array of in-process horizontally-extending sacrificial rails 20′ can be formed such that M vertically alternating stacks (10′, 20′) of (N+1) in-process horizontally-extending semiconductor rail 10′ and (N+2) in-process horizontally-extending sacrificial rails 20′ are formed.

Each of the vertically alternating stacks (10′, 20′) laterally extends along the first horizontal direction hd1. The vertically alternating stacks (10′, 20′) are laterally spaced apart from each other along a second horizontal direction hd2 by lateral isolation trenches 59. Each of the lateral isolation trenches 59 may comprise (L+1) uniform width portions having a uniform width (which may be referred to as a first trench width tw1) and L laterally bulging portions having a width that is greater than the uniform width, as shown in FIGS. 2C and 2D. The laterally bulging portions have a width (which may be referred to as a second trench width tw2) that is greater than the width of the uniform width portions. Thus, each of the lateral isolation trenches 59 may include periodically laterally bulging portions 59B having a greater width (such as the second trench width tw2) that is greater than the width of uniform width portions (such as the first trench width tw1).

Each of the unit cells UC comprises a portion of in-process horizontally-extending semiconductor rail 10′, a portion of a lower half of an overlying in-process horizontally-extending sacrificial rail 20′, and a portion of an upper half of an underlying in-process horizontally-extending sacrificial rail 20′. Each of the in-process horizontally-extending semiconductor rails 10′ and the in-process horizontally-extending sacrificial rails 20′ may have (L+1) uniform width portions having a first width w1 and L notch portions having a second width w2 that is less than the first width w1, as shown in FIGS. 2C and 2D. The first width w1 may be in a range from 30 nm to 900 nm, such as from 100 nm to 500 nm, although lesser and greater dimensions may also be employed. The second width w2 may be in a range from 10 nm to 300 nm, although lesser and greater dimensions may also be employed. The first trench width tw1 may be in a range from 10 nm to 200 nm, such as from 20 nm to 100 nm, although lesser and greater widths may also be employed. The second trench width tw2 may be the same as the sum of the first trench width tw1 and the difference between the first width w1 and the second width w2, i.e., tw2=tw1+(w2−w1).

The center-to-center distance between neighboring pairs of laterally bulging portions of a lateral isolation trench 59 along the first horizontal direction hd1 can be the same as the first periodicity of the three-dimensional array of unit cells UC along the first horizontal direction hd1. The first periodicity may be in a range from 200 nm to 10,000 nm, such as from 400 nm to 1,000 nm, although lesser and greater dimensions may also be employed for the first periodicity. The center-to-center distance between neighboring pairs of the lateral isolation trenches 59 can be the same as the second periodicity of the three-dimensional array of unit cells UC along the second horizontal direction hd2. The second periodicity may be in a range from 20 nm to 1,000 nm, such as from 40 nm to 500 nm, although lesser and greater dimensions may also be employed for the second periodicity.

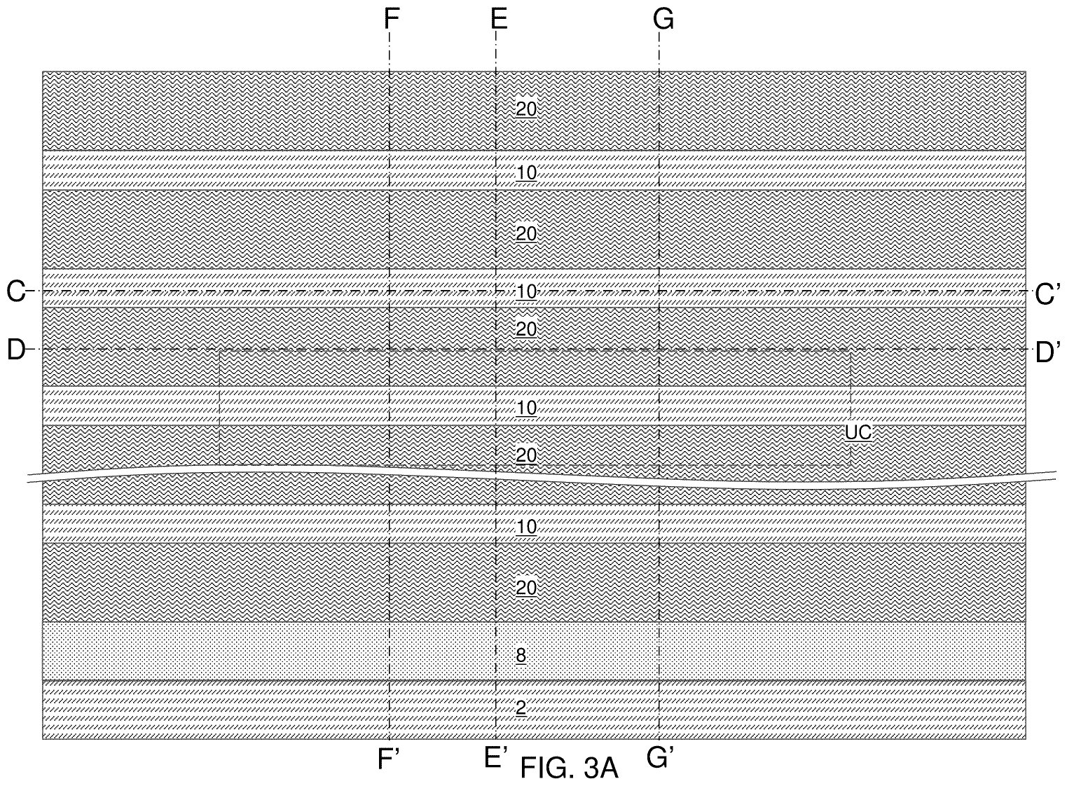

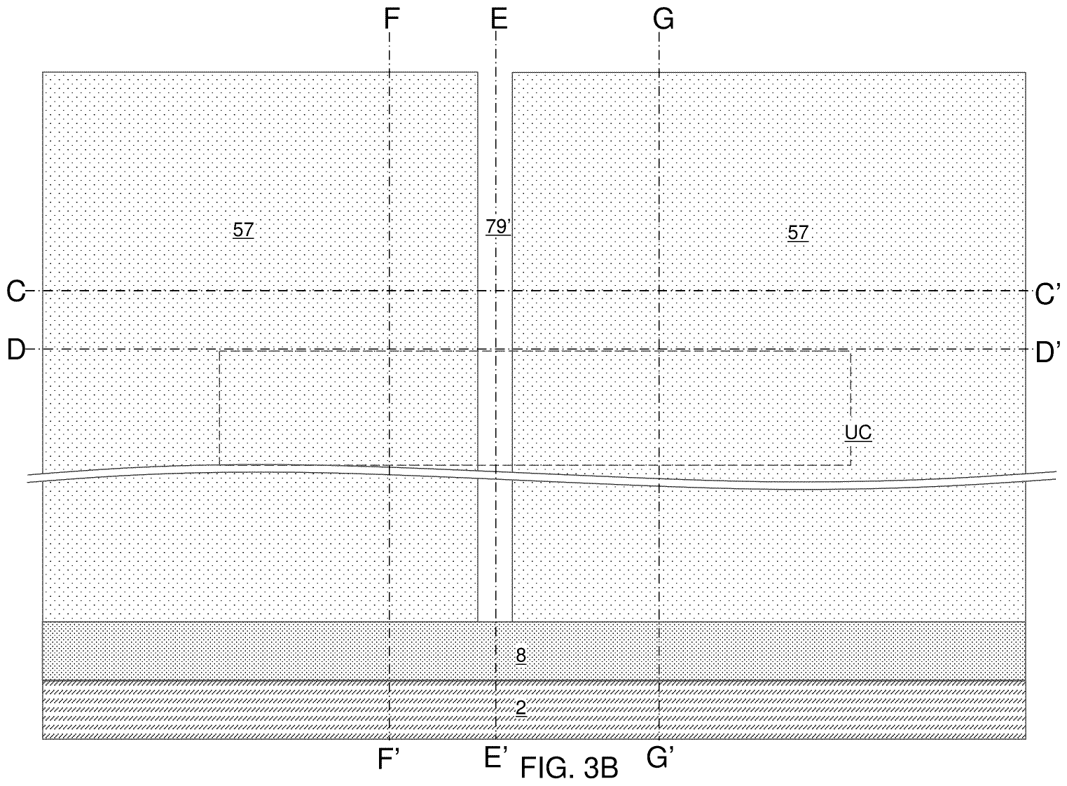

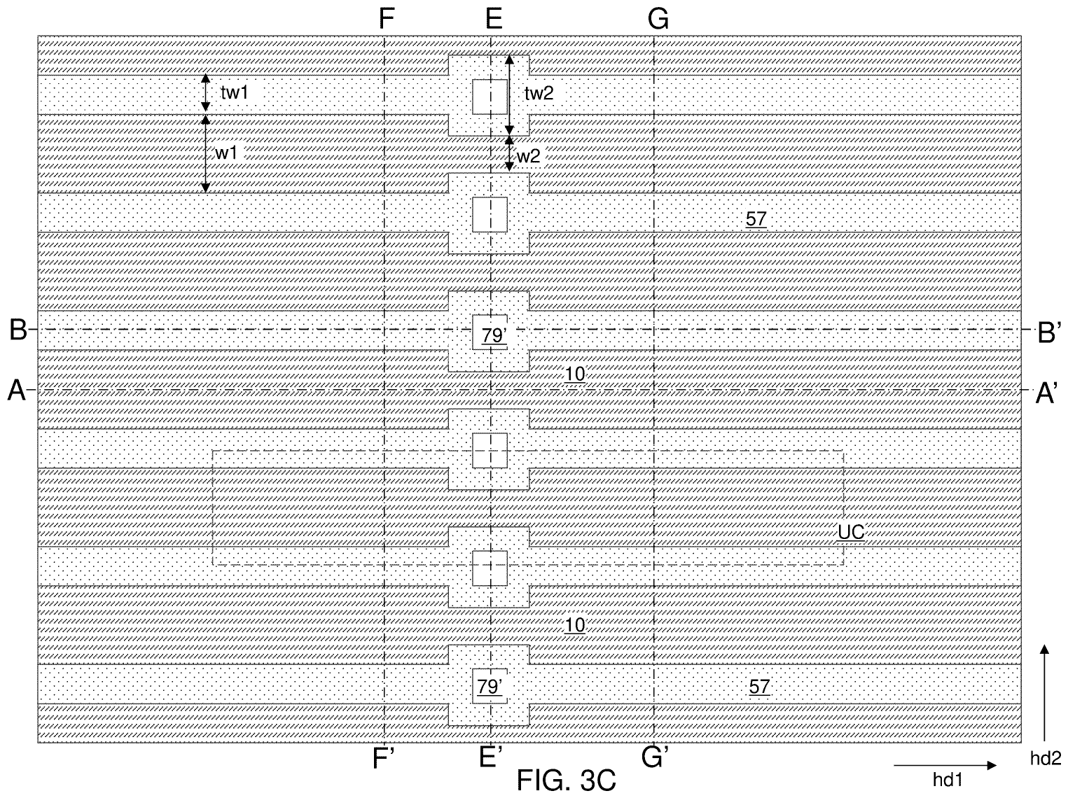

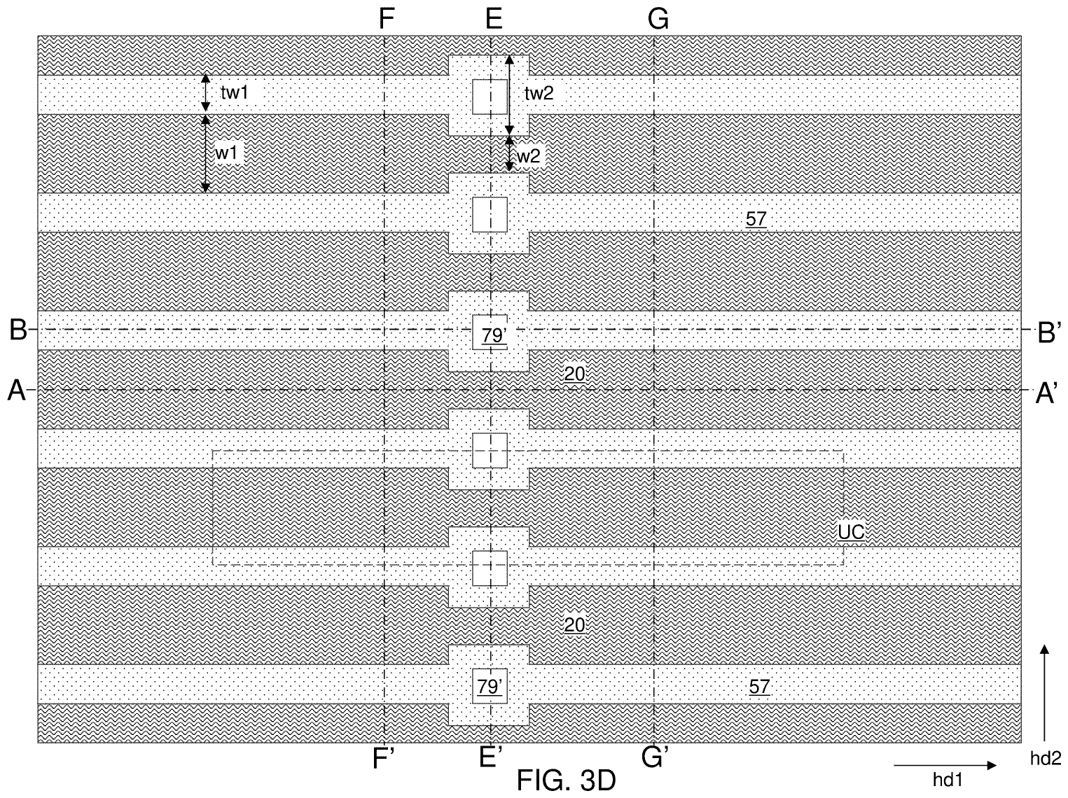

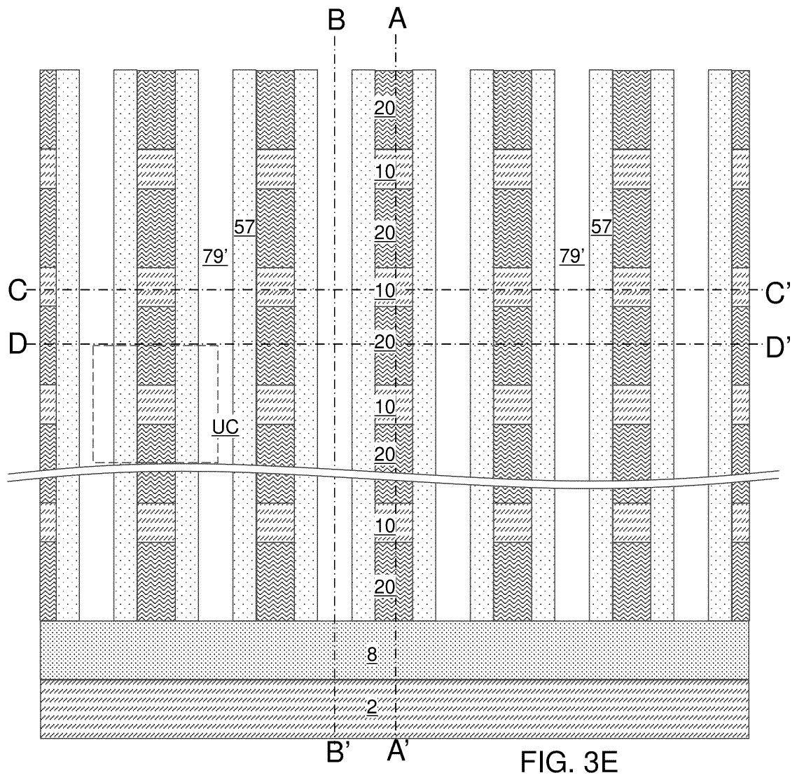

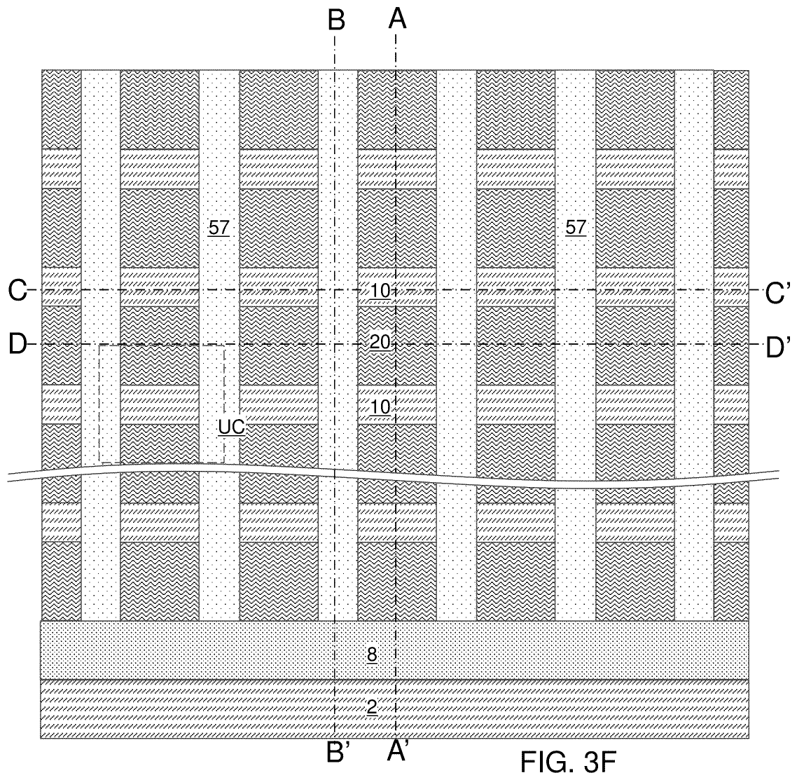

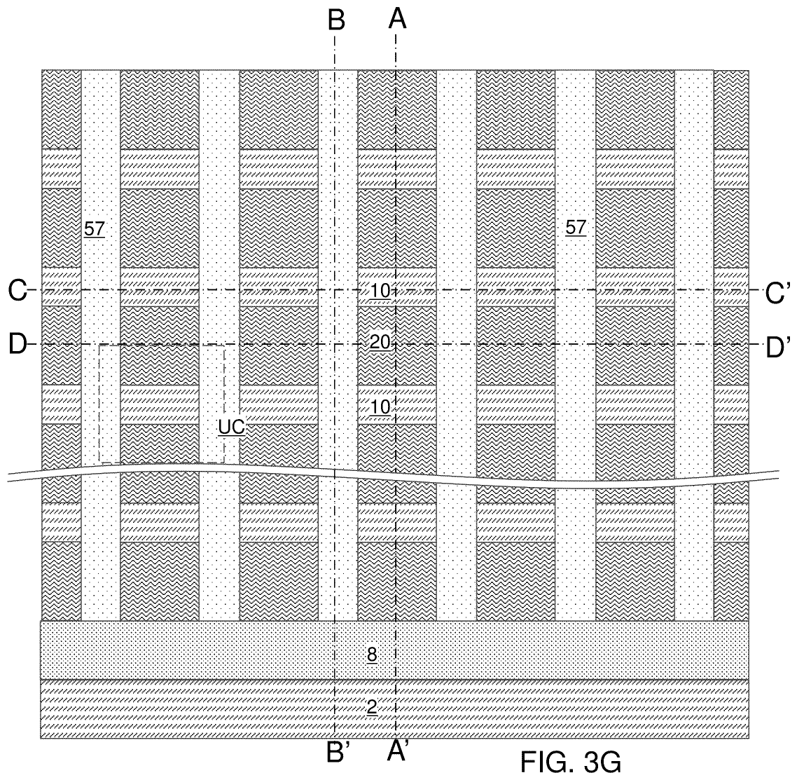

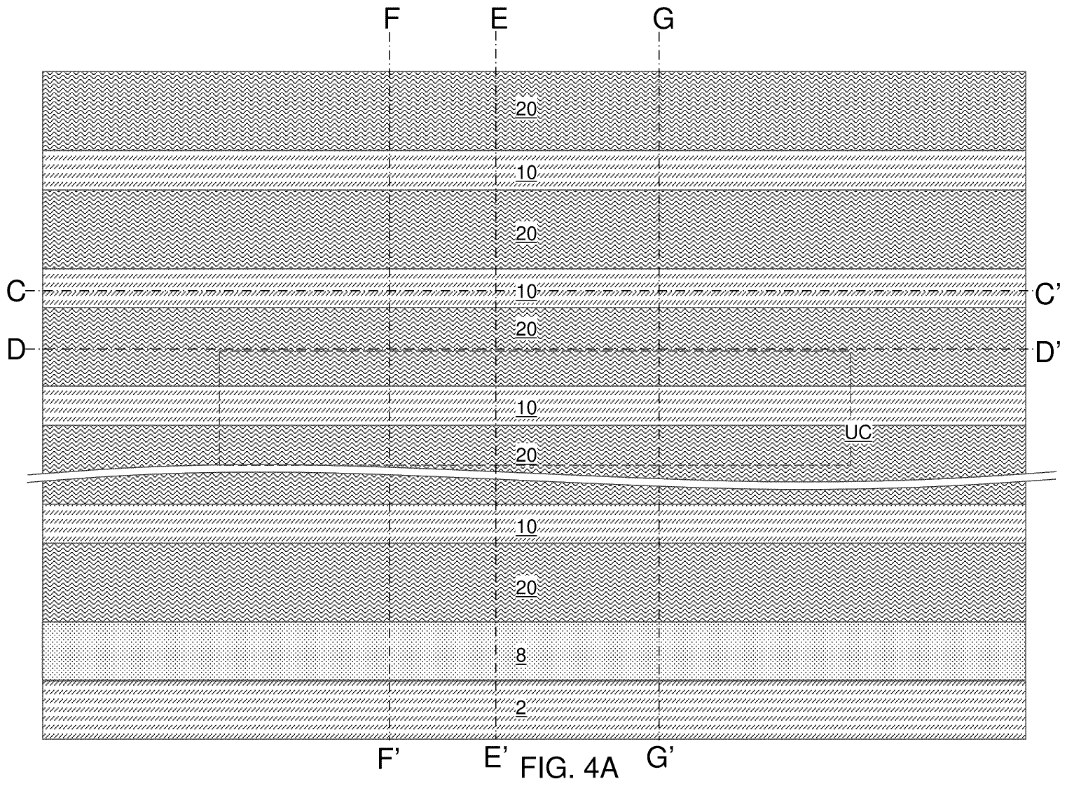

Referring to FIGS. 3A, 3B, 3C, 3D, 3E, 3F, and 3G, a sacrificial fill material layer 57L can be deposited in the lateral isolation trenches 59 and over the vertically alternating stacks (10′, 20′). The sacrificial fill material layer 57L may comprise a carbon-based material (such as amorphous carbon or diamond-like carbon), organosilicate glass, silicon oxide, silicon nitride, or a polymer material. For example, the sacrificial fill material may comprise silicon oxide. The sacrificial fill material may be different from the material of the in-process horizontally-extending sacrificial rails 20′. The duration of the deposition process that deposits the sacrificial fill material is selected such that the uniform width portions of the lateral isolation trenches 59 having the first trench width tw1 are filled, while the laterally bulging portions 59B of the lateral isolation trenches 59 having the second trench width tw2 are not completely filled and thus, have a respective vertically extending void 79′ therein. If a conformal deposition process is employed to deposit the sacrificial fill material, the thickness of the deposited sacrificial fill material may be greater than one half of the first trench width tw1, and is less than one half of the second trench width tw2.

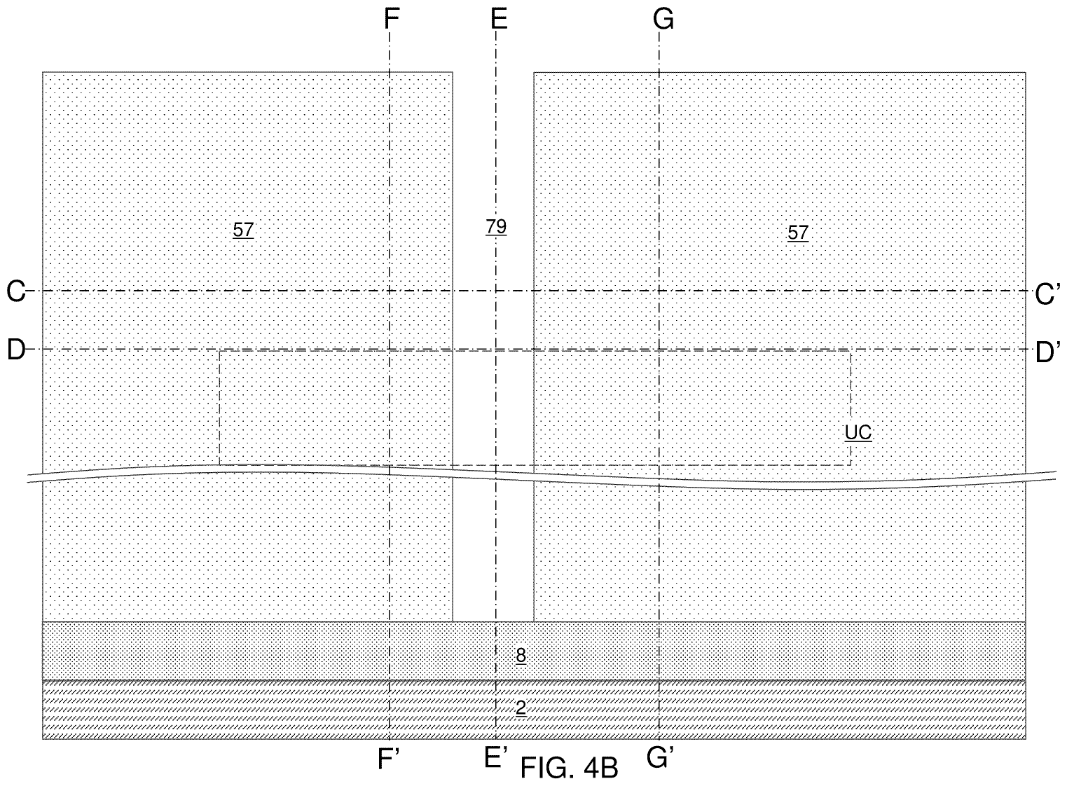

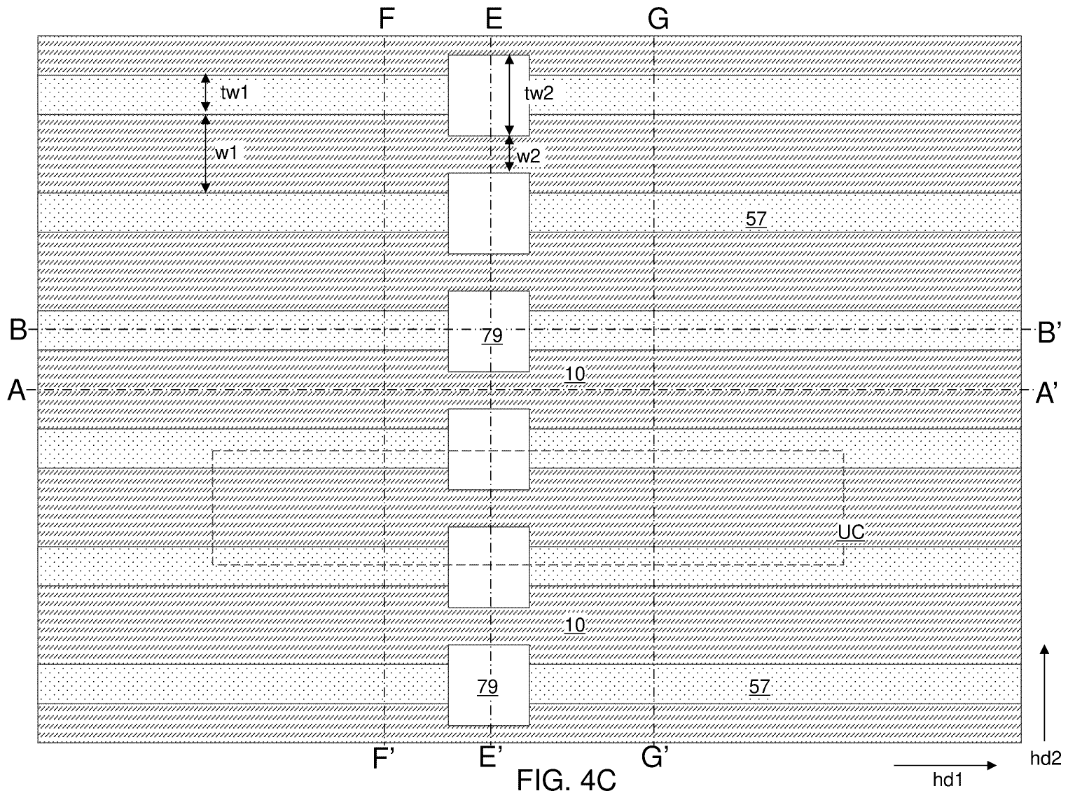

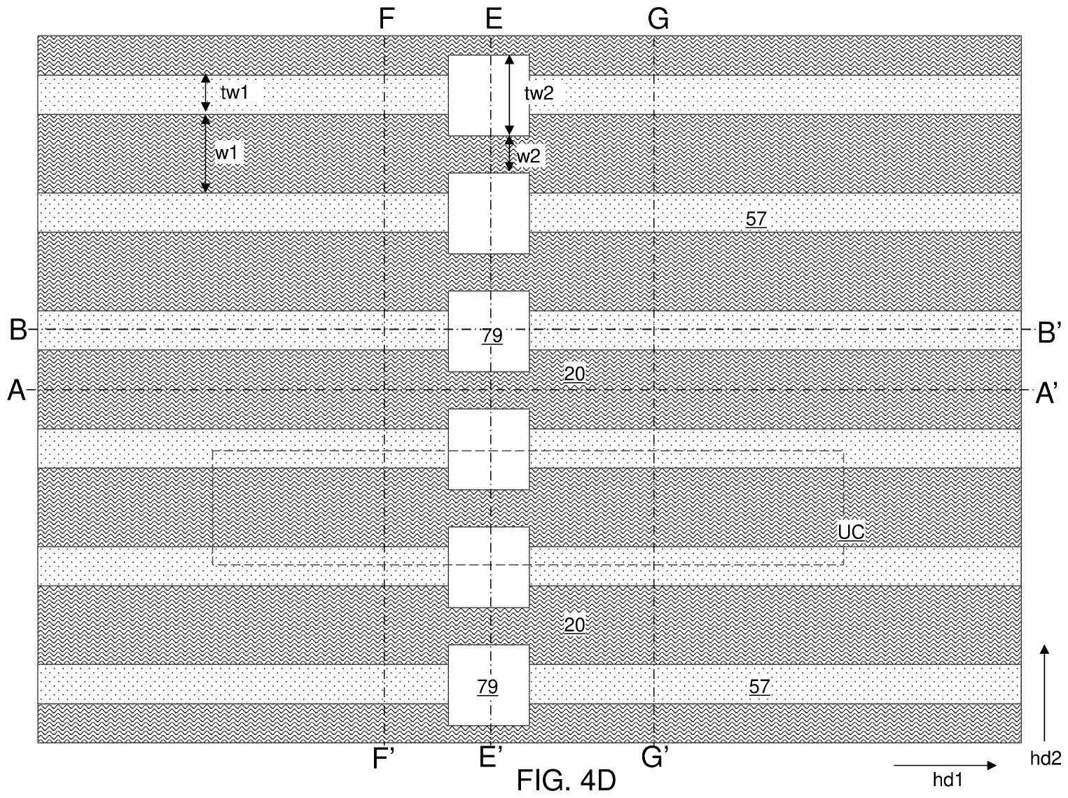

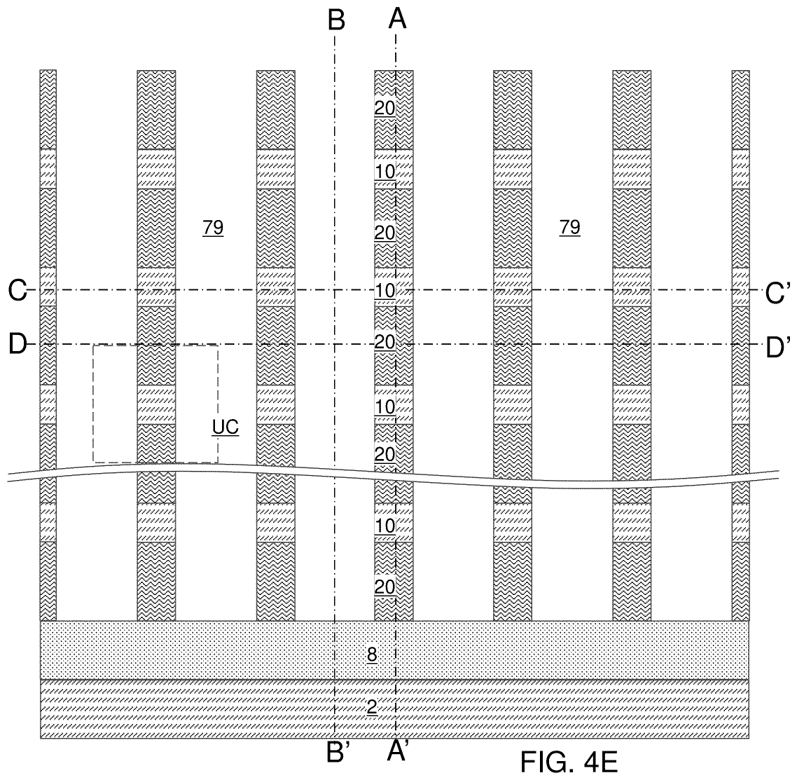

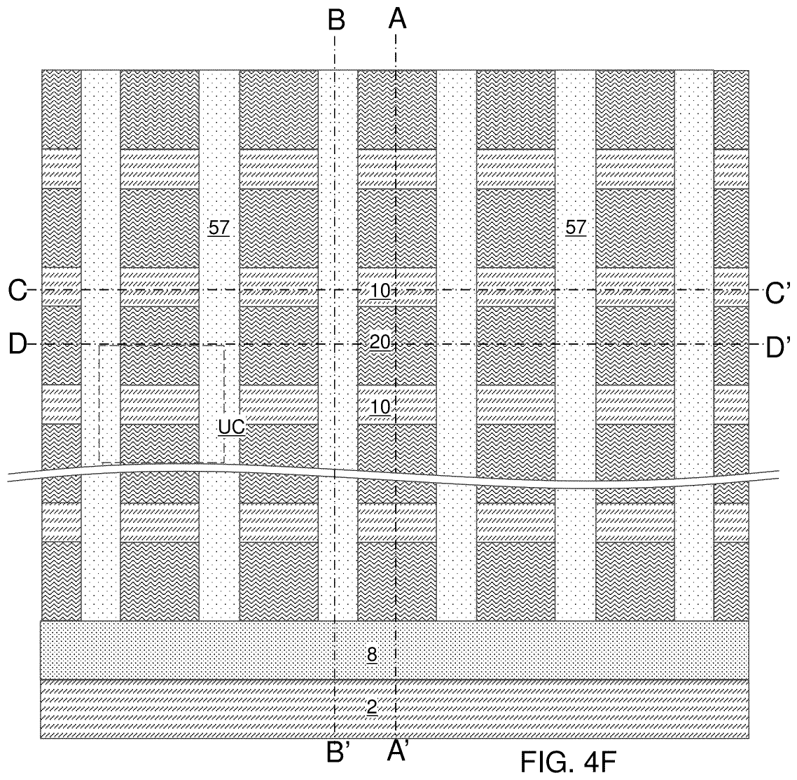

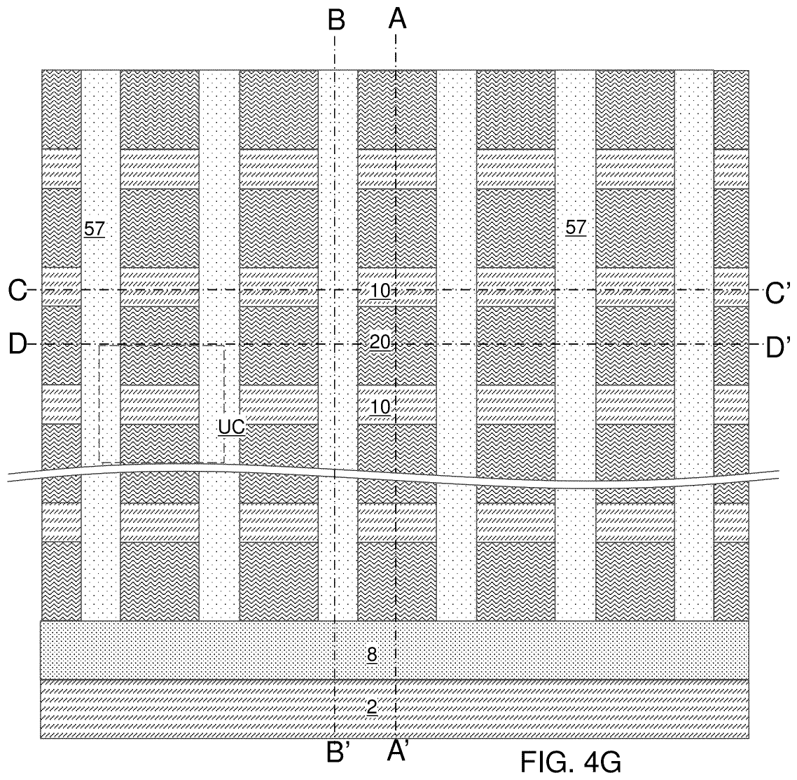

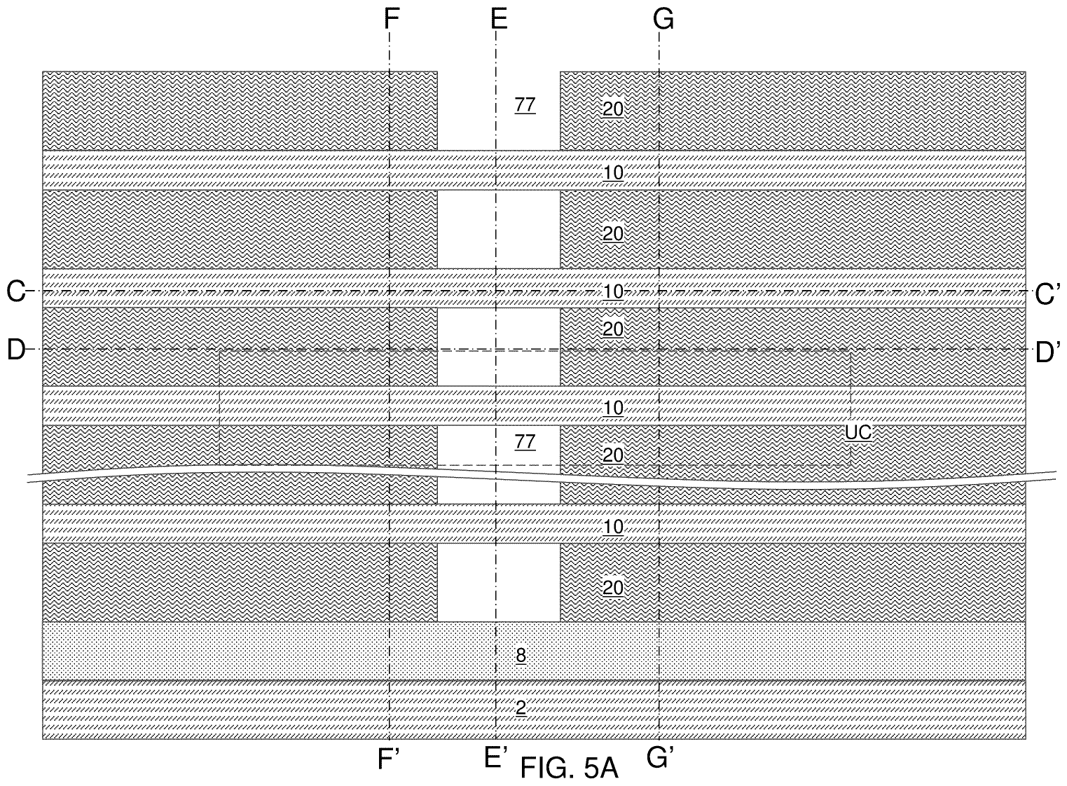

Referring to FIGS. 4A, 4B, 4C, 4D, 4E, 4F, and 4G, an isotropic etch process can be performed to isotropically etch the sacrificial fill material of the sacrificial fill material layer 57L. The duration of the isotropic etch process can be selected such that the etch distance of the isotropic etch process for the sacrificial fill material is in a range from 100% to 120% of the thickness of the sacrificial fill material layer 57L. The isotropic etch process removes portions of the sacrificial fill material layer 57L that overlie the horizontal plane including the top surfaces of the vertically alternating stacks (10′, 20′), and removes portions of the sacrificial fill material layer 57L that are located inside the volumes of the laterally bulging portions 59B of the lateral isolation trenches 59. Remaining portions of the sacrificial fill material layer 57L that fill the volumes of the uniform width portions of the lateral isolation trenches 59 comprise sacrificial isolation trench fill structures 57. A two-dimensional array of sacrificial isolation trench fill structures 57 can be formed, which may include (L+1)×(M+1) sacrificial isolation trench fill structures 57. In one embodiment, the two-dimensional array of sacrificial isolation trench fill structures 57 may comprise at least a two-dimensional (L−1)×(M−1) rectangular periodic array of sacrificial isolation trench fill structures 57. The lateral dimension of the voids 79′ is expanded by the etch to form a two-dimensional array of pillar cavities 79 in the volumes of the laterally bulging portions 59B of the lateral isolation trenches 59. The two-dimensional array of pillar cavities 79 may comprise L×(M+1) rectangular periodic array of pillar cavities 79. While an embodiment is illustrated in which each pillar cavity 79 has a horizontal cross-sectional shape of a rectangle, alternative embodiments are expressly contemplated herein in which each pillar cavity 79 may have a horizontal cross-sectional shape of a rounded rectangle, an ellipse or an oval, or a circle. Generally, the maximum width of each pillar cavity 79 along the second horizontal direction hd2 is referred to as a second trench width tw2.

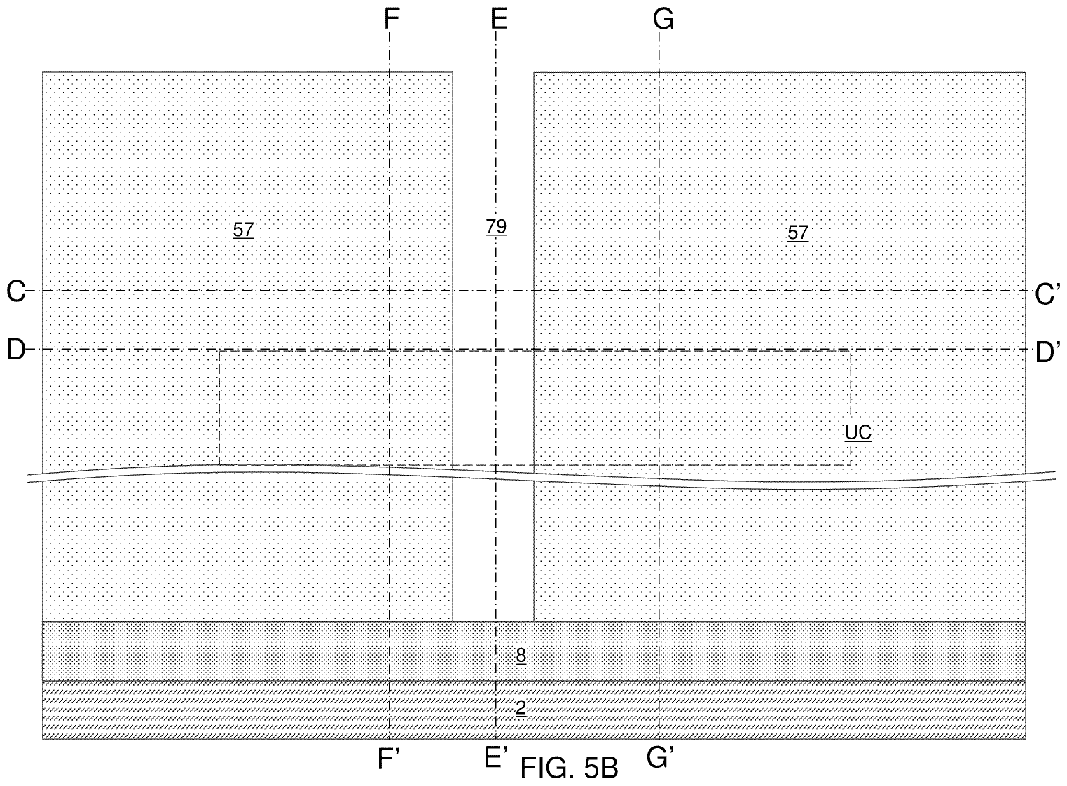

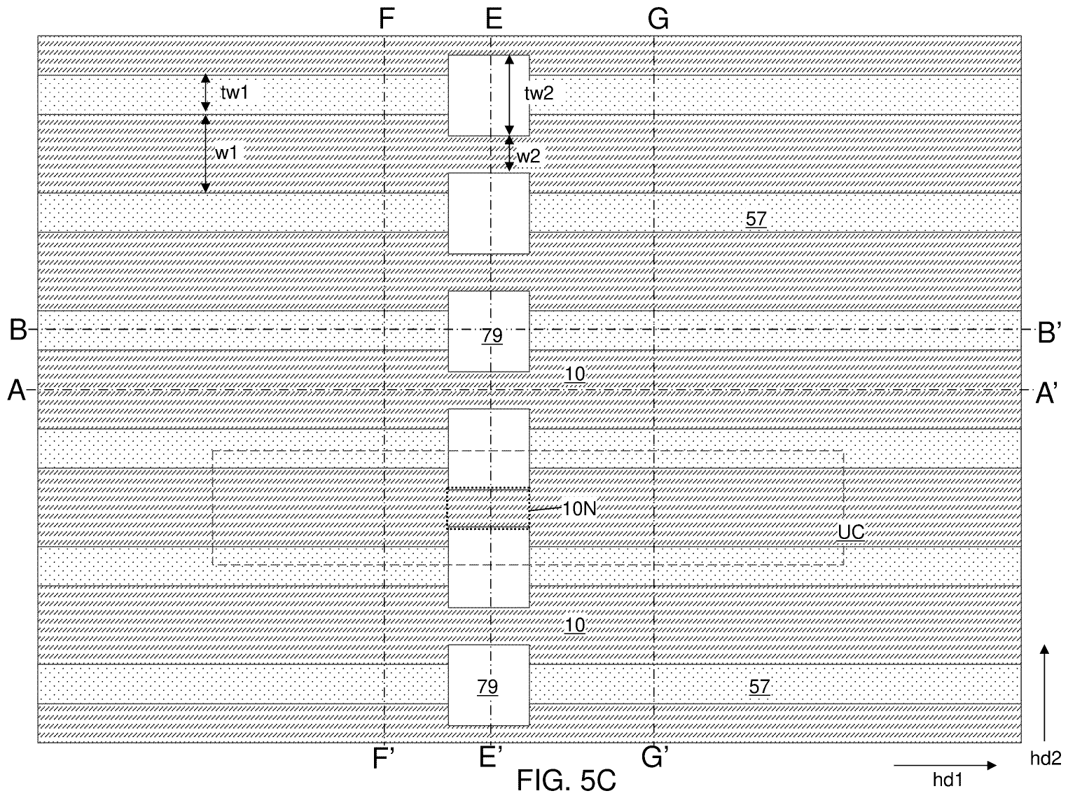

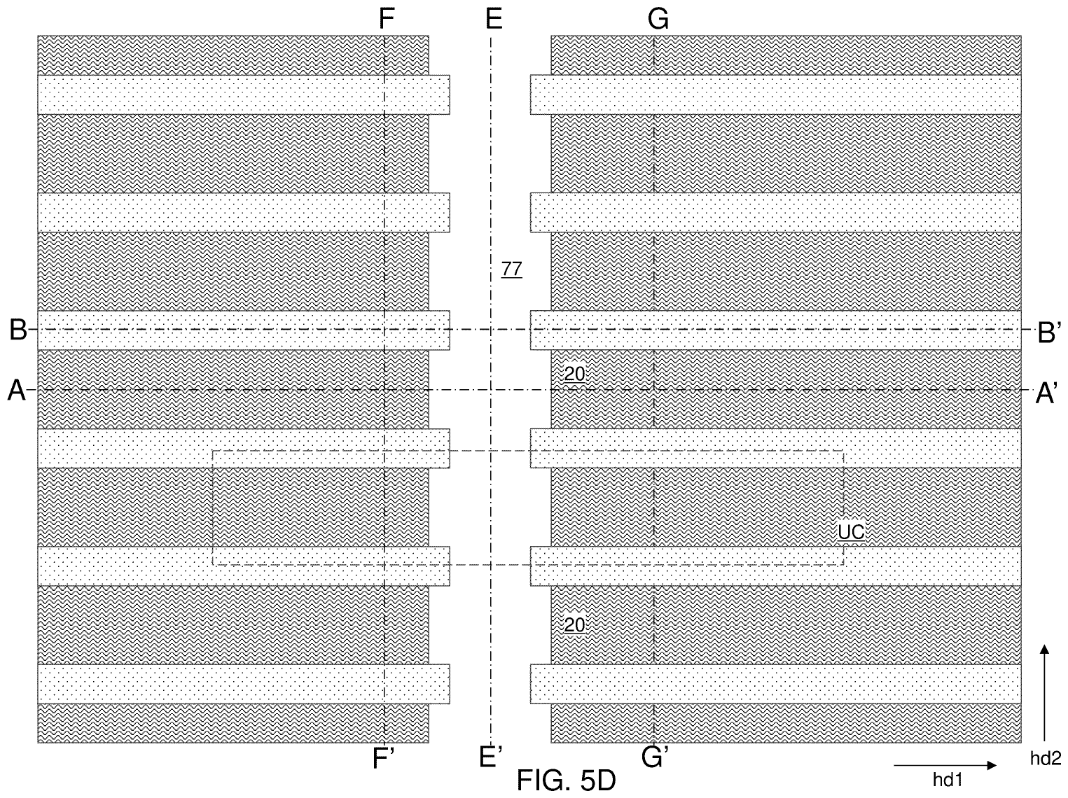

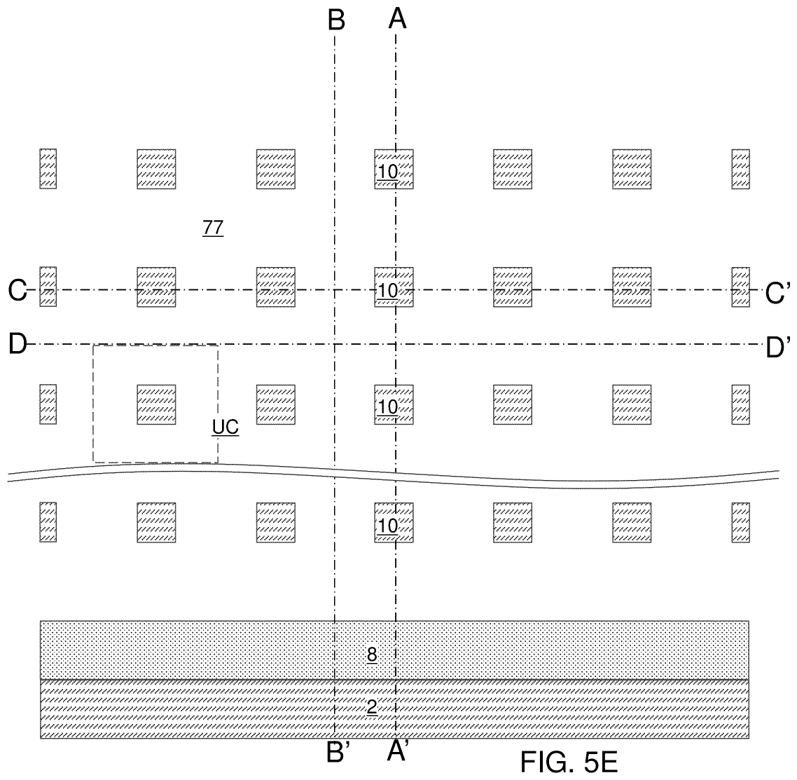

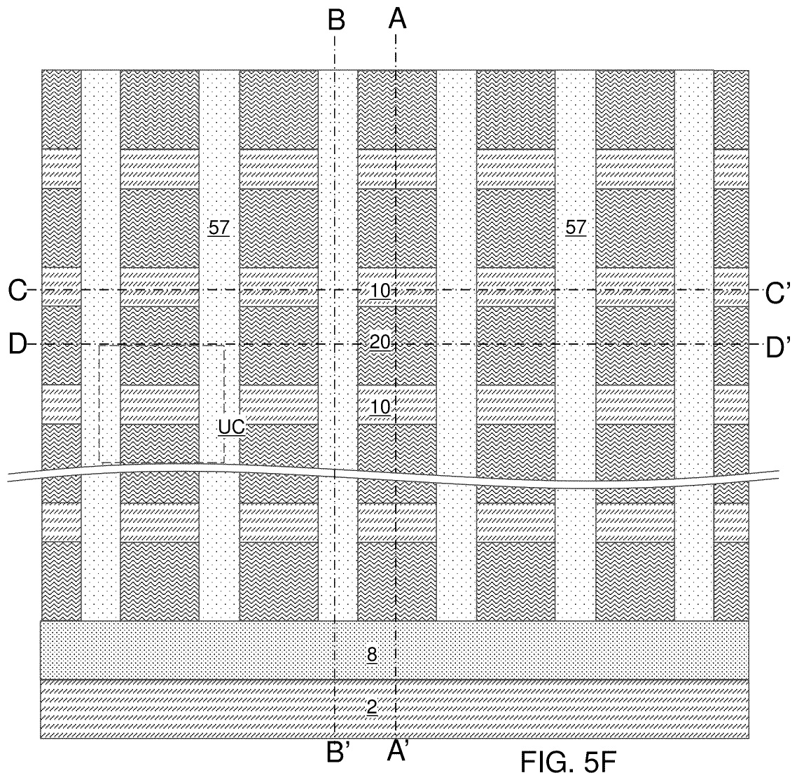

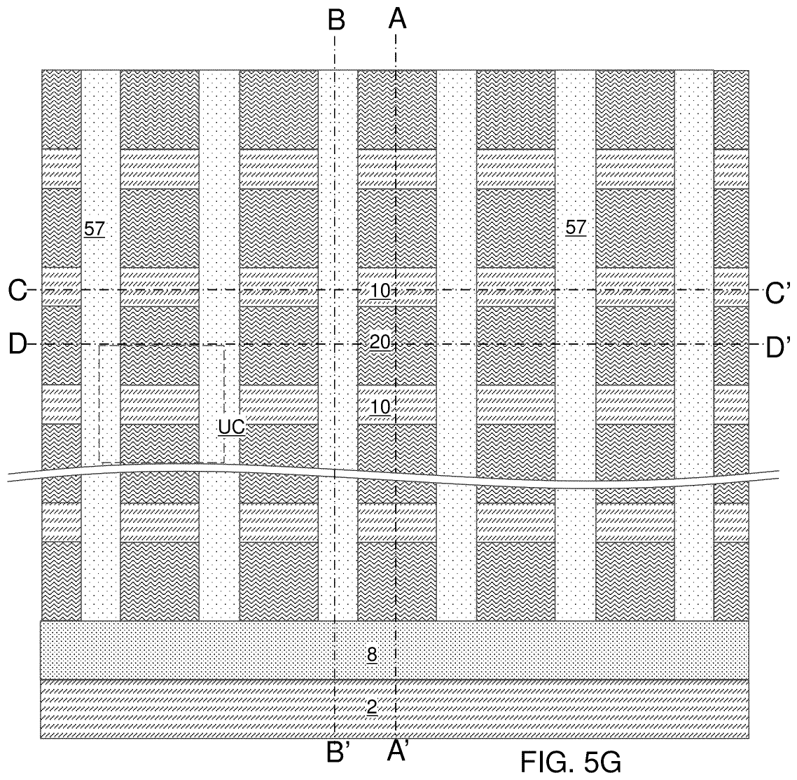

Referring to FIGS. 5A, 5B, 5C, 5D, 5E, 5F, and 5G, an isotropic etch process can be performed to isotropically etch the material of the in-process horizontally-extending sacrificial rails 20′ selectively to the materials of the in-process horizontally-extending semiconductor rails 10′ and the sacrificial isolation trench fill structures 57. For example, if the in-process horizontally-extending sacrificial rails 20′ comprise a silicon-germanium alloy and if the in-process horizontally-extending semiconductor rails 10 comprise silicon, a wet etch chemistry employing a mixture of acetic acid and hydrogen peroxide may be employed to etch portions of the in-process horizontally-extending sacrificial rails 20′ that are proximal to the pillar cavities 79. The lateral etch distance of the isotropic etch process for the material of the in-process horizontally-extending sacrificial rails 20′ is greater than one half of the second width w2. Generally, the duration of the isotropic etch process can be selected such that each column of pillar cavities 79 arranged along the second horizontal direction hd2 are merged to form a respective continuously extending cavity through which a two-dimensional (M×(N+1)) array of physically exposed portions (e.g., bridge portions) of the in-process horizontally-extending semiconductor rails 10′ laterally extend. Each such continuously extending cavity is herein referred to as a bridges-encircling cavity 77. As used herein, a bridges-encircling cavity refers to a cavity through which an array of bridge structures extends. In the instant case, an (M×(N+1)) array of portions of the in-process horizontally-extending semiconductor rails 10′ extends through each bridges-encircling cavity 77. Each bridges-encircling cavity 77 has a volume of a planar wall including (M×(N+1)) perforations therethrough. Physically exposed surfaces of each in-process horizontally-extending semiconductor rail 10′ includes surfaces of neck portions 10N of the in-process horizontally-extending semiconductor rail 10′ having the second width w2, and surfaces of uniform-width portions of the in-process horizontally-extending semiconductor rail 10′ having the first width w1 and proximal to the neck portions 10N, as shown in FIG. 5C.

Each in-process horizontally-extending sacrificial rail 20′ is divided into a plurality of horizontally-extending sacrificial rails 20 that are laterally spaced apart among one another by the bridges-encircling cavities 77. In one embodiment, a three-dimensional (L+1)×M×(N+2) array of sacrificial rails 20 may be formed. The three-dimensional (L+1)×M×(N+2) array of sacrificial rails 20 may comprise at least a two-dimensional (L−1)×M×N periodic array of sacrificial rails 20.

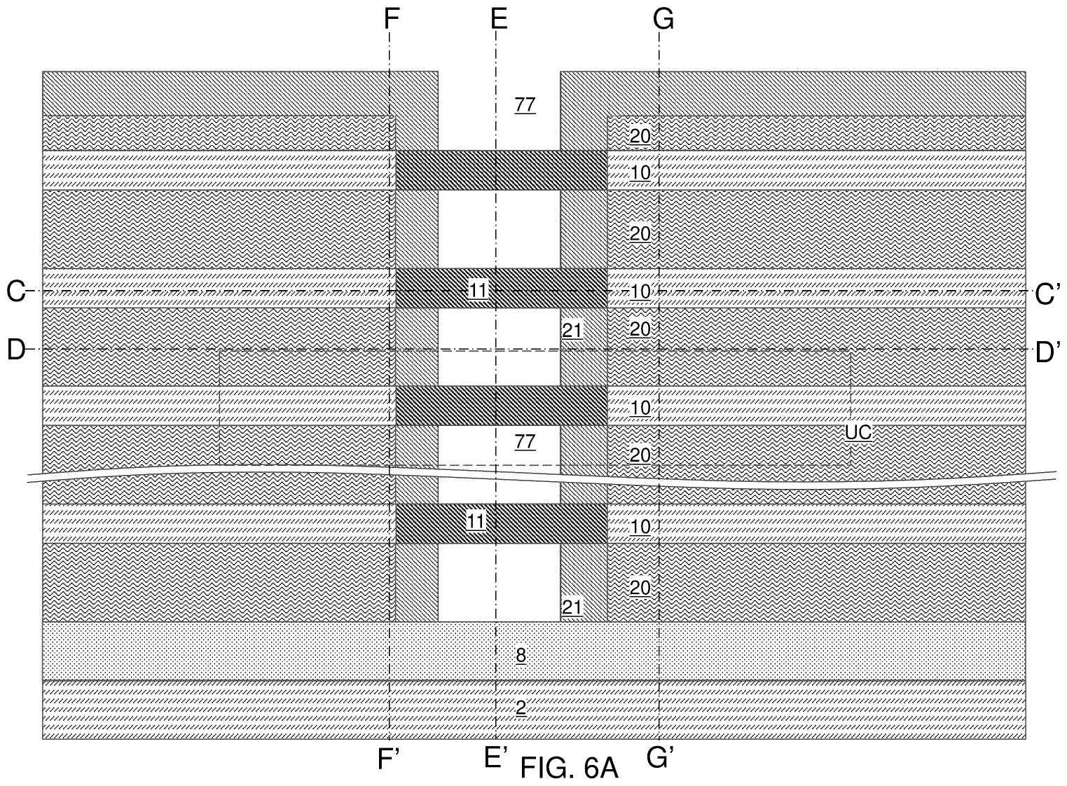

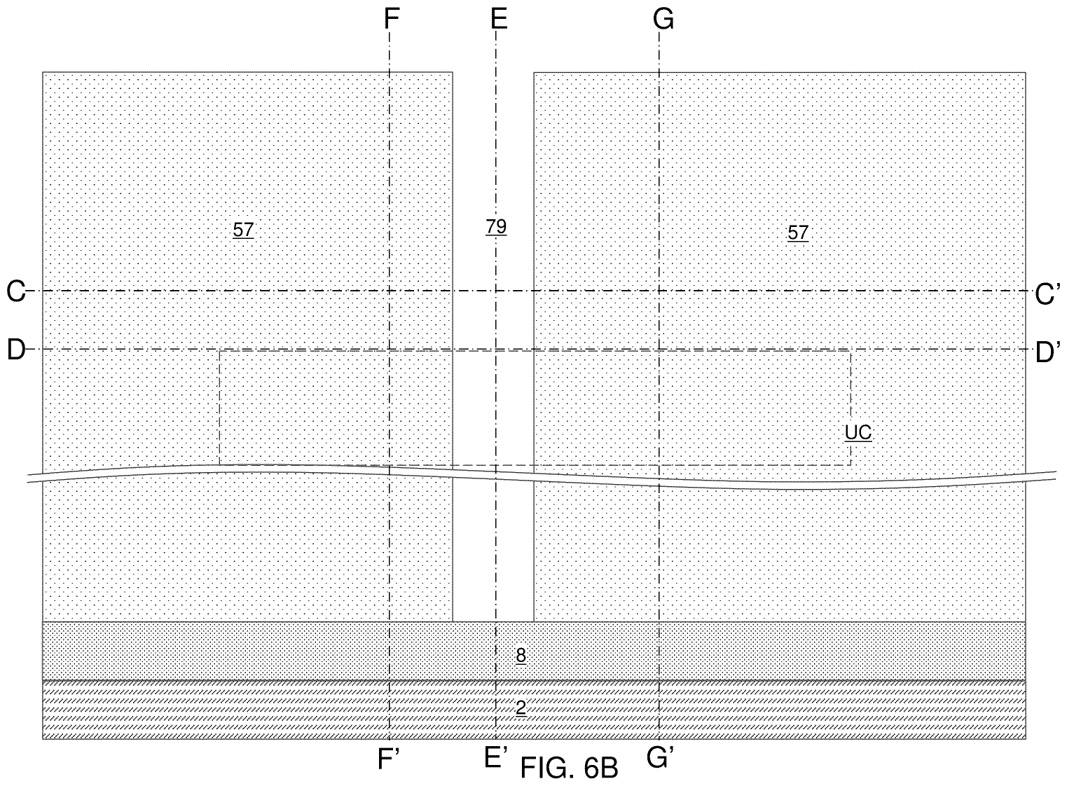

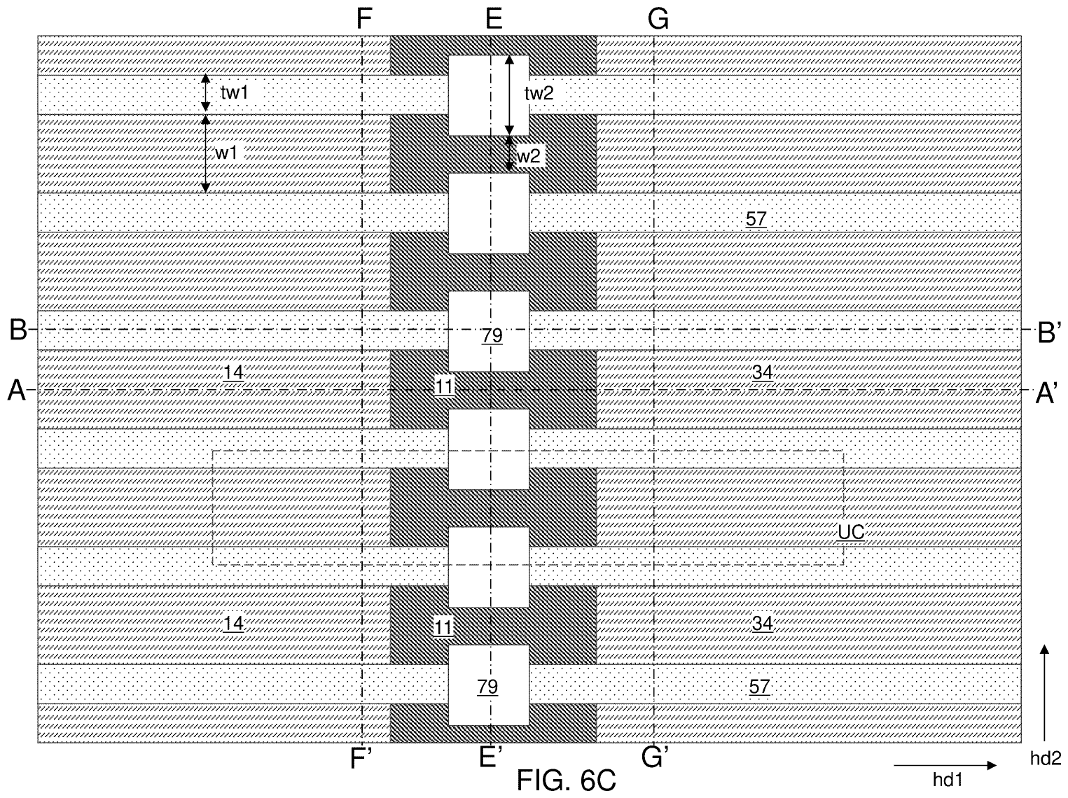

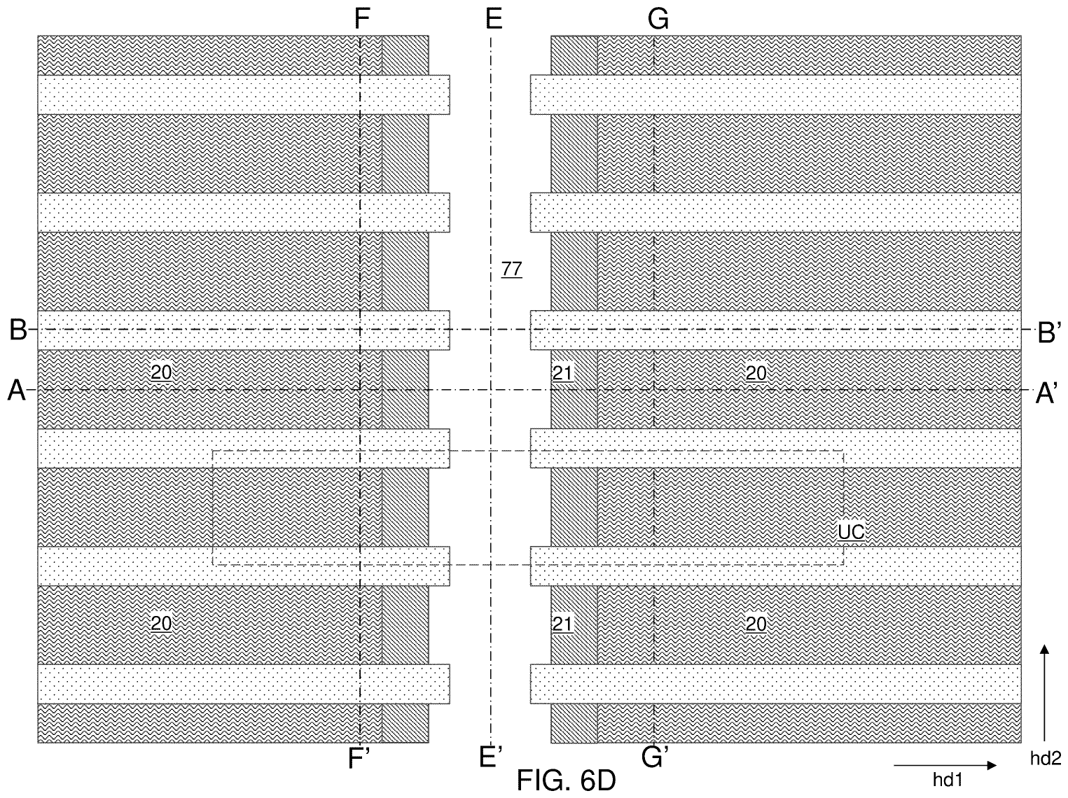

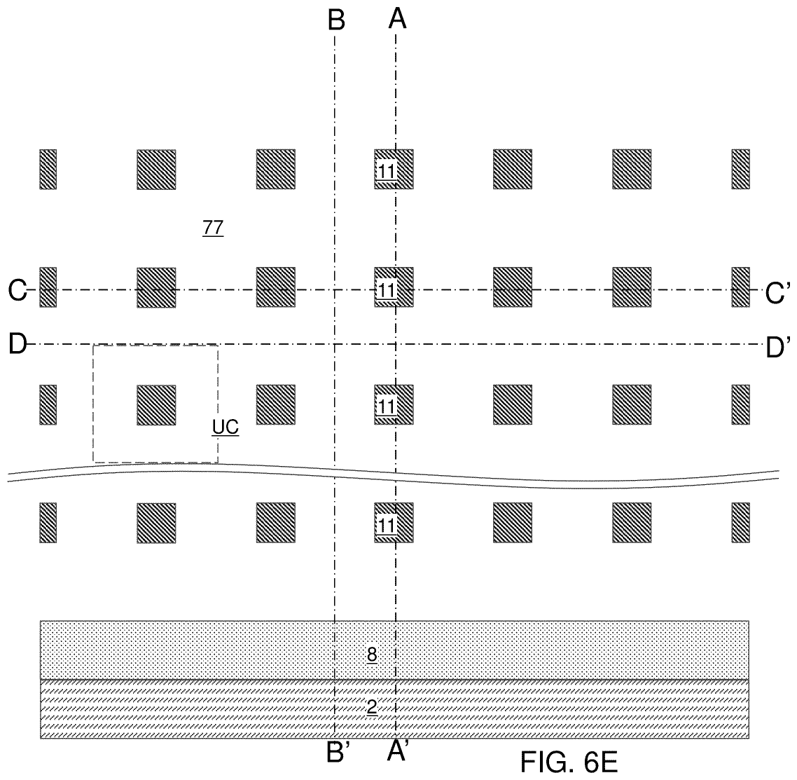

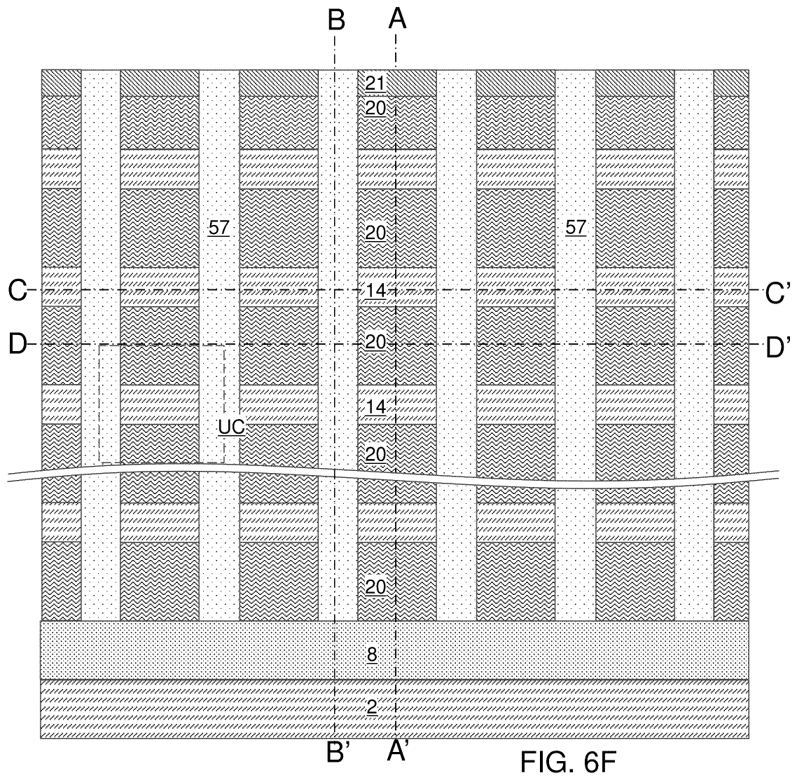

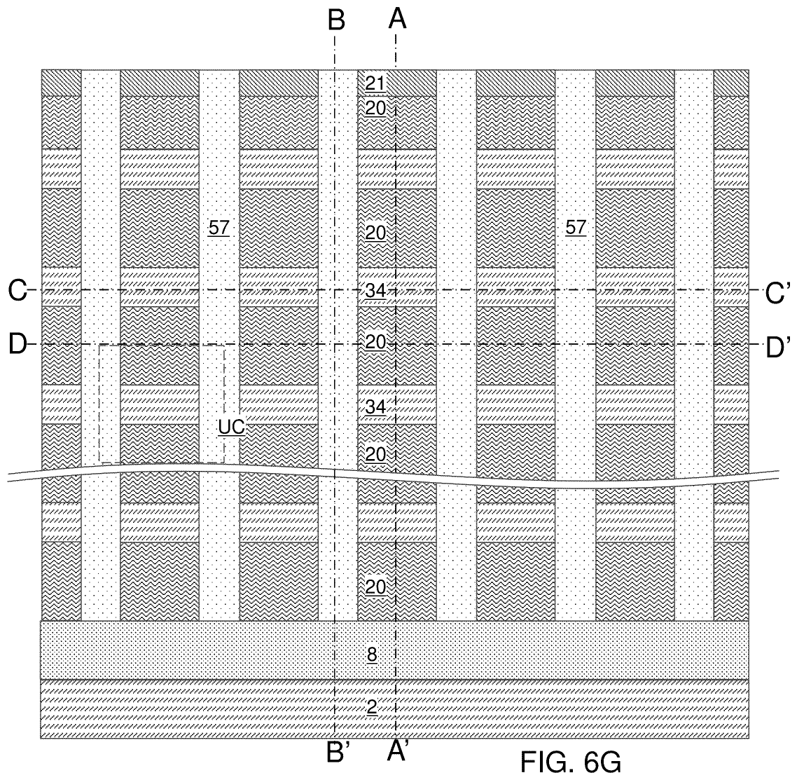

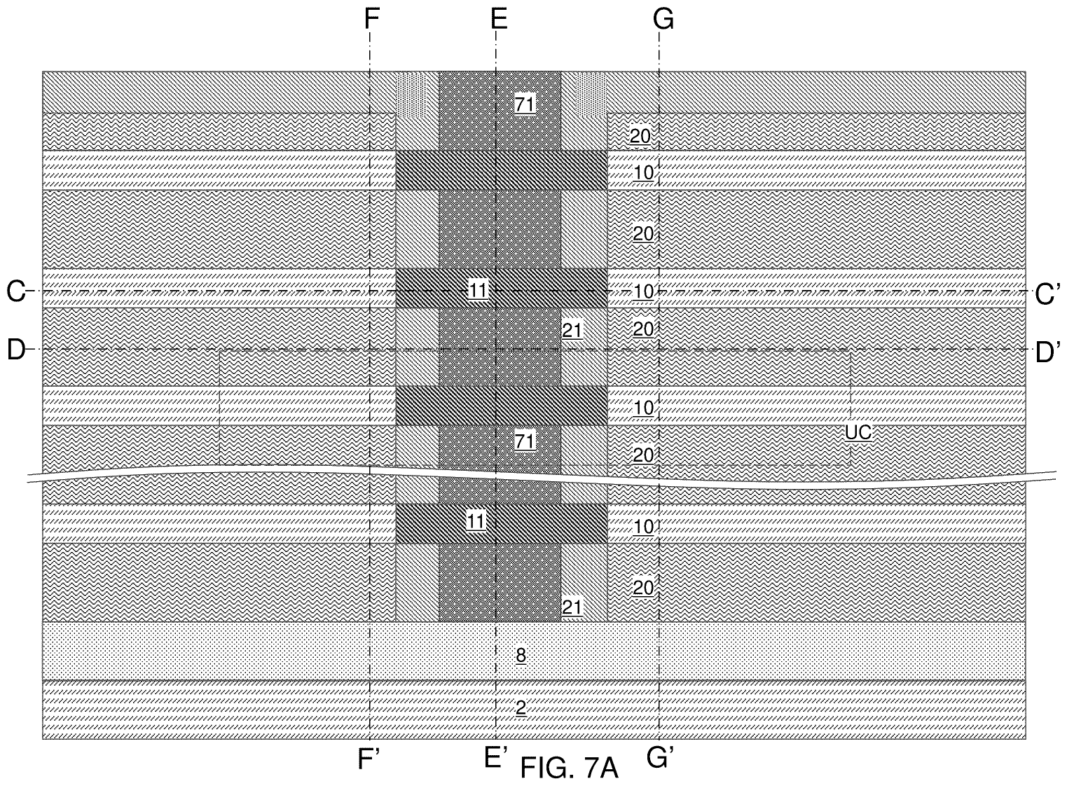

Referring to FIGS. 6A, 6B, 6C, 6D, 6E, 6F, and 6G, an isotropic doping process can be performed to introduce dopants into portions of the in-process horizontally-extending semiconductor rails 10′ that are proximal to the physically exposed surfaces of the in-process horizontally-extending semiconductor rails 10′. The physically exposed surface of the in-process horizontally-extending semiconductor rails 10′ are exposed to a respective one of the bridges-encircling cavities 77. The isotropic doping process may comprise a gas phase doping process, or a thermal dopant diffusion process employing a conformal sacrificial doped silicate glass layer that contains dopant species such as phosphorus, arsenic, or boron. Alternatively, a plasma doping process may be employed to dope the physically exposed surface of the in-process horizontally-extending semiconductor rails 10′ with electrical dopants.

If a gas phase doping process is employed, a hydride gas of a dopant species, such as diborane, phosphine, or arsine, may be employed as a dopant source gas. The process temperature at which the physically exposed surfaces of the in-process horizontally-extending semiconductor rails 10′ are exposed to the hydride gas of the dopant species may be in a range from 850 degrees Celsius to 1,000 degrees Celsius.

If a thermal dopant diffusion process is employed, an arsenosilicate glass layer, a phosphosilicate glass layer, or a borosilicate glass layer may be employed as the conformal sacrificial doped silicate glass layer. In this case, first exemplary structure can be annealed at an elevated temperature (for example, a temperature in a range from 800 degrees Celsius to 950 degrees Celsius) to induce outdiffusion of dopant atoms from the conformal sacrificial doped silicate glass layer after deposition of the conformal sacrificial doped silicate glass layer. Subsequently, the conformal sacrificial doped silicate glass layer may be removed by performing an isotropic selective etch process (such as a timed wet etch process employing dilute hydrofluoric acid).

Proximal portions of the horizontally-extending semiconductor rails 10 (e.g., the neck regions 10N and adjacent portions to the neck regions) around the bridges-encircling cavities 77 (which include the volumes of the laterally bulging portions of the lateral isolation trenches 59) are converted into a three-dimensional array of doped semiconductor material portions 11 by diffusing electrical dopants therein. The electrical dopants may comprise p-type dopants or n-type dopants. The doped semiconductor material portions 11 have a higher doping concentration than that of the first and second horizontally-extending semiconductor channels (14, 34). The average atomic concentration of the electrical dopants in the doped semiconductor material portions 11 may be in a range from 1×10¹⁸/cm³ to 5×10²⁰/cm³ such as from 3×10¹⁹/cm³ to 2×10²⁰/cm³, although lesser and greater average atomic concentrations may also be employed. Each unit cell UC comprises a first portion of an in-process horizontally-extending semiconductor rail 10′ that adjoins a doped semiconductor material portion 11, which is subsequently employed as a horizontally-extending semiconductor channel 14. Each unit cell UC comprises a second portion of the in-process horizontally-extending semiconductor rail 10′ that adjoins the doped semiconductor material portion 11, which is subsequently employed as a horizontally-extending semiconductor beam 34.

The horizontally-extending semiconductor beam 34 may have the same material composition as the first horizontally-extending semiconductor channel 14. The doped semiconductor material portion 11 is in contact with the horizontally-extending semiconductor channel 14 and in contact with the horizontally-extending semiconductor beam 34. The doped semiconductor material portion 11 may have the same conductivity type (i.e., the same doping type) or an opposite conductivity type (i.e., opposite doping type) relative to the channel 14 and the beam 34. If the doped semiconductor material portion 11 has the opposite conductivity type to that of the channel and the beam (14, 34), then a first p-n junction can be formed at the interface between the horizontally-extending semiconductor channel 14 and the doped semiconductor material portion 11, and a second p-n junction can be formed at the interface between the horizontally-extending semiconductor beam 34 and the doped semiconductor material portion 11. Within each of the unit cells UC, the horizontally-extending semiconductor channel 14 and the horizontally-extending semiconductor beam 34 laterally extend along a first horizontal direction hd1. A width (such as the second width w2) of a center segment of the doped semiconductor material portion 11 along a second horizontal direction hd2 that is perpendicular to the first horizontal direction hd1 is less than a width (such as the first width w1) of the horizontally-extending semiconductor channel 14 along the second horizontal direction hd2. Within each of the unit cells UC, the horizontally-extending semiconductor channel 14 and the horizontally-extending semiconductor beam 34 have a first uniform vertical extent; and the doped semiconductor material portion 11 may have the same uniform vertical extent, i.e., the first uniform vertical extent (which may also be referred to as a vertical thickness or as a vertical height).

Portions of the in-process horizontally-extending sacrificial rails 20′ that are exposed to the bridges-encircling cavities 77 and surface portions of the topmost in-process horizontally-extending sacrificial rails 20′ can be collaterally doped during formation of the doped semiconductor material portions 11 to form doped sacrificial material portions 21. For example, if the in-process horizontally-extending sacrificial rails 20′ comprise a single crystalline silicon-germanium or a polycrystalline silicon-germanium, the doped sacrificial material portions 21 may comprise a doped silicon-germanium.

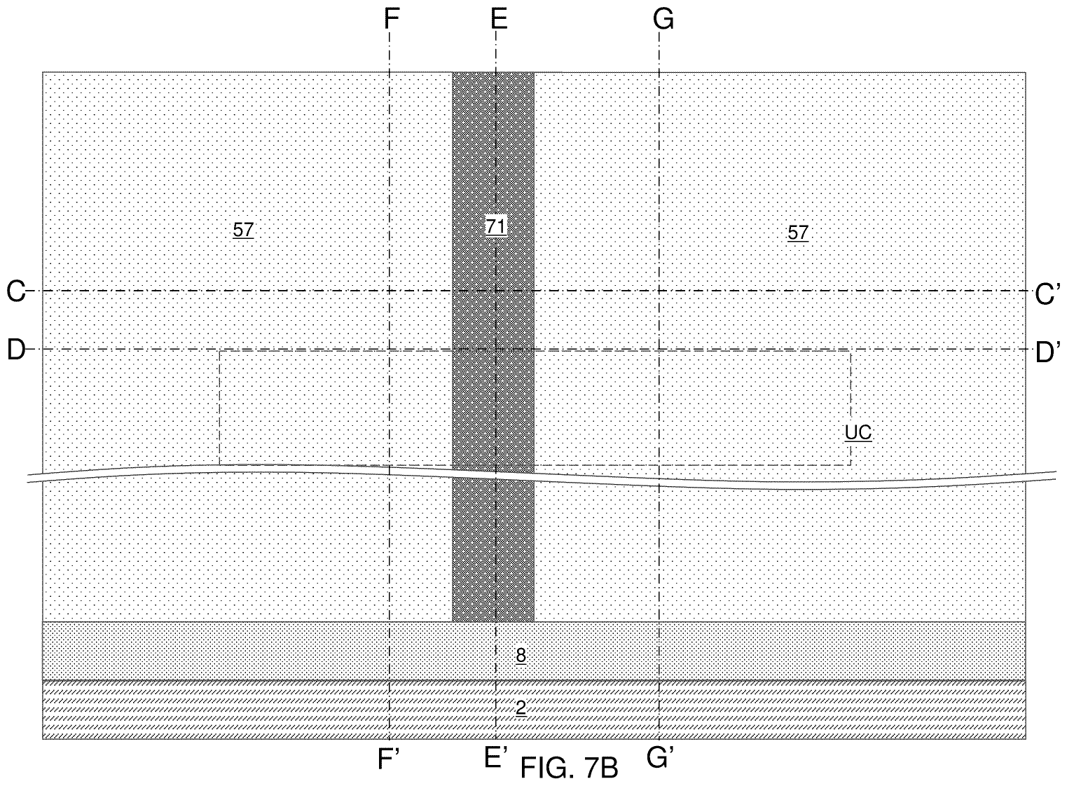

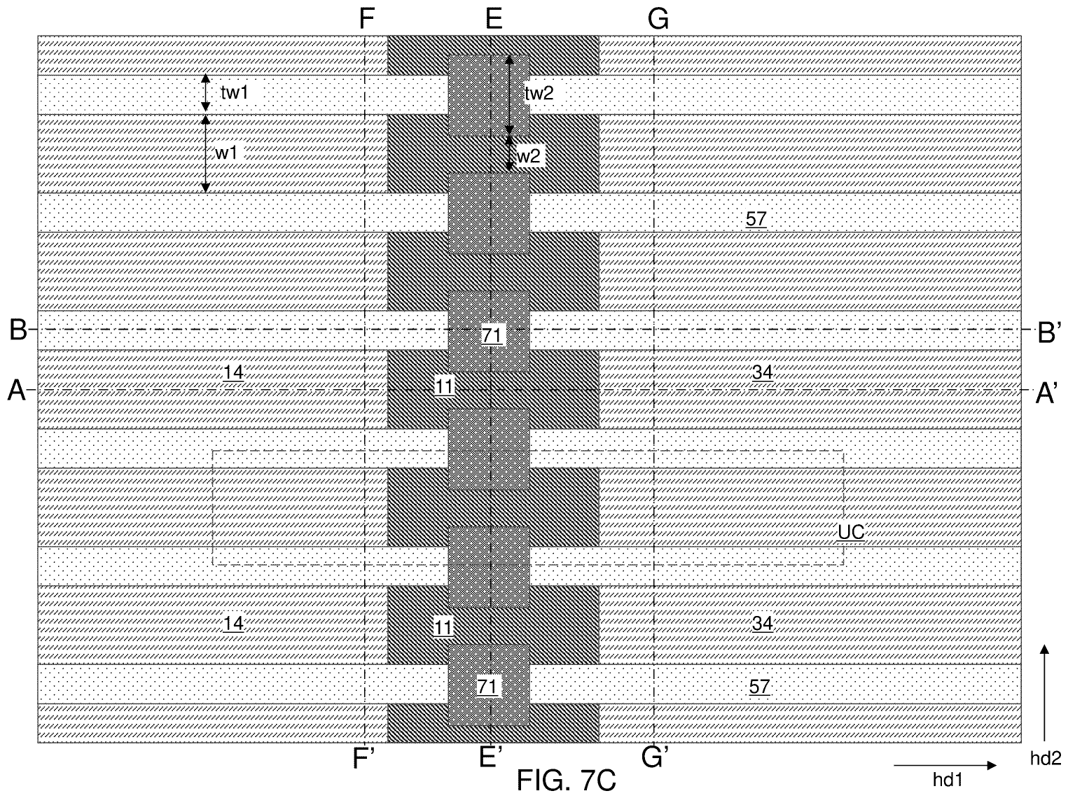

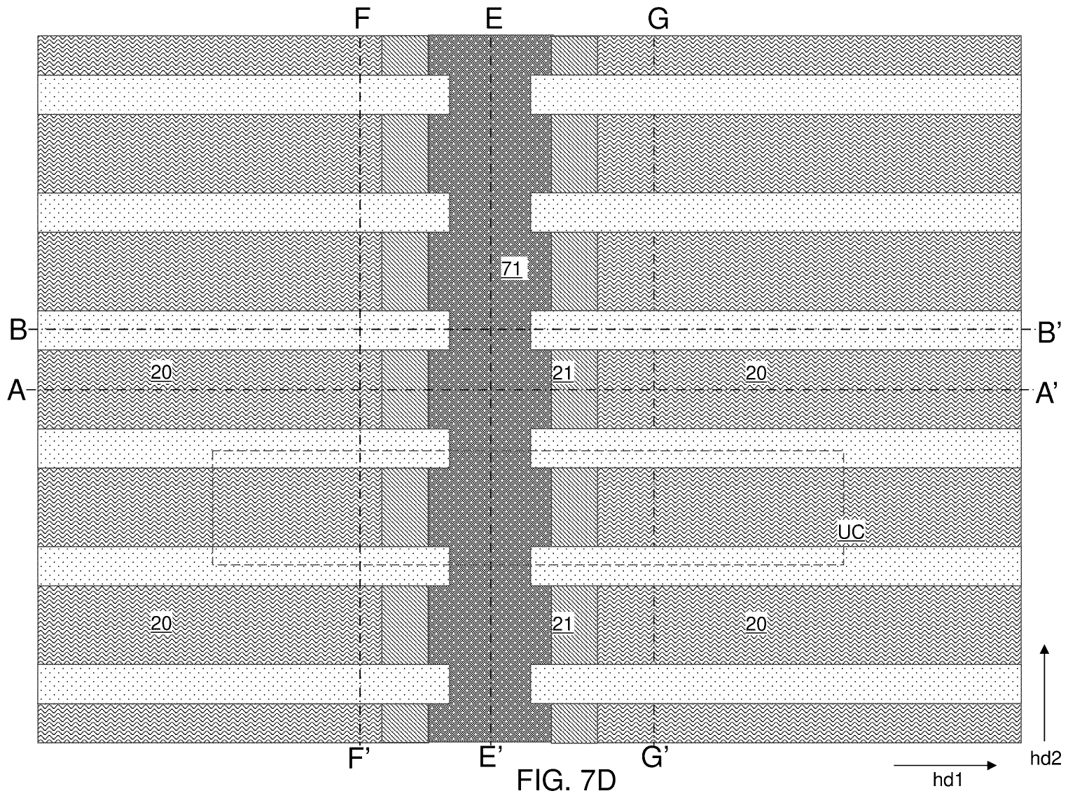

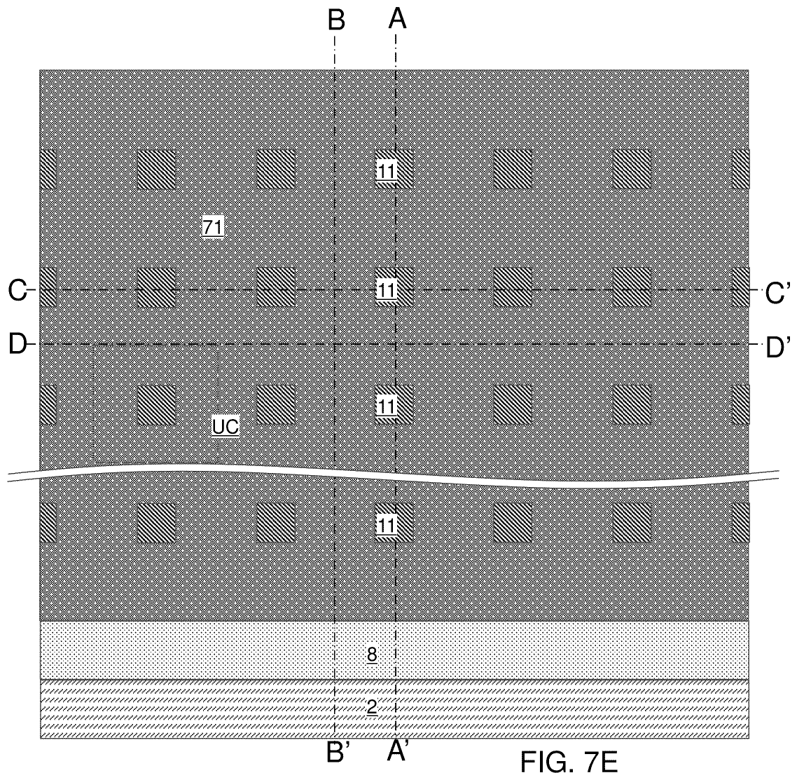

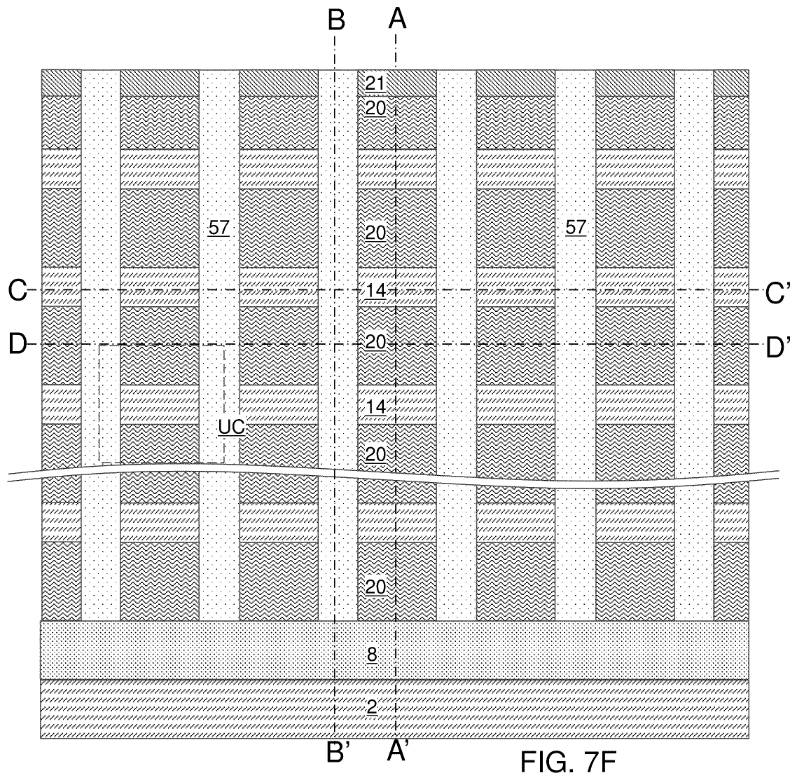

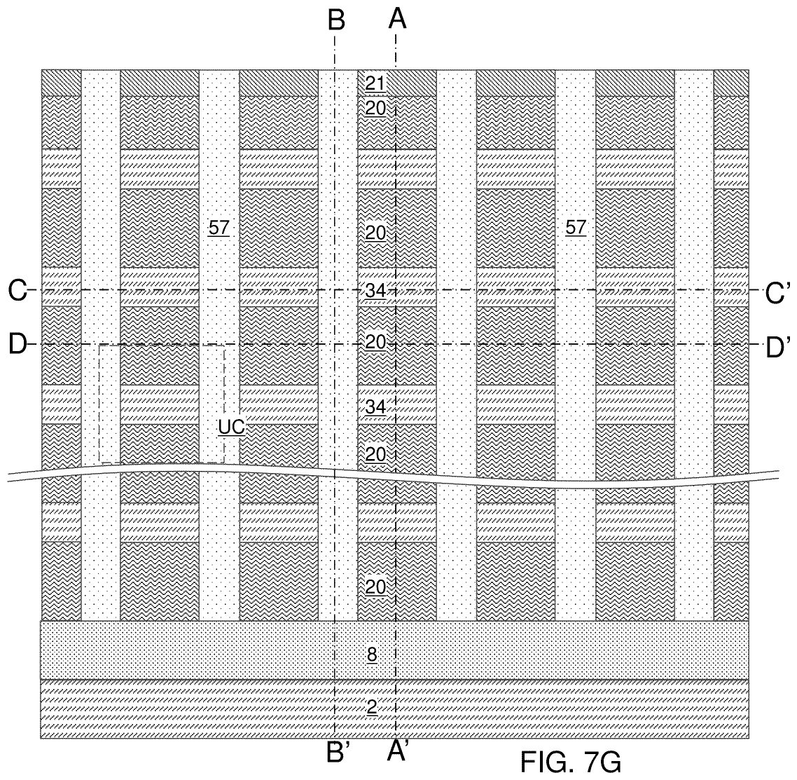

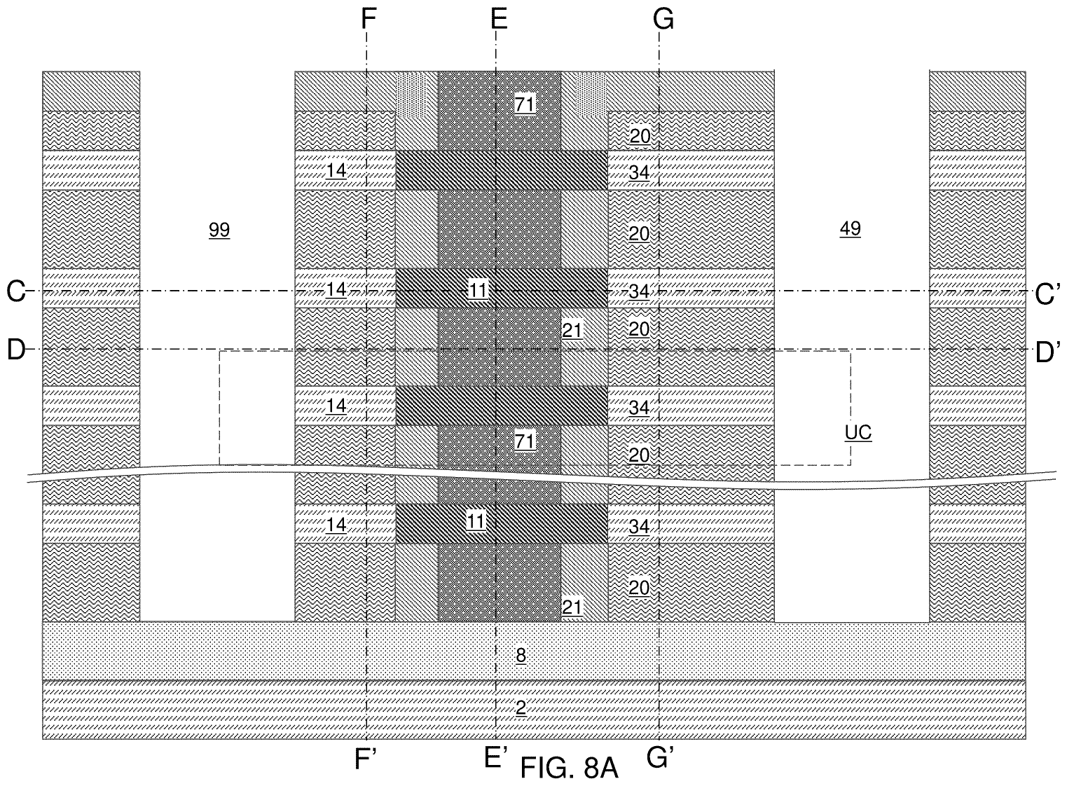

Referring to FIGS. 7A, 7B, 7C, 7D, 7E, 7F, and 7G, a sacrificial cavity fill material can be conformally deposited in the bridges-encircling cavities 77. The sacrificial cavity fill material is different from the materials of the in-process horizontally-extending semiconductor rails 10′, the sacrificial rails 20, and the sacrificial isolation trench fill structures 57. In an illustrative example, the sacrificial cavity fill material may comprise silicon nitride, silicon carbide, silicon carbonitride, and/or a dielectric metal oxide. Excess portions of the sacrificial cavity fill material may be removed from above a horizontal plane that overlies the topmost surfaces of the in-process horizontally-extending semiconductor rails 10′ by performing a planarization process. The planarization process may comprise a chemical mechanical polishing process or a recess etch process. In some embodiments, topmost regions of the doped sacrificial material portions 21 and/or topmost portions of the sacrificial isolation trench fill structures 57 may be collaterally removed during the planarization process. Each remaining portion of the sacrificial cavity fill material that fills a respective bridges-encircling cavity 77 constitutes a sacrificial perforated wall structure 71. A one-dimensional array of sacrificial perforated wall structures 71 can be formed. In one embodiment, each of the sacrificial perforated wall structures 71 surrounds a respective two-dimensional array of doped semiconductor material portions 11 within the three-dimensional array of doped semiconductor material portions 11.

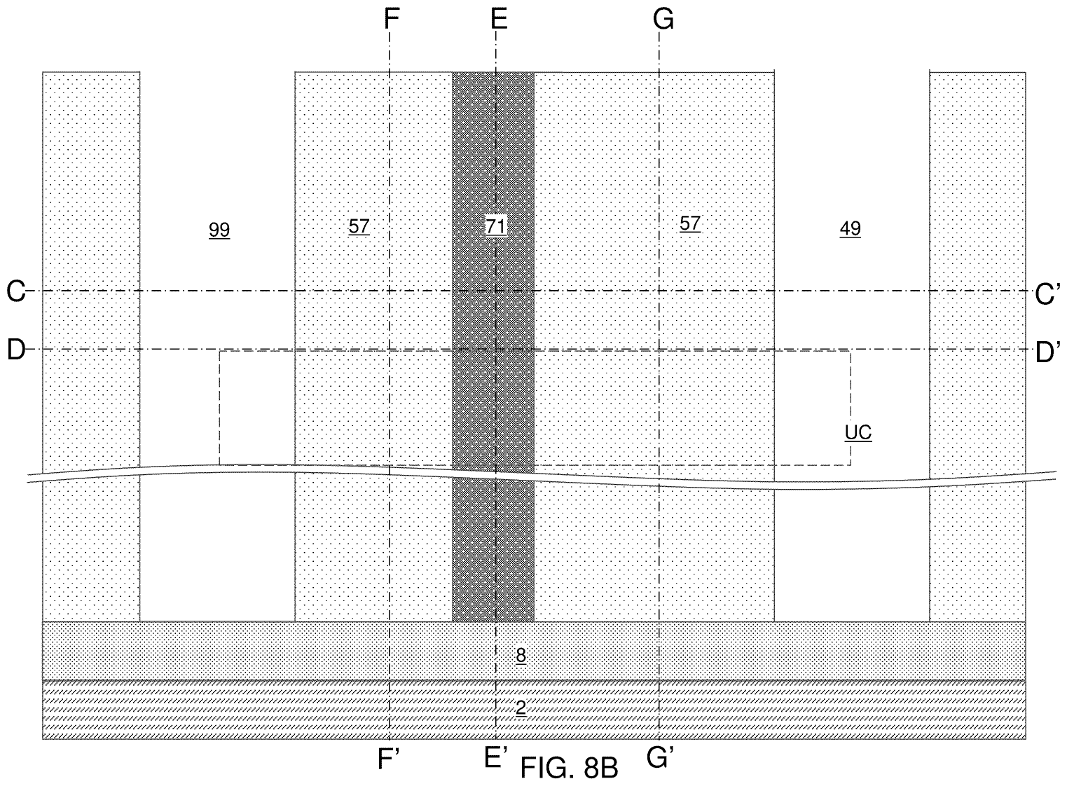

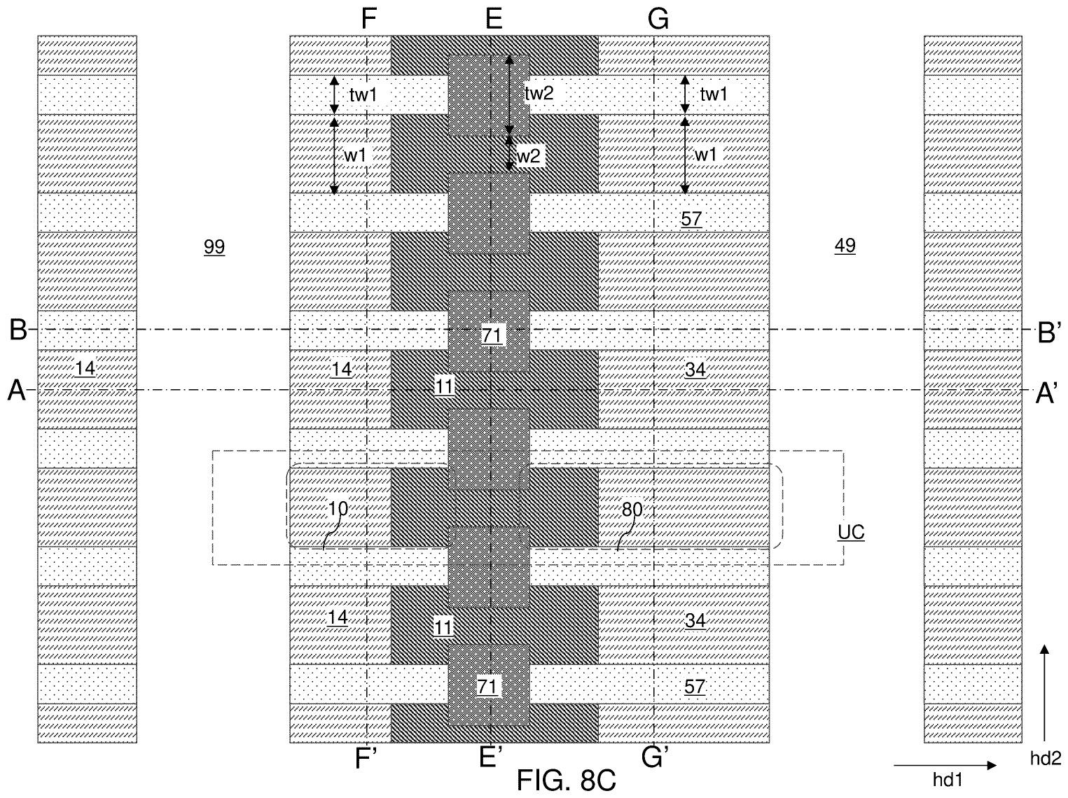

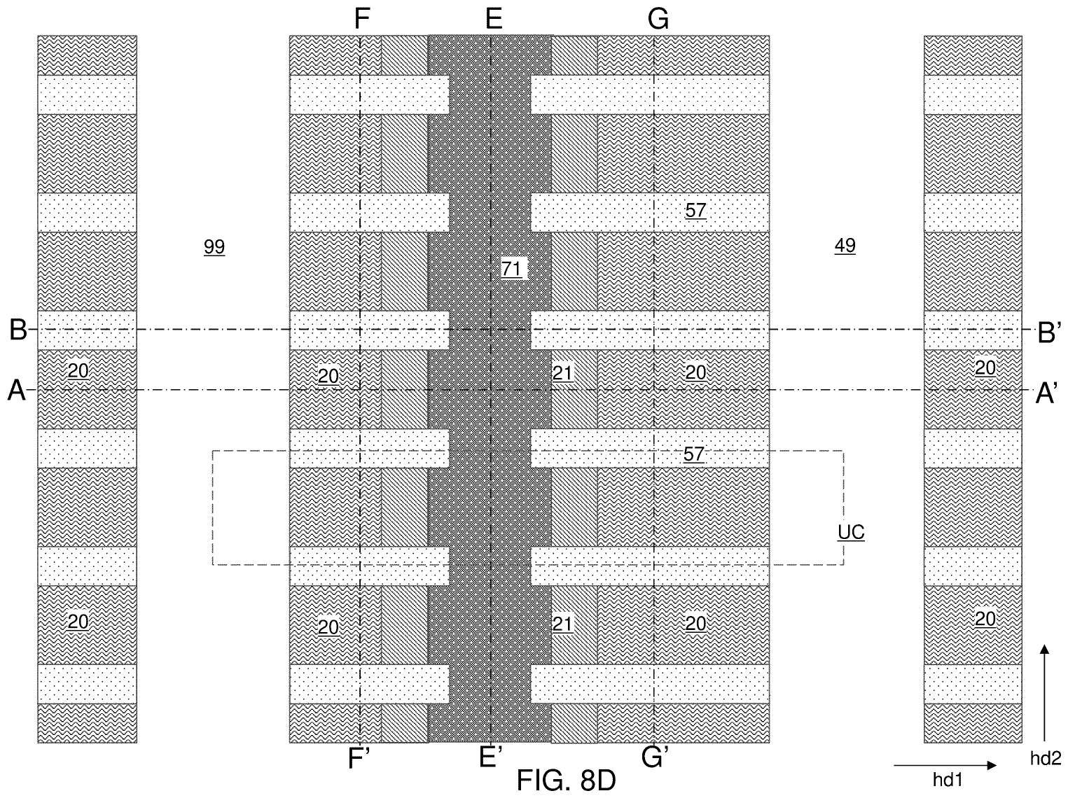

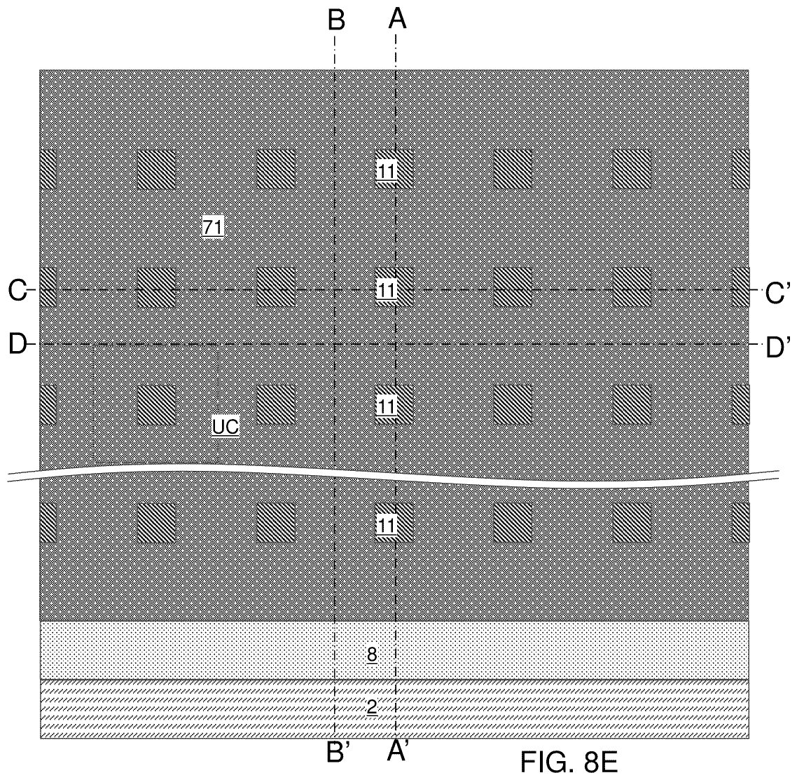

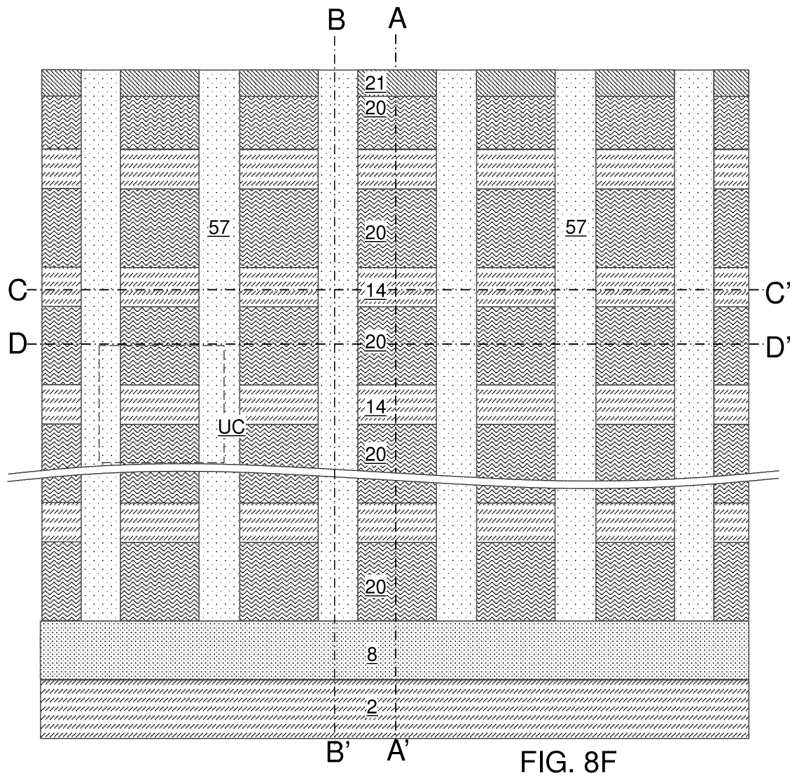

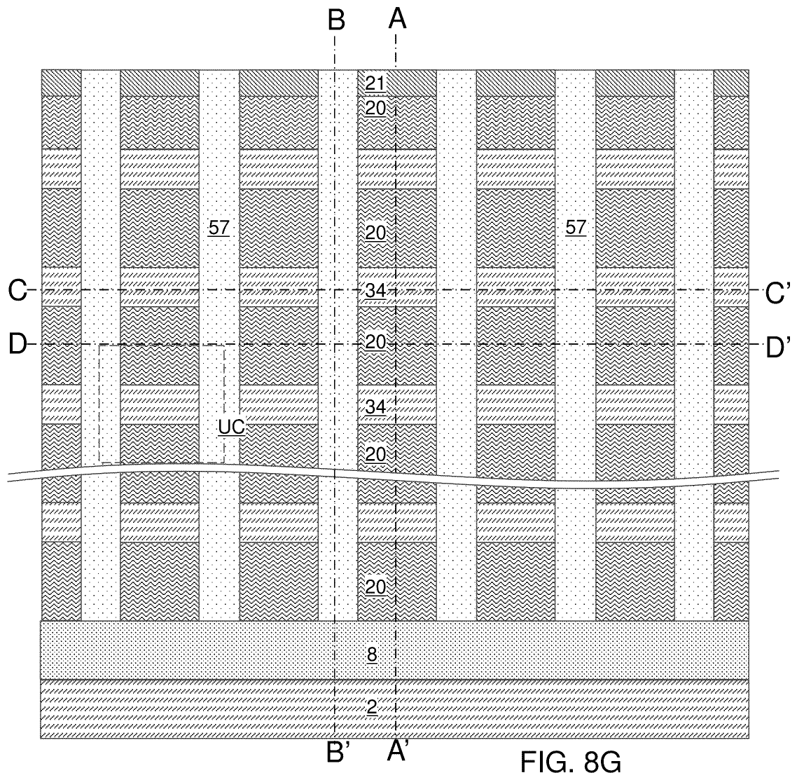

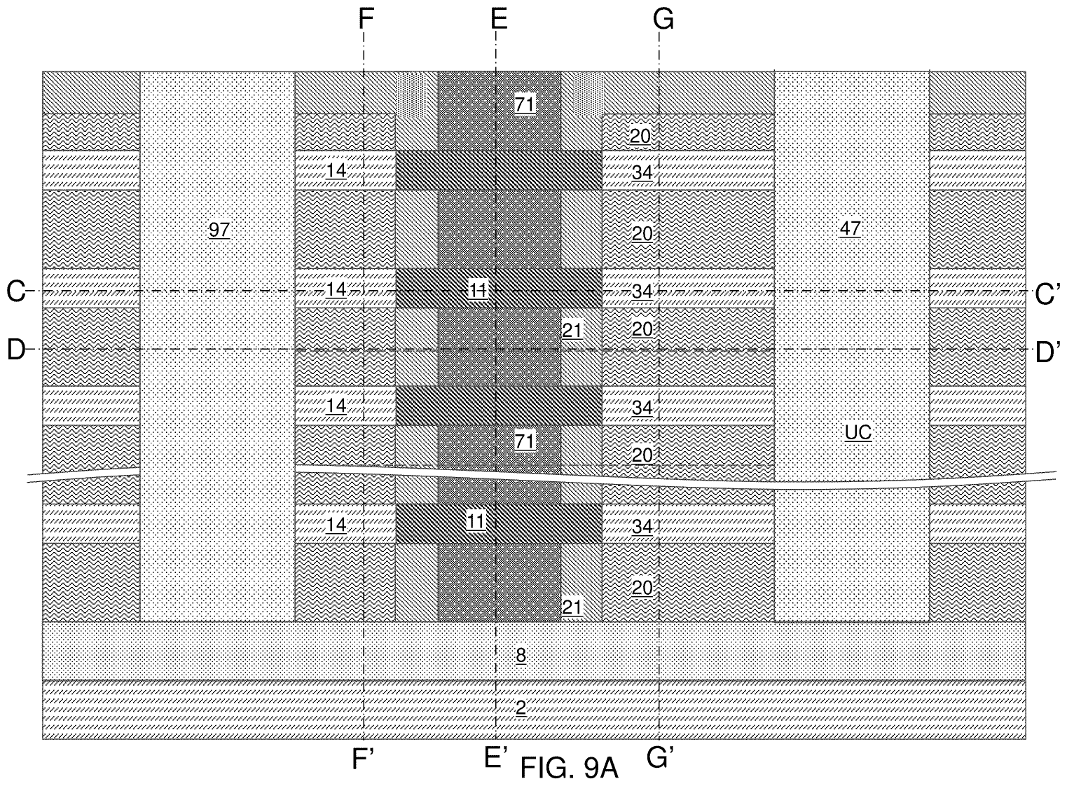

Referring to FIGS. 8A, 8B, 8C, 8D, 8E, 8F, and 8G, a photoresist layer (not shown) can be applied over an assembly of the in-process horizontally-extending semiconductor rails 10′, the sacrificial rails 20, the sacrificial isolation trench fill structures 57, and the sacrificial perforated wall structures 71, and can be lithographically patterned to form elongated openings that laterally extend along the second horizontal direction hd2. The elongated openings may have a uniform width along the first horizontal direction hd1, and are formed at boundaries of neighboring pairs of unit cells UC. An anisotropic etch process can be performed to transfer the pattern of the openings in the first photoresist layer through the assembly of the in-process horizontally-extending semiconductor rails 10′, the sacrificial rails 20, the sacrificial isolation trench fill structures 57, and the sacrificial perforated wall structures 71. Trenches (49, 99) that laterally extend along the second horizontal direction hd2 can be formed. The total number of the trenches (49, 99) may be L+1. The trenches (49, 99) may comprise a laterally alternating sequence of source trenches 49 (e.g., write-side trenches) and bit-line trenches 99 (e.g., read-side trenches) that alternate along the first horizontal direction hd1. Each of the source trenches 49 and the bit-line trenches 99 may have a respective uniform width along the first horizontal direction hd1, which may be in a range from 50 nm to 600 nm, such as from 100 nm to 400 nm, although lesser and greater widths may also be employed. The center-to-center distance between neighboring pairs of the trenches (49, 99) can be the same as the first periodicity of the three-dimensional array of unit cells UC along the first horizontal direction hd1.

The assembly of the in-process horizontally-extending semiconductor rails 10′, the sacrificial rails 20, the sacrificial isolation trench fill structures 57, and the sacrificial perforated wall structures 71 is divided into multiple divided assemblies (20A, 20B, 14, 11, 34, 21, 71). Each divided assembly may comprise an M×(N+1) two-dimensional array of horizontally-extending semiconductor channels 14, an M×(N+1) two-dimensional array of horizontally-extending semiconductor beams 34, an M×(N+1) two-dimensional array of doped semiconductor material portions 11, an M×(N+2) two-dimensional array of first-type sacrificial rails 20A, an M×(N+2) two-dimensional array of second-type sacrificial rails 20B, a 2×(M+1) array of sacrificial isolation trench fill structures 57, a sacrificial perforated wall structure 71, and doped sacrificial material portions 21. The first-type sacrificial rails 20A and the second-type sacrificial rails 20B are collectively referred to as sacrificial rails 20. The first-type sacrificial rails 20A can contact the horizontally-extending semiconductor channels 14, and the second-type sacrificial rails 20B can contact the horizontally-extending semiconductor beams 34. The multiple divided assemblies (20A, 20B, 14, 11, 34, 21, 71) are laterally spaced apart from each other by an alternating sequence of source trenches 49 and bit-line trenches 99. Each divided assembly (20A, 20B, 14, 11, 34, 21, 71) may have a respective first planar sidewall that is perpendicular to the first horizontal direction hd1 and is exposed to a respective bit-line trench 99, and a respective second planar sidewall that is perpendicular to the first horizontal direction hd1 and is exposed to a respective source trench 49. The photoresist layer can be subsequently removed, for example, by ashing. Each contiguous combination of a horizontally-extending semiconductor channel 14, a doped semiconductor material portion 11, and a horizontally-extending semiconductor beam 34 constitutes a semiconductor rail (14, 11, 34).

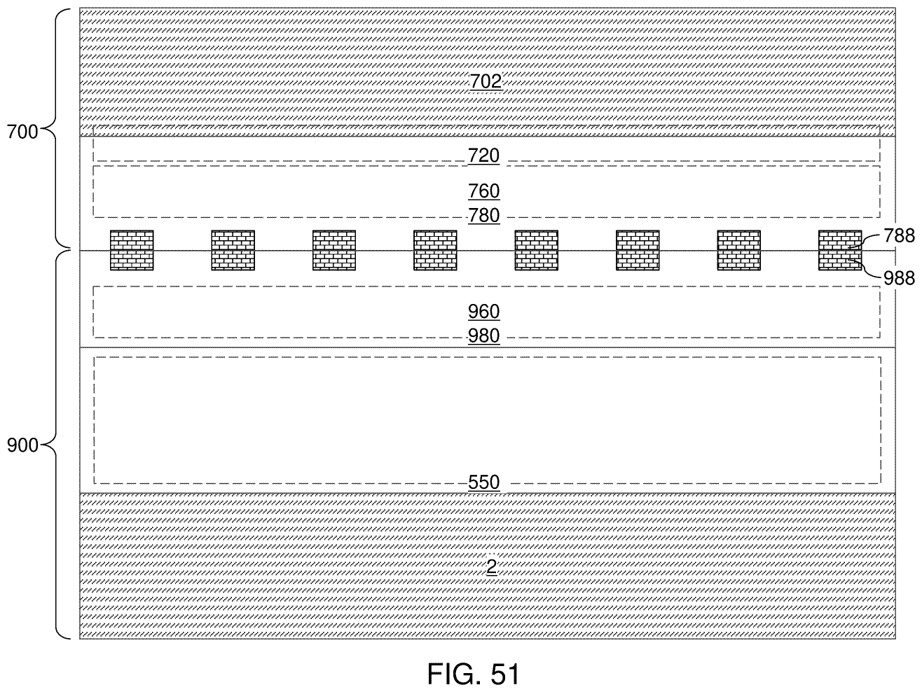

Generally, the vertically alternating stacks (10′, 20′) of in-process horizontally-extending semiconductor rail 10′ and in-process horizontally-extending sacrificial rails 20′ as formed by the processing steps described with reference to FIGS. 51A, 51B, 51C, 51D, 51E, 51F, and 51G are patterned by formation of the bit-line trenches 99 and source trenches 49. Patterned portions of the vertically alternating stacks (10′, 20′) comprise a three-dimensional array of horizontally-extending semiconductor rails 10 each containing a respective horizontally-extending semiconductor channel 14, a respective doped semiconductor material portion 11 which is a respective one of the doped semiconductor material portions 11, and a horizontally-extending semiconductor beam 34.

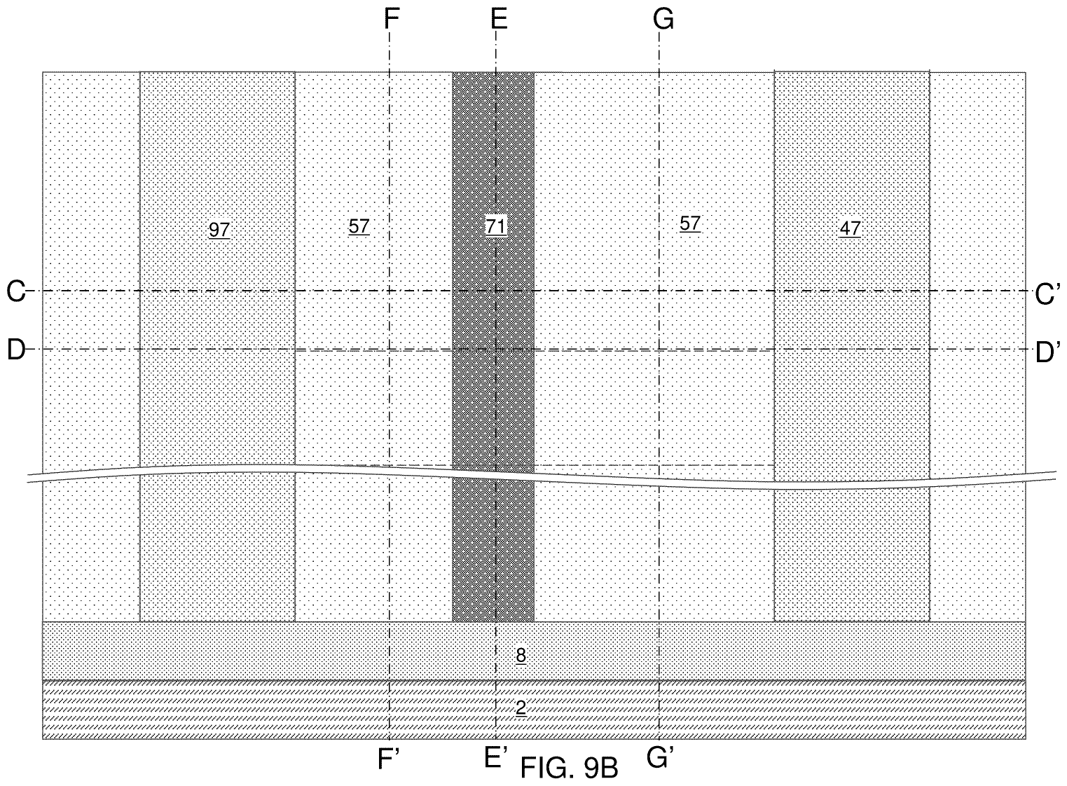

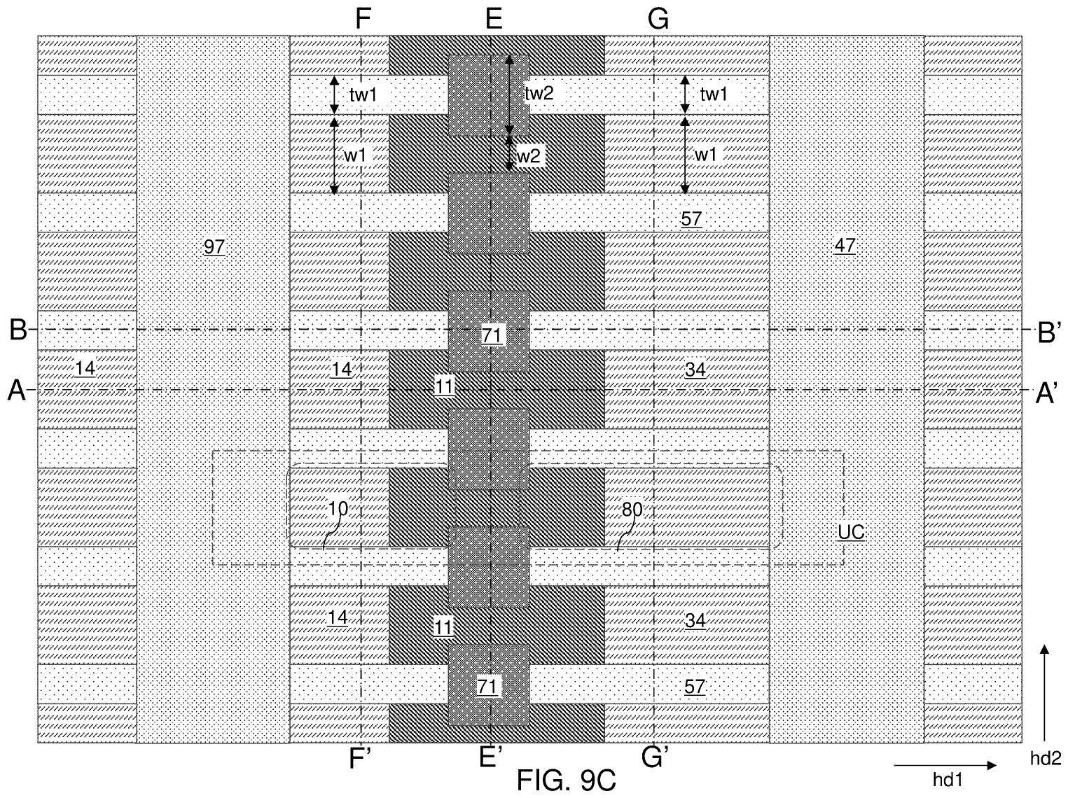

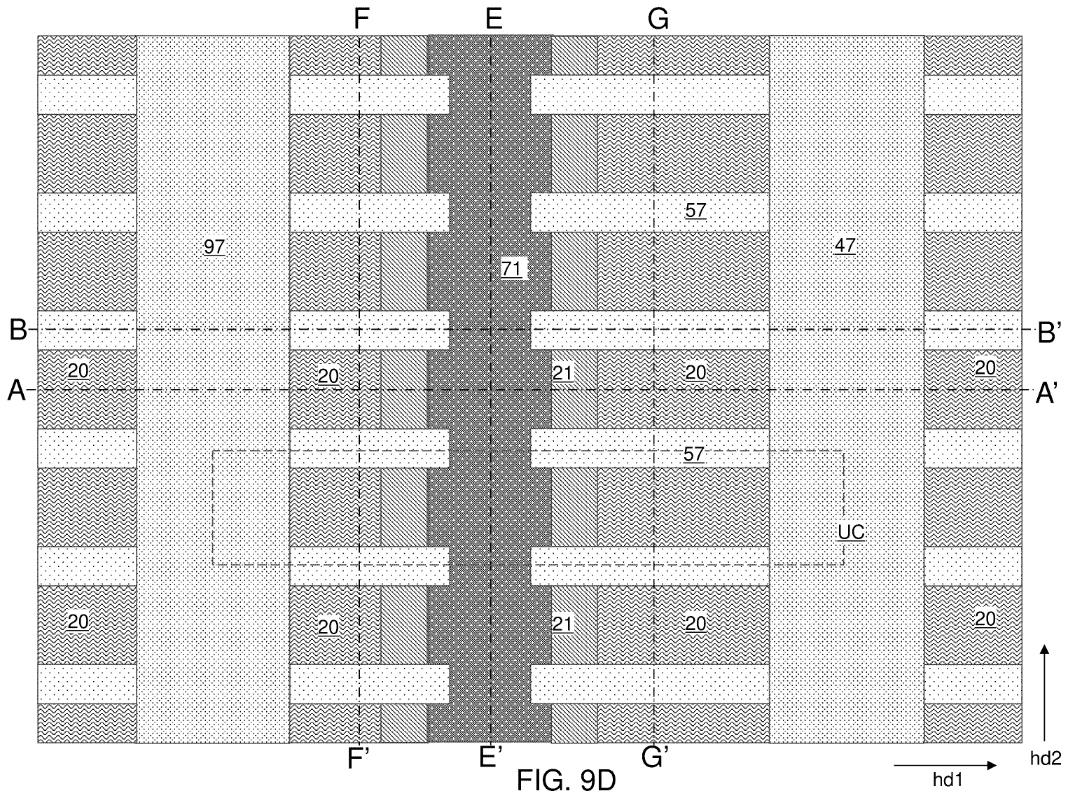

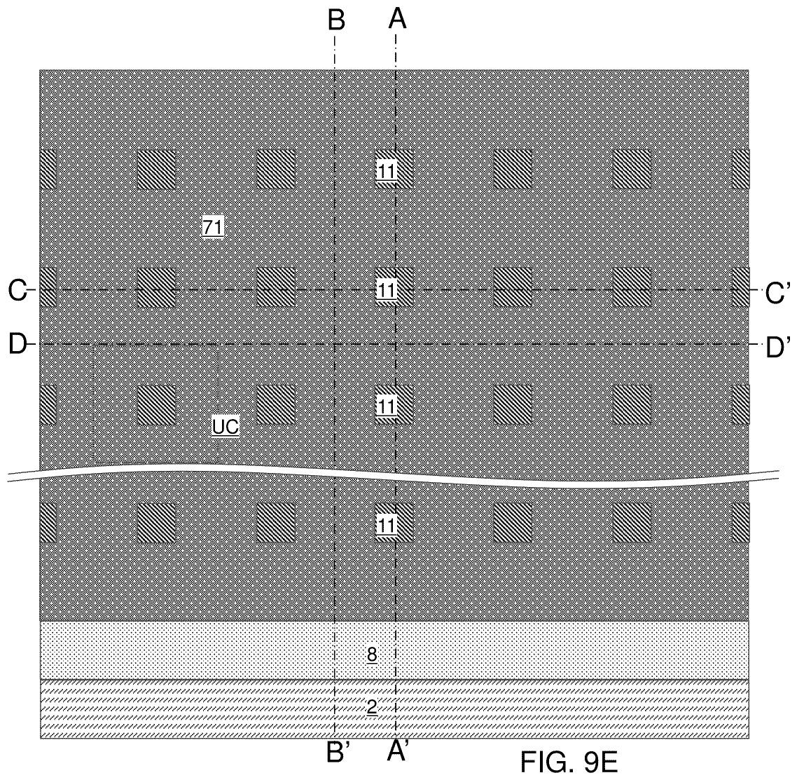

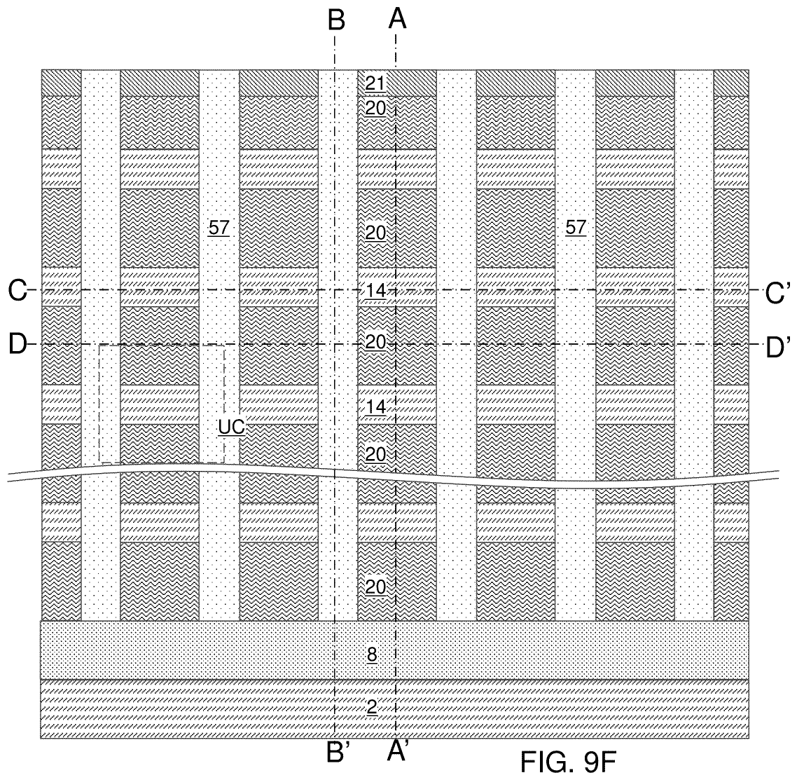

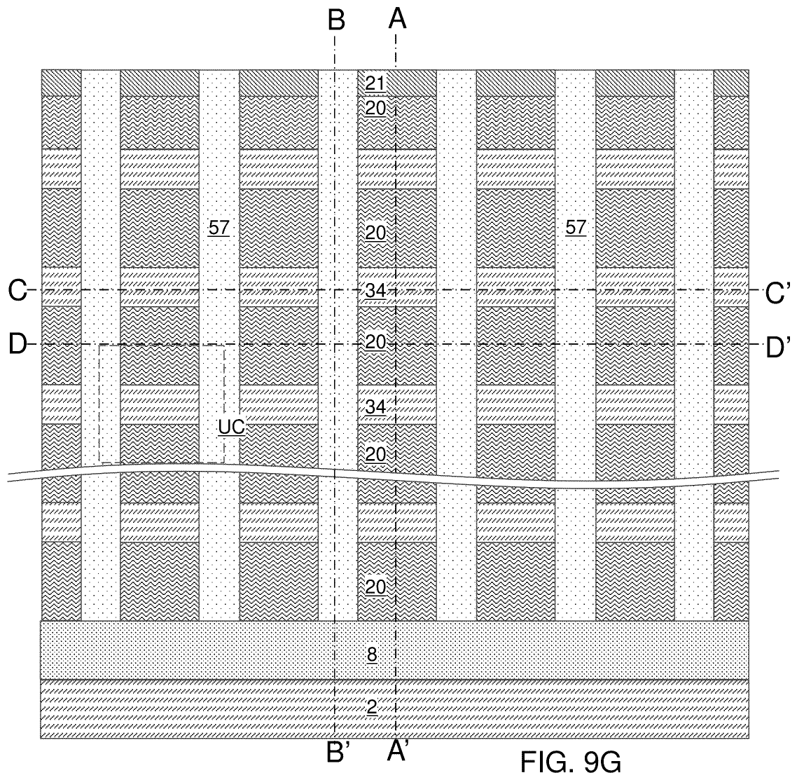

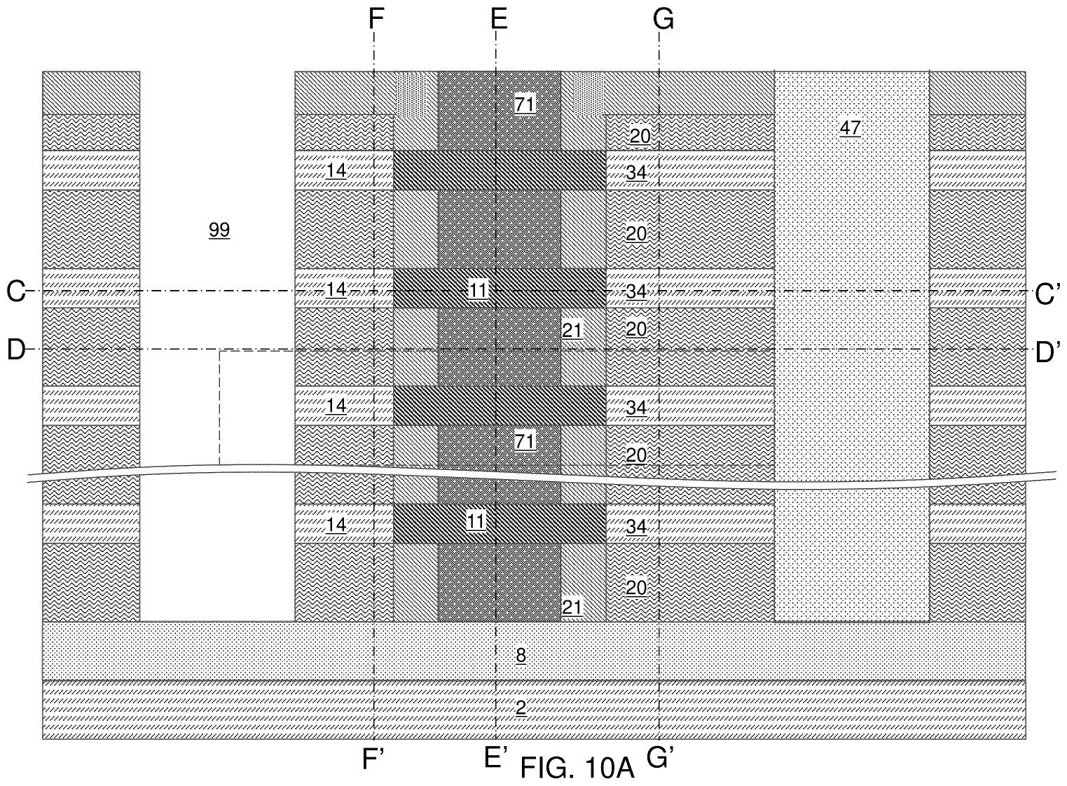

Referring to FIGS. 9A, 9B, 9C, 9D, 9E, 9F, and 9G, a sacrificial fill material can be deposited in the source trenches 49 and the bit-line trenches 99. The sacrificial fill material that is deposited at this processing step may comprise a carbon-based material (such as amorphous carbon or diamond-like carbon), organosilicate glass, silicon oxide, silicon nitride, or a polymer material. The sacrificial fill material that is deposited at this processing step may be different from or may be the same as the material of the sacrificial rails 20. Excess portions of the sacrificial fill material can be removed from above the horizontal plane including the top surfaces of the sacrificial isolation trench fill structures 57 and/or top surfaces of the sacrificial perforated wall structures 71 by a planarization process The planarization process may employ a chemical mechanical polishing process and/or a recess etch process. Each portion of the sacrificial fill material that fills a source trench 49 constitutes a sacrificial source trench fill structure 47. Each portion of the sacrificial fill material that fills a bit-line trench 99 constitutes a sacrificial bit-line trench fill structure 97.

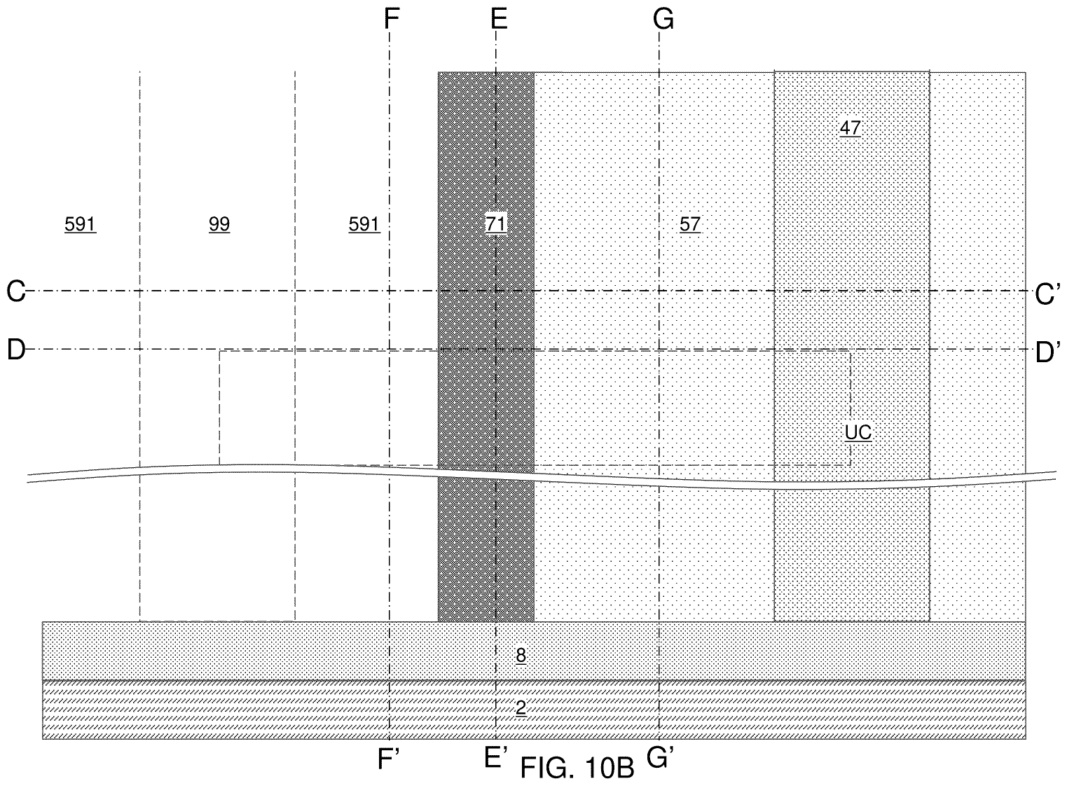

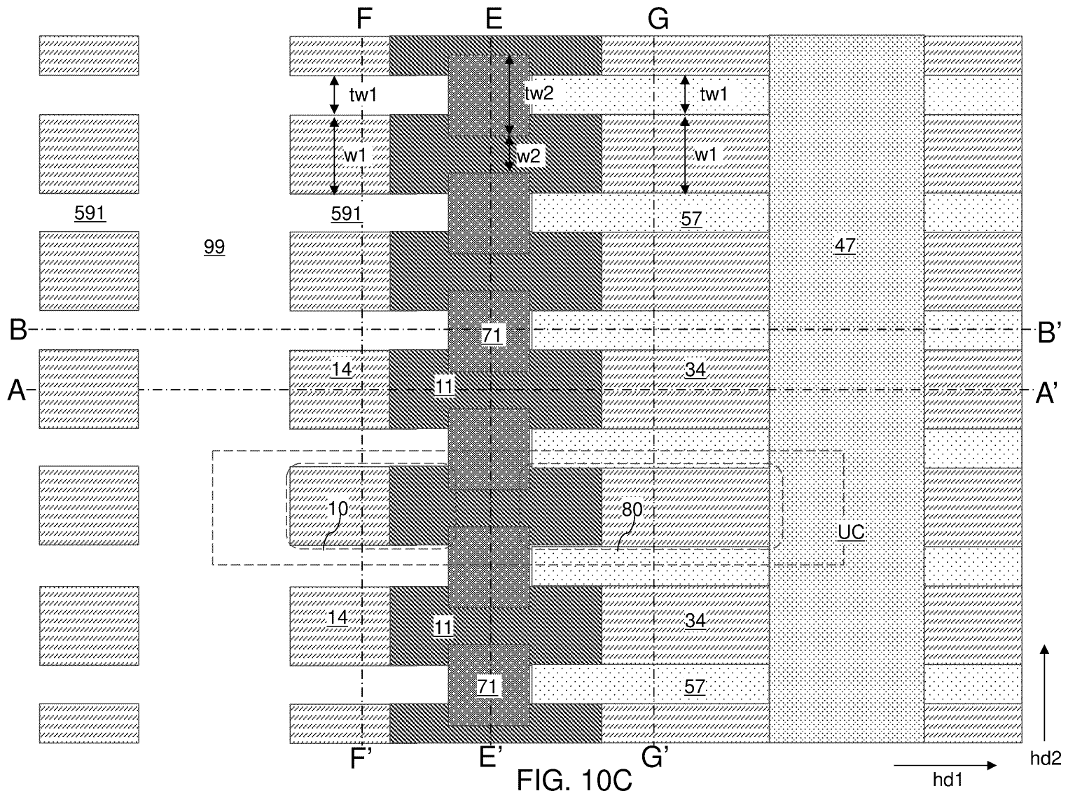

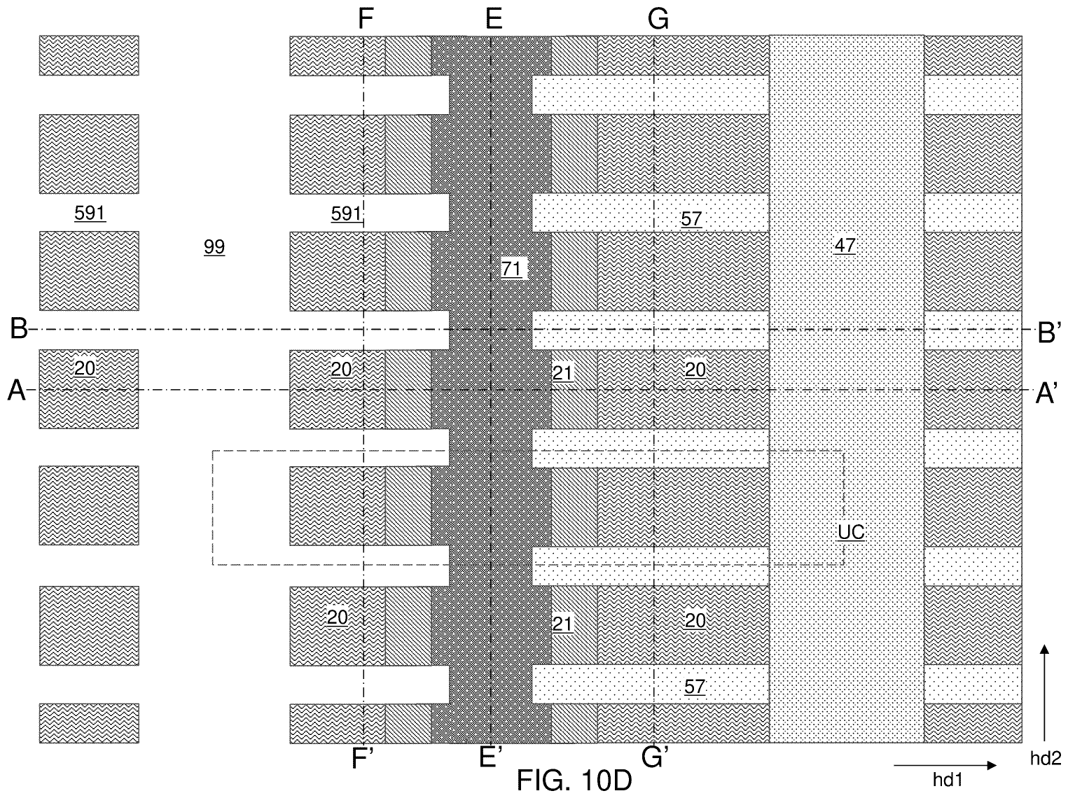

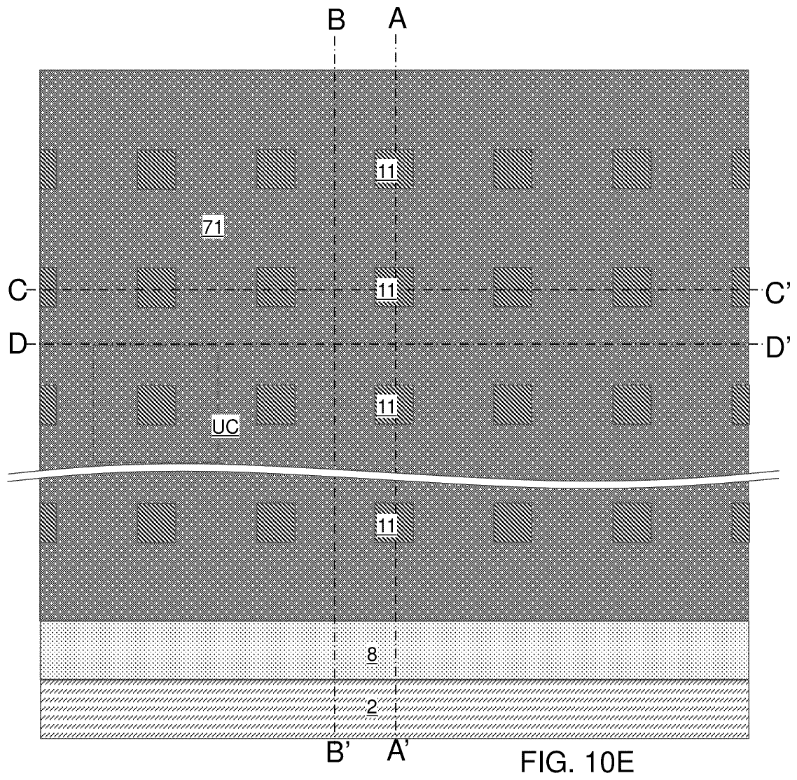

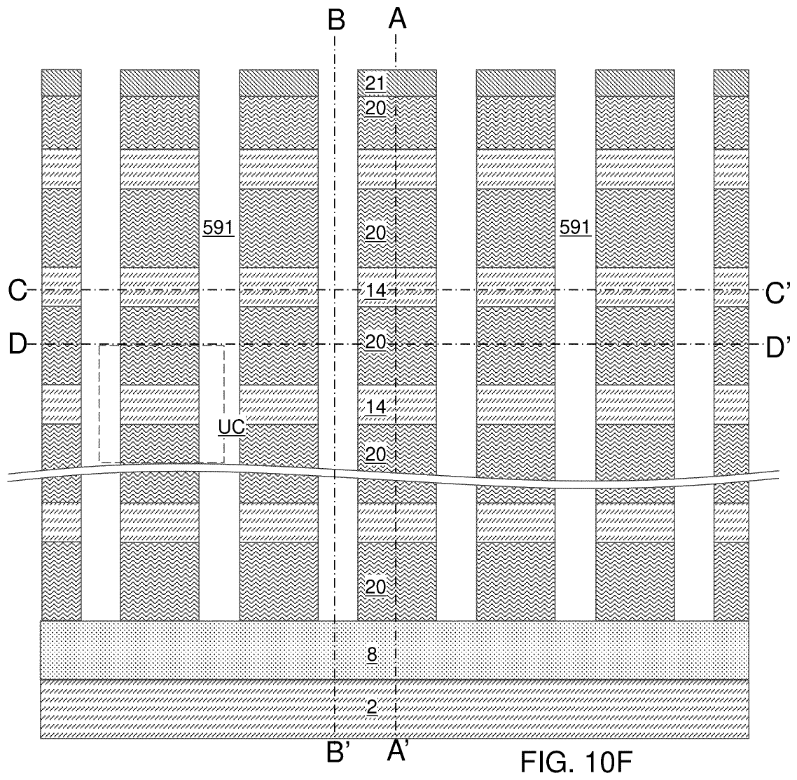

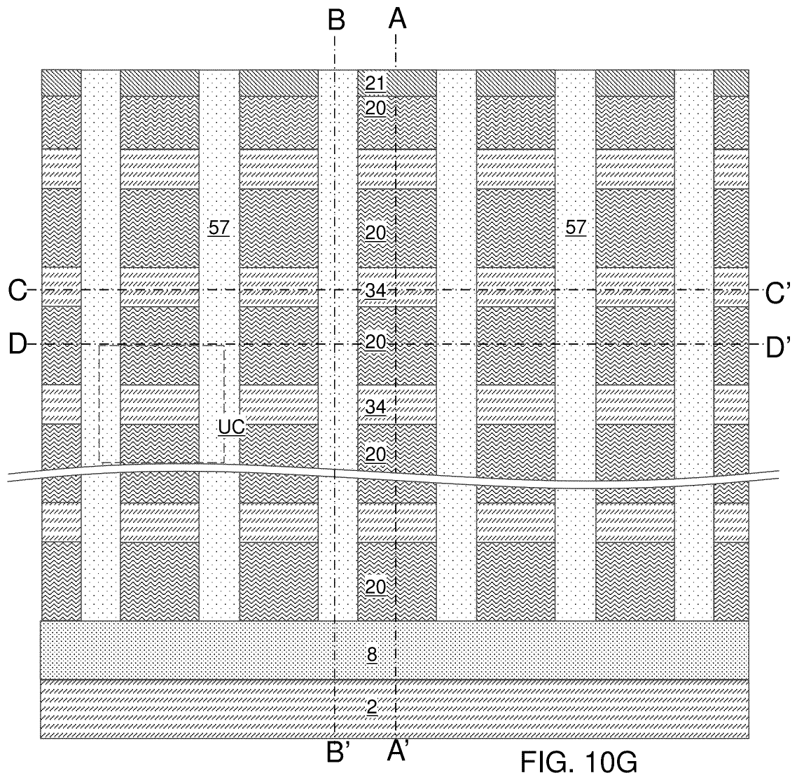

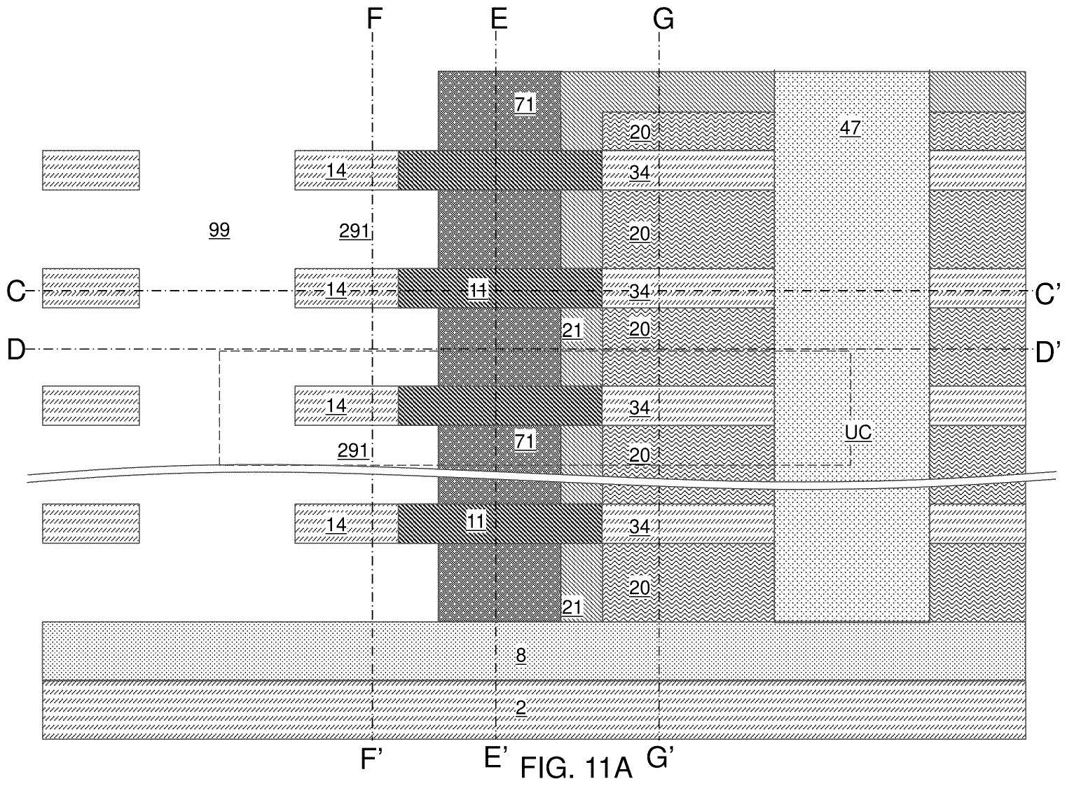

Referring to FIGS. 10A, 10B, 10C, 10D, 10E, 10F, and 10G, an etch mask layer (not illustrated), such as a photoresist layer, can be formed over the first exemplary structure, and can be patterned to form openings over the areas of the sacrificial bit-line trench fill structures 97 and a first subset of the sacrificial isolation trench fill structure 57 that contacts a respective one of the sacrificial bit-line trench fill structures 97. The etch mask layer can cover each of the sacrificial perforated wall structures 71, the sacrificial source trench fill structures 47, and a second subset of the sacrificial isolation trench fill structures 57 that contacts a respective one of the sacrificial source trench fill structures 47.

At least one first selective material removal process can be performed to remove the sacrificial bit-line trench fill structures 97 and the first subset of the sacrificial isolation trench fill structure 57 selectively to the materials of the semiconductor rails (14, 11, 34), the etch stop structure 8, and sacrificial perforated wall structures 71. In an illustrative example, if the sacrificial bit-line trench fill structures 97 comprise silicon nitride, a wet etch process employing hot phosphoric acid may be performed to remove the sacrificial bit-line trench fill structures 97 without removing the first subset of the sacrificial isolation trench fill structure 57. If the sacrificial bit-line trench fill structures 97 comprise a carbon-based material such as amorphous carbon or diamond-like carbon, an ashing process may be employed to remove the sacrificial bit-line trench fill structures 97. Voids are formed in the volumes of the bit-line trenches 99. Subsequently, if the first subset of the sacrificial isolation trench fill structure 57 comprises a silicate glass-based material, a wet etch process employing dilute hydrofluoric acid may be performed to etch the first subset of the sacrificial isolation trench fill structure 57 selectively to the materials of the semiconductor rails (14, 11, 34), the etch stop structure 8, and sacrificial perforated wall structures 71. Alternatively, if the sacrificial perforated wall structures 71 comprise a material that is different from the material(s) of the sacrificial bit-line trench fill structures 97 and the sacrificial isolation trench fill structure 57, a single isotropic etch process may be performed to simultaneously etch the material(s) of the sacrificial bit-line trench fill structures 97 and the sacrificial isolation trench fill structure 57. First lateral isolation trenches 591 are formed in the volumes from which the first subset of the sacrificial isolation trench fill structures 57 are removed. The first lateral isolation trenches 591 are formed between laterally-neighboring pairs of horizontally-extending semiconductor channels 14 by removing the first subset of the sacrificial isolation trench fill structures 57.

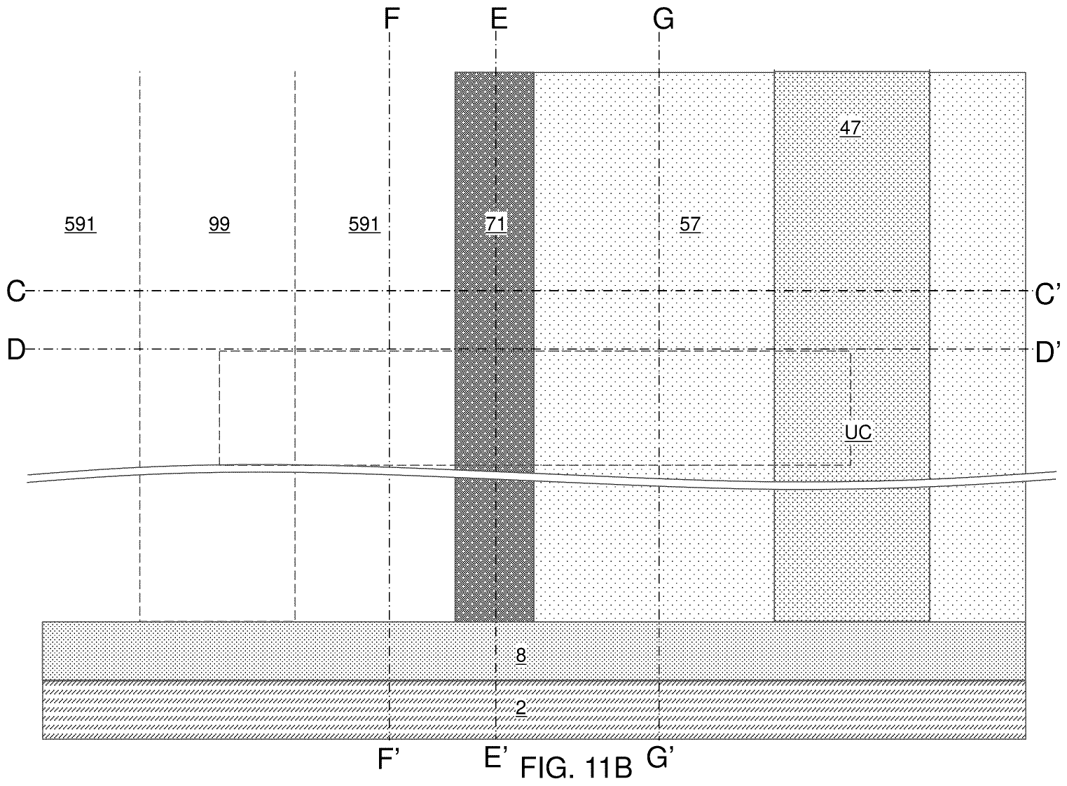

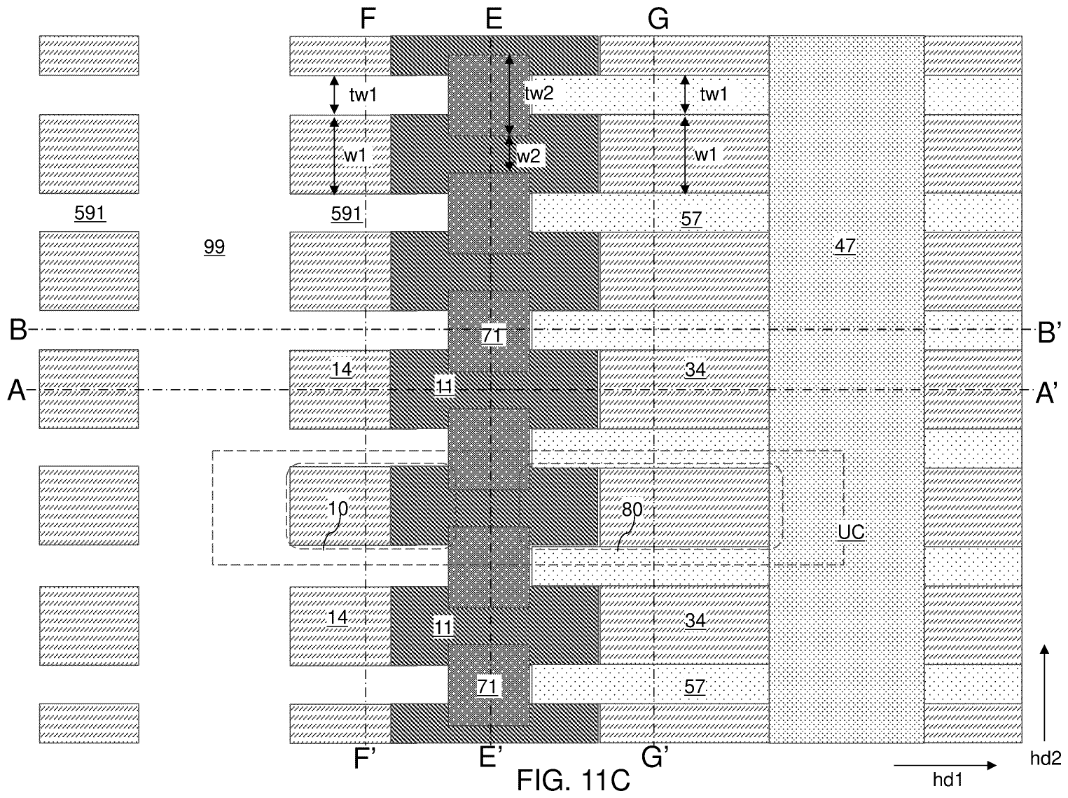

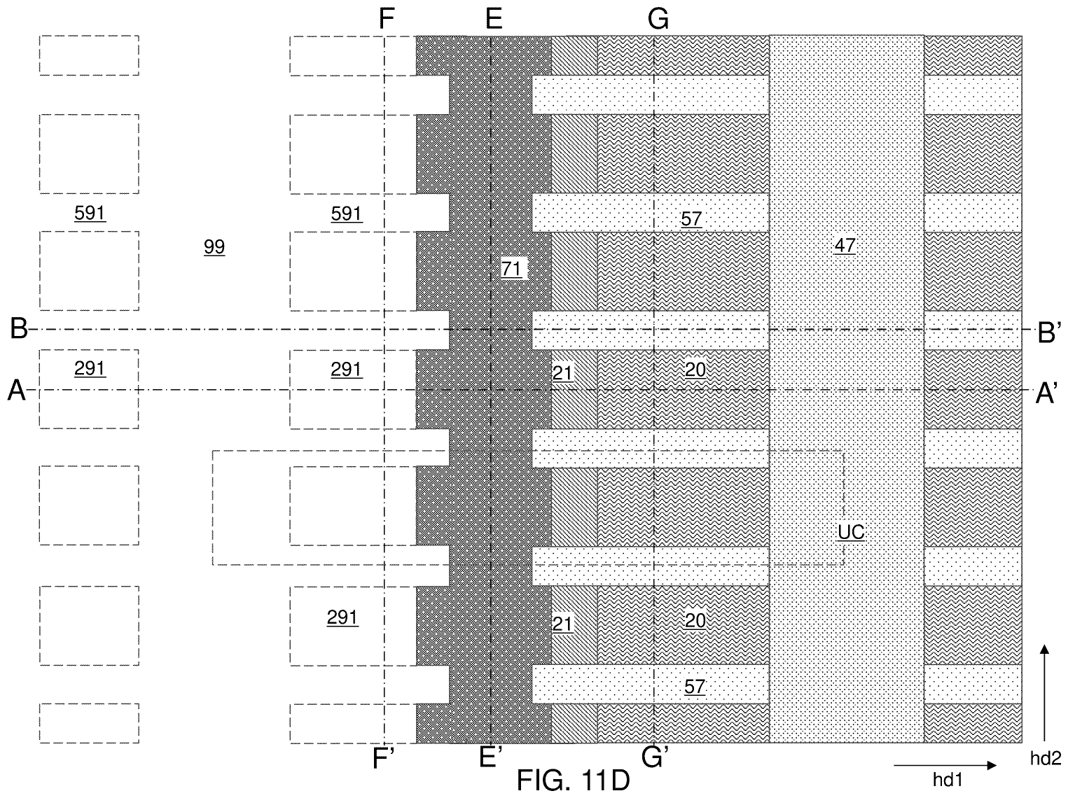

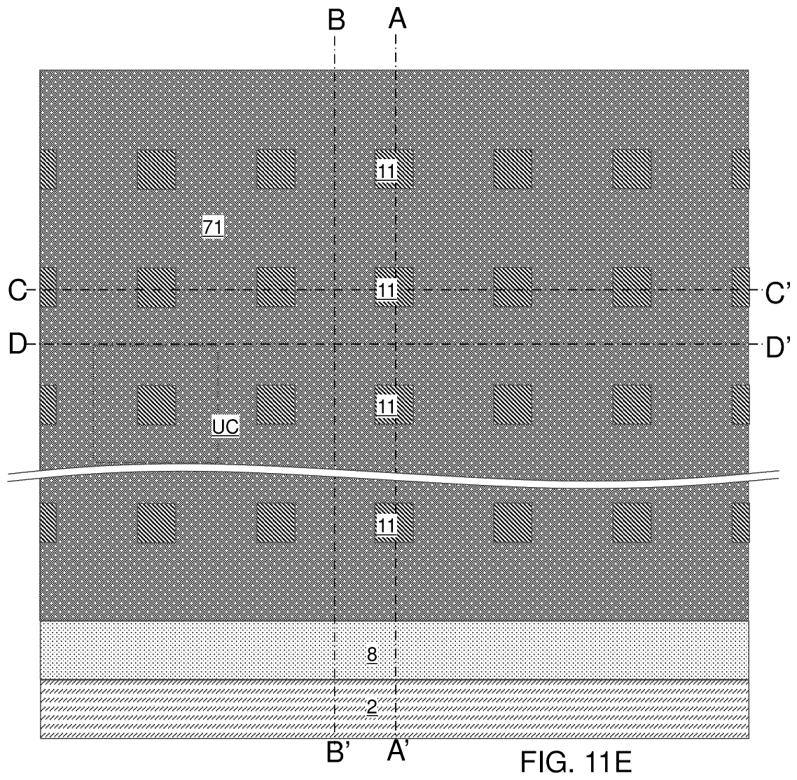

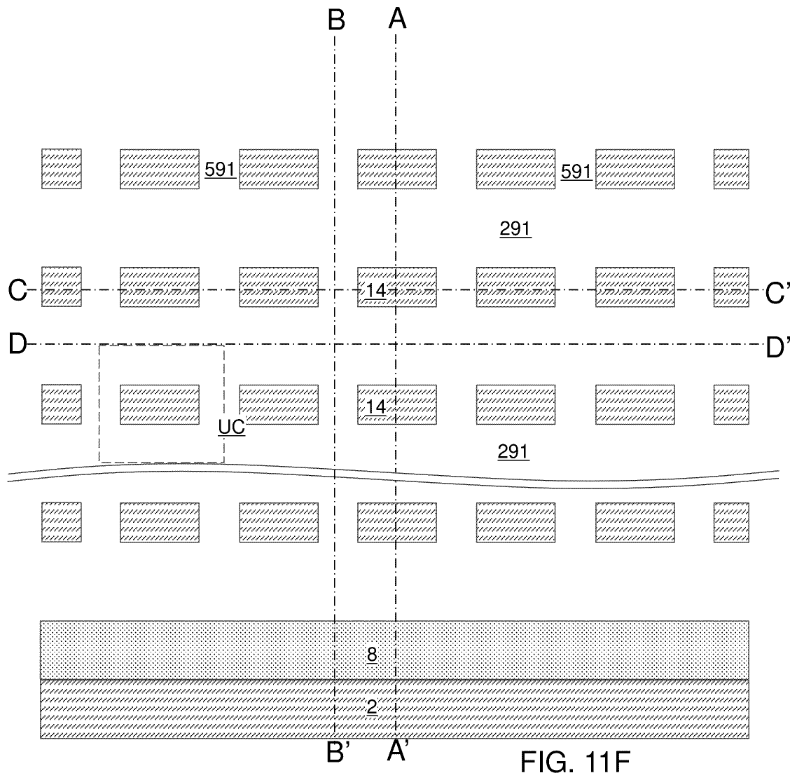

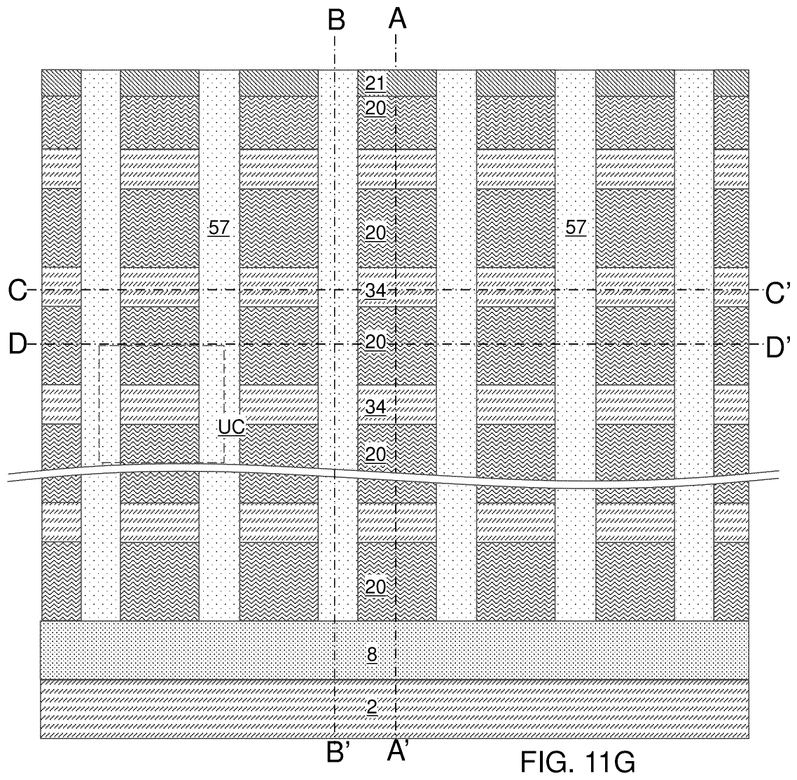

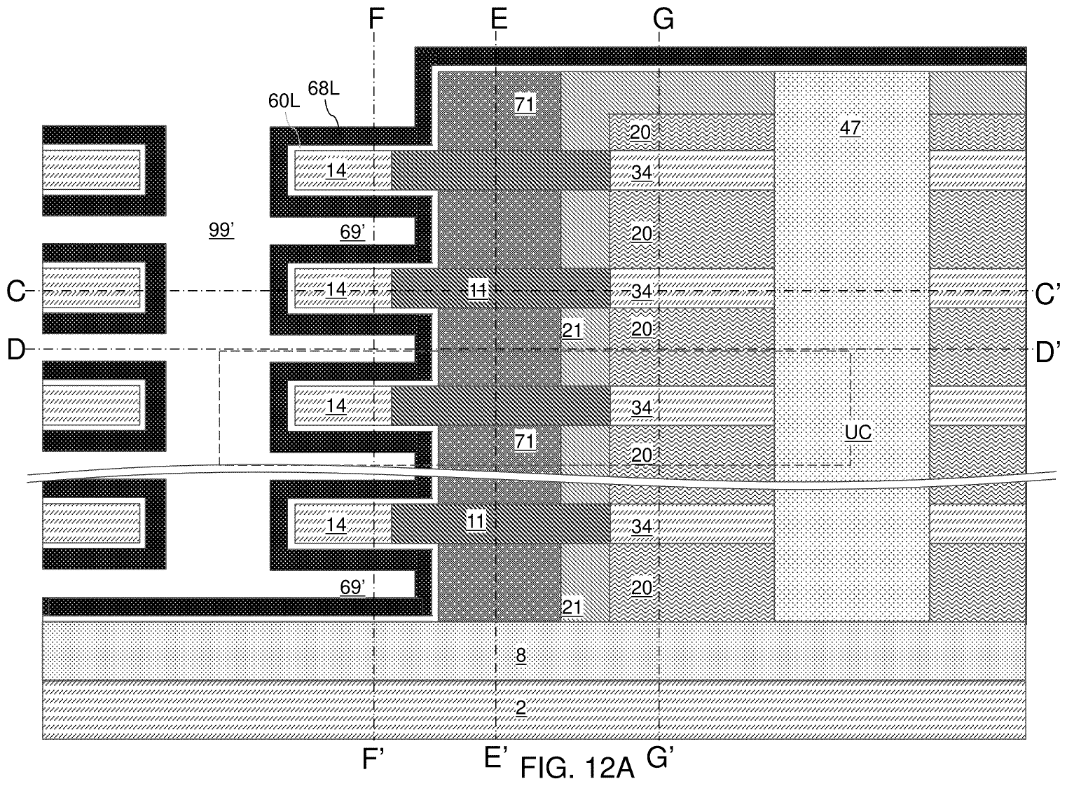

Referring to FIGS. 11A, 11B, 11C, 11D, 11E, 11F, and 11G, at least one second selective material removal process may be performed to remove each of the first-type sacrificial rails 20A. First inter-rail cavities 291 are formed in the volumes from which the first-type sacrificial rails 20A are removed. The first inter-rail cavities 291 are formed between vertically-neighboring pairs of horizontally-extending semiconductor channels 14 by removing the first-type sacrificial rails 20A. The etch mask layer can be subsequently removed.

In alternative embodiments, the set of processing steps described with reference to FIGS. 10A-11G may be replaced with any alternative set of processing steps provided that the materials of the sacrificial bit-line trench fill structure 97, the first subset of the sacrificial isolation trench fill structures 57, and the first-type sacrificial rails 20A are removed.

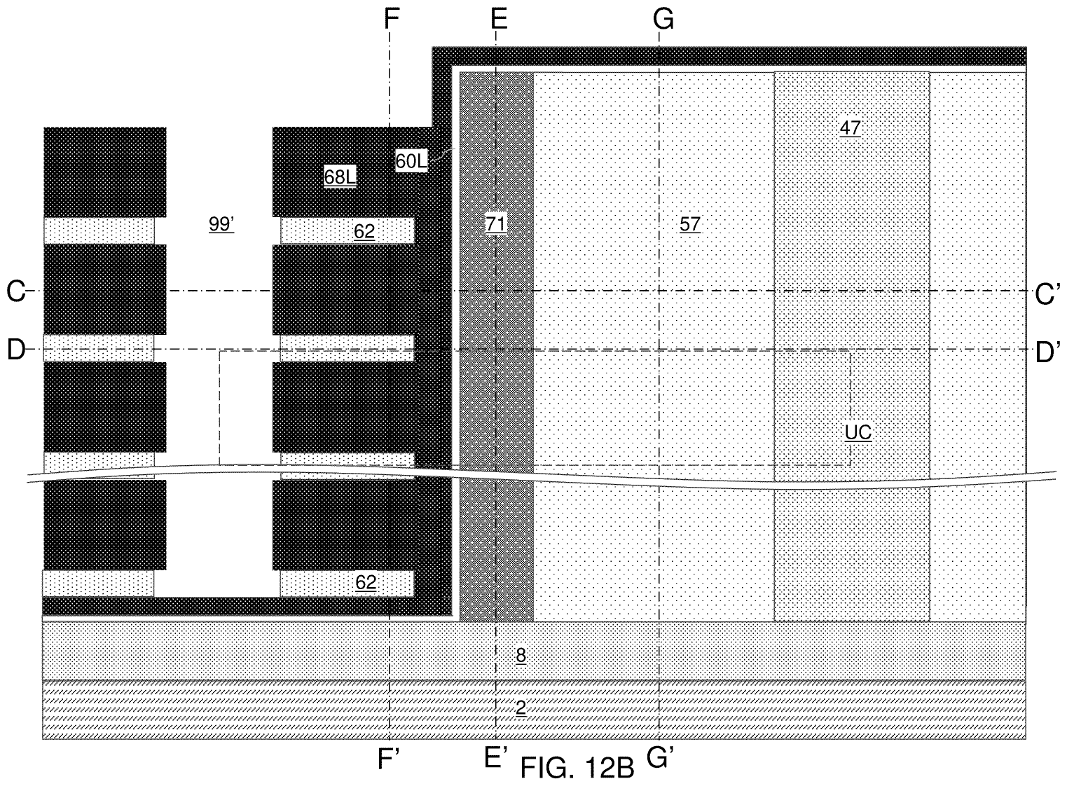

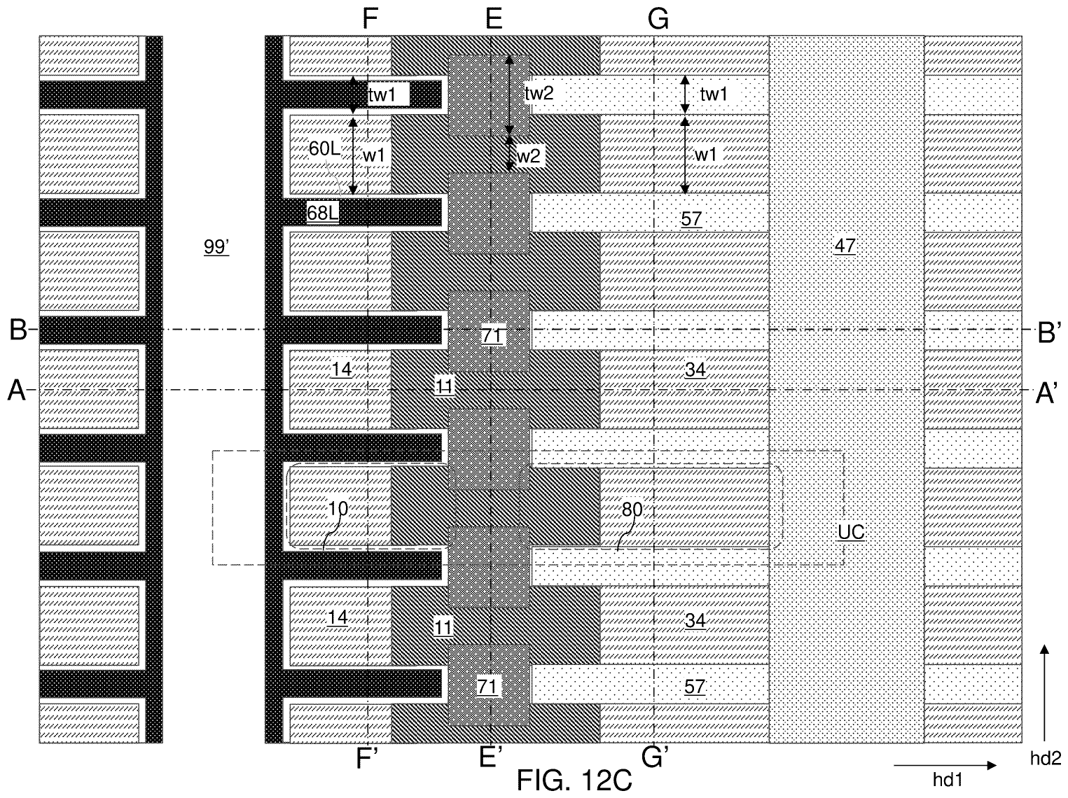

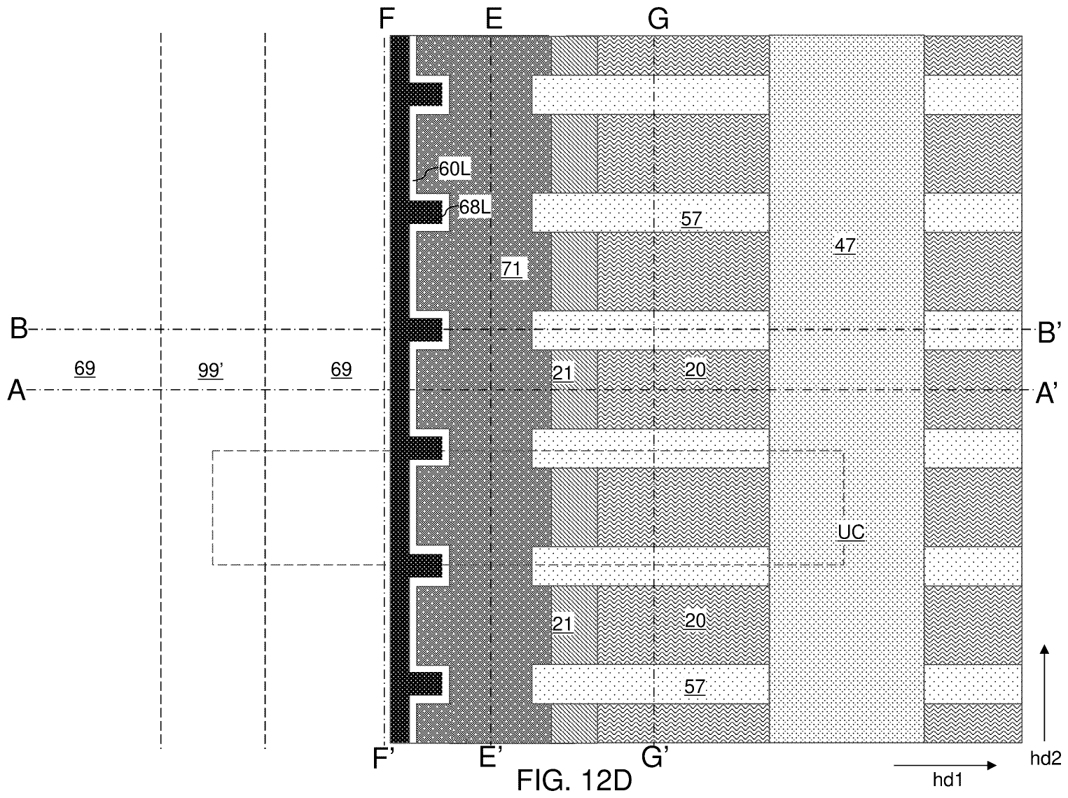

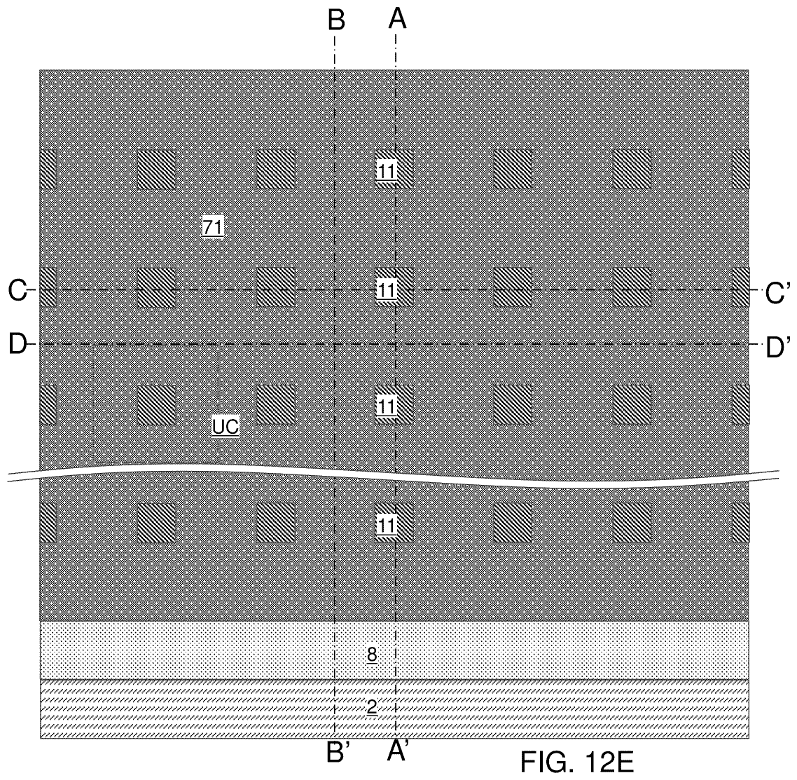

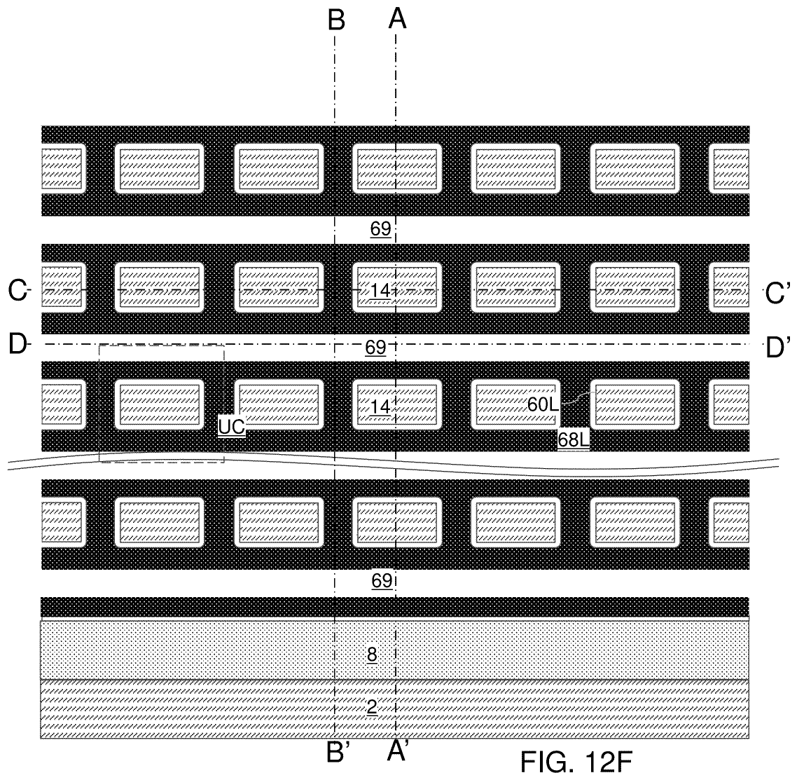

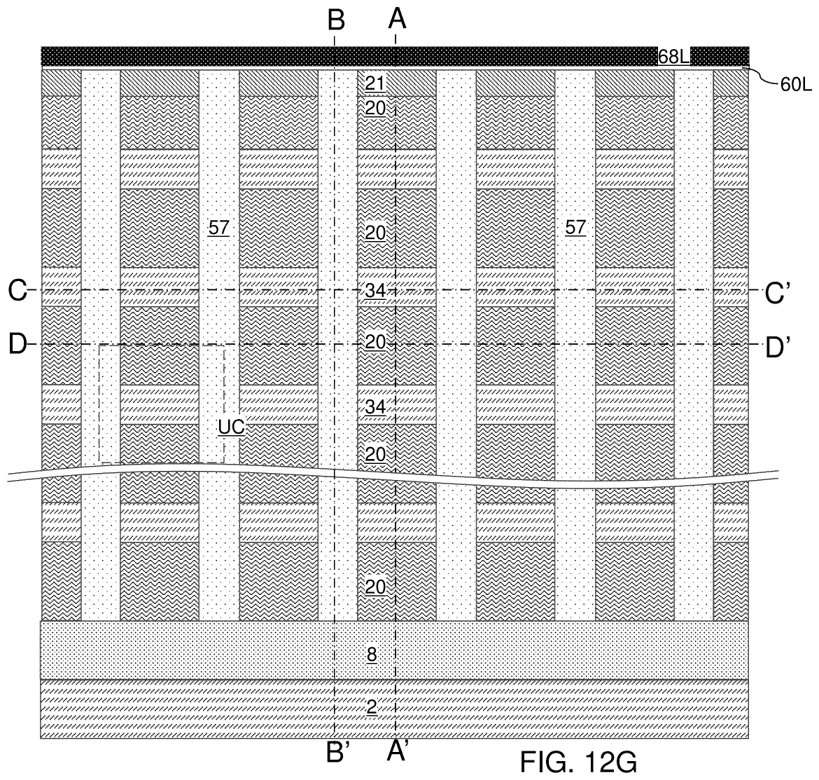

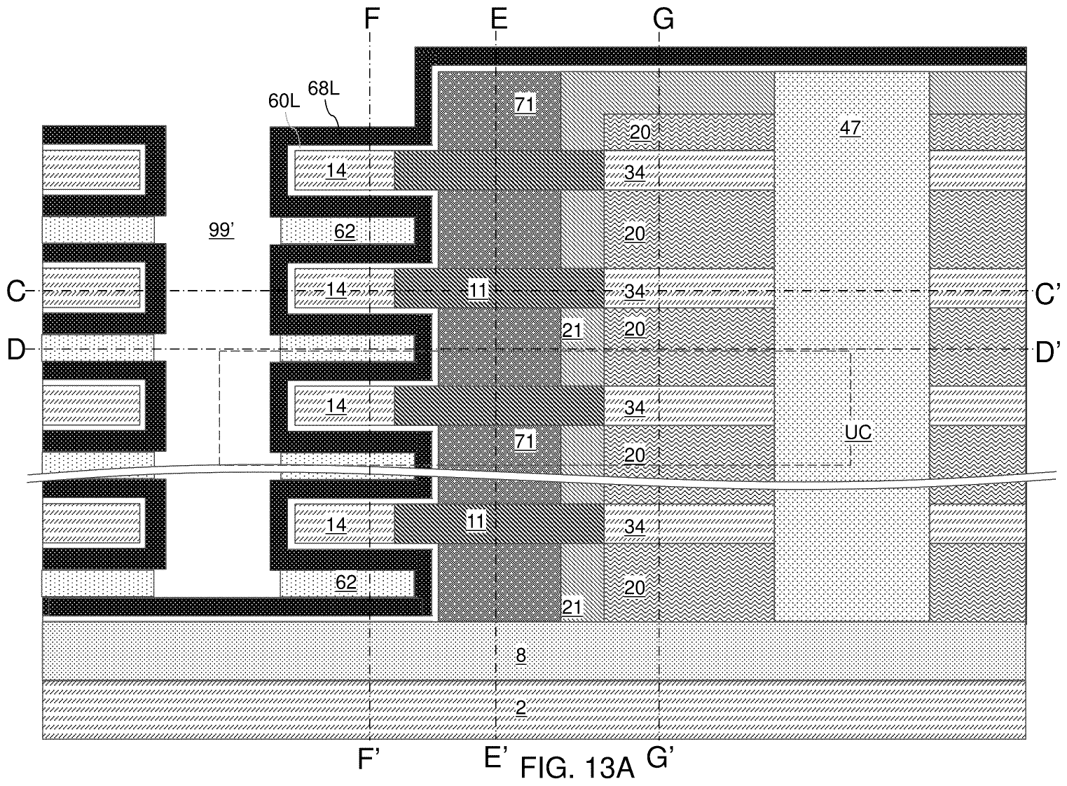

Referring to FIGS. 12A, 12B, 12C, 12D, 12E, 12F, and 12G, a first gate dielectric material layer 60L is formed by conformal deposition of a gate dielectric material and/or by oxidation of physically exposed surface portions of the semiconductor rails (14, 11, 34). The first gate dielectric material layer 60L comprises a first gate dielectric material, such as silicon oxide or a dielectric metal oxide. The thickness of the first gate dielectric material layer 60L may be in a range from 2 nm to 20 nm, such as from 3 nm to 6 nm, although lesser and greater thicknesses may also be employed.

A continuous first gate electrode material layer 68L may be conformally deposited on the first gate dielectric material layer 60L. The continuous first gate electrode material layer 68L comprises a first gate electrode material, which may comprise any suitable conductive material. For example, the continuous first gate electrode material layer 68L may comprise at least one metallic barrier layer, such as TIN, TaN, WN or MON, and a metal fill layer such as W, Ti, Ta, Ru or Mo. The continuous first gate electrode material layer 68L can be formed around each first portion of the horizontally-extending semiconductor rails (14, 11, 34), i.e., around each horizontally-extending semiconductor channel 14. The continuous first gate electrode material layer 68L is deposited as a continuous material layer such that lateral gaps between laterally-neighboring pairs of the first portions of the horizontally-extending semiconductor rails (14, 11, 34) are filled with the first gate electrode material, while vertical gaps between vertically-neighboring pairs of the first portions of the horizontally-extending semiconductor rails (14, 11, 34) are not completely filled with the first gate electrode material. Thus, first laterally-extending voids 69 that laterally extend along the second horizontal direction hd2 are present in unfilled volumes of the vertical gaps between neighboring pairs of first portions of the semiconductor rails (14, 11, 34) after deposition of the first gate electrode material of the continuous first gate electrode material layer 68L. A laterally-extending void 99′ can be present within each bit-line trench 99.

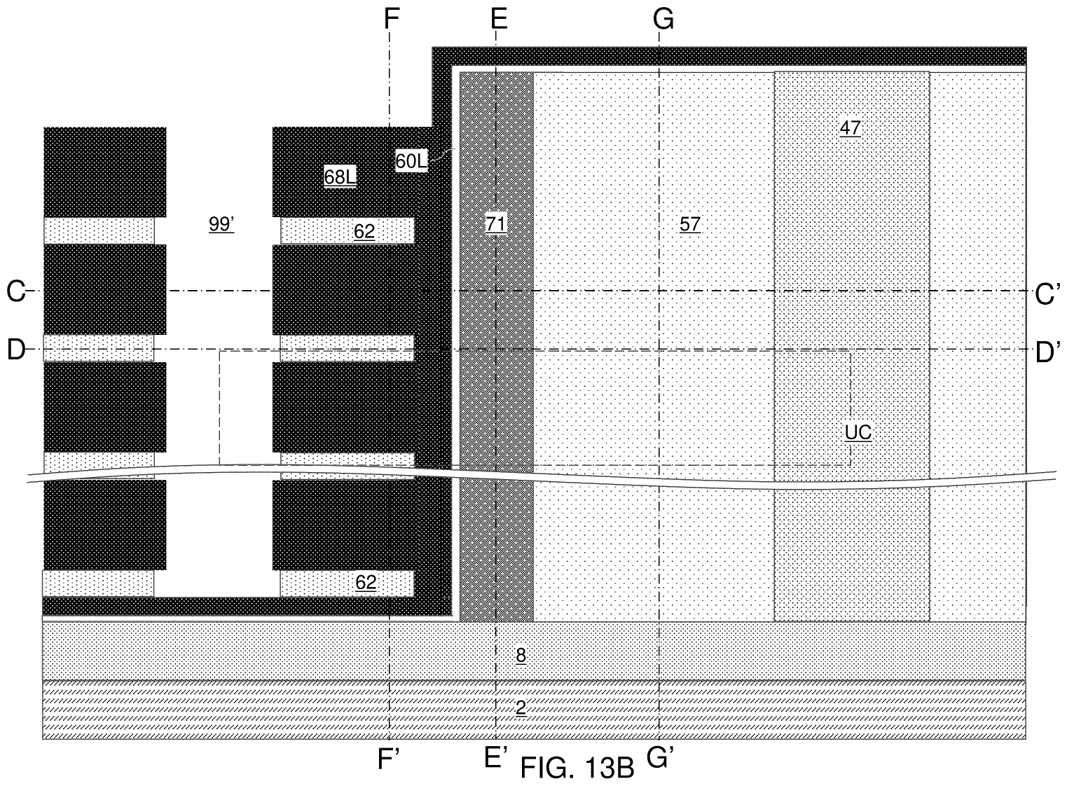

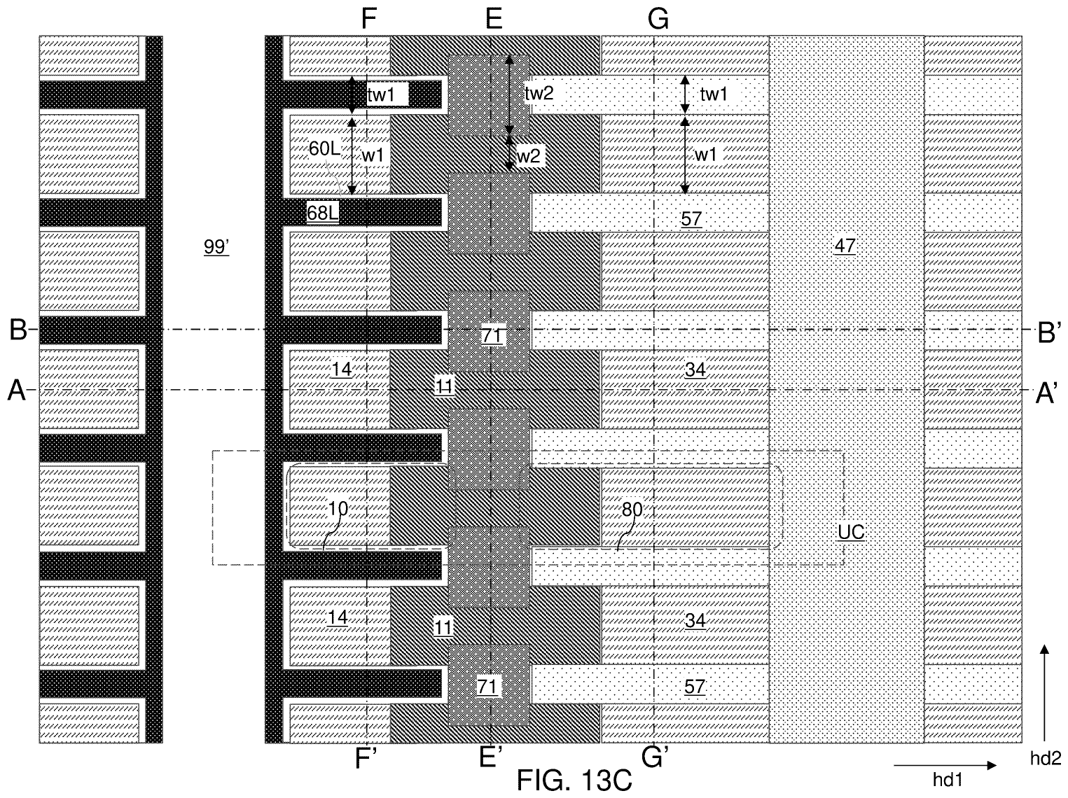

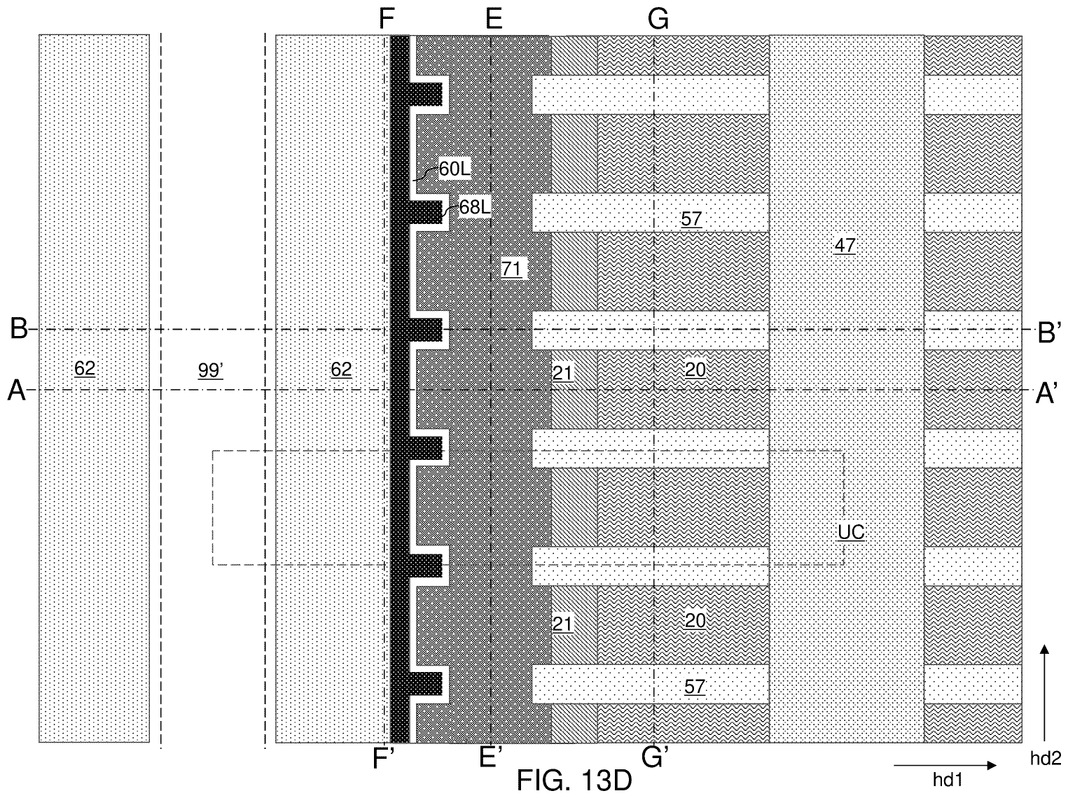

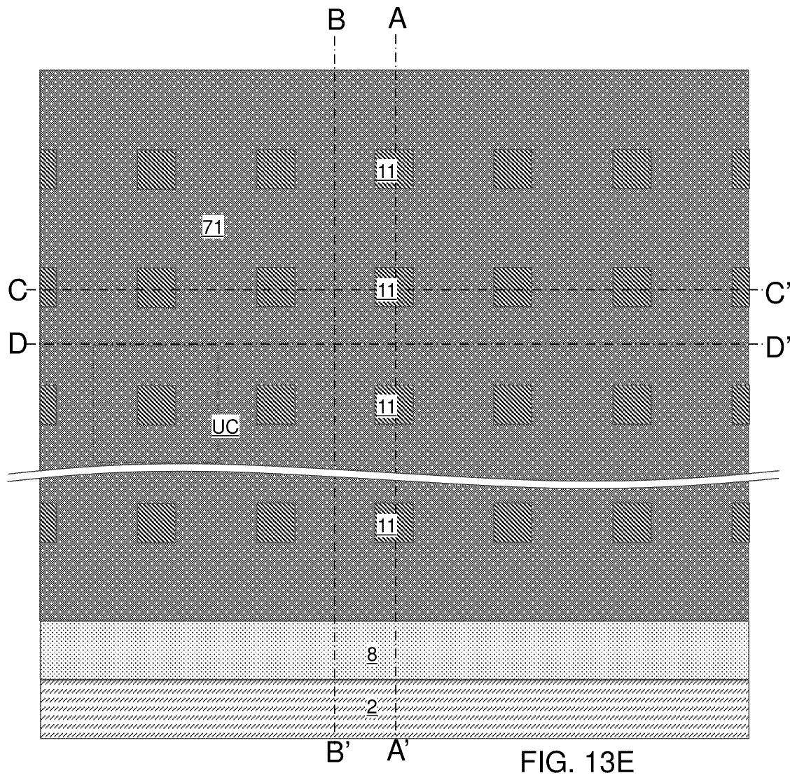

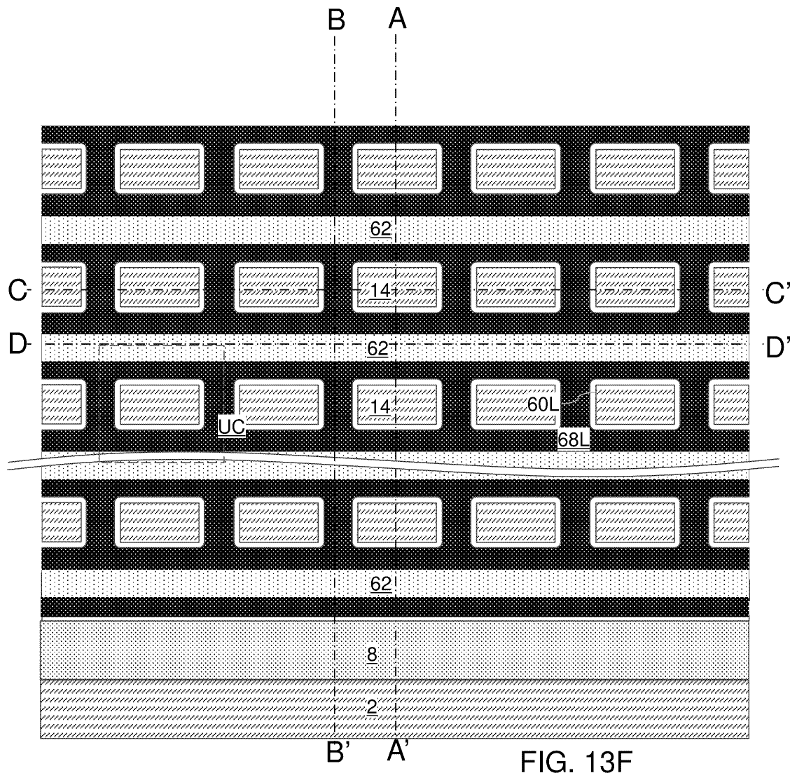

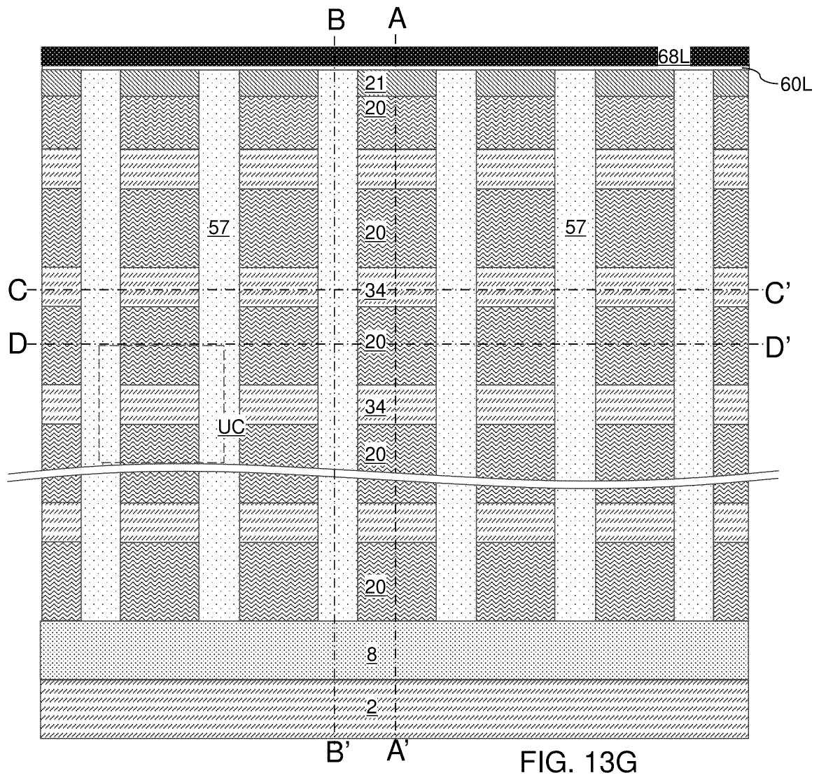

Referring to FIGS. 13A, 13B, 13C, 13D, 13E, 13F, and 13G, a first dielectric fill material, such as silicon oxide can be conformally deposited in the first laterally-extending voids 69, in peripheral portions of the bit-line trenches 99, and over the horizontally-extending portion of the continuous first gate electrode material layer 68L that overlie the three-dimensional array of semiconductor rails (14, 11, 34). A recess etch process may be performed to remove portions of the first dielectric fill material from outside the volumes of the first laterally-extending voids 69. Remaining portions of the first dielectric fill material that fill the first laterally-extending voids 69 comprise a two-dimensional array of first dielectric plates 62. Each first dielectric plate 62 is formed between a respective vertically neighboring pair of laterally extending portions of the continuous first gate electrode material layer 68L that laterally extend along the second horizontal direction hd2.

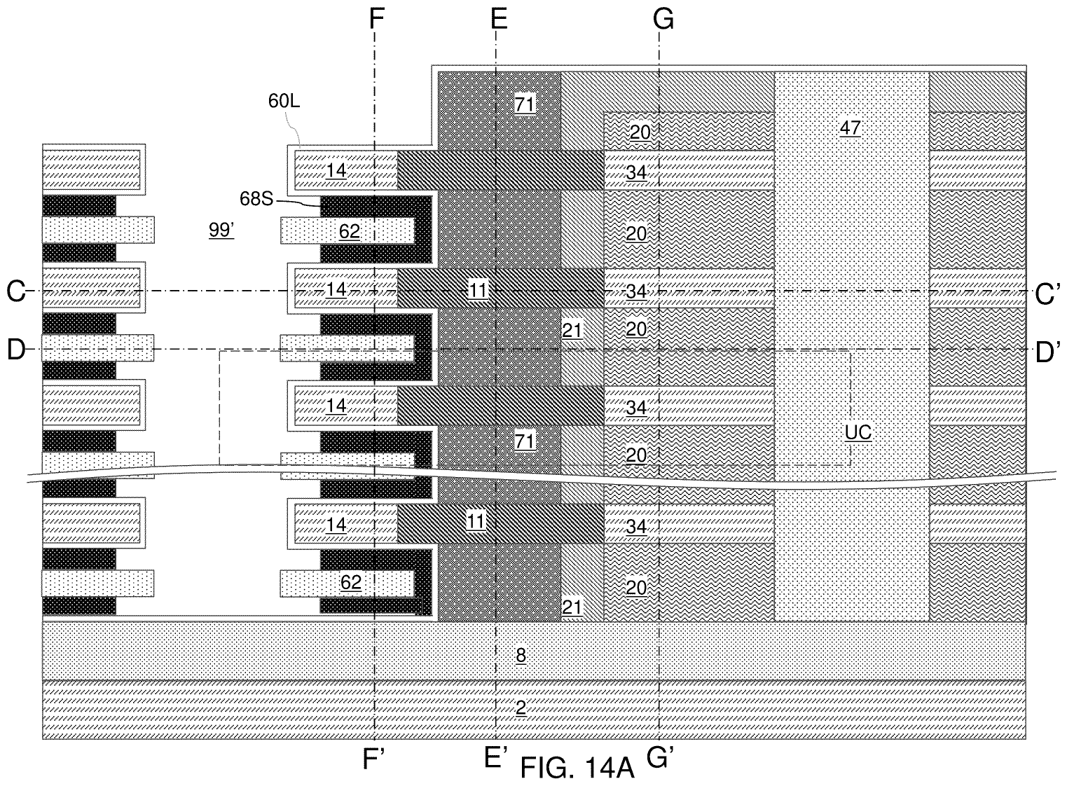

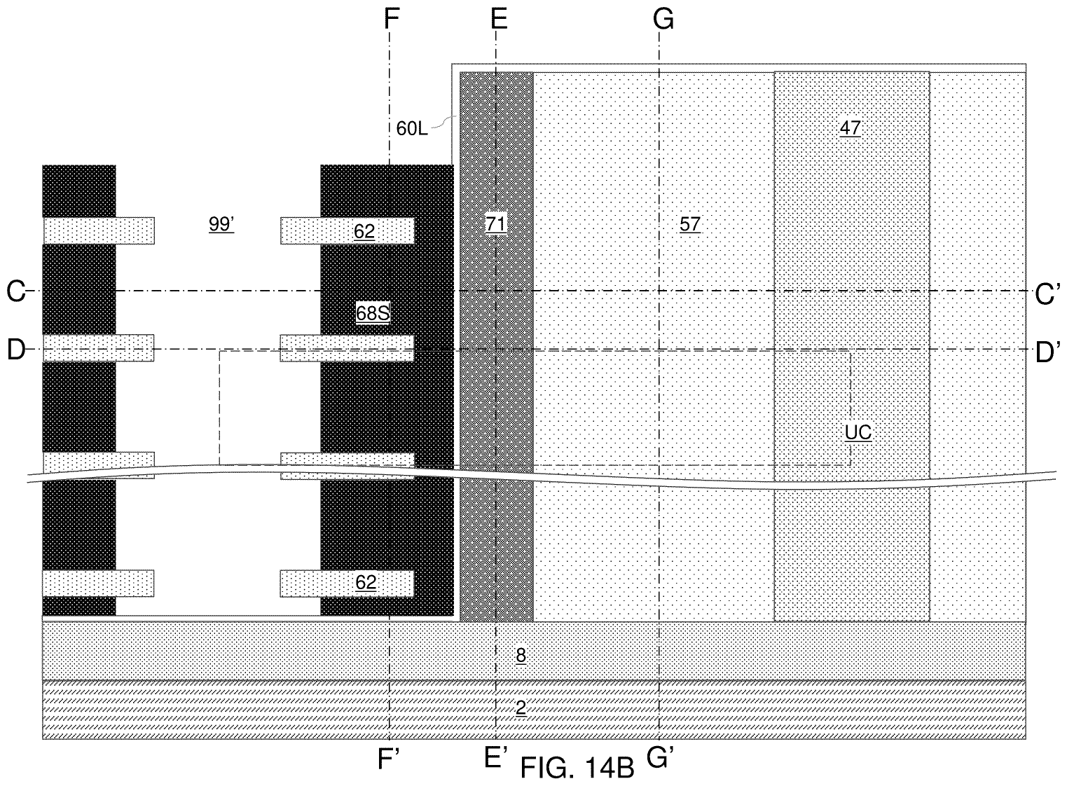

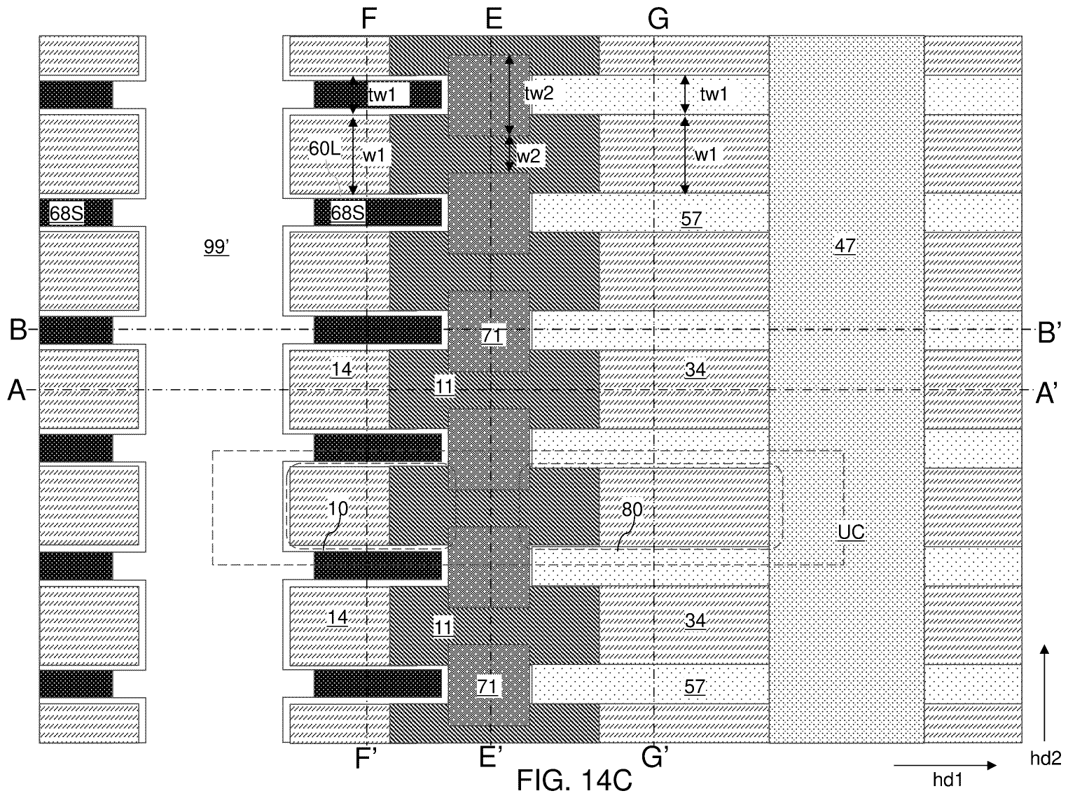

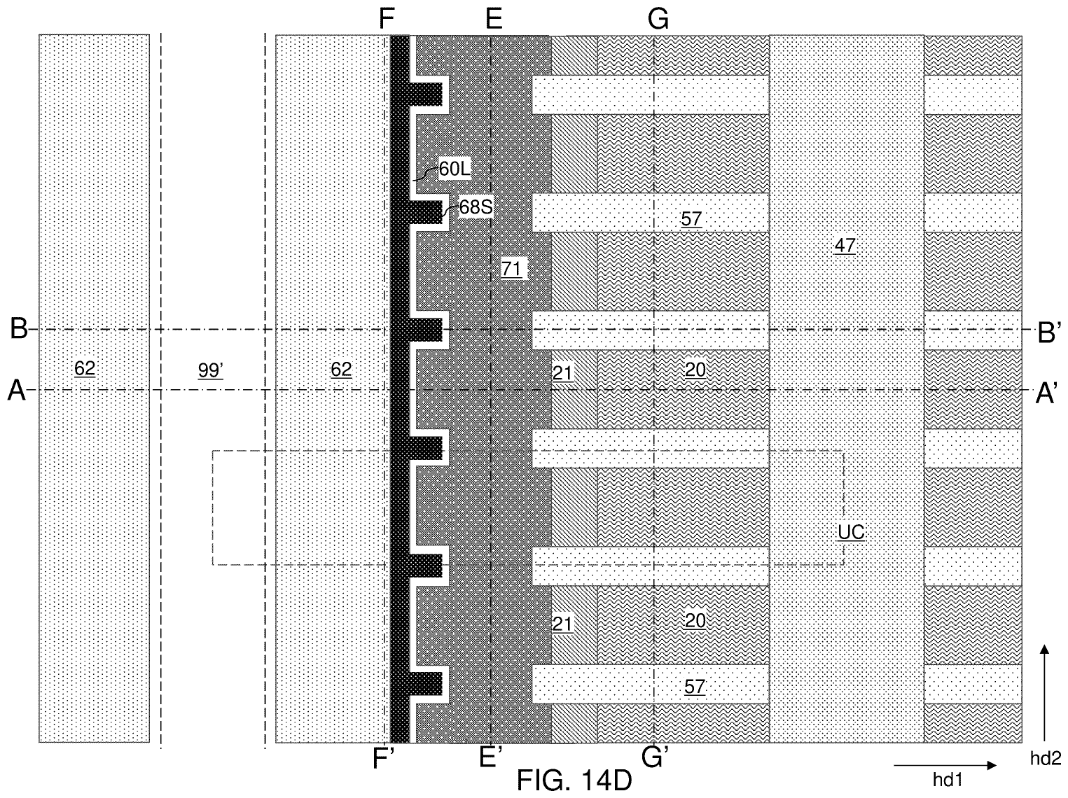

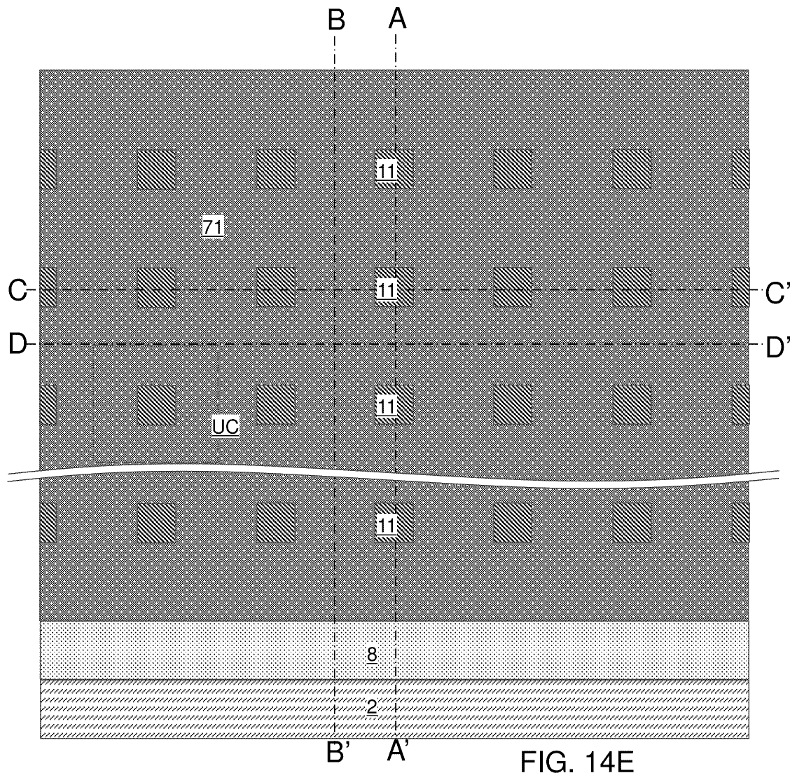

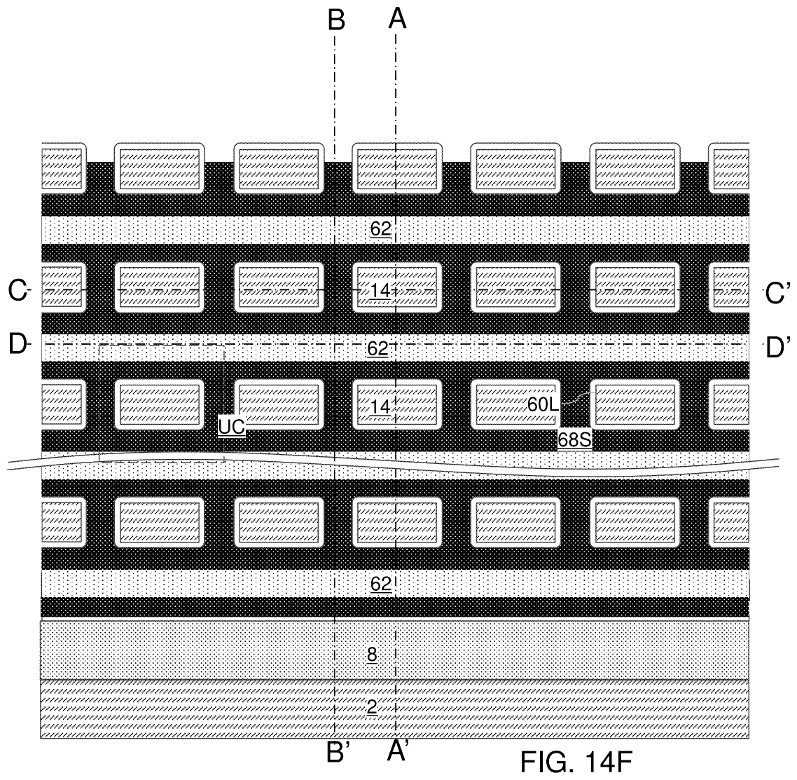

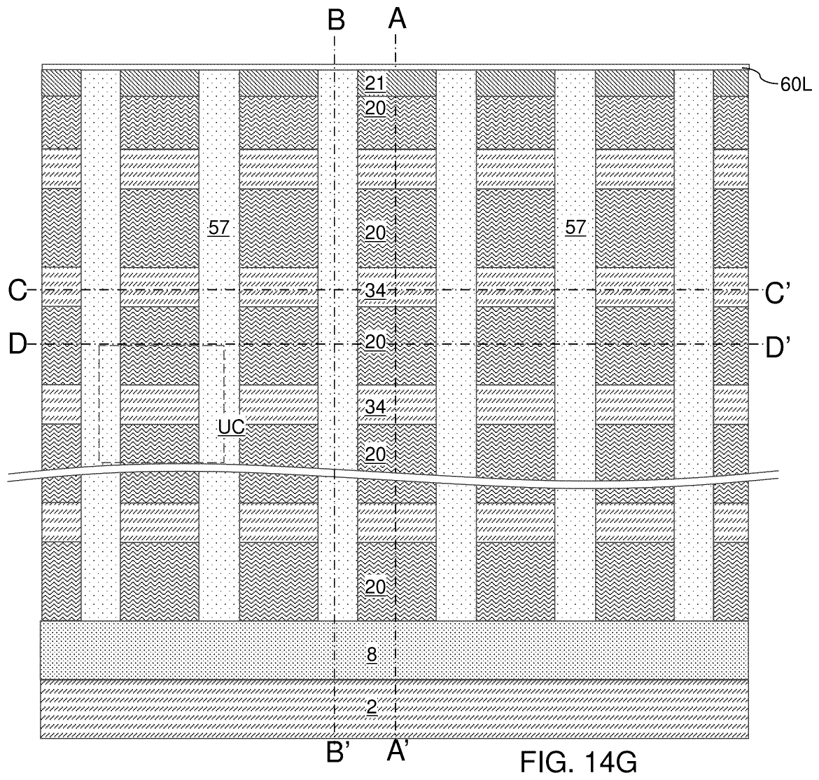

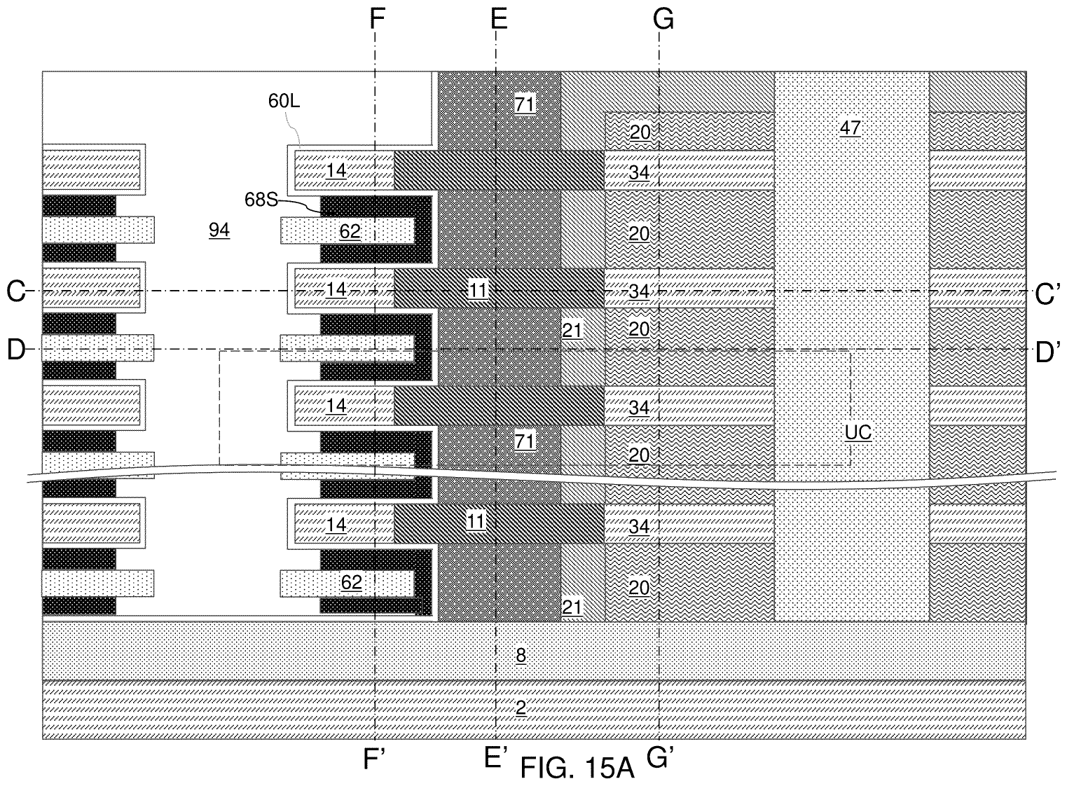

Referring to FIGS. 14A, 14B, 14C, 14D, 14E, 14F, and 14G, a first selective isotropic etch process can be performed to etch portions of the continuous first gate electrode material layer 68L that are proximal to the bit-line trenches 99 or overlie the topmost semiconductor rails (14, 11, 34). The first selective isotropic etch process can etch the first gate electrode material selectively to the first gate dielectric material. For example, a wet etch process that isotropically etches the first gate electrode material selectively to the first gate dielectric material may be employed. The first selective isotropic etch process patterns the continuous first gate electrode material layer 68L into a one-dimensional array of first gate electrode material layers 68S that are laterally spaced apart along the first horizontal direction hd1. Each first gate electrode material layer 68S may surround a respective two-dimensional array of semiconductor rails (14, 11, 34), i.e., a respective two-dimensional array of horizontally-extending semiconductor channels 14. For example, each first gate electrode material layer 68S may have a rectangular array of perforations through which a respective two-dimensional array of horizontally-extending semiconductor channels 14 laterally extends along the first horizontal direction hd1, as shown in FIG. 63F. Optionally, a second selective isotropic etch process can be performed to etch portions of the first gate dielectric material layer 60L that are proximal to the bit-line trenches 99 or overlie the topmost semiconductor rails (14, 11, 34).

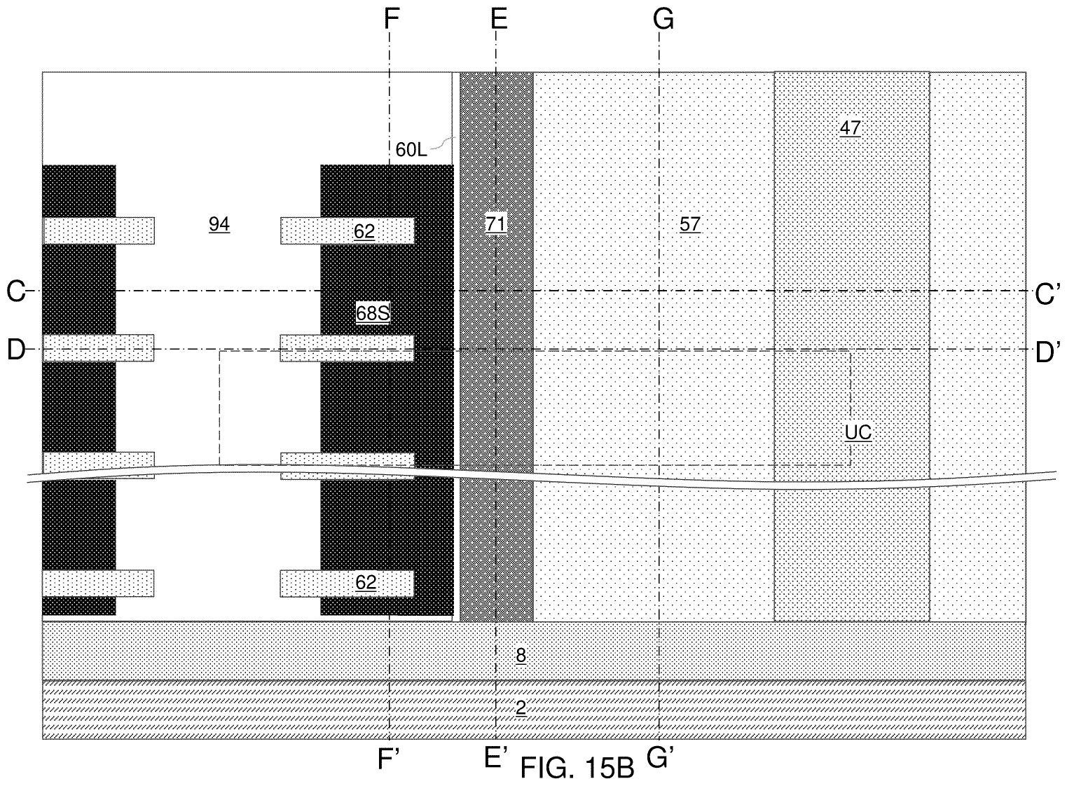

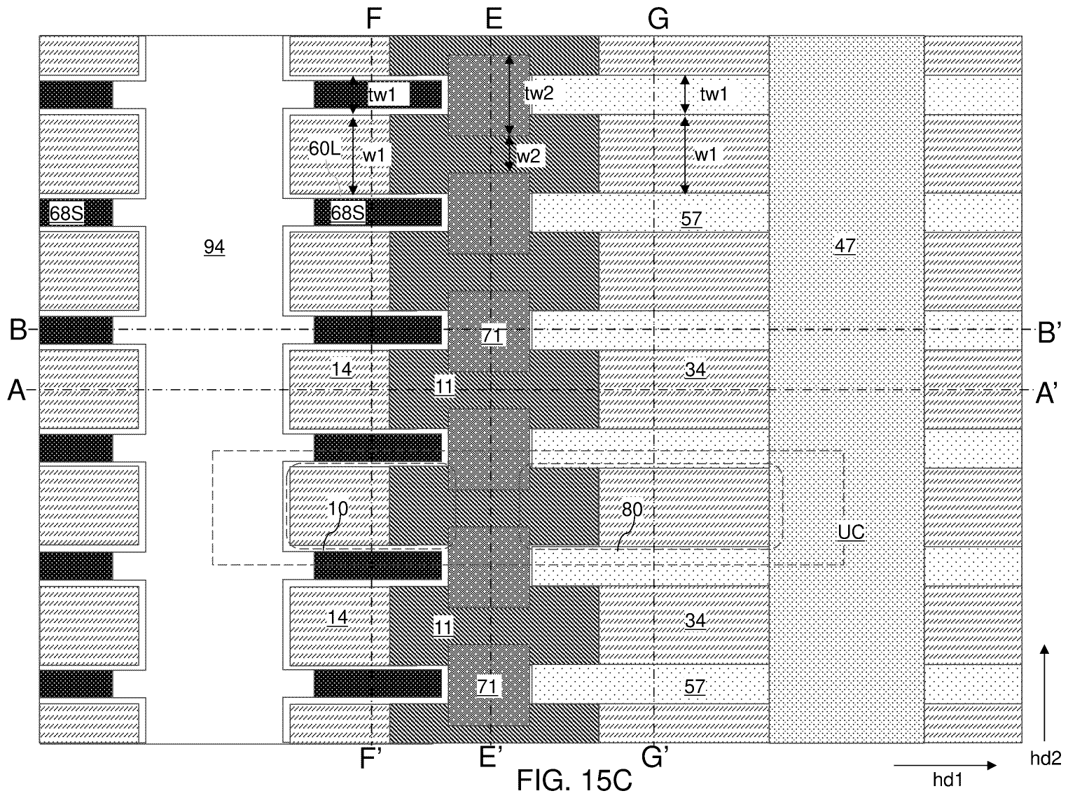

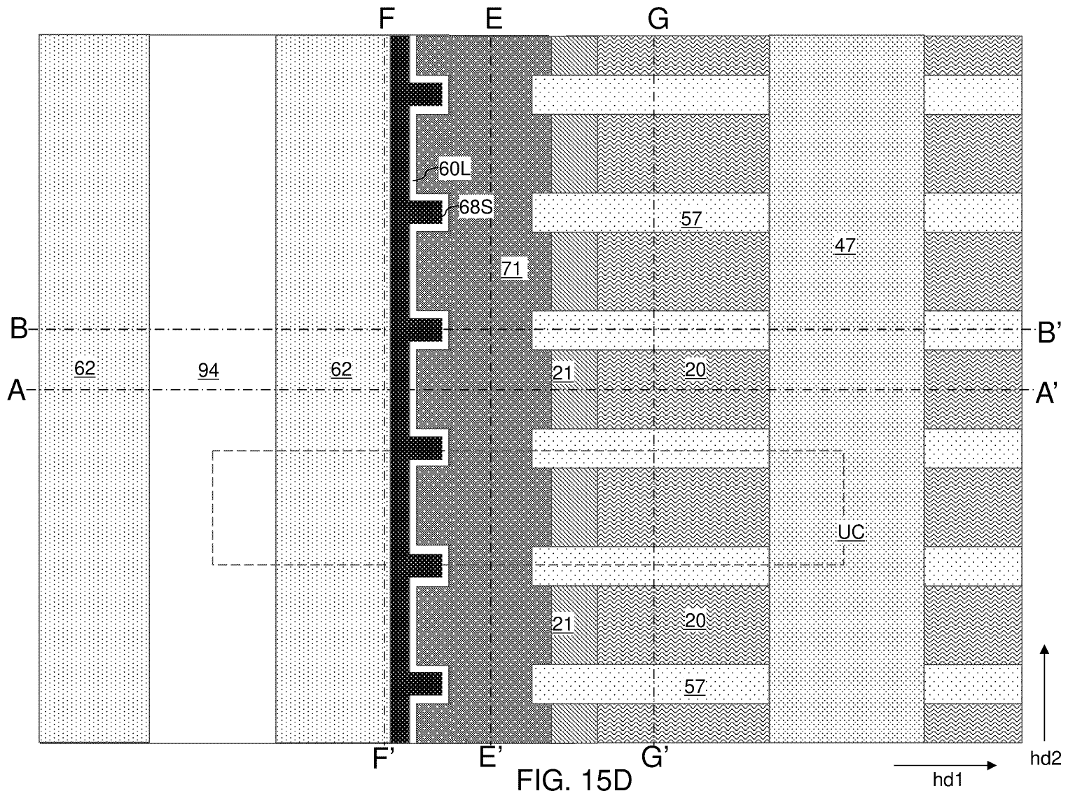

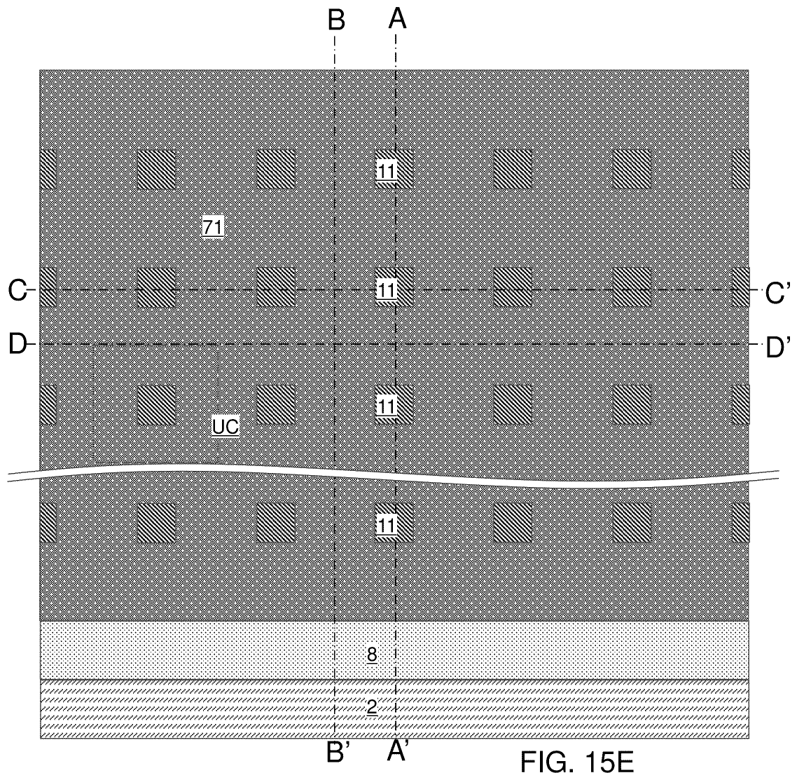

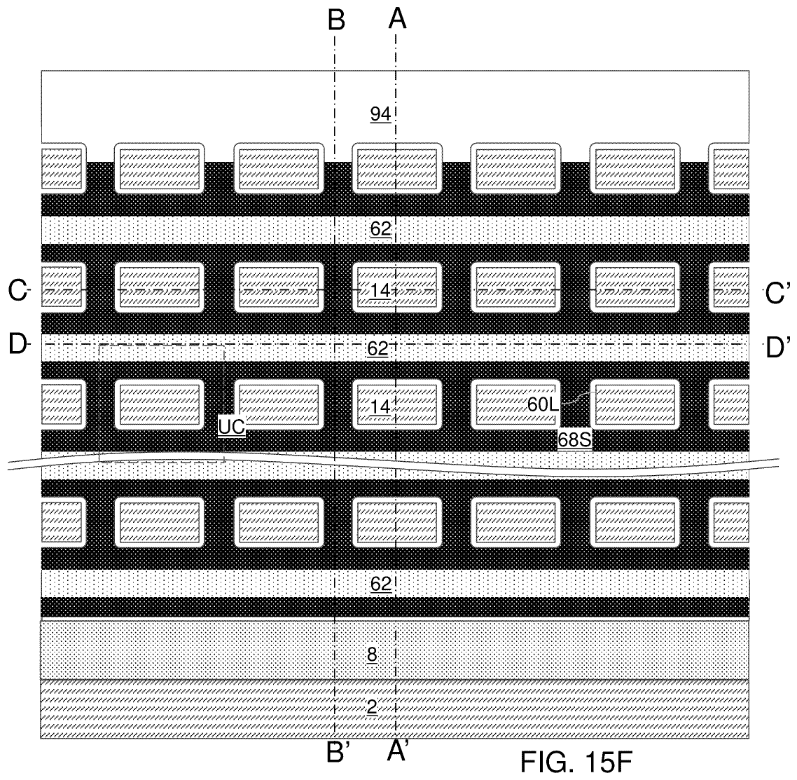

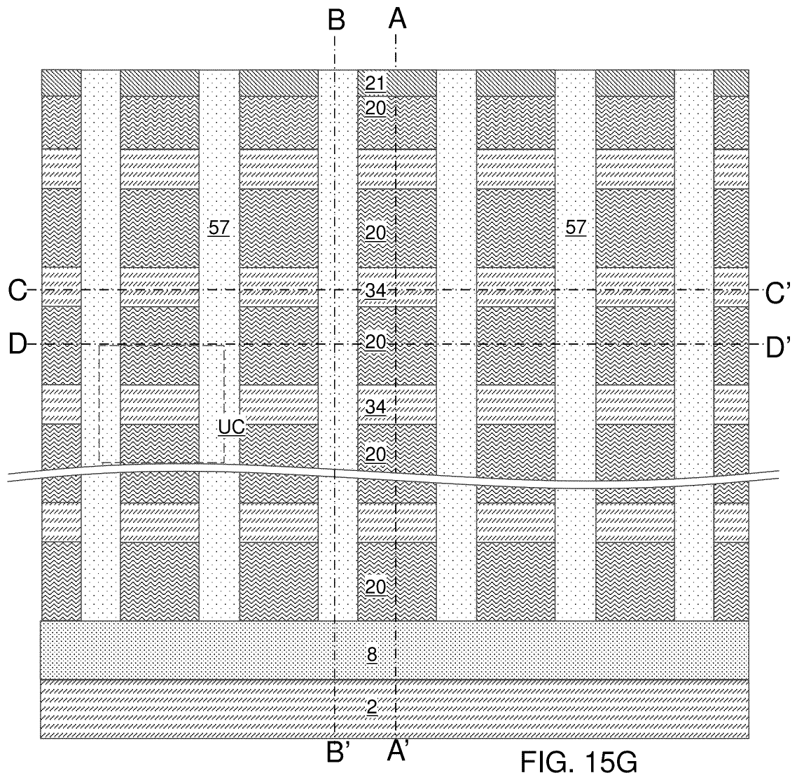

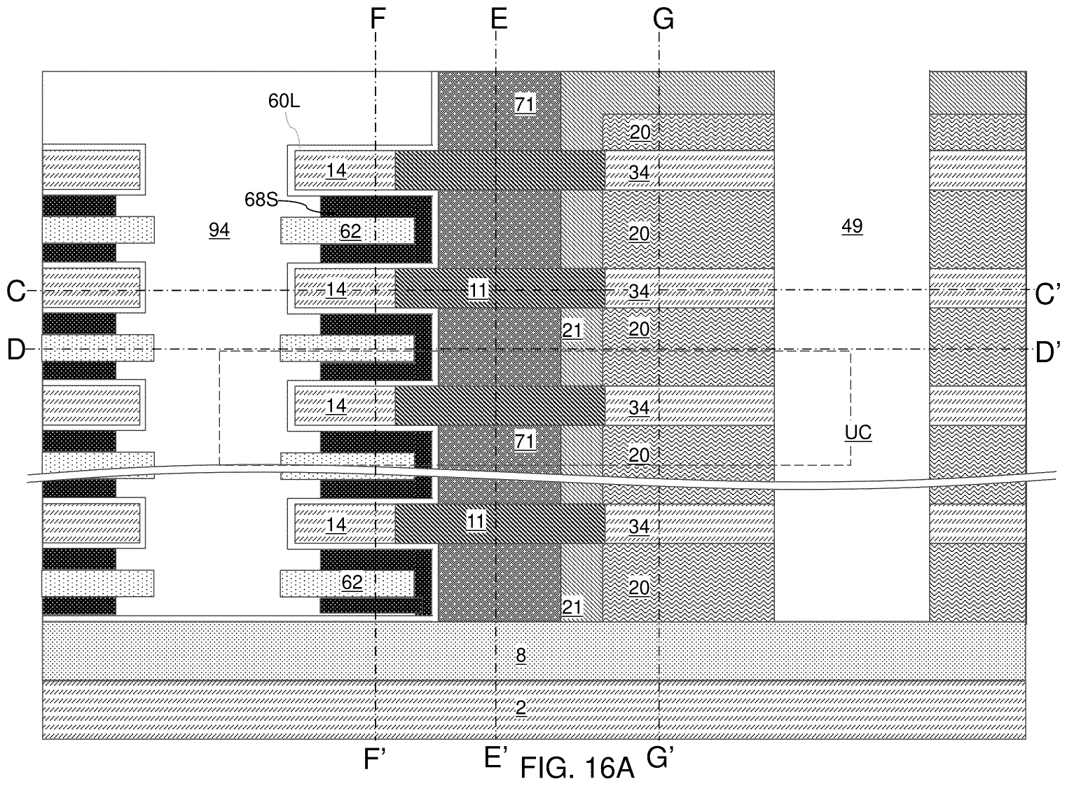

Referring to FIGS. 15A, 15B, 15C, 15D, 15E, 15F, and 15G, a dielectric fill material, such as undoped silicate glass (i.e., silicon oxide) or a doped silicate glass, can be deposited in the bit-line trenches 99. A planarization process, such as a chemical mechanical polishing process, can be performed to remove portions of the dielectric fill material from above the horizontal plane including the top surfaces of the sacrificial perforated wall structures 71. Each remaining portion of the dielectric fill material that fills the bit-line trenches 99 comprises a bit-line trench isolation structure 94. In one embodiment, top surfaces of the bit-line trench isolation structures 94 may be formed within the horizontal plane including the top surfaces of the sacrificial perforated wall structures 71 and/or the sacrificial source trench fill structures 47. A laterally alternating sequence of bit-line trench isolation structures 94 and sacrificial source trench fill structures 47 can be arranged along the first horizontal direction hd1.

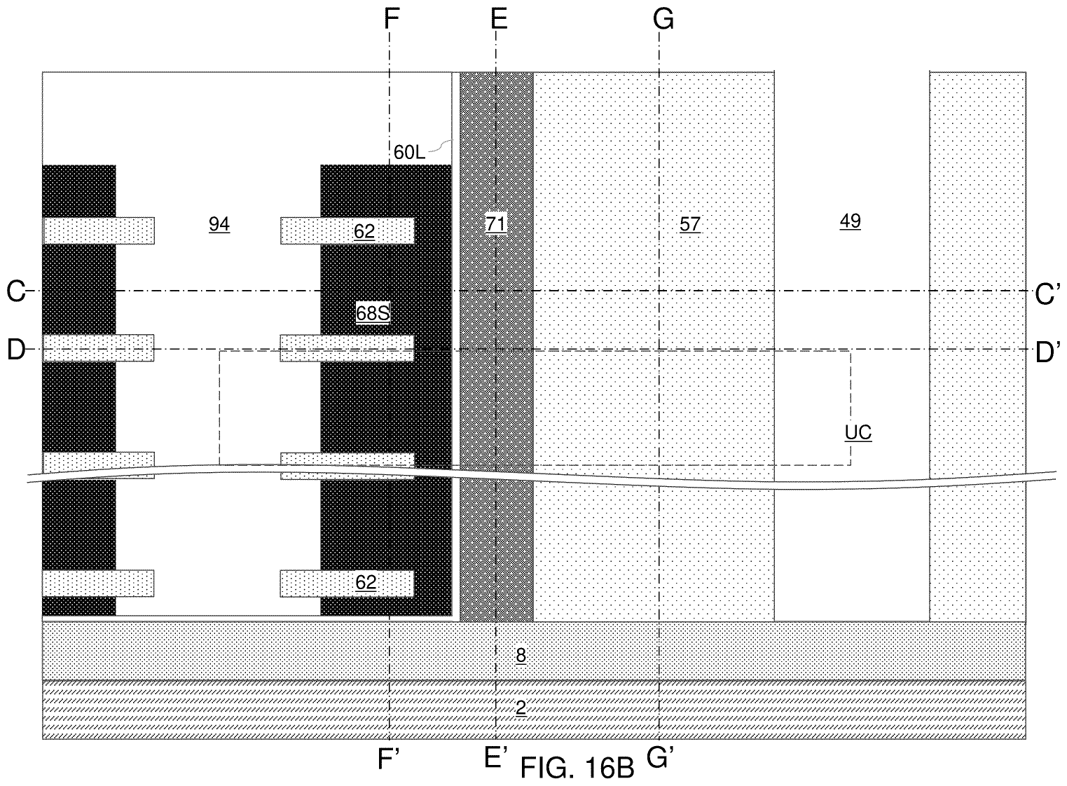

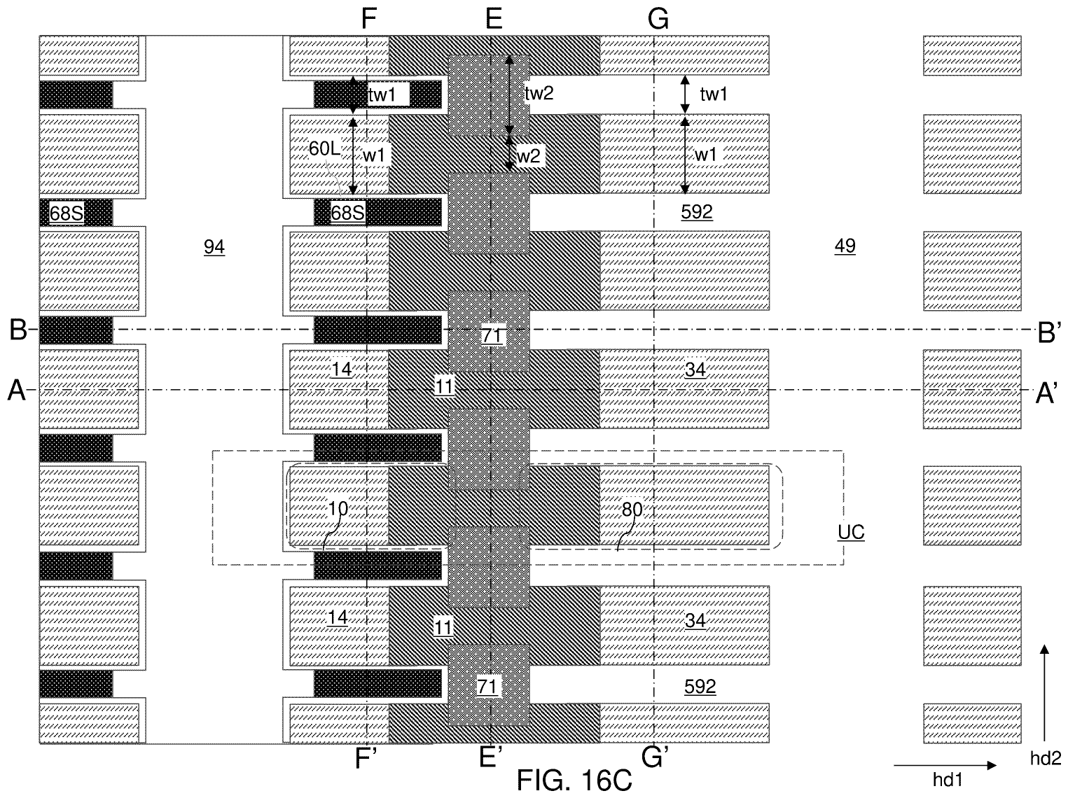

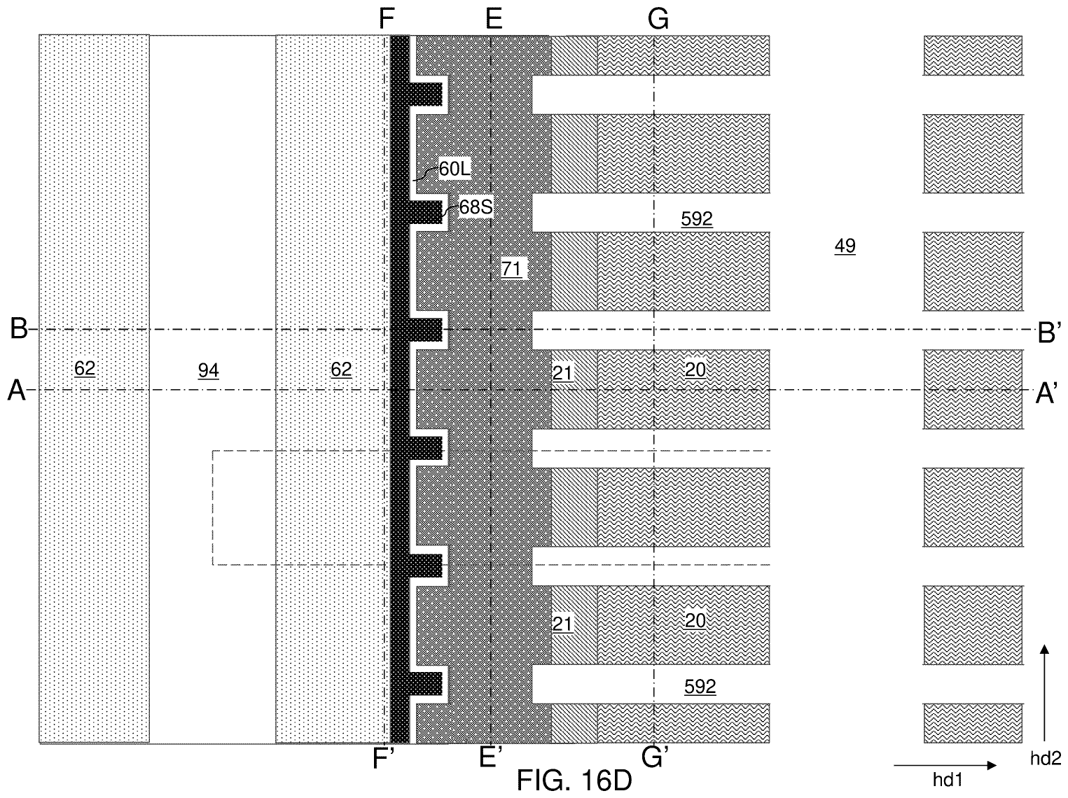

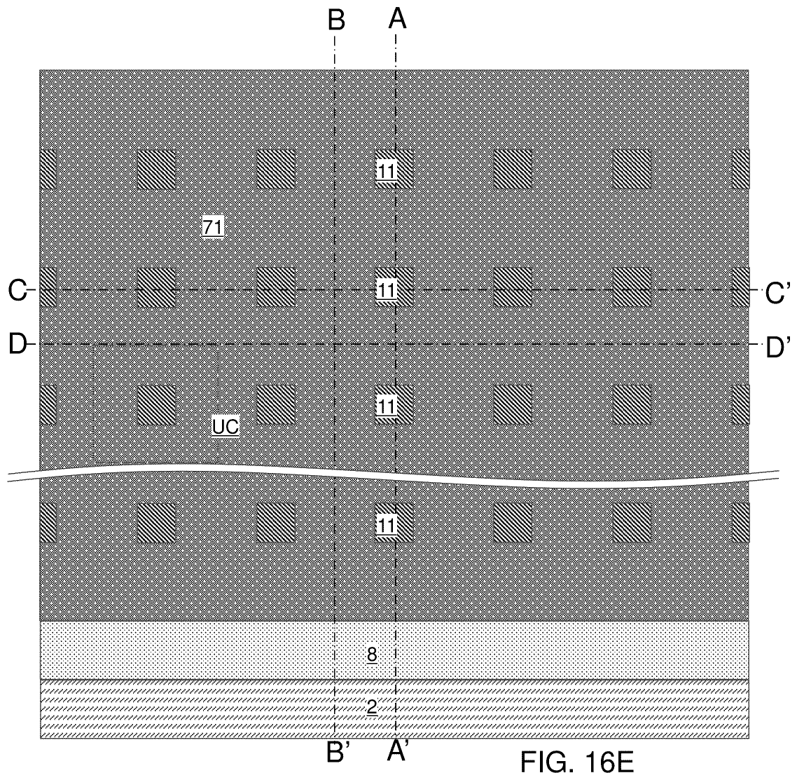

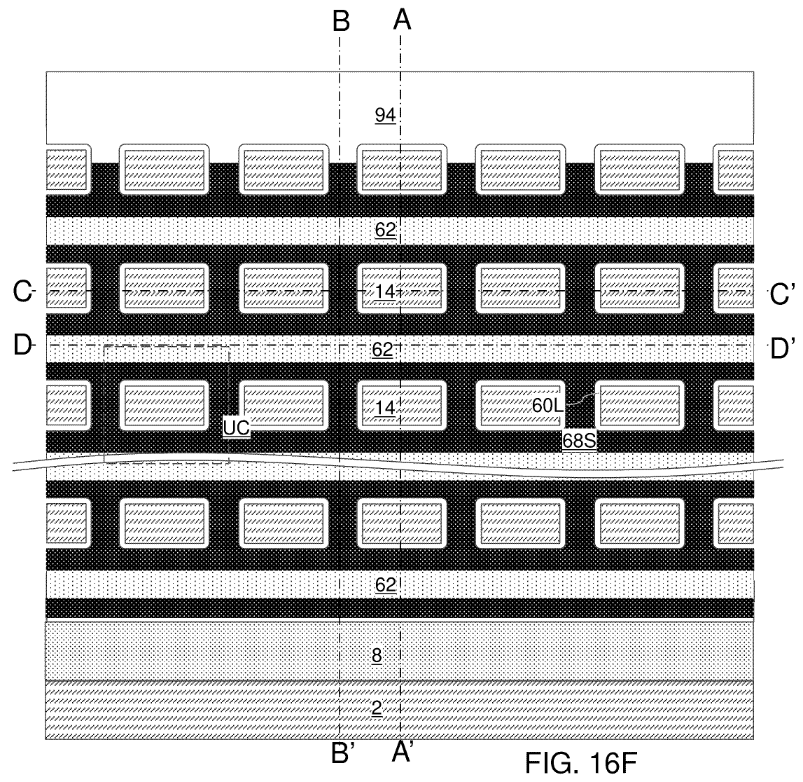

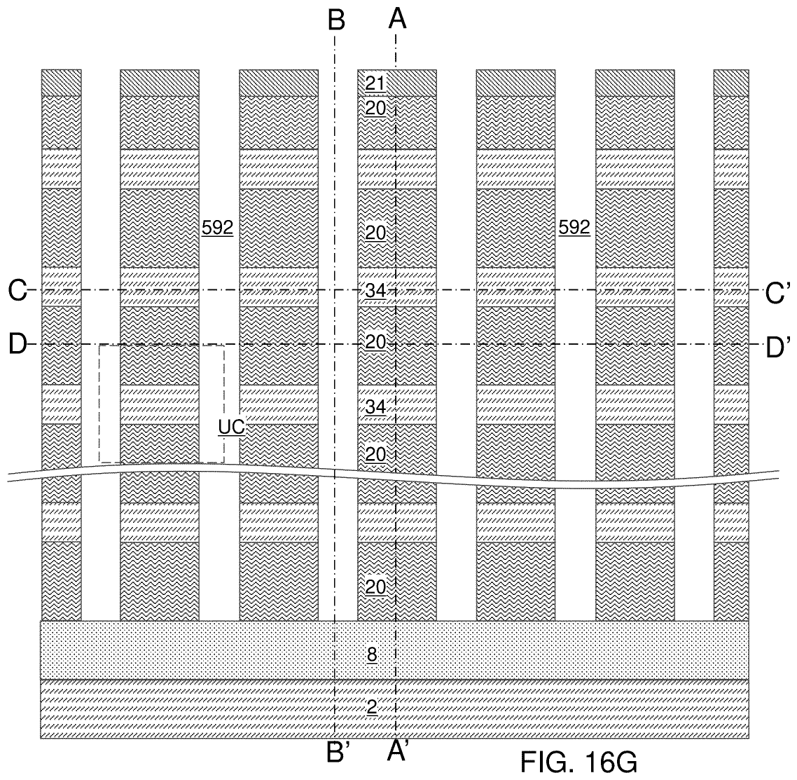

Referring to FIGS. 16A, 16B, 16C, 16D, 16E, 16F, and 16G, an etch mask layer (not illustrated), such as a photoresist layer, can be formed over the first exemplary structure, and can be patterned to form openings over the areas of the sacrificial source trench fill structures 47 and a second subset of the sacrificial isolation trench fill structure 57 that contacts a respective one of the sacrificial source trench fill structures 47. The etch mask layer can cover each of the sacrificial perforated wall structures 71 and the bit-line trench isolation structures 94.

At least one third selective material removal process can be performed to remove the sacrificial source trench fill structures 47 and the second subset of the sacrificial isolation trench fill structure 57 selectively to the materials of the semiconductor rails (14, 11, 34), the etch stop structure 8, and sacrificial perforated wall structures 71. In an illustrative example, if the sacrificial source trench fill structures 47 comprise silicon nitride, a wet etch process employing hot phosphoric acid may be performed to remove the sacrificial source trench fill structures 47 without removing the second subset of the sacrificial isolation trench fill structure 57. If the sacrificial source trench fill structures 47 comprise a carbon-based material such as amorphous carbon or diamond-like carbon, an ashing process may be employed to remove the sacrificial source trench fill structures 47. Voids are formed in the volumes of the source trenches 49. Subsequently, if the second subset of the sacrificial isolation trench fill structure 57 comprises a silicate glass-based material, a wet etch process employing dilute hydrofluoric acid may be performed to etch the second subset of the sacrificial isolation trench fill structure 57 selectively to the materials of the semiconductor rails (14, 11, 34), the etch stop structure 8, and sacrificial perforated wall structures 71. Alternatively, if the sacrificial perforated wall structures 71 comprises a material that is different from the material(s) of the sacrificial source trench fill structures 47 and the sacrificial isolation trench fill structure 57, a single isotropic etch process may be performed to simultaneously etch the material(s) of the sacrificial source trench fill structures 47 and the sacrificial isolation trench fill structure 57. Second lateral isolation trenches 592 are formed in the volumes from which the second subset of the sacrificial isolation trench fill structures 57 are removed. The second lateral isolation trenches 592 are formed between laterally-neighboring pairs of horizontally-extending semiconductor beams 34 by removing the second subset of the sacrificial isolation trench fill structures 57.

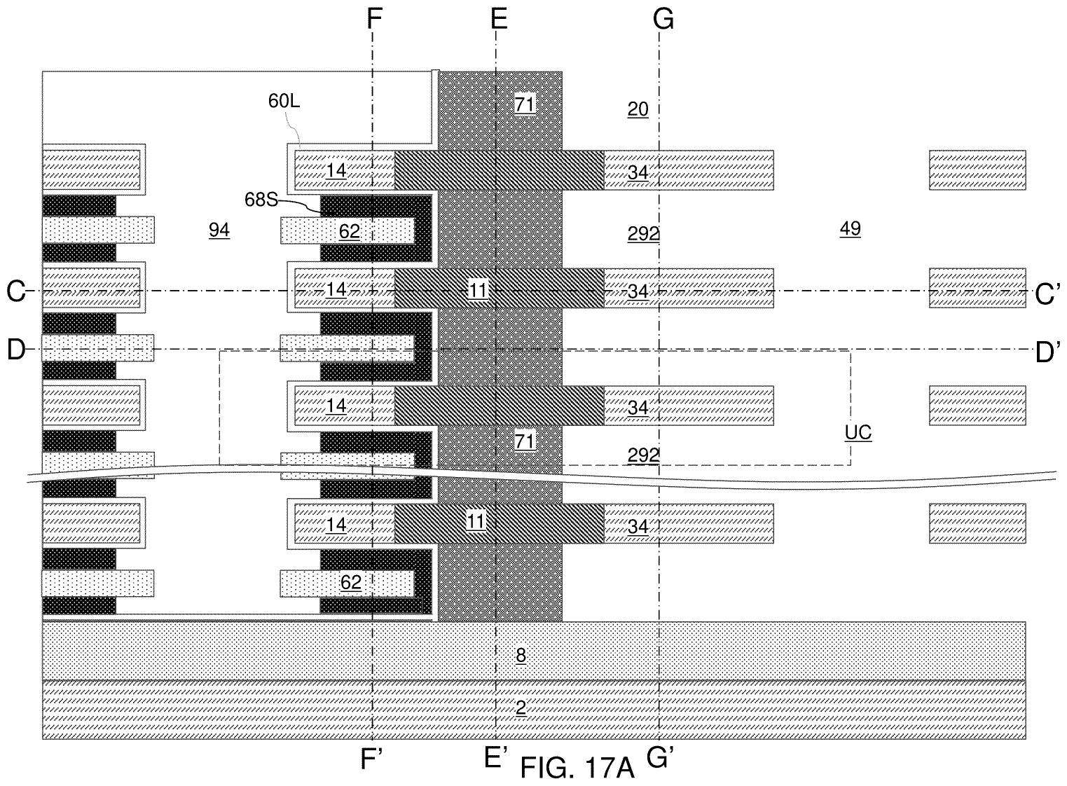

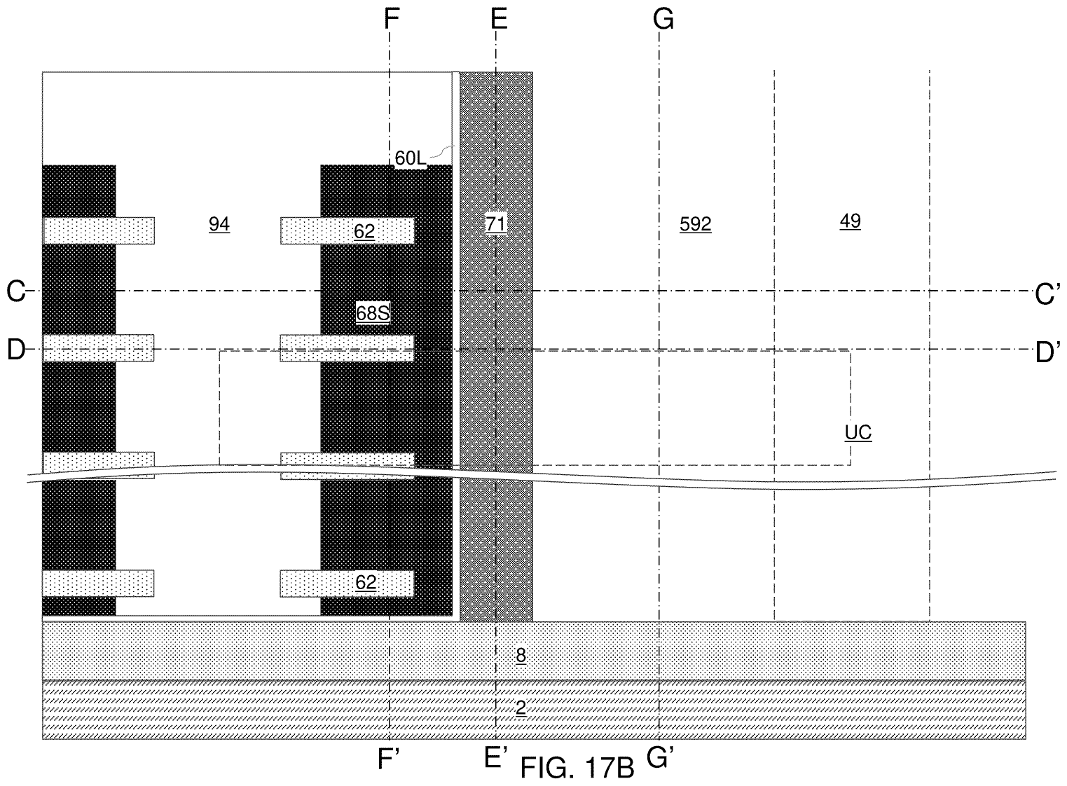

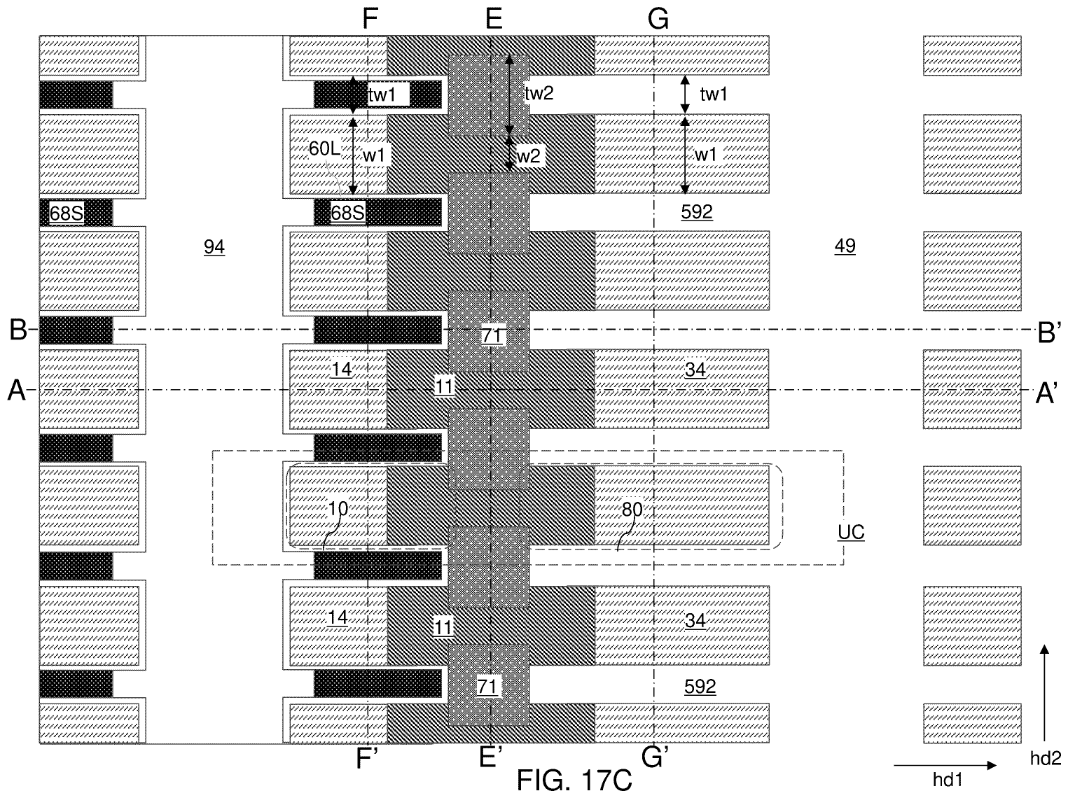

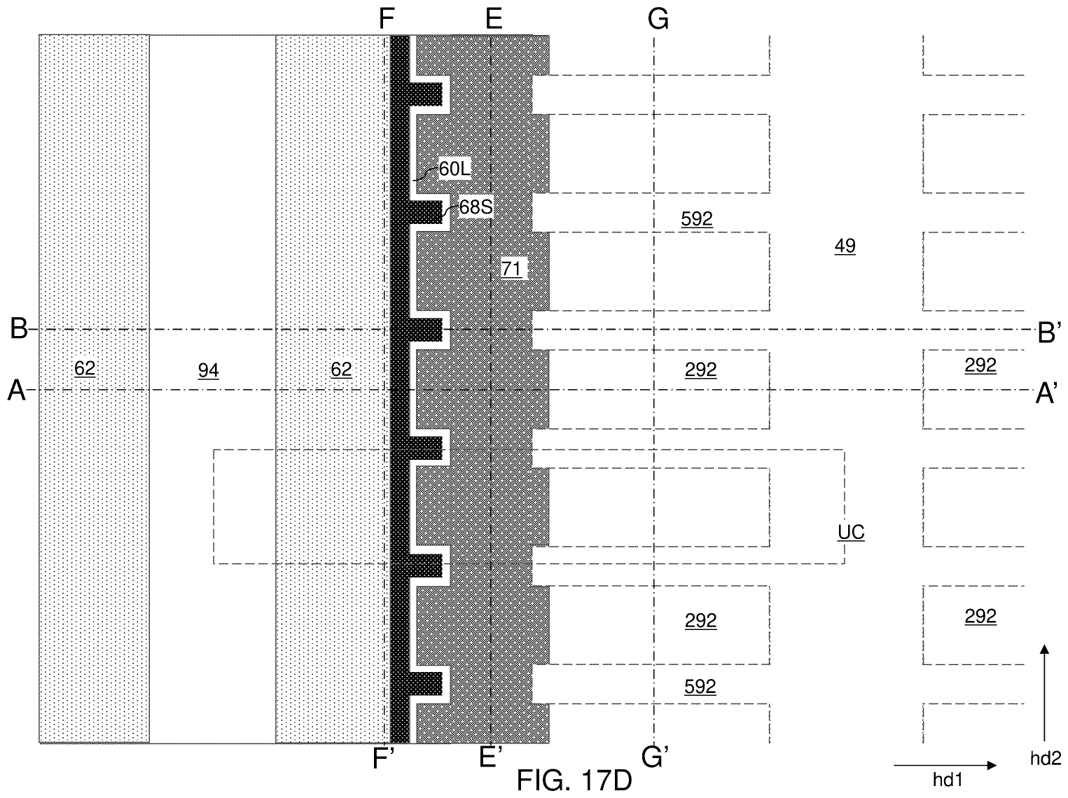

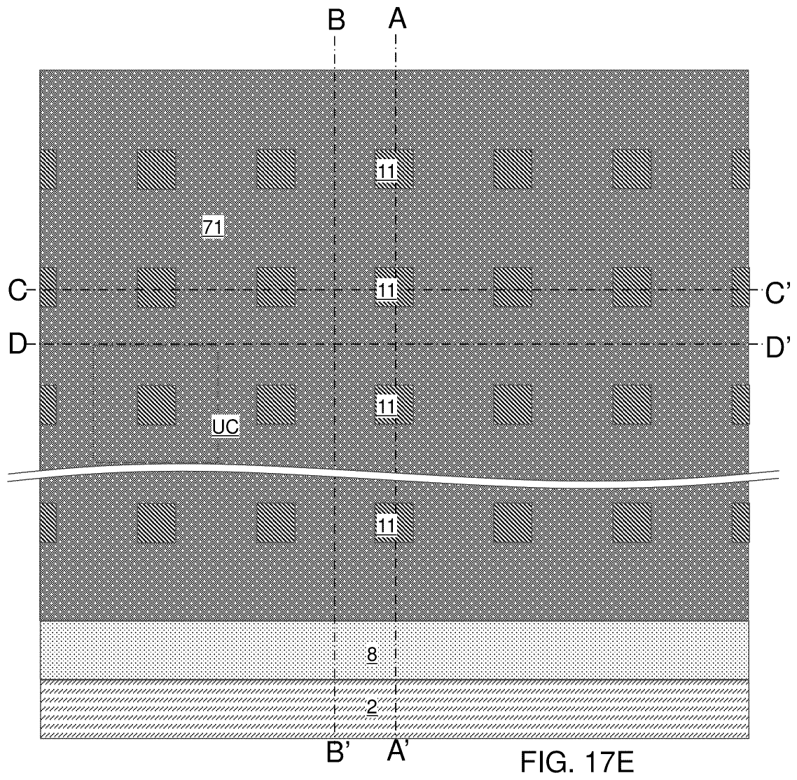

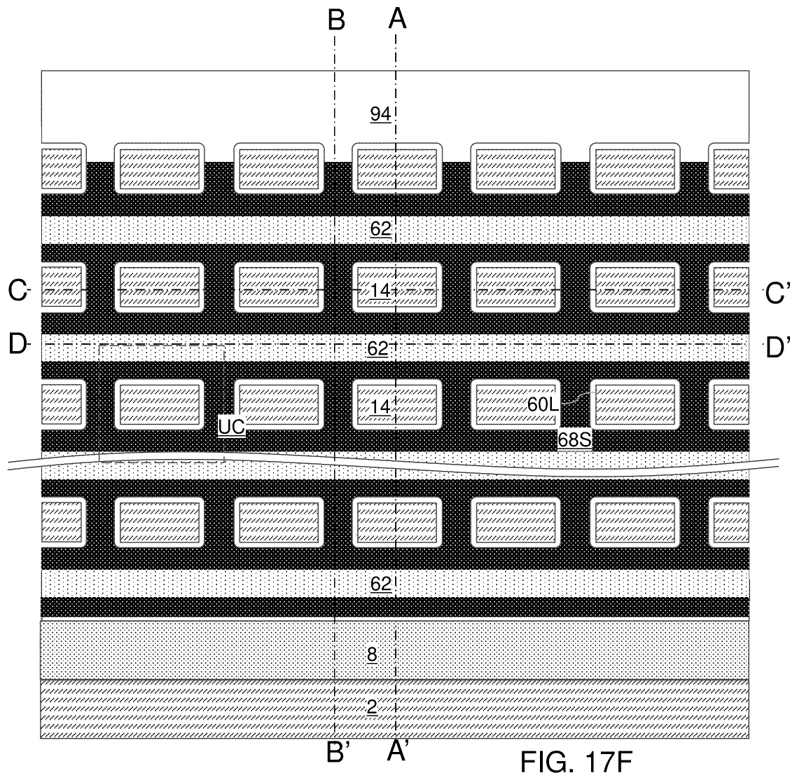

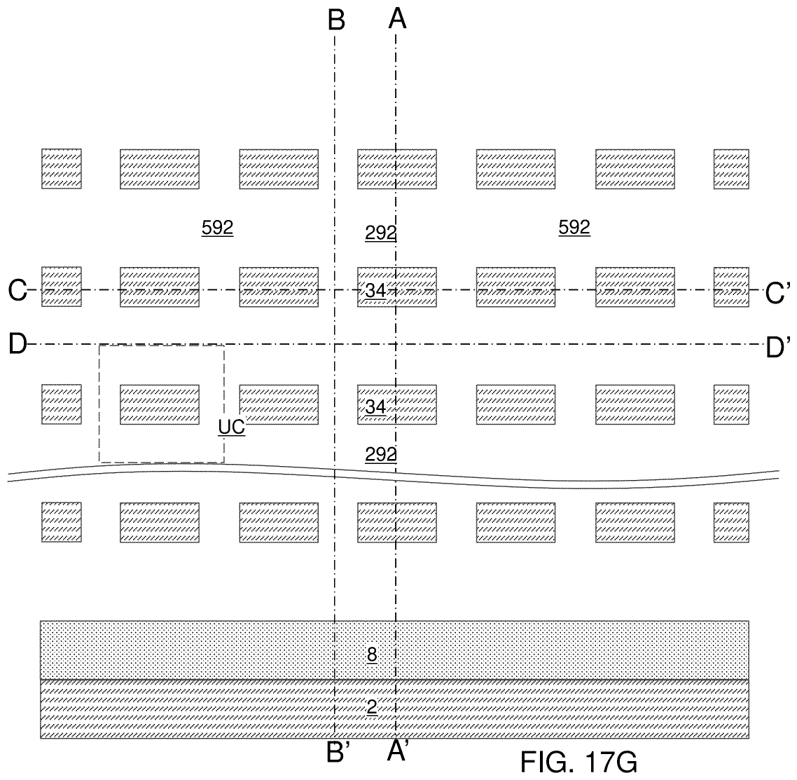

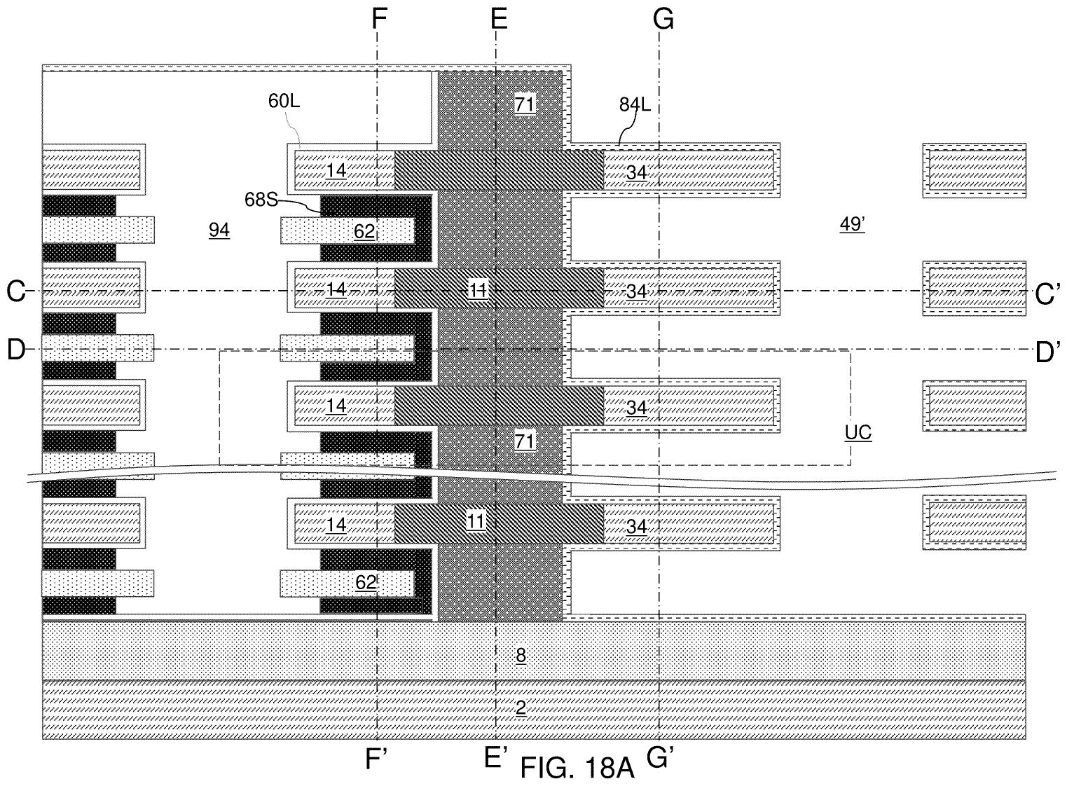

Referring to FIGS. 17A, 17B, 17C, 17D, 17E, 17F, and 17G, at least one fourth selective material removal process may be performed to remove each of the second-type sacrificial rails 20B. Second inter-rail cavities 292 are formed in the volumes from which the second-type sacrificial rails 20B are removed. The second inter-rail cavities 292 are formed between vertically-neighboring pairs of horizontally-extending semiconductor beams 34 by removing the second-type sacrificial rails 20B. The etch mask layer can be subsequently removed.

In alternative embodiments, the set of processing steps described with reference to FIGS. 16A-17G may be replaced with any alternative set of processing steps provided that the materials of the sacrificial source trench fill structure 47, the second subset of the sacrificial isolation trench fill structures 57, and the second-type sacrificial rails 20B are removed.

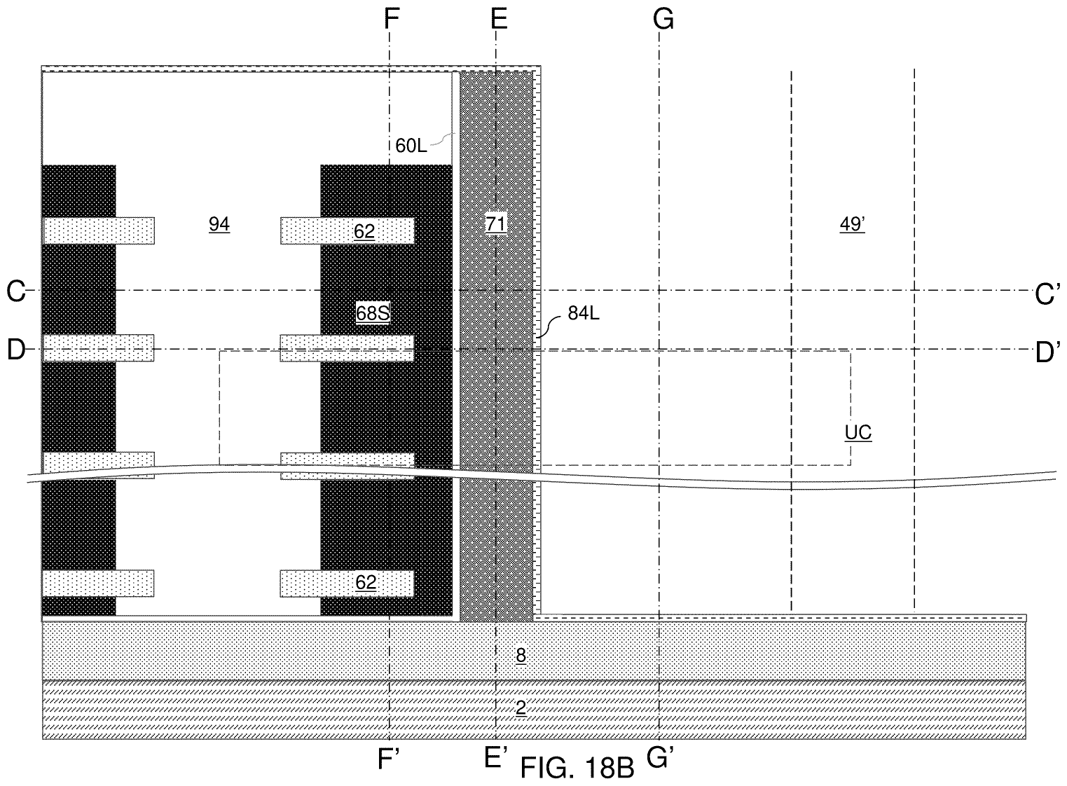

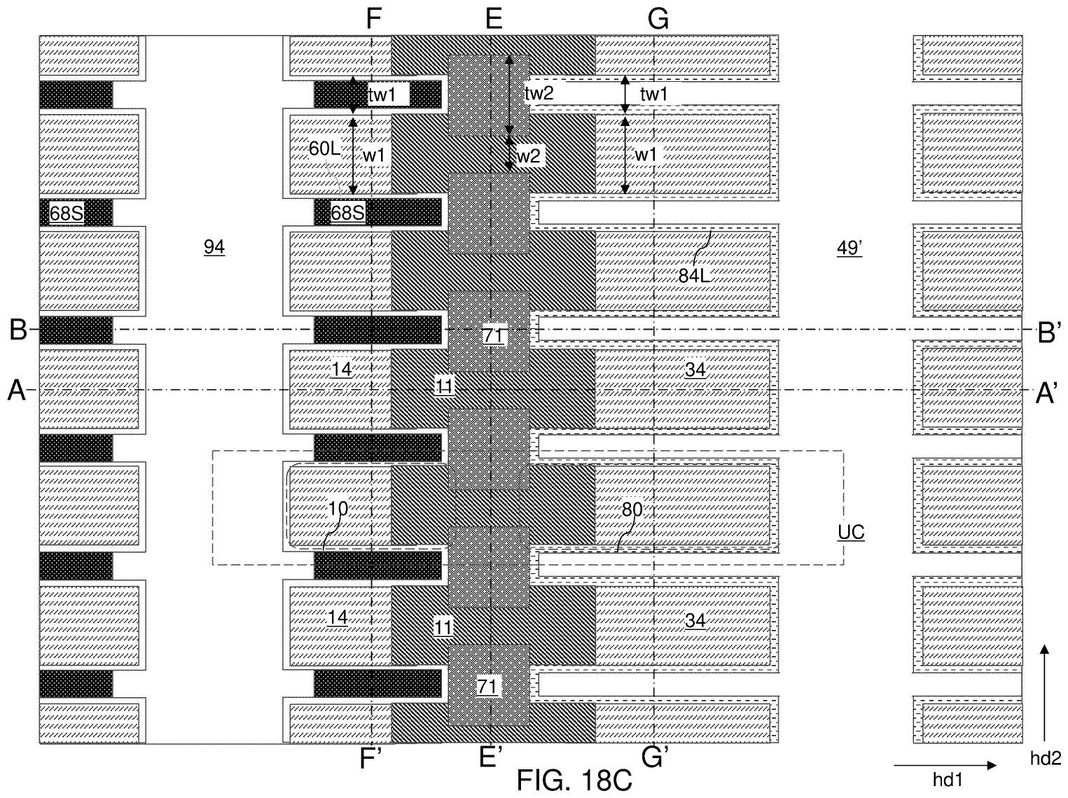

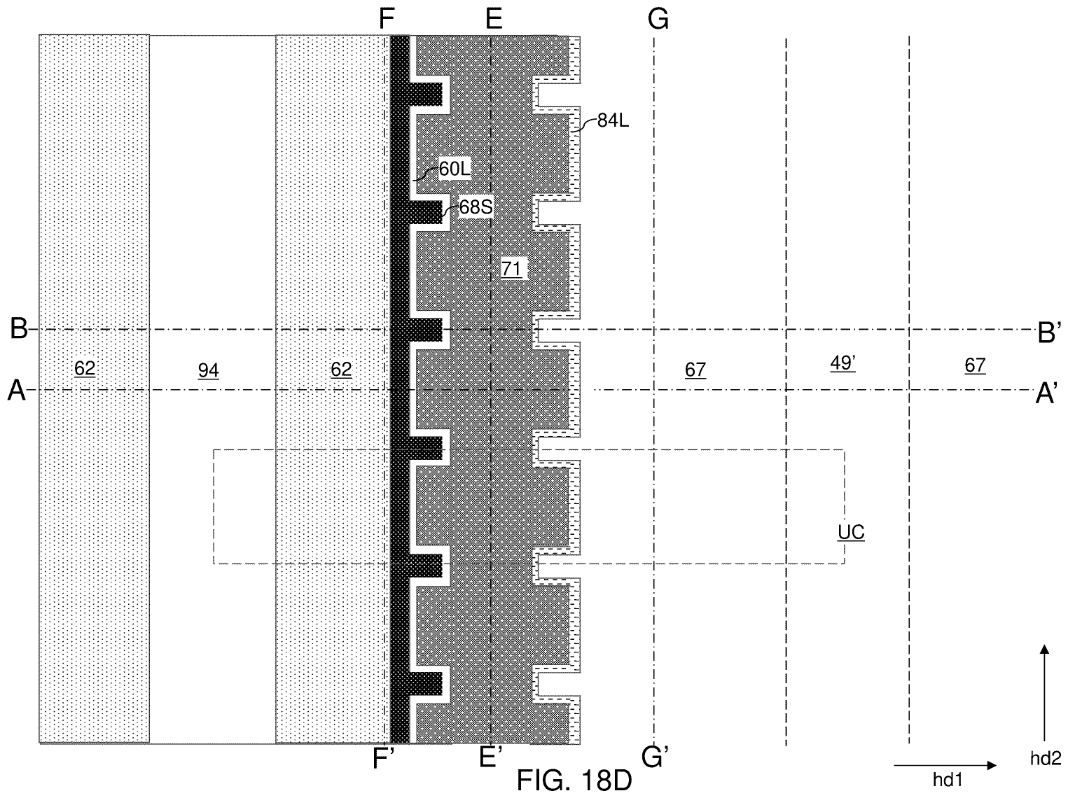

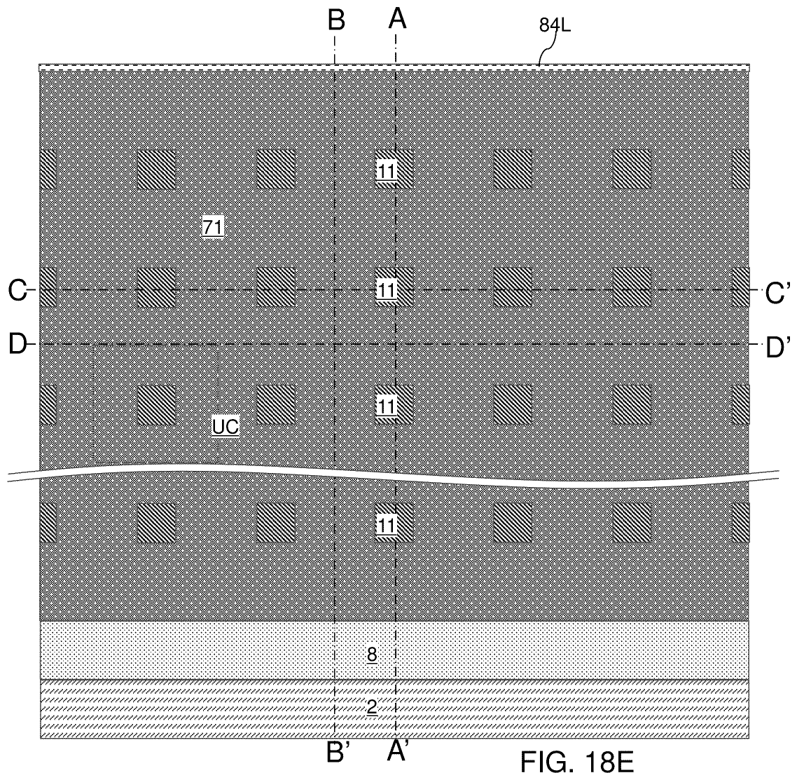

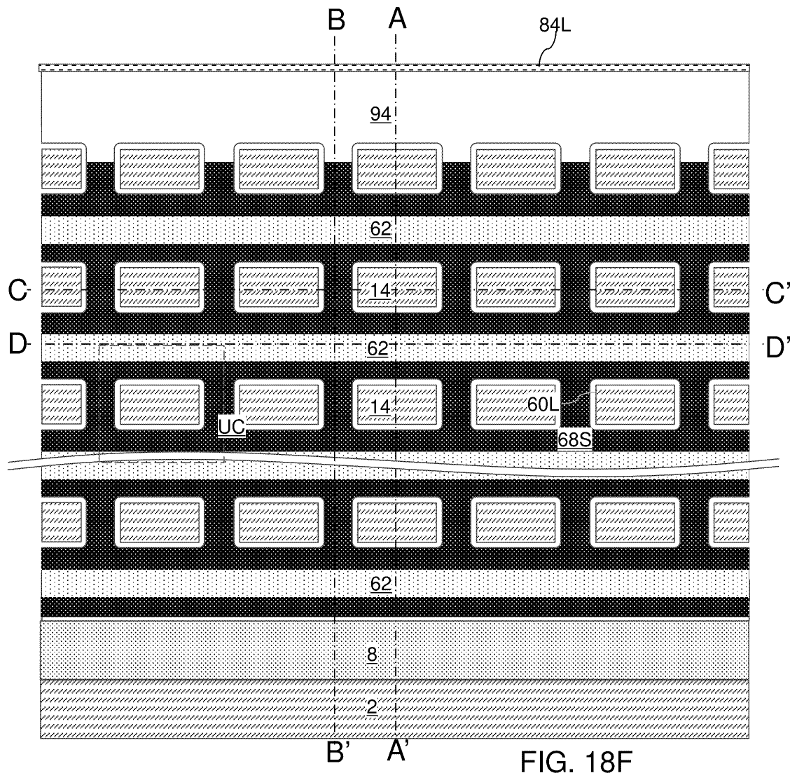

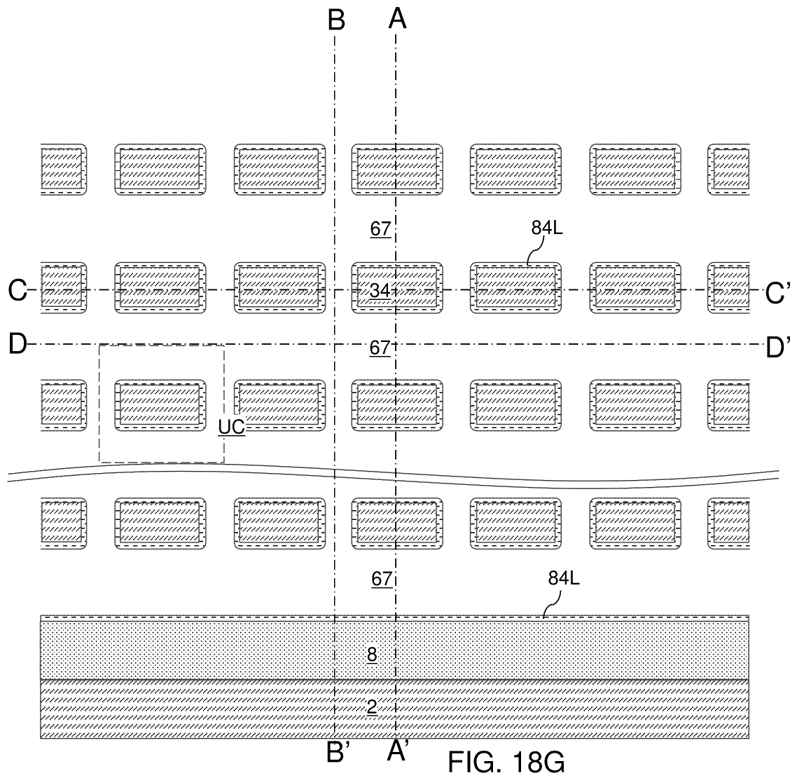

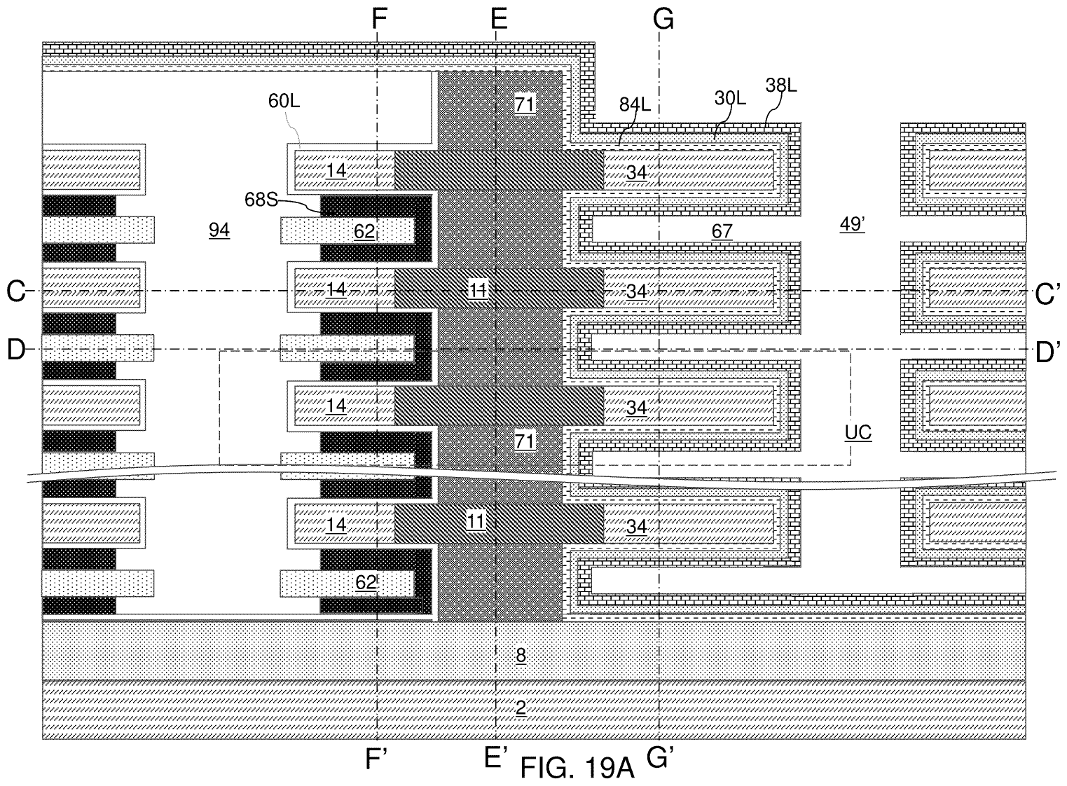

Referring to FIGS. 18A, 18B, 18C, 18D, 18E, 18F, and 18G, a channel material layer 84L can be formed at least on the physically exposed surfaces of the horizontally-extending semiconductor beams 34. The channel material layer 84L may comprise any semiconductor channel material.

The channel material layer 84L may comprise at least one elemental semiconductor material, such as germanium. In one embodiment, the channel material layer 84L may comprise a compound semiconductor material, such as silicon-germanium, a III-V compound semiconductor material, a II-VI compound semiconductor material, a metal oxide semiconductor material (such as indium gallium zinc oxide (IGZO), indium tin zinc oxide (ITZO), zinc oxide, zinc oxynitride or titanium oxide), or an organic semiconductor material. Generally, the channel material layer 84L may comprise a semiconductor that can provide modulated resistance or transconductance depending on the state of the memory material layer to be subsequently formed. For example, ferroelectric field effect transistors (FeFETs) having a hafnium oxide ferroelectric gate dielectric layer and silicon germanium or metal oxide semiconductor channel materials exhibit higher endurance than FeFETs with having a hafnium oxide ferroelectric gate dielectric layer and silicon channel. Thus, the channel material layer 84L that includes at least one non-silicon material provides a FeFET with higher endurance and improved reliability.

The channel material layer 84L may be deposited by a conformal deposition process or by a selective deposition process. The availability of a selective deposition process for deposition of the material of the channel material layer 84L generally depends on the material composition of the channel material layer 84L. In one embodiment shown in FIGS. 18A-18G, the channel material layer 84L may be deposited by a conformal deposition process, such as a chemical vapor deposition process or an atomic layer deposition process. In this case, the channel material layer 84L can be conformally deposited on all physically exposed surfaces of the first exemplary structure. The thickness of the channel material layer 84L can be in a range from 1% to 25%, such as from 5% to 15%, of the thickness of the sacrificial layers 20L as provided at the processing steps of FIGS. 1A-1G.

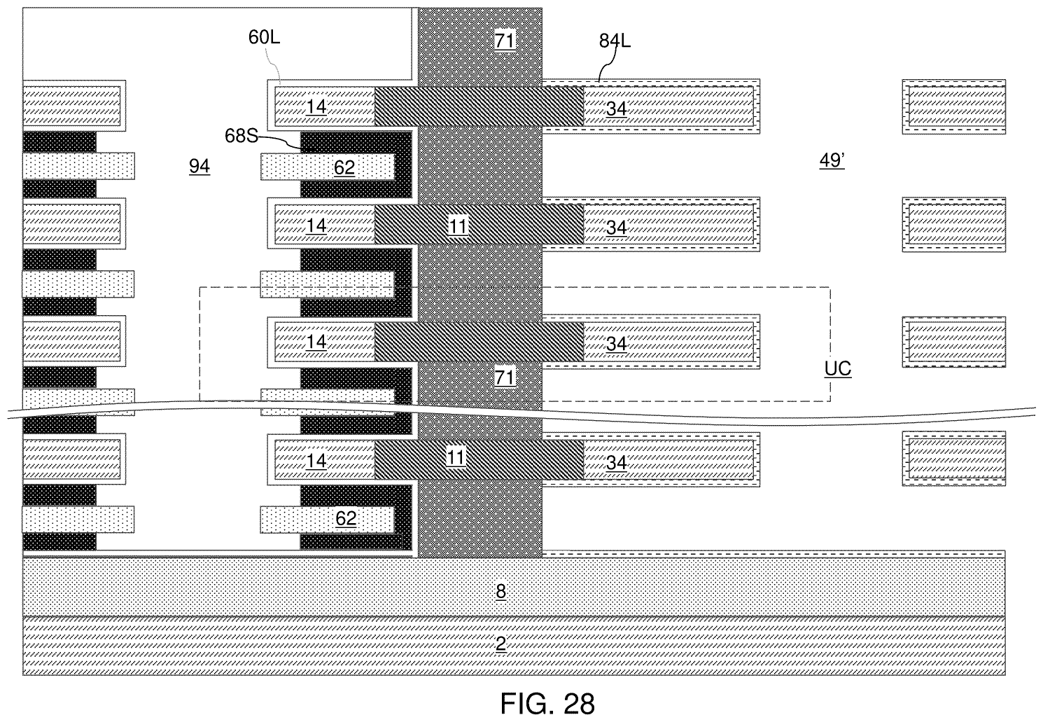

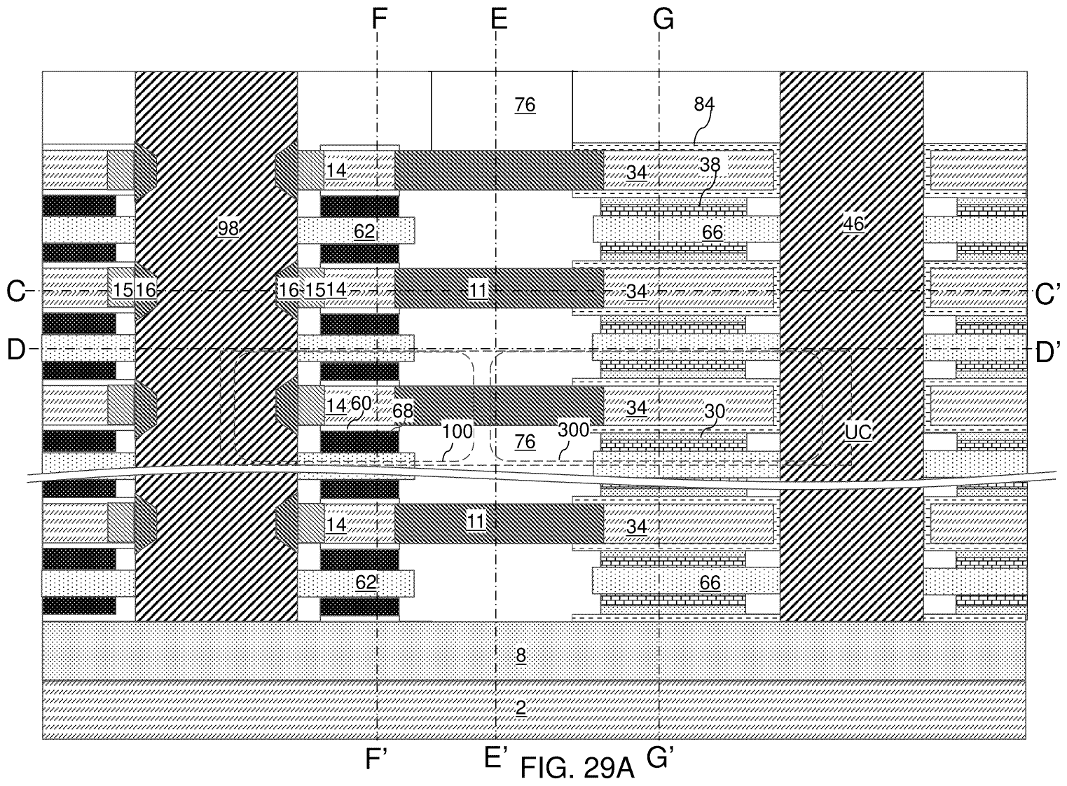

Alternatively, as shown in FIG. 28, the channel material layer 84L may be deposited by a selective deposition process, in which the material of the channel material layer 84L is deposited on semiconductor surfaces of the horizontally-extending semiconductor beams 34 and the doped semiconductor material portions 11, while growth of the material of the channel material layer 84L from dielectric surfaces, such as the surfaces of the bit-line trench isolation structures 94 and the sacrificial perforated wall structures 71 is suppressed. Exemplary selective semiconductor deposition processes include deposition processes for silicon-germanium, in which hydrogen chloride gas can be flowed concurrently with a semiconductor precursor gas (such as silane, germane, dichlorosilane, digermane, etc.) to selectively deposit silicon germanium on the horizontally-extending semiconductor beams 34 and the doped semiconductor material portions 11.

Each tubular portion of the channel material layer 84L that surrounds a respective horizontally-extending semiconductor beam 34 constitutes a tubular-portion-containing channel for a memory field effect transistor to be subsequently formed. Thus, the tubular-portion-containing channels for the memory field effect transistors can be formed on the second portions of the horizontally-extending semiconductor rails (14, 11, 34), i.e., on the horizontally-extending semiconductor beams 34.

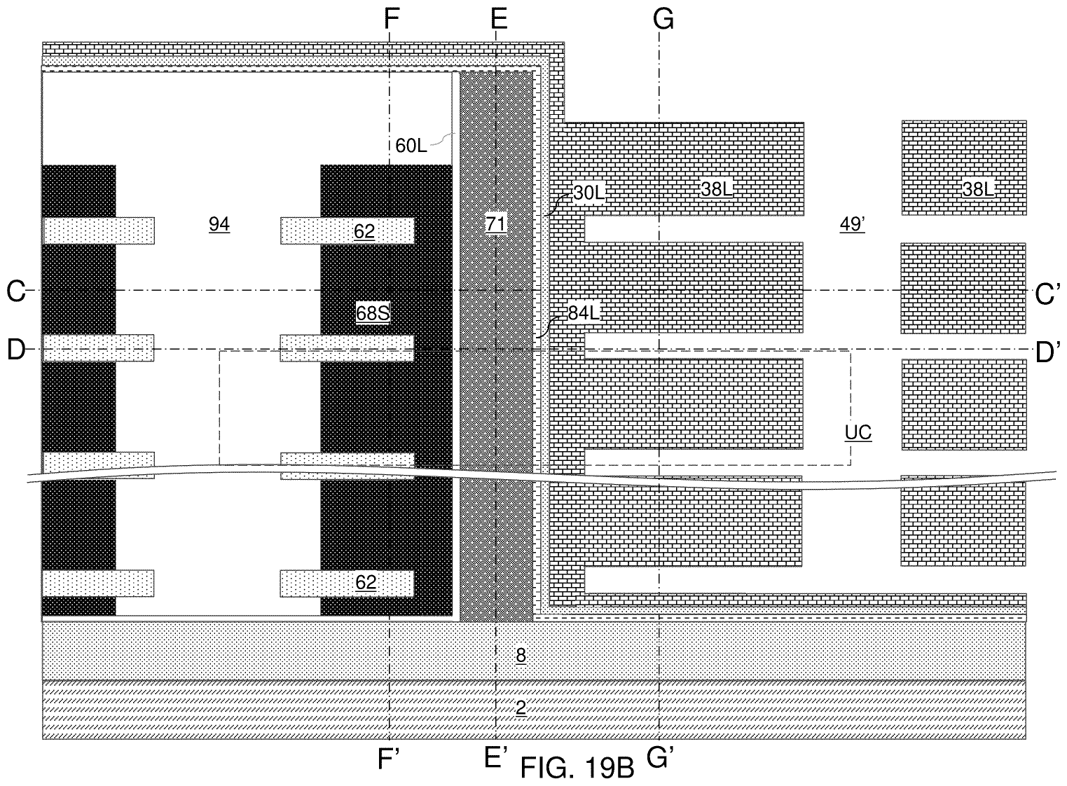

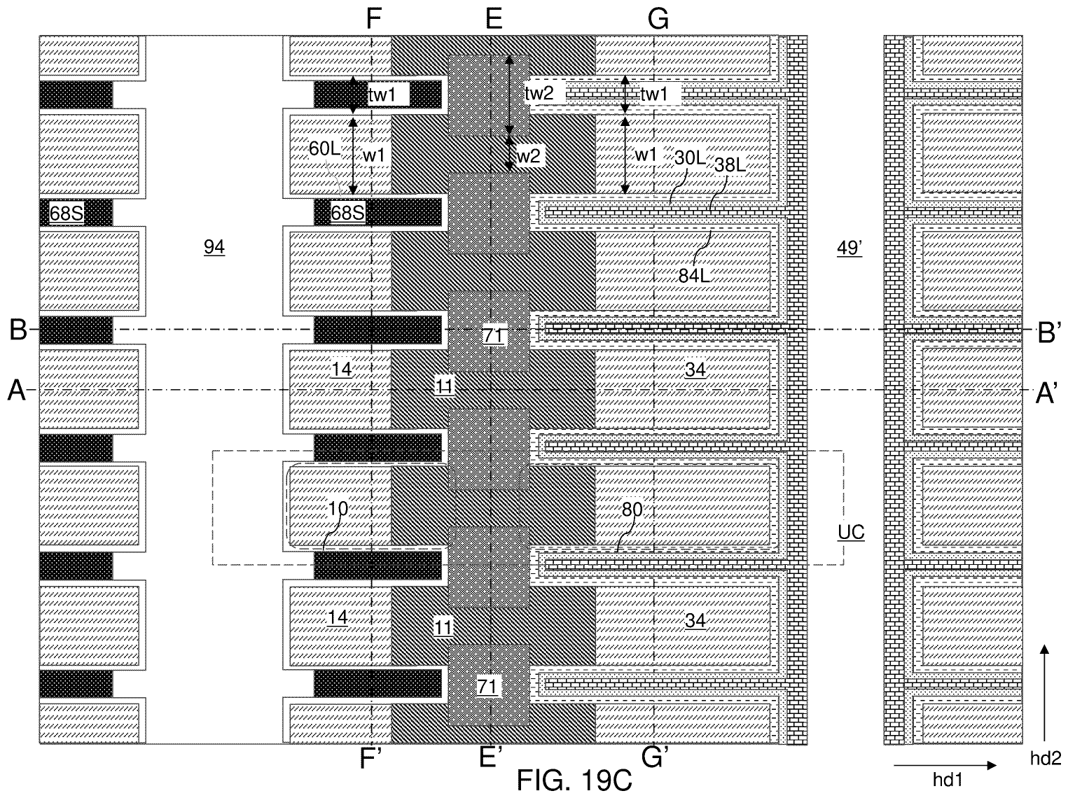

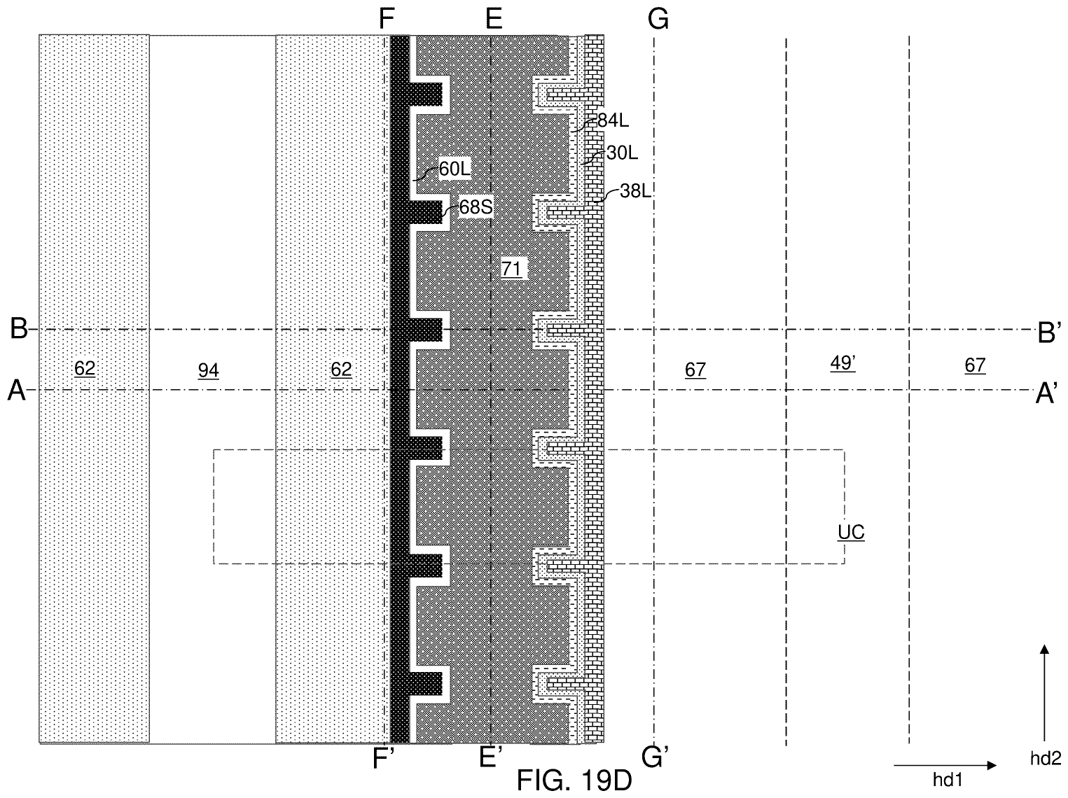

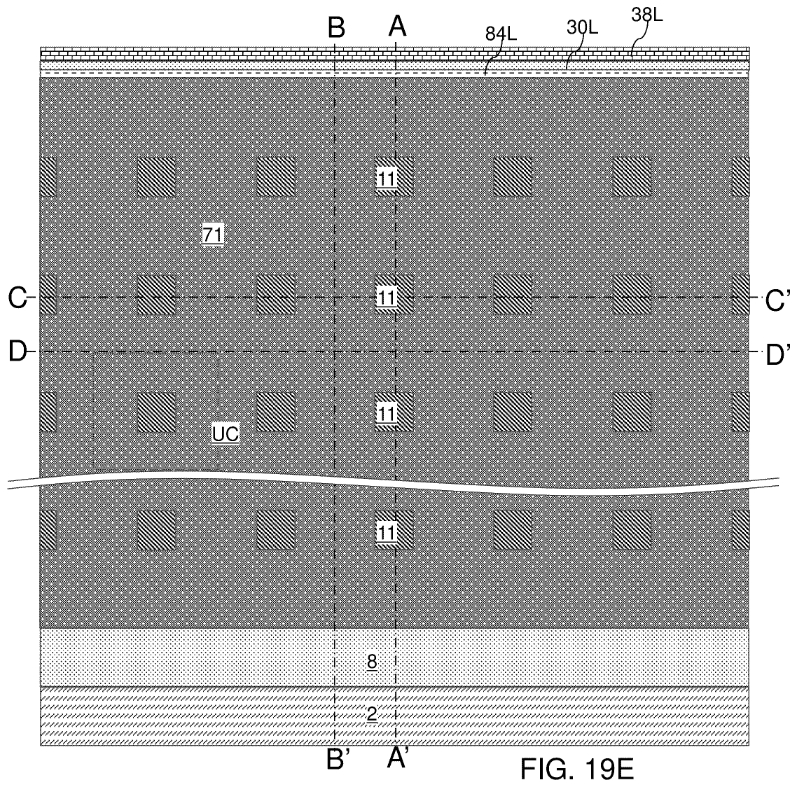

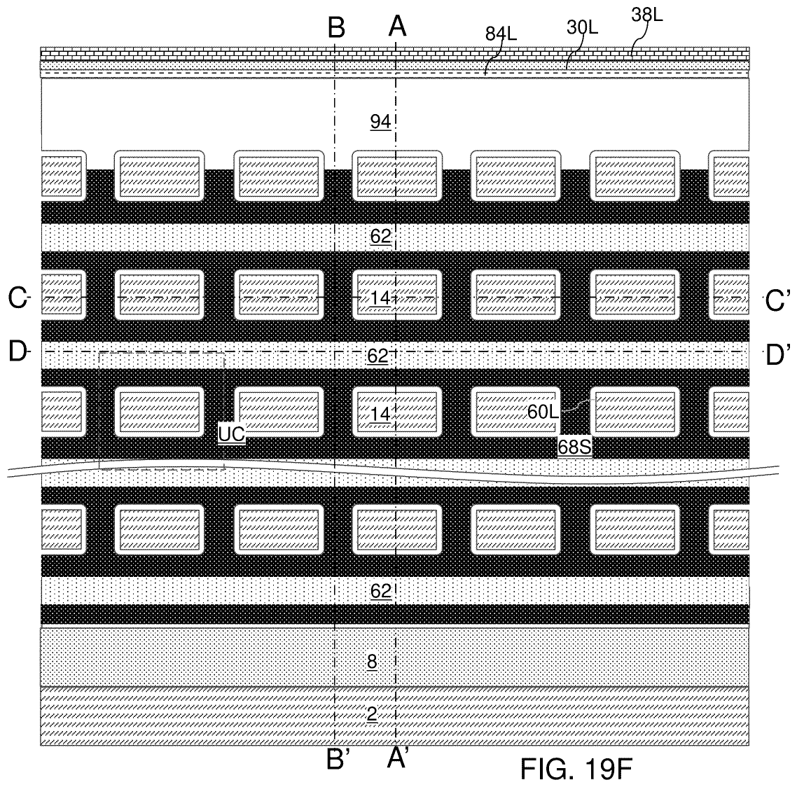

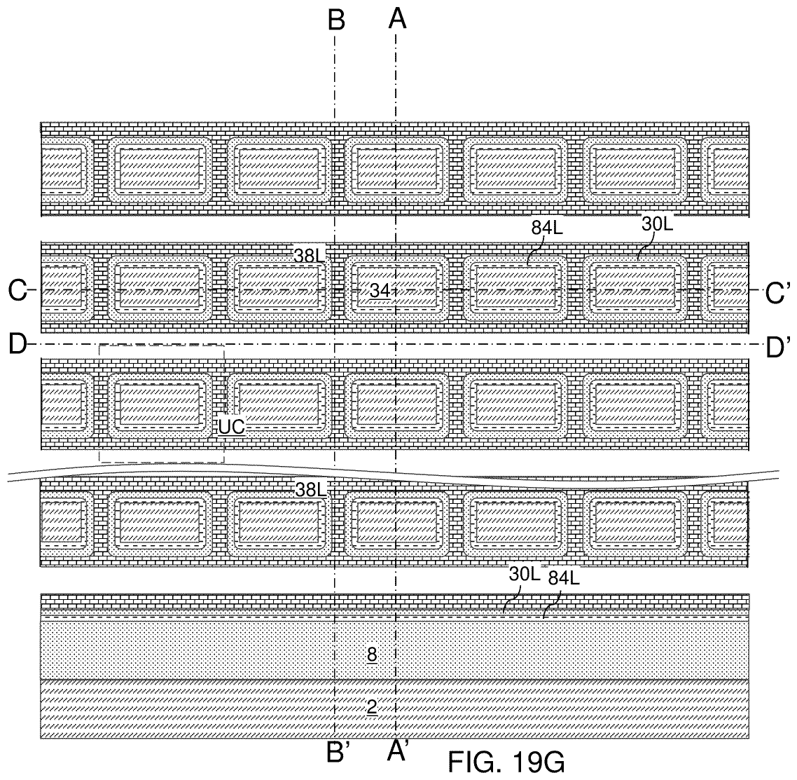

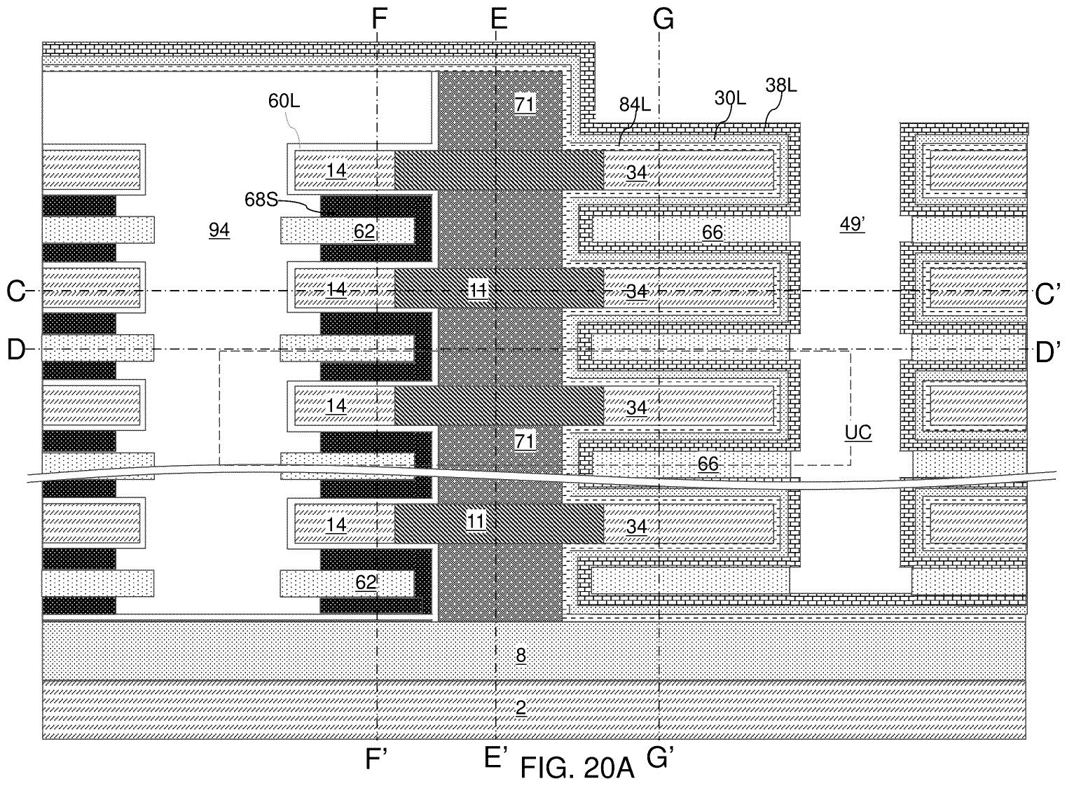

Referring to FIGS. 19A, 19B, 19C, 19D, 19E, 19F, and 19G, a second gate dielectric material can be conformally deposited on the channel material layer 84L to form a second gate dielectric material layer 30L. For example, a chemical vapor deposition process or an atomic layer deposition process may be employed to deposit the second gate dielectric material layer 30L. The thickness of the second gate dielectric material layer 30L may be in a range from 2 nm to 40 nm, such as from 4 nm to 20 nm, although lesser and greater thicknesses may also be employed. According to an aspect of the present disclosure, the second gate dielectric material may comprise a ferroelectric or charge trapping dielectric material having at least two programmable states. In one embodiment, the second gate dielectric material comprises or consists essentially of the ferroelectric dielectric material. Non-limiting examples of ferroelectric dielectric materials include a titanate ferroelectric dielectric material such as barium titanate, lead titanate, lead zirconate titanate, lead lanthanum zirconate titanate (PLZT), potassium niobate (KNbO₃), sodium potassium niobate (KNN), lithium niobate (LiNbO₃), lithium tantalate (LiTaO₃), and bismuth ferrite (BiFeO₃). Other ferroelectric dielectric materials include strontium bismuth tantalate (SBT), polyvinylidene fluoride (PVDF), and its copolymers, zirconium oxide (ZrO₂), hafnium oxide (HfO₂) in a non-centrosymmetric orthorhombic phase, and its doped variants such as zirconium doped hafnium oxide (HZO), aluminum doped hafnium oxide (HfAlO), and lanthanum doped hafnium oxide (HfLaO). In one embodiment, the second gate dielectric material comprises a layer stack including a ferroelectric dielectric material layer and a non-ferroelectric dielectric material layer. In another embodiment, the second gate dielectric material comprises or consists essentially of a charge trapping dielectric material, such as silicon nitride or a stack of silicon oxide, silicon nitride and silicon oxide sublayers. In one embodiment, the second gate dielectric material may comprise a memory dielectric material having at least two programmable states that provide different values of resistance transconductance to a semiconductor material of the channel material layer 84L.

A continuous second gate electrode material layer 38L may be conformally deposited on the second gate dielectric material layer 30L. The continuous second gate electrode material layer 38L comprises a second gate electrode material, which may comprise any suitable conductive material. For example, the continuous second gate electrode material layer 38L may comprise at least one metallic barrier layer, such as TIN, TaN, WN or MON, and a metal fill layer such as W, Ti, Ta, Ru or Mo. The continuous second gate electrode material layer 38L can be formed around each second portion of the horizontally-extending semiconductor rails (14, 11, 34), i.e., around each horizontally-extending semiconductor beam 34. The second gate electrode material of the continuous second gate electrode material layer 38L is deposited as a continuous material layer such that lateral gaps between laterally-neighboring pairs of the second portions of the horizontally-extending semiconductor rails (14, 11, 34) are filled with the second gate electrode material, while vertical gaps between vertically-neighboring pairs of the second portions of the horizontally-extending semiconductor rails (14, 11, 34) are not completely filled with the second gate electrode material. Thus, second laterally-extending voids 67 that laterally extend along the second horizontal direction hd2 are present in unfilled volumes of the vertical gaps between neighboring pairs of second portions of the semiconductor rails (14, 11, 34) after deposition of the second gate electrode material of the continuous second gate electrode material layer 38L. A laterally-extending void 49′ can be present within each source trench 49.

In summary, a second gate dielectric material and a second gate electrode material can be deposited around the tubular-portion-containing channels (i.e., tubular portions of the channel material layer 84L). The second gate dielectric material comprises a memory dielectric material having at least two programmable states that modulate resistance and/or transconductance of the tubular-portion-containing channels at least by an order of magnitude.

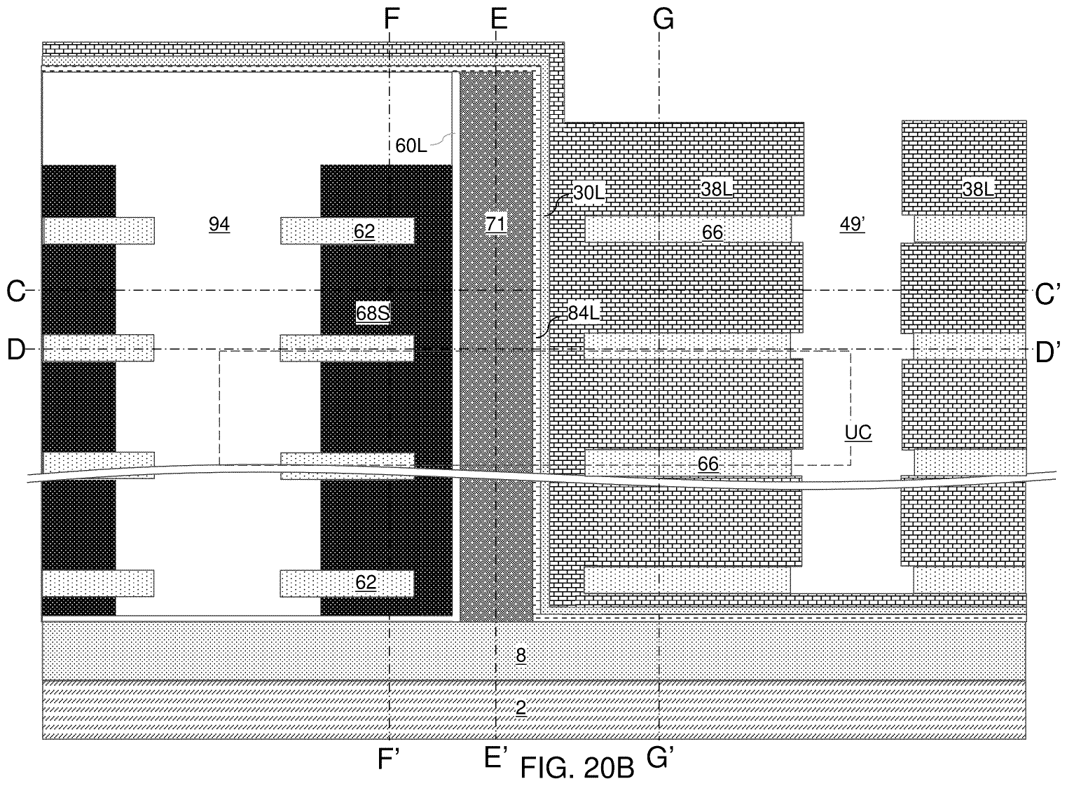

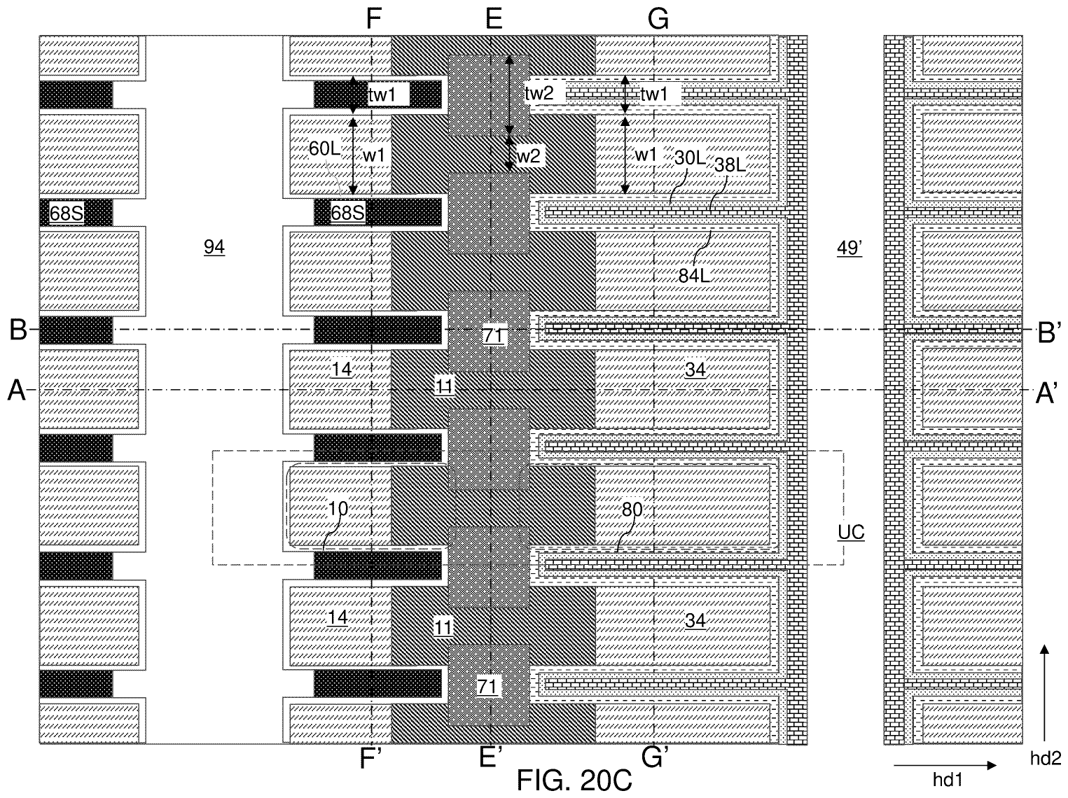

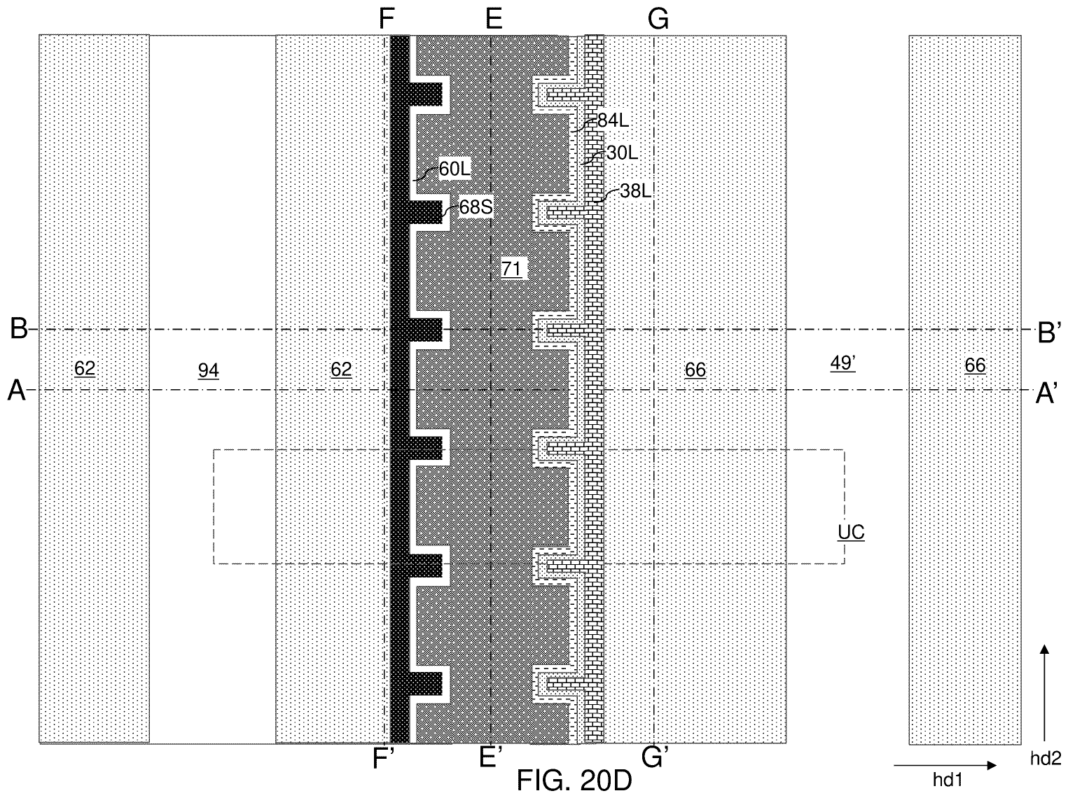

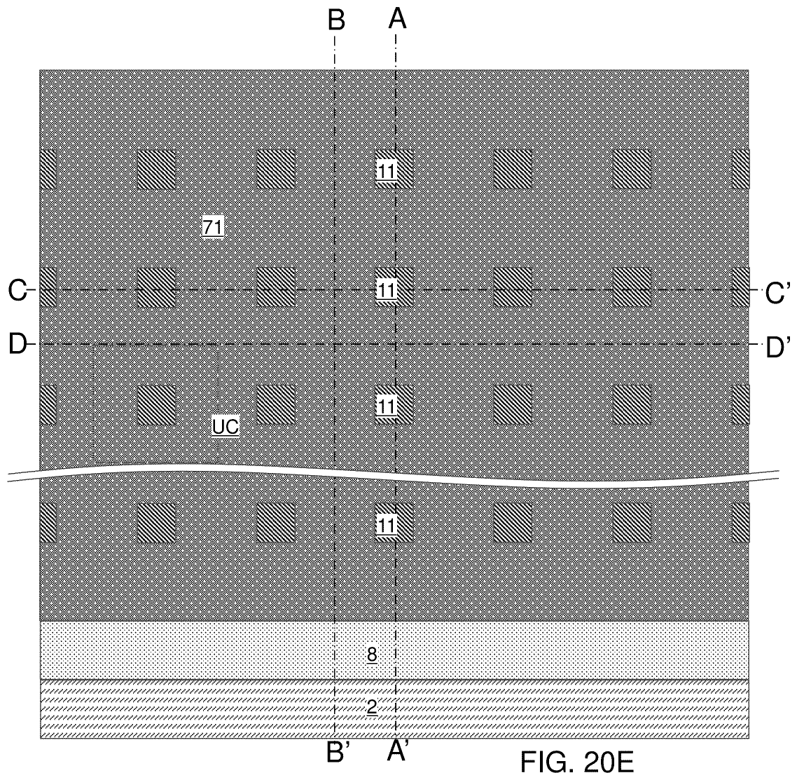

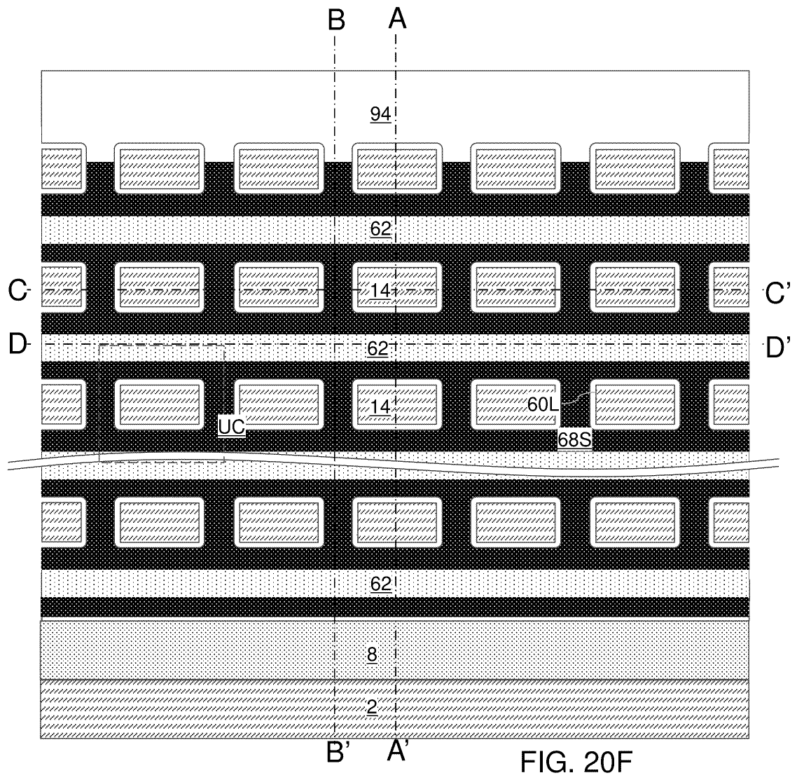

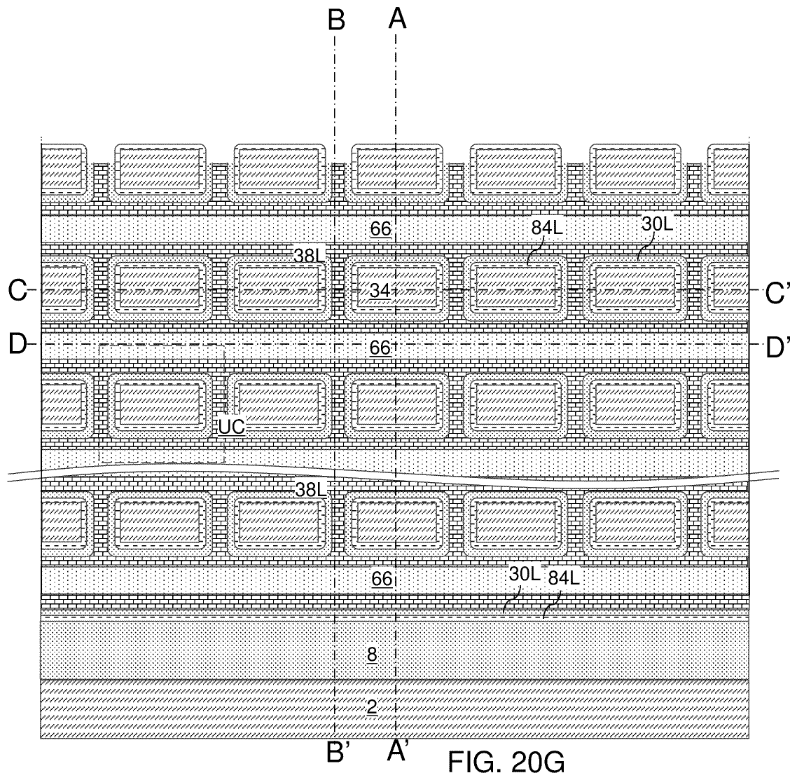

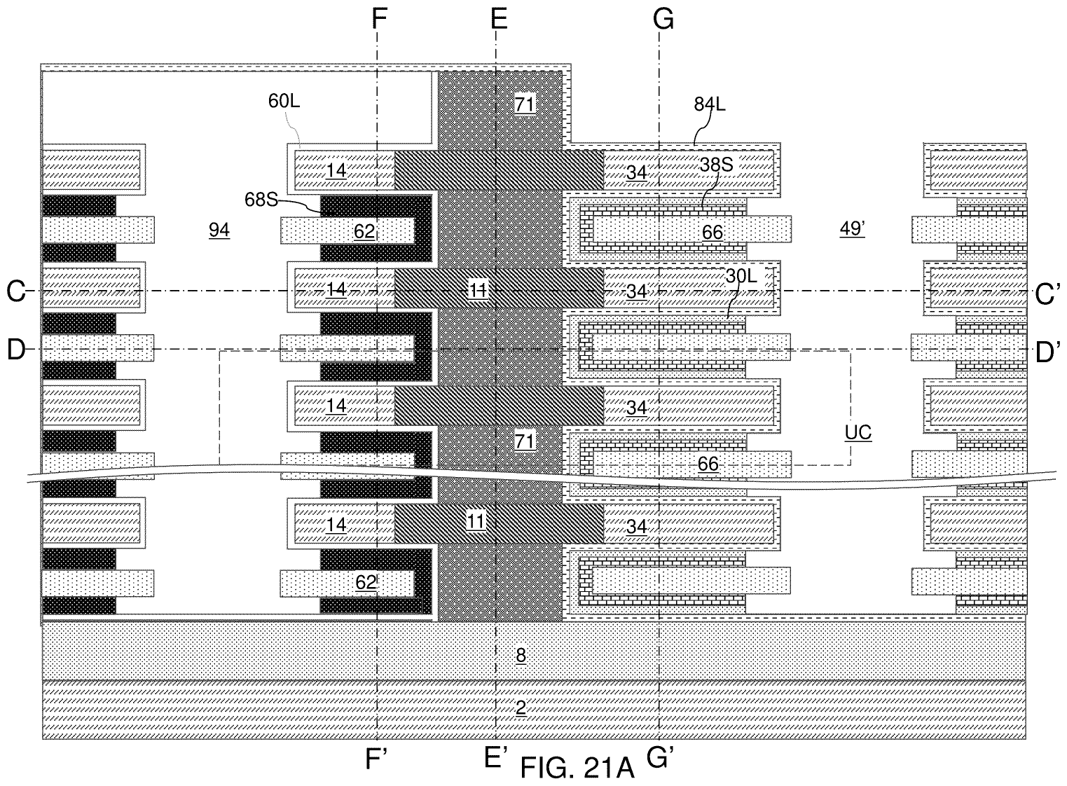

Referring to FIGS. 20A, 20B, 20C, 20D, 20E, 20F, and 20G, a second dielectric fill material, such as silicon oxide can be conformally deposited in the second laterally-extending voids 67, in peripheral portions of the source trenches 49, and over the horizontally-extending portion of the continuous second gate electrode material layer 38L that overlie the three-dimensional array of semiconductor rails (14, 11, 34). A recess etch process may be performed to remove portions of the second dielectric fill material from outside the volumes of the second laterally-extending voids 67. Remaining portions of the second dielectric fill material that fill the second laterally-extending voids 67 comprise a two-dimensional array of second dielectric plates 66. Each second dielectric plate 66 is formed between a respective vertically neighboring pair of laterally extending portions of the continuous second gate electrode material layer 38L that laterally extend along the second horizontal direction hd2.

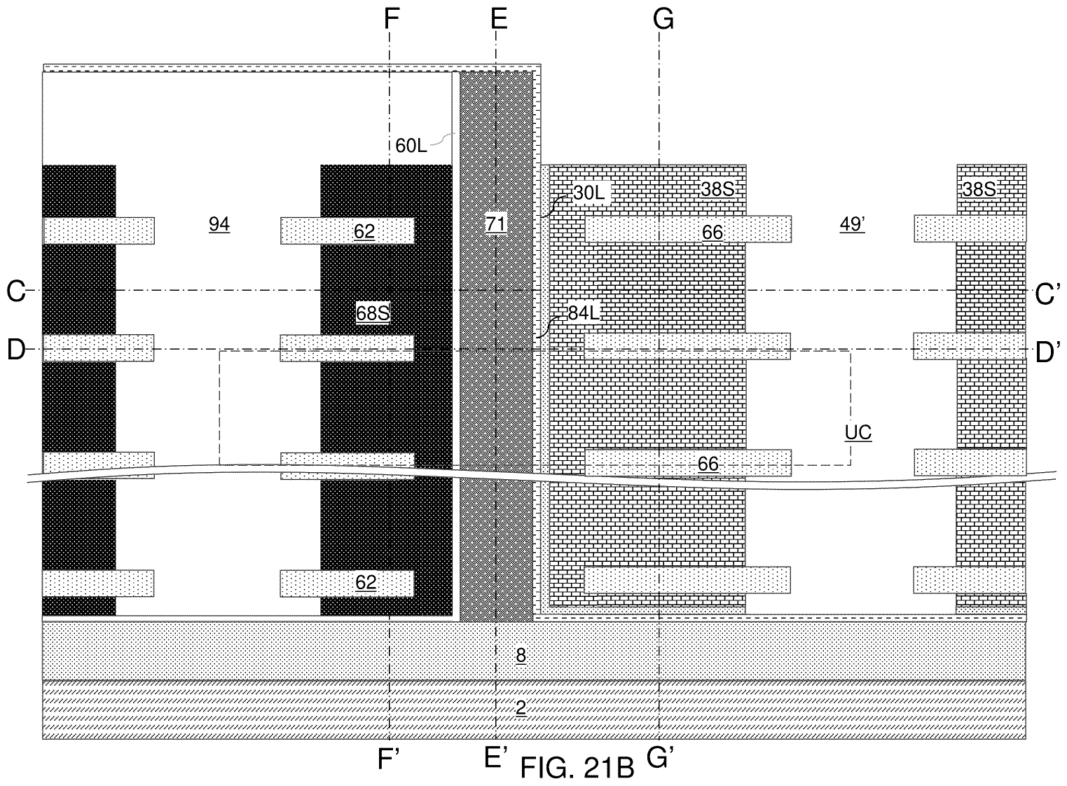

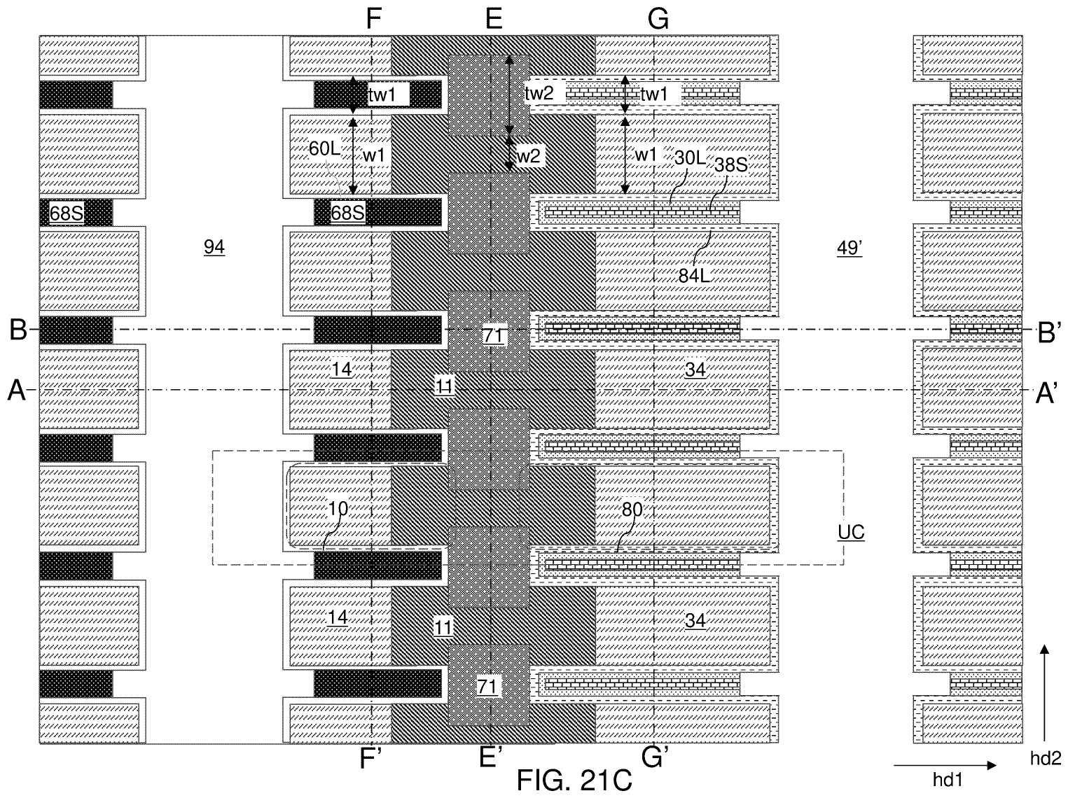

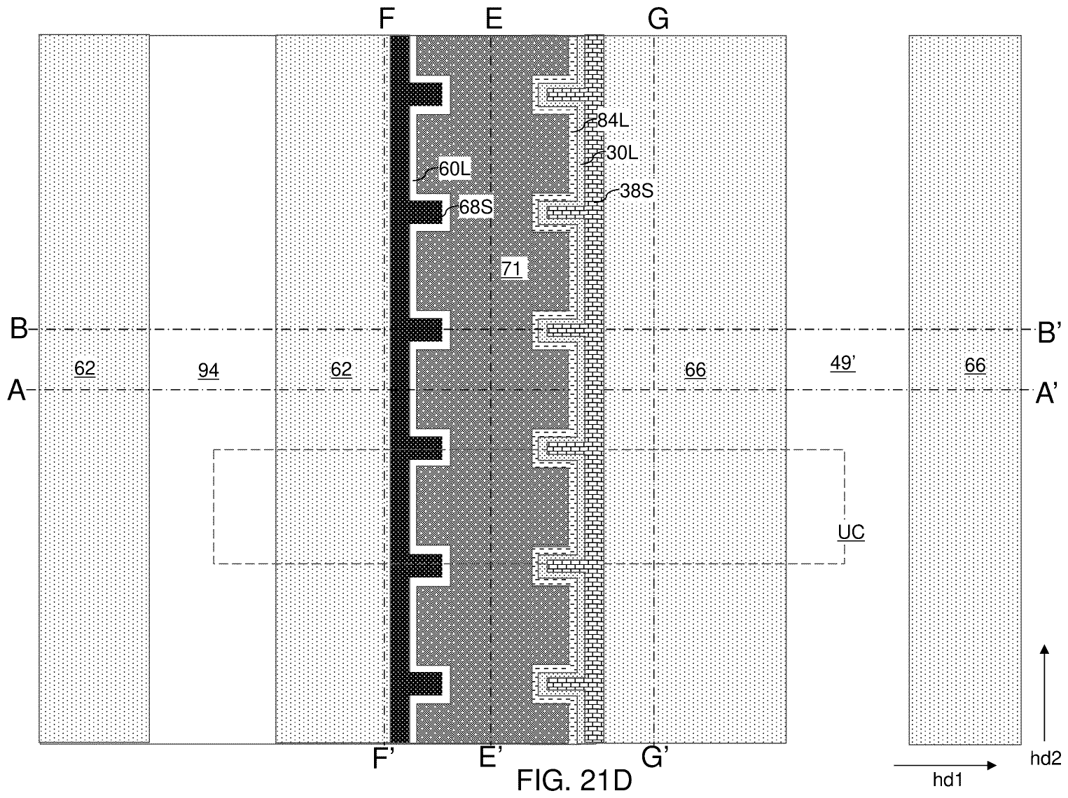

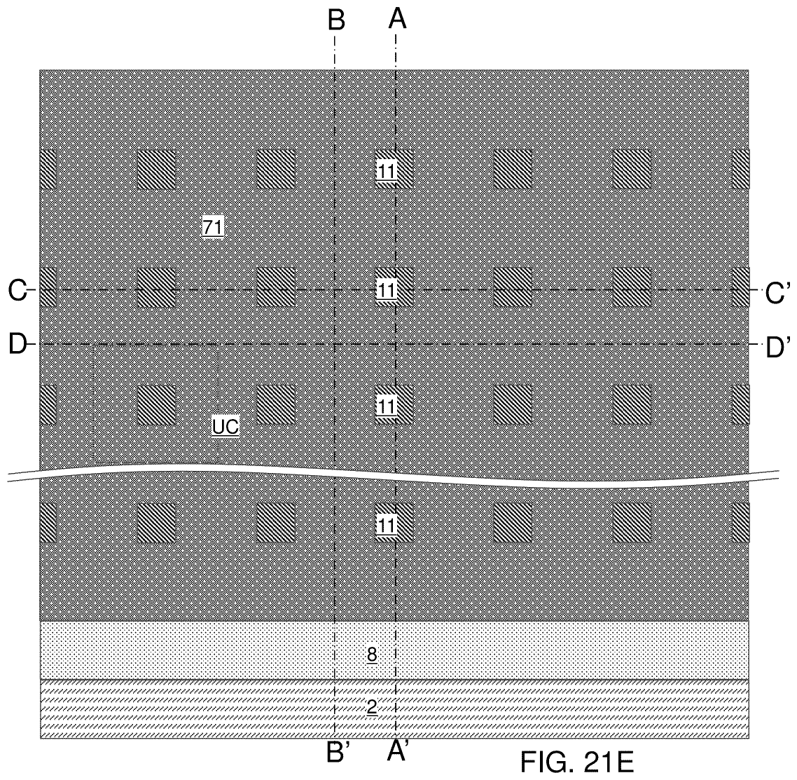

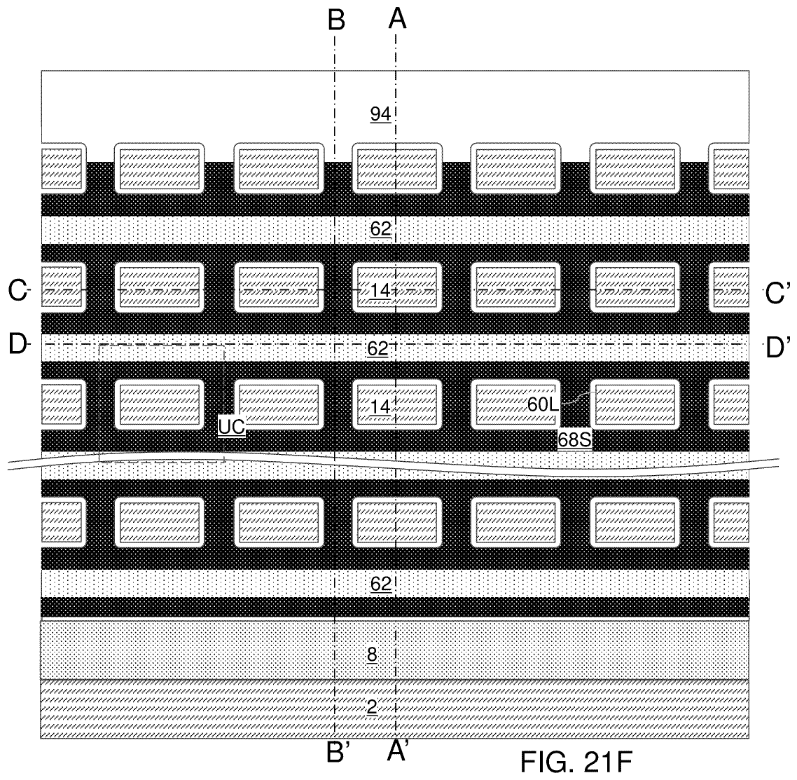

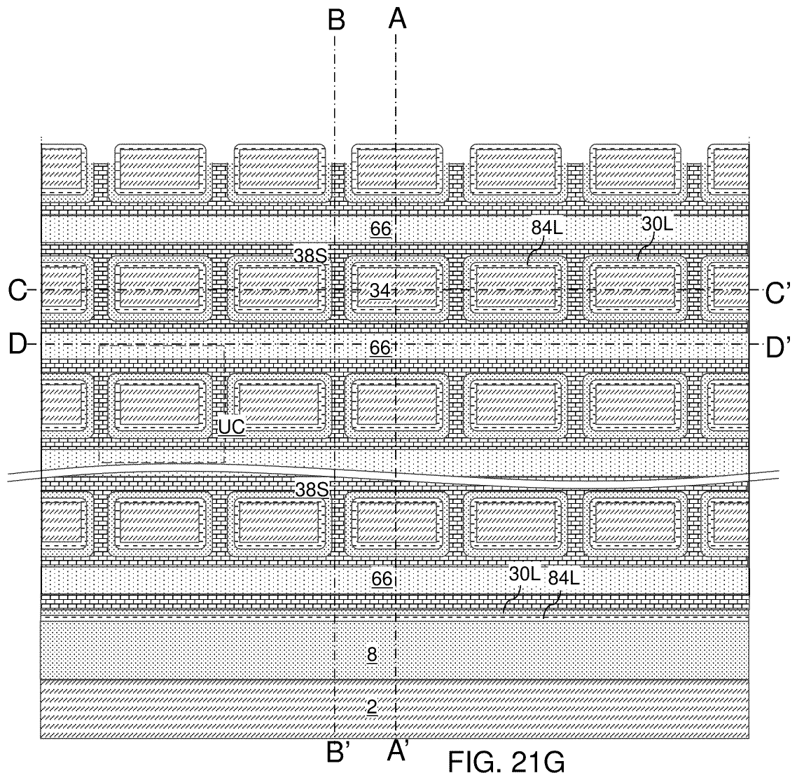

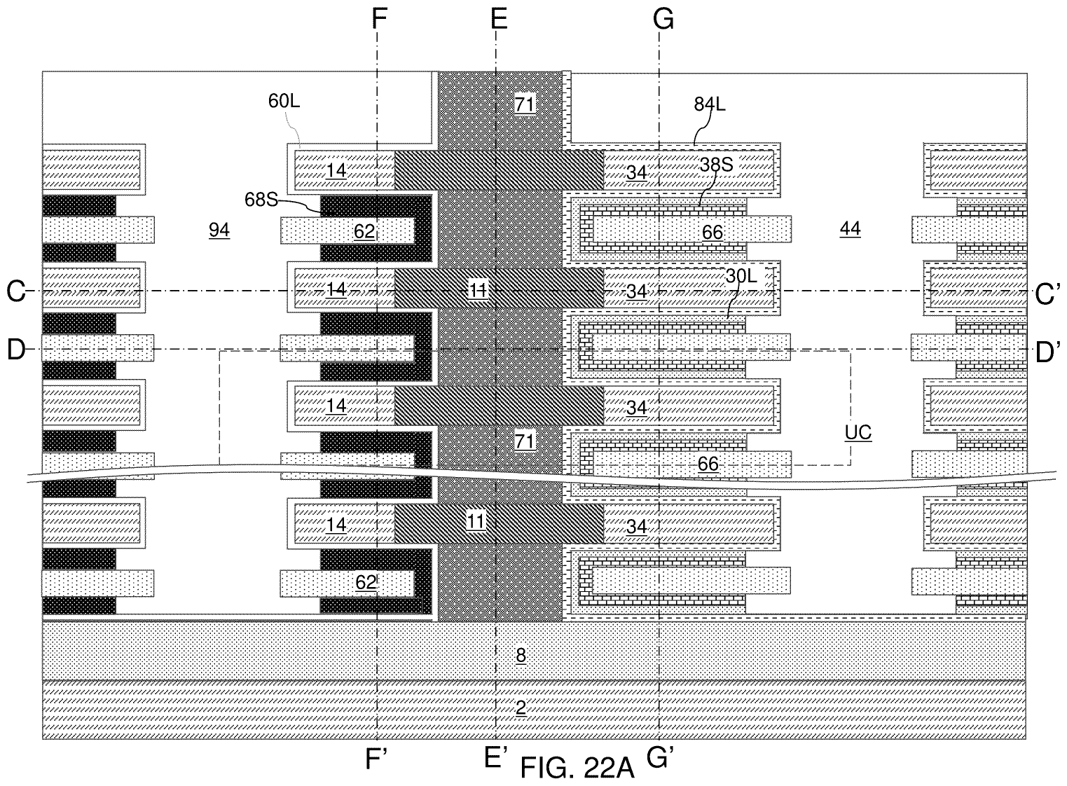

Referring to FIGS. 21A, 21B, 21C, 21D, 21E, 21F, and 21G, a selective isotropic etch process can be performed to etch portions of the continuous second gate electrode material layer 38L that are proximal to the source trenches 49 or overlie the topmost semiconductor rails (14, 11, 34). The selective isotropic etch process can etch the second gate electrode material selectively to the second gate dielectric material. For example, a wet etch process that isotropically etches the second gate electrode material selectively to the second gate dielectric material may be employed. The selective isotropic etch process patterns the continuous second gate electrode material layer 38L into a one-dimensional array of second gate electrode material layers 38S that are laterally spaced apart along the first horizontal direction hd1. Each second gate electrode material layer 38S may surround a respective two-dimensional array of semiconductor rails (14, 11, 34), i.e., a respective two-dimensional array of horizontally-extending semiconductor beams 34. For example, each second gate electrode material layer 38S may have a rectangular array of perforations through which a respective two-dimensional array of horizontally-extending semiconductor beams 34 laterally extends along the first horizontal direction hd1.

Subsequently, an additional selective isotropic etch process can be performed to etch physically exposed portions of the second gate dielectric material layer 30L, i.e., to etch portions of the second gate dielectric material layer 30L that are exposed to the source trenches 49 or overlie the topmost semiconductor rails (14, 11, 34). The second gate dielectric material layer 30L, which is formed as a single continuous material layer at the processing steps described with reference to FIGS. 19A-19G, is divided into L second gate dielectric material layers 30L that are arranged along the first horizontal direction hd1.

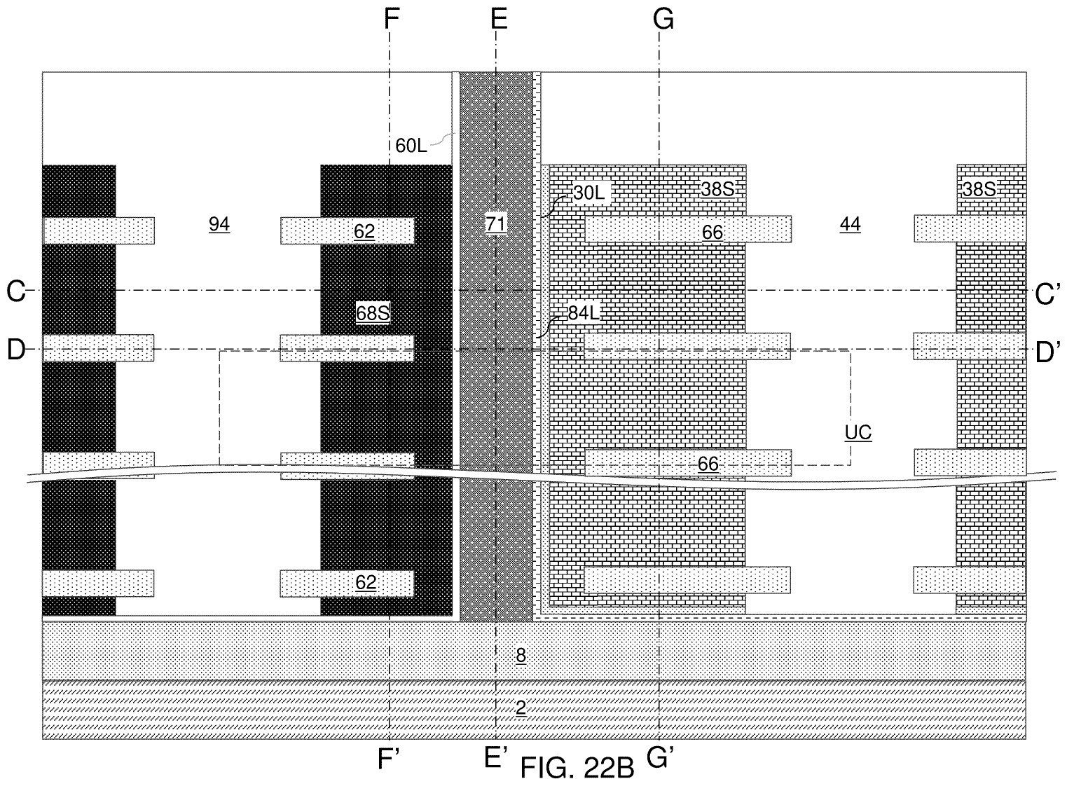

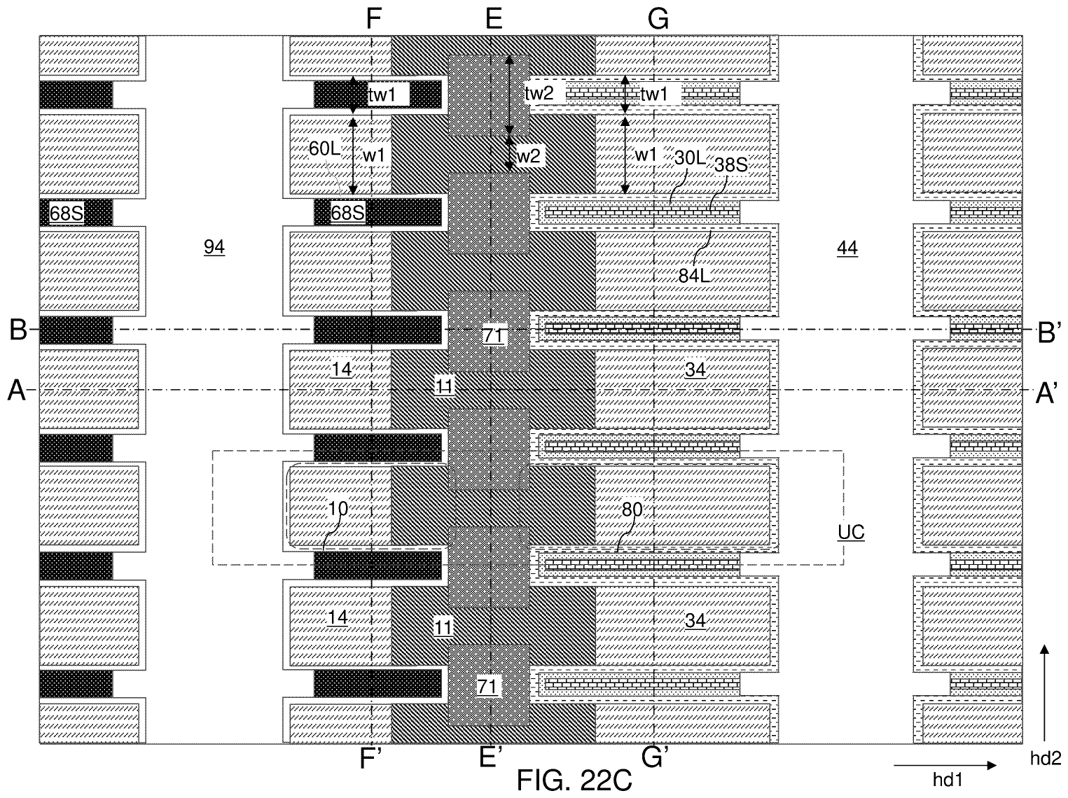

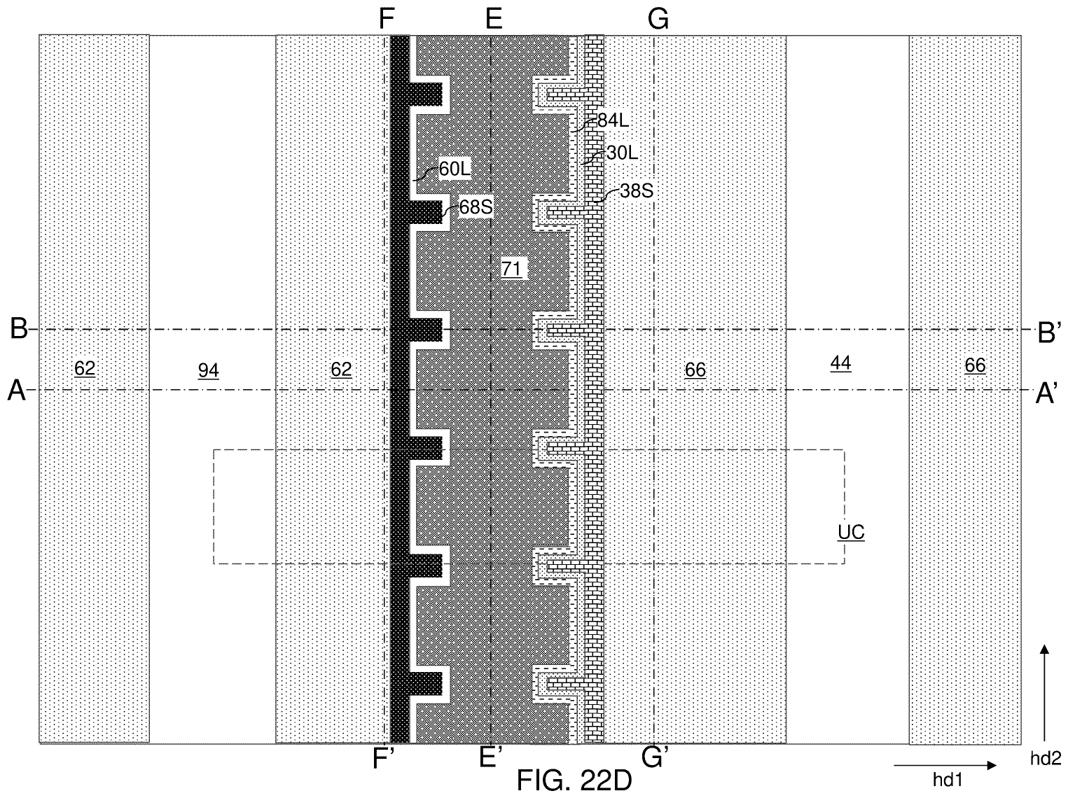

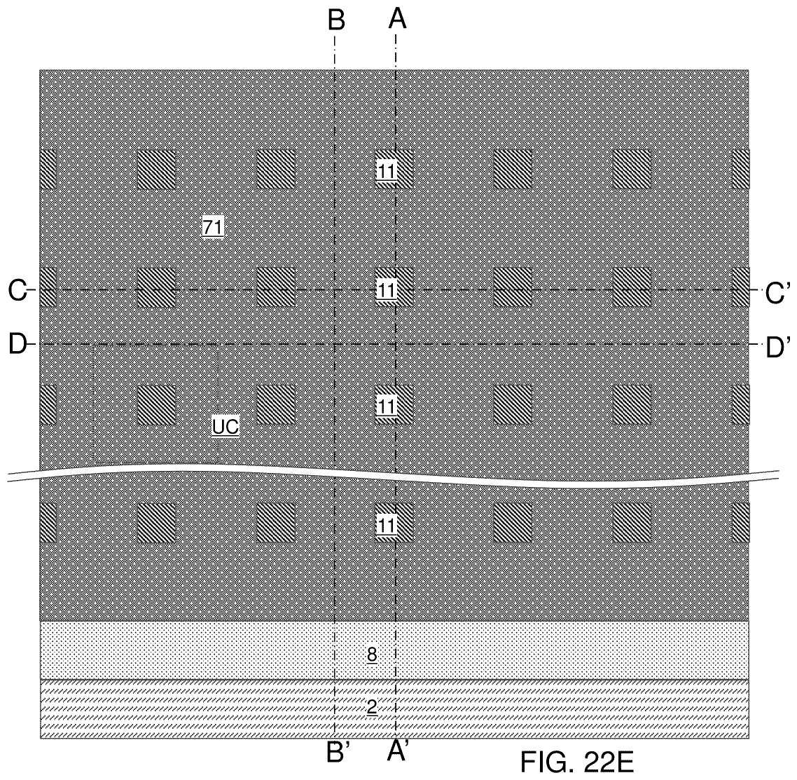

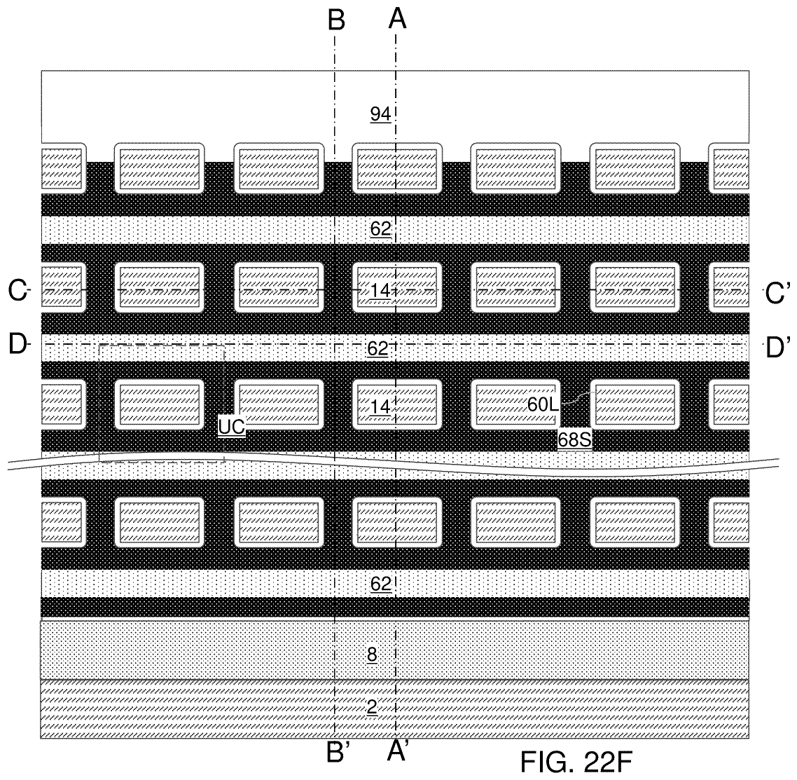

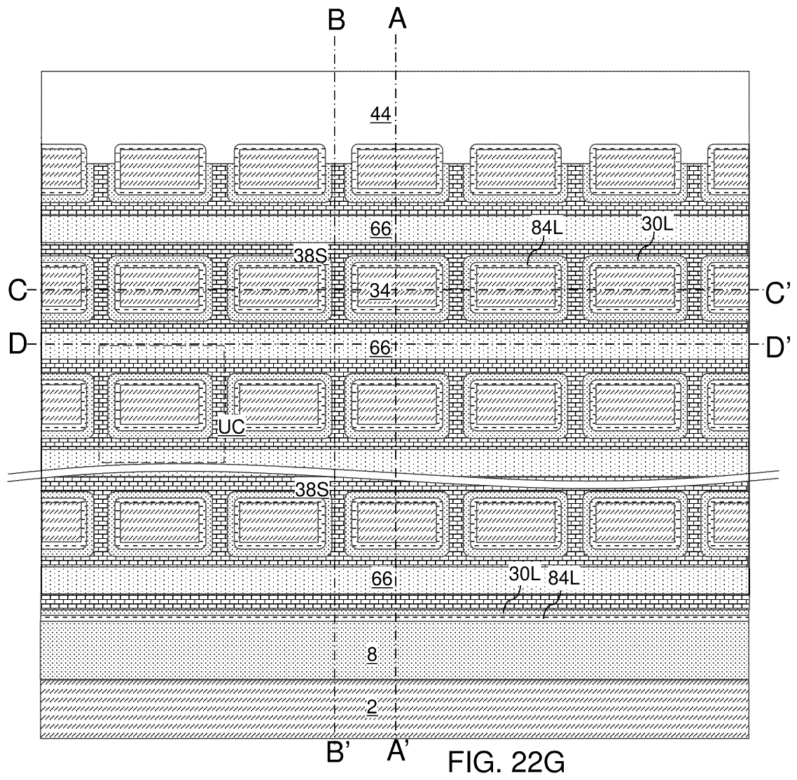

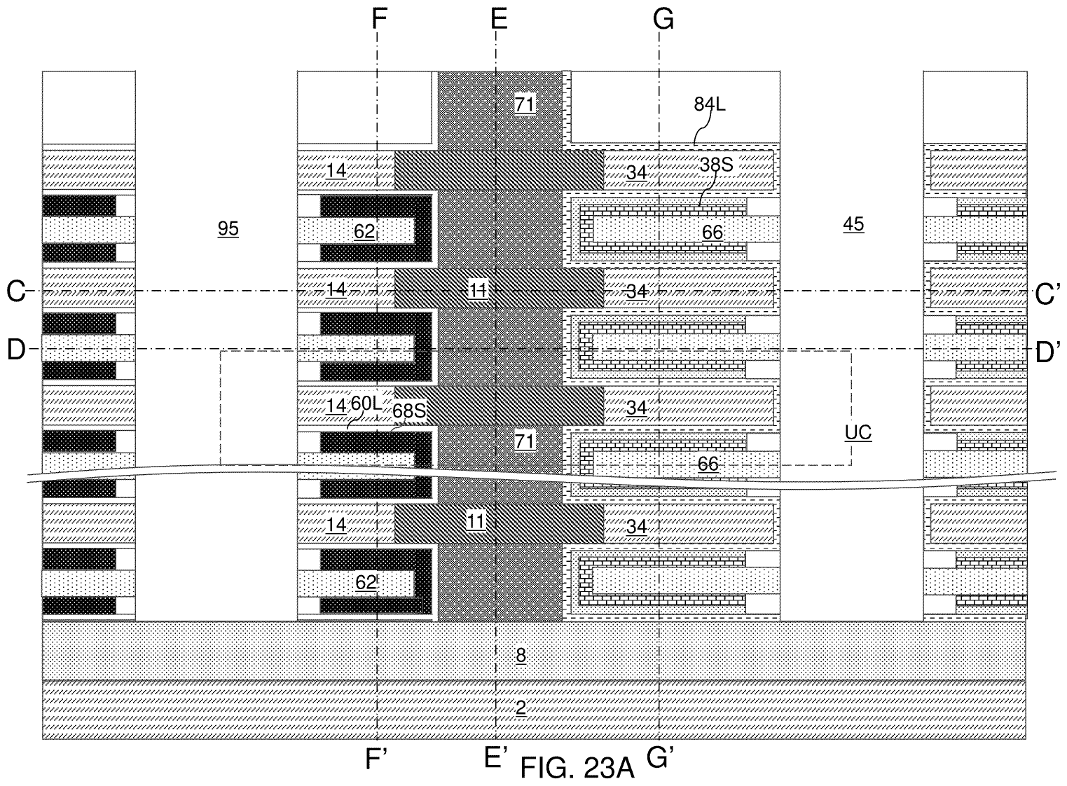

Referring to FIGS. 22A, 22B, 22C, 22D, 22E, 22F, and 22G, a dielectric fill material, such as undoped silicate glass (i.e., silicon oxide) or a doped silicate glass, can be deposited in the source trenches 49. A planarization process, such as a chemical mechanical polishing process, can be performed to remove portions of the dielectric fill material from above the horizontal plane including the top surfaces of the sacrificial perforated wall structures 71. Each remaining portion of the dielectric fill material that fills the source trenches 49 comprises a source trench isolation structure 44. In one embodiment, top surfaces of the source trench isolation structures 44 may be formed within the horizontal plane including the top surfaces of the sacrificial perforated wall structures 71 and/or the bit-line trench isolation structures 94. A laterally alternating sequence of bit-line trench isolation structures 94 and source trench isolation structures 44 can be arranged along the first horizontal direction hd1.

In an alternative embodiment, the steps described above with respect to FIGS. 16A-22G may be performed prior to performing the steps described above with respect to FIGS. 10A-15G.

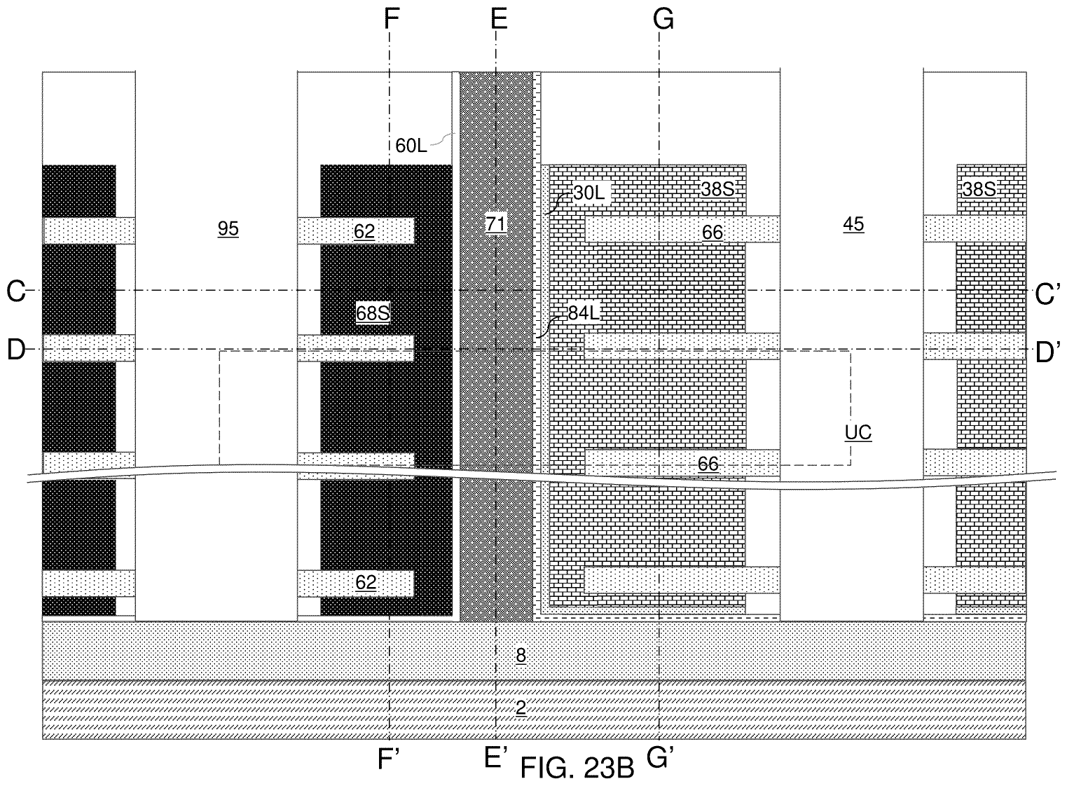

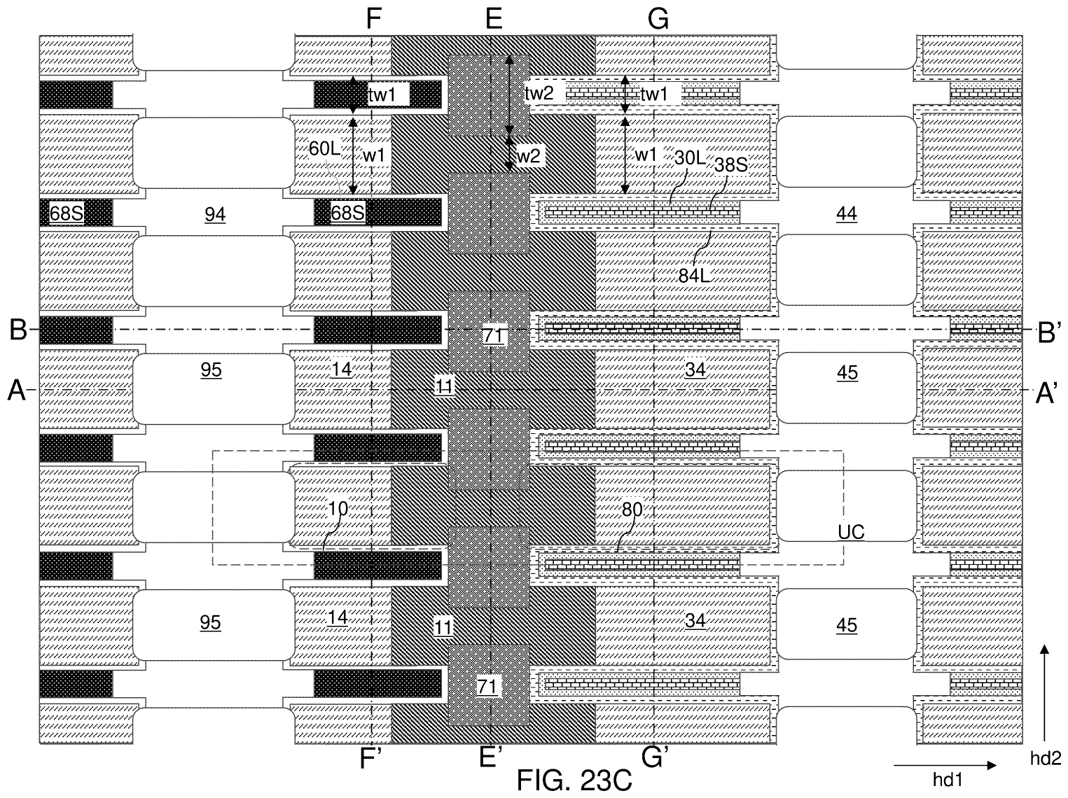

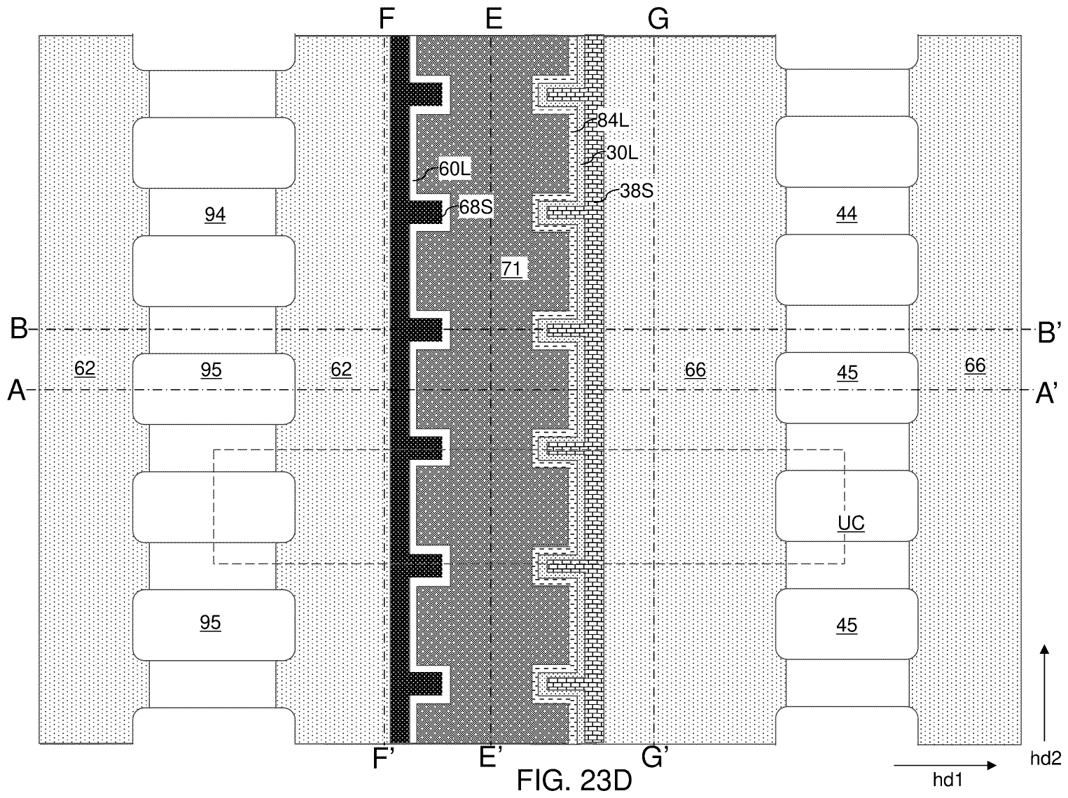

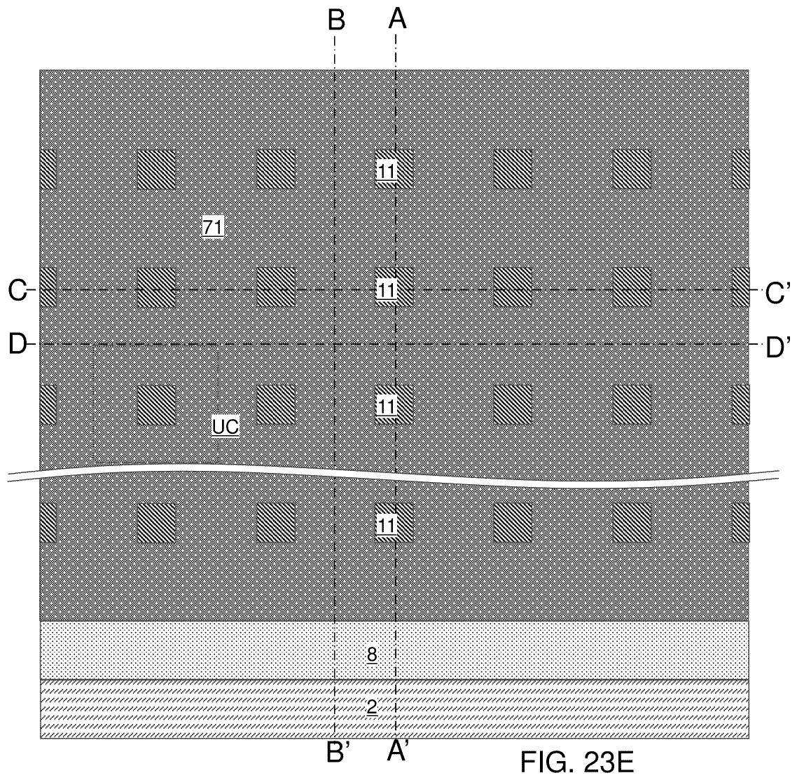

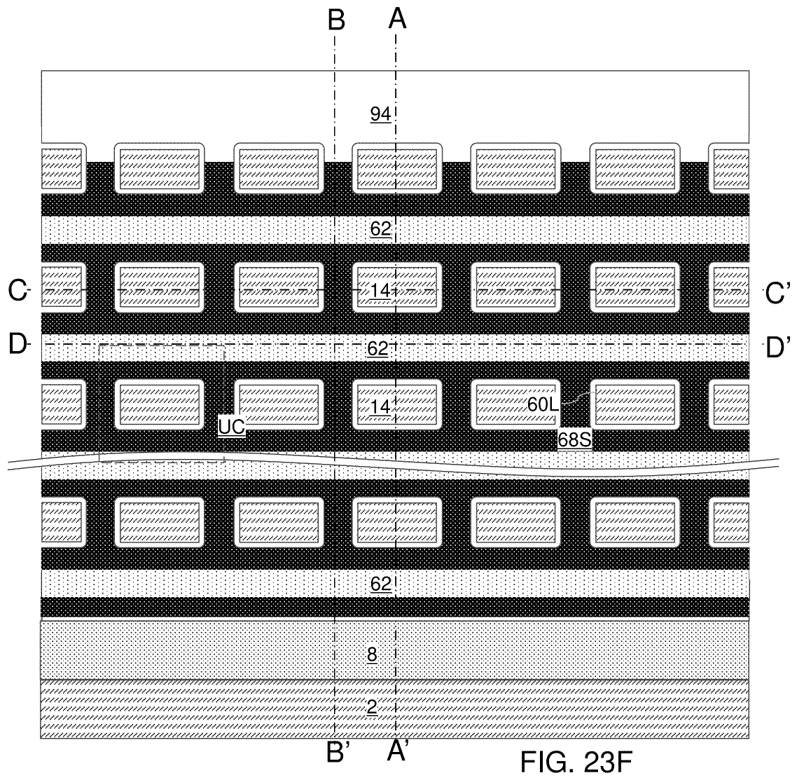

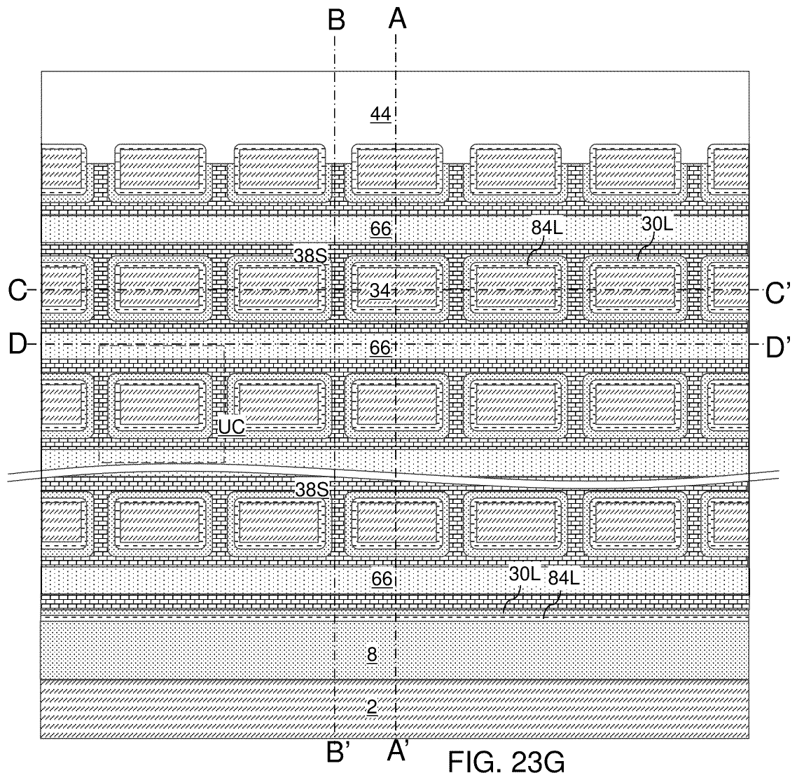

Referring to FIGS. 23A, 23B, 23C, 23D, 23E, 23F, and 23G, a photoresist layer (not shown) can be applied over the first exemplary structure, and can be lithographically patterned to form a total of (L+1)×M openings over the bit-line trench isolation structures 94 and the source trench isolation structures 44. Each opening in the photoresist layer may have an areal overlap in a plan view with a respective vertical stack of (N+1) interfaces between (N+1) semiconductor rails (14, 11, 34) and a bit-line trench isolation structure 94 or a source trench isolation structures 44. An anisotropic etch process can be performed to transfer the pattern of the openings in the photoresist layer through the bit-line trench isolation structures 94 and source trench isolation structures 44 and end segments of the semiconductor rails (14, 11, 34). Bit-line via cavities 95 vertically extending down to the etch stop structure 8 (or to the substrate 2 if the etch stop structure is omitted) can be formed through the bit-line trench isolation structures 94. Source-line via cavities 45 vertically extending down to the etch stop structure 8 (or to the substrate 2 if the etch stop structure is omitted) can be formed through the source trench isolation structures 44. The photoresist layer can be subsequently removed, for example, by ashing.

For each bit-line via cavity 95 located between two M×(N+1) arrays of semiconductor rails (14, 11, 34), 2×M×(N+1) end sidewalls of horizontally-extending semiconductor channels 14 can be physically exposed to the bit-line via cavity 95. For each source via cavities 45 located between two M×(N+1) arrays of semiconductor rails (14, 11, 34), 2×M×(N+1) end sidewalls of the channel material layer 84L can be physically exposed to the source via cavity 45. Specifically, end walls of the channel material layer 84L that are located at the levels of the horizontally-extending semiconductor beams 34 may be physically exposed to a respective source via cavity 45. Each of the bit-line via cavities 95 may comprise at least two straight sidewalls that vertically extend from a top surface of a bit-line trench isolation structure 94 to a top surface of an etch stop structure 8. Each of the source via cavities 45 may comprise at least two straight sidewalls that vertically extend from a top surface of a source trench isolation structure 44 to a top surface of an etch stop structure 8.

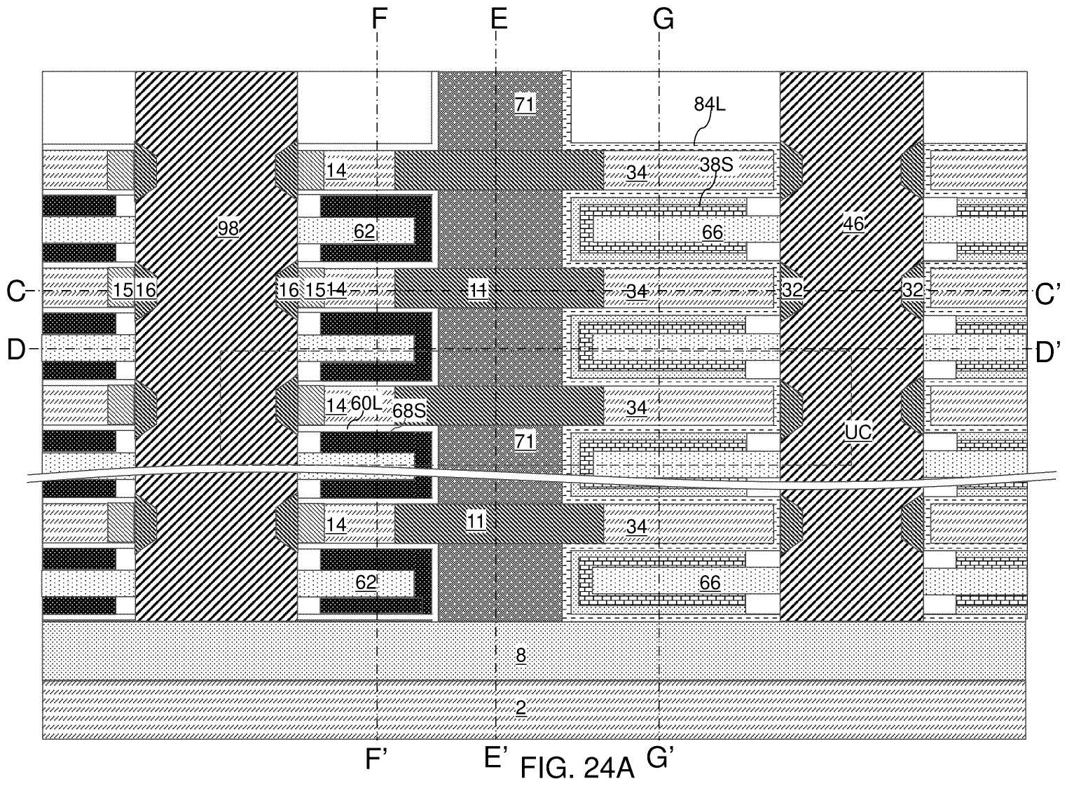

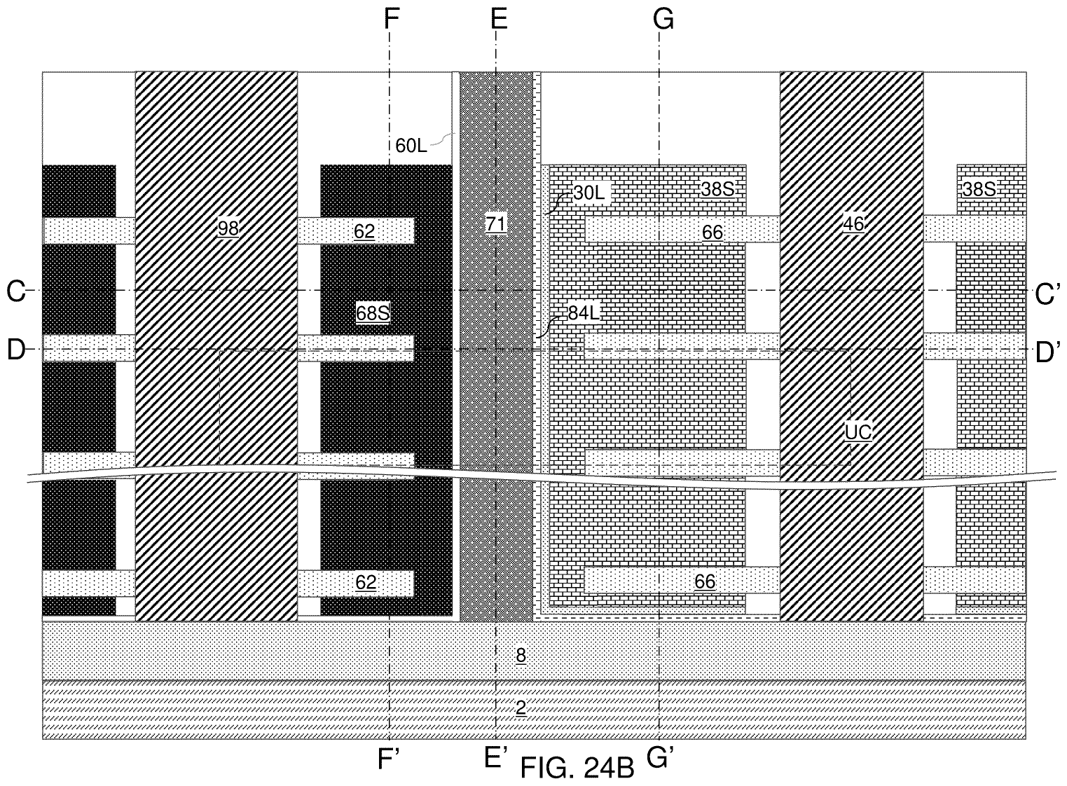

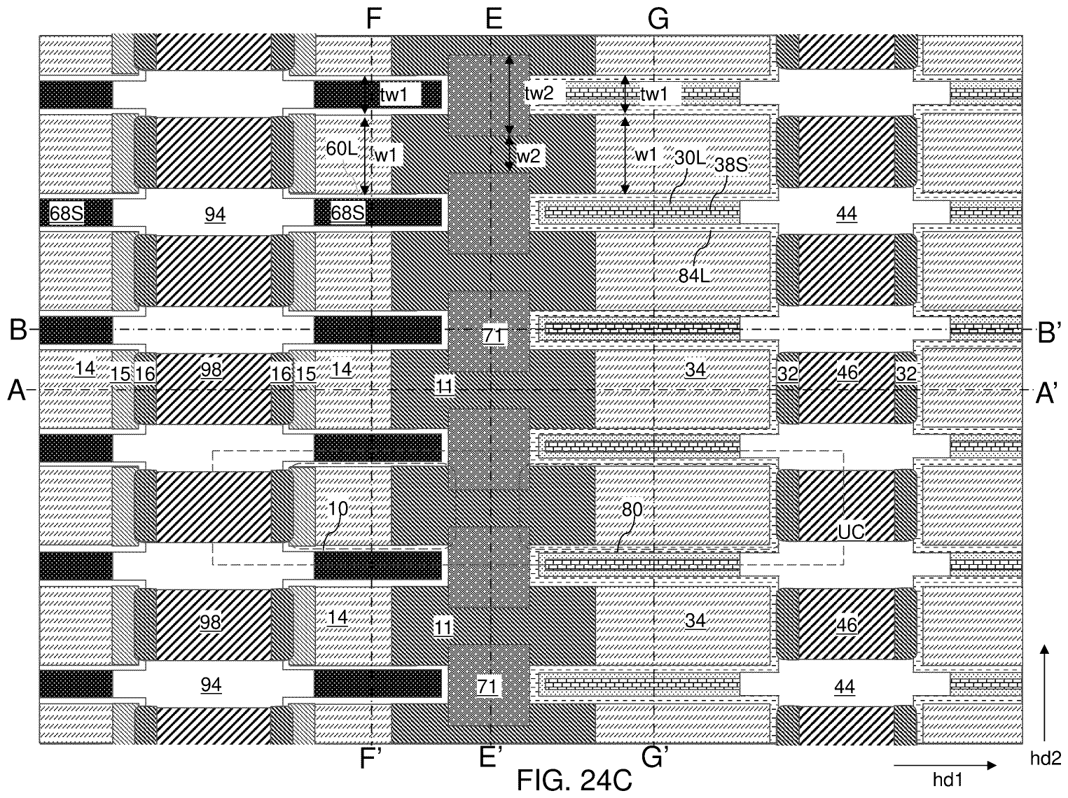

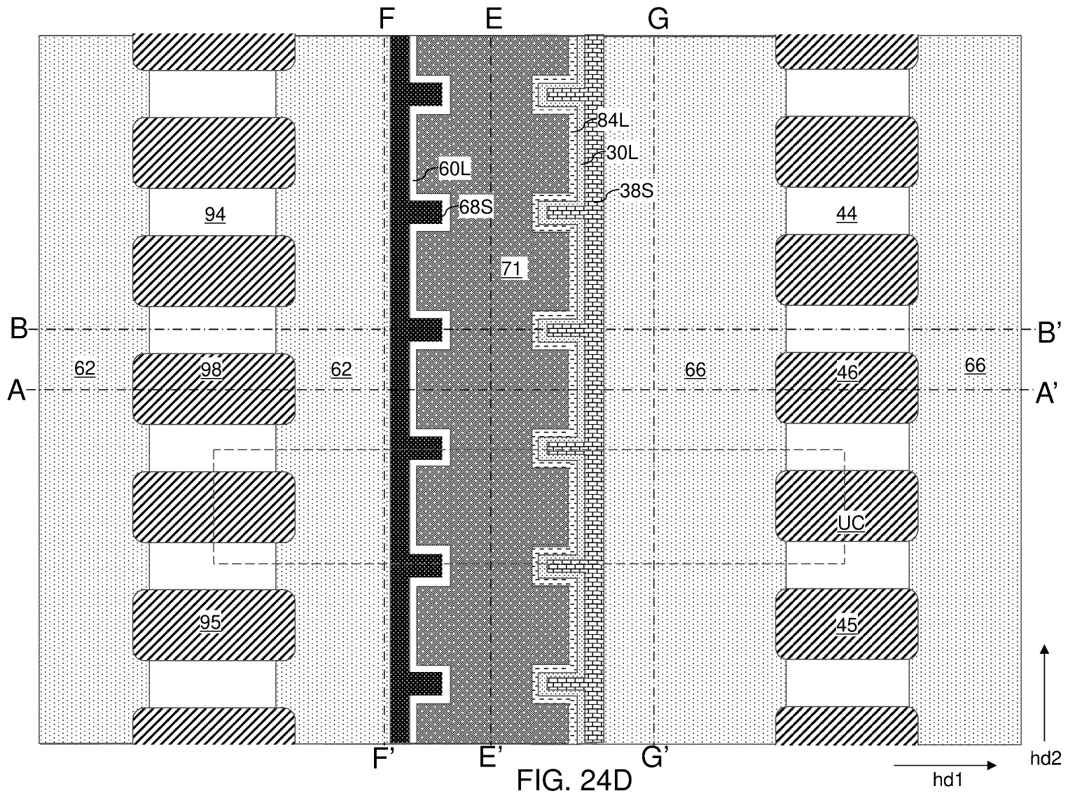

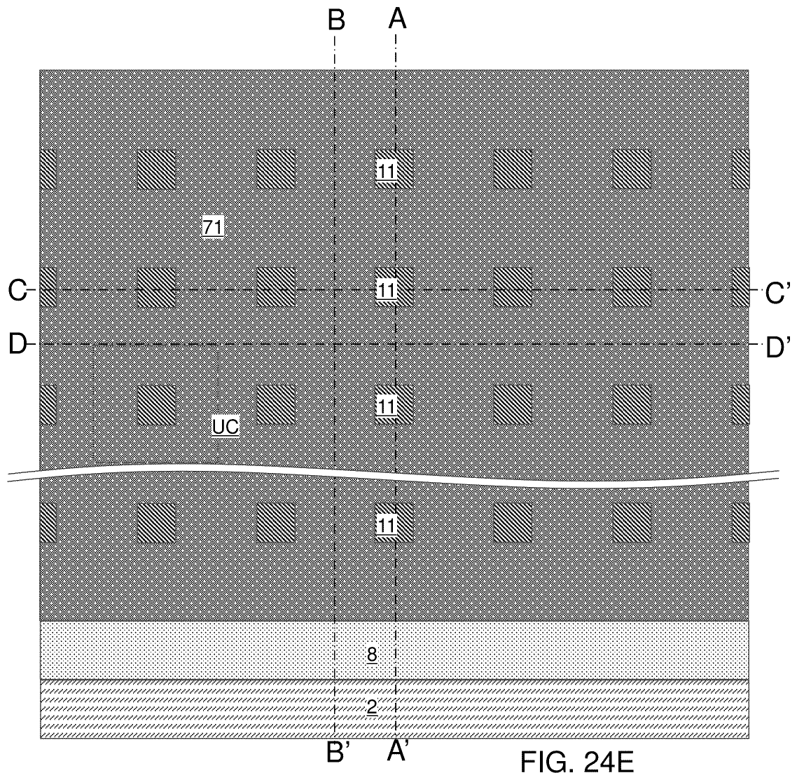

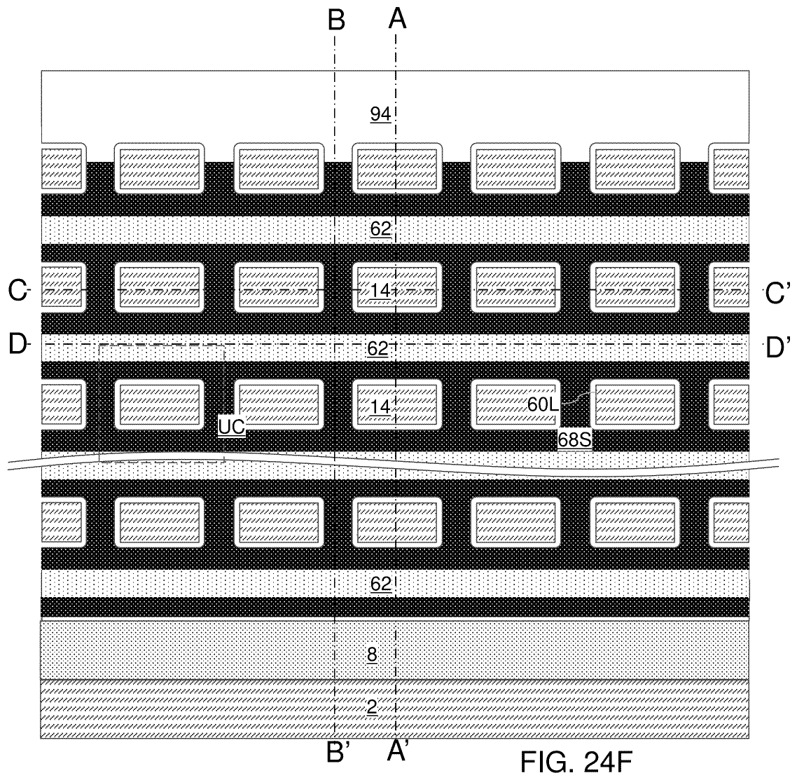

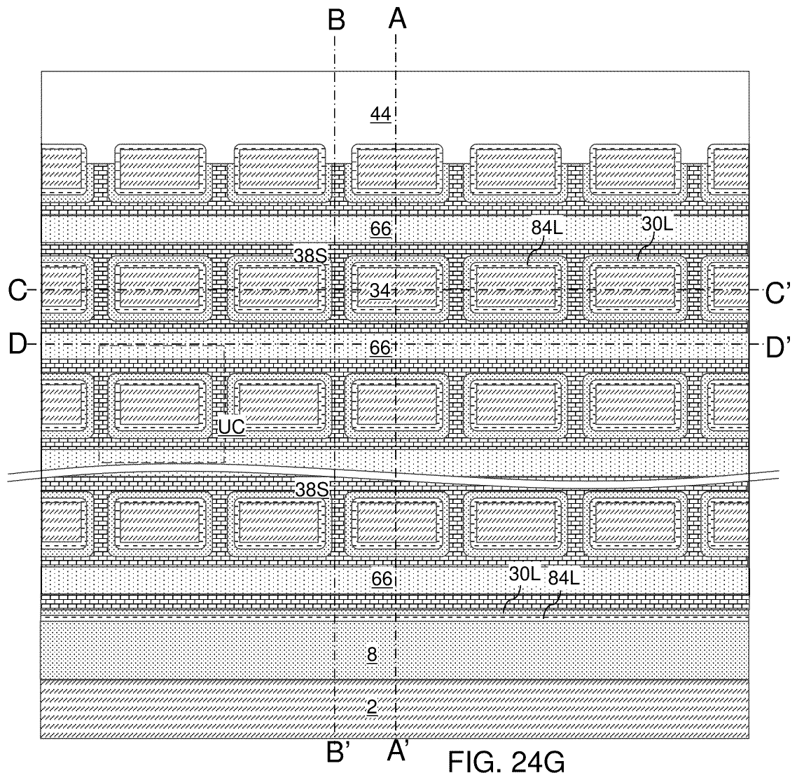

Referring to FIGS. 24A, 24B, 24C, 24D, 24E, 24F, and 24G, an optional extension region doping process may be performed to electrically dope edge portions of the semiconductor rails (14, 11, 34) that are proximal to the physically exposed sidewall surfaces of semiconductor rails (14, 11, 34). For example, a gas phase doping process or an outdiffusion process employing a conformally deposited sacrificial doped silicate glass layer (such as a sacrificial phosphosilicate glass layer or a sacrificial arsenosilicate glass layer) may be employed to convert surface portions of the semiconductor rails (14, 11, 34) that are proximal to the source via cavities 45 into source extension regions (not shown), and to convert surface portions of the semiconductor rails (14, 11, 34) that are proximal to the bit-line via cavities 95 into drain extension regions 15. In other words, surface portions of the horizontally-extending semiconductor beams 34 that are proximal to the source via cavities 45 may be converted into source extension regions, and surface portions of the horizontally-extending semiconductor channels 14 that are proximal to the bit-line via cavities 95 are converted into drain extension regions 15. The source extension regions may also optionally be formed in physically exposed end portions of the channel material layers 84L depending on the material composition of the channel material layers 84L.

The remaining portions of the horizontally-extending semiconductor channels 14 function as channel regions of first field effect transistors to be subsequently formed. The remaining portions of the horizontally-extending semiconductor beams 34 function as core structures of second field effect transistors to be subsequently formed. In one embodiment, the horizontally-extending semiconductor channels 14 and the horizontally-extending semiconductor beams 34 may have a doping of a first conductivity type, and the source extension regions (if formed) and the drain extension regions 15 may have a doping of a second conductivity type that is the opposite of the first conductivity type. Alternatively, formation of the source extension regions and the drain extension regions 15 may be omitted.

A selective doped semiconductor deposition process can be performed to grow a doped semiconductor material having a doping of the second conductivity type from first physically exposed semiconductor surfaces of the horizontally-extending semiconductor rails (15, 14, 11, 34) that are exposed to the source via cavities 45, and from second physically exposed semiconductor surfaces of the horizontally-extending semiconductor rails (15, 14, 11, 34) that are exposed to the bit-line via cavities 95. In one embodiment, the doped semiconductor material having a doping of the second conductivity type can be grown from physically exposed semiconductor surfaces of the channel material layers 84L that are exposed to the source via cavities 45, and from physically exposed semiconductor surfaces of the drain extension regions 15 that are exposed to the bit-line via cavities 95.

Source regions 32 are formed on first sidewalls of the semiconductor rails (15, 14, 11, 34) in peripheral portions of the source via cavities 49, and drain regions 16 are formed on second sidewalls of the semiconductor rails (14, 11, 34) in peripheral portions of the bit-line via cavities 95. In one embodiment, the source regions 32 may be formed directly on the channel material layers 84L (or on source extension regions depending on the material composition of the channel material layers 84L), and the drain regions 16 may be formed directly on the drain extension regions 15.

The source regions 32 and the drain regions 16 may comprise heavily doped regions of the second conductivity type, which have a higher dopant concentration than the optional extension regions (33, 15). The source regions 32 may have different horizontal cross-sectional shapes in vertical cross-sectional views along vertical planes that are perpendicular to the first horizontal direction hd1 that vary as a function of a lateral distance from a most proximal one among the semiconductor rails (15, 14, 11, 34). The drain regions 16 may have different horizontal cross-sectional shapes in vertical cross-sectional views along vertical planes that are perpendicular to the first horizontal direction hd1 that vary as a function of a lateral distance from a most proximal one among the semiconductor rails (14, 11, 34). If the etch stop structure 8 is omitted, then a doped semiconductor region of the second conductivity type is also formed on the exposed, etched portion of the substrate 2.

At least one conductive material layer can be deposited in the remaining volumes of the bit-line via cavities 95 and the source-line via cavities 45. The at least one conductive material layer may comprise a combination of a metallic barrier material and a metal fill material. Exemplary metallic barrier materials include TiN, TaN, WN, and/or MoN. Exemplary metal fill materials include W, Co, Ru, Mo, Ti, Ta, Cu, etc. Excess portions of the at least one conductive material can be removed from above the horizontal plane including the top surfaces of the bit-line trench isolation structures 94 and the source trench isolation structures 44. Each remaining portion of the at least one conductive material that fills a respective source-line via cavity 45 comprises a vertical source line 46. Each vertical source line 46 located between a pair of M×(N+1) arrays of semiconductor rails (15, 14, 11, 34) contacts two vertical stacks of N source regions 32 and may contact an overlying dummy source region located on a dummy semiconductor rail. An L×M array of vertical source lines 46 may be formed. Each remaining portion of the at least one conductive material that fills a respective bit-line via cavity 95 comprises a bit line 98. Each bit line 98 located between a pair of M×(N+1) arrays of semiconductor rails (15, 14, 11, 34) contacts two vertical stacks of N drain regions 16 and may contact two overlying dummy drain regions. An L′×M array of bit lines 98 may be formed, in which the integer L′ is (L+1)/2 or L/2 or L/2+1. An L″×M array of vertical source lines 46 may be formed, in which the integer L″ is (L+1)/2 or L/2 or L/2+1.

In summary, a two-dimensional array of vertical bit lines 98 can be formed such that each of the vertical bit lines 98 contacts a set of drain regions 16 located within a respective vertical stack of unit cells UC. A two-dimensional array of vertical source lines 46 can be formed such that each of the vertical source lines 46 contacts a set of source regions 32 located within a respective vertical stack of unit cells UC. In one embodiment, each of the unit cells UC comprises a source region 32 in contact with an end portion of a tubular-portion-containing channel (comprising a portion of a channel material layer 84L) and in contact with a vertical bit line 98 that extends along a vertical direction. In an alternative embodiment, the vertical bit lines 98 and the vertical source lines 46 may be formed during separate patterning and etching steps.

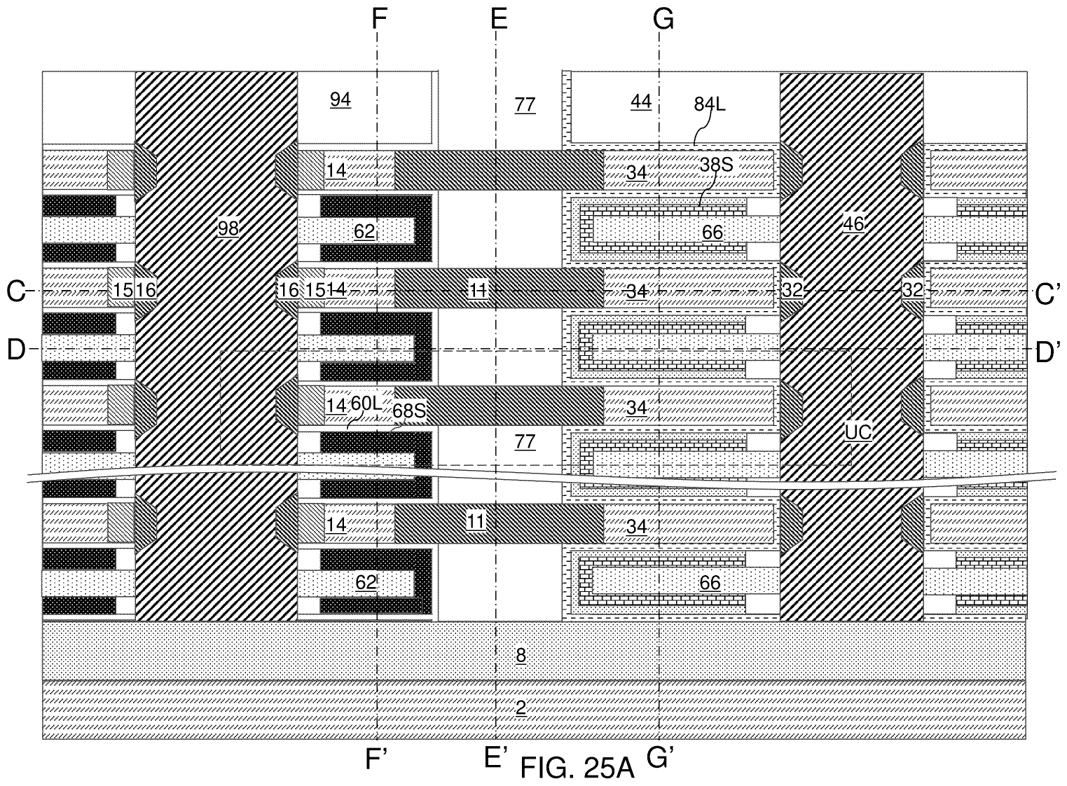

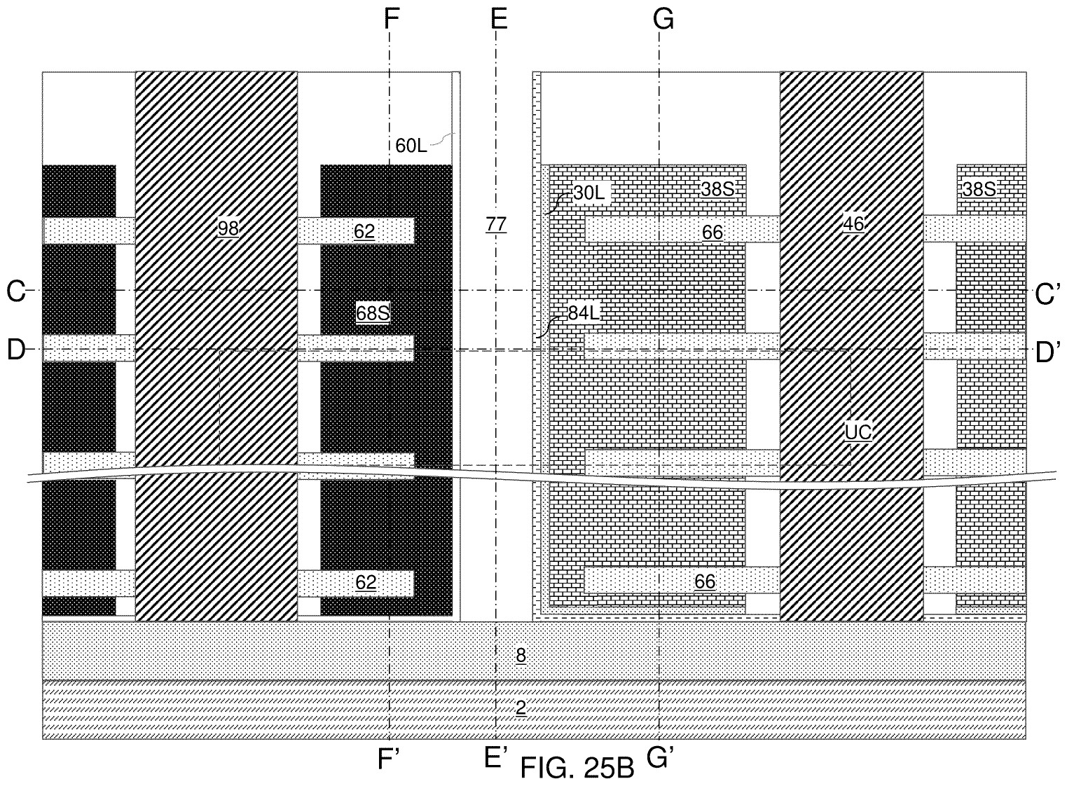

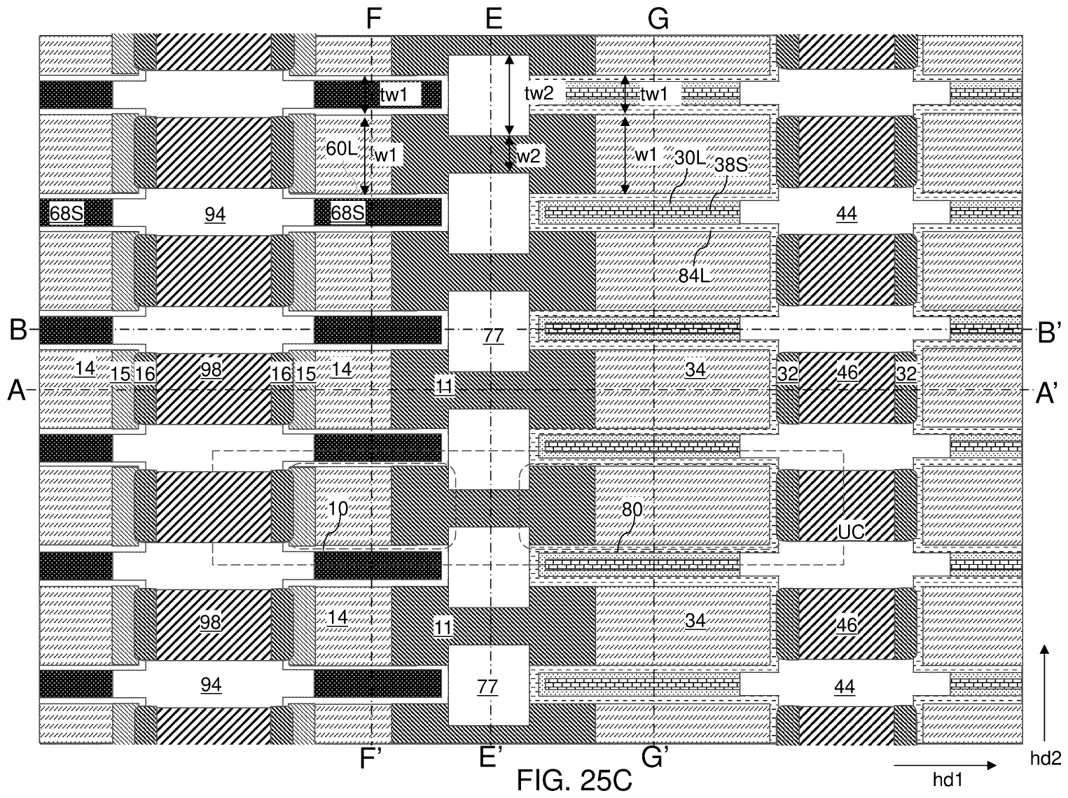

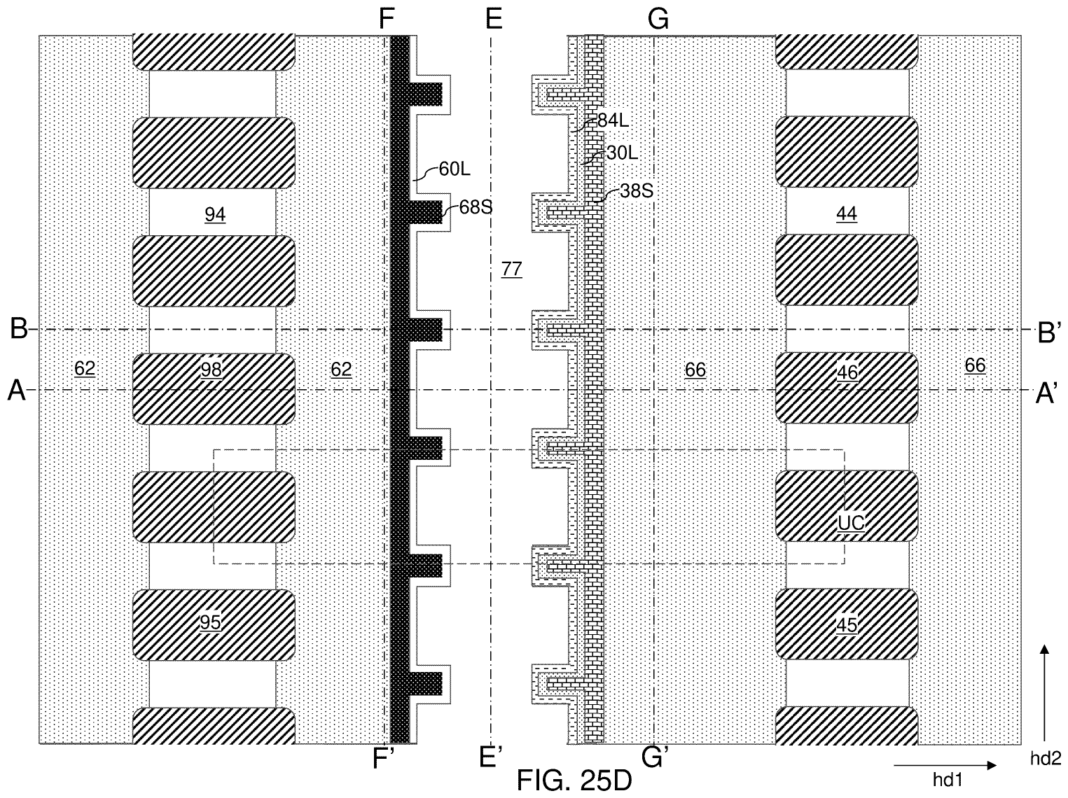

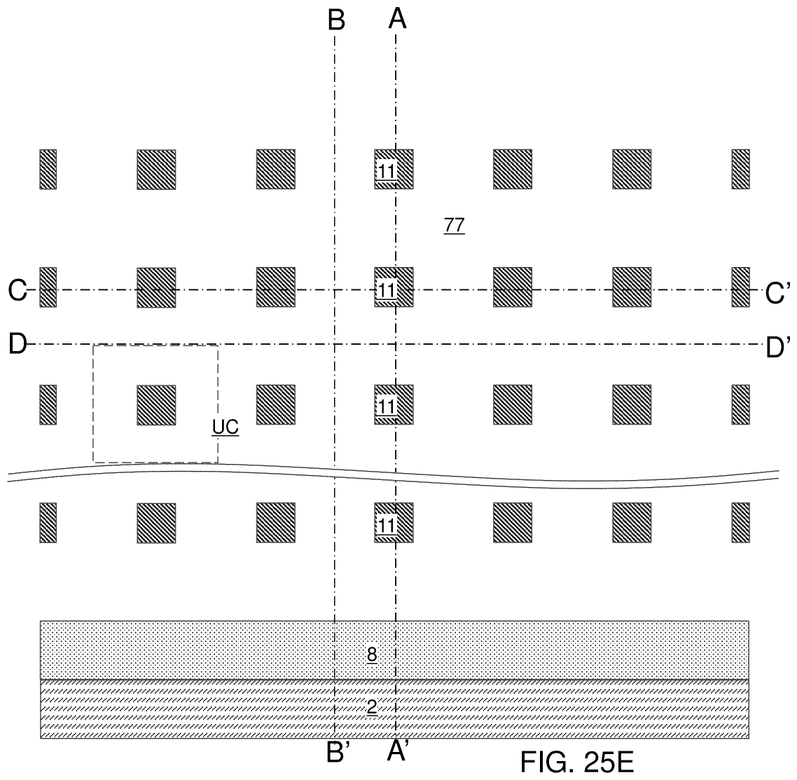

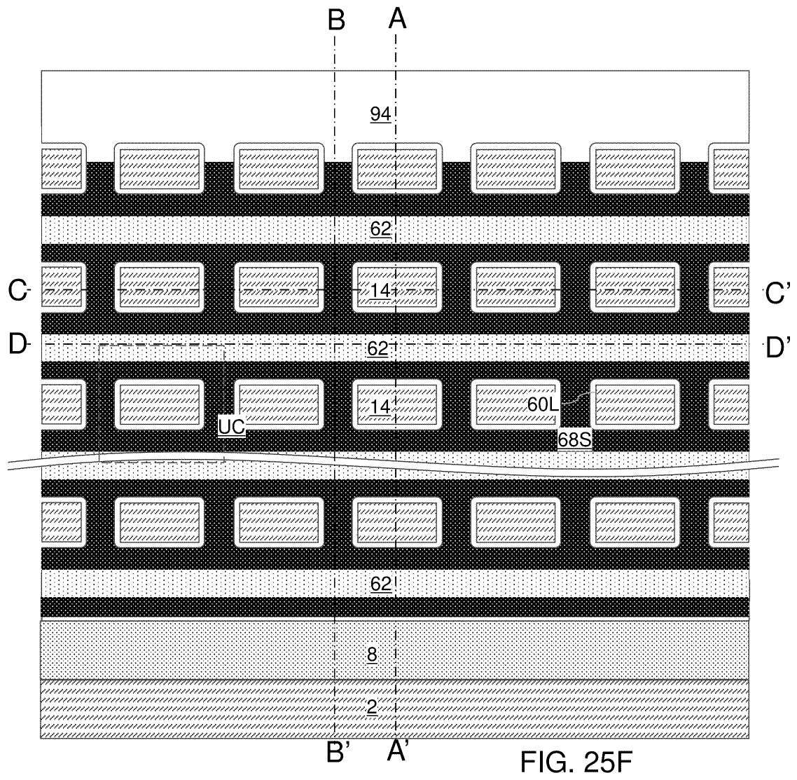

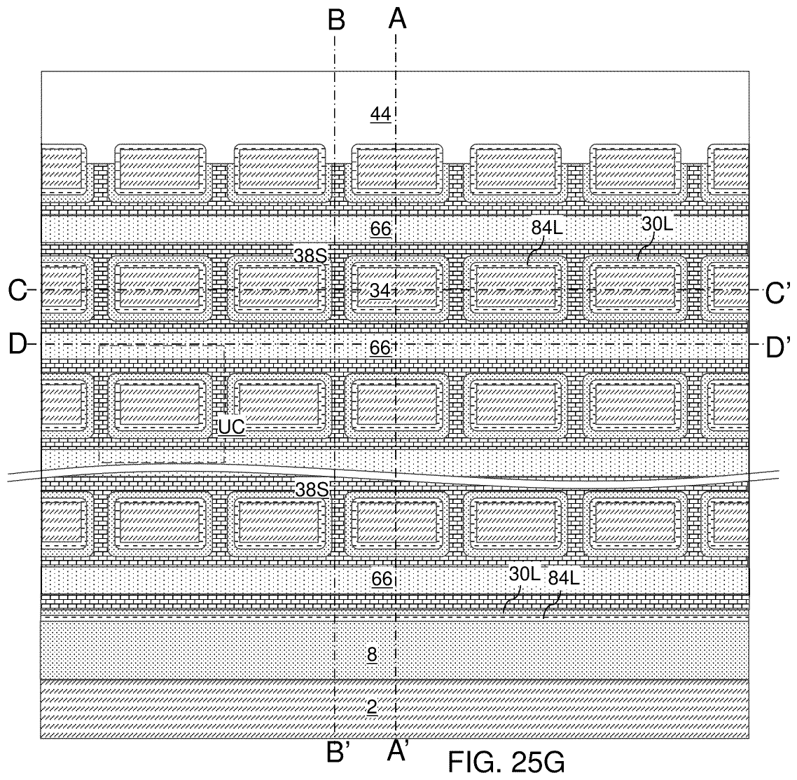

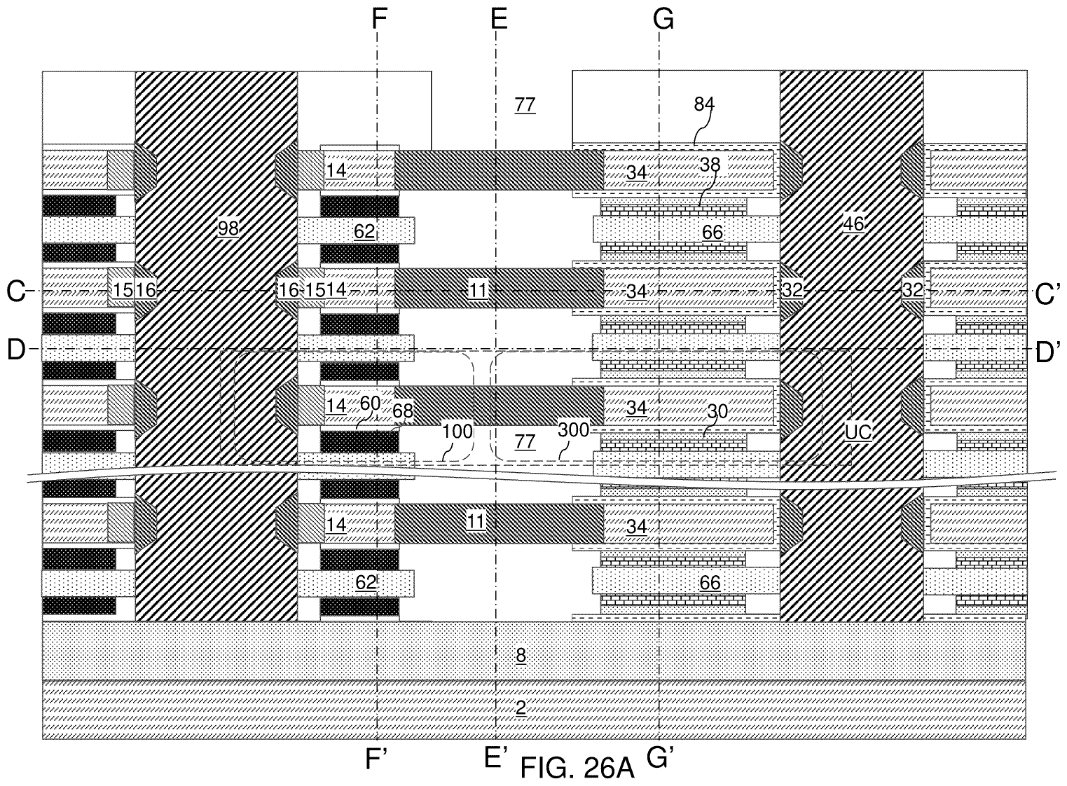

Referring to FIGS. 25A, 25B, 25C, 25D, 25E, 25F, and 25G, a selective isotropic etch process can be performed to isotropically etch the material of the one-dimensional array of sacrificial perforated wall structures 71. For example, if the sacrificial perforated wall structures 71 comprise silicon nitride, a wet etch process employing hot phosphoric acid may be performed to remove the sacrificial perforated wall structures 71 selectively to the materials of the bit-line trench isolation structures 94, the source trench isolation structures 44, the vertical bit lines 98, the vertical source lines 46, the semiconductor rails (15, 14, 11, 34), the first gate dielectric material layers 60L (or the first gate electrode material layers 68S), and the second gate dielectric material layers 30L (or the second gate electrode material layers 38S). A one-dimensional array of bridges-encircling cavities 77 is formed by removing the one-dimensional array of sacrificial perforated wall structures 71. Each M×(N+1) two-dimensional array of doped semiconductor material portions 11 arranged along directions that are perpendicular to the first horizontal direction hd1 is exposed to a respective one of the bridges-encircling cavities 77.

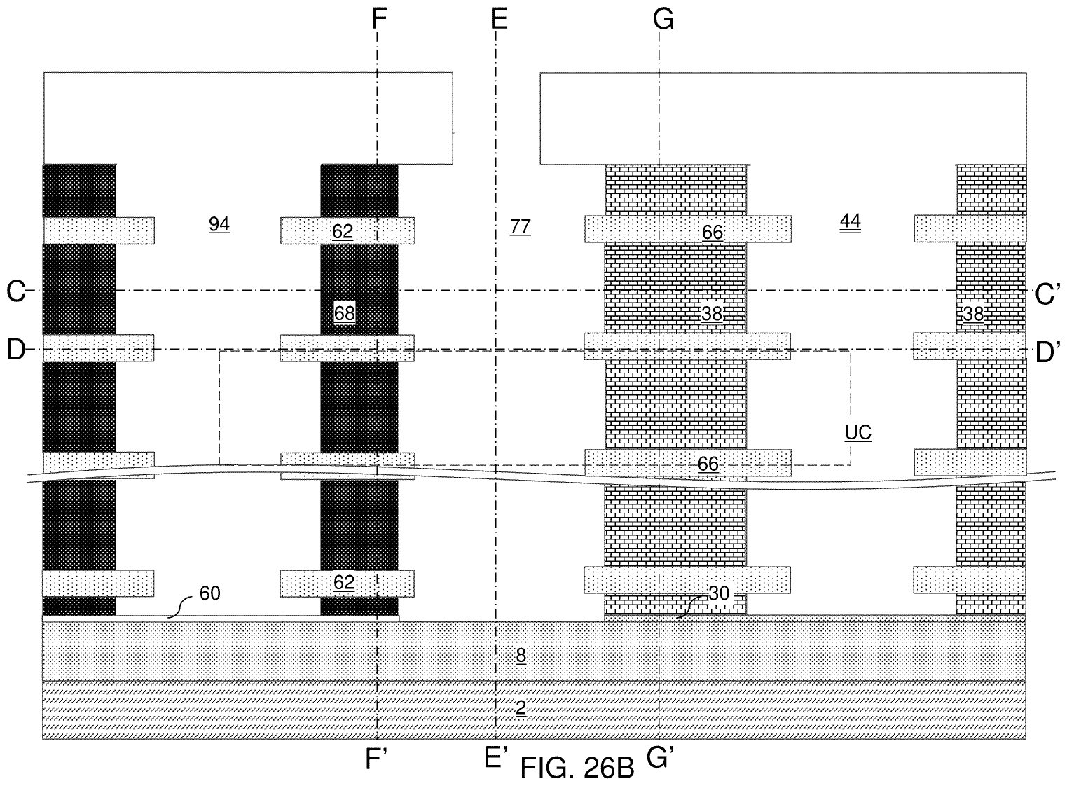

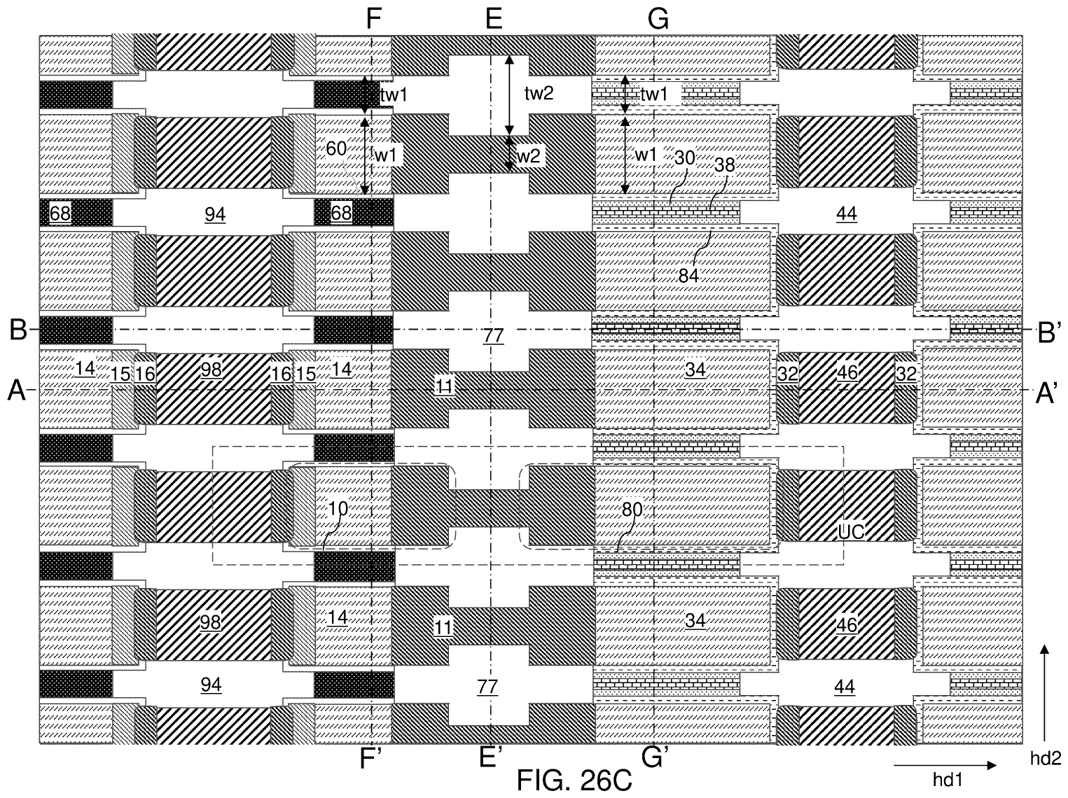

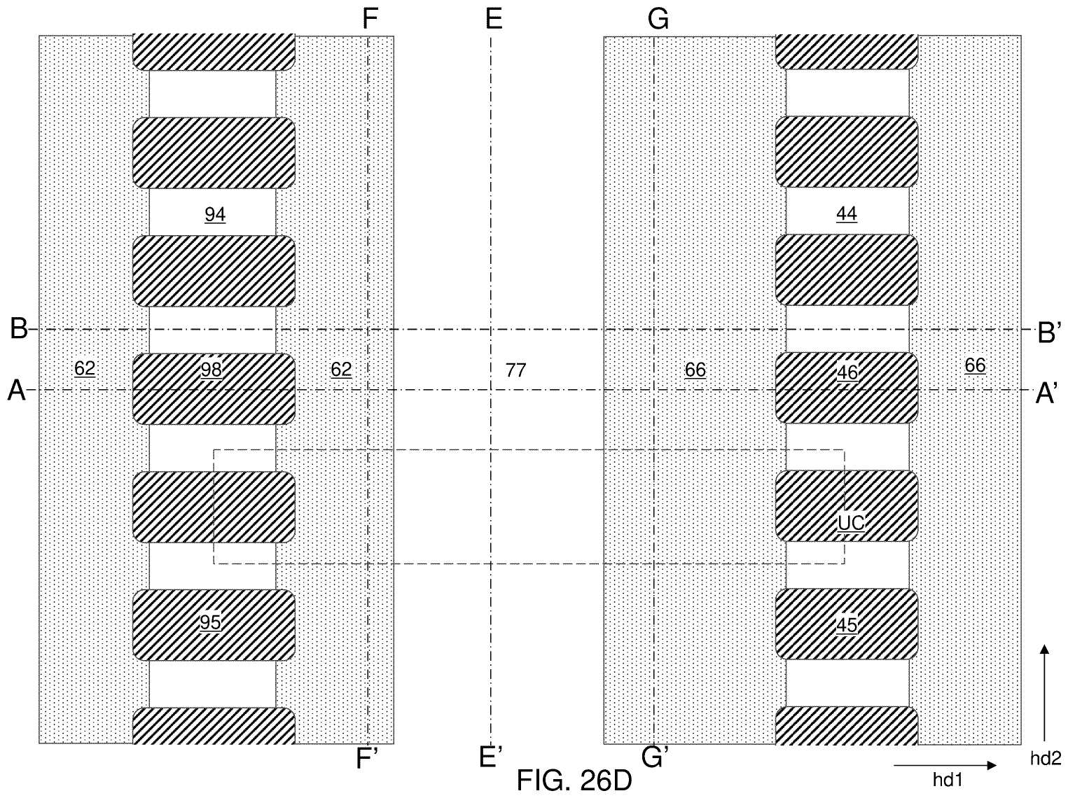

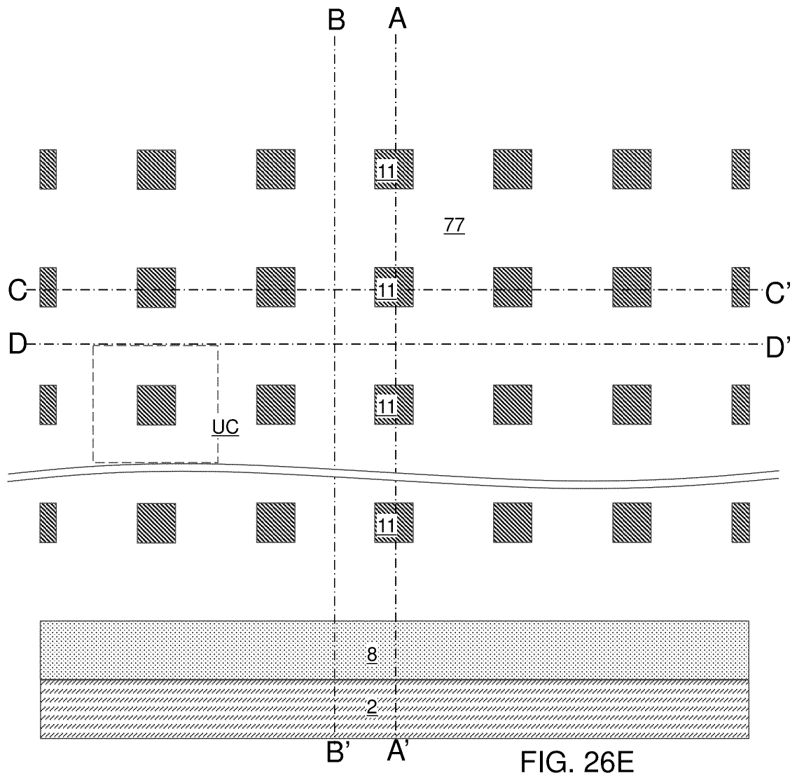

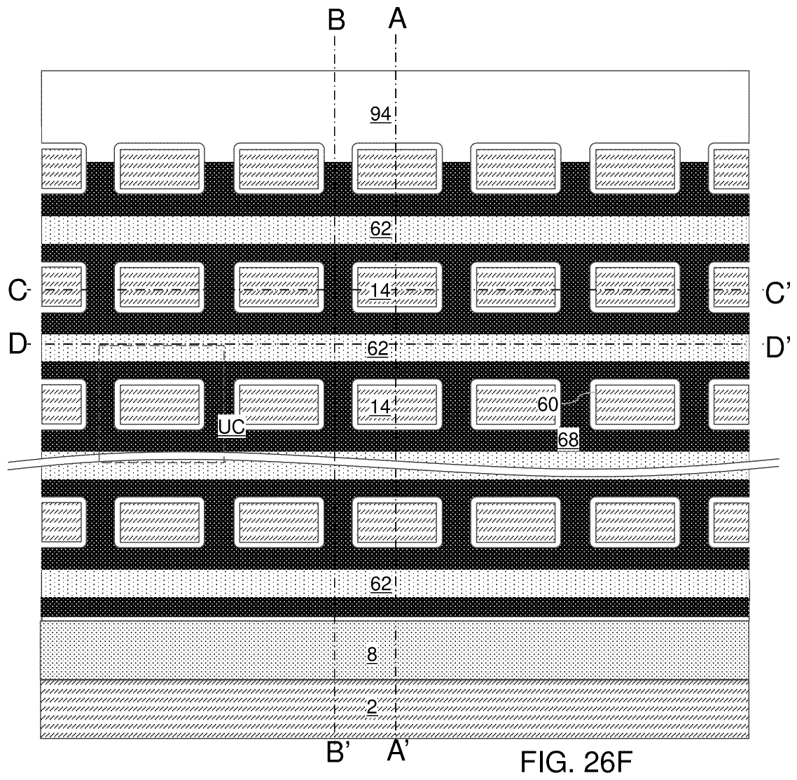

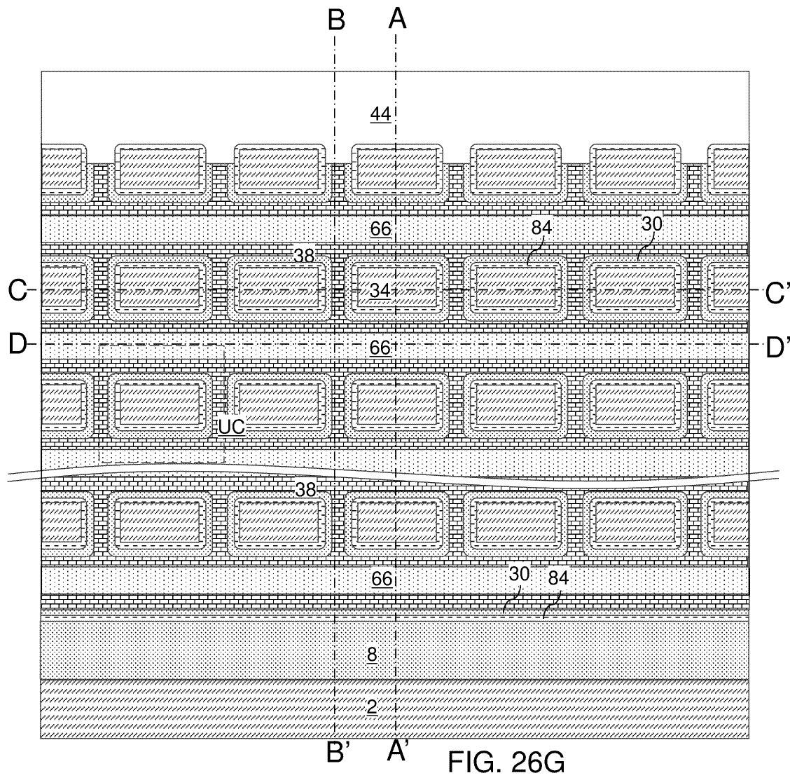

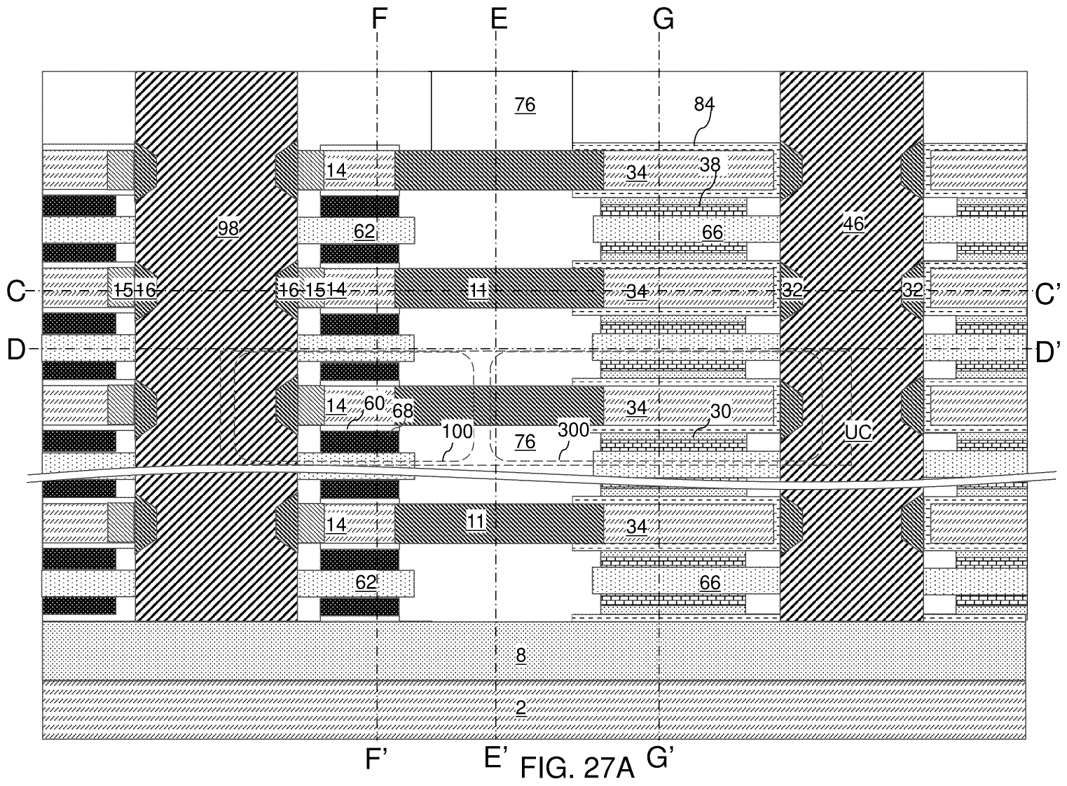

Referring to FIGS. 26A, 26B, 26C, 26D, 26E, 26F, and 26G, a first isotropic etch process can be performed to isotropically etch physically exposed portions of the channel material layer 84L. The first isotropic etch process can etch the physically exposed portions of the channel material layer 84L selectively to the materials of the bit-line trench isolation structures 94, the source trench isolation structures 44, and optionally selectively to the material of the first gate dielectric material layers 60L. The first isotropic etch process may be selective to the material of the doped semiconductor material portions 11, or may collaterally recess the material of the doped semiconductor material portions 11. Vertically extending portions of the channel material layers 84L located around the bridges-encircling cavities 77 can be removed, and vertically-extending sidewalls of the second gate dielectric material layers 30L can be physically exposed. The patterned discrete portions of the channel material layers 84L comprise tubular-portion-containing channels 84. A three-dimensional L×M×N array of tubular-portion-containing channels 84 can be formed. Each tubular-portion-containing channel 84 has a tubular shape and having an end cap portion on a first end of the tubular shape. The horizontally-extending semiconductor beams 34 can function as core structures that are surrounded by a respective one of the tubular-portion-containing channels 84. If the beams 34 comprise a semiconductor material, such as silicon, then they can function as an inner core portion of a core-shell horizontal semiconductor channel (34, 84), while the tubular-portion-containing channels 84 function as the outer shell portion of the core-shell horizontal semiconductor channel (34, 84). Since the silicon beam 34 does not contact a ferroelectric second gate dielectric 30, the endurance of the FeFET can be improved. Depending on the positions of the vertical source lines 46, a tubular-portion-containing channel 84 may optionally comprise an end wall portion having an end wall that is perpendicular to the first horizontal direction hd1 and contacting a respective one of the horizontally-extending semiconductor beams 34.

Subsequently, a second isotropic etch process can be performed to isotropically etch physically exposed portions of the first gate dielectric material and the second gate dielectric material around the one-dimensional array of bridges-encircling cavities 77. The second isotropic etch process can isotropically etch the materials of the first gate dielectric material layers 60L and the second gate dielectric material layers 30L selectively to the materials of the semiconductor rails (15, 14, 11, 34), the first gate electrode material layers 68S, and the second gate electrode material layers 38S. Each first gate dielectric material layer 60L can be divided into an M×(N+1) two-dimensional array of first gate dielectrics 60 each having a respective tubular configuration and laterally surrounding a respective horizontally-extending semiconductor channel 14. Each second gate dielectric material layer 30L can be divided into an M×(N+1) two-dimensional array of second gate dielectrics 30 each having a respective tubular configuration and laterally surrounding a respective horizontally-extending semiconductor beam 34. Thus, remaining portions of the first gate dielectric material comprise a three-dimensional array of first gate dielectrics 60, and remaining portions of the second gate dielectric material comprise a three-dimensional array of second gate dielectrics 30.

A third isotropic etch process can be performed to isotropically etch physically exposed portions of the first gate electrode material and the second gate electrode material around the one-dimensional array of bridges-encircling cavities 77. The third isotropic etch process can isotropically etch the materials of the first gate electrode material layers 68S and the second gate electrode material layers 38S selectively to the materials of the vertical bit lines 98, the vertical source lines 46, the semiconductor rails (15, 14, 11, 34), the first gate dielectrics 60, and the second gate dielectrics 30. Each first gate electrode material layer 68S can be divided into N first word lines 68 and optionally one or more drain select lines. Each first word line 68 laterally surrounds a respective set of M first gate dielectrics 60, and thus, comprises M first gate electrodes of M first field effect transistors. Each second gate electrode material layer 38S can be divided into N second word lines 38 and optionally one or more source select lines Each second word line 38 laterally surrounds a respective set of M second gate dielectrics 30, and thus, comprises M second gate electrodes of M second field effect transistors. Thus, remaining portions of the first gate electrode material comprise a two-dimensional array of first word lines 68, and remaining portions of the second gate electrode material comprise a two-dimensional array of second word lines 38.

The first exemplary structure may comprise an L×M×N three-dimensional array of unit cells UC. In one embodiment, each of the unit cells UC comprises: an access field effect transistor (e.g., read transistor) 100 comprising a horizontally-extending semiconductor channel 14, a first gate dielectric 60, and a first gate electrode (which is a portion of a first word line 68); and a memory field effect transistor (e.g., write transistor) 300 comprising a tubular-portion-containing channel 84, a second gate dielectric 30, and a second gate electrode (which is a portion of a second word line 38). The second gate dielectric 30 comprises a memory dielectric material having at least two programmable states that modulate electrical transconductance of the tubular-portion-containing channel 84.

In one embodiment, within each of the unit cells UC, the tubular-portion-containing channel 84 surrounds a core structure which may comprise a horizontally-extending semiconductor beam 34. In one embodiment, the combination of the tubular-portion-containing channel 84 and the core structure comprising the horizontally-extending semiconductor beam 34 function as a semiconductor channel of the memory field effect transistor 300. In one embodiment, within each of the unit cells UC, the core structure (i.e., the horizontally-extending semiconductor beam 34) comprises a semiconductor material having a same material composition as the horizontally-extending semiconductor channel 14. In one embodiment, each of the unit cells UC comprises a doped semiconductor material portion 11 is located between the horizontally-extending semiconductor channel 14 and the core structure which comprises the horizontally-extending semiconductor beam 34. In one embodiment, the doped semiconductor material portion 11 is in contact with an end surface of the horizontally-extending semiconductor channel 14 and in contact with an end surface of the core structure comprising the horizontally-extending semiconductor beam 34.

In one embodiment, within each of the unit cells UC: the horizontally-extending semiconductor channel 14 and the tubular-portion-containing channel 84 laterally extend along a first horizontal direction hd1; and the horizontally-extending semiconductor channel 14 has a first width w1 along a second horizontal direction hd2 that is perpendicular to the first horizontal direction hd1; and the width of the tubular-portion-containing channel 84 along the second horizontal direction hd2 is greater than the first width w1.

In one embodiment, each of the unit cells UC comprises a doped semiconductor material portion 11 that comprises: a first end portion in contact with the horizontally-extending semiconductor channel 14 and having the first width w1; a second end portion that is laterally spaced from the first end portion toward the tubular-portion-containing channel 84 and having the first width w1; and a neck portion located between the first end portion and the second end portion and having a second width w2 that is less than the first width w1.

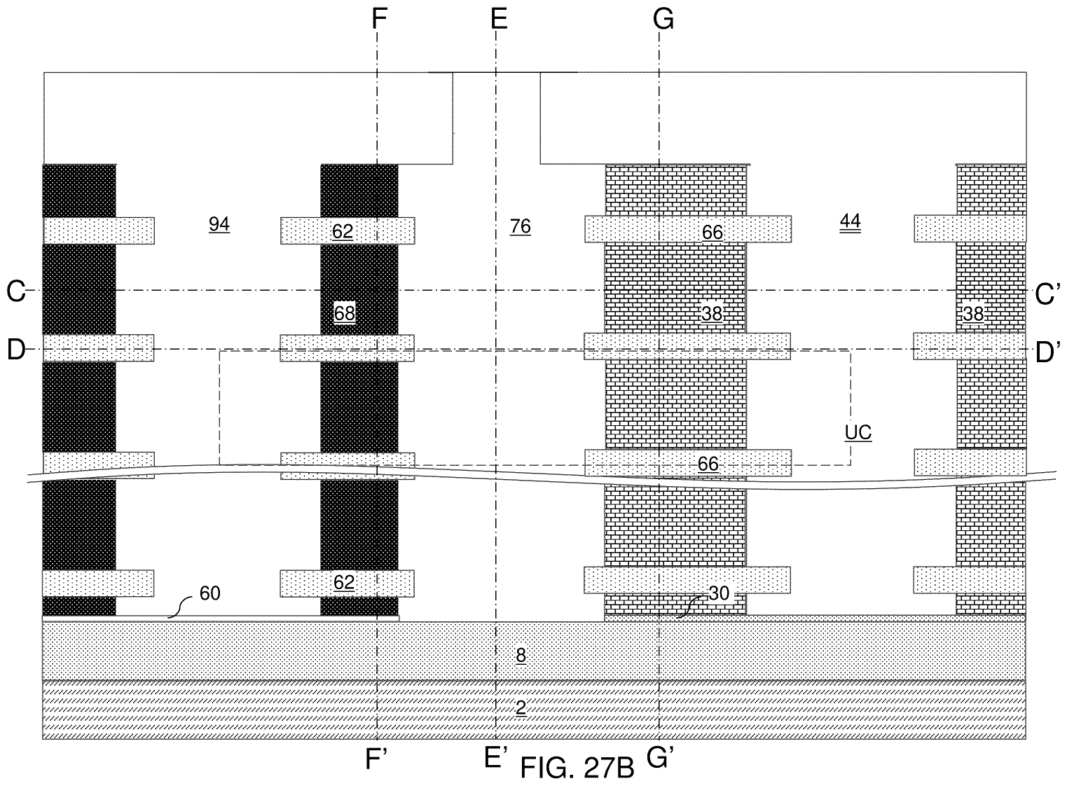

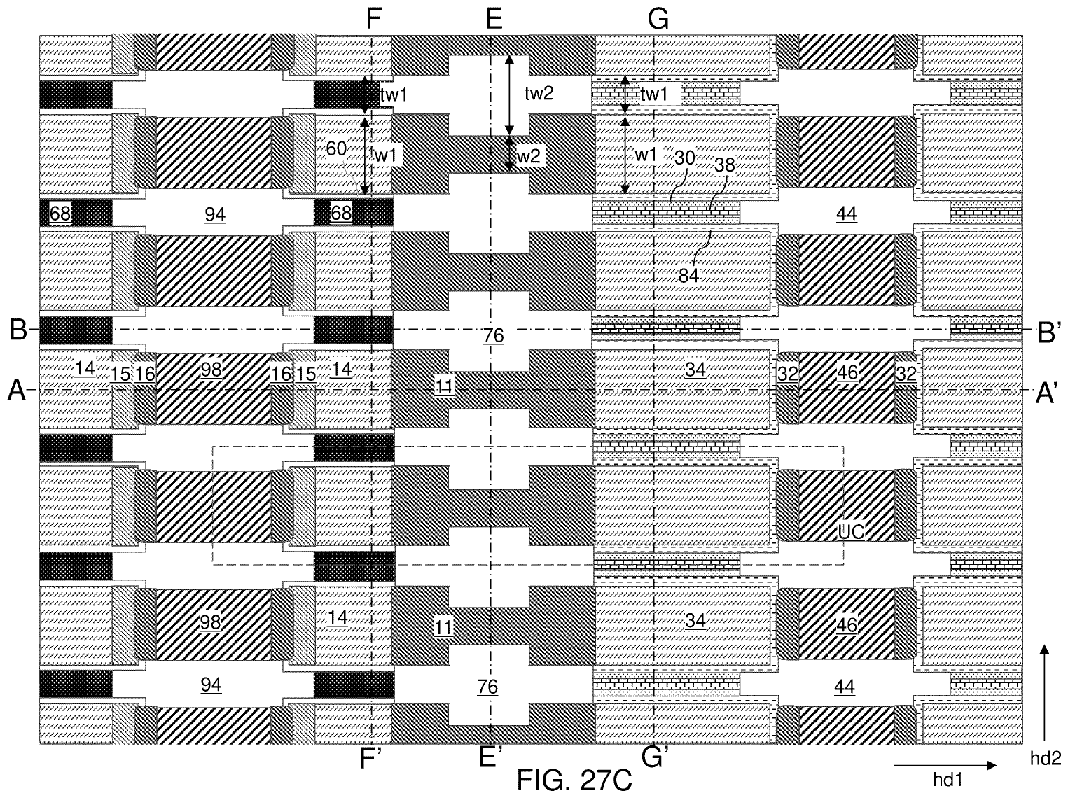

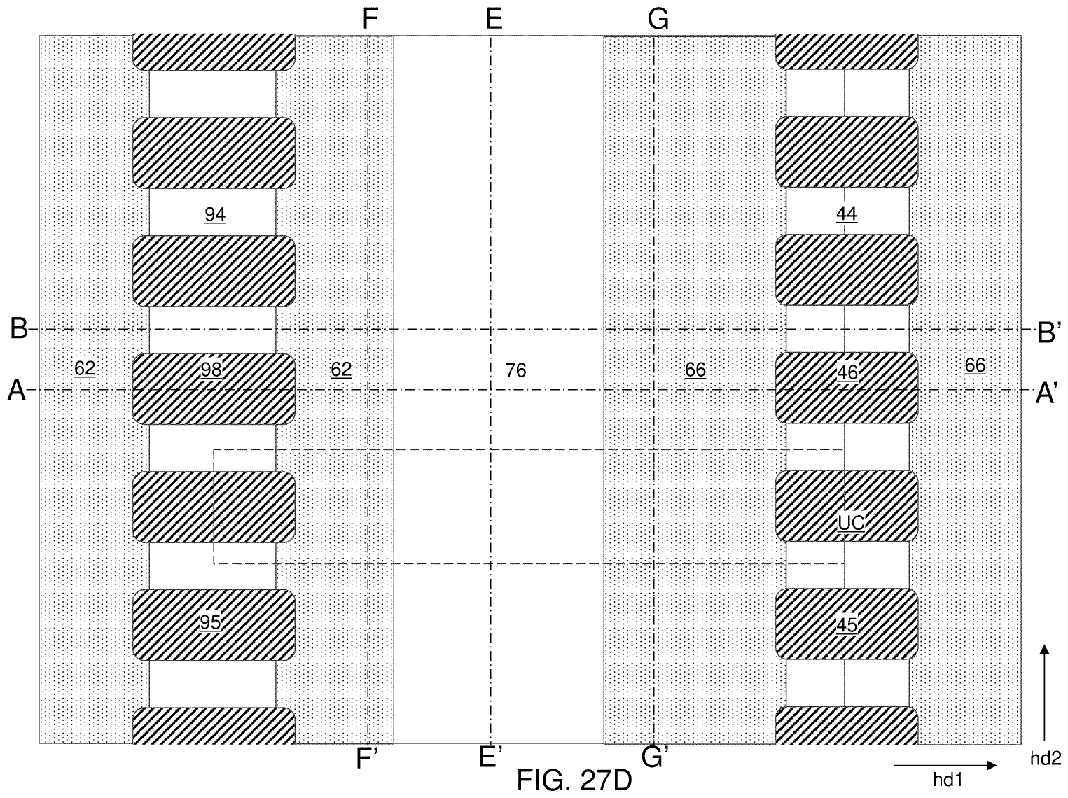

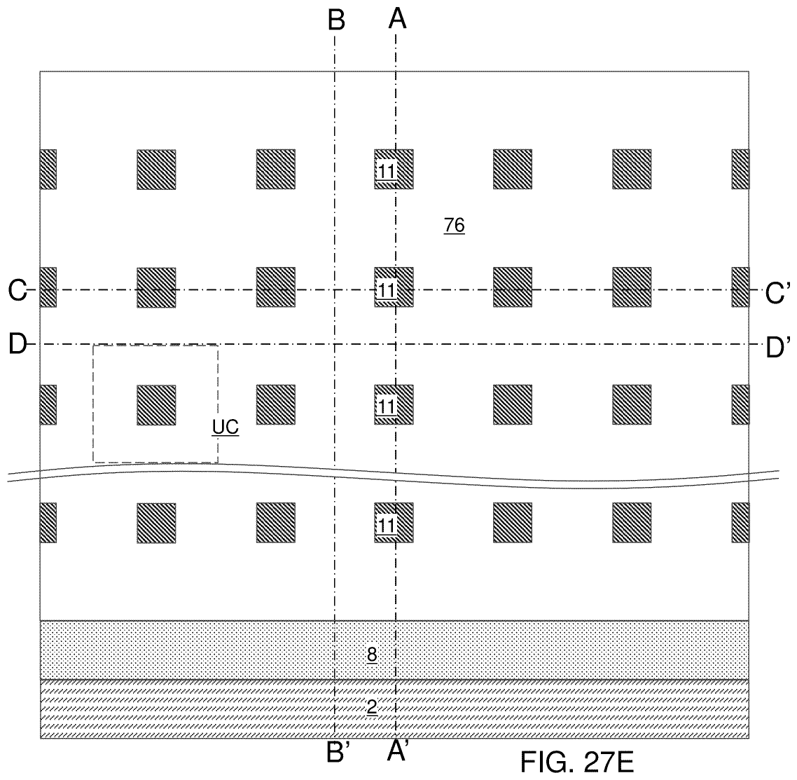

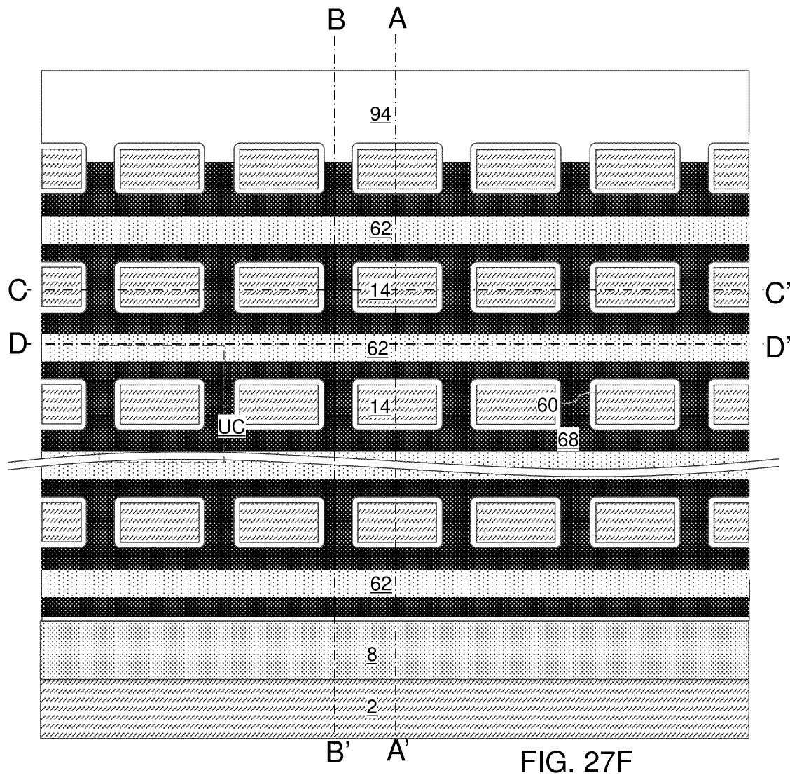

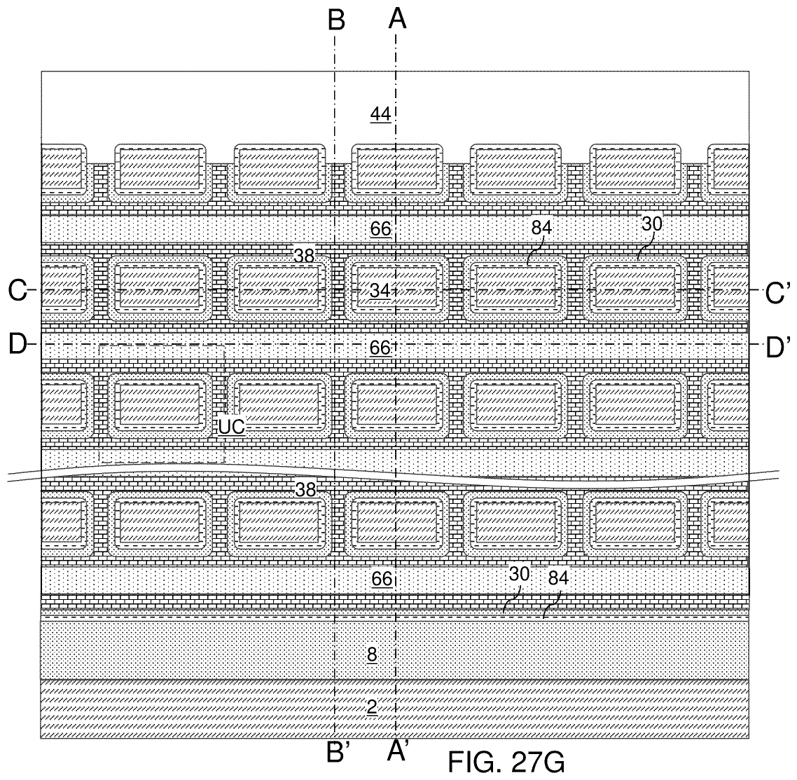

Referring to FIGS. 27A, 27B, 27C, 27D, 27E, 27F, and 27G, a dielectric fill material such as silicon oxide may be conformally deposited in the bridges-encircling cavities 77. Excess portions of the dielectric fill material can be removed from above the horizontal plane including top surfaces of the bit-line trench isolation structures 94 and the source trench isolation structures 44 by performing a planarization process, which may comprise a chemical mechanical polishing process or a recess etch process. A one-dimensional array of perforated dielectric walls 76 can be formed in the bridges-encircling cavities 77. The one-dimensional array of perforated dielectric walls 76 can be arranged along the first horizontal direction hd1. Each perforated dielectric wall 76 within the one-dimensional array of perforated dielectric walls 76 surrounds a respective two-dimensional array of doped semiconductor material portions 11.

In one embodiment, each perforated dielectric wall 76 within the one-dimensional array of perforated dielectric walls 76 contacts a respective two-dimensional array of first gate electrodes (comprising portions of a vertical stack of first word lines 68) among the first gate electrodes of the three-dimensional array of unit cells UC, and contacts a respective two-dimensional array of second gate electrodes (comprising portions of a vertical stack of second word lines 38). In one embodiment, each perforated dielectric wall 76 within the one-dimensional array of perforated dielectric walls 76 contacts a respective two-dimensional array of the first gate dielectrics 60, and contacts a respective two-dimensional array of the second gate dielectrics 30.

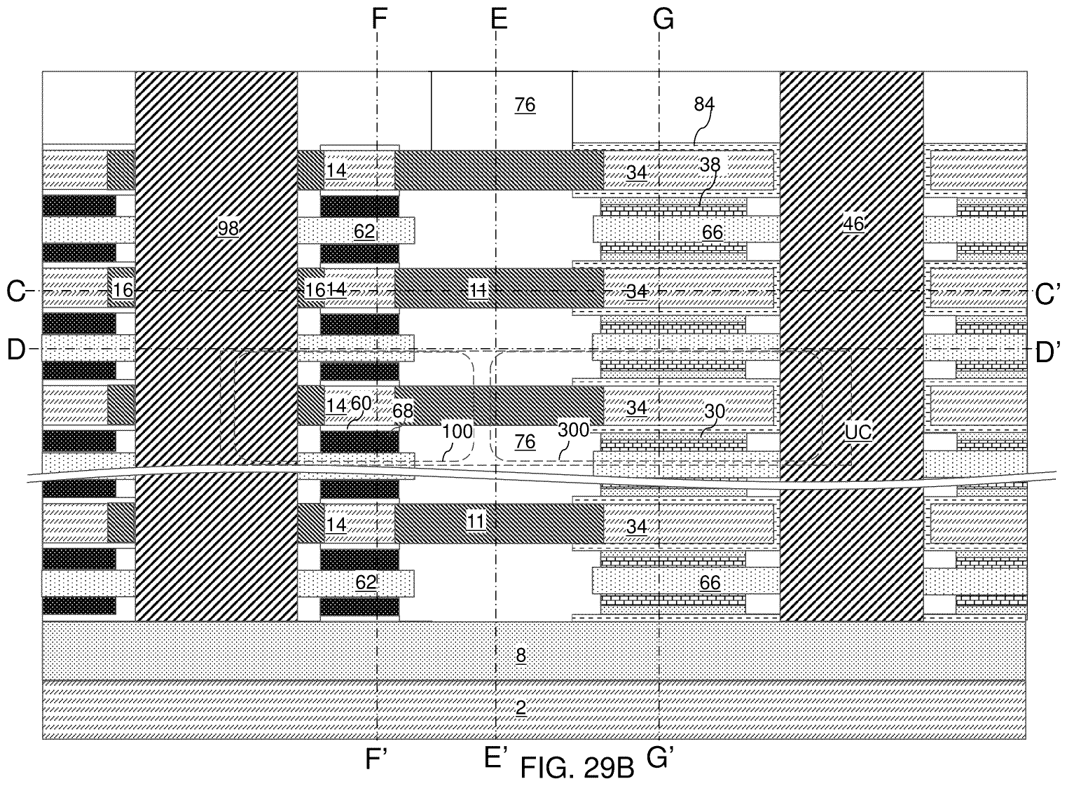

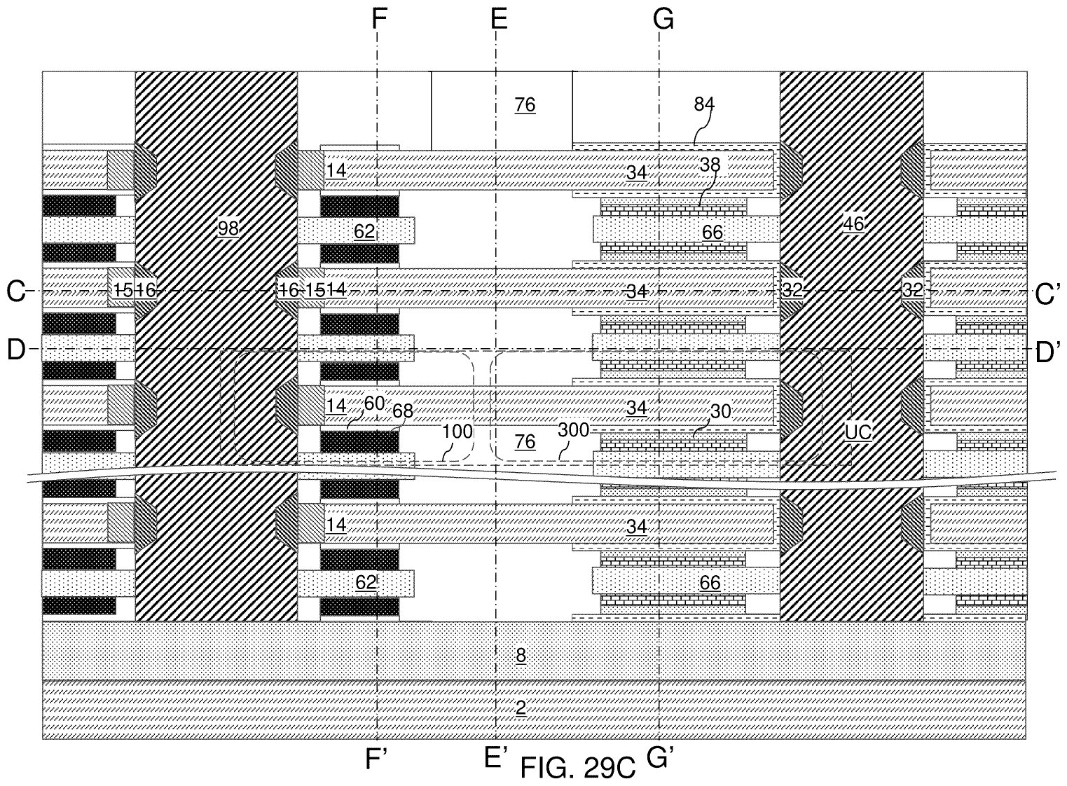

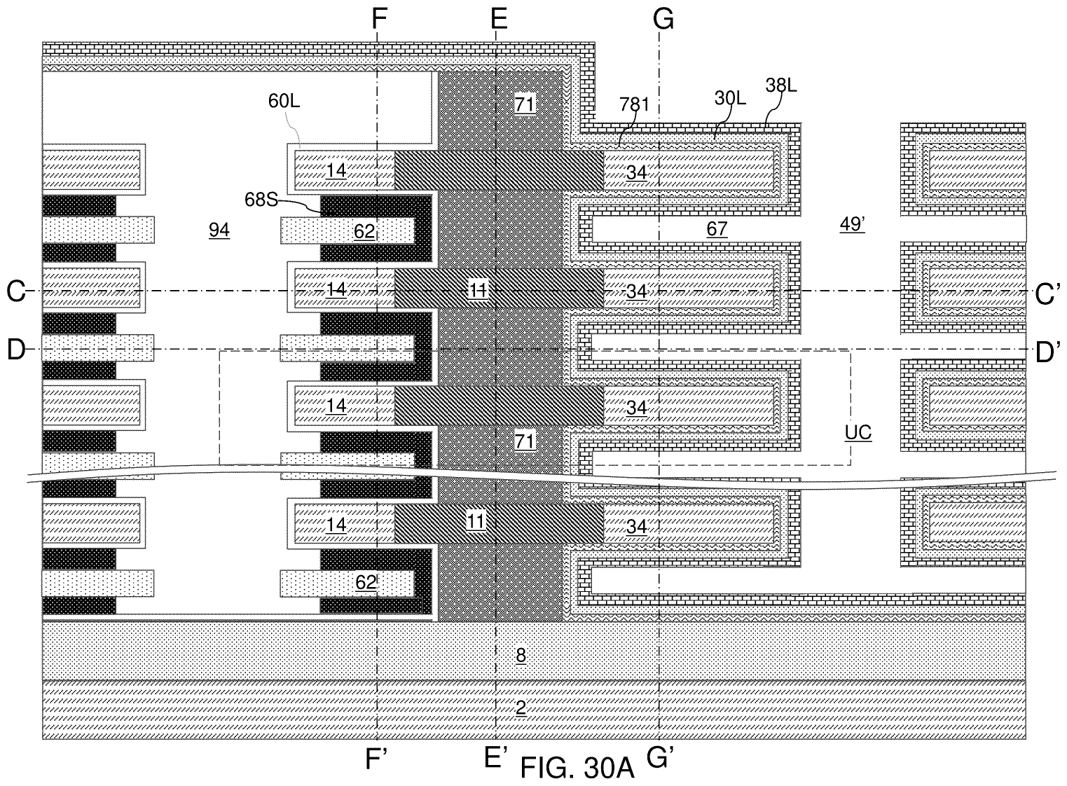

Referring to FIG. 29A, a first alternative configuration of the first exemplary structure is illustrated. The first alternative configuration of the first exemplary structure can be derived from the first exemplary structure in case the material of the tubular-portion-containing channels 84 does not allow selective growth of source regions during selective growth of the drain regions 16. For example, the tubular-portion-containing channels 84 may comprise a compound semiconductor material that does not allow selective growth of source regions while the drain regions 16 are formed on the surfaces of the drain extension regions 15 or on the surfaces of the horizontally-extending semiconductor channels 14 (in case the drain extension regions 15 are omitted). In this case, the vertical source lines 46 may be formed directly on surfaces of the tubular-portion-containing channels 84. In an alternative embodiment, surfaces of the tubular-portion-containing channels 84 may be doped by gas phase doping to form doped source regions together with formation of the drain extension regions 15 or separately from forming the drain extension regions 15.

Referring to FIG. 29B, a second alternative configuration of the first exemplary structure can be derived from the first exemplary structure by omitting a selective semiconductor deposition process described with reference to FIGS. 24A-24G. In this case, the drain extension regions 15 described with reference to FIGS. 24A-24G can function as drain regions 16 in the second alternative configuration of the first exemplary structure.

Referring to FIG. 29C, a third alternative configuration of the first exemplary structure can be derived from the first exemplary structure of FIG. 27A by omitting formation of the doped semiconductor material portions 11.

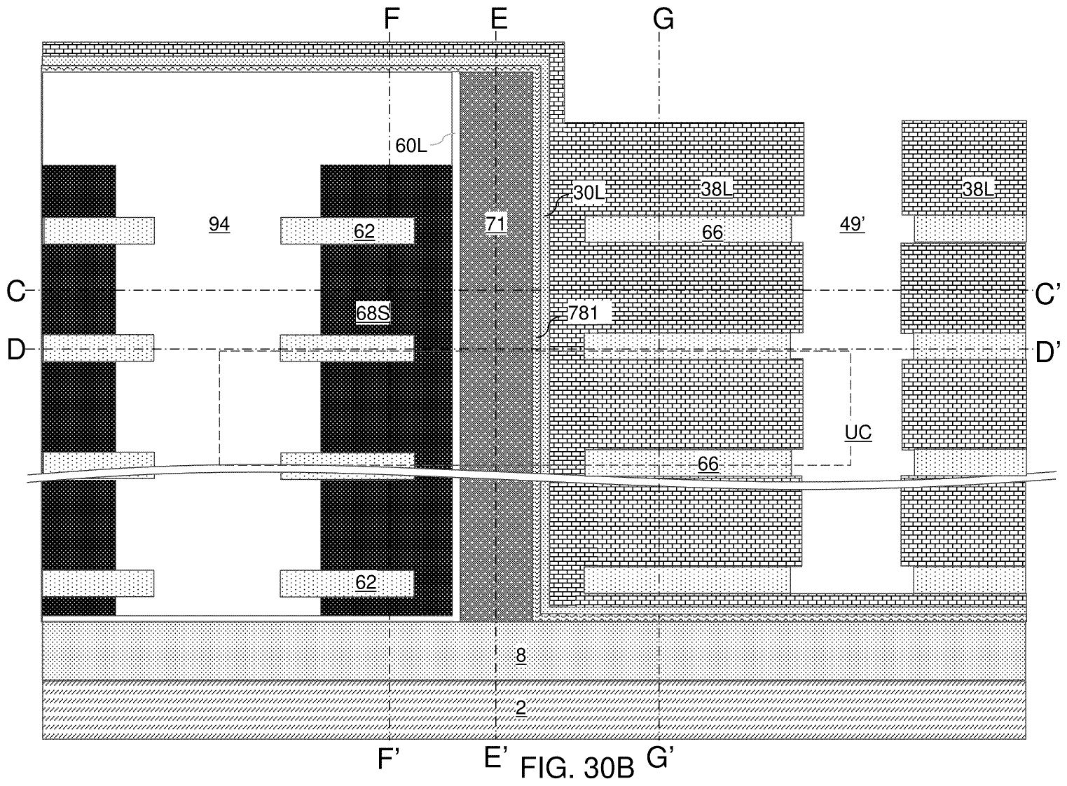

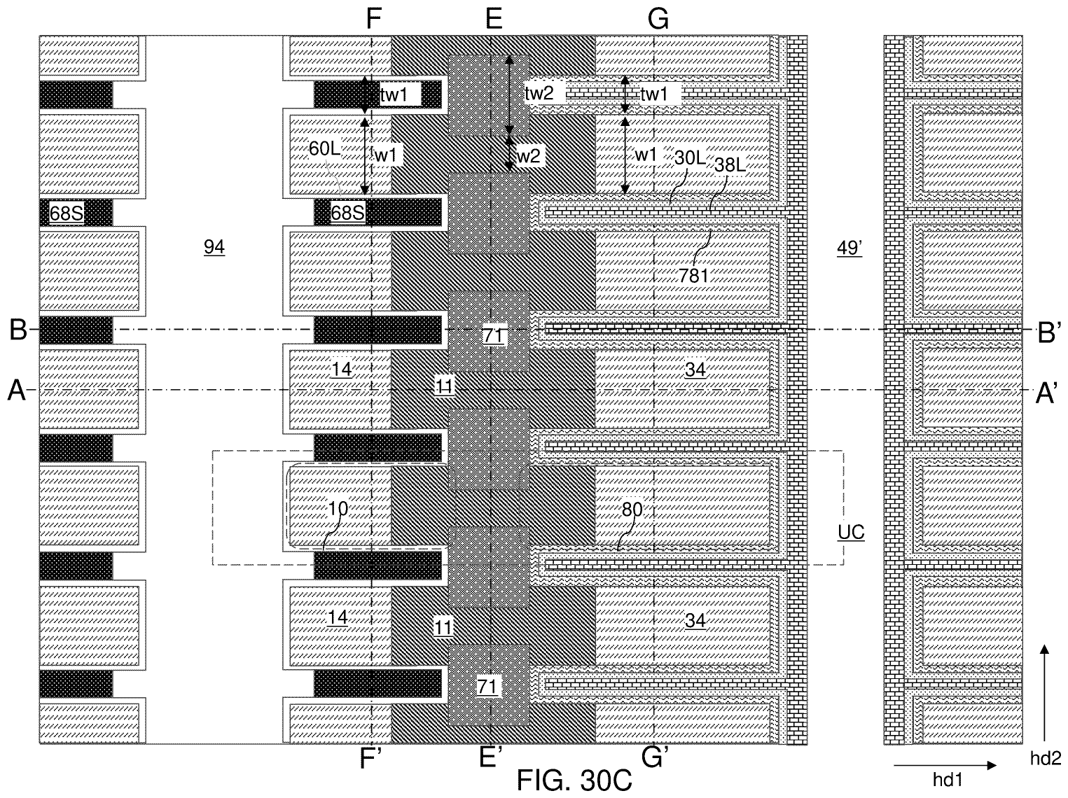

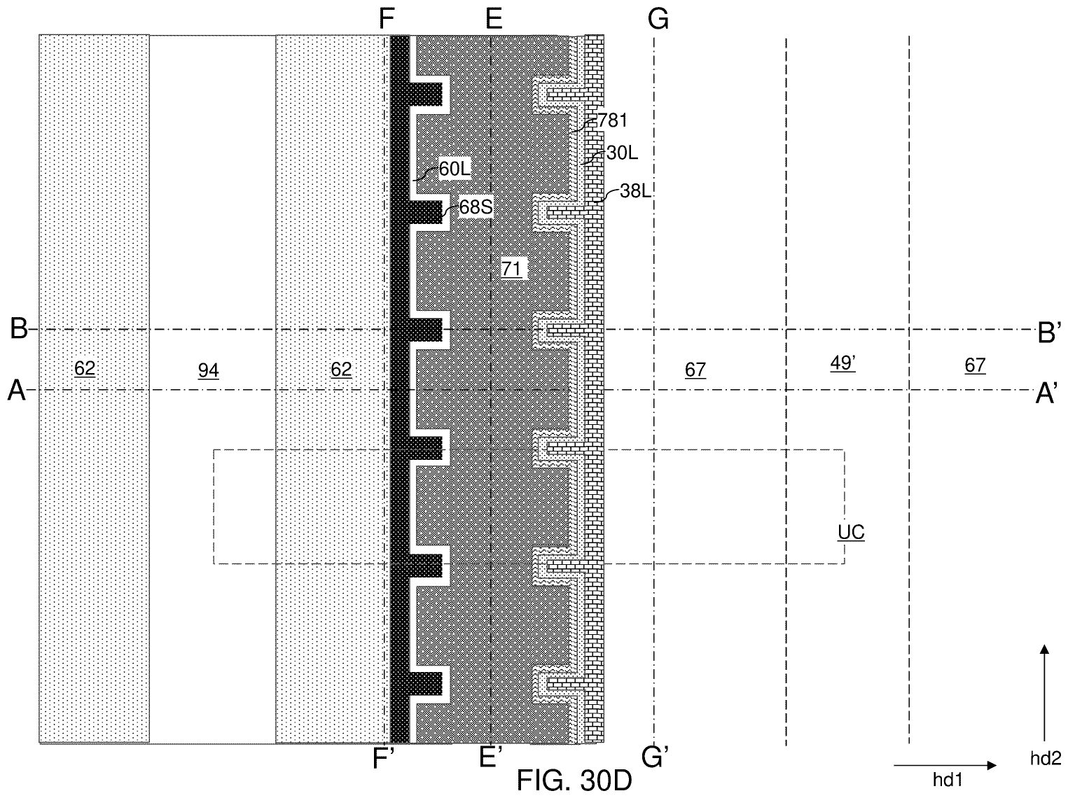

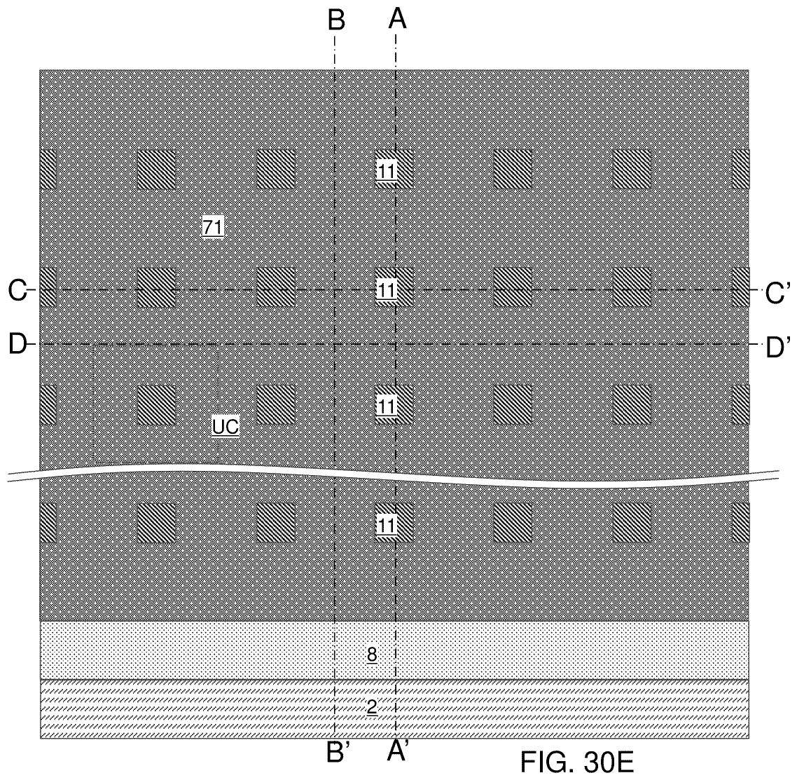

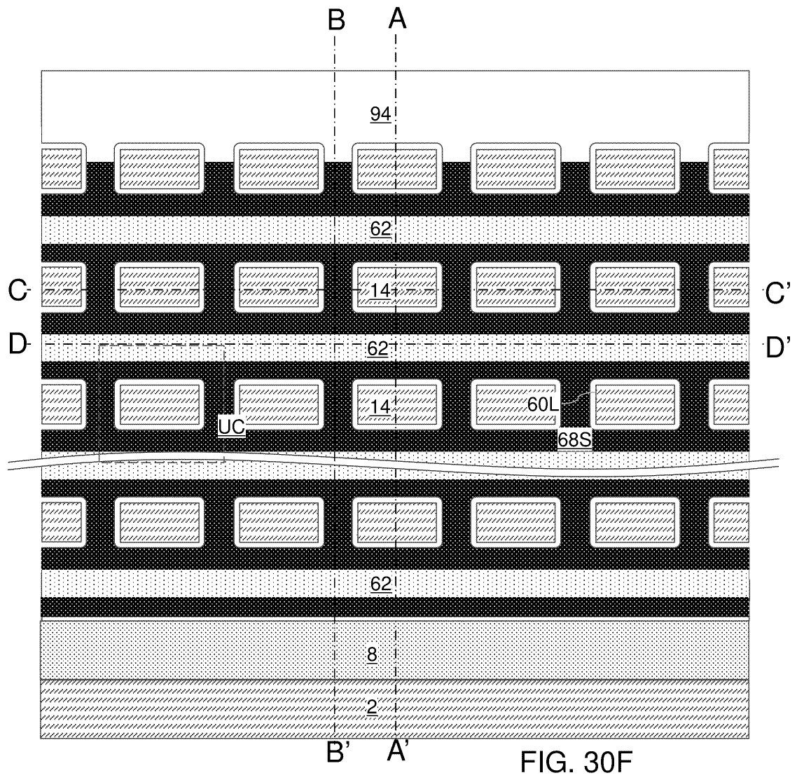

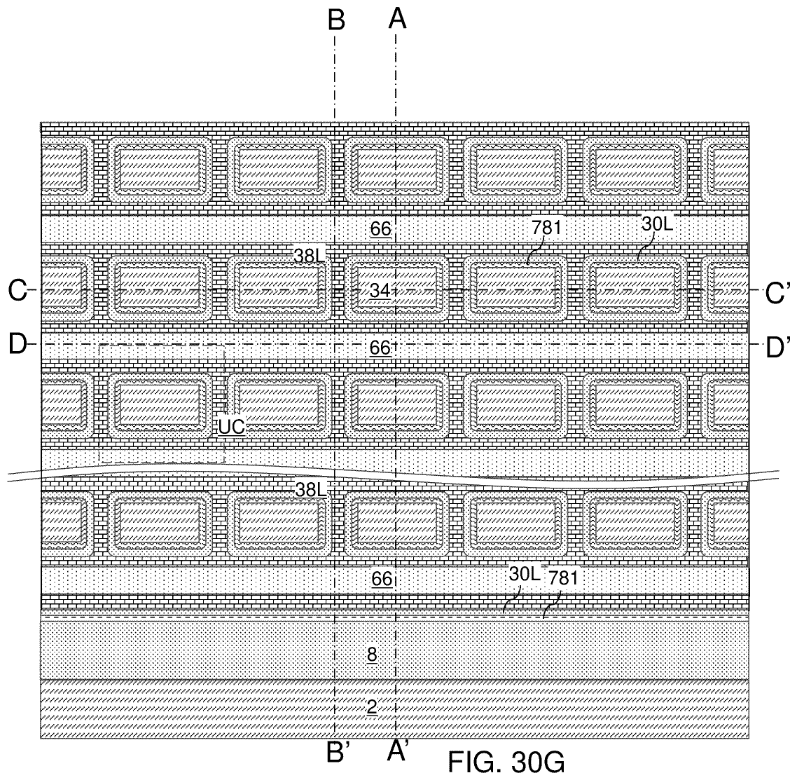

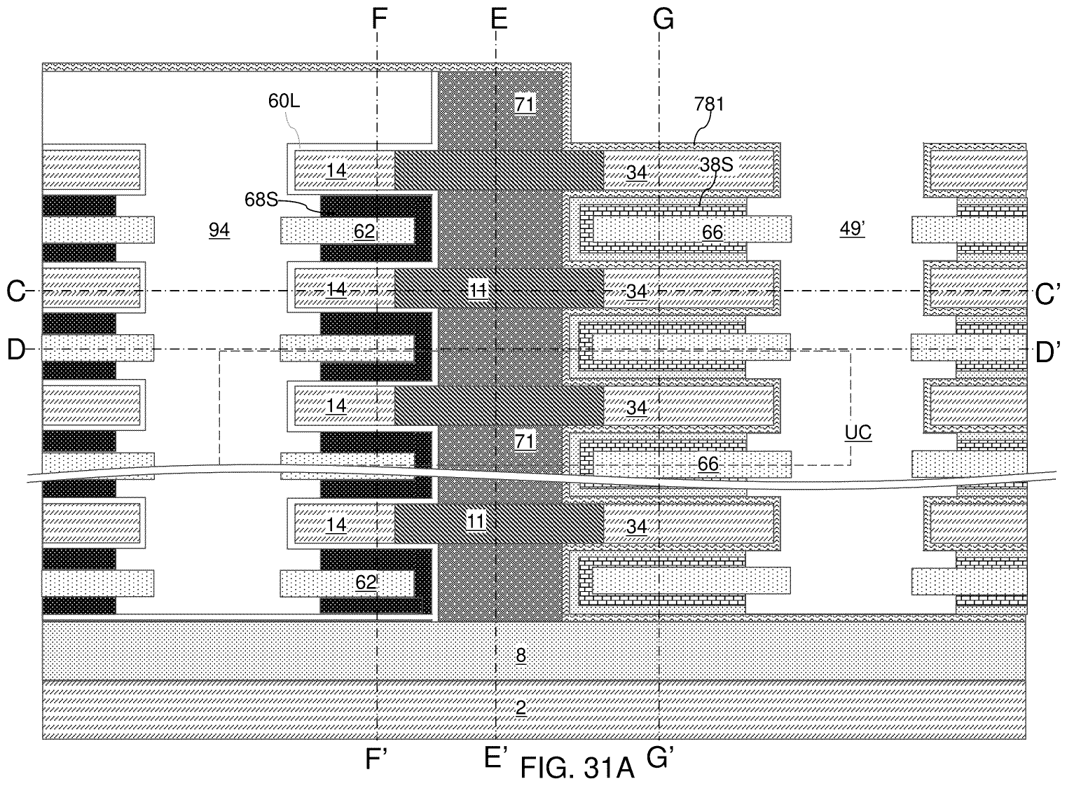

Referring to FIGS. 30A, 30B, 30C, 30D, 30E, 30F, and 30G, a second exemplary structure according to a second embodiment of the present disclosure can be derived from the first exemplary structure illustrated in FIGS. 17A-17H by sequentially depositing an etch-stop layer 781, the second gate dielectric material layer 30L, and the continuous second gate electrode material layer 38L. The etch-stop layer 781 comprises an etch-stop material that can prevent collateral etching of the material of the second gate dielectric material layer 30L during a subsequent isotropic etch process that etches the semiconductor material of the horizontally-extending semiconductor beams 34. In one embodiment, the etch-stop layer 781 may comprise a dielectric metal oxide material (such as aluminum oxide or a transition metal oxide), silicon carbide, silicon nitride, silicon carbonitride, silicon oxynitride, or a thin metallic material, such as titanium nitride. The etch-stop layer 781 may be deposited by a conformal deposition process, such as a chemical vapor deposition process or an atomic layer deposition process. The thickness of the etch-stop layer 781 may be in a range from 1 nm to 20 nm, such as from 2 nm to 5 nm, although lesser and greater thicknesses may also be employed.

The second gate dielectric material layer 30L and the continuous second gate electrode material layer 38L may be the same as described with reference to FIGS. 19A-19G. The continuous second gate electrode material layer 38L comprises a second gate electrode material, which may comprise any suitable conductive material, as described above. The second laterally-extending voids 67 that laterally extend along the second horizontal direction hd2 are present in unfilled volumes of the vertical gaps between neighboring pairs of second portions of the semiconductor rails (14, 11, 34) after deposition of the second gate electrode material of the continuous second gate electrode material layer 38L. A laterally-extending void 49′ can be present within each source trench 49.

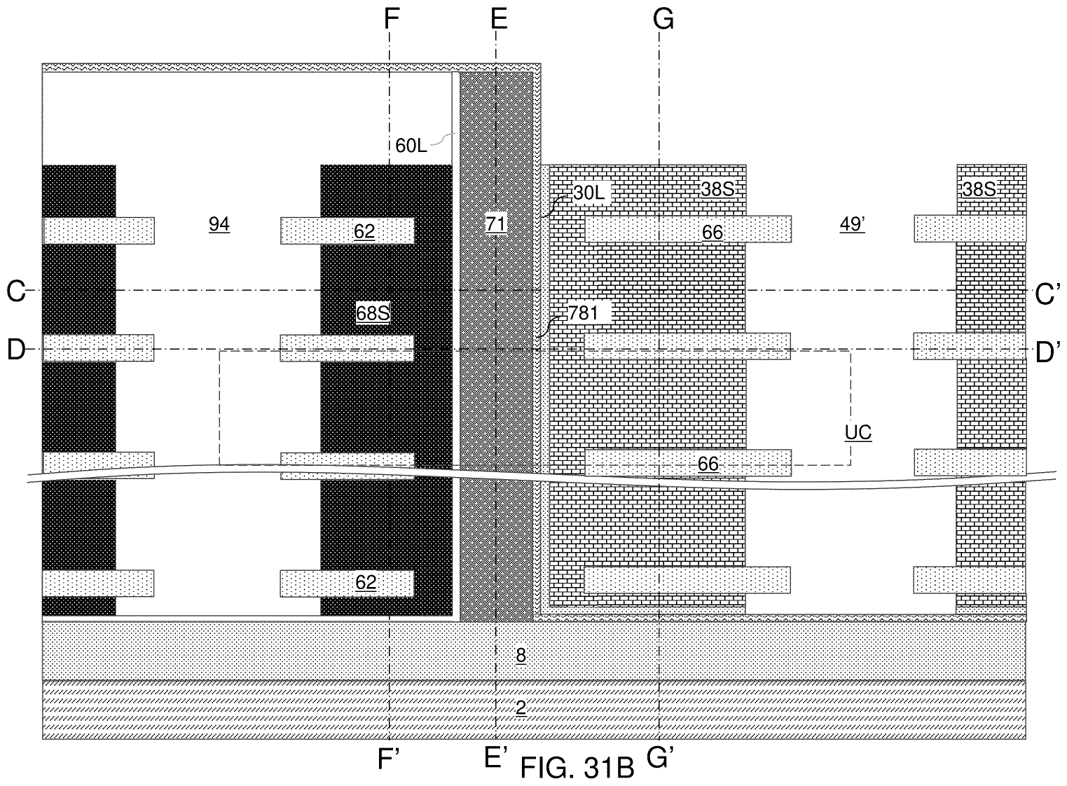

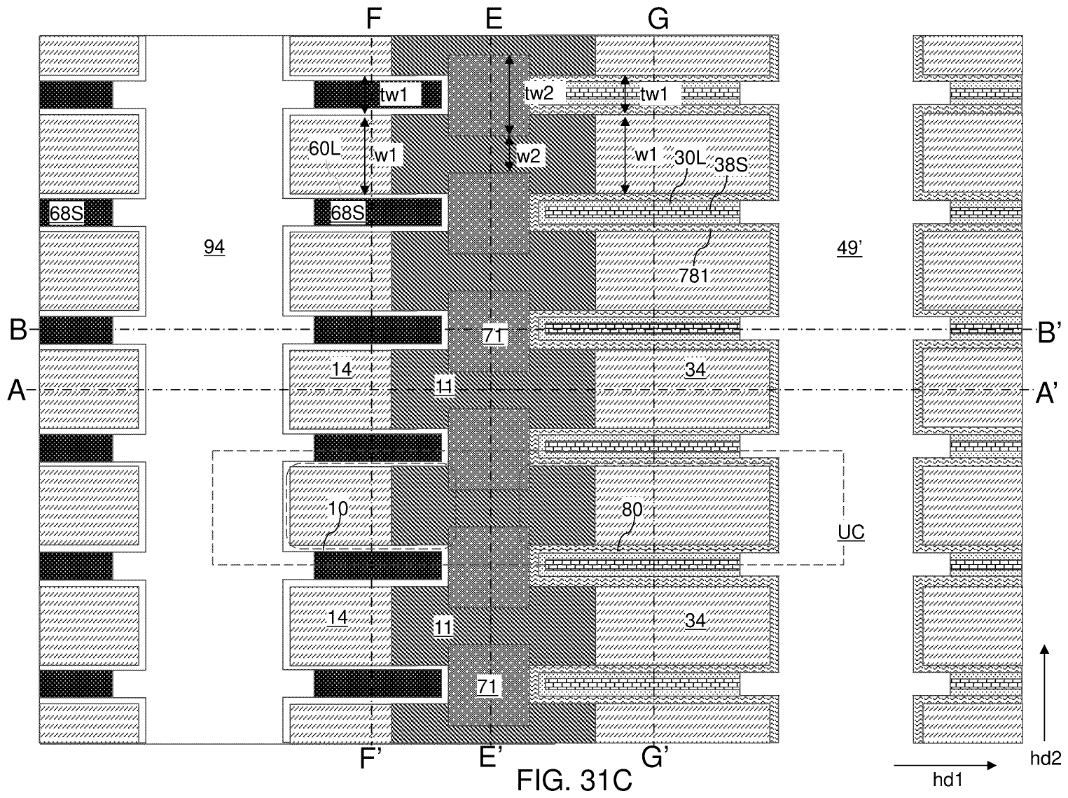

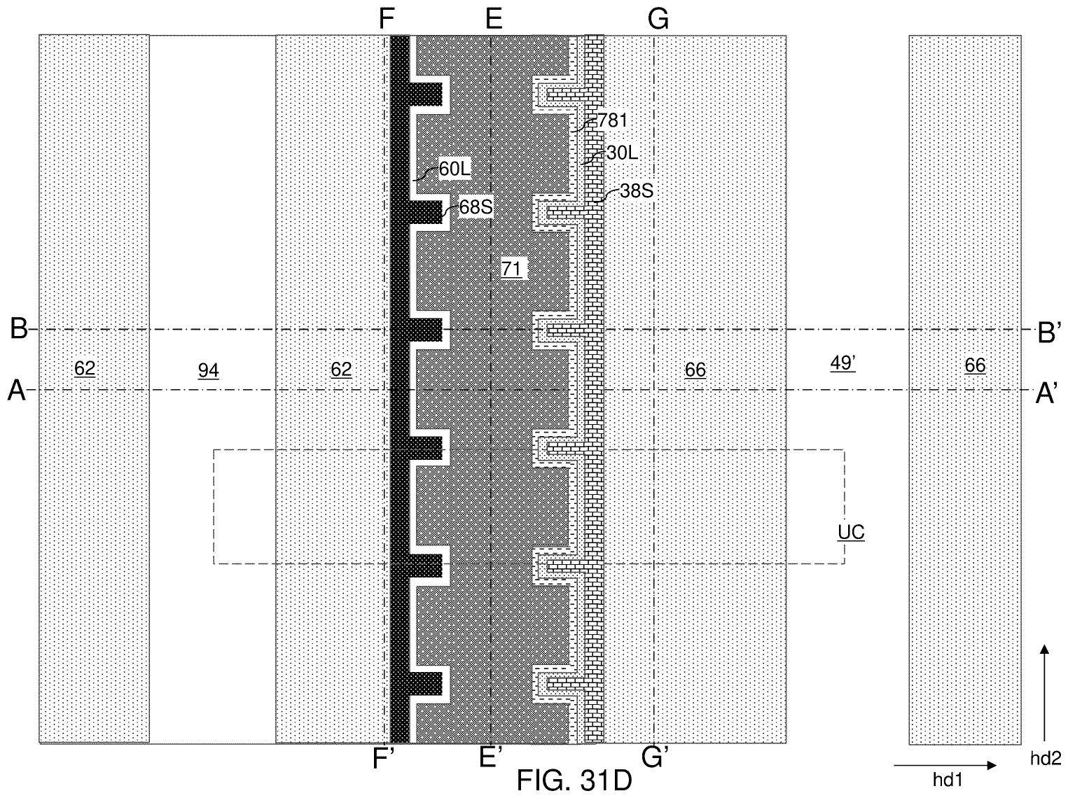

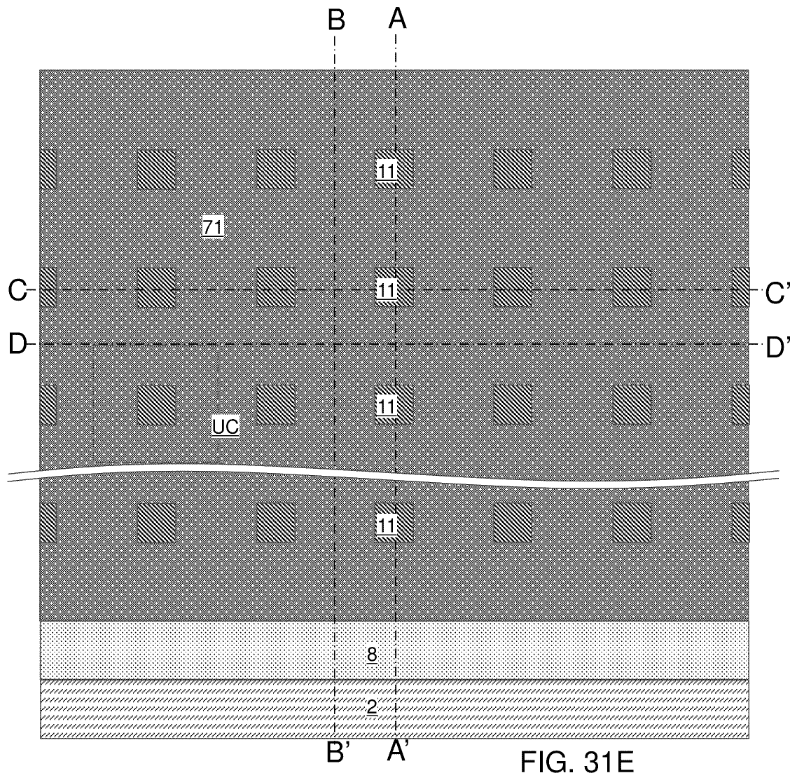

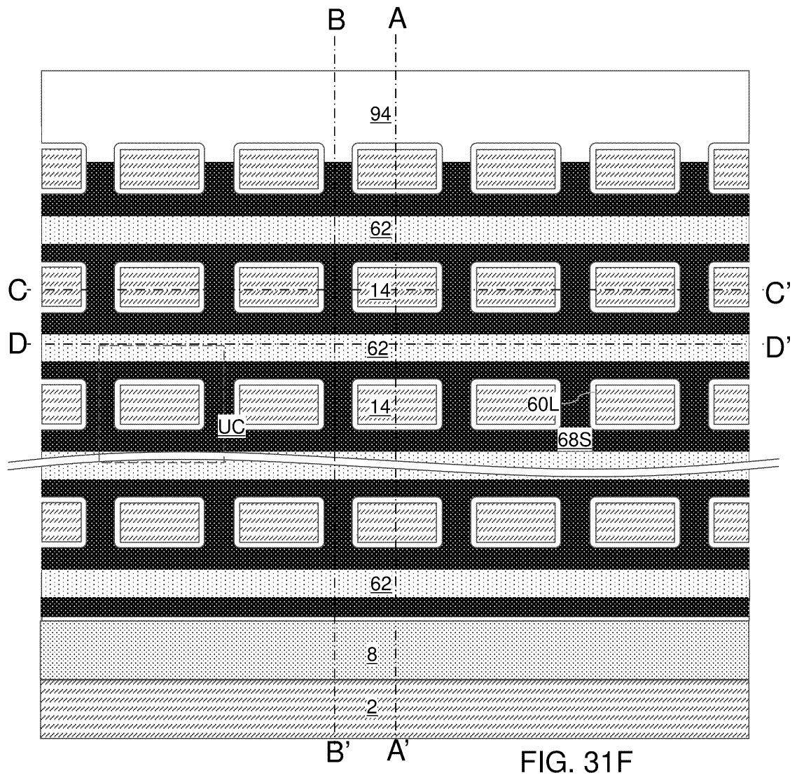

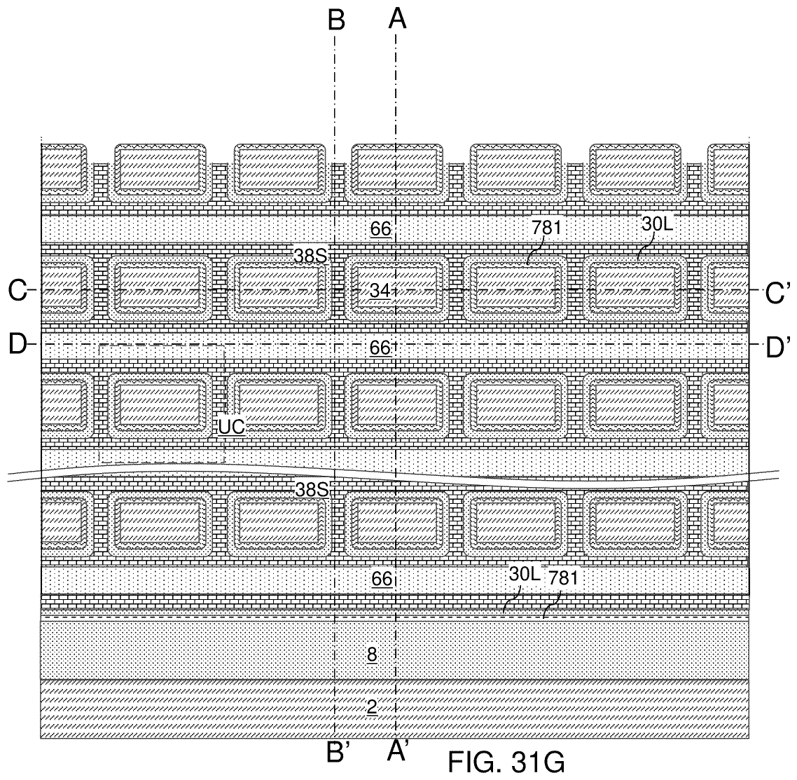

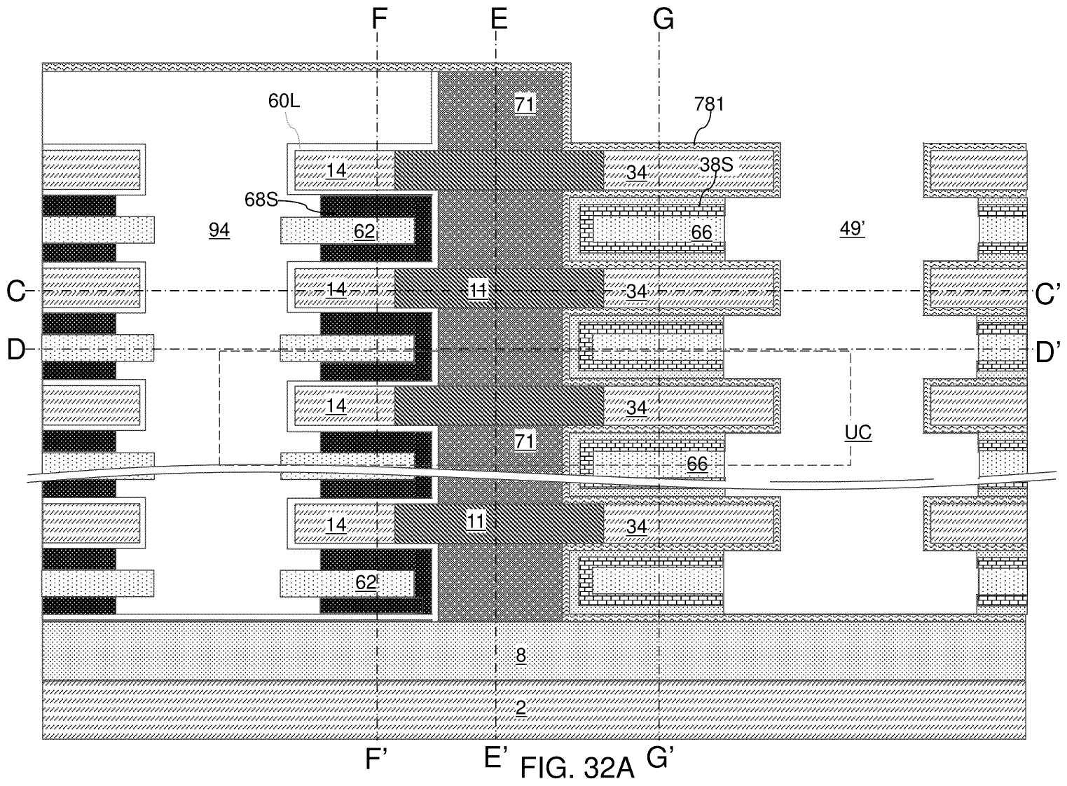

Referring to FIGS. 31A, 31B, 31C, 31D, 31E, 31F, and 31G, a second dielectric fill material, such as silicon oxide can be conformally deposited in the second laterally-extending voids 67, in peripheral portions of the source trenches 49, and over the horizontally-extending portion of the continuous second gate electrode material layer 38L that overlie the three-dimensional array of semiconductor rails (14, 11, 34). An isotropic recess etch process may be performed to remove portions of the second dielectric fill material from outside the volumes of the second laterally-extending voids 67. Remaining portions of the second dielectric fill material that fill the second laterally-extending voids 67 comprise a two-dimensional array of second dielectric plates 66. Each second dielectric plate 66 is formed between a respective vertically neighboring pair of laterally extending portions of the continuous second gate electrode material layer 38L that laterally extend along the second horizontal direction hd2.

Subsequently, a selective isotropic etch process can be performed to etch portions of the continuous second gate electrode material layer 38L that are proximal to the source trenches 49 or overlie the topmost semiconductor rails (14, 11, 34). The selective isotropic etch process can etch the second gate electrode material selectively to the second gate dielectric material. For example, a wet etch process that isotropically etches the second gate electrode material selectively to the second gate dielectric material may be employed. The selective isotropic etch process patterns the continuous second gate electrode material layer 38L into a one-dimensional array of second gate electrode material layers 38S that are laterally spaced apart along the first horizontal direction hd1. Each second gate electrode material layer 38S may surround a respective two-dimensional array of semiconductor rails (14, 11, 34), i.e., a respective two-dimensional array of horizontally-extending semiconductor beams 34. For example, each second gate electrode material layer 38S may have a rectangular array of perforations through which a respective two-dimensional array of horizontally-extending semiconductor beams 34 laterally extends along the first horizontal direction hd1.

Subsequently, an additional selective isotropic etch process can be performed to etch physically exposed portions of the second gate dielectric material layer 30L, i.e., to etch portions of the second gate dielectric material layer 30L that are exposed to the source trenches 49 or overlie the topmost semiconductor rails (14, 11, 34). The second gate dielectric material layer 30L, which is formed as a single continuous material layer at the processing steps described with reference to FIGS. 19A-19G, is divided into L second gate dielectric material layers 30L that are arranged along the first horizontal direction hd1.

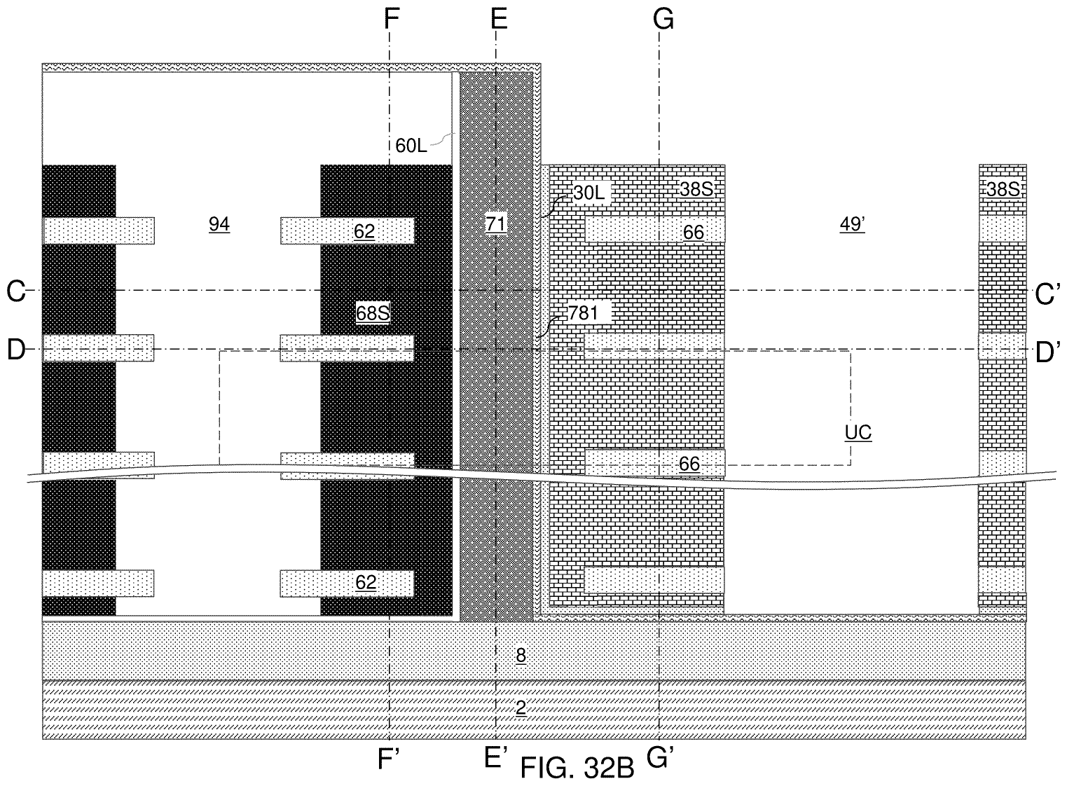

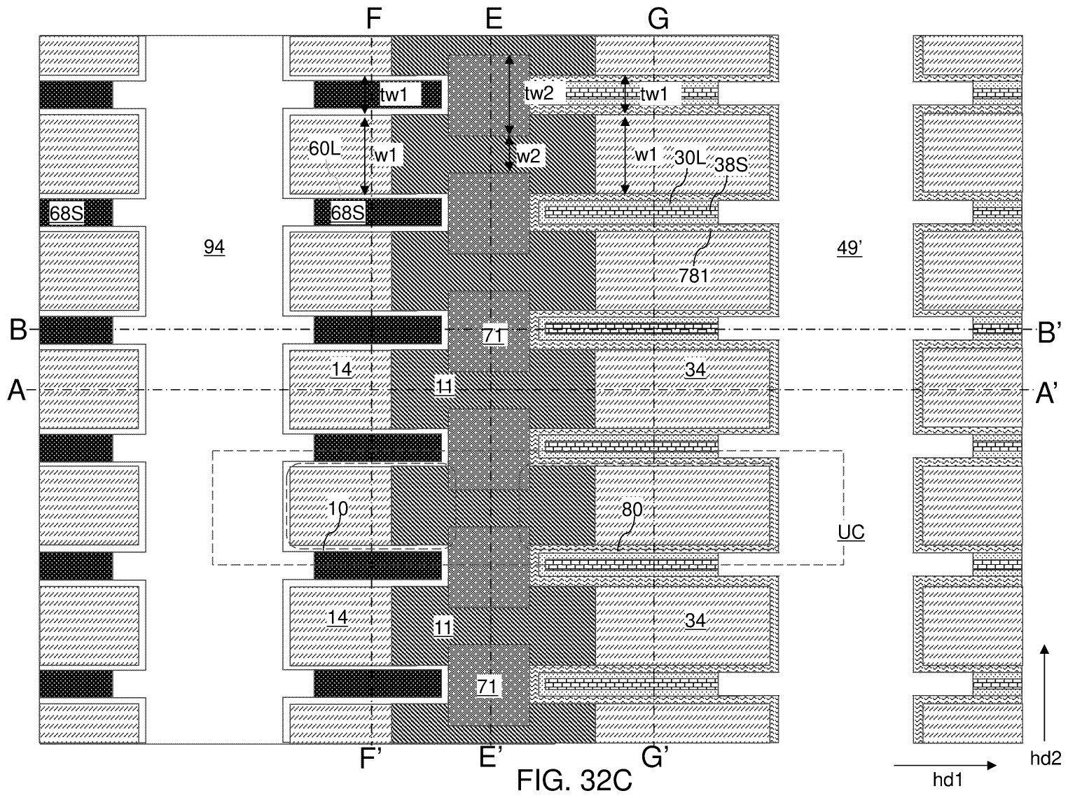

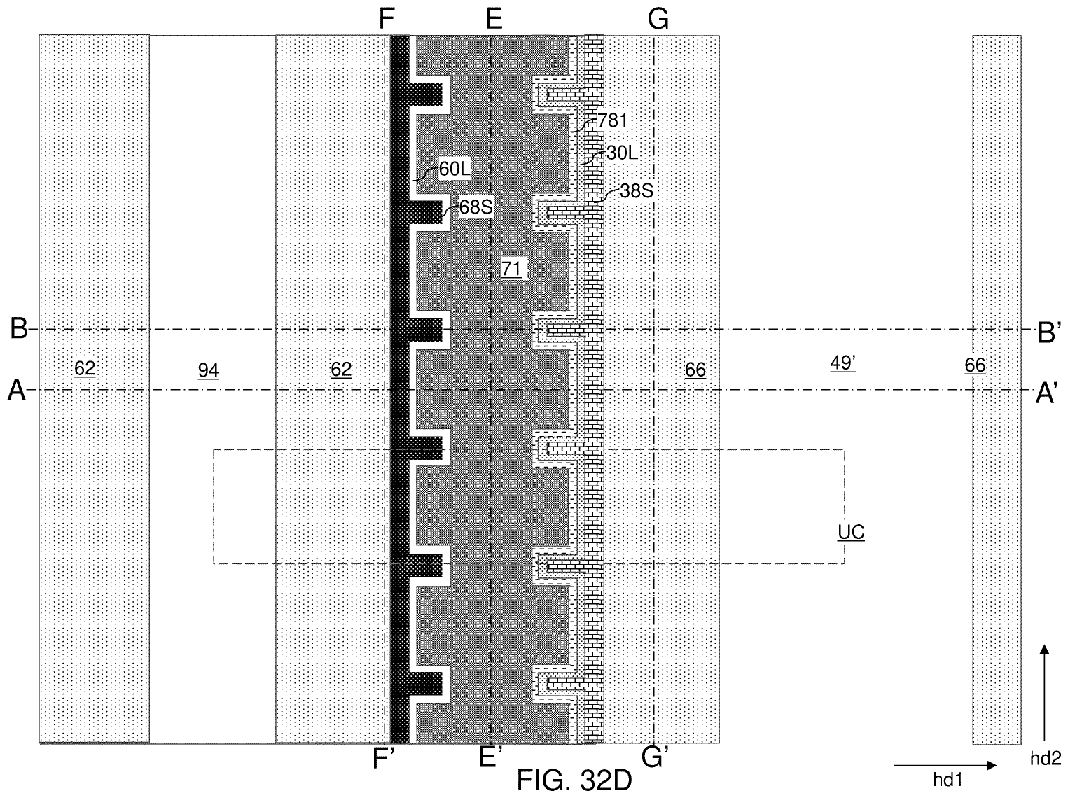

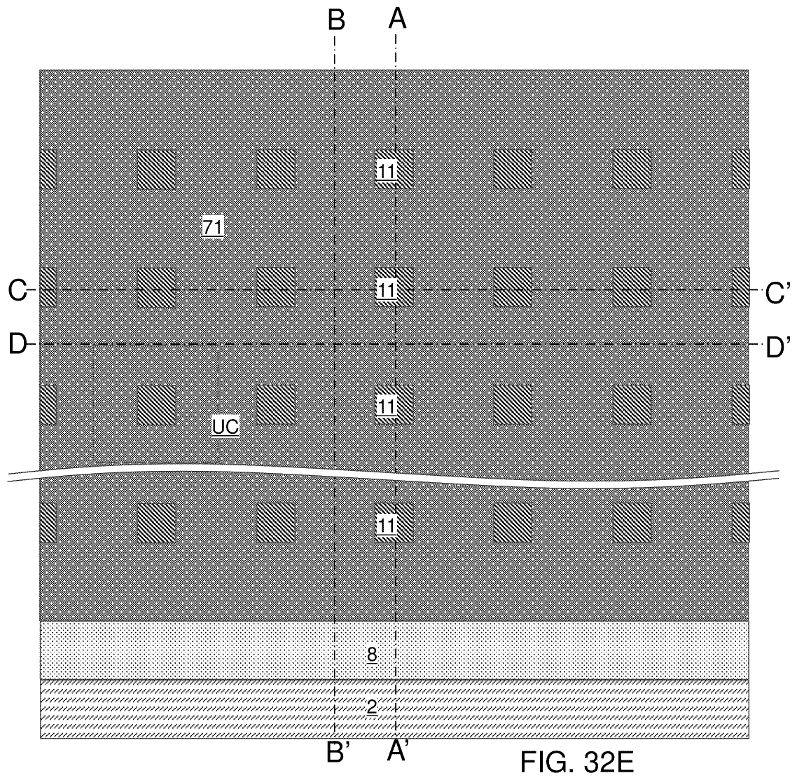

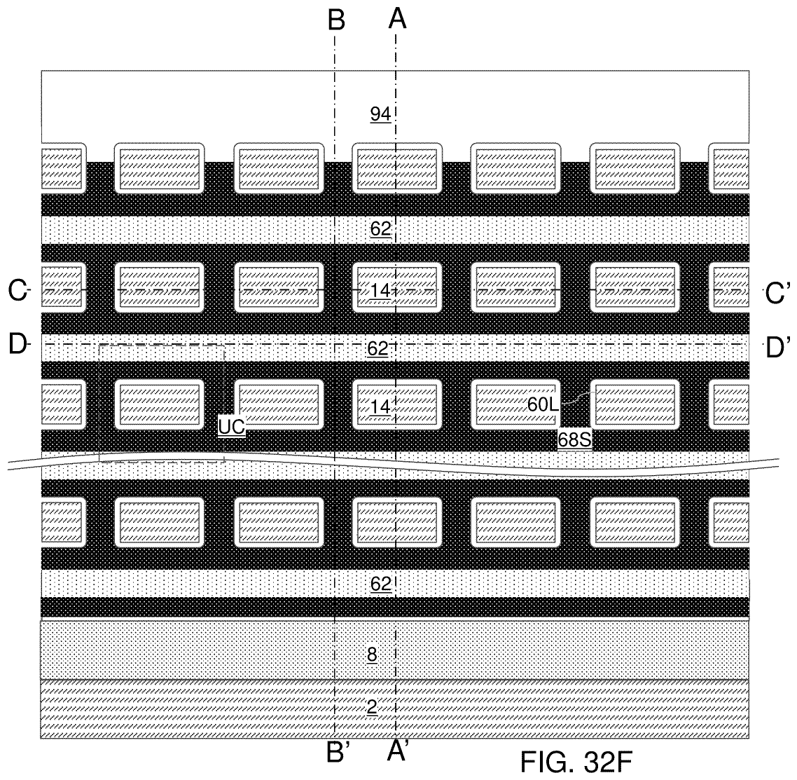

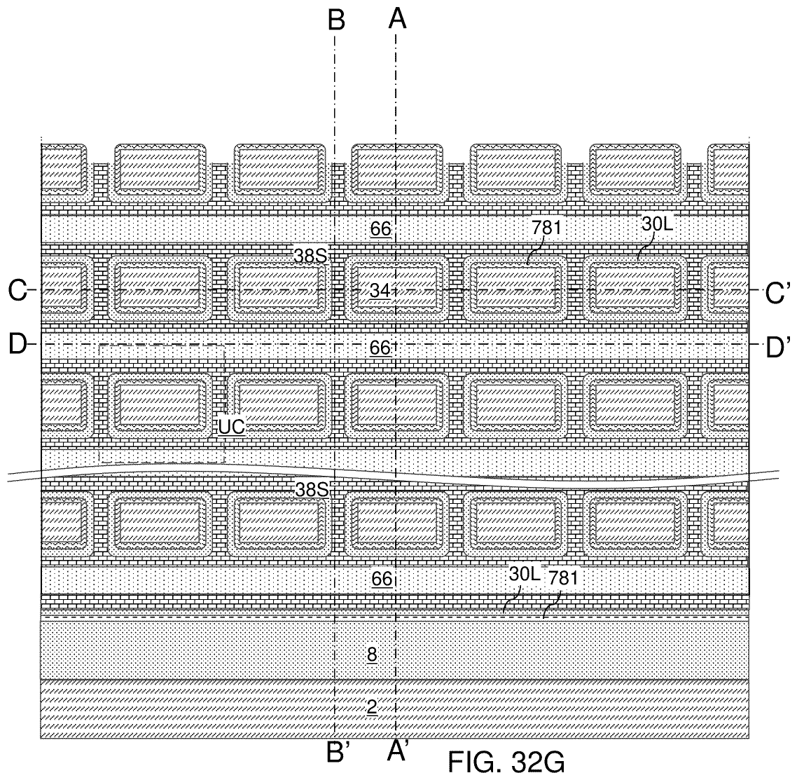

Referring to FIGS. 32A, 32B, 32C, 32D, 32E, 32F, and 32G, a selective isotropic etch process can be performed to isotropically recess physically exposed portions of the second dielectric plates 66 from around the laterally-extending voids 49′ within the source trenches 49. The etch-stop layer 781 may function as an etch-stop during the selective isotropic etch process to protect the beams 34 from being etched. Optionally, the second gate electrode material layer 38S and/or the second gate dielectric material layers 30L may be collaterally recessed during the selective isotropic etch process. In an illustrative example, the second dielectric plates 66 may comprise a silicon oxide, and the selective isotropic etch process may comprise a wet etch process employing dilute hydrofluoric acid. Physically exposed vertical end surfaces of the second dielectric plates 66 may be laterally recessed relative to a vertical plane including vertical surfaces of the etch-stop layer 781 that are exposed to the laterally-extending voids 49′ by a lateral offset distance in a range from 5 nm to 100 nm, such as from 10 nm to 40 nm, although lesser and greater lateral offset distances may also be employed. Physically exposed surfaces of the second gate electrode material layer 38S may also be laterally recessed relative to the vertical plane including vertical surfaces of the etch-stop layer 781 that are exposed to the laterally-extending voids 49′ by a lateral offset distance in a range from 5 nm to 100 nm, such as from 10 nm to 40 nm, although lesser and greater lateral offset distances may also be employed.

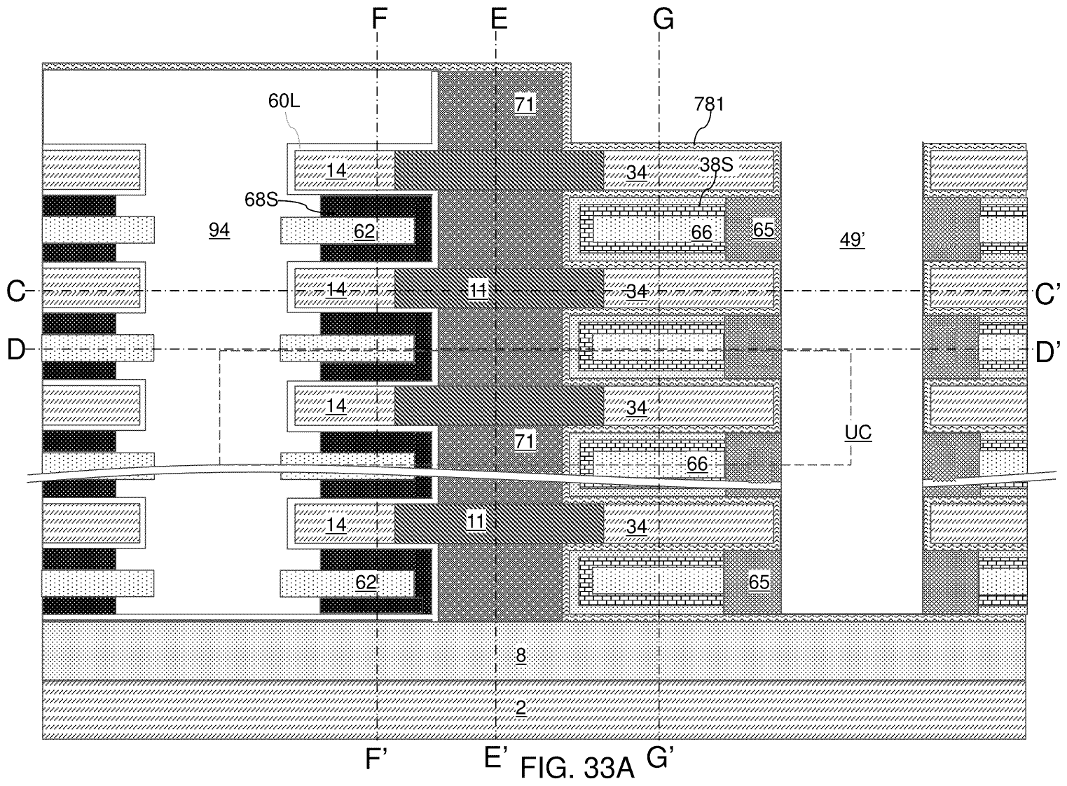

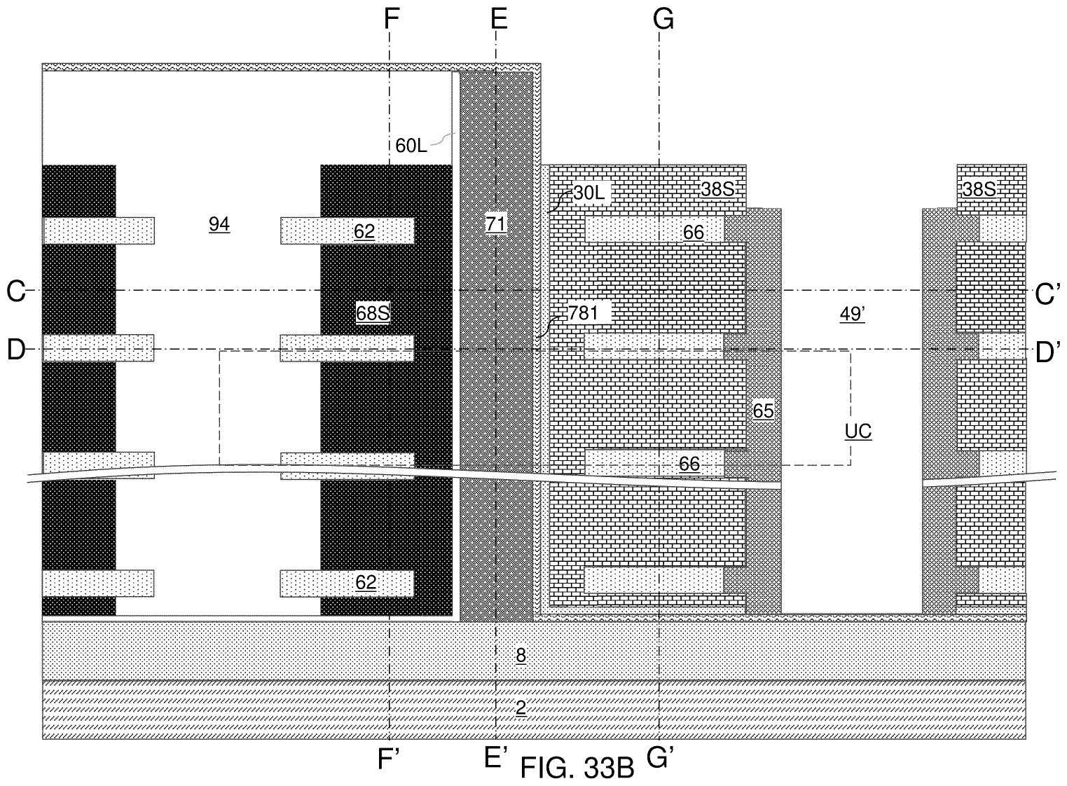

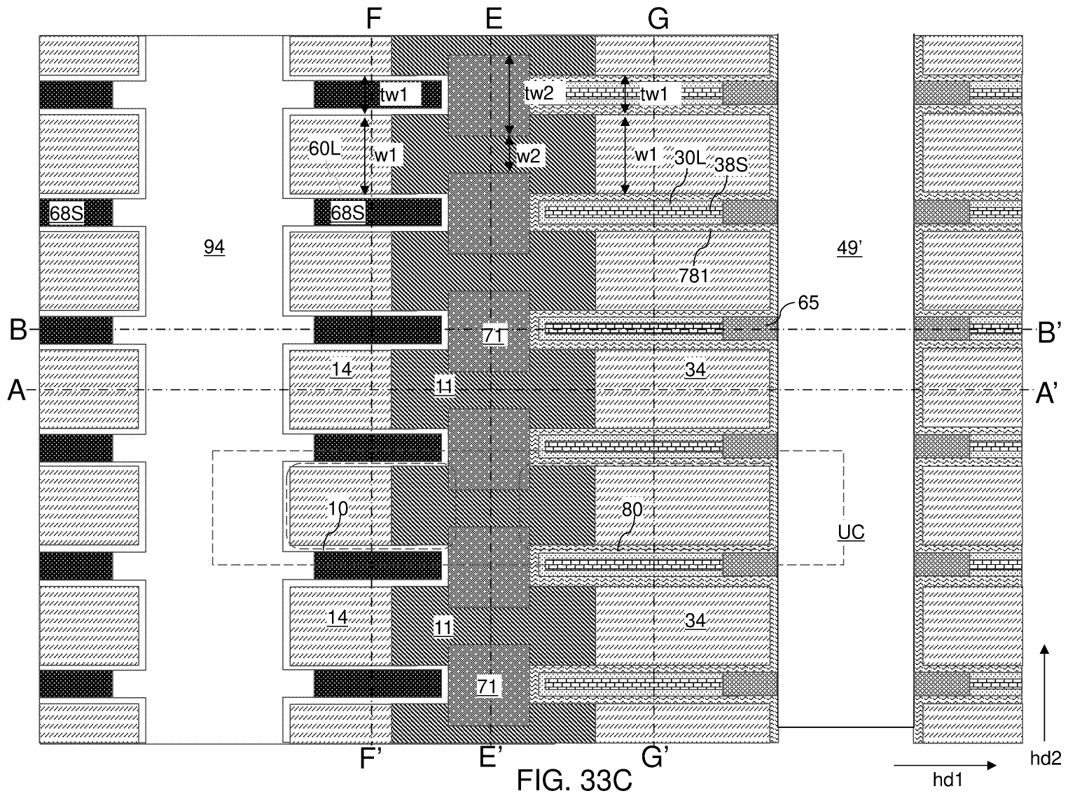

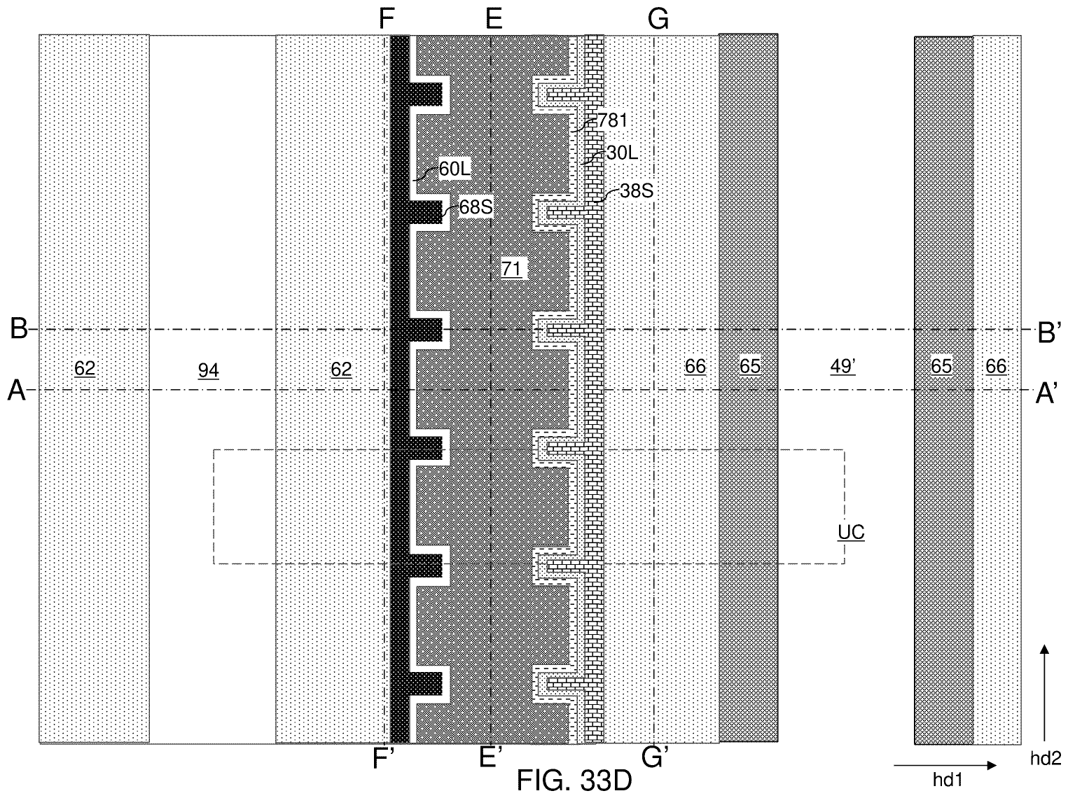

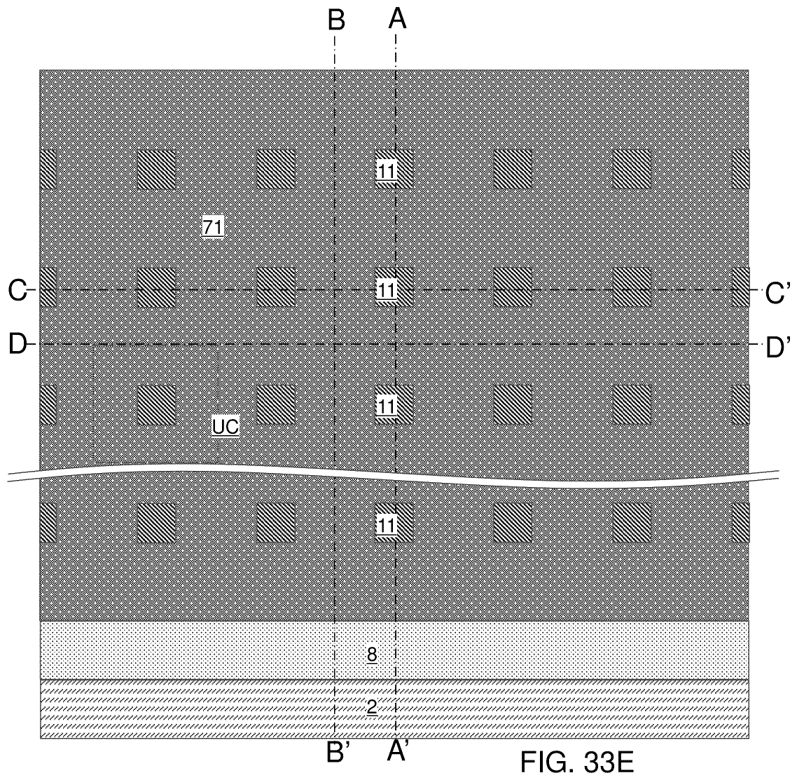

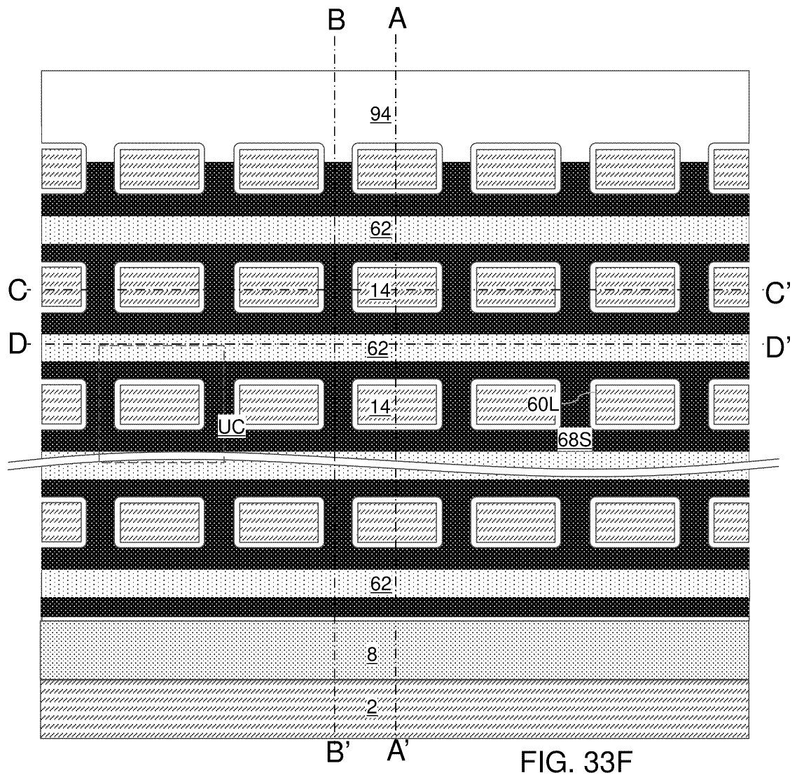

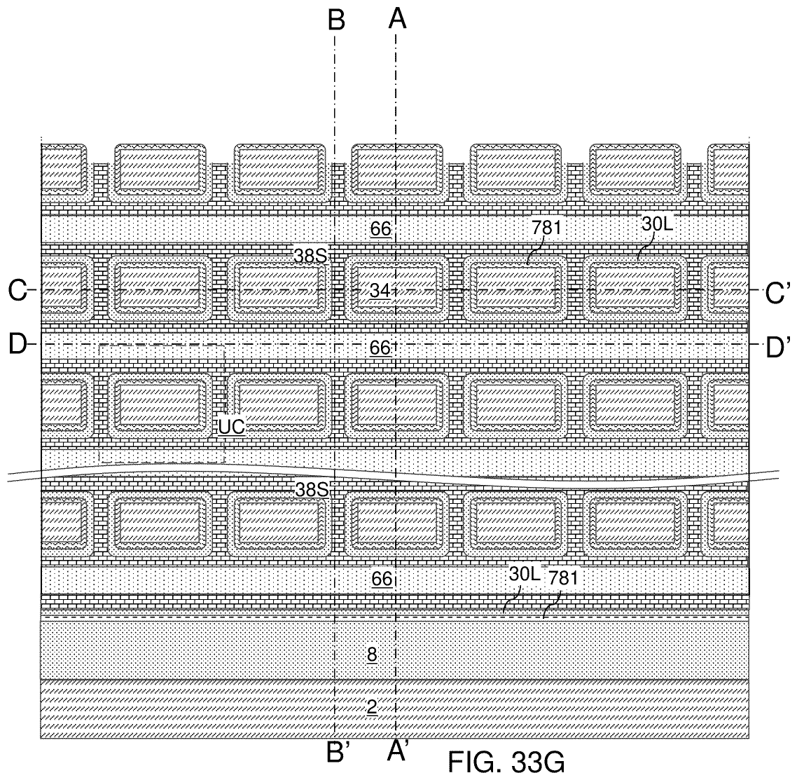

Referring to FIGS. 33A, 33B, 33C, 33D, 33E, 33F, and 33G, a dielectric passivation material, such as silicon nitride, silicon carbonitride, or a dielectric metal oxide may be conformally deposited within the gaps between neighboring portions of the etch-stop layer 781. For example, a low pressure chemical vapor deposition may be employed to conformally deposit the dielectric passivation material. The thickness of the deposited dielectric passivation material is selected such that all gaps between laterally neighboring pairs of portions of the etch-stop layer 781 are filled with the dielectric passivation material, and all gaps between vertically neighboring pairs of portions of the etch-stop layer 781 are filled with the dielectric passivation material. Subsequently, a recess etch process may be performed to etch back portions of the dielectric passivation material that are located outside the gaps filled by the dielectric passivation material.

Remaining portions of the dielectric passivation material form continuous structures each laterally extending along the second horizontal direction hd2 and along the vertical direction and laterally surrounding a respective two-dimensional M×N array of end portions of the horizontally-extending semiconductor beams 34 (i.e., the second portions of the horizontally-extending semiconductor rails (14, 11, 34)). Each remaining portion of the dielectric passivation material may constitute a perforated passivation wall 65. In one embodiment, each perforated passivation wall 65 may comprise an M×N array of perforations therethrough. In one embodiment, a one-dimensional array of L perforated passivation walls 65 may be formed.

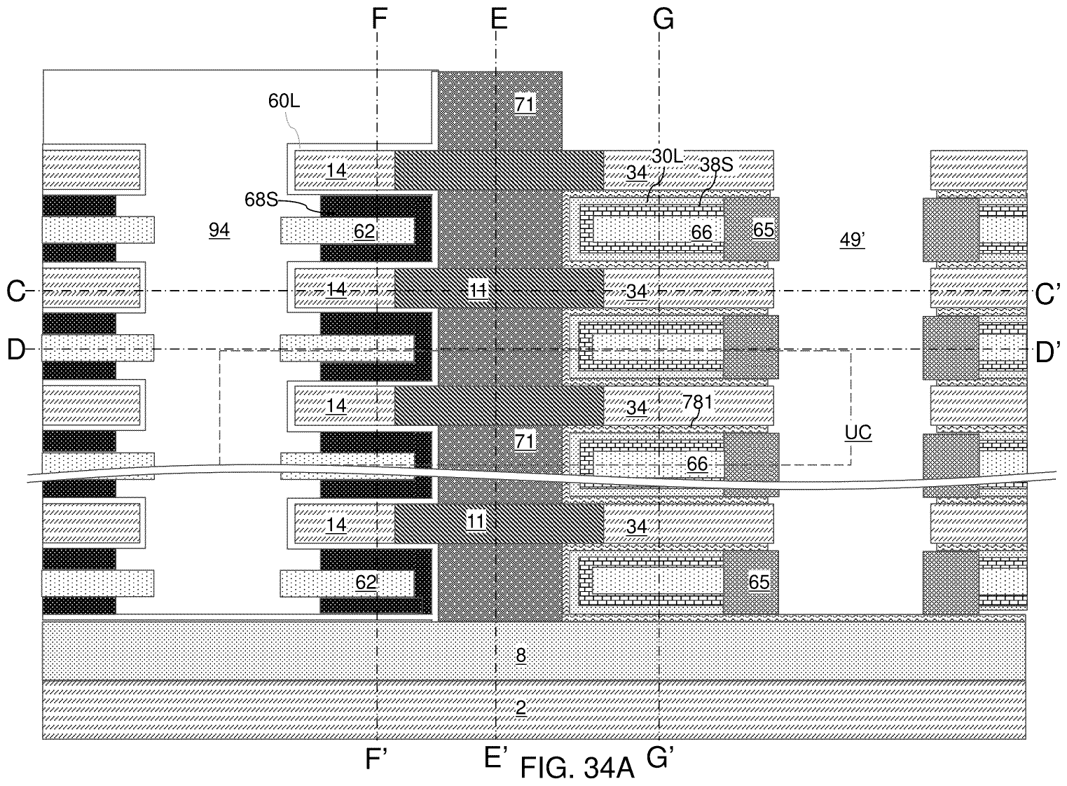

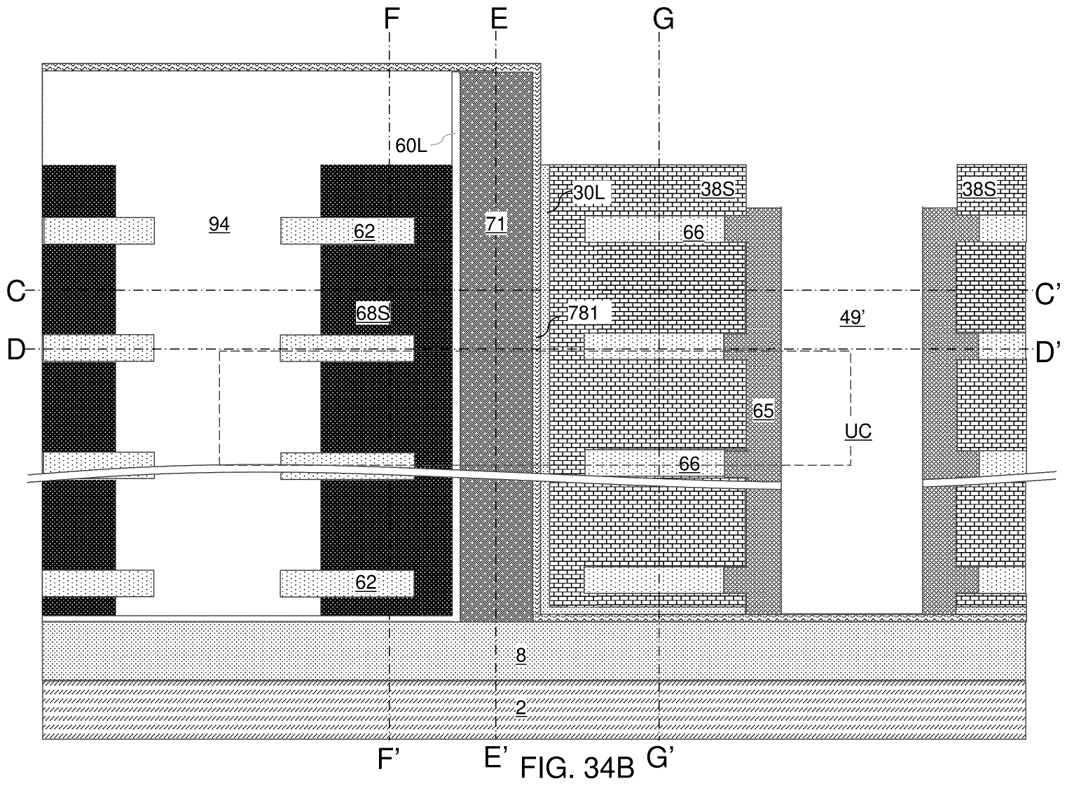

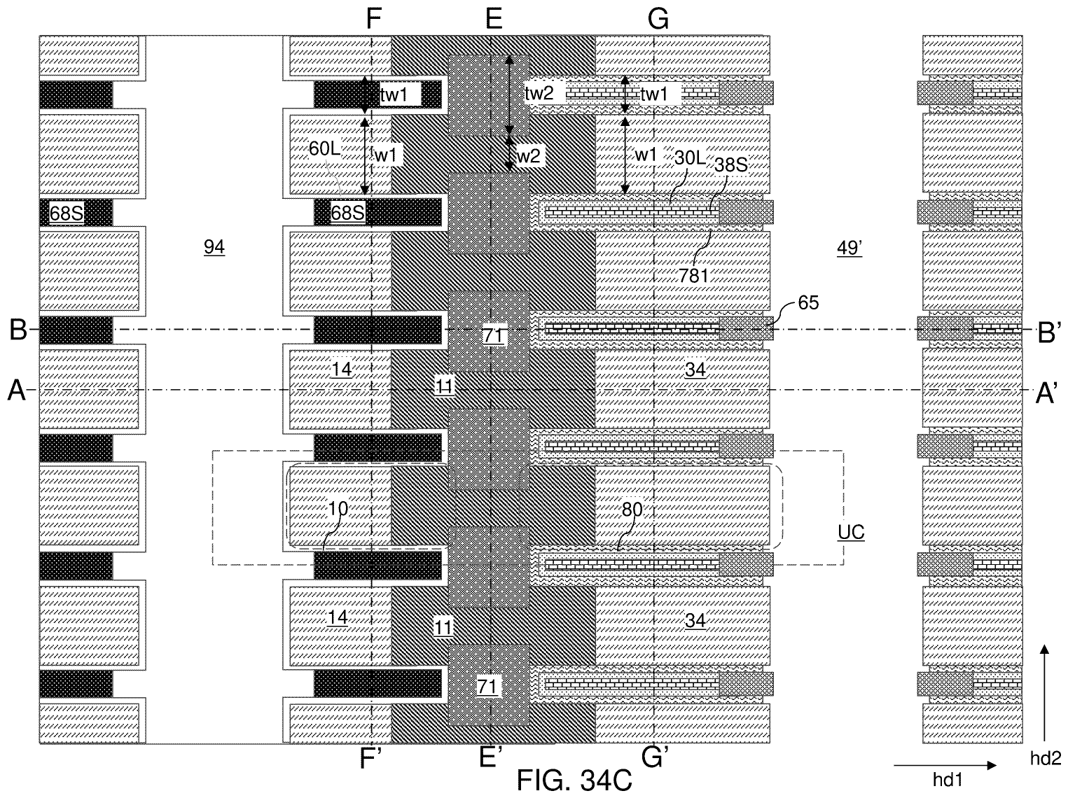

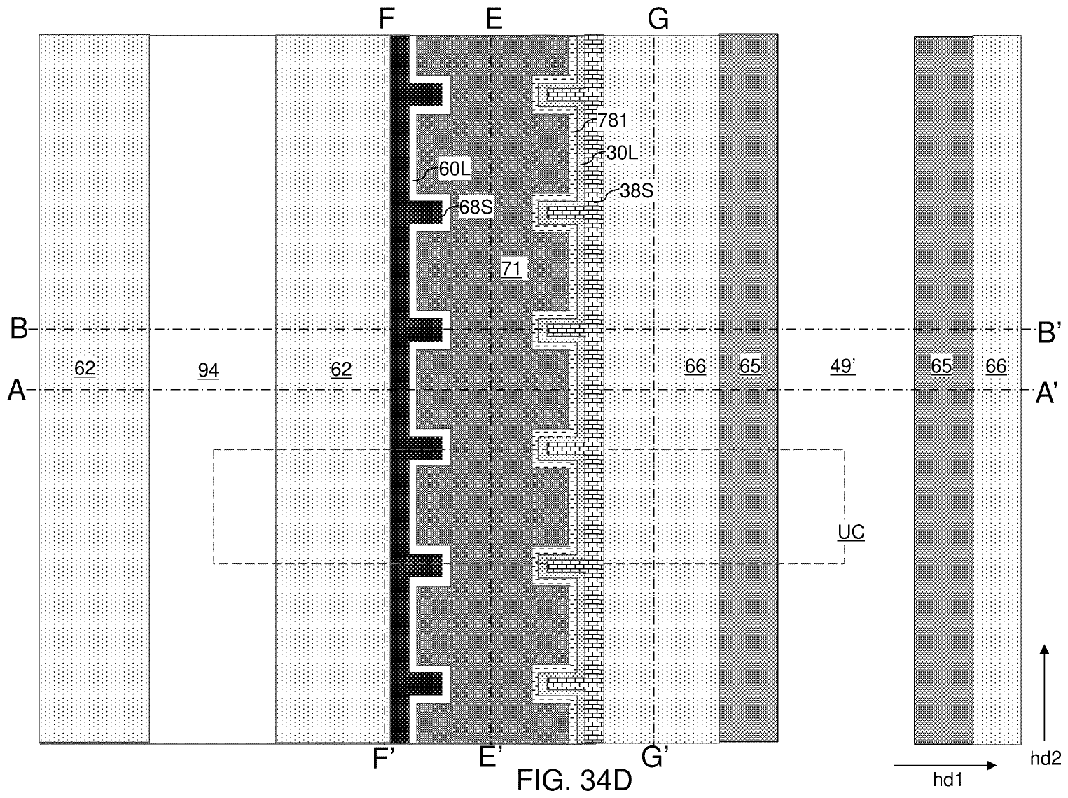

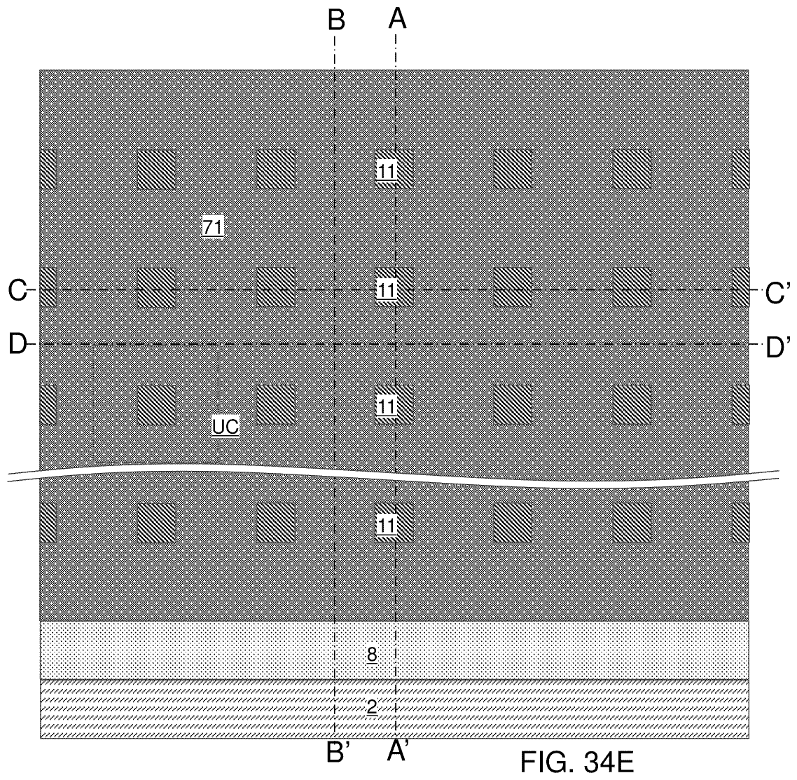

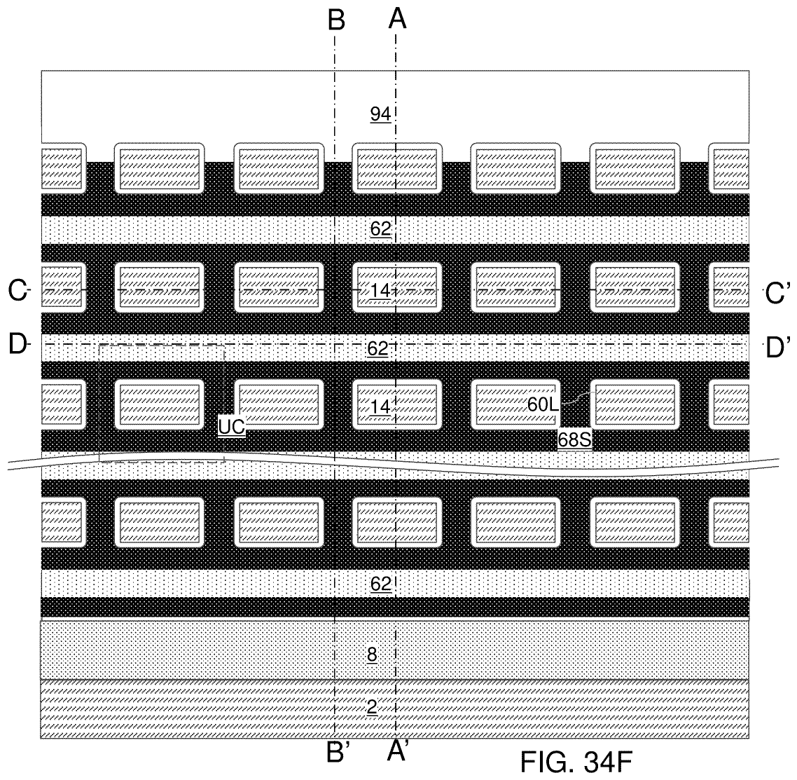

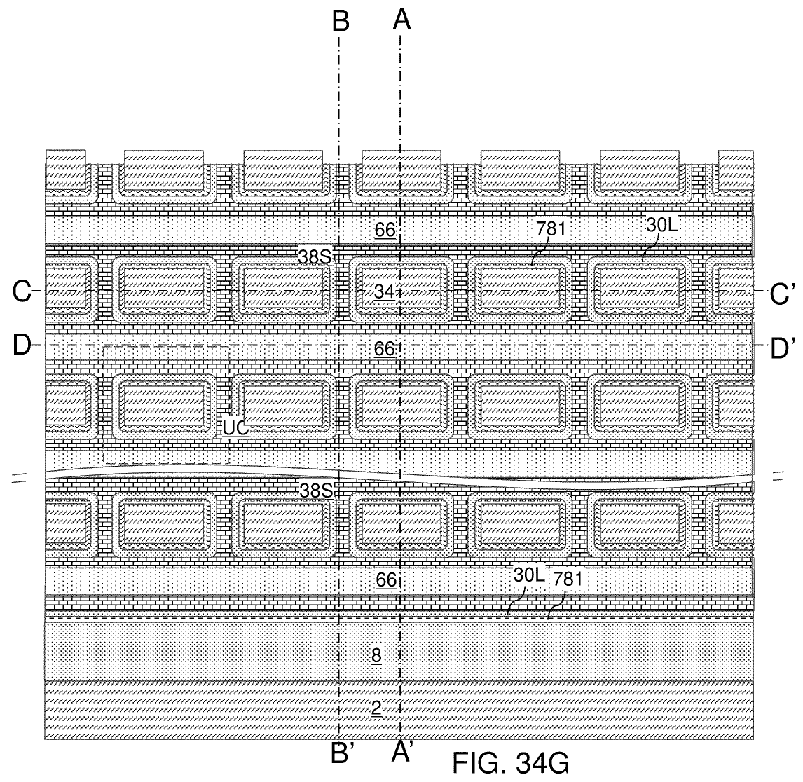

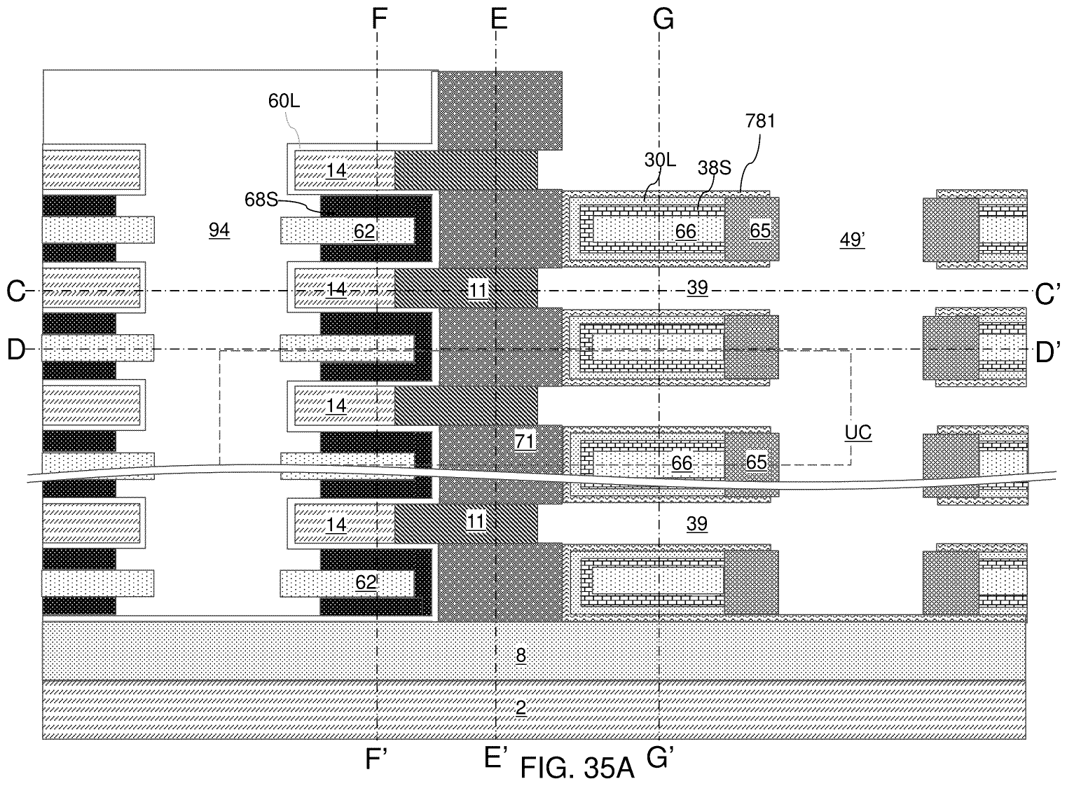

Referring to FIGS. 34A, 34B, 34C, 34D, 34E, 34F, and 34G, physically exposed portions of the etch-stop layer 781 can be etched selectively to the materials of the bit-line trench isolation structures 94, the sacrificial perforated wall structures 71, and the perforated passivation walls 65, and preferably selectively to the materials of the horizontally-extending semiconductor beams 34 and the doped semiconductor material portions 11. Sidewalls of the horizontally-extending semiconductor beams 34 are physically exposed. Optionally, a silicon oxide fill material may be deposited in the voids 49′ and then patterned and etched to reform the voids 49′.

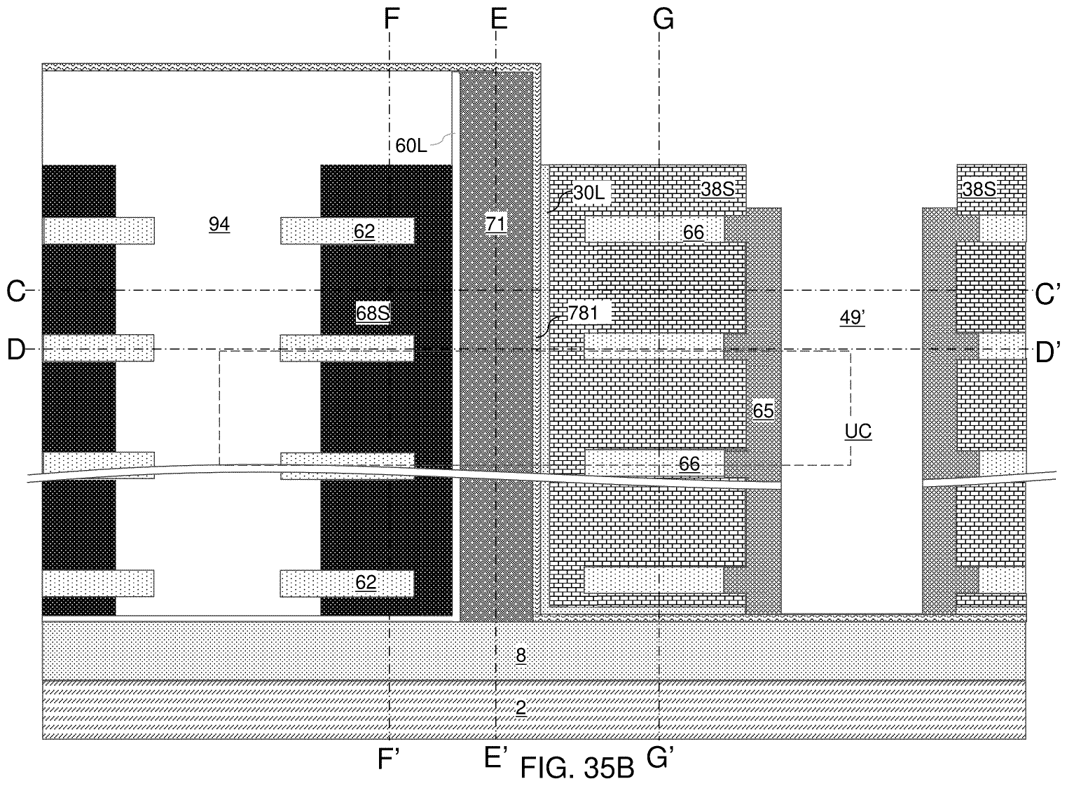

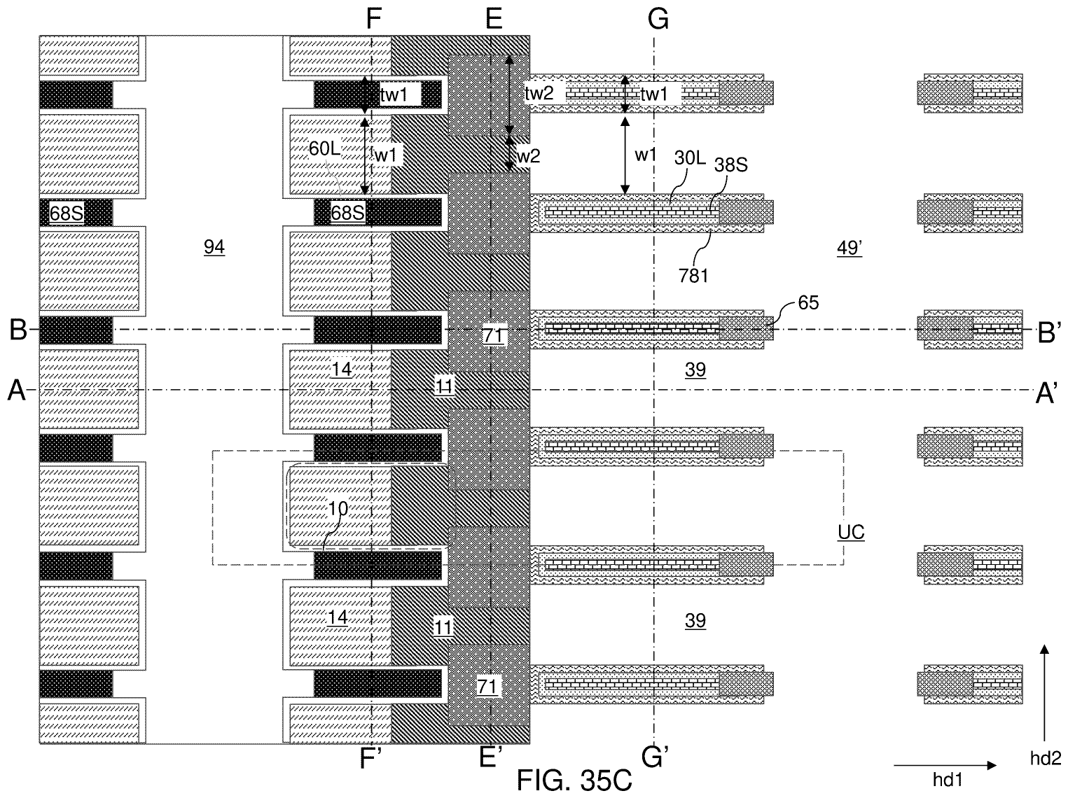

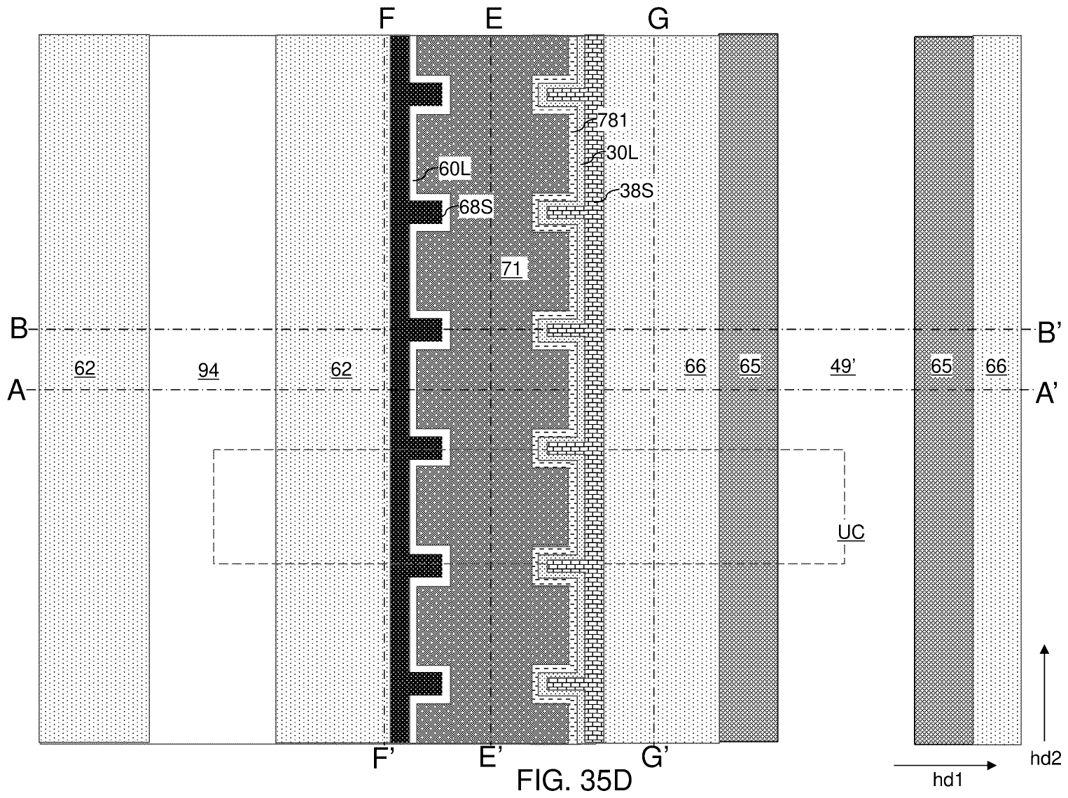

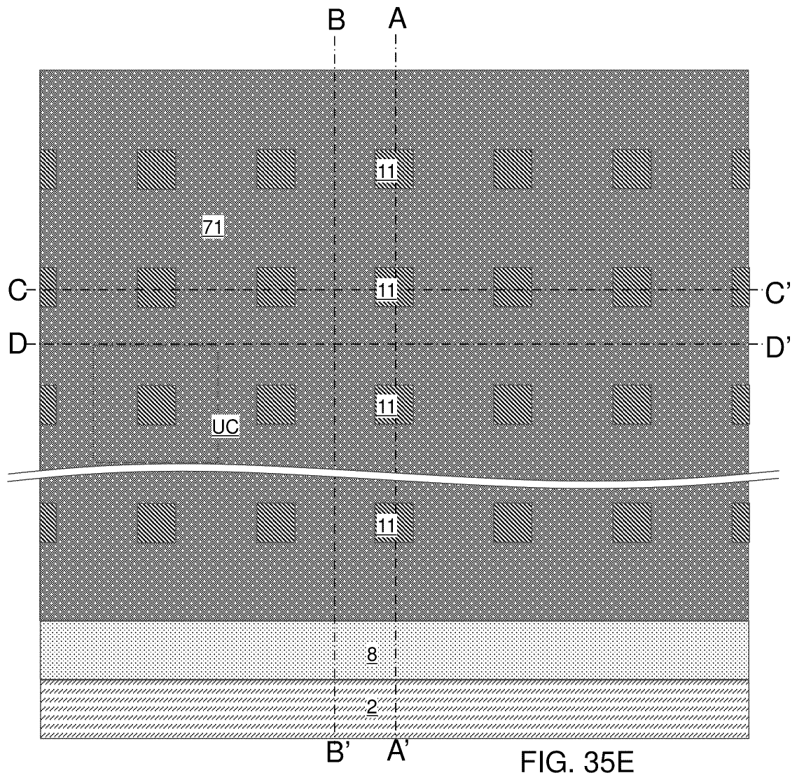

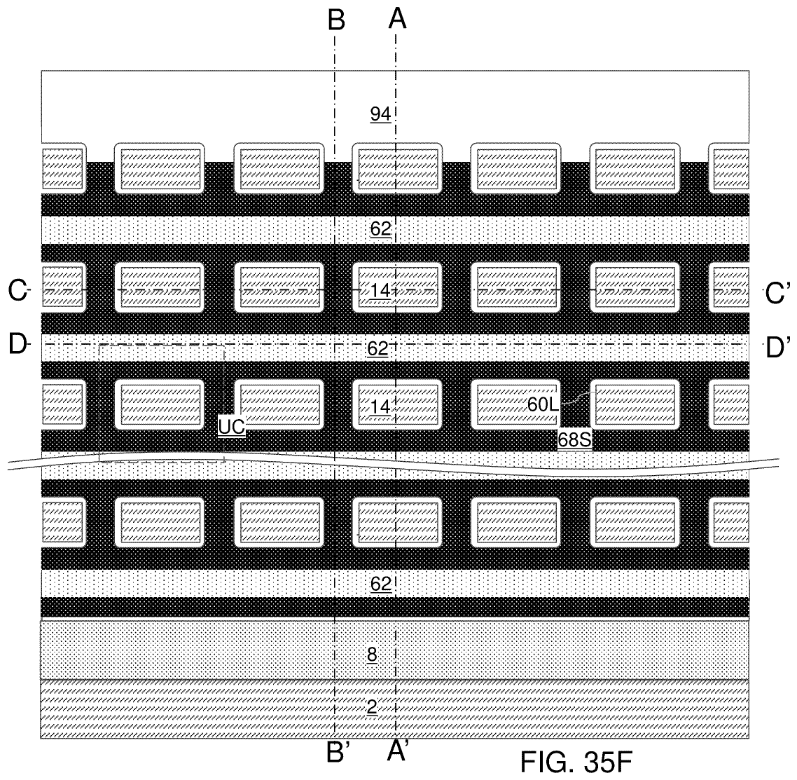

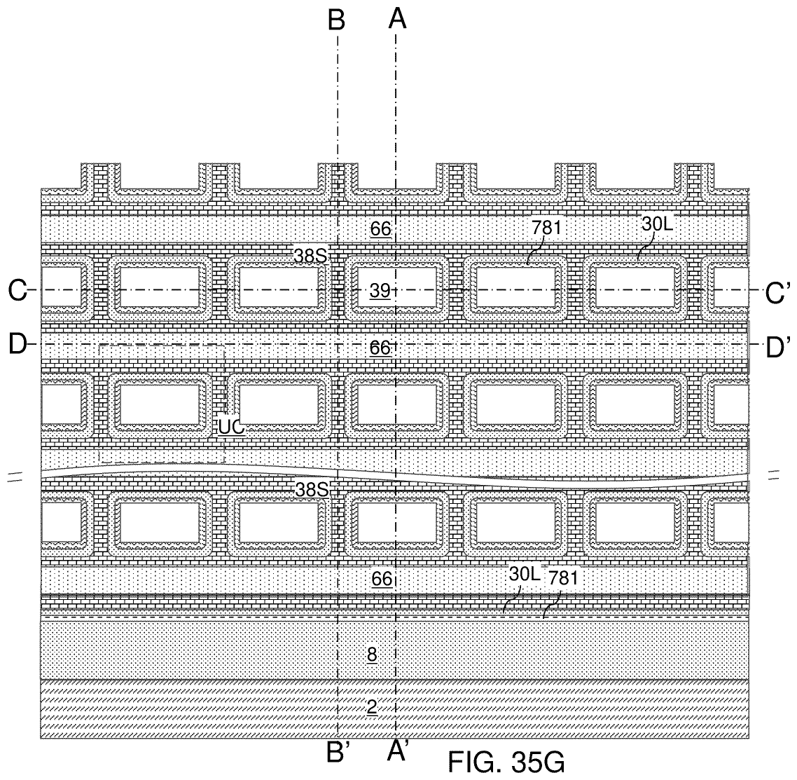

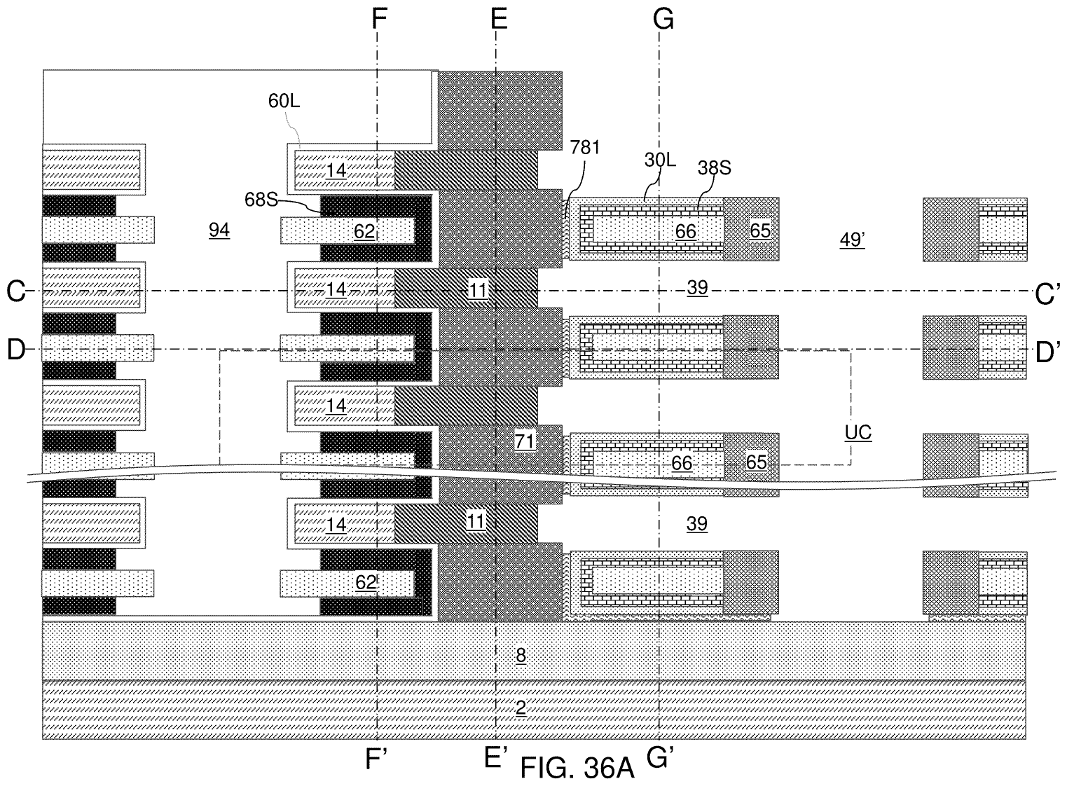

Referring to FIGS. 35A, 35B, 35C, 35D, 35E, 35F, and 35G, a first selective isotropic etch process can be performed to etch the semiconductor materials of the horizontally-extending semiconductor beams 34 selectively to the materials of the etch-stop layers 781, the sacrificial perforated wall structures 71, and the perforated passivation walls 65. In addition, the doped semiconductor material portions 11 may be laterally recessed during a terminal portion of the isotropic etch process. Elongated cavities 39 are formed in the volumes from which the materials of the horizontally-extending semiconductor beams 34 and the doped semiconductor material portions 11 are etched. A three-dimensional array of elongated cavities 39 can be formed. Each elongated cavity 39 may be bounded by sidewalls of a respective doped semiconductor material portion 11, a respective sacrificial perforated wall structure 71, and a respective etch-stop layer 781.

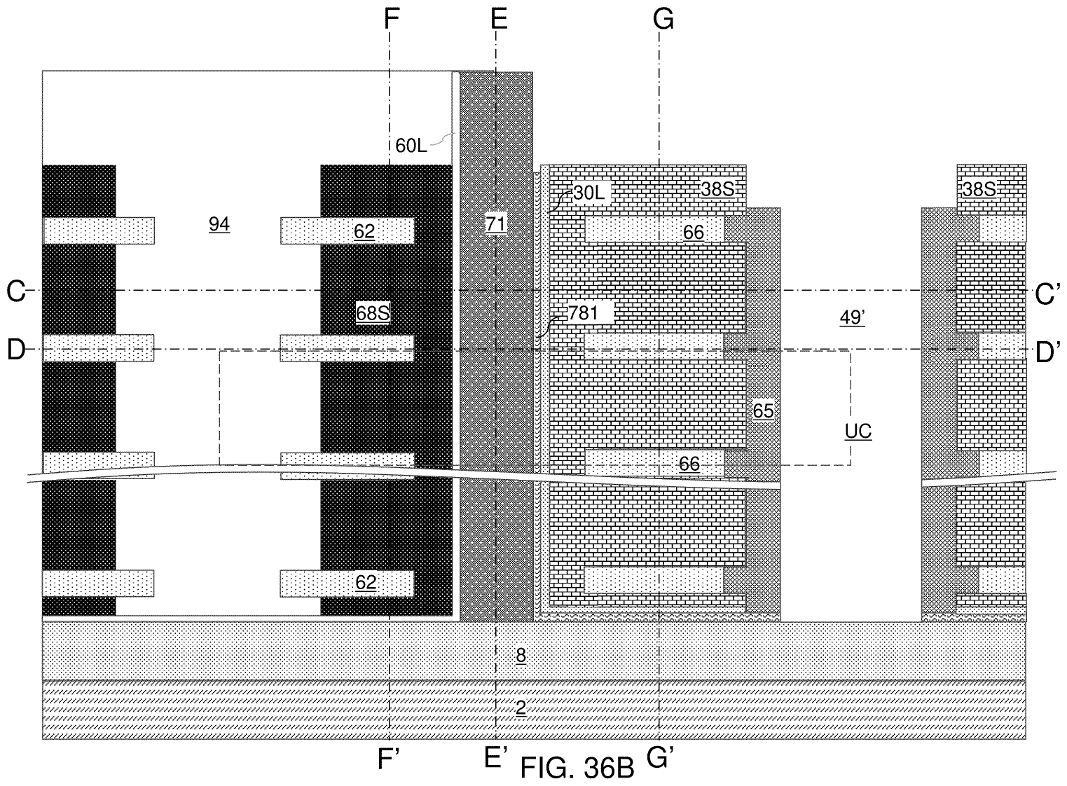

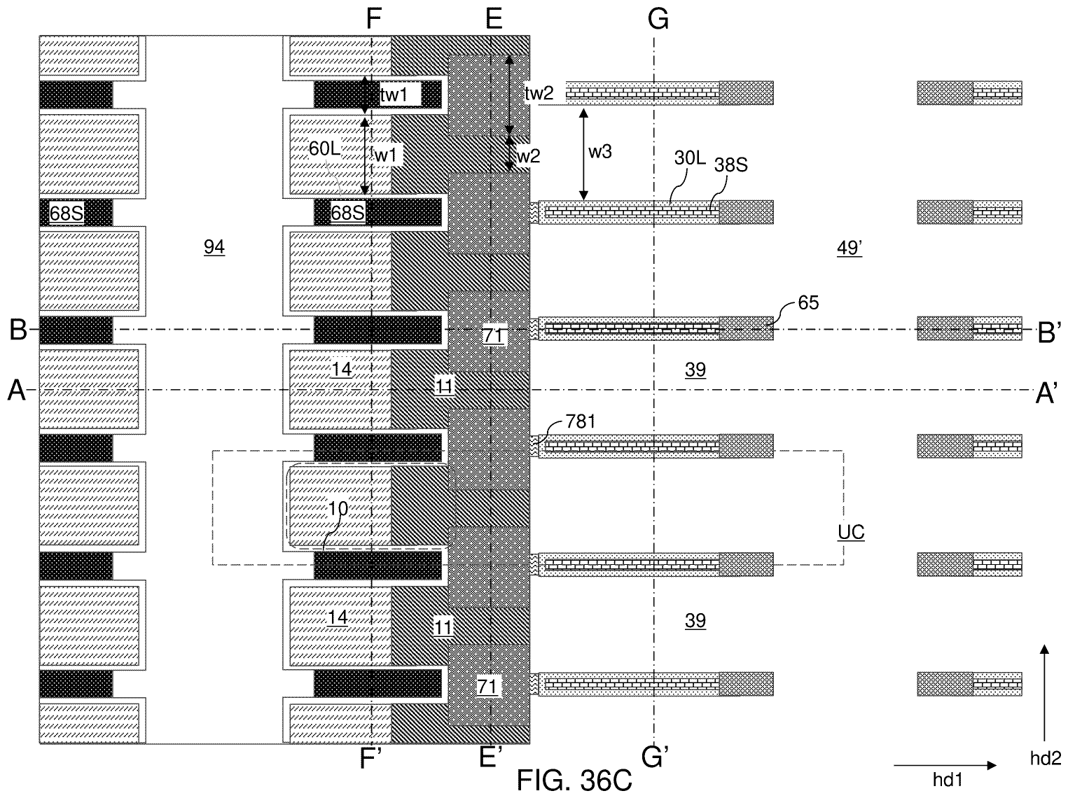

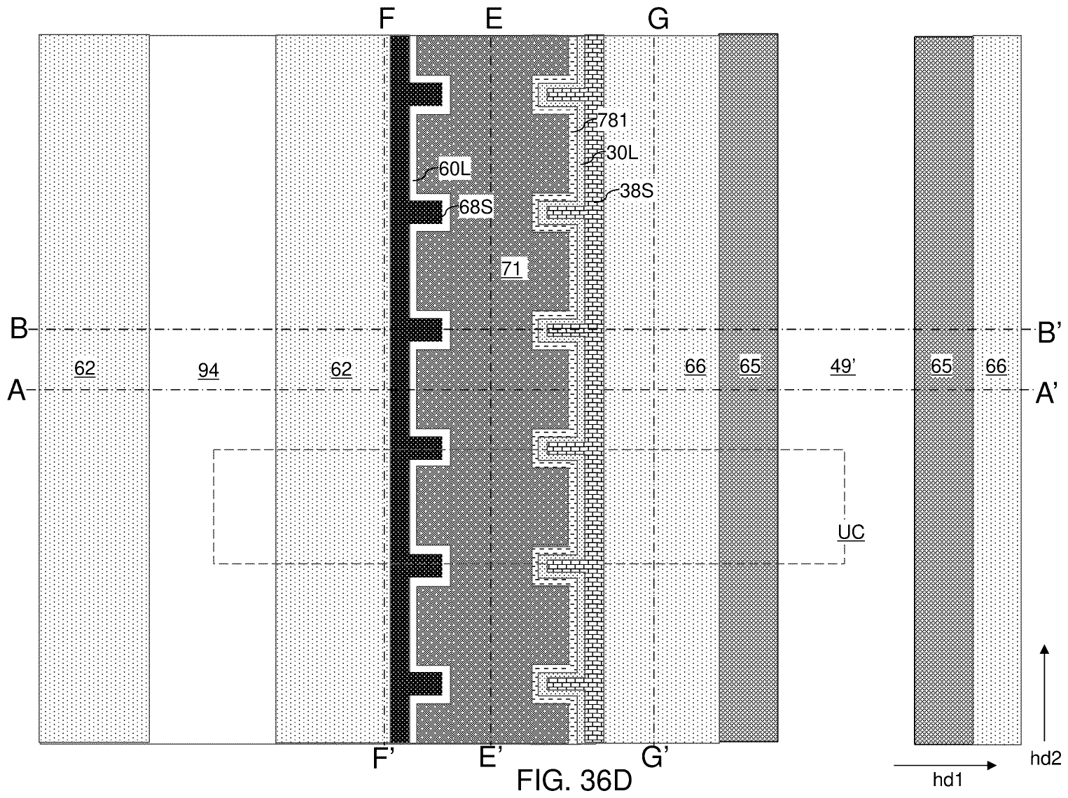

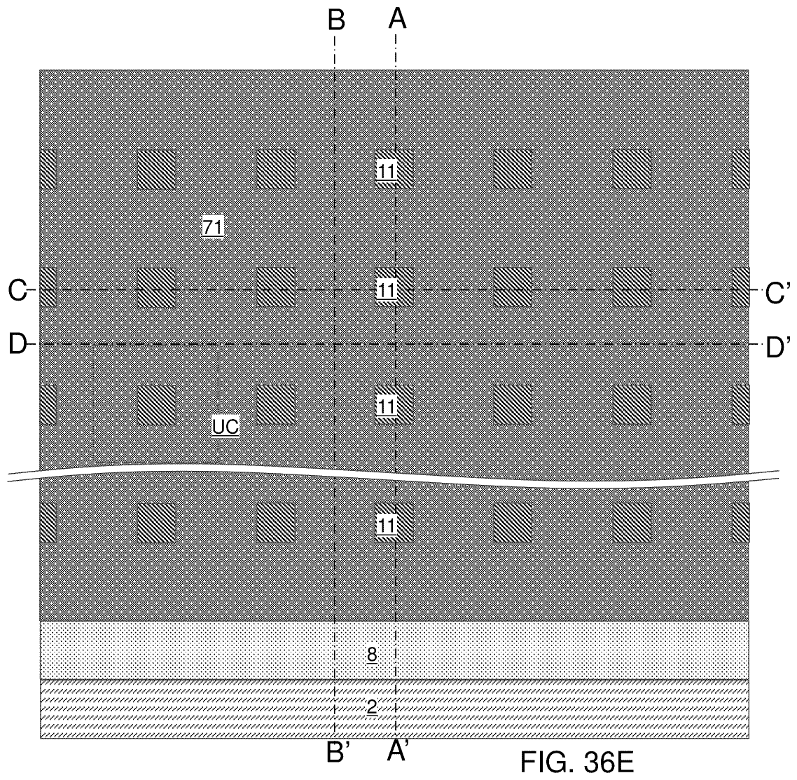

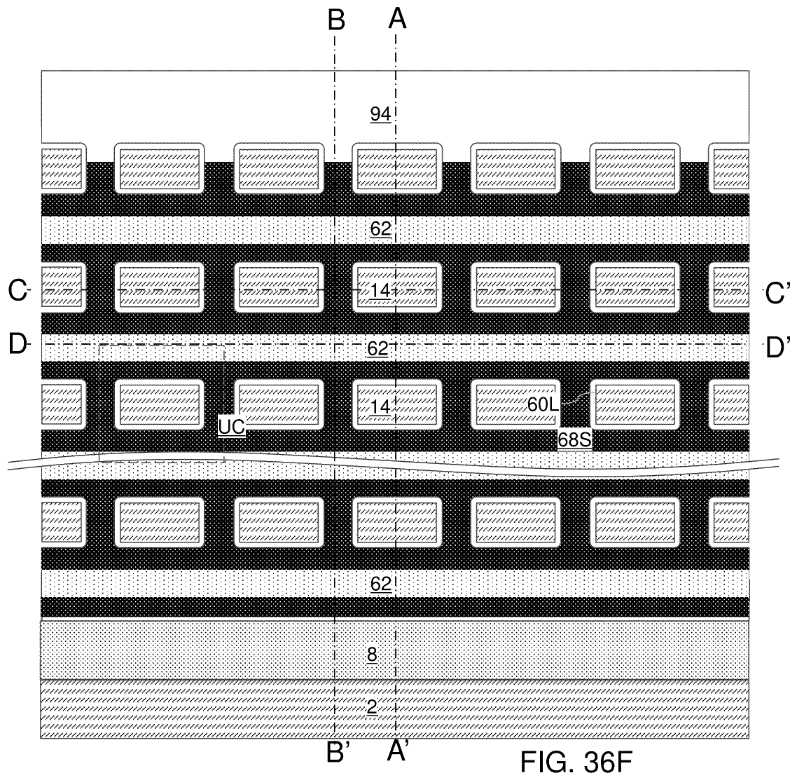

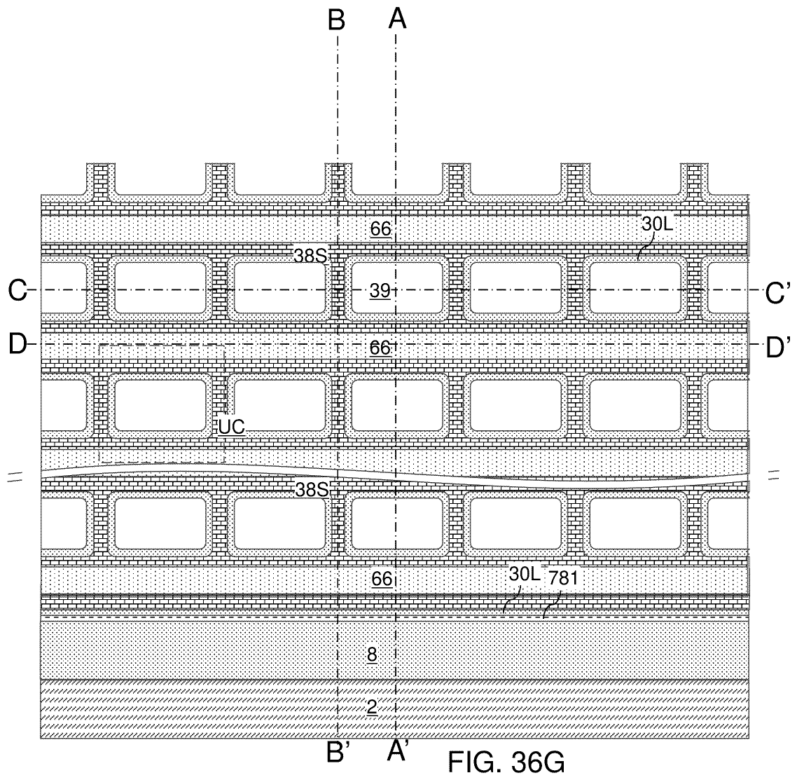

Referring to FIGS. 36A, 36B, 36C, 36D, 36E, 36F, and 36G, a second selective isotropic etch process can be performed to etch physically exposed portions of the etch-stop layer 781 around the elongated cavities 39 selectively to the material of the second gate dielectric material layers 30L, and preferably selectively to the materials of the doped semiconductor material portions 11, the sacrificial perforated wall structures 71, and the perforated passivation walls 65. Remaining portions of the etch-stop layers 781 may comprise perforated sheet structures that are perpendicular to the first horizontal direction and including a respective two-dimensional M×N array of perforations therethrough. Each of the elongated cavities 39 may be laterally enclosed by a respective tubular portion of a second gate dielectric material layer 30L as illustrated in FIG. 36G. The wall-to-wall distance between facing pairs of sidewalls of a second gate dielectric material layer 30L around an elongated cavity 39 along the second horizontal direction hd2 is herein referred to as a third width w3, as shown in FIG. 36C. The third width w3 defines the lateral extent along the second horizontal direction hd2 of each tubular-portion-containing channel to be subsequently formed for a memory field effect transistor.

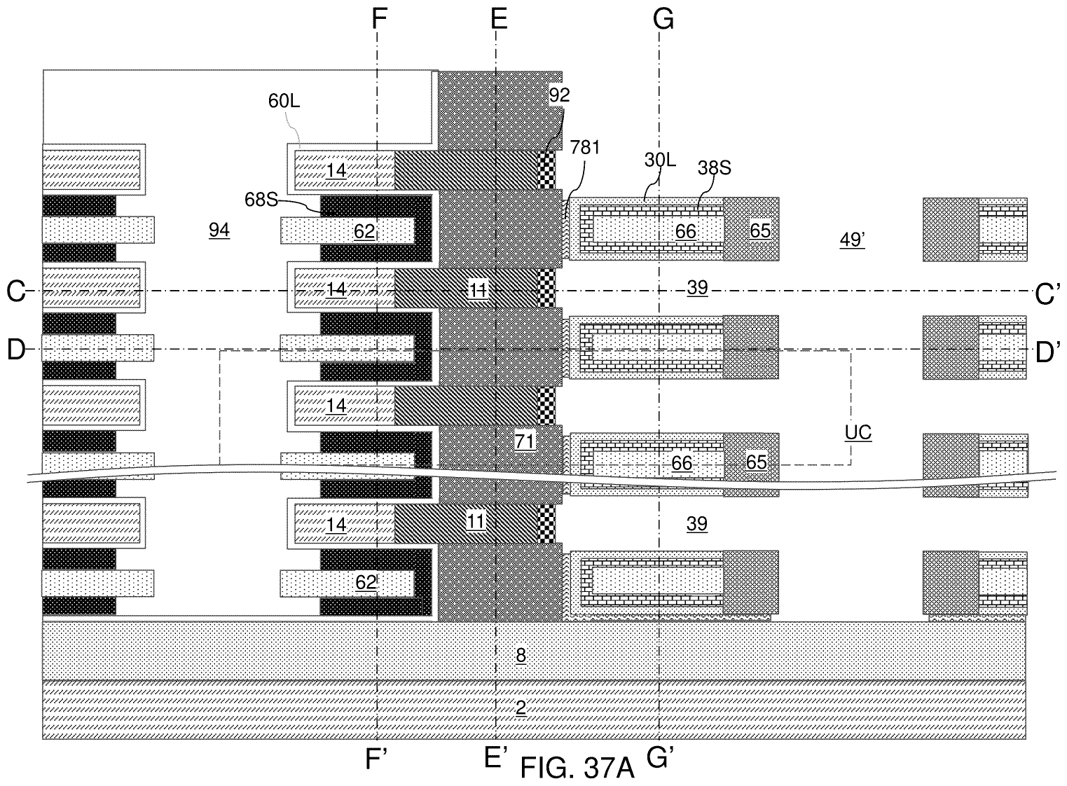

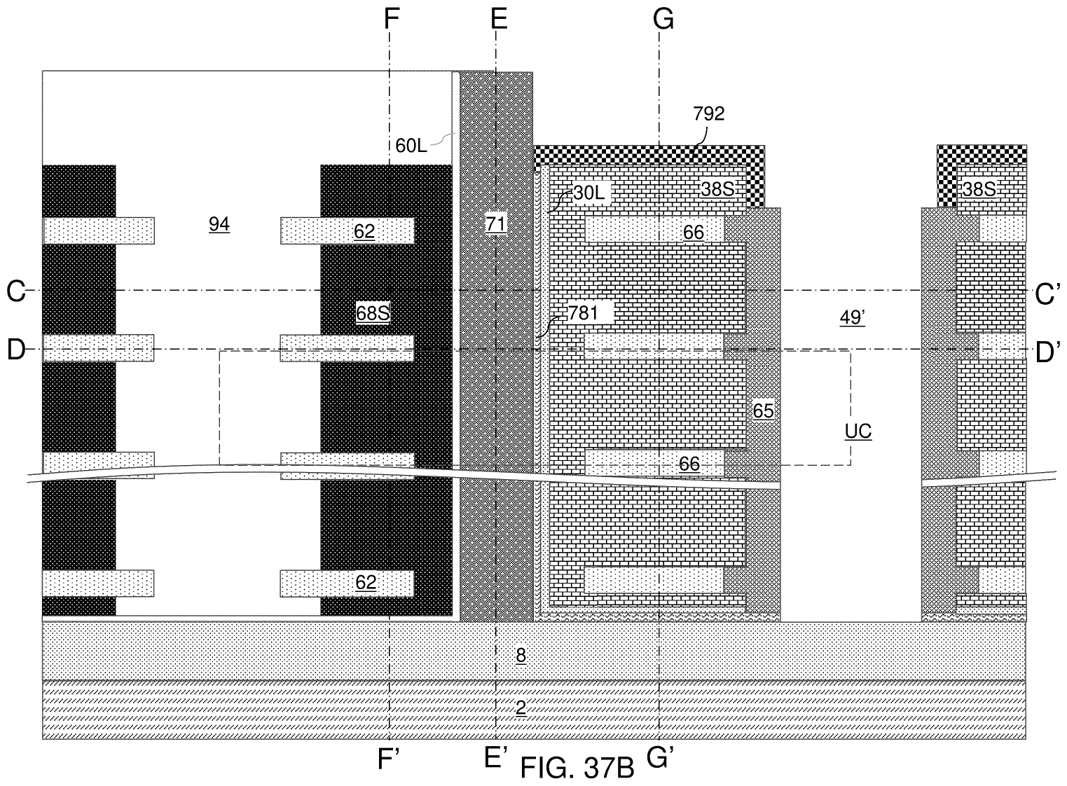

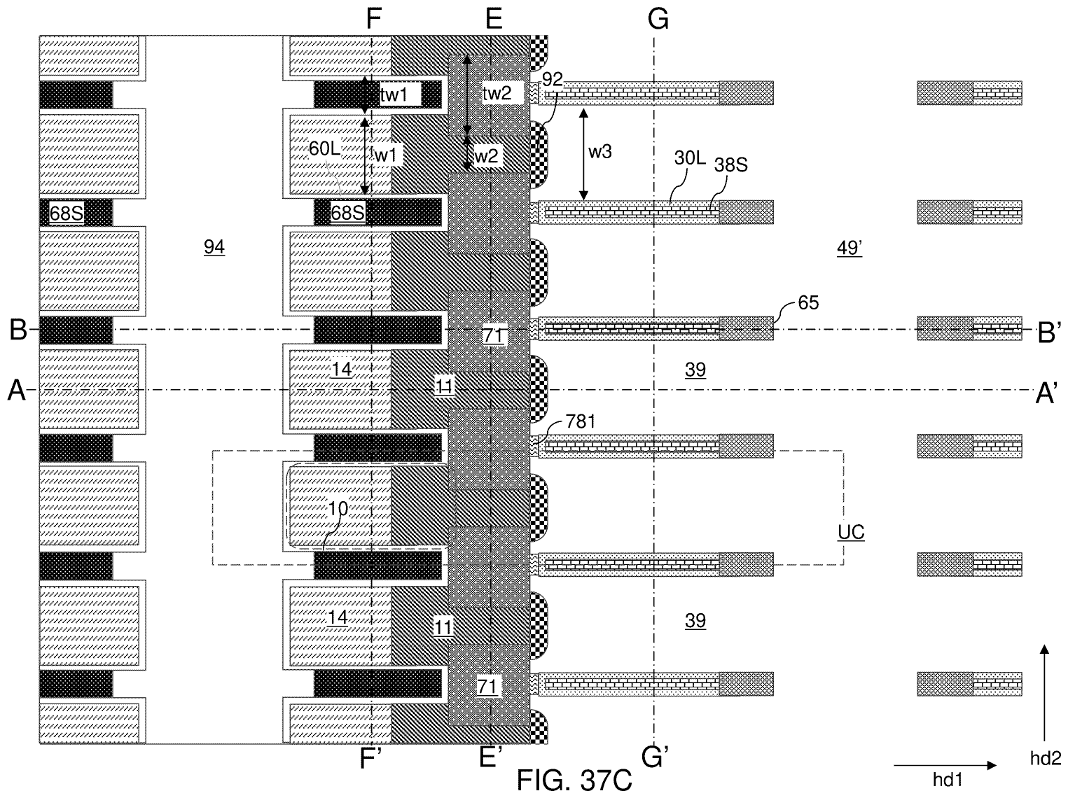

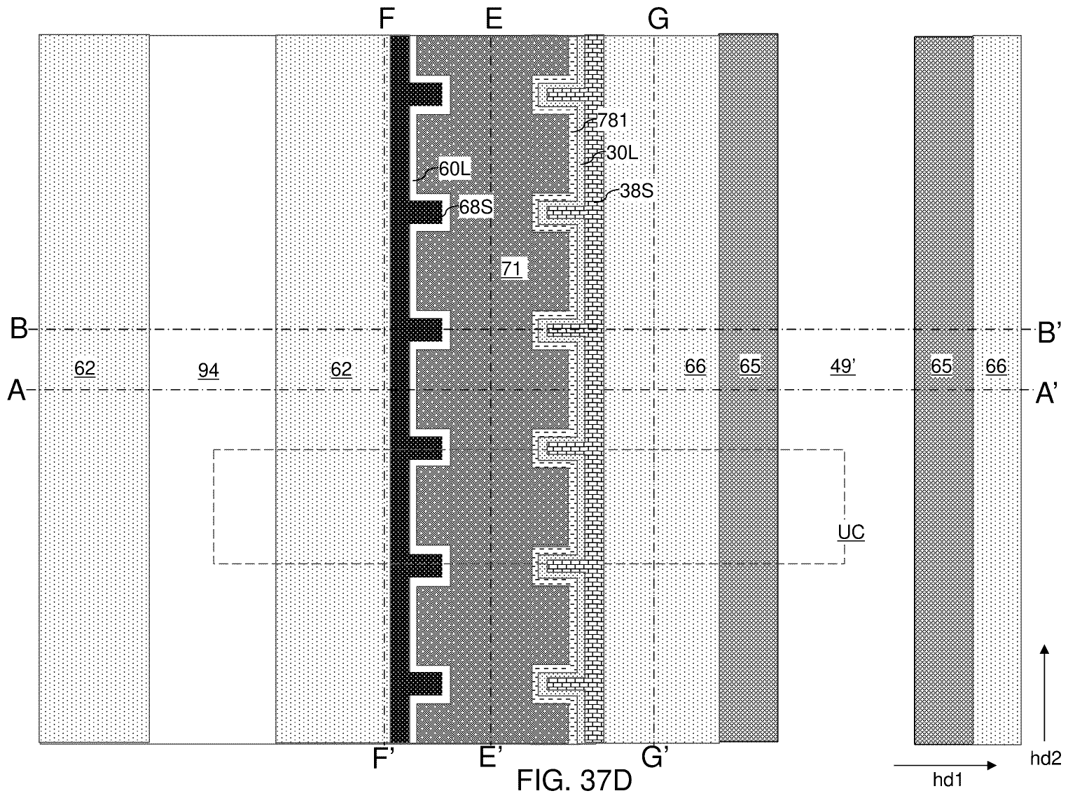

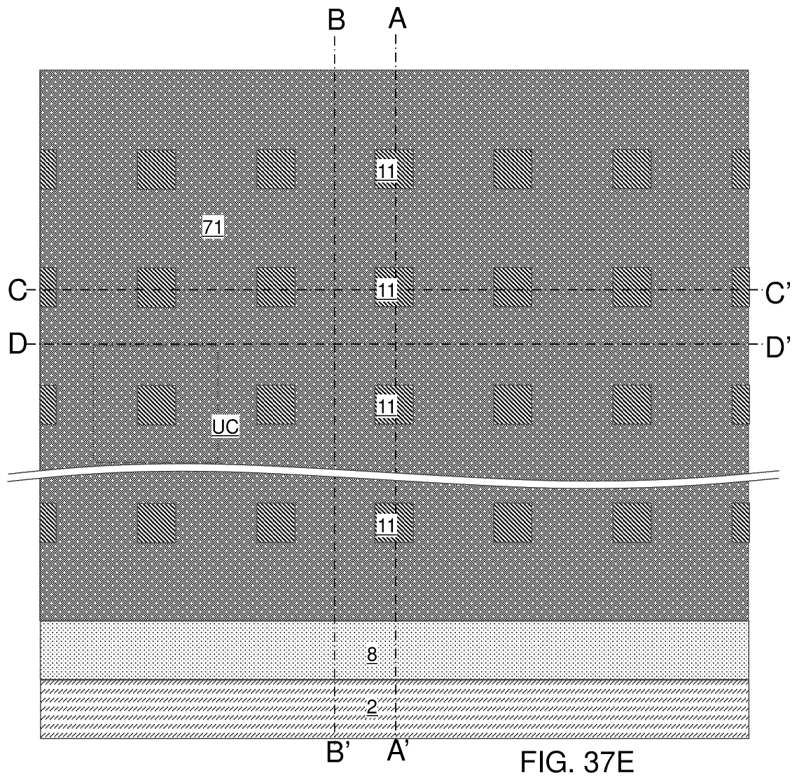

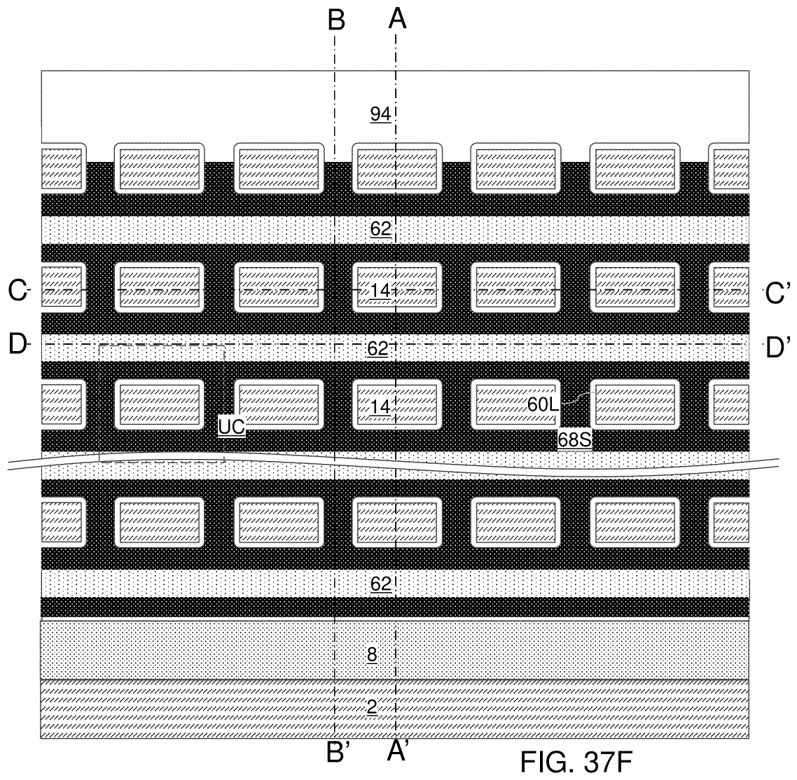

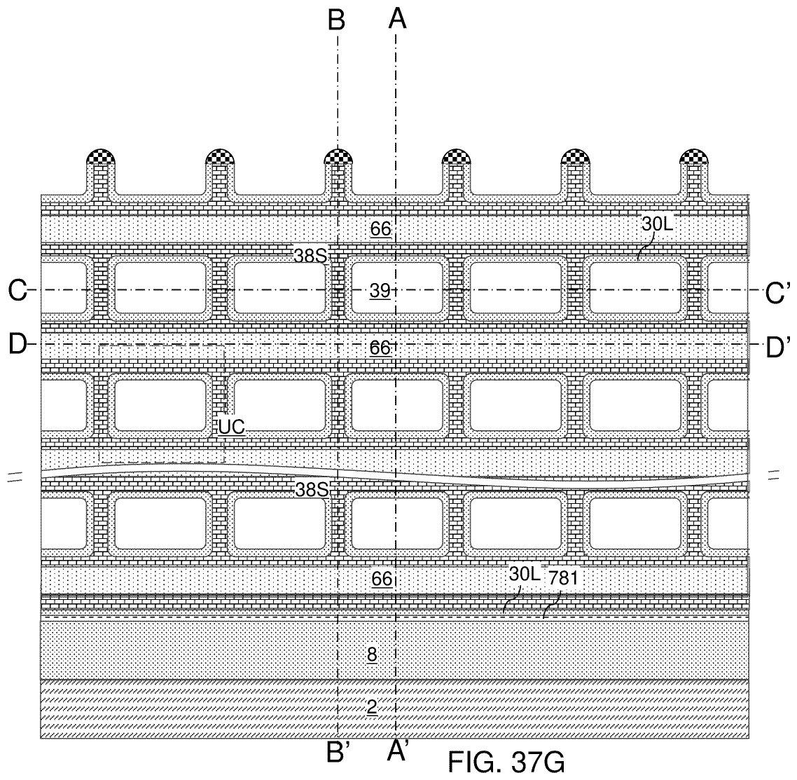

Referring to FIGS. 37A, 37B, 37C, 37D, 37E, 37F, and 37G, metallic material portions 92 may be optionally formed on physically exposed surfaces of the doped semiconductor material portions 11. In one embodiment, the metallic material portions 92 may be deposited by performing a selective metal deposition process that grows a metal from physically exposed semiconductor surfaces (such as the surfaces of the doped semiconductor material portions 11) while suppressing growth of the metal from dielectric surfaces (such as surfaces of the second gate dielectric material layers 30L, the sacrificial perforated wall structures 71, the perforated passivation walls 65, and the bit-line trench isolation structures 94. Generally, a metal precursor gas that induces nucleation on semiconductor surfaces and suppresses nucleation on dielectric surfaces may be employed to effect the selective metal deposition process.

In an illustrative example, such metal precursor gases may include fluorine-containing metal precursor gases such as tungsten hexafluoride (WF₆), tantalum pentafluoride (TaF₅), molybdenum hexafluoride (MoF₆), titanium tetrafluoride (TiF₄), etc. Alternatively, non-fluorine-containing metal precursor gases may also be employed, which include, for example, tetrakis(dimethylamido) titanium (TDMAT), molybdenum hexacarbonyl (Mo(CO)₆), etc. In one embodiment, the metallic material portions 92 may consist essentially of an element metal, such as a refractory metal or a non-reactive metal that acts as diffusion barrier. Alternatively, the metallic material portions 92 may comprise a conductive metallic nitride material such as TiN, TaN, MoN, or WN. Such a conductive metallic nitride material may be selectively deposited by employing an atomic layer deposition process in which a metal-containing precursor gas an ammonia are alternately flowed into a process chamber. In some embodiments, reactivity of ammonia may be enhanced by employing a plasma-enhanced atomic layer deposition process. In some cases, a chemical vapor deposition process at an elevated temperature may be employed in lieu of an atomic layer deposition process. Generally, the process conditions for the selective metal or metal nitride deposition process can be selected to ensure that metallic materials do not nucleated on dielectric surfaces such as surfaces of the second gate dielectric material layers 30L. The thickness of the metallic material portions 92 may be in a range from 1 nm to 30 nm, such as from 3 nm to 10 nm, although lesser and greater thicknesses may also be employed.

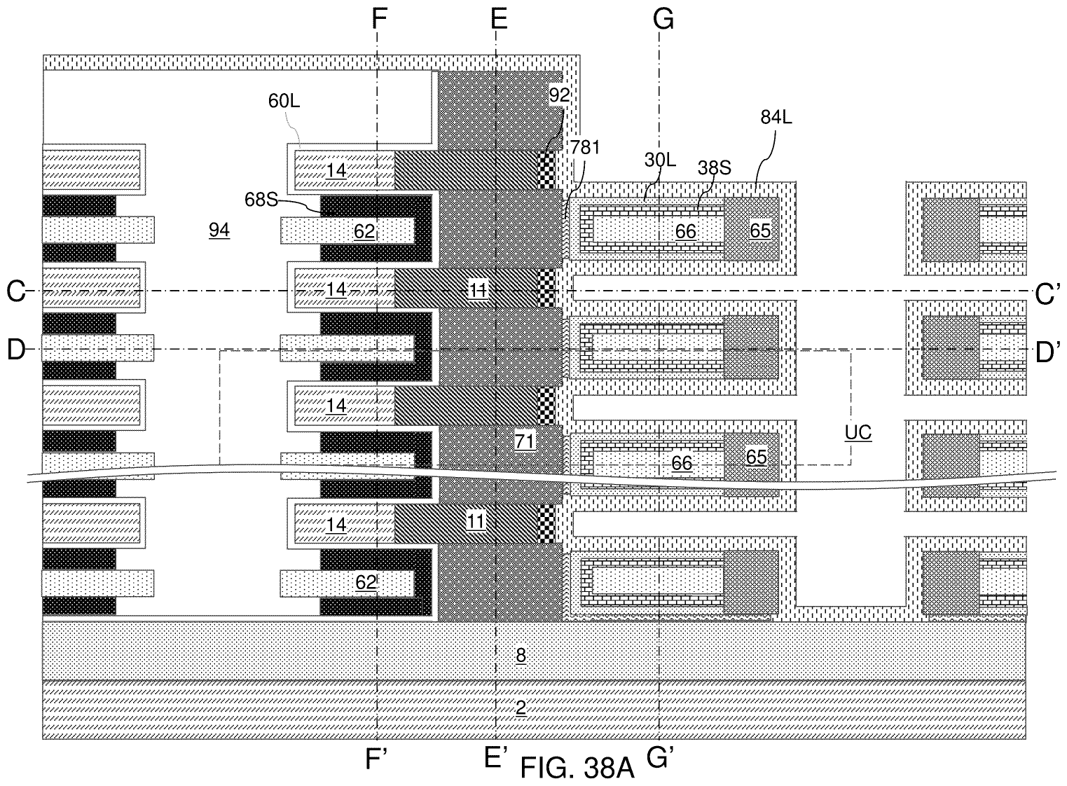

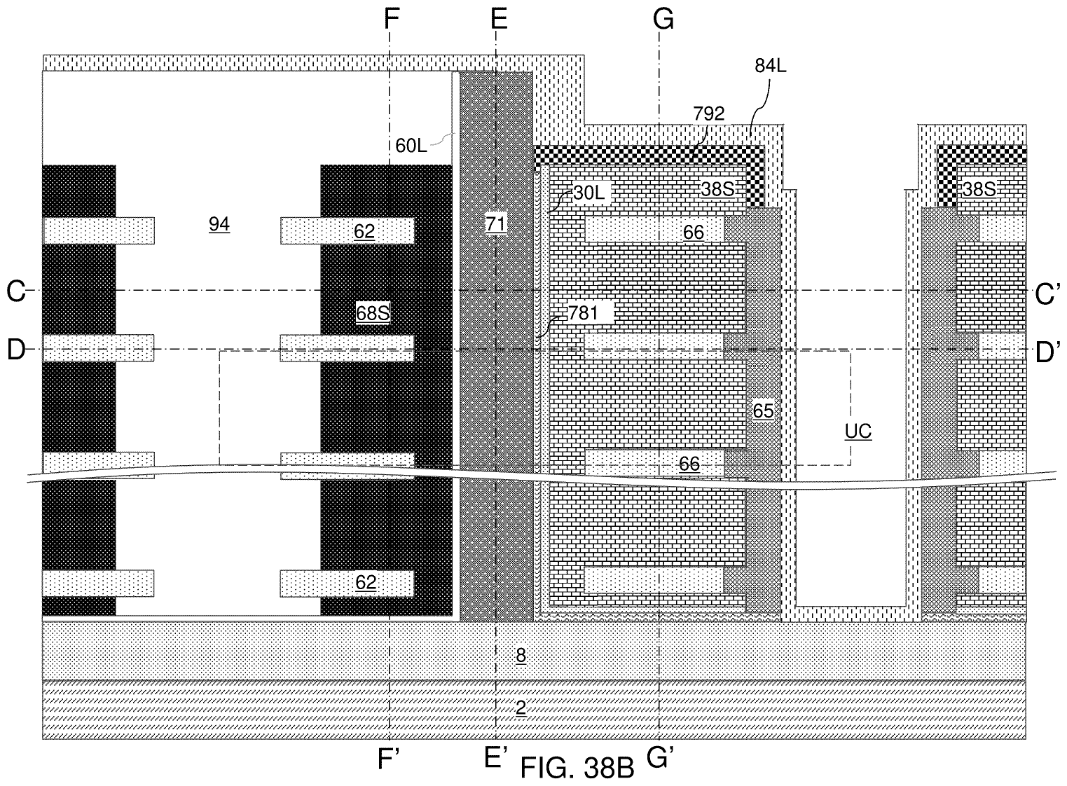

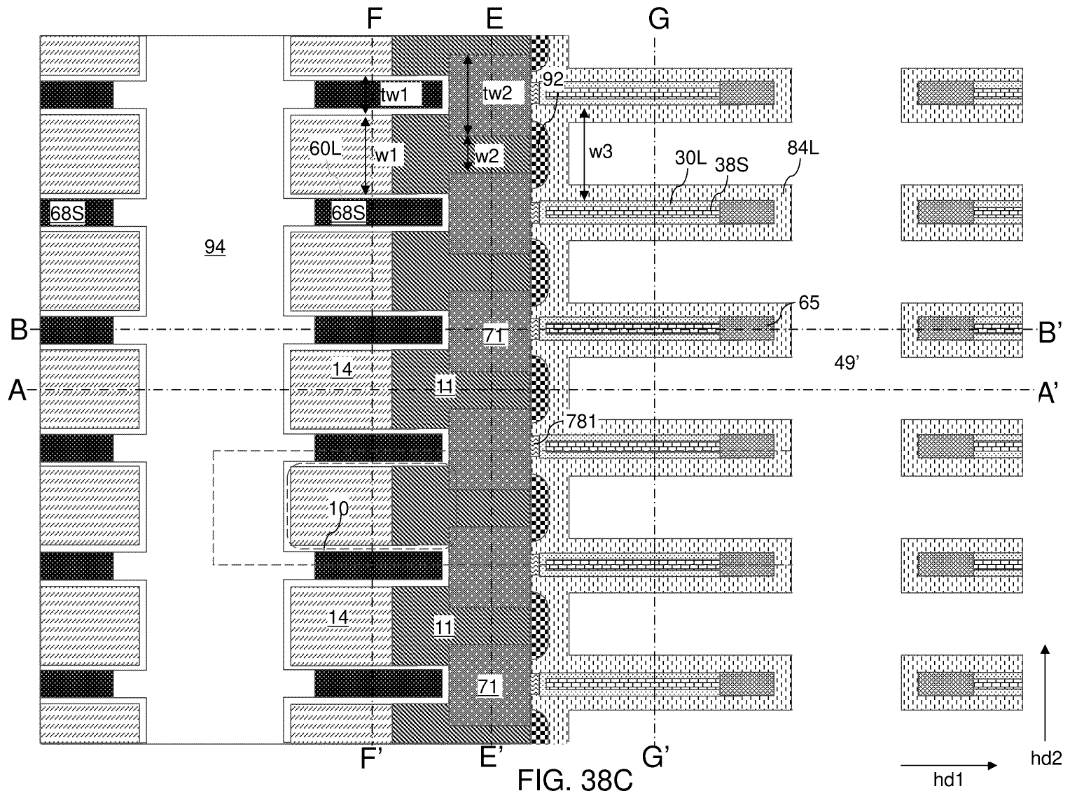

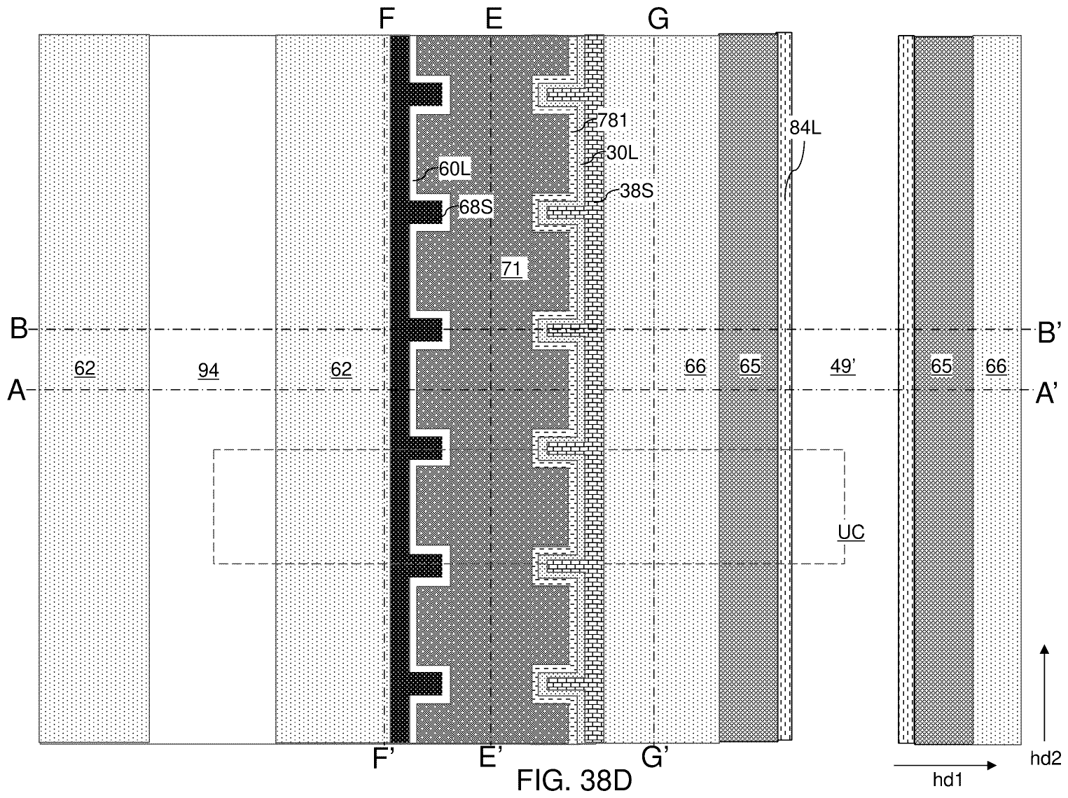

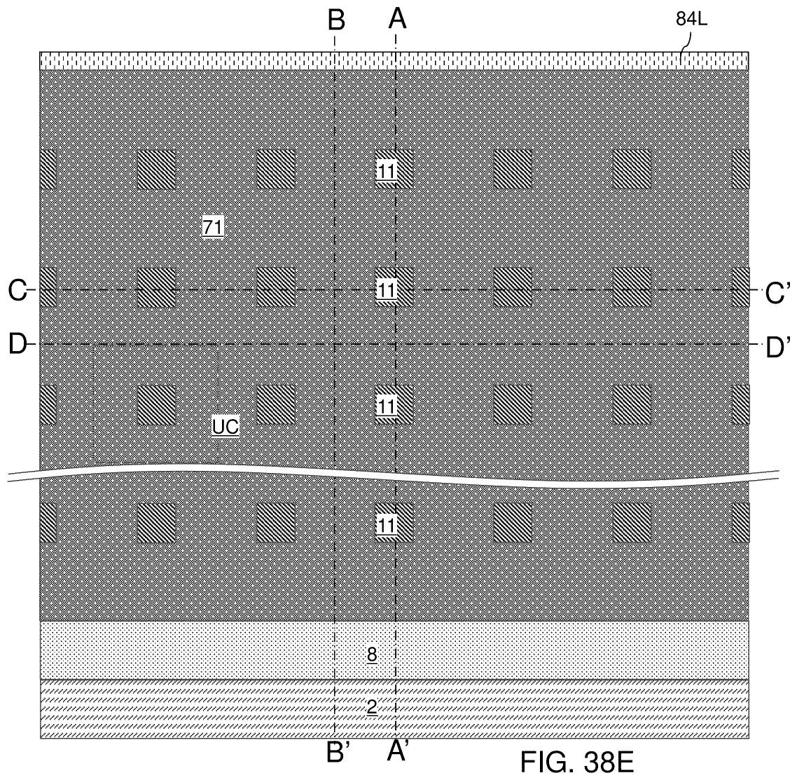

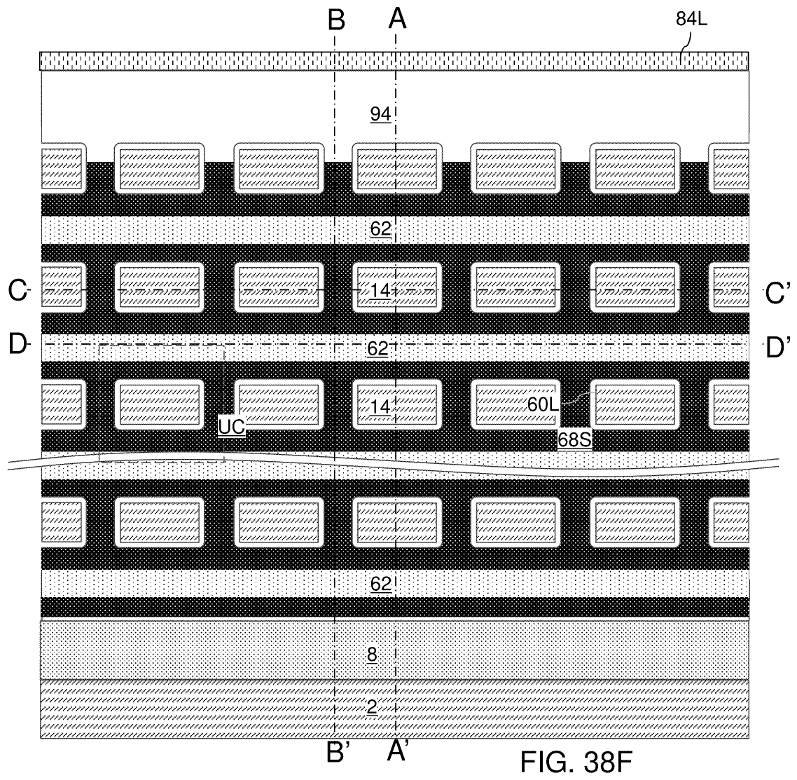

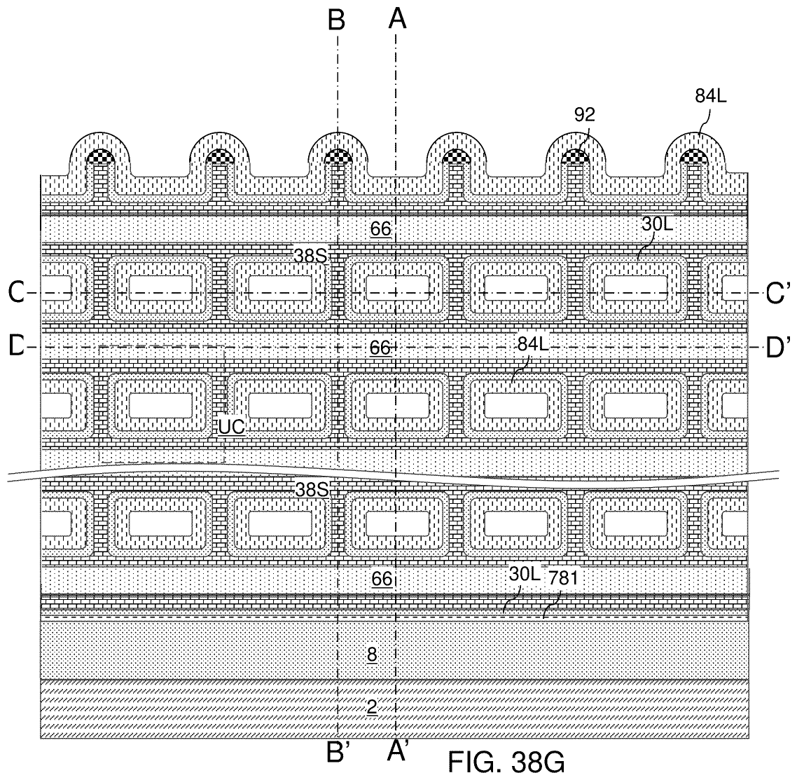

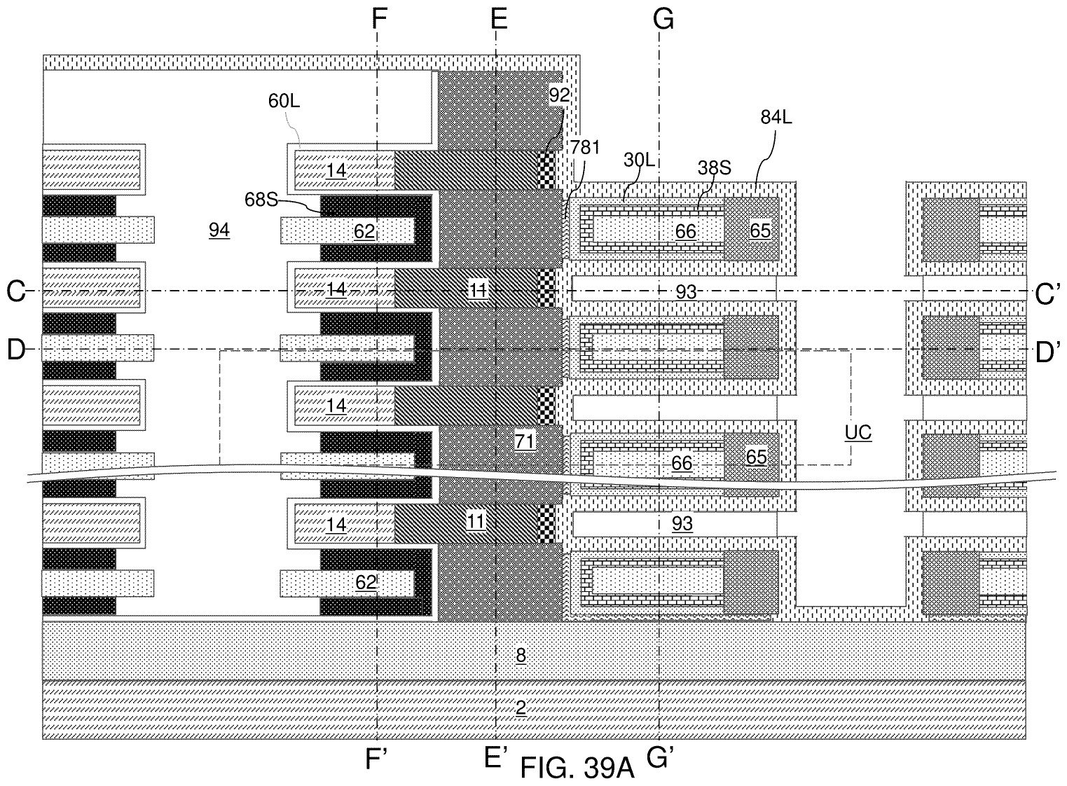

Referring to FIGS. 38A, 38B, 38C, 38D, 38E, 38F, and 38G, the channel material layer 84L can be formed at least on the physically exposed surfaces of the second gate dielectric material layers 30L and the metallic material portions 92. The channel material layer 84L may comprise any semiconductor channel material. As described above, The channel material layer 84L may comprise germanium or a compound semiconductor material, such as silicon-germanium, a III-V compound semiconductor material, a II-VI compound semiconductor material, a metal oxide semiconductor material (such as indium gallium zinc oxide (IGZO), indium tin zinc oxide (ITZO), zinc oxide, zinc oxynitride or titanium oxide), or an organic semiconductor material.

The channel material layer 84L may be deposited by a conformal deposition process such as a chemical vapor deposition process or an atomic layer deposition process. In this case, the channel material layer 84L can be conformally deposited on all physically exposed surfaces of the second exemplary structure. The thickness of the channel material layer 84L can be in a range from 1% to 25%, such as from 5% to 15%, of the thickness of the sacrificial layers 20L as provided at the processing steps of FIGS. 1A-1G. Each tubular portion of the channel material layer 84L that is laterally surrounded by a respective tubular portion of a second gate dielectric material layer 30L constitutes a tubular-portion-containing channel for a memory field effect transistor to be subsequently formed. Thus, the tubular-portion-containing channels for the memory field effect transistors can be formed on tubular portions of the second gate dielectric material layers 30L within the volumes of the elongated cavities 39.

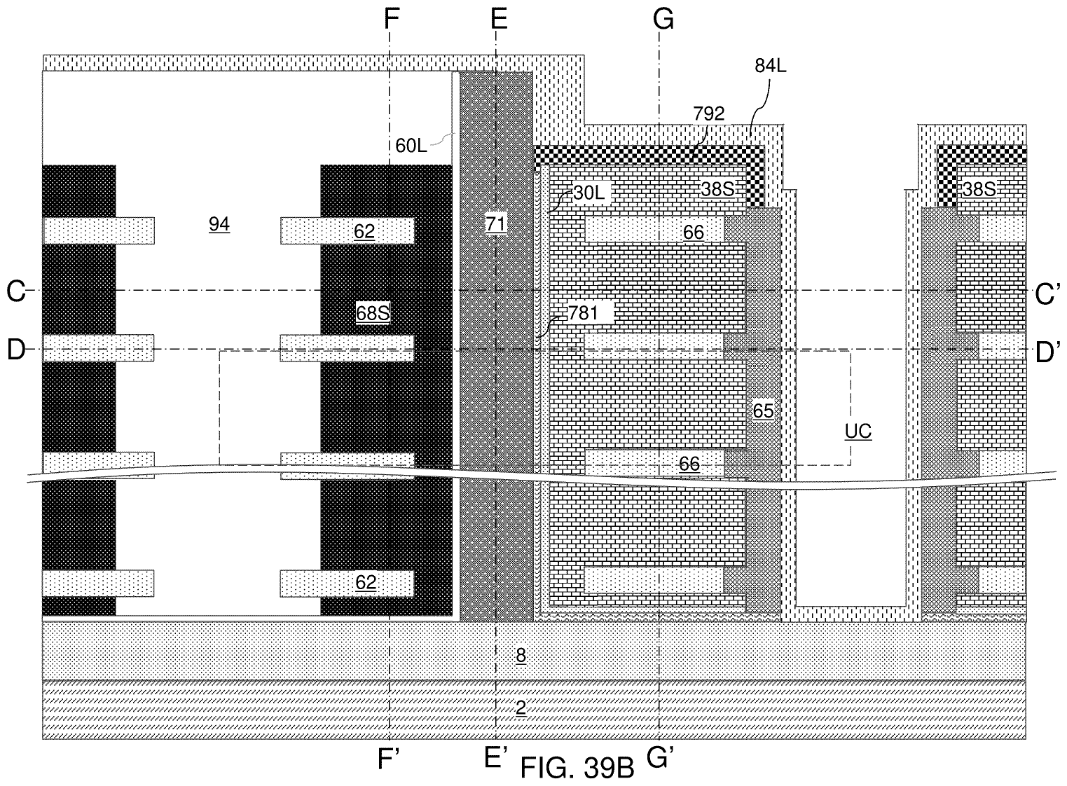

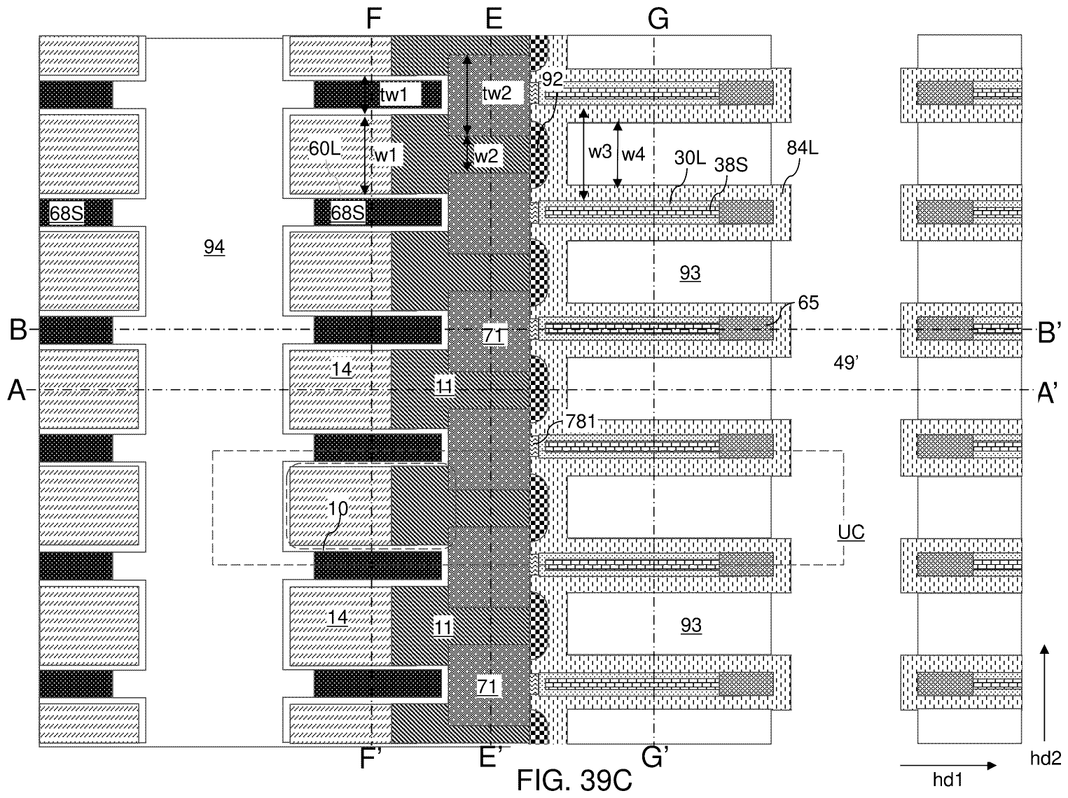

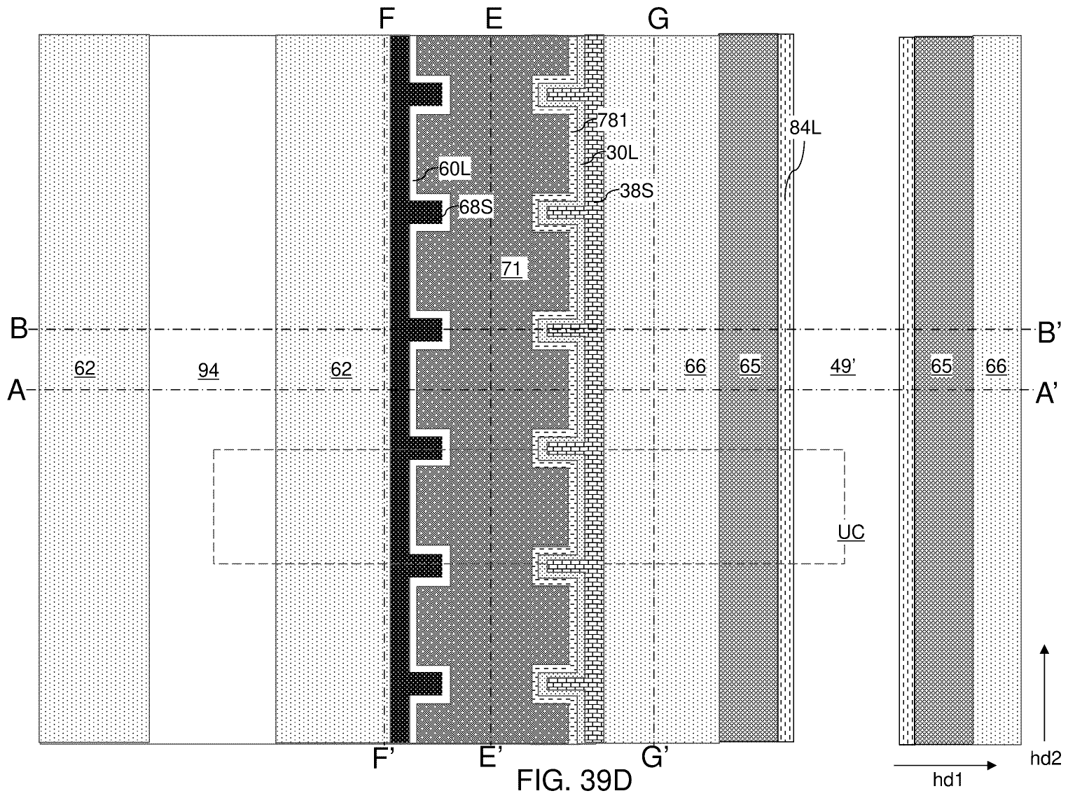

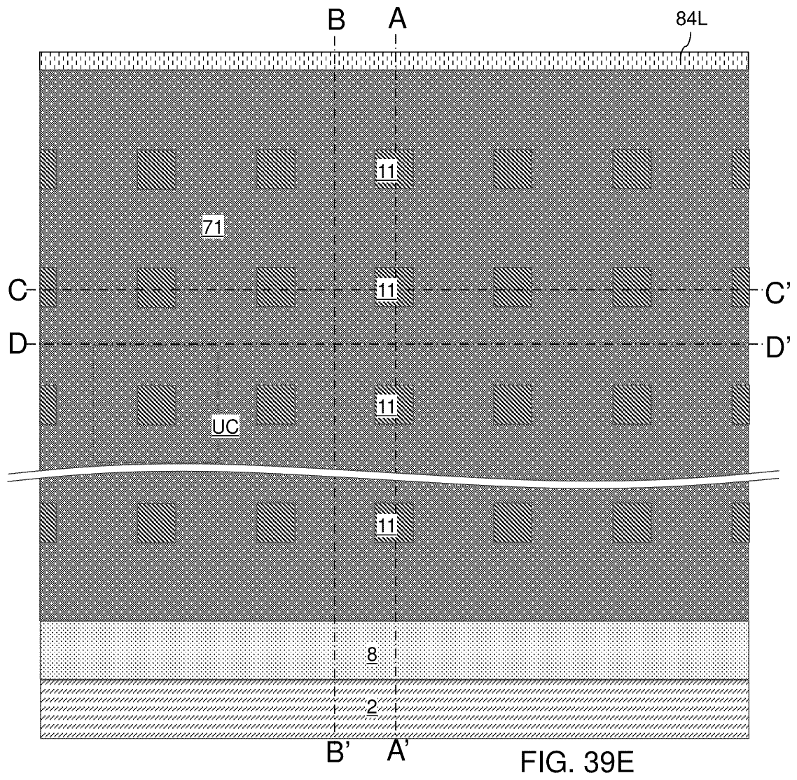

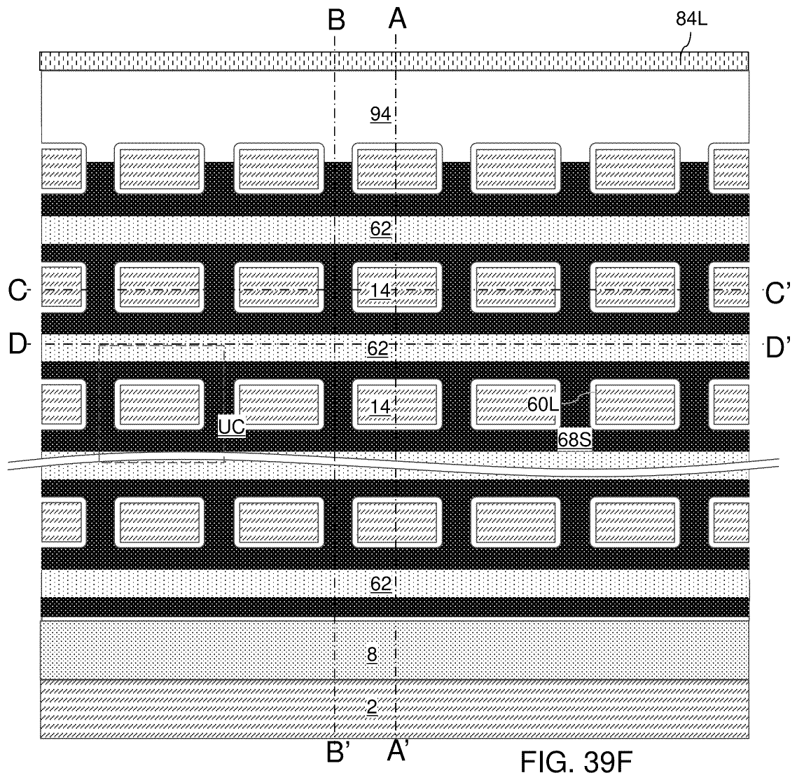

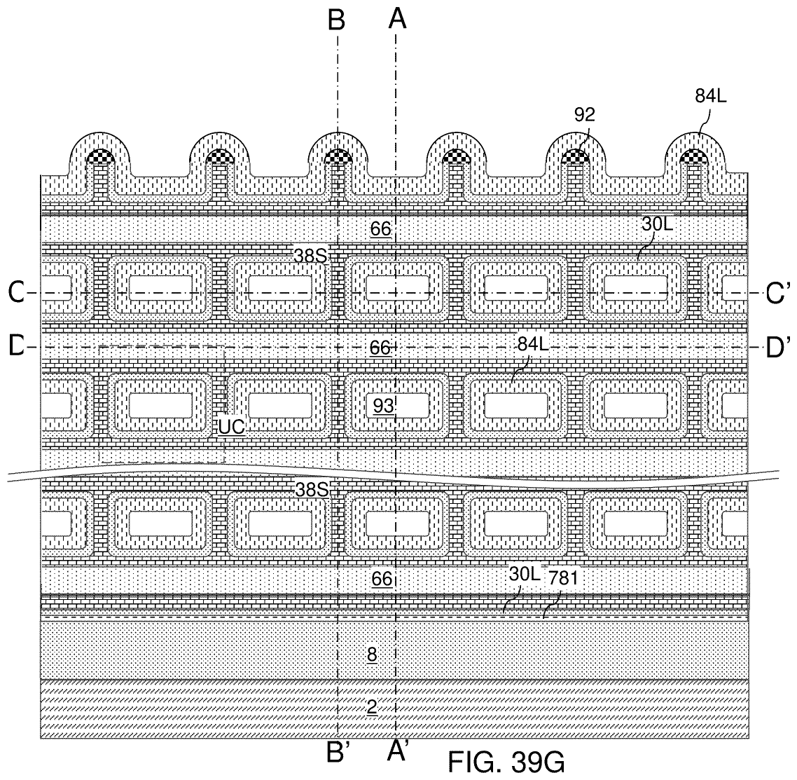

Referring to FIGS. 39A, 39B, 39C, 39D, 39E, 39F, and 39G, a three-dimensional L×M×N array of dielectric core structures 93 can be formed in remaining volumes of the elongated cavities 39. The dielectric core structures 93 are formed in the unfilled volumes of the elongated cavities 39 by conformally depositing a dielectric fill material and isotropically or anisotropically recessing the dielectric fill material. Remaining portions of the dielectric fill material comprise the dielectric core structures 93. Specifically, a second dielectric fill material such as silicon oxide can be conformally deposited in the elongated cavities 39, in peripheral portions of the source trenches 49, and over the horizontally-extending portion of the channel material layer 84L that overlie a horizontal plane including topmost surfaces of the second gate dielectric material layers 30L. An isotropic or anisotropic recess etch process may be performed to remove portions of the second dielectric fill material from outside the volumes of the elongated cavities 39. Remaining portions of the second dielectric fill material that fill the elongated cavities 39 comprise a two-dimensional array of dielectric core structures 93. Each dielectric core structure 93 is laterally surrounded by a respective tubular portion of the channel material layer 84L.

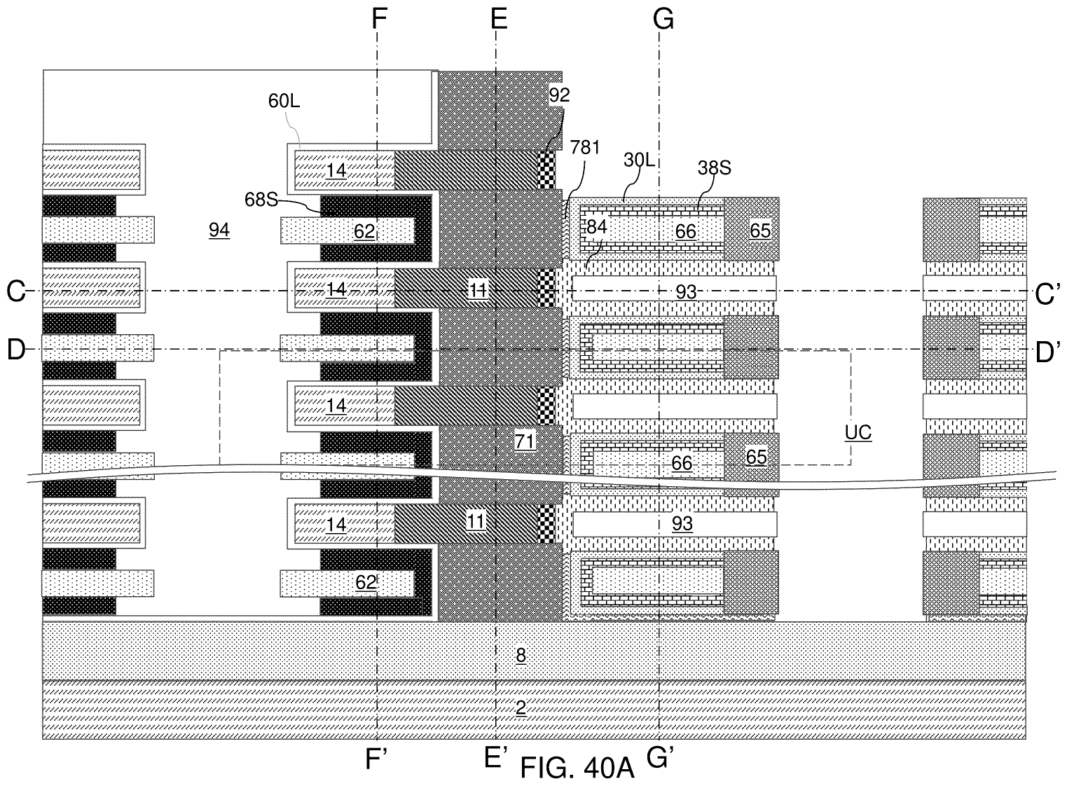

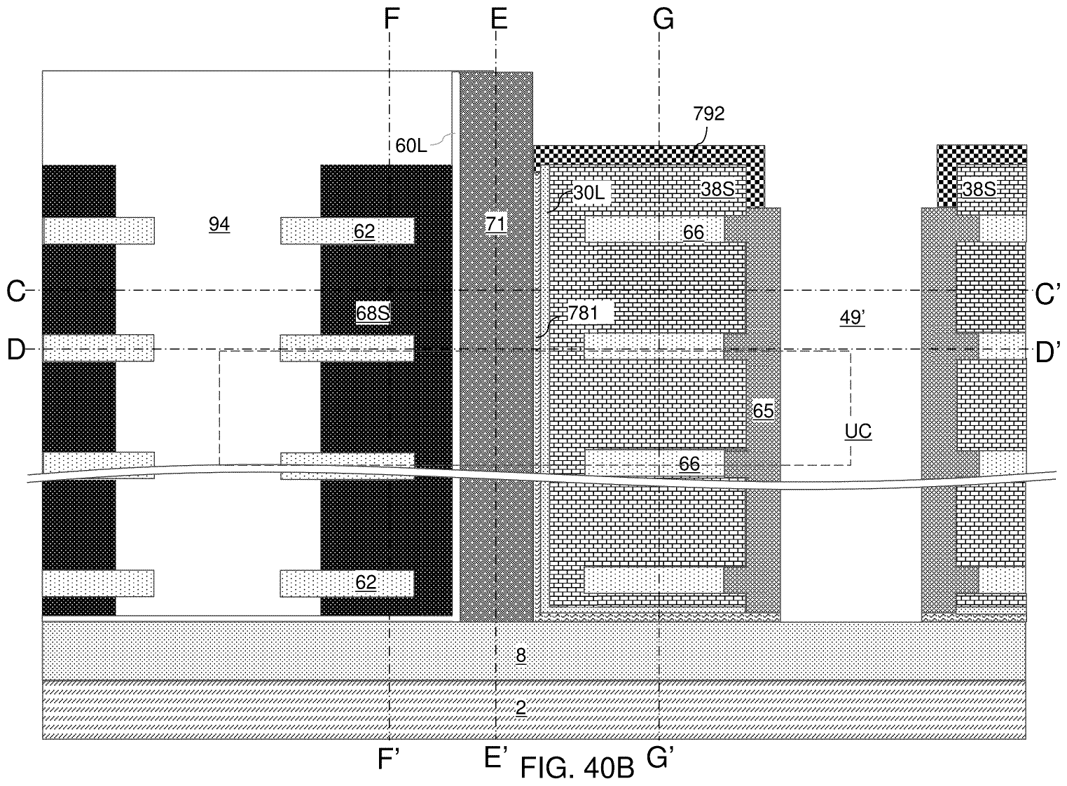

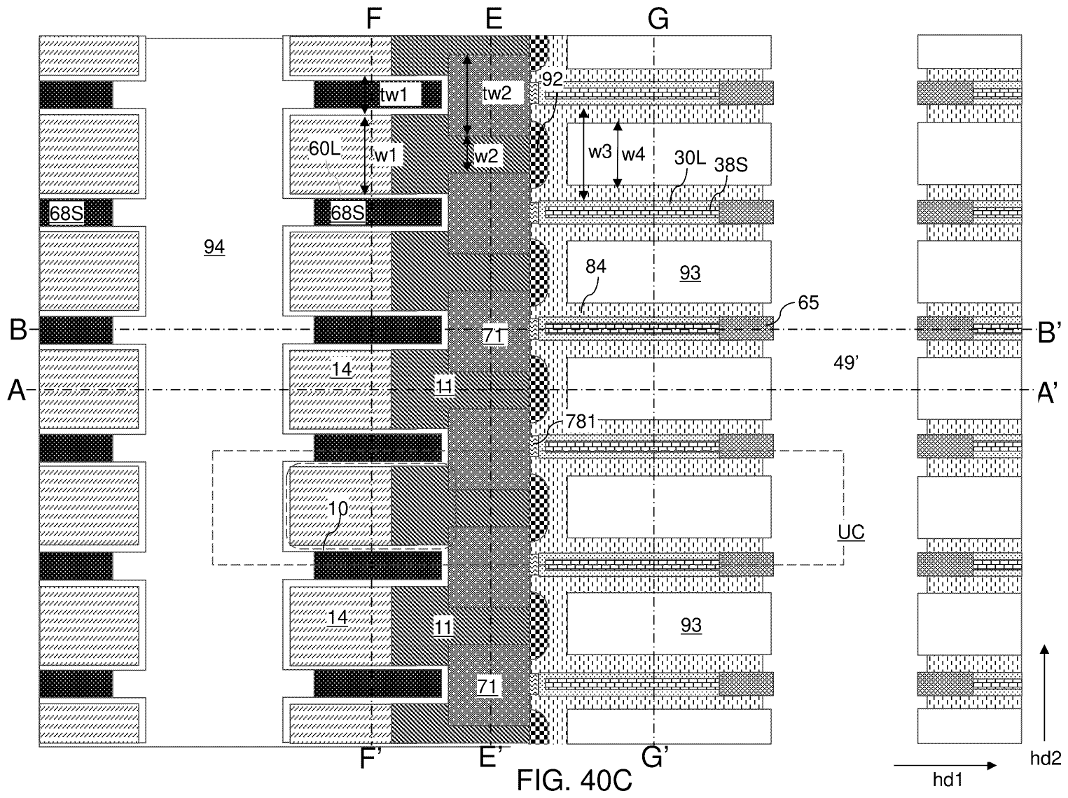

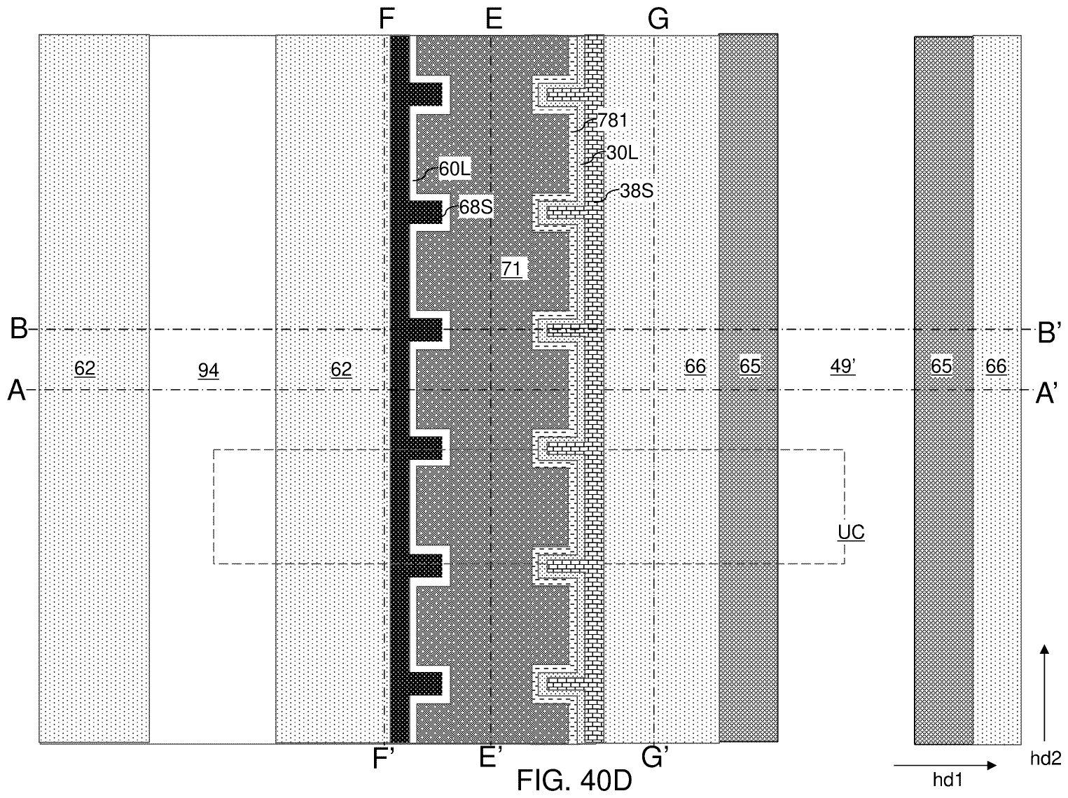

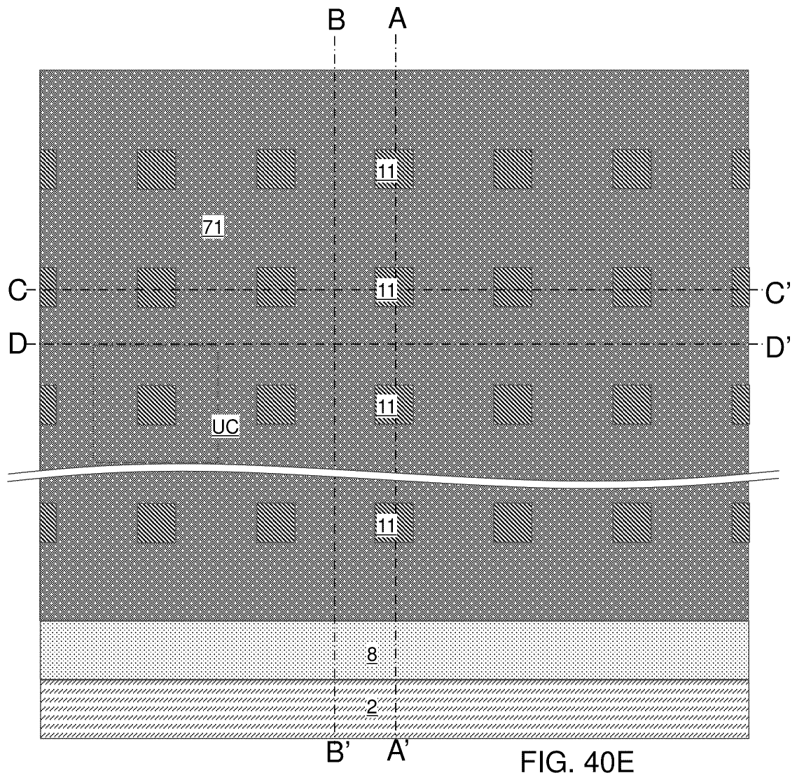

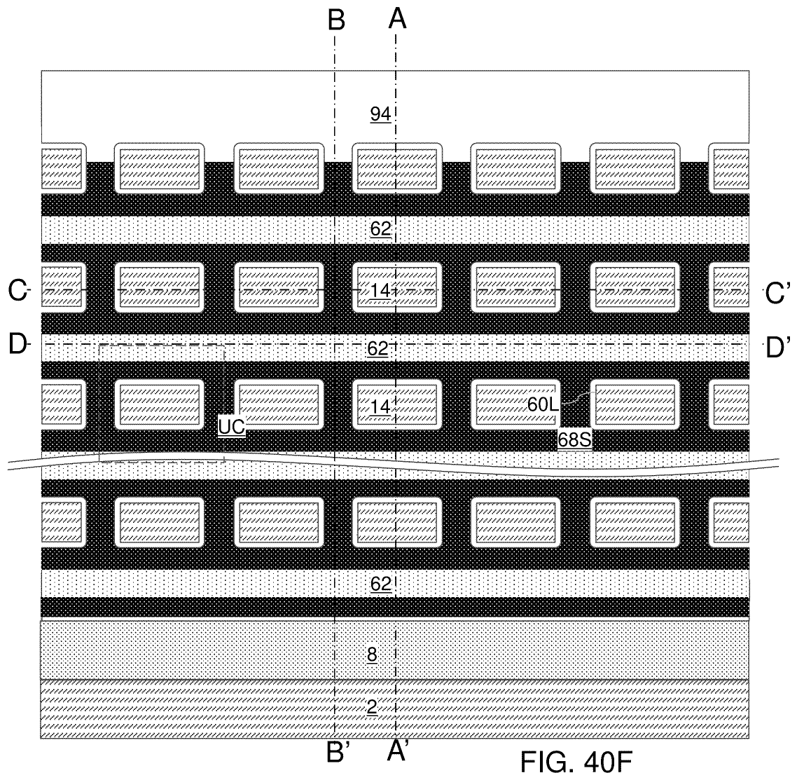

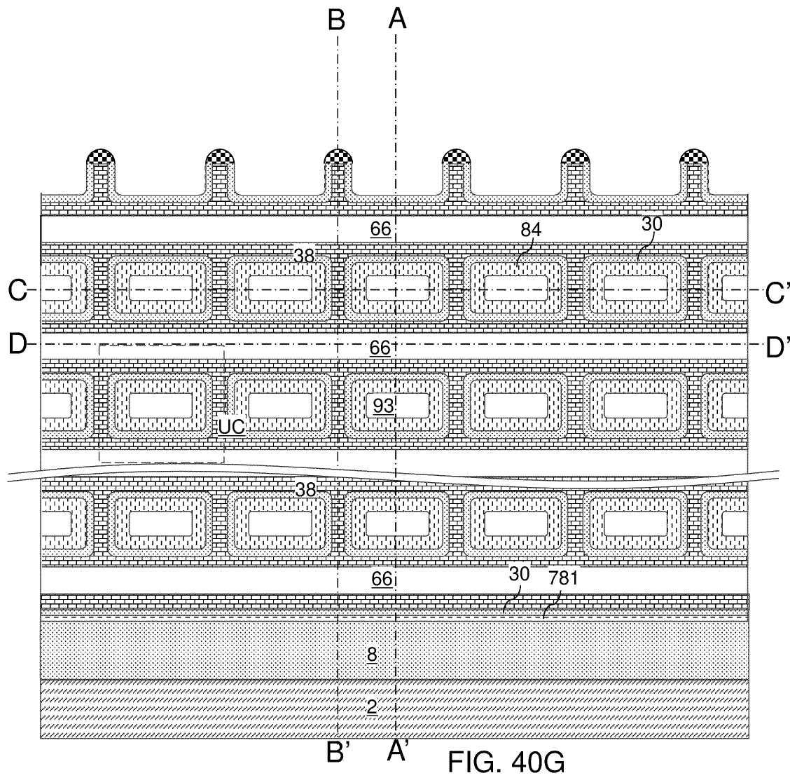

Referring to FIGS. 40A, 40B, 40C, 40D, 40E, 40F, and 40G, an etch process can be performed to remove physically exposed portions of the channel material layer 84L selectively to the material of the metallic material portions 92, the perforated passivation wall 65 and the sacrificial perforated wall structures 71. The perforated passivation wall 65 protects the second gate dielectric material layers 30L from being etched. Remaining patterned portions of the channel material layer 84L comprise a three-dimensional L×M×N array of tubular-portion-containing channels 84. Each tubular-portion-containing channel 84 has a tubular shape and having an end cap portion that blocks a first end of the tubular shape. Each tubular-portion-containing channel 84 laterally encloses a respective dielectric core structure 93.

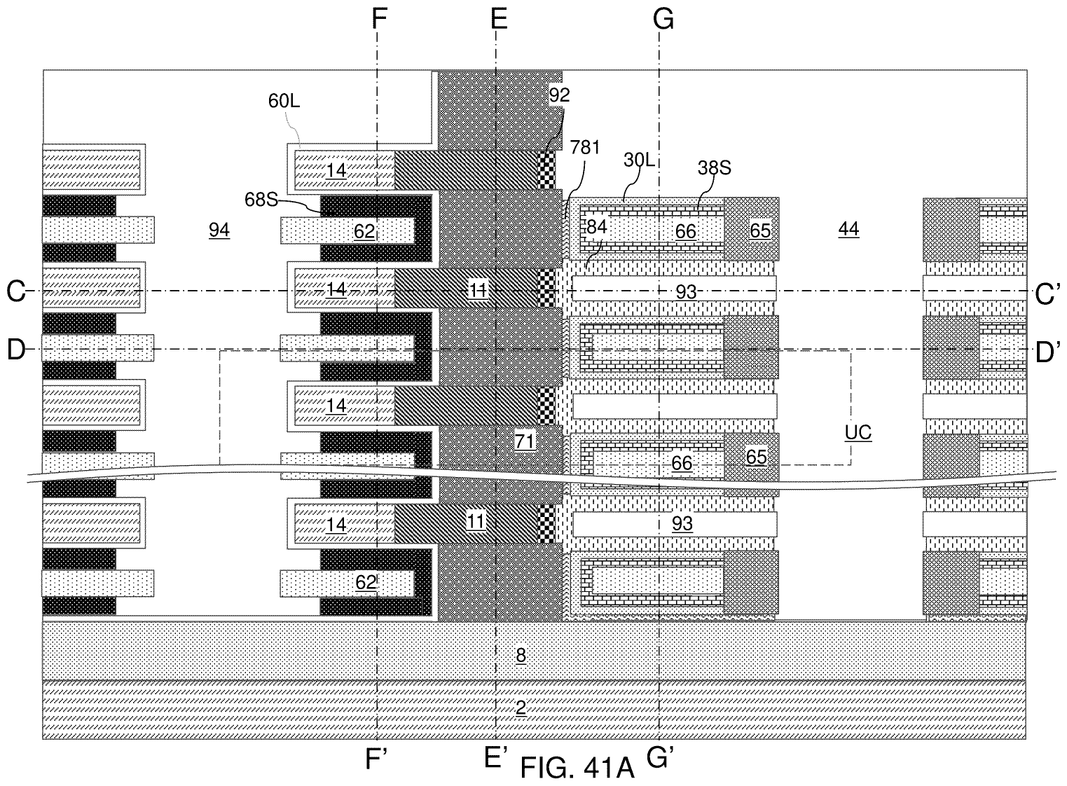

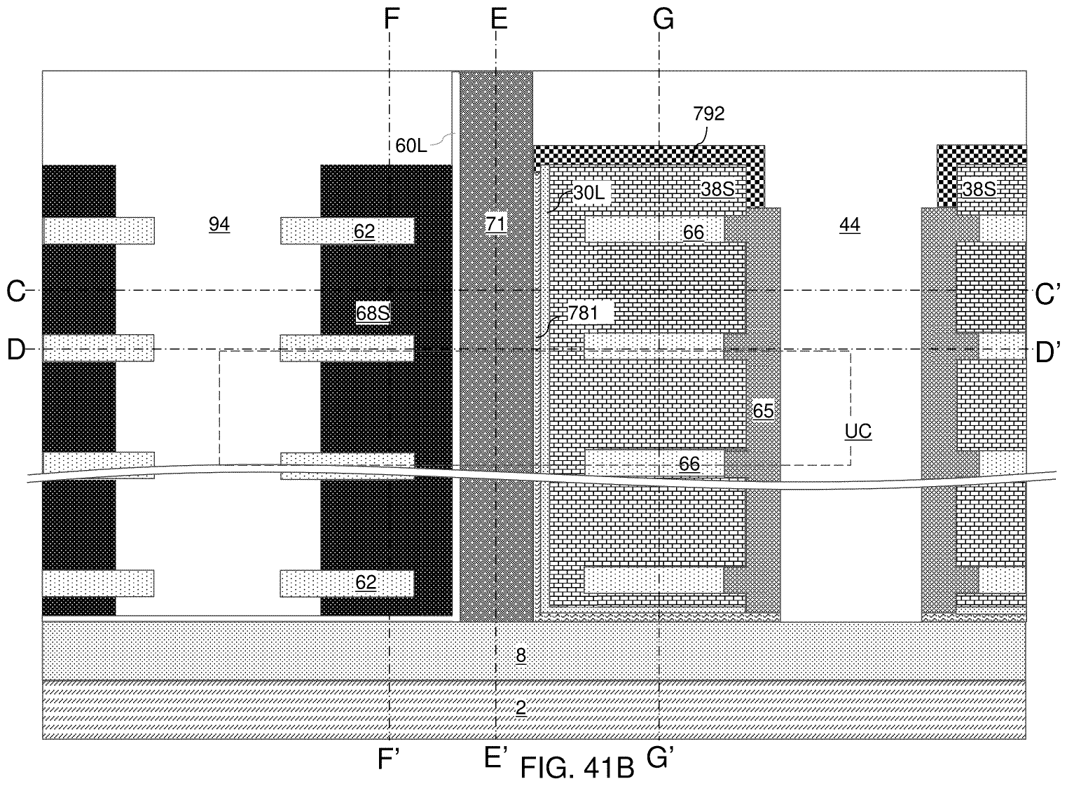

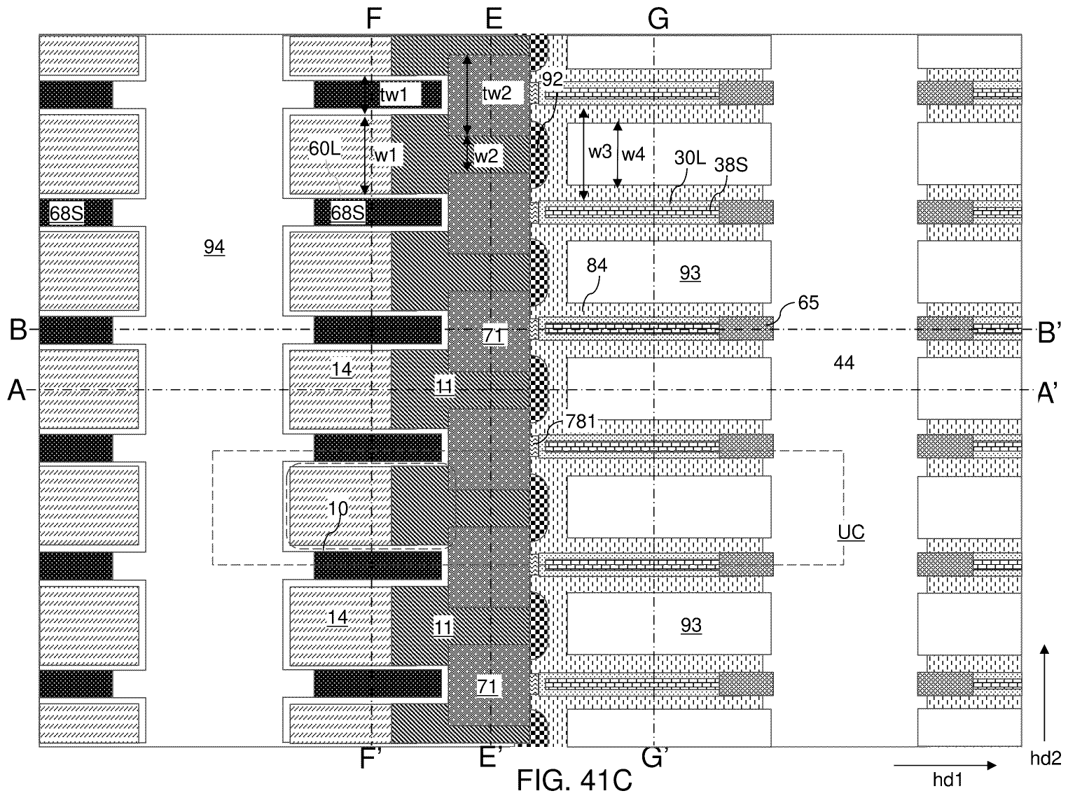

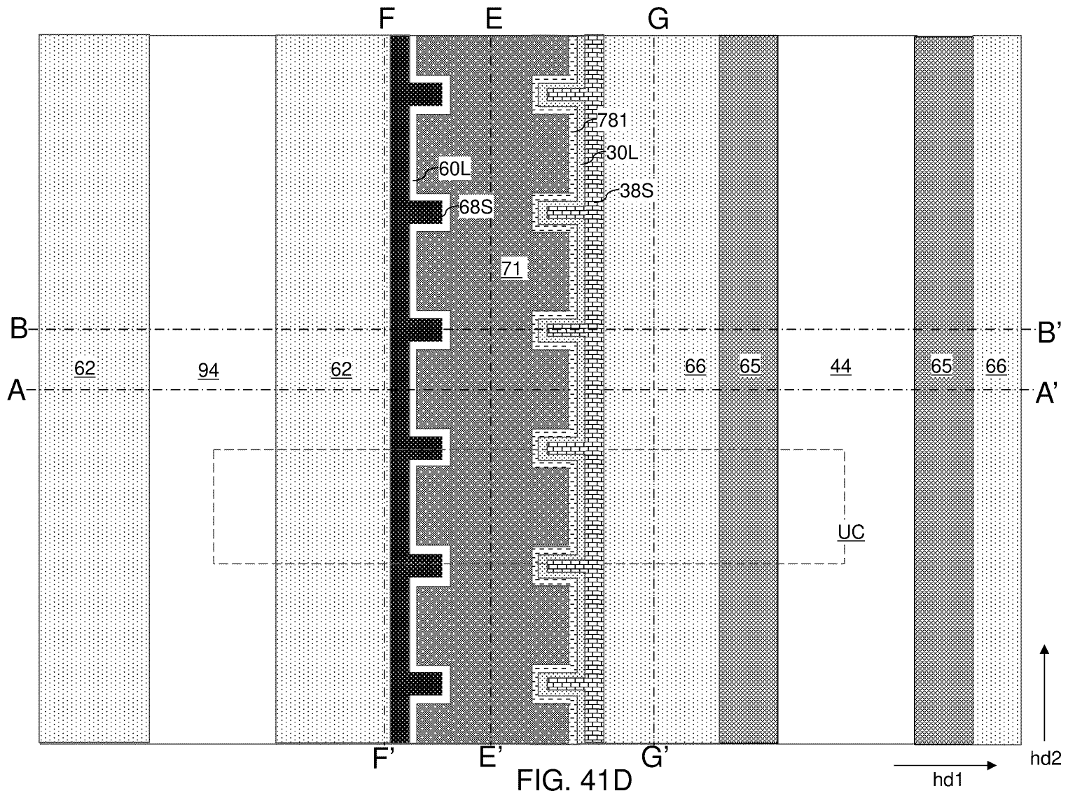

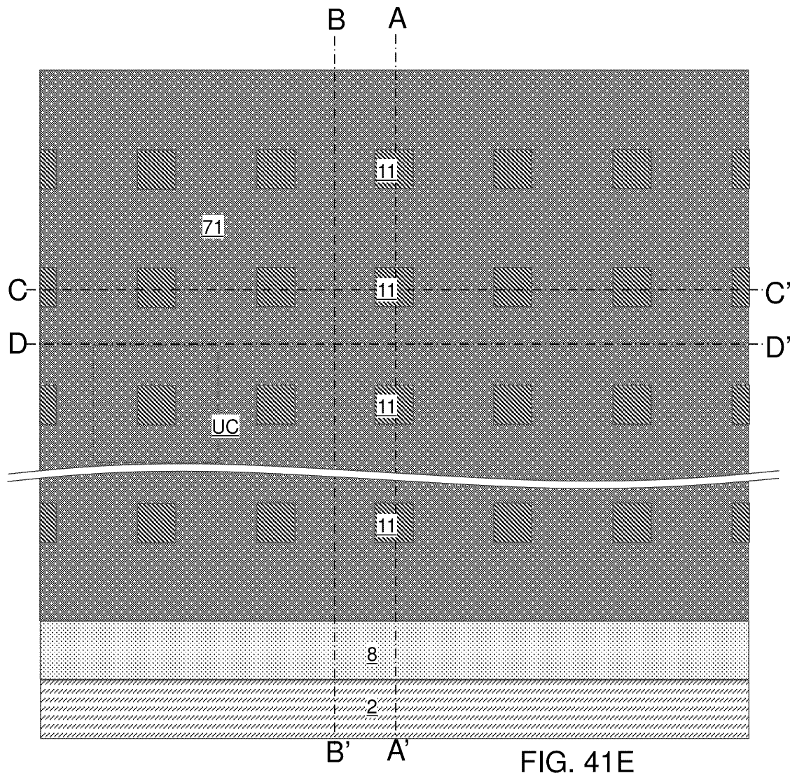

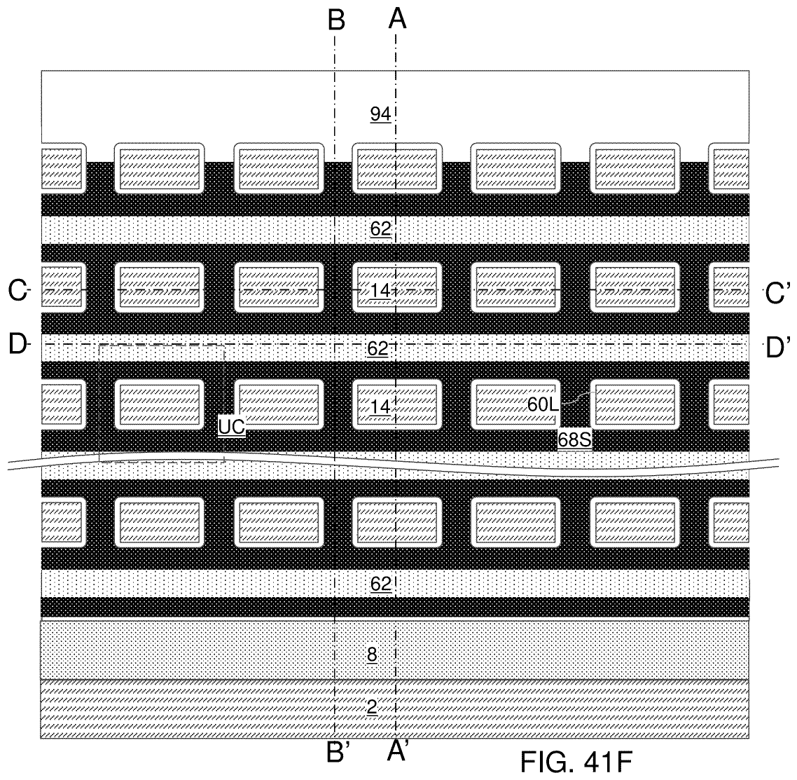

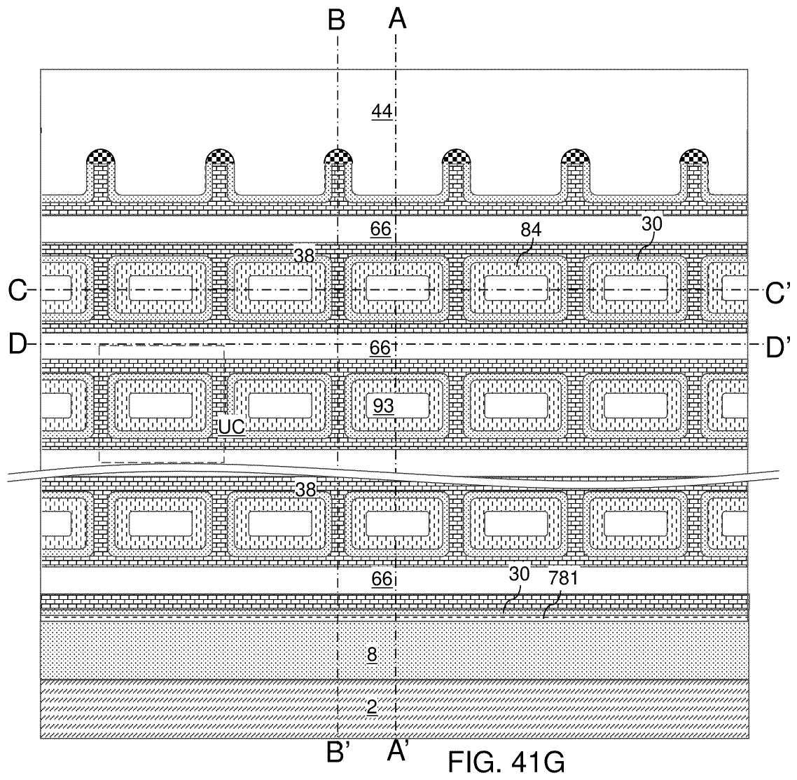

Referring to FIGS. 41A, 41B, 41C, 41D, 41E, 41F, and 41G, a dielectric fill material, such as undoped silicate glass (i.e., silicon oxide) or a doped silicate glass, can be deposited in the source trenches 49. A planarization process, such as a chemical mechanical polishing process, can be performed to remove portions of the dielectric fill material from above the horizontal plane including the top surfaces of the sacrificial perforated wall structures 71. Each remaining portion of the dielectric fill material that fills the bit-line trenches 99 comprises a bit-line trench isolation structure 94. In one embodiment, top surfaces of the bit-line trench isolation structures 94 may be formed within the horizontal plane including the top surfaces of the sacrificial perforated wall structures 71 and/or the bit-line trench isolation structures 94. A laterally alternating sequence of bit-line trench isolation structures 94 and source trench isolation structures 44 can be arranged along the first horizontal direction hd1.

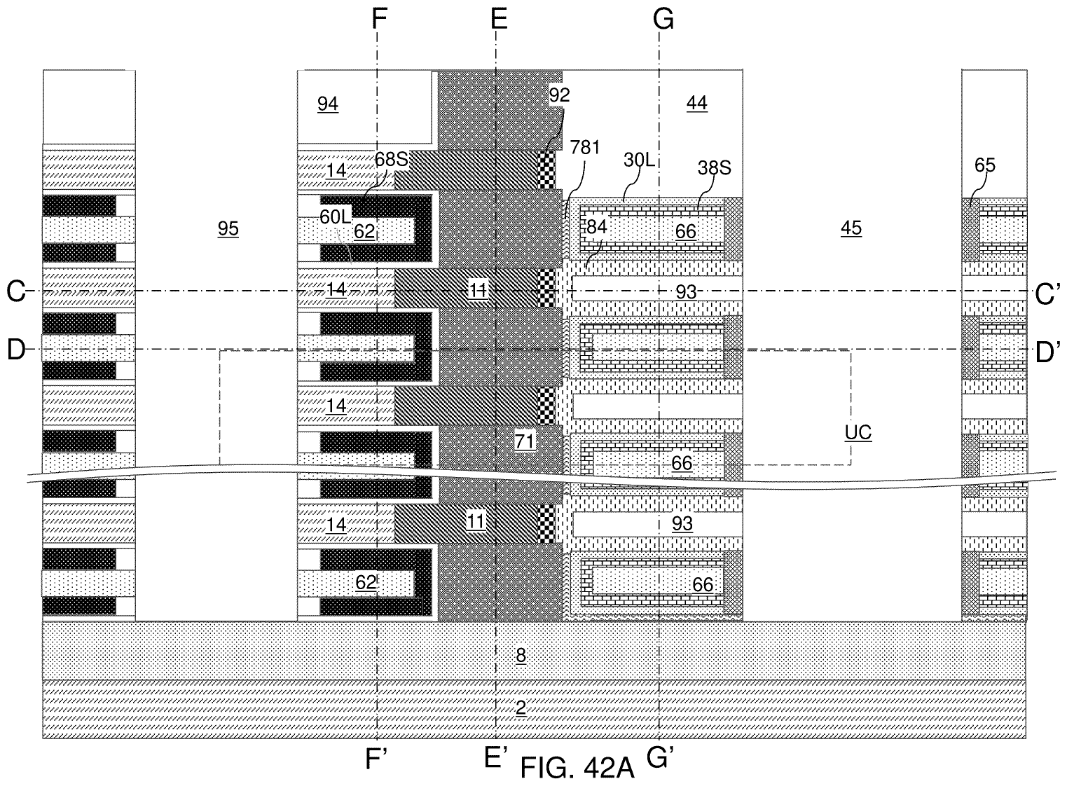

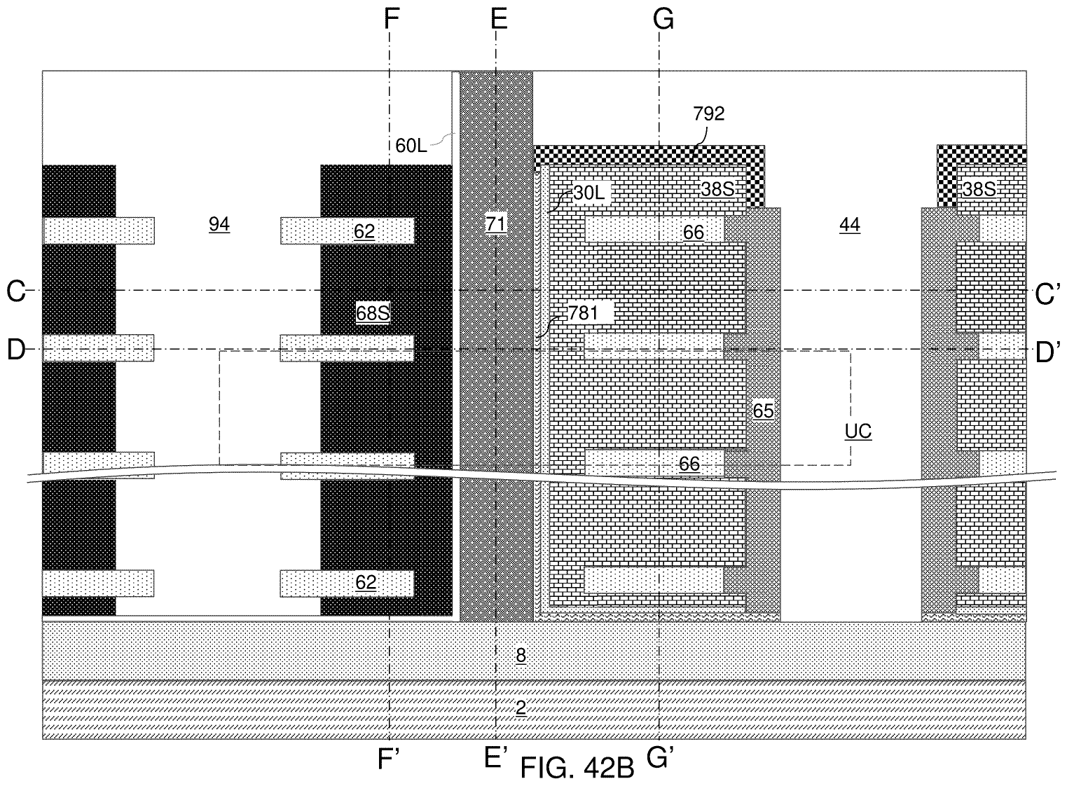

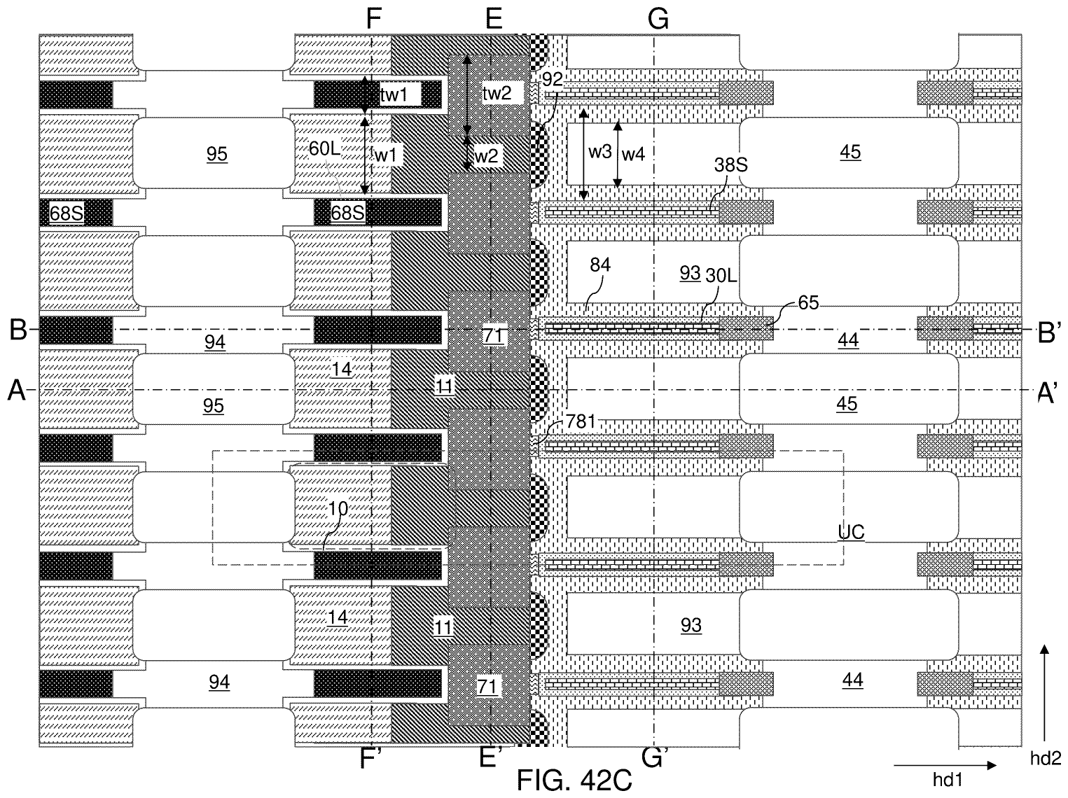

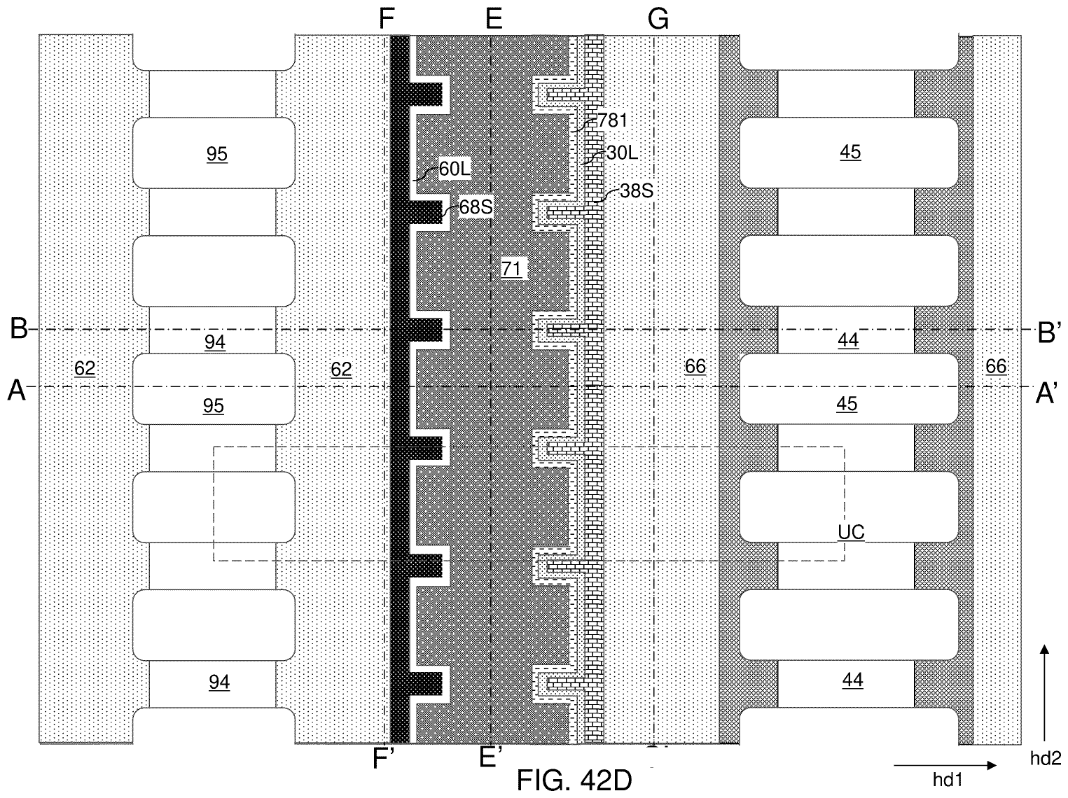

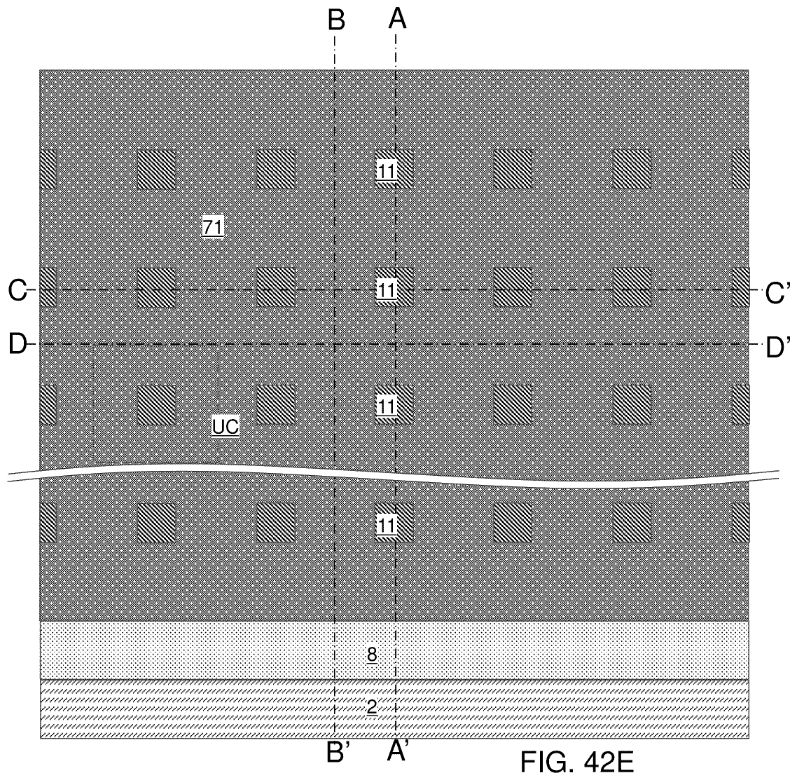

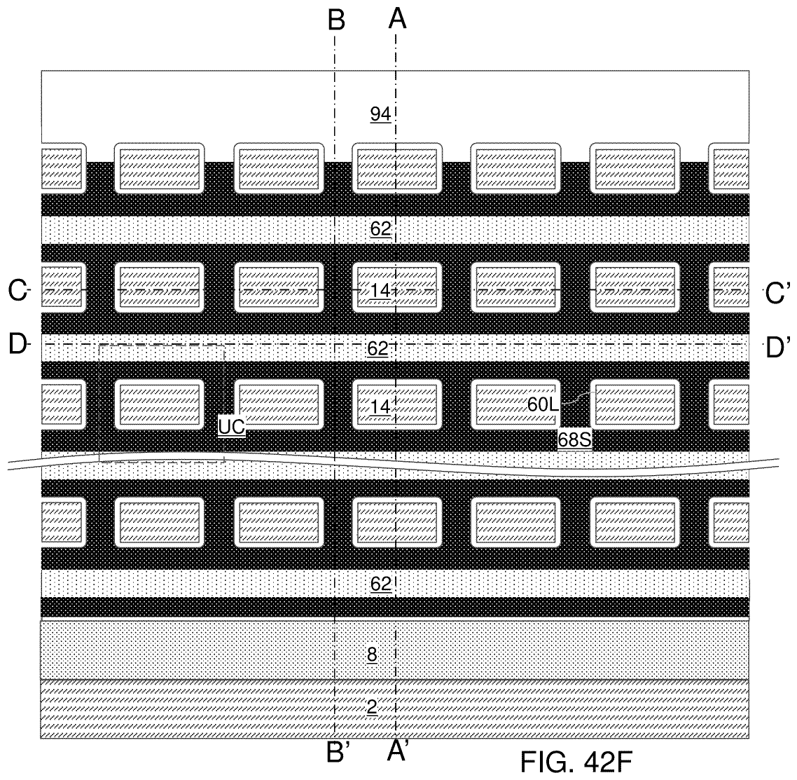

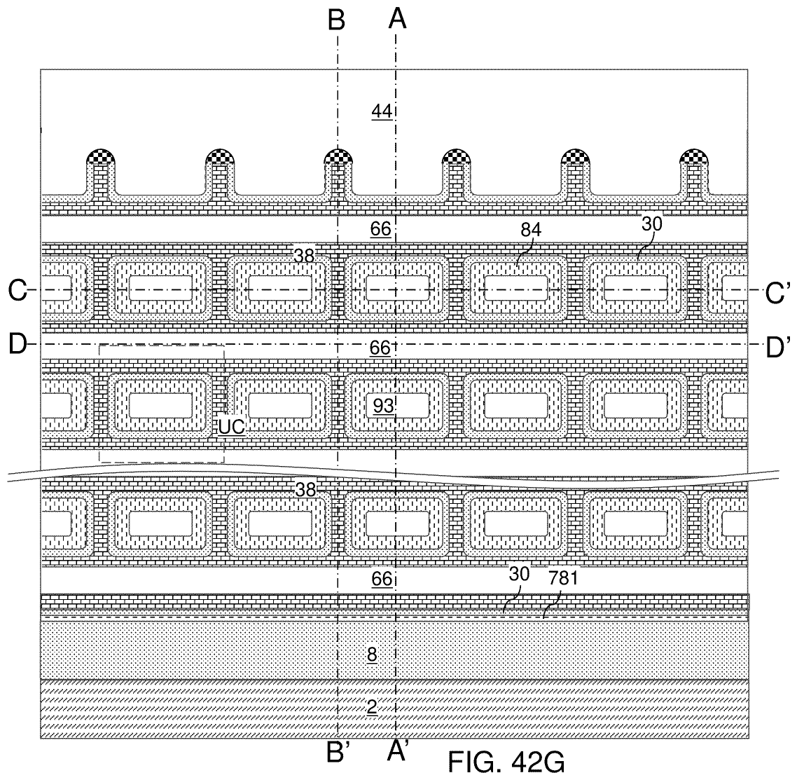

Referring to FIGS. 42A, 42B, 42C, 42D, 42E, 42F, and 42G, a photoresist layer (not shown) can be applied over the second exemplary structure, and can be lithographically patterned to form a total of (L+1)×M openings over the bit-line trench isolation structures 94 and the source trench isolation structures 44. An anisotropic etch process can be performed to transfer the pattern of the openings in the photoresist layer through the bit-line trench isolation structures 94 and source trench isolation structures 44. Bit-line via cavities 95 vertically extending down to the etch stop structure 8 (or to the substrate 2 if the etch stop structure is omitted) can be formed through the bit-line trench isolation structures 94. Source-line via cavities 45 vertically extending down to the etch stop structure 8 (or to the substrate 2 if the etch stop structure is omitted) can be formed through the source trench isolation structures 44. The photoresist layer can be subsequently removed, for example, by ashing.

Each first end portion of the horizontally-extending semiconductor channels 14 may be cut by a respective one of the bit-line via cavities 95. In one embodiment, an end wall of each horizontally-extending semiconductor channel 14 may be exposed to a respective one of the bit-line via cavities 95. Each first end portion of the tubular-portion-containing channels 84 may be cut by a respective one of the source via cavities 45. At least one sidewall of each tubular-portion-containing channel 84 may be exposed to a respective one of the source via cavities 45. In one embodiment, a pair of sidewalls of each tubular-portion-containing channel 84 can be exposed to a respective one of the source via cavities 45. In one embodiment, each first end portion of the dielectric core structures 93 may be cut through by a respective one of the source via cavities 45. Thus, each dielectric core structure 93 may comprise a sidewall that is physically exposed to a respective one of the source via cavities 45. In one embodiment, portions of each perforated passivation wall 65 may be cut by a respective column of source via cavities 45. In this case, each perforated passivation wall 65 may have a serrated horizontal cross-sectional profile as illustrated in FIG. 42D.

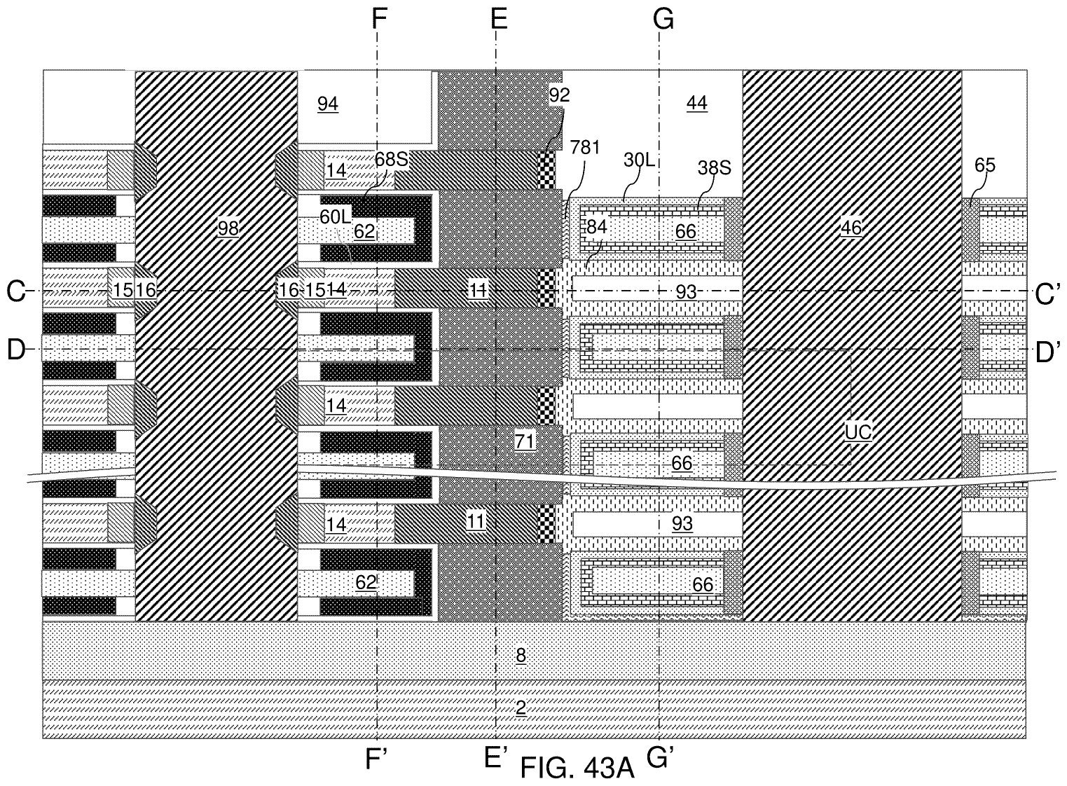

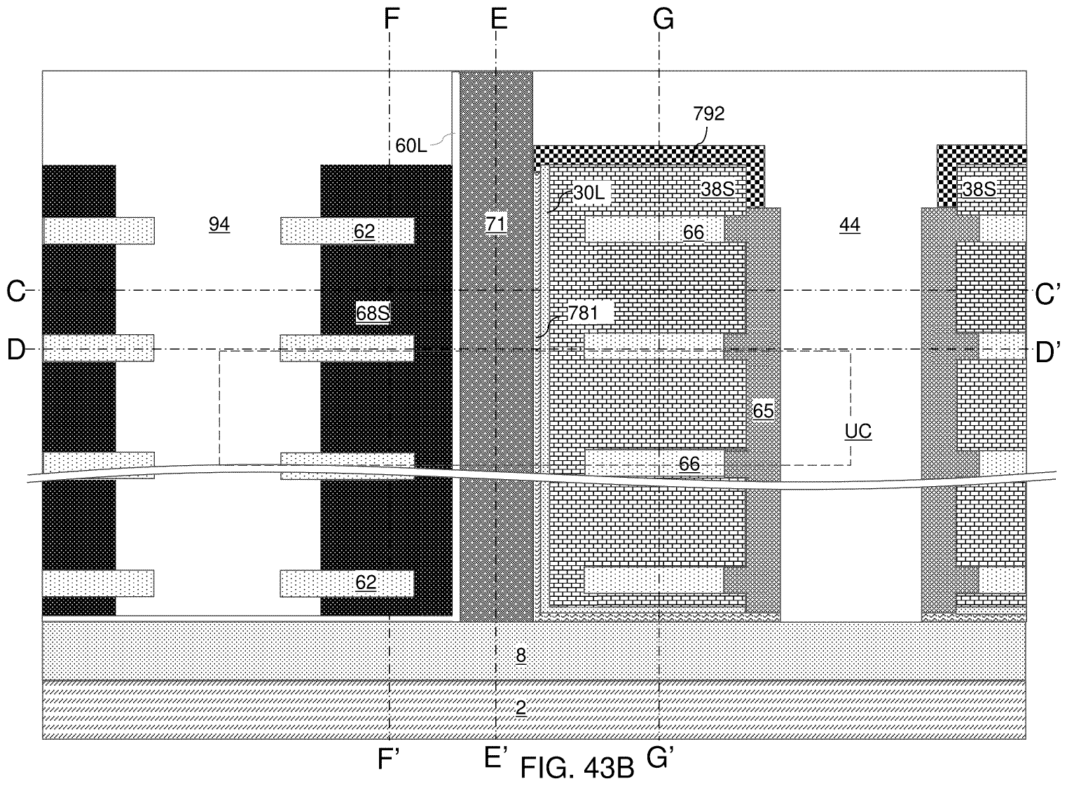

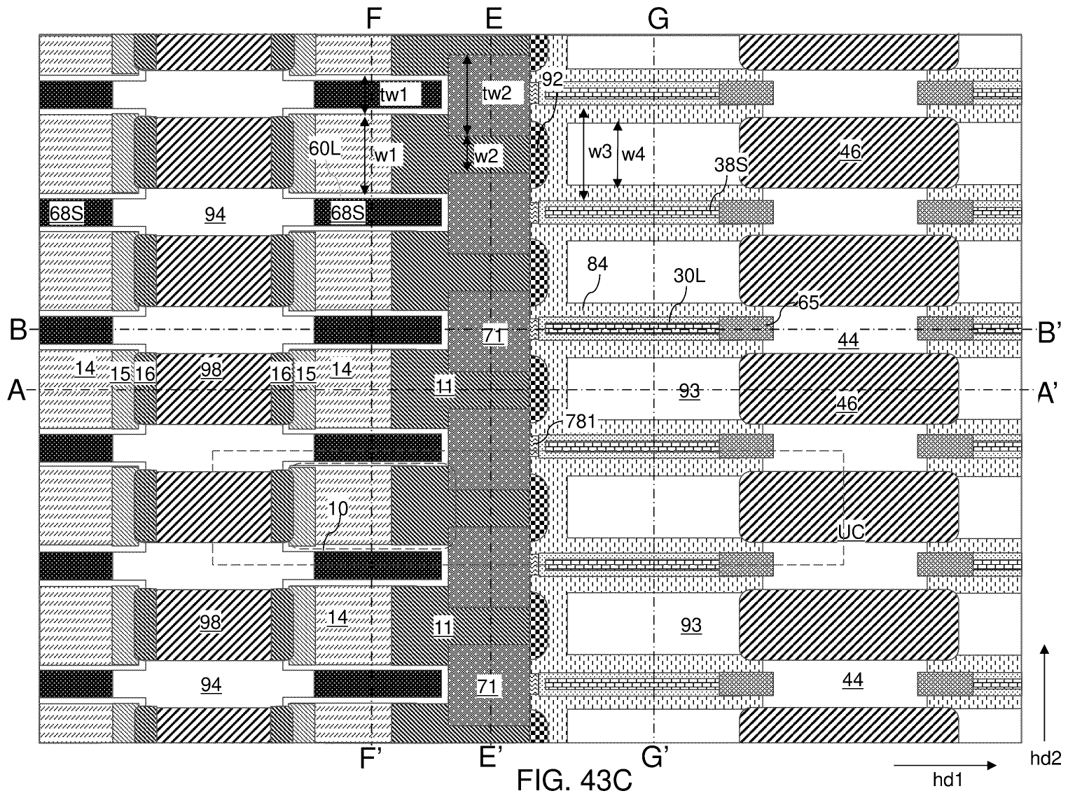

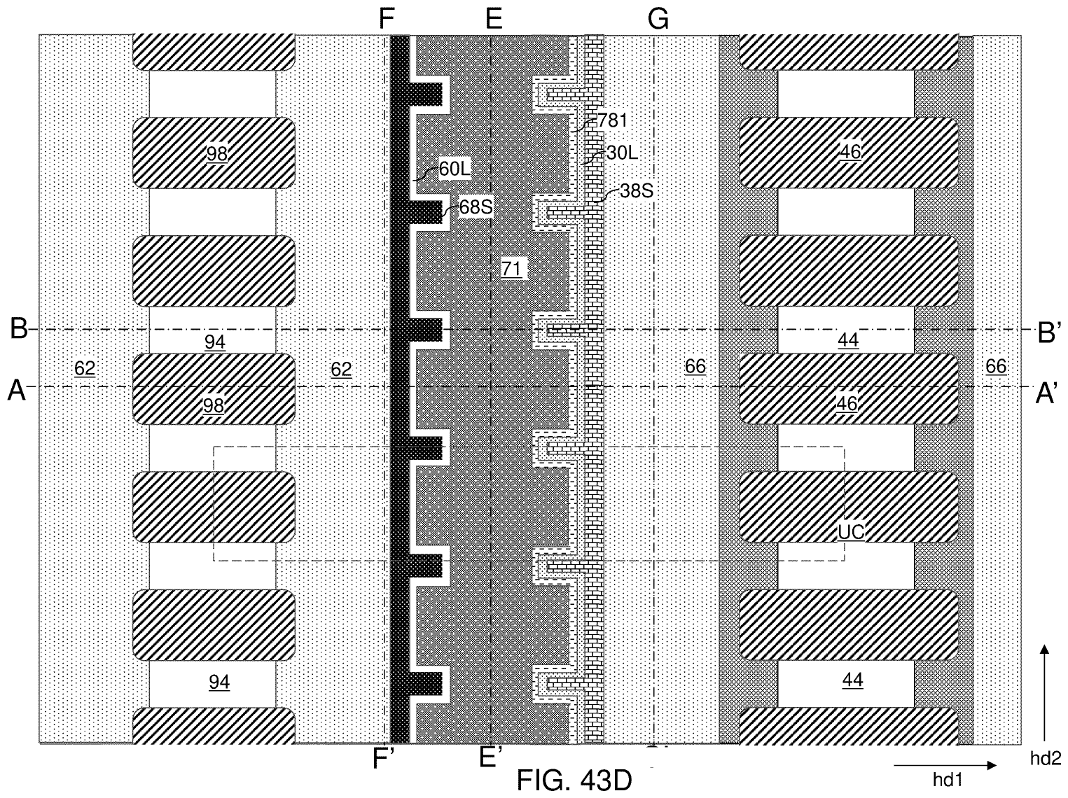

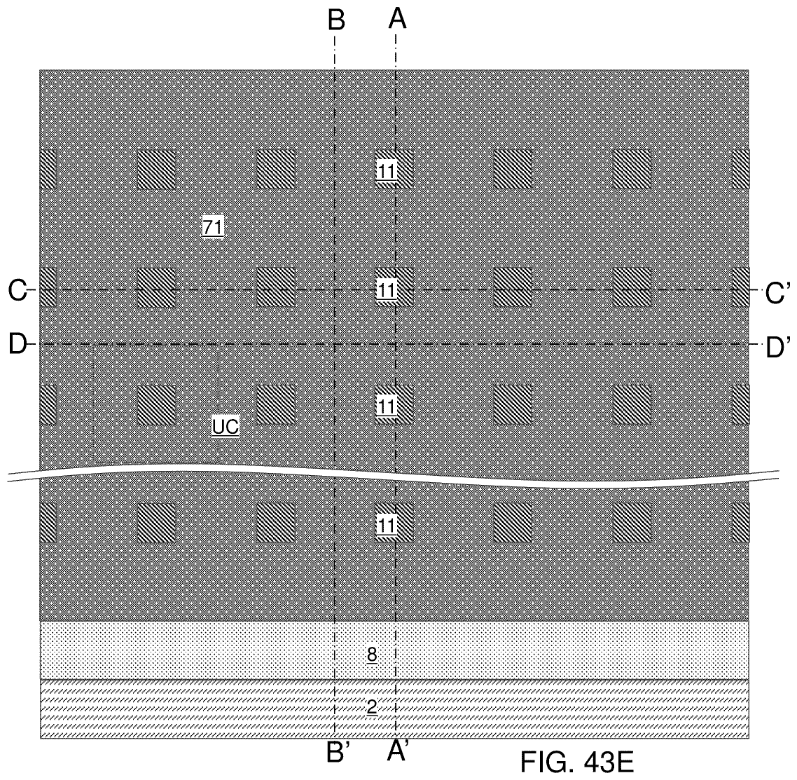

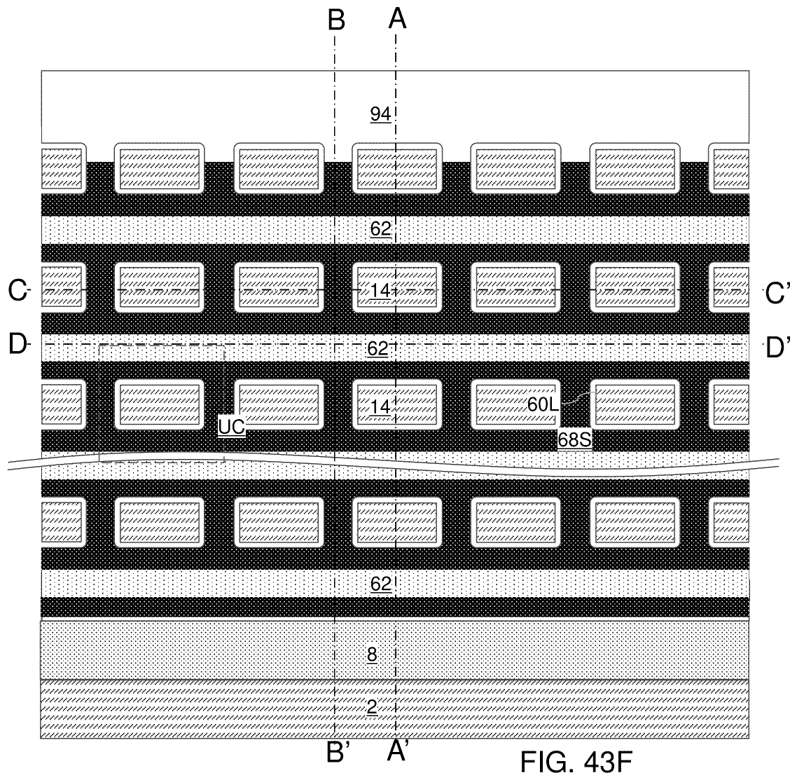

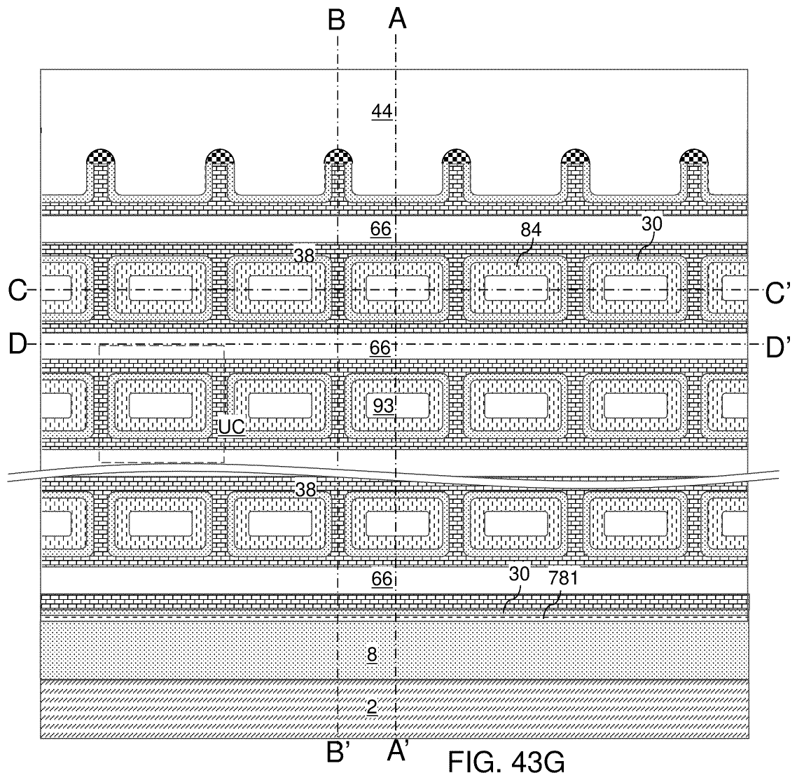

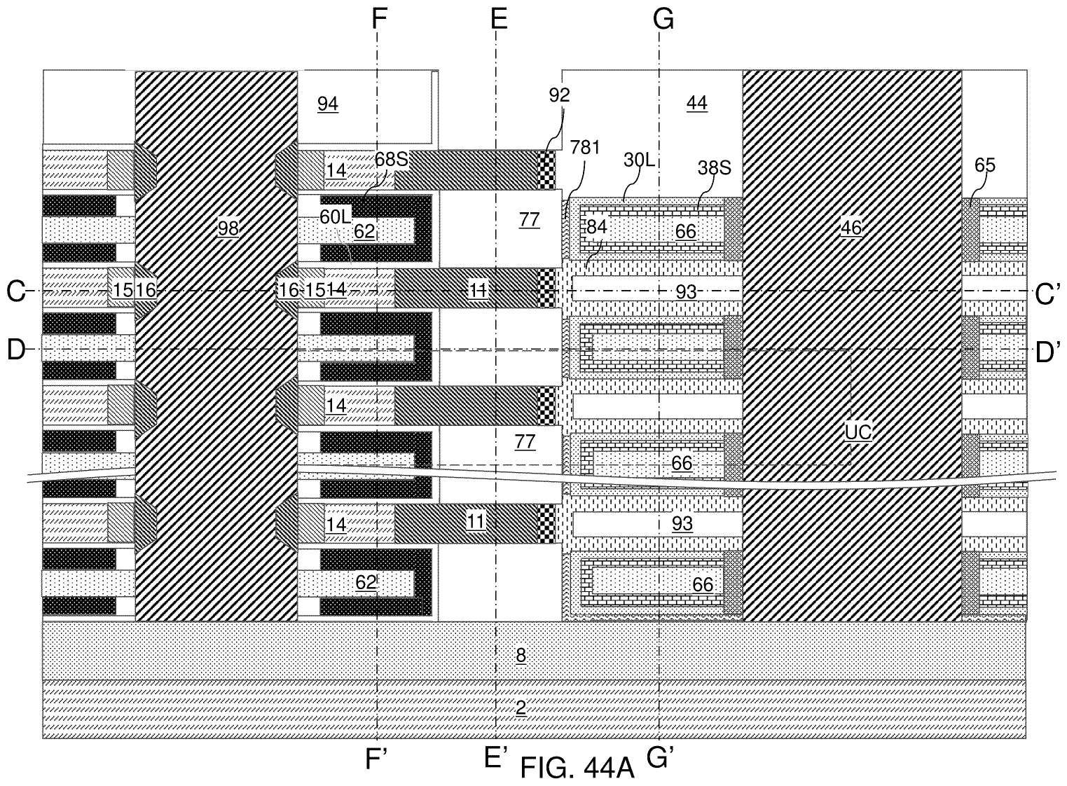

Referring to FIGS. 43A, 43B, 43C, 43D, 43E, 43F, and 43G, an optional extension region doping process may be performed to electrically dope edge portions of the horizontally-extending semiconductor channels 14 that are proximal to the bit-line via cavities 95. For example, a gas phase doping process or an outdiffusion process employing a conformally deposited sacrificial doped silicate glass layer (such as a sacrificial phosphosilicate glass layer or a sacrificial arsenosilicate glass layer) may be employed to convert surface portions of the horizontally-extending semiconductor channels 14 that are proximal to the bit-line via cavities 95 into drain extension regions 15. In other words, surface portions of the horizontally-extending semiconductor channels 14 that are proximal to the bit-line via cavities 95 are converted into drain extension regions 15. Source extension regions may optionally be formed in physically exposed end portions of the tubular-portion-containing channels 84 depending on the material composition of the tubular-portion-containing channels 84. The remaining portions of the horizontally-extending semiconductor channels 14 function as channel regions of first field effect transistors to be subsequently formed.

A selective doped semiconductor deposition process can be performed to grow a drain region 16 having a doping of the second conductivity type from physically exposed semiconductor surfaces of the horizontally-extending semiconductor channels 14 that are exposed to the bit-line via cavities 95. In one embodiment, a doped semiconductor material having a doping of the second conductivity type can be grown from physically exposed semiconductor surfaces of the tubular-portion-containing channels 84 that are exposed to the source via cavities 45 to provide source regions (not illustrated). Selective deposition of a doped semiconductor source material may optionally occur from physically exposed surfaces of the tubular-portion-containing channels 84, and thus, source regions may optionally be formed on the tubular-portion-containing channels 84 depending on the material composition of the tubular-portion-containing channels 84. The drain regions 16 are formed on the sidewalls of the horizontally-extending semiconductor channels 14 in peripheral portions of the bit-line via cavities 95. While FIGS. 43A-43G illustrate an embodiment in which source regions are not formed the source via cavities 49, embodiments are expressly contemplated herein in which source regions are formed on sidewalls of the tubular-portion-containing channels 84 (depending on the material of the tubular-portion-containing channels 84).

The source regions (if formed) and the drain regions 16 may comprise heavily doped regions of the second conductivity type, which have a higher dopant concentration than the optional extension regions 15. The drain regions 16 may have different horizontal cross-sectional shapes in vertical cross-sectional views along vertical planes that are perpendicular to the first horizontal direction hd1 that vary as a function of a lateral distance from a most proximal one among the horizontally-extending semiconductor channels 14. The source regions (if formed) may also have different horizontal cross-sectional shapes in vertical cross-sectional views along vertical planes that are perpendicular to the first horizontal direction hd1 that vary as a function of a lateral distance from a most proximal one among the tubular-portion-containing channels 84. If the etch stop structure 8 is omitted, then a doped semiconductor region of the second conductivity type is also formed on the exposed, etched portion of the substrate 2.

At least one conductive material layer can be deposited in the remaining volumes of the bit-line via cavities 95 and the source-line via cavities 45. The at least one conductive material layer may comprise a combination of a metallic barrier material and a metallic fill material. Exemplary metallic barrier materials include TIN, TaN, WN, and/or MoN. Exemplary metallic fill materials include W, Co, Ru, Mo, Ti, Ta, Cu, etc. Excess portions of the at least one conductive material can be removed from above the horizontal plane including the top surfaces of the bit-line trench isolation structures 94 and the source trench isolation structures 44. Each remaining portion of the at least one conductive material that fills a respective source-line via cavity 45 comprises a vertical source line 46. Each vertical source line 46 located between a pair of M×(N+1) arrays of tubular-portion-containing channels 84 may contacts two vertical stacks of N tubular-portion-containing channels 84. An L×M array of vertical source lines 46 may be formed. Each remaining portion of the at least one conductive material that fills a respective bit-line via cavity 95 comprises a bit line 98. Each bit line 98 located between two neighboring M×(N+1) arrays of horizontally-extending semiconductor channels 14 contacts two vertical stacks of N drain regions 16 and may contact two overlying dummy drain regions (which are not employed as electrically active components). An L′×M array of bit lines 98 may be formed, in which the integer L′ is (L+1)/2 or L/2 or L/2+1. An L″×M array of vertical source lines 46 may be formed, in which the integer L″ is (L+1)/2 or L/2 or L/2+1.

Generally, a two-dimensional array of vertical bit lines 98 can be formed such that each of the vertical bit lines 98 contacts a set of drain regions 16 located within a respective vertical stack of unit cells UC. A two-dimensional array of vertical source lines 46 can be formed such that each of the vertical source lines 46 contacts a set of source regions (if present) or channels 84 located within a respective vertical stack of unit cells UC.

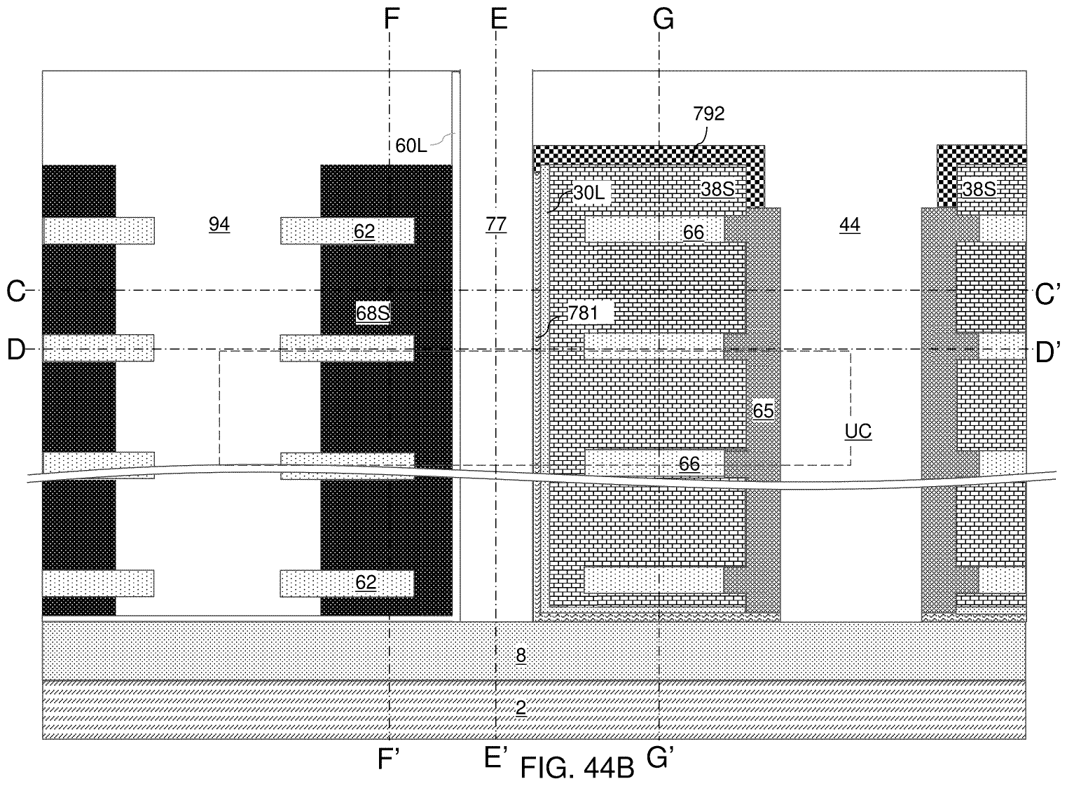

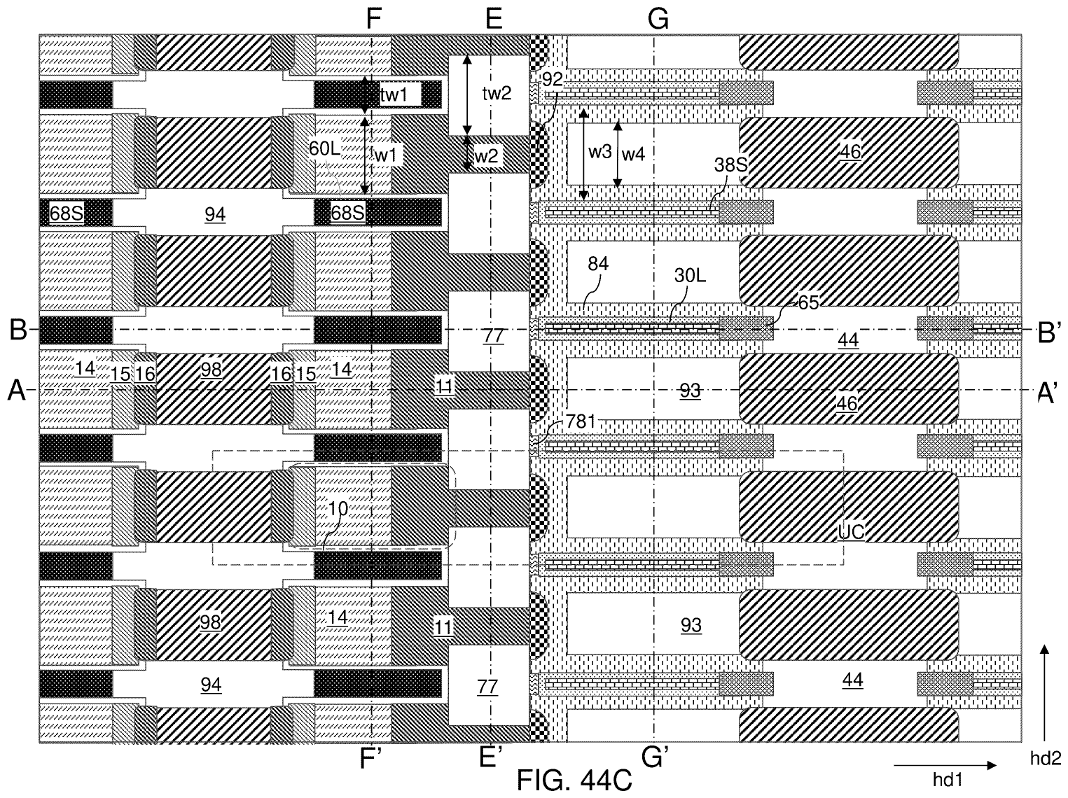

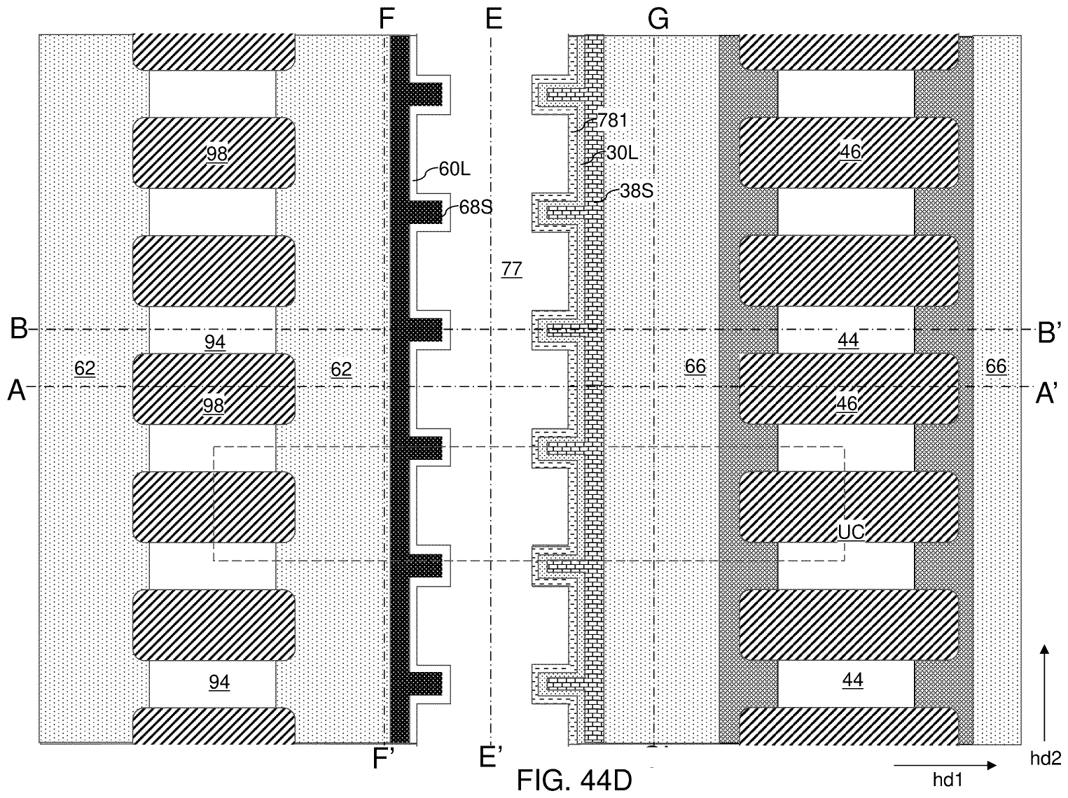

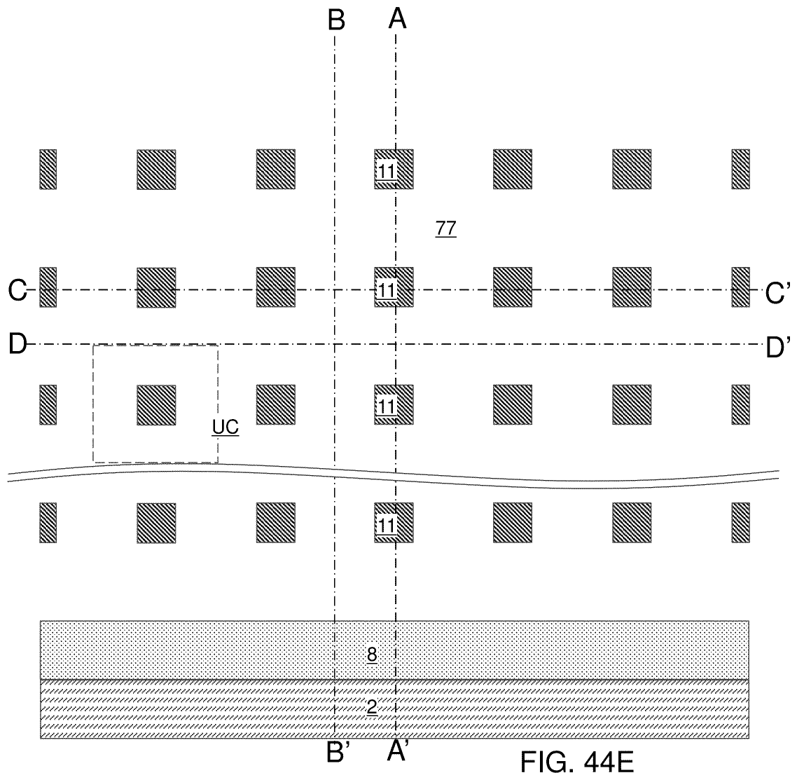

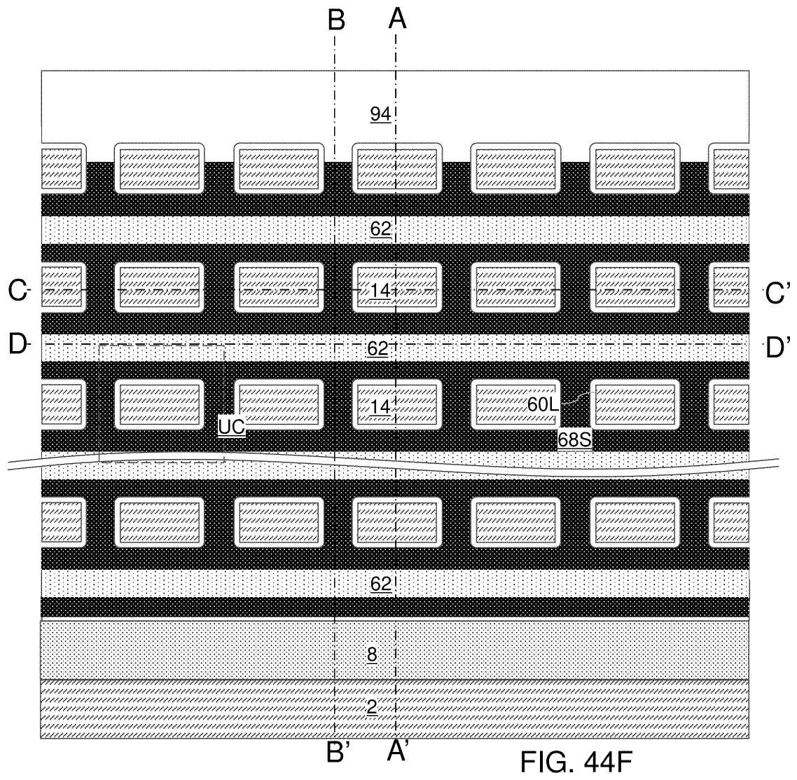

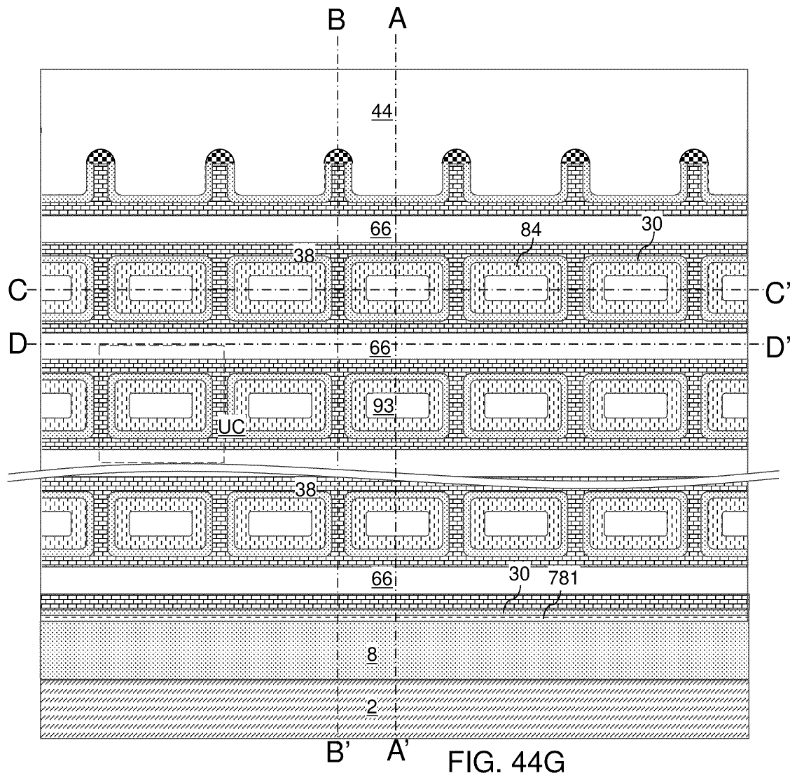

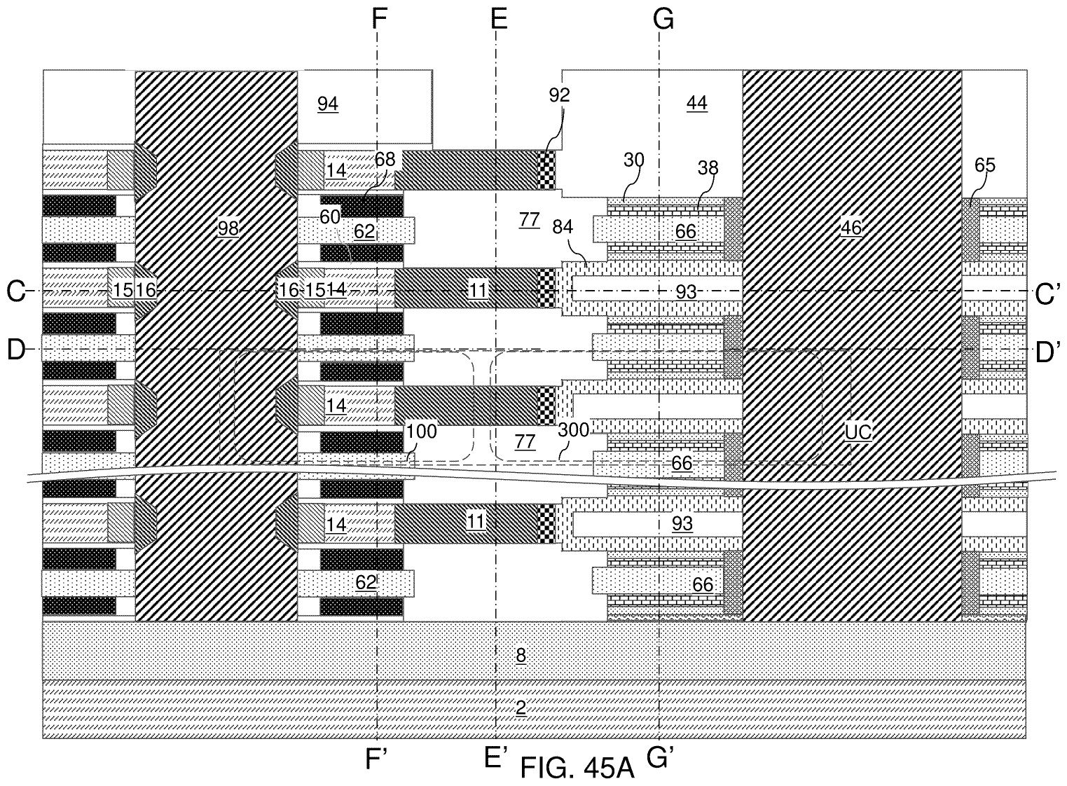

Referring to FIGS. 44A, 44B, 44C, 44D, 44E, 44F, and 44G, a selective isotropic etch process can be performed to isotropically etch the material of the one-dimensional array of sacrificial perforated wall structures 71. For example, if the sacrificial perforated wall structures 71 comprise silicon nitride, a wet etch process employing hot phosphoric acid may be performed to remove the sacrificial perforated wall structures 71 selectively to the materials of the bit-line trench isolation structures 94, the source trench isolation structures 44, the vertical bit lines 98, the vertical source lines 46, the doped semiconductor material portions 11, the metallic material portions 92, the etch-stop layer 781, and the first gate dielectric material layers 60L (or the first gate electrode material layers 68S). A one-dimensional array of the bridges-encircling cavities 77 is formed by removing the one-dimensional array of sacrificial perforated wall structures 71. Each M×(N+1) two-dimensional array of doped semiconductor material portions 11 arranged along directions that are perpendicular to the first horizontal direction hd1 is exposed to a respective one of the bridges-encircling cavities 77. The lateral distance between inner sidewalls of each tubular-portion-containing channel 84 is herein referred to as a fourth width w4, which may be less than the first width w1 and greater than the second width w2, as shown in FIG. 44C.

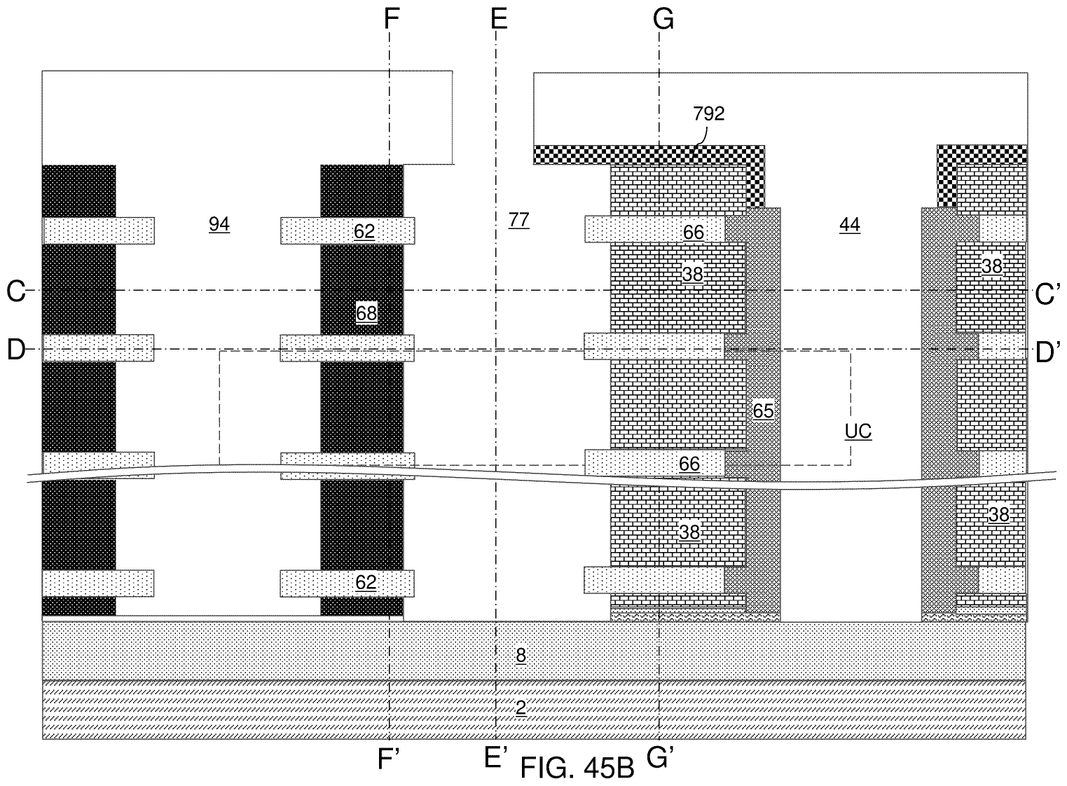

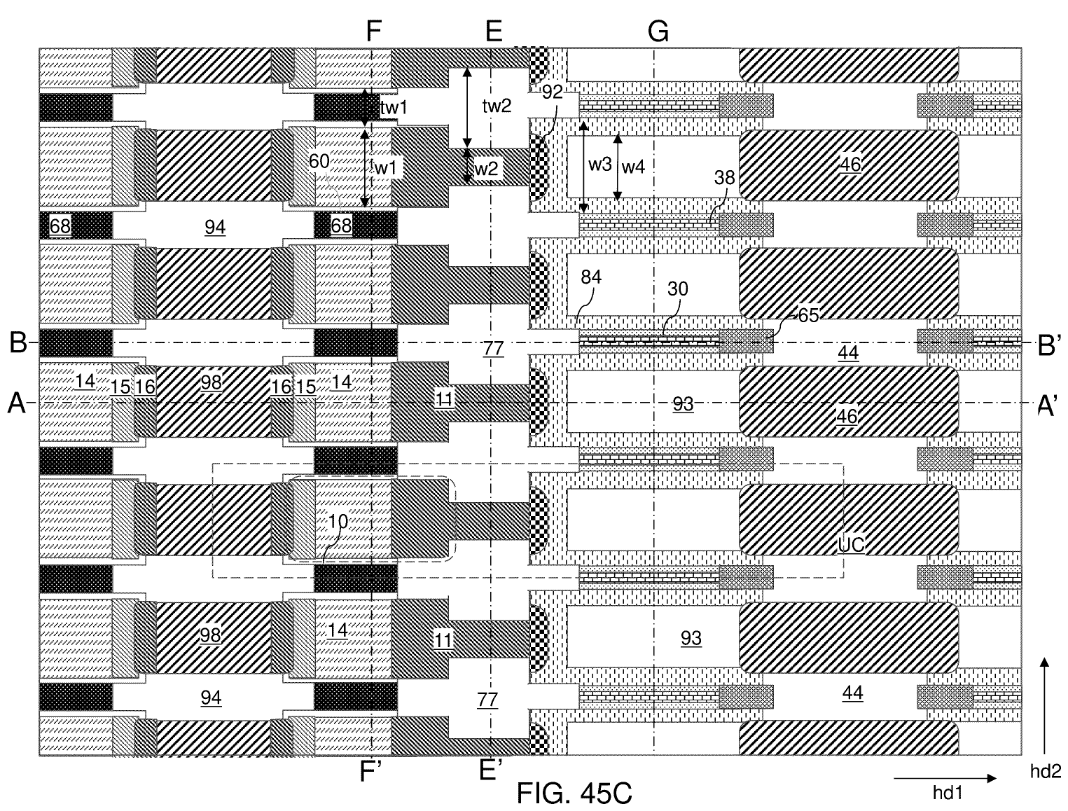

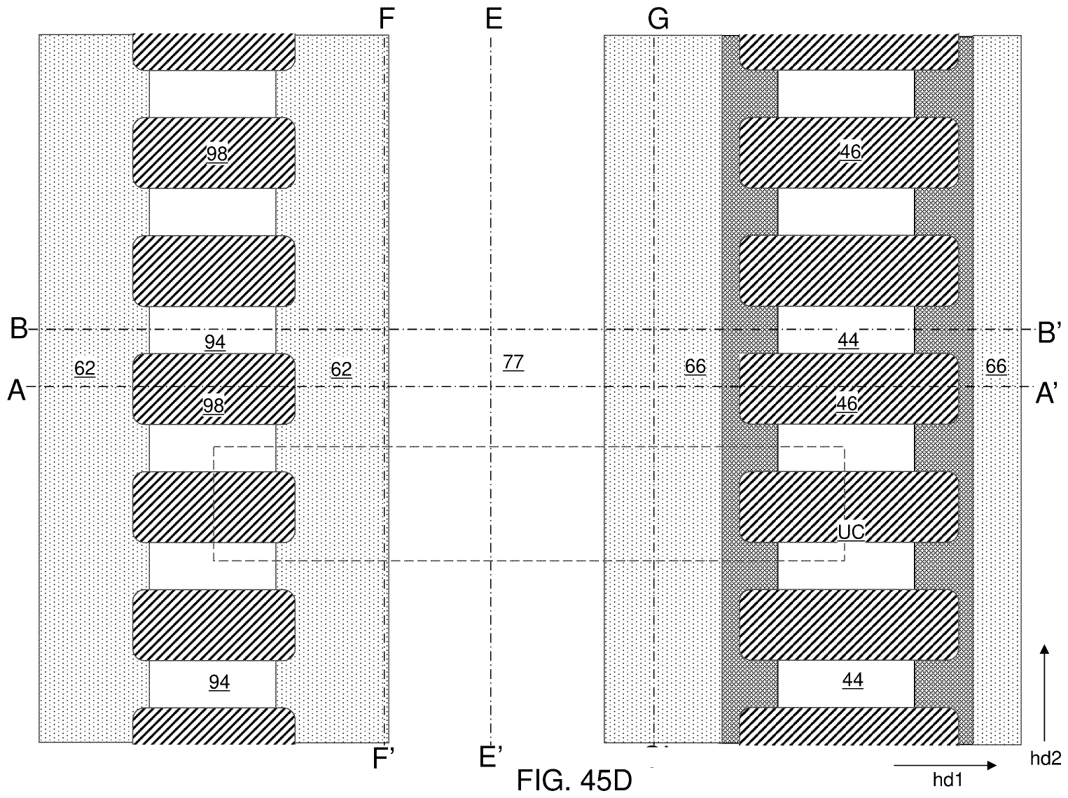

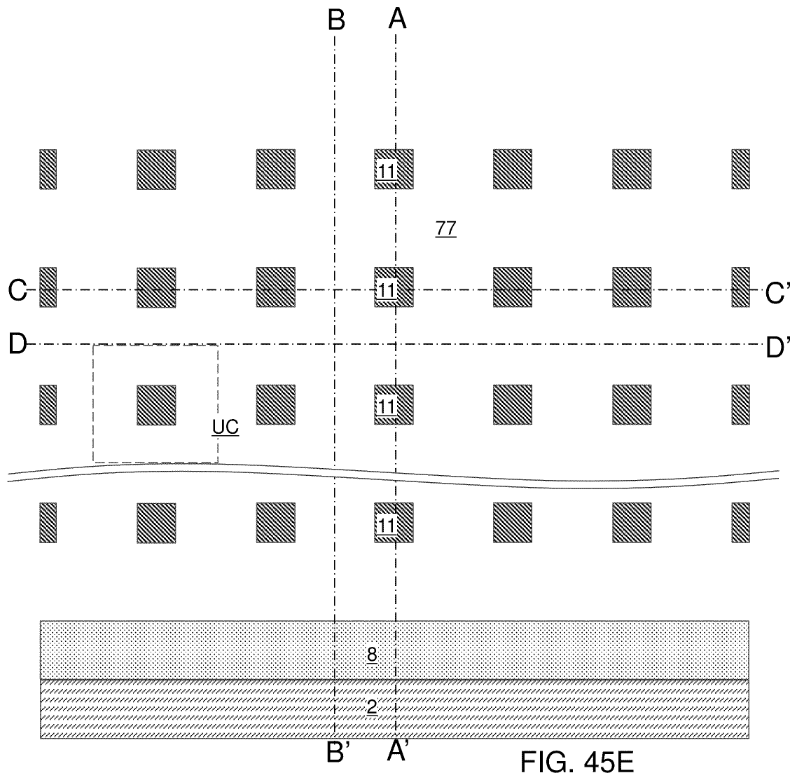

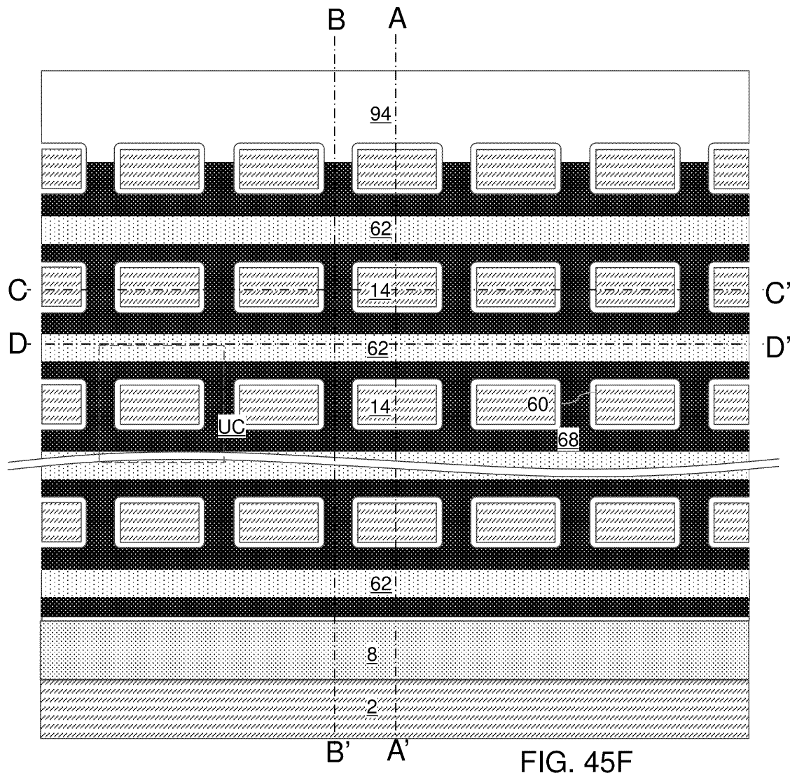

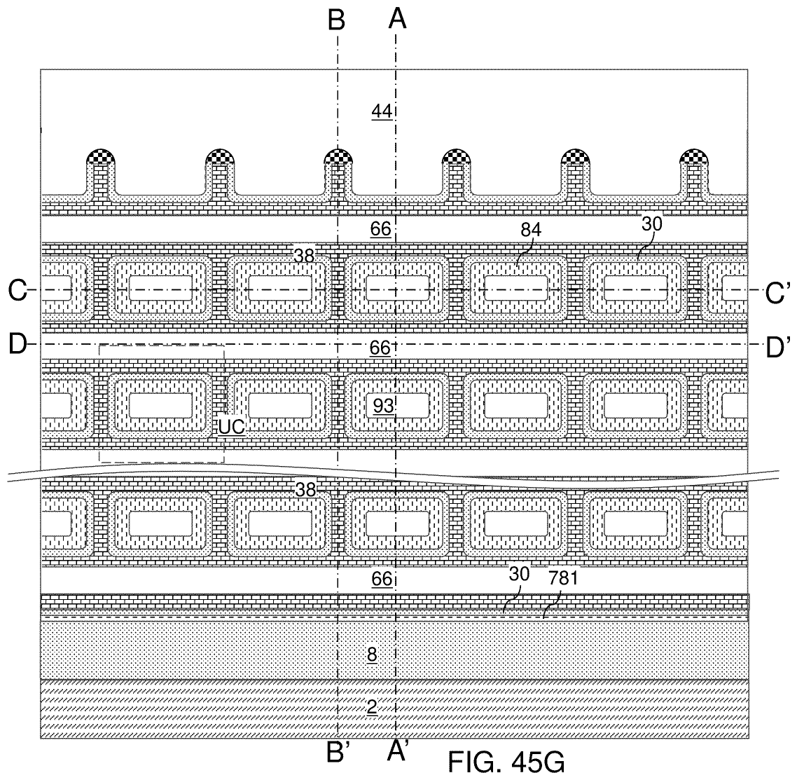

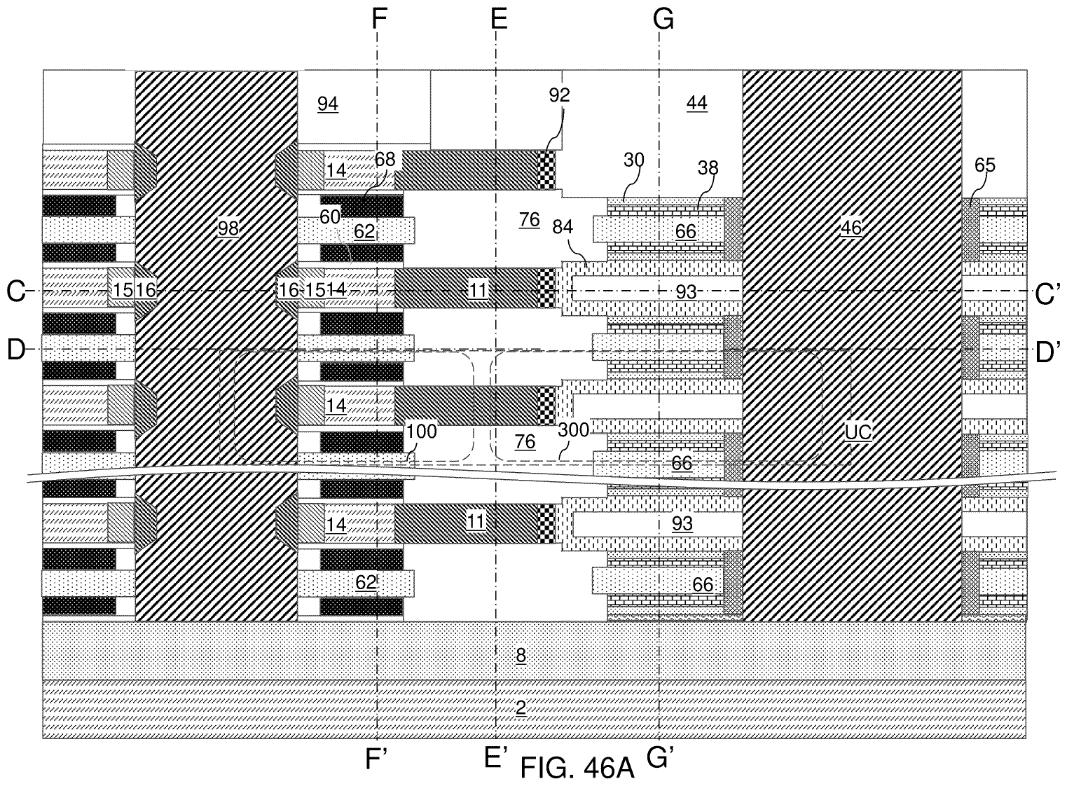

Referring to FIGS. 45A, 45B, 45C, 45D, 45E, 45F, and 45G, a first isotropic etch process can be performed to isotropically etch physically exposed portions of the etch-stop layer 781. The first isotropic etch process can etch the physically exposed portions of the etch-stop layer 781 selectively to the materials of the bit-line trench isolation structures 94, the source trench isolation structures 44, and optionally selectively to the material of the first gate dielectric material layers 60L. The first isotropic etch process may be selective to the material of the doped semiconductor material portions 11, or may collaterally recess the material of the doped semiconductor material portions 11. Vertically extending portions of the etch-stop layer 781 located around the bridges-encircling cavities 77 can be removed, and vertically-extending sidewalls of the second gate dielectric material layers 30L can be physically exposed.

Subsequently, a second isotropic etch process can be performed to isotropically etch physically exposed portions of the first gate dielectric material and the second gate dielectric material around the one-dimensional array of bridges-encircling cavities 77. The second isotropic etch process can isotropically etch the materials of the first gate dielectric material layers 60L and the second gate dielectric material layers 30L selectively to the materials of the doped semiconductor material portions 11, the first gate electrode material layers 68S, and the second gate electrode material layers 38S. Each first gate dielectric material layer 60L can be divided into an M×(N+1) two-dimensional array of first gate dielectrics 60 each having a respective tubular configuration and laterally surrounding a respective horizontally-extending semiconductor channel 14. Each second gate dielectric material layer 30L can be divided into an M×(N+1) two-dimensional array of second gate dielectrics 30 each having a respective tubular configuration and laterally surrounding a respective tubular-portion-containing channel 84. Thus, remaining portions of the first gate dielectric material comprise a three-dimensional array of first gate dielectrics 60, and remaining portions of the second gate dielectric material comprise a three-dimensional array of second gate dielectrics 30.

A third isotropic etch process can be performed to isotropically etch physically exposed portions of the first gate electrode material and the second gate electrode material around the one-dimensional array of bridges-encircling cavities 77. The third isotropic etch process can isotropically etch the materials of the first gate electrode material layers 68S and the second gate electrode material layers 38S selectively to the materials of the vertical bit lines 98, the vertical source lines 46, the semiconductor rails (15, 14, 11, 34), the first gate dielectrics 60, and the second gate dielectrics 30. Each first gate electrode material layer 68S can be divided into N first word lines 68, a bottom first dummy word line, and a top first dummy word line. Each first word line 68 laterally surrounds a respective set of M first gate dielectrics 60, and thus, comprises M first gate electrodes of M first field effect transistors. Each second gate electrode material layer 38S can be divided into N second word lines 38, a bottom second dummy word line, and a top second dummy word line. Each second word line 38 laterally surrounds a respective set of M second gate dielectrics 30, and thus, comprises M second gate electrodes of M second field effect transistors. Thus, remaining portions of the first gate electrode material comprise a two-dimensional array of first word lines 68, and remaining portions of the second gate electrode material comprise a two-dimensional array of second word lines 38.

Generally, at least one isotropic etchant that etches a respective material among the first gate electrode material, the second gate electrode material, the first gate dielectric material, and the second gate dielectric material can be introduced into the bridges-encircling cavities 77. The first gate electrode material, the second gate electrode material, the first gate dielectric material, and the second gate dielectric material can be patterned by the at least one isotropic etchant. Patterned portions of the first gate electrode material comprise first word lines 68, patterned portions of the second gate electrode material comprise second word lines 38, patterned portions of the first gate dielectric material comprise first gate dielectrics 60, and patterned portions of the second gate dielectric material comprise second gate dielectrics 30.

The second exemplary structure may comprise an L×M×N three-dimensional array of unit cells UC. In one embodiment, each of the unit cells UC comprises: an access field effect transistor 100 comprising a horizontally-extending semiconductor channel 14, a first gate dielectric 60, and a first gate electrode (comprising a portion of a first word line 68); and a memory field effect transistor 300 comprising a tubular-portion-containing channel 84, a second gate dielectric 30, and a second gate electrode (comprising a portion of a second word line 38). The second gate dielectric 30 comprises a memory dielectric material having at least two programmable states.

In the second embodiment, the tubular-portion-containing channel 84 surrounds a core structure (which comprises a dielectric core structure 93 in the second embodiment) which comprises a dielectric material. In one embodiment, each of the unit cells UC comprises a doped semiconductor material portion 11 located between the horizontally-extending semiconductor channel 14 and the core structure 93.

In one embodiment, each of the unit cells UC comprises a metallic material portion 92 in contact with the doped semiconductor material portion 11 located between the horizontally-extending semiconductor channel 14 and the tubular-portion-containing channel 84. In one embodiment, the metallic material portion 92 contacts an end surface of the doped semiconductor material portion 11 and an end surface of the tubular-portion-containing channel 84. In one embodiment, the metallic material portion 92 has a different material composition than the second gate electrode (which comprises a portion of a second word line 38).

In one embodiment, the horizontally-extending semiconductor channel 14 and the tubular-portion-containing channel 84 laterally extend along a first horizontal direction hd1; the horizontally-extending semiconductor channel 14 has a first width w1 along a second horizontal direction hd2 that is perpendicular to the first horizontal direction hd1; and a width of the tubular-portion-containing channel 84 along the second horizontal direction hd2 is greater than the first width w1.

In one embodiment, each of the unit cells UC comprises a doped semiconductor material portion 11 that comprises: a first end portion in contact with the horizontally-extending semiconductor channel 14 and having the first width w1; a second end portion that is laterally spaced from the first end portion toward the tubular-portion-containing channel 84 and having the first width w1; and a neck portion located between the first end portion and the second end portion and having a second width w2 that is less than the first width w1.

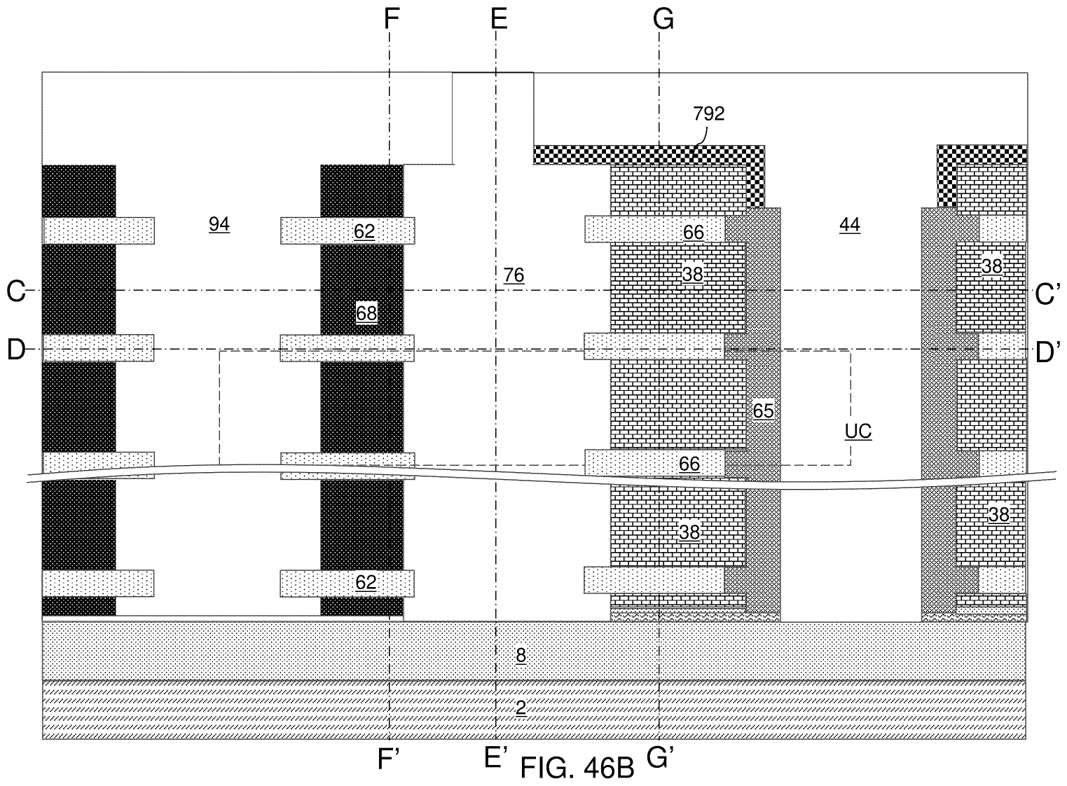

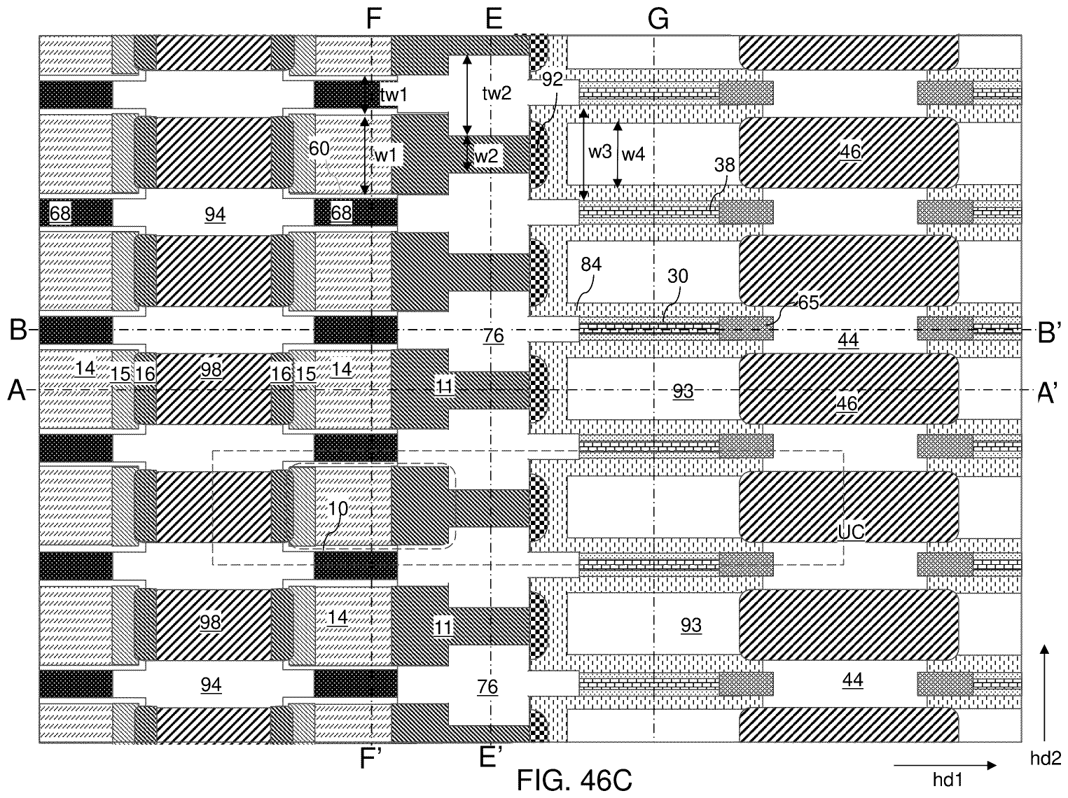

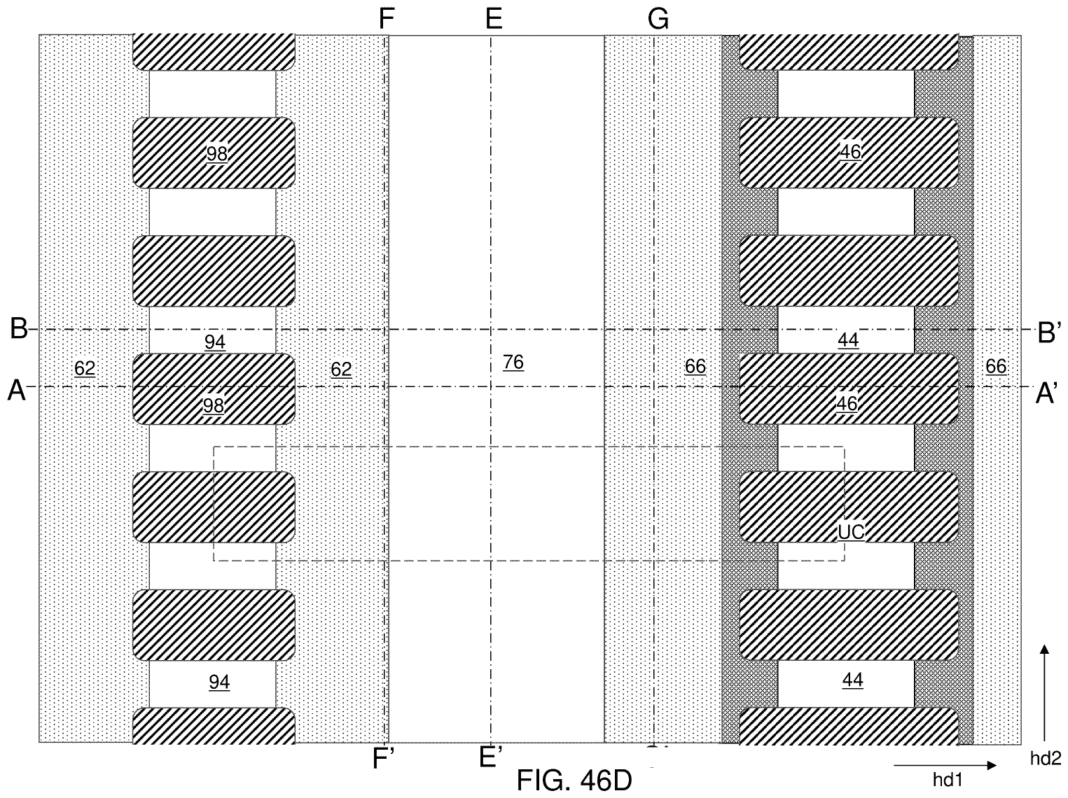

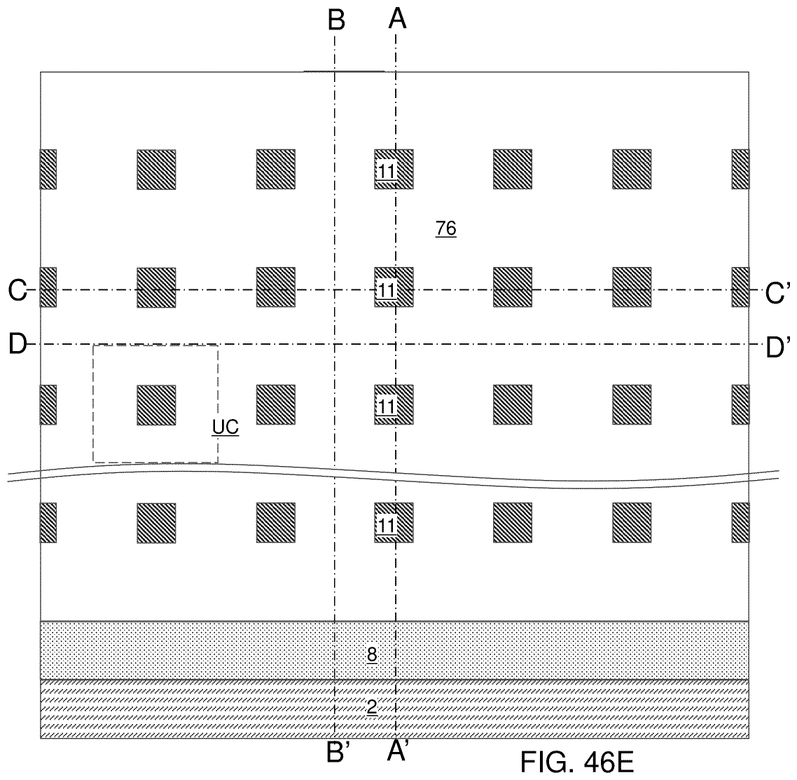

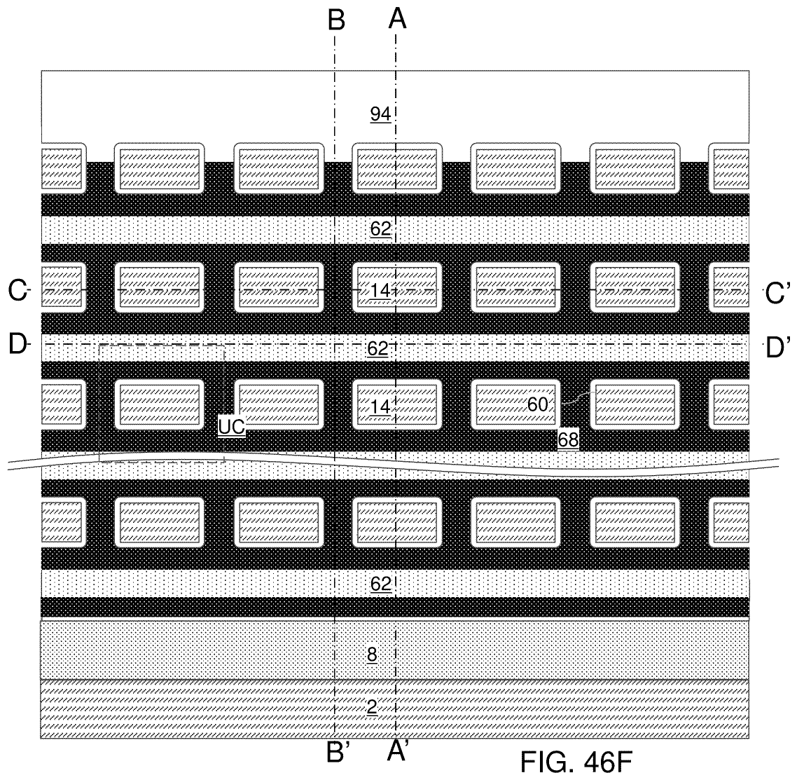

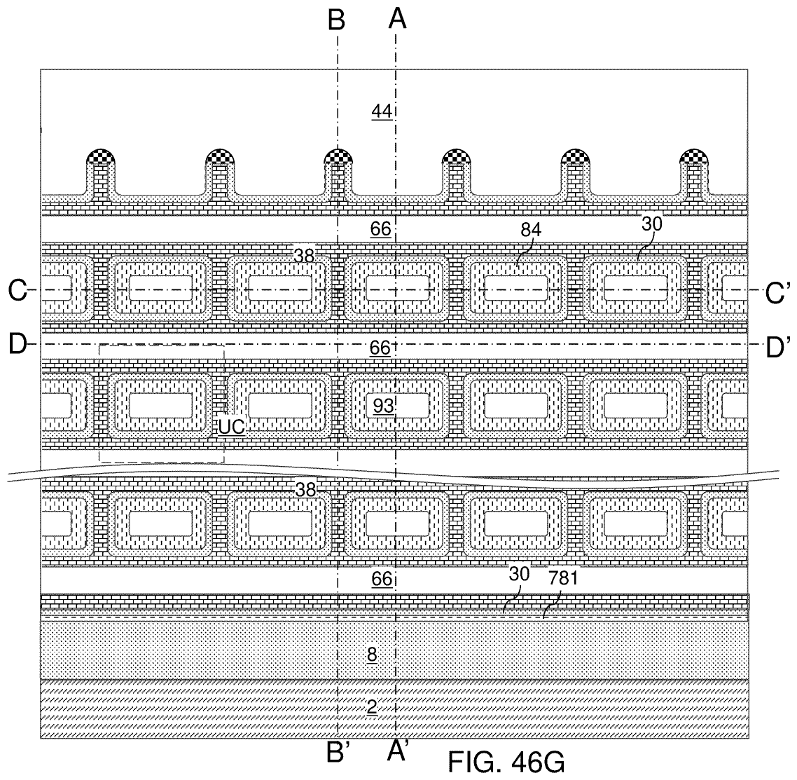

Referring to FIGS. 46A, 46B, 46C, 46D, 46E, 46F, and 46G, a dielectric fill material such as silicon oxide may be conformally deposited in the bridges-encircling cavities 77. Excess portions of the dielectric fill material can be removed from above the horizontal plane including top surfaces of the bit-line trench isolation structures 94 and the source trench isolation structures 44 by performing a planarization process, which may comprise a chemical mechanical polishing process or a recess etch process. A one-dimensional array of perforated dielectric walls 76 can be formed in the bridges-encircling cavities 77. The one-dimensional array of perforated dielectric walls 76 can be arranged along the first horizontal direction hd1. Each perforated dielectric wall 76 within the one-dimensional array of perforated dielectric walls 76 surrounds a respective two-dimensional array of doped semiconductor material portions 11.

In one embodiment, each perforated dielectric wall 76 within the one-dimensional array of perforated dielectric walls 76 contacts a respective two-dimensional array of first gate electrodes (comprising portions of a vertical stack of first word lines 68), and contacts a respective two-dimensional array of second gate electrodes (comprising portions of a vertical stack of second word lines 38). In one embodiment, each perforated dielectric wall 76 within the one-dimensional array of perforated dielectric walls 76 contacts a respective two-dimensional array of first gate dielectrics 60, and contacts a respective two-dimensional array of second gate dielectrics 30.

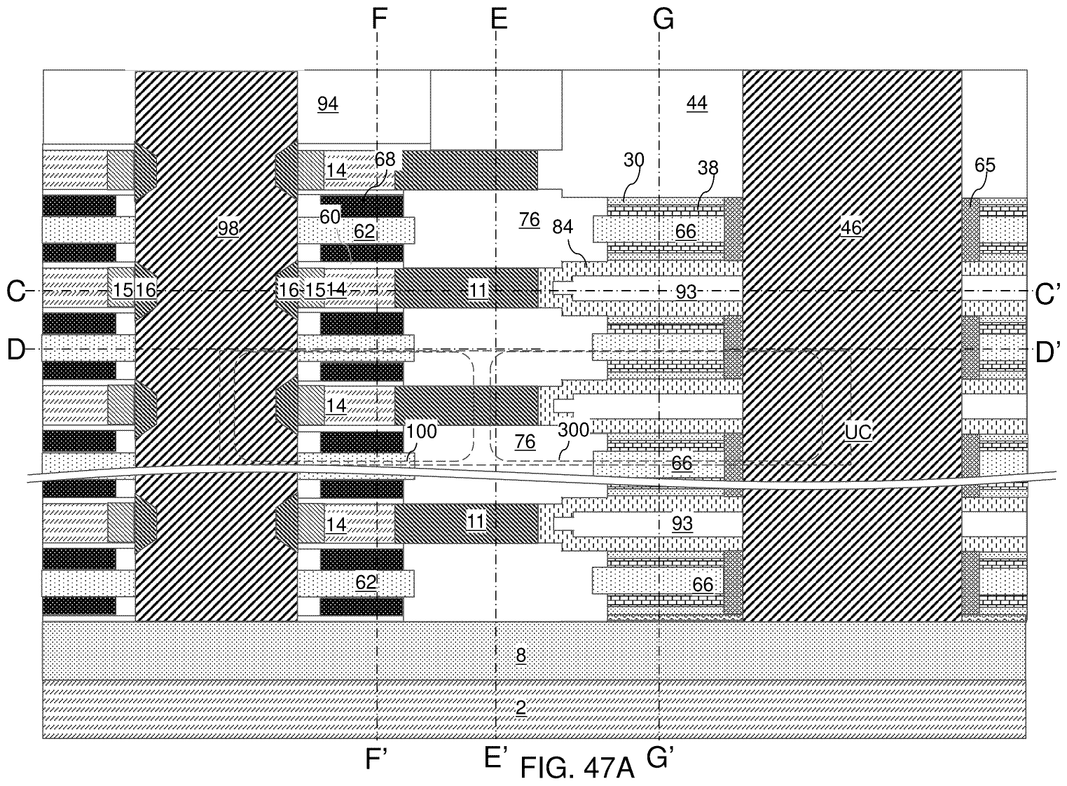

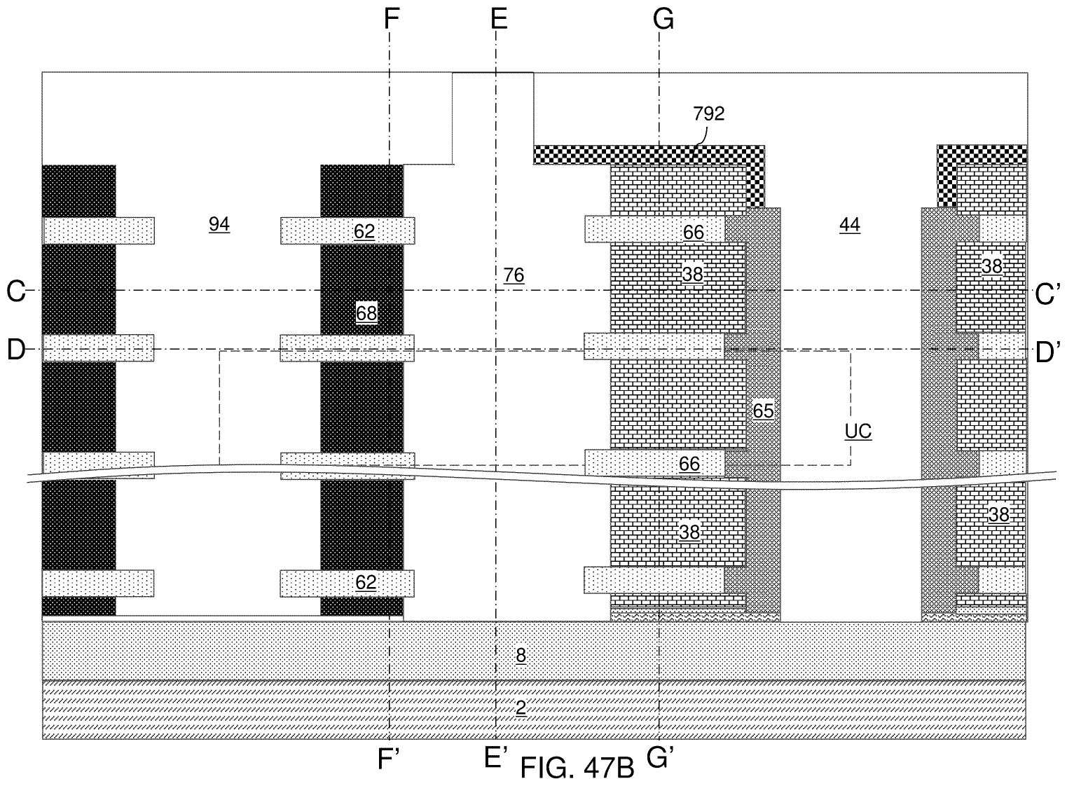

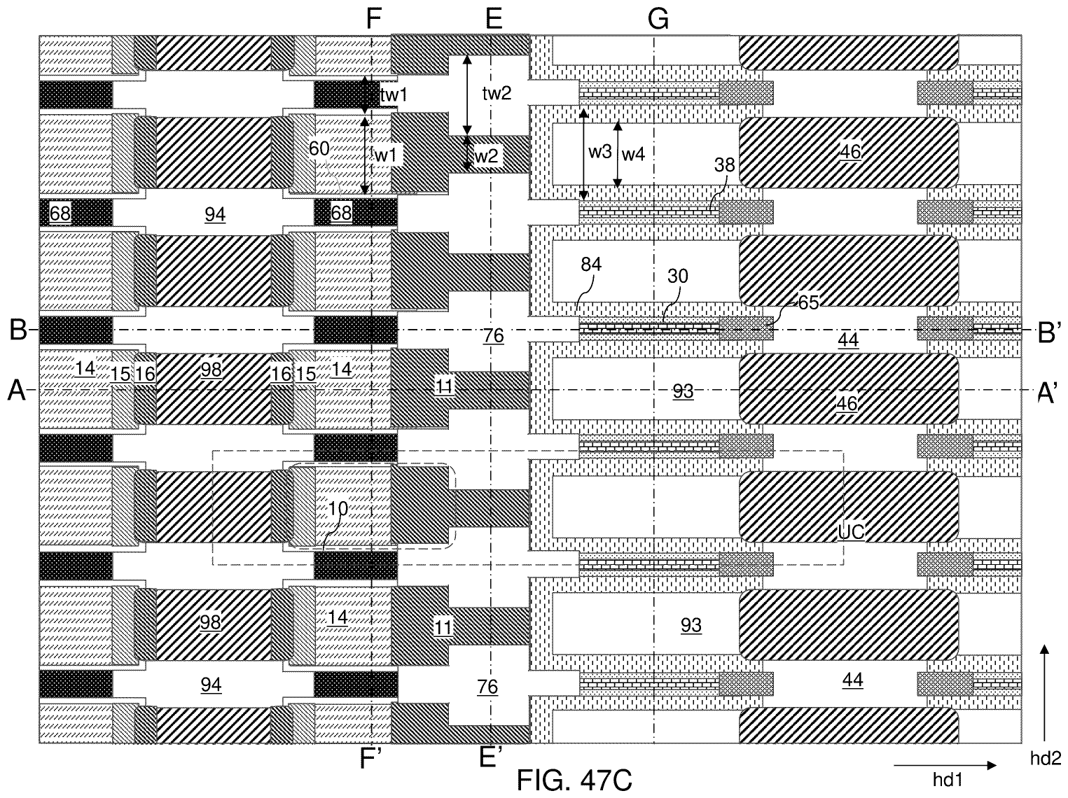

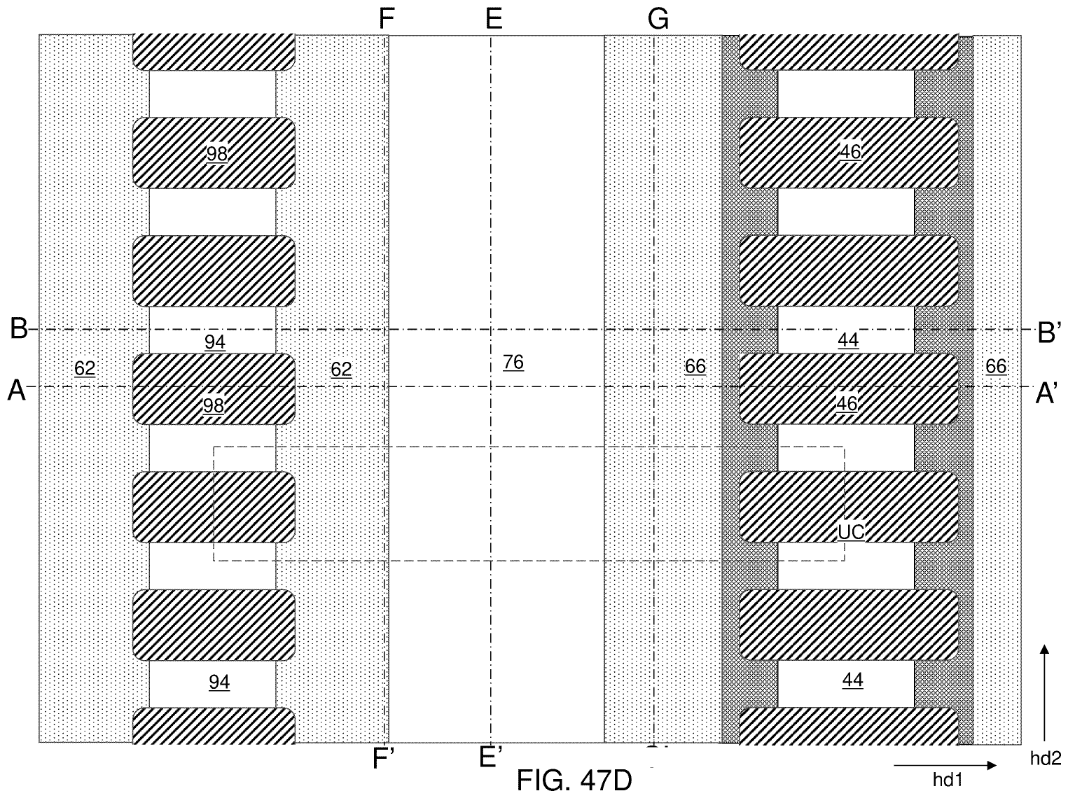

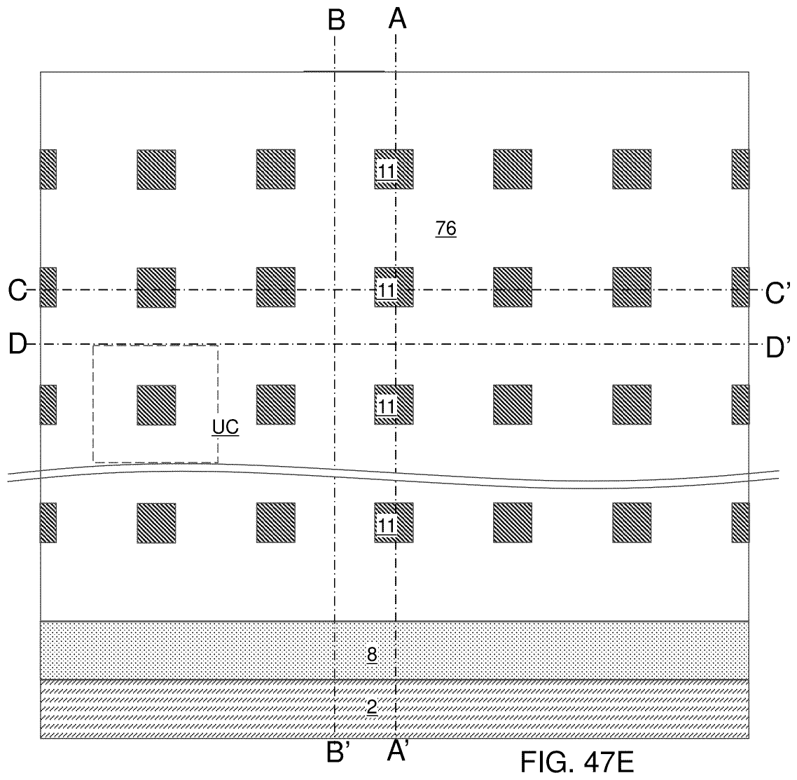

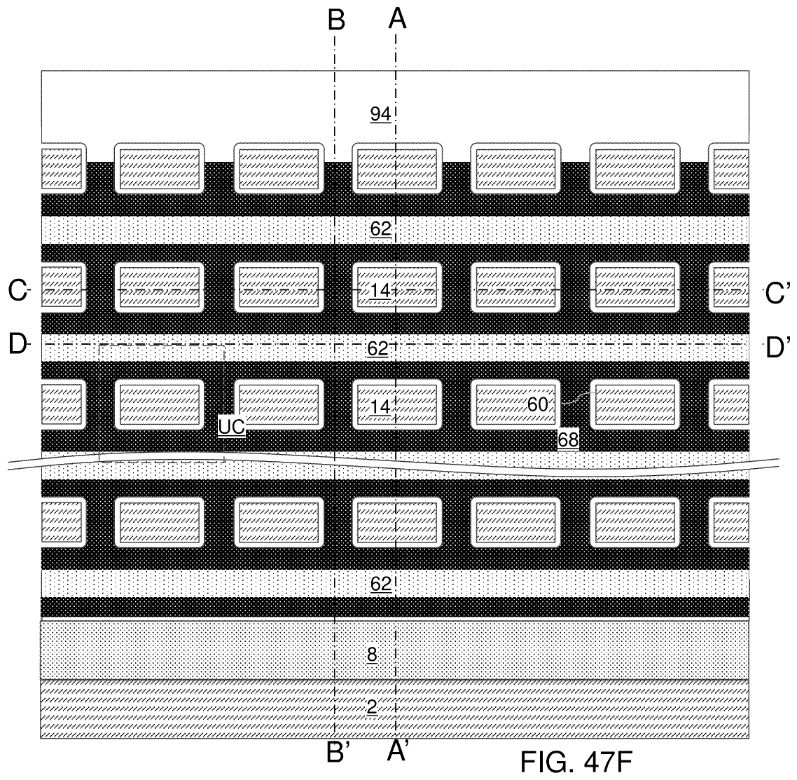

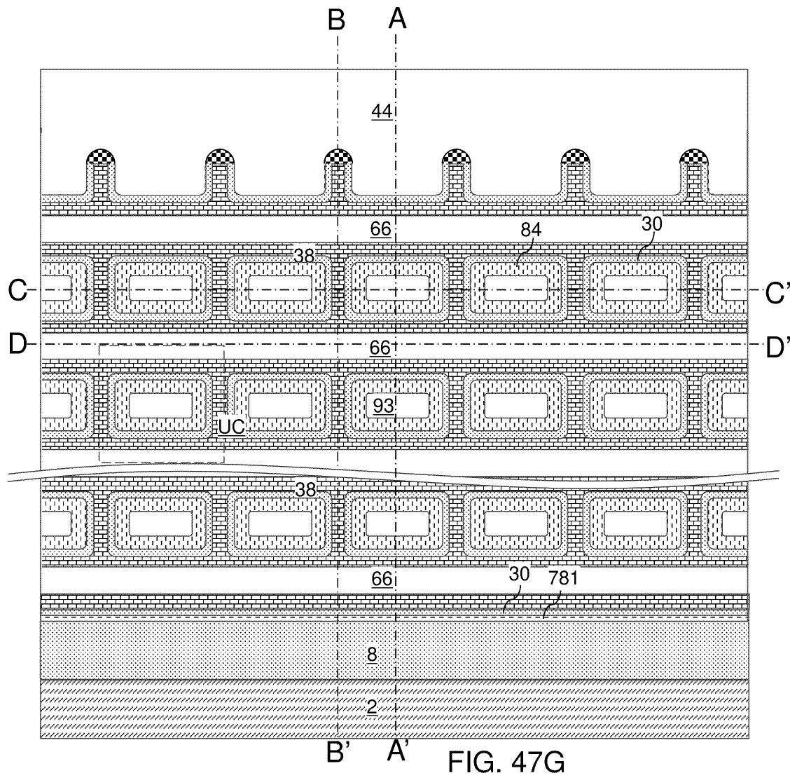

Referring to FIGS. 47A, 47B, 47C, 47D, 47E, 47F, and 47G, a first alternative configuration of the second exemplary structure may be derived from the second exemplary structure by omitting formation of the metallic material portions 92.

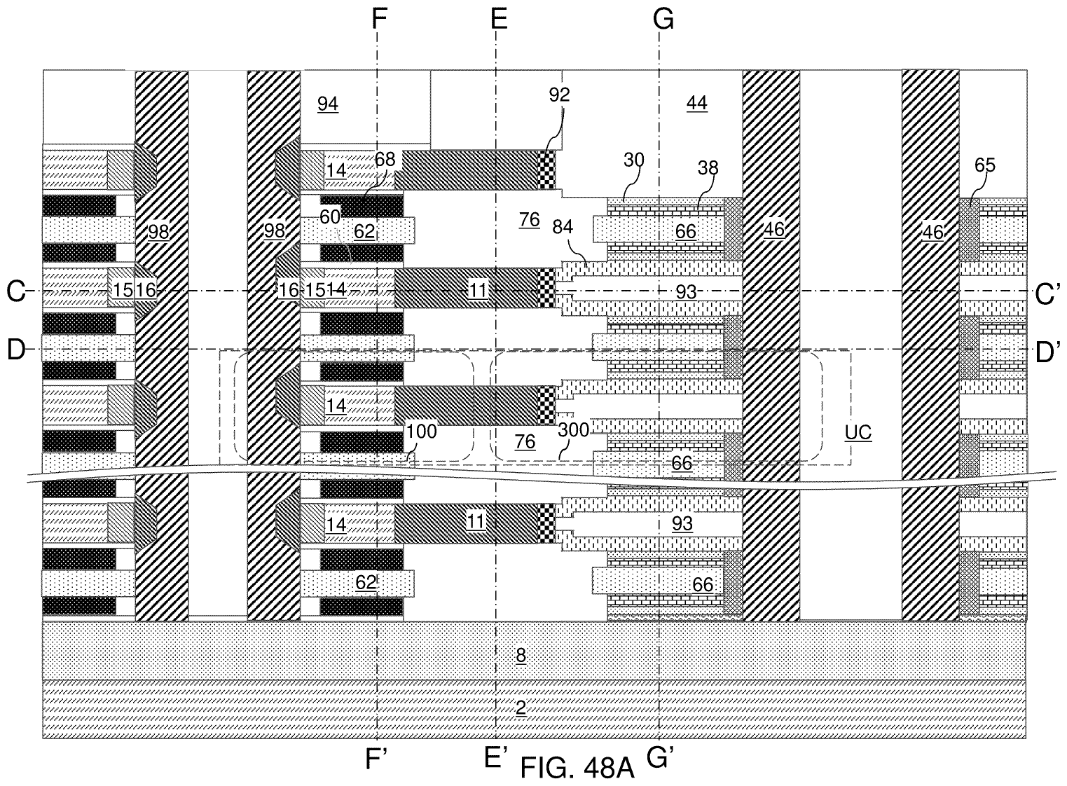

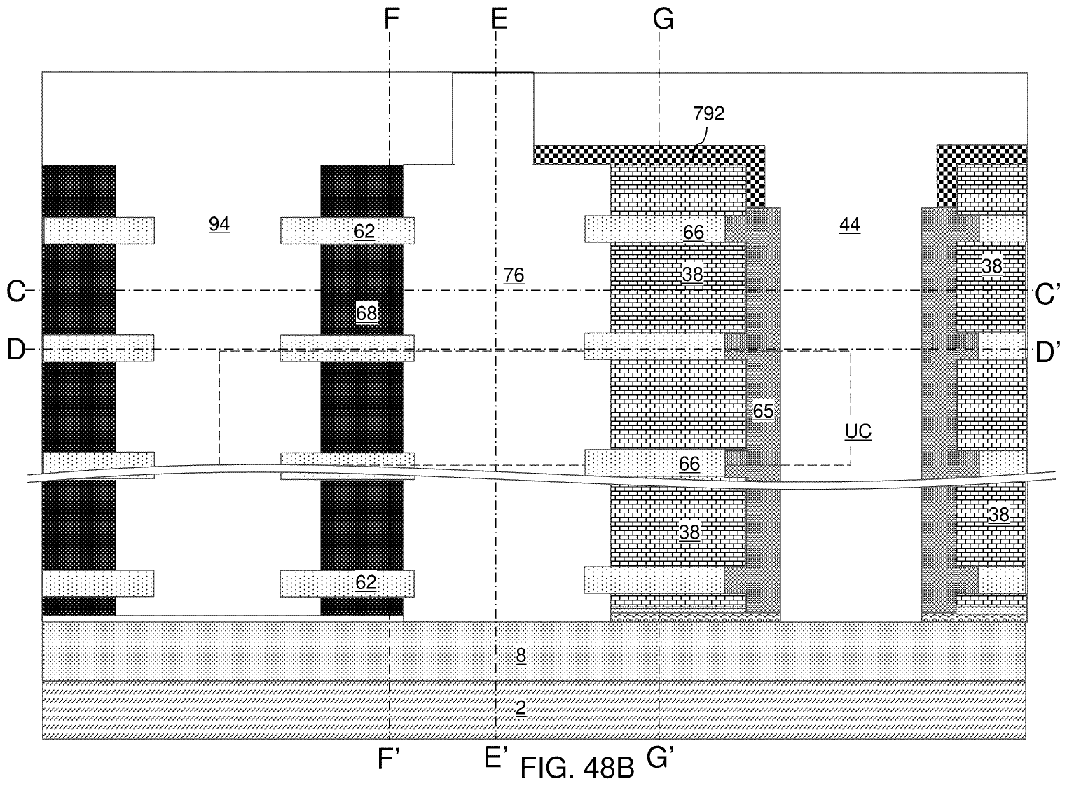

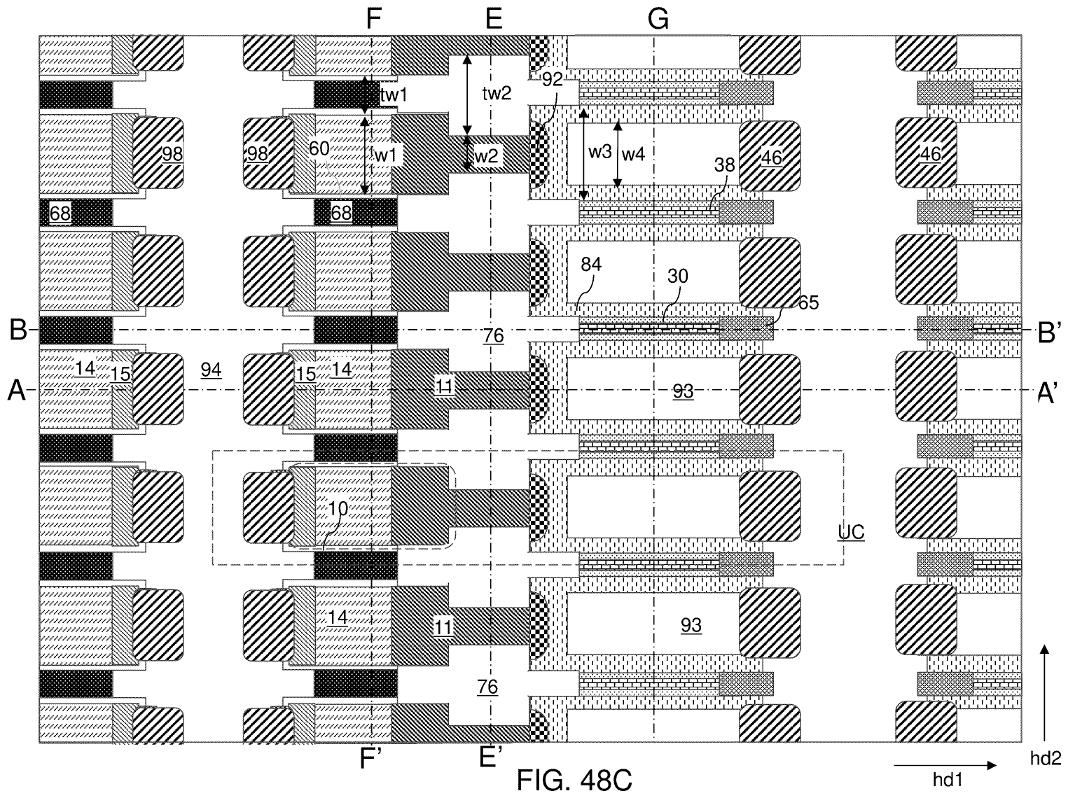

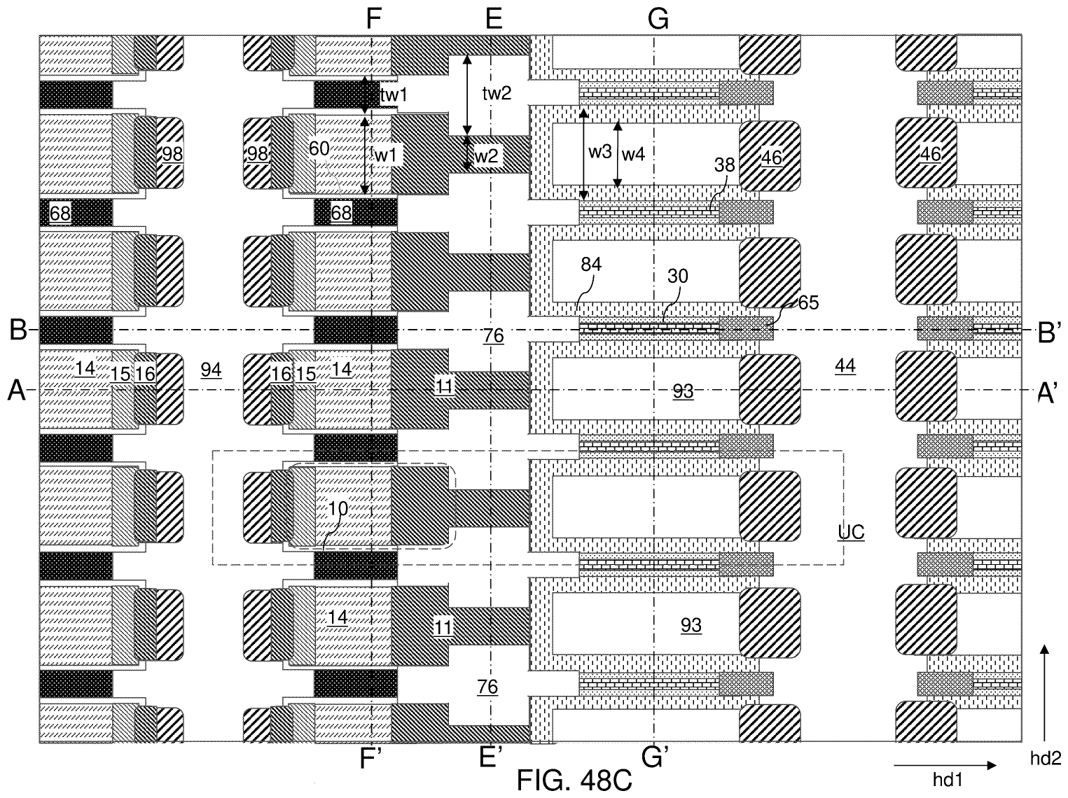

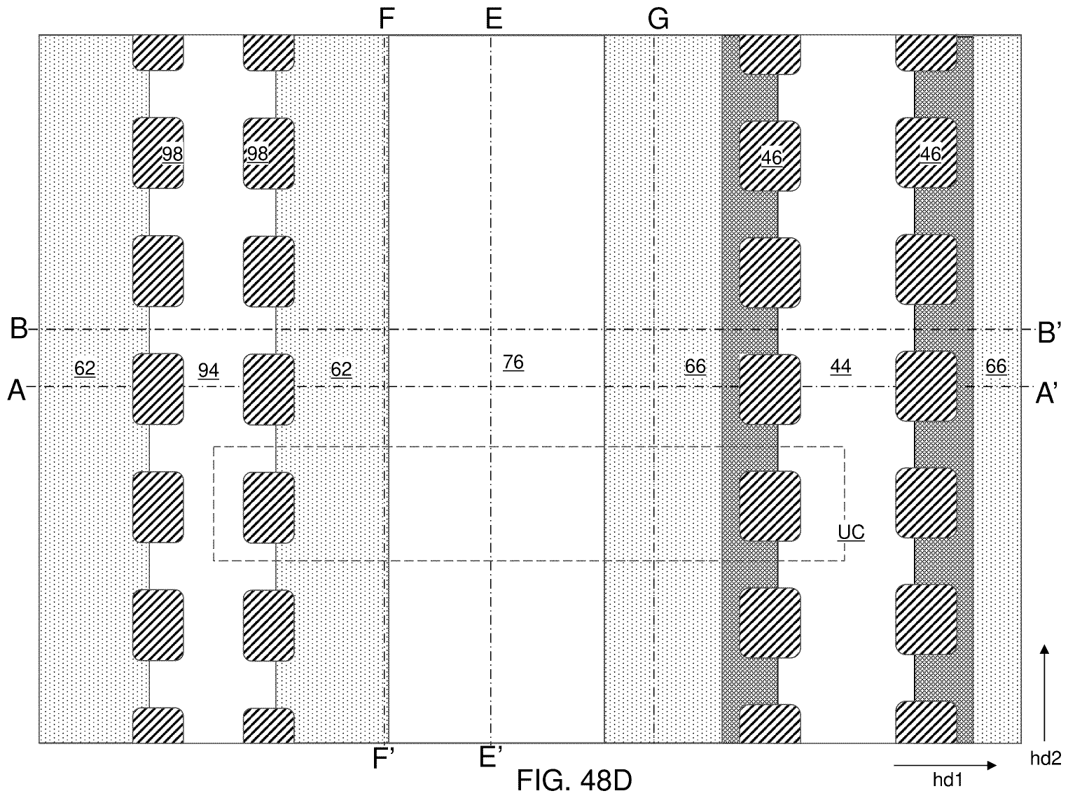

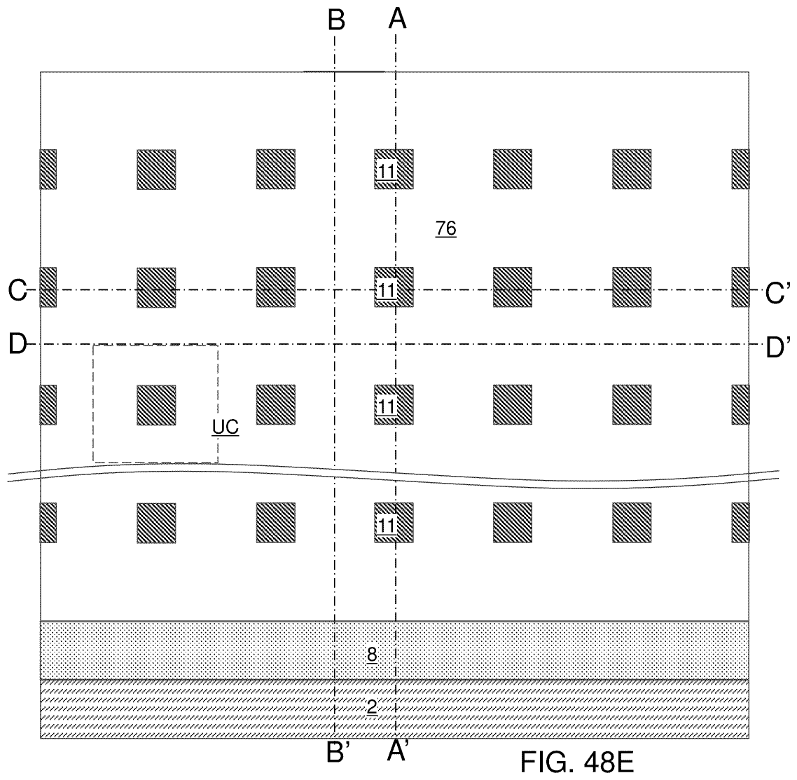

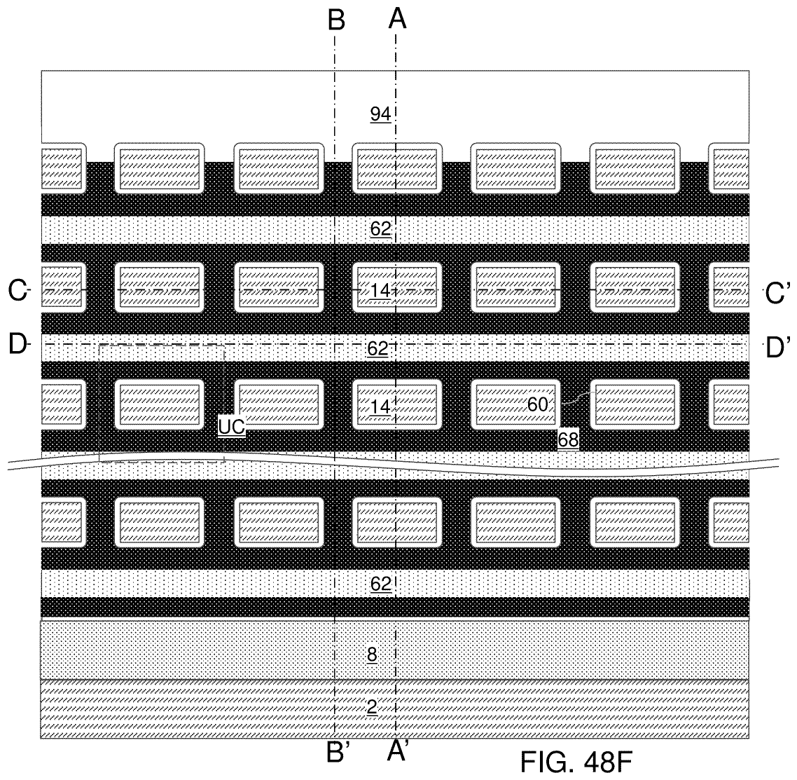

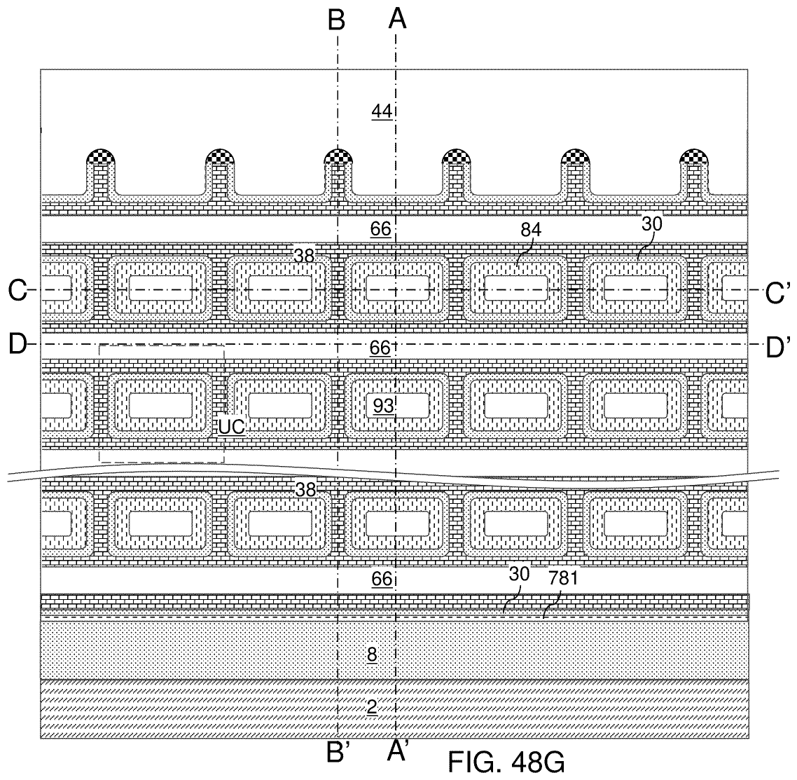

Referring to FIGS. 48A, 48B, 48C, 48D, 48E, 48F, and 48G, a second alternative configuration of the second exemplary structure may be derived from the second exemplary structure by merging neighboring pairs of vertical bit lines 98 that are located within a same bit-line trench 99 and spaced from each other along the first horizontal direction hd1, and/or by merging neighboring pairs of vertical source lines 46 that are located within a same source trench 49 and spaced from each other along the first horizontal direction hd1. A similar configuration may be provided for the first exemplary structure.

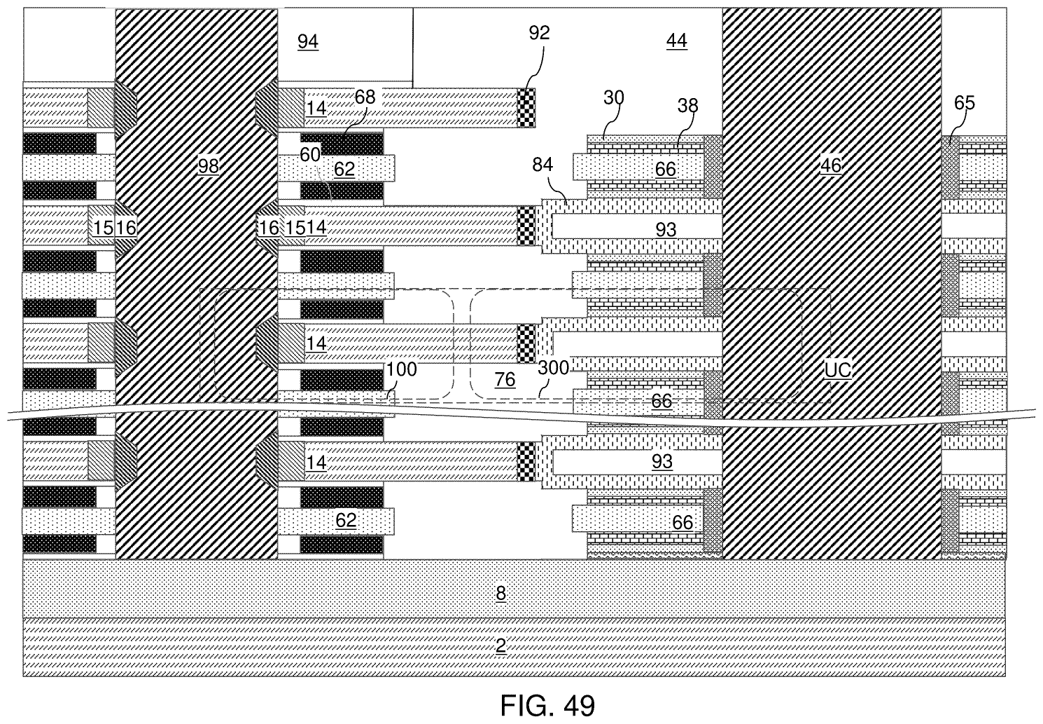

Referring to FIG. 49, a third alternative configuration of the second exemplary structure can be derived from the first exemplary structure of FIG. 46A by omitting formation of the doped semiconductor material portions 11.

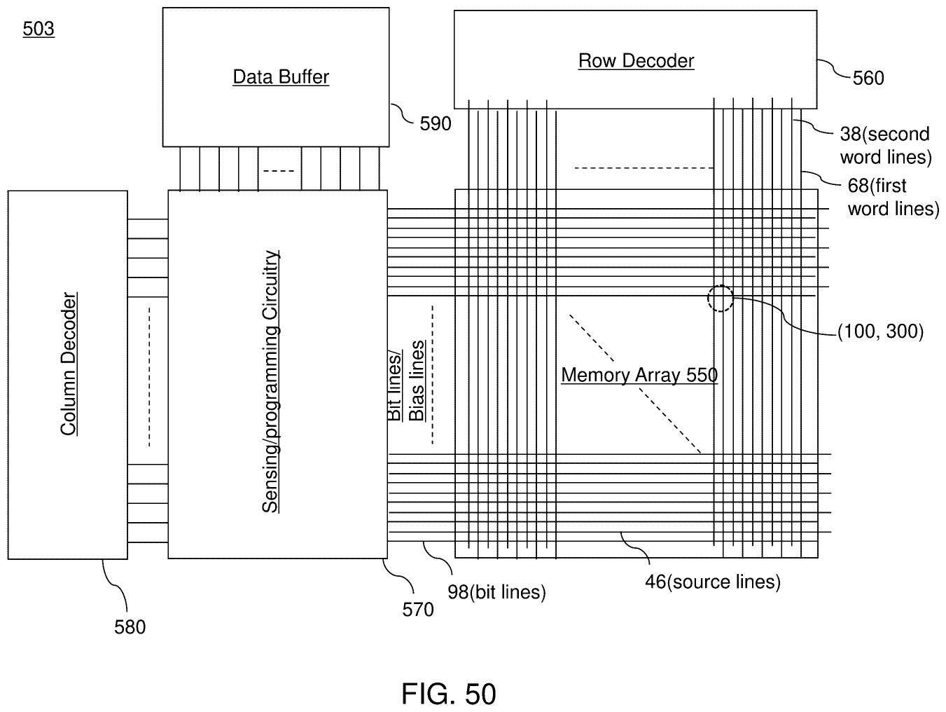

Referring to FIG. 50, a schematic circuit diagram of an exemplary circuit is illustrated, which may be employed to implement a three-dimensional memory device including the first exemplary structure or the second exemplary structure comprising the memory field effect transistors 300. The third exemplary circuit may comprise a first random access memory (RAM) device 503 including a three-dimensional array, such as a three-dimensional L×M×N array, of the integrated memory cells (100, 300) in the first exemplary structure or the second exemplary structure. Each unit cell UC in the second exemplary structure comprises an integrated memory cell (100, 300) including an access field effect transistor 100 and a memory field effect transistor 300. Each memory field effect transistor 300 is electrically accessible through the access field effect transistor 100 within a respective integrated memory cell (100, 300). Each access field effect transistor 100 can be activated only when the bit line 98 and the first word line 68 that are connected to the access field effect transistor are activated. Each memory field effect transistor 300 can be programmed by activating the access field effect transistor within the same integrated memory cell (100, 300), and by electrically biasing a respective second gate electrode (which is portion of a respective second word line 38) and a respective vertical source line 46. In one embodiment, the RAM device 502 includes a memory array region 550 including first word lines 68, second word lines 38, bit lines 98, and vertical source lines 46. In an illustrative example, the first RAM device 503 may contain a row decoder 560 connected to the first word lines 68 and to the second word lines 38, and a sensing/programming circuitry 570 connected to the bit lines 98 and the vertical source lines 46. Each pair of a bit line 98 and a vertical source line 46 that are connected to a vertical stack of N semiconductor rails 10 may be individually activated. A column decoder 580 and a data buffer 590 can be connected to the sensing/programming circuitry 570.

The three-dimensional memory array of the embodiments of the present disclosure may be located in various dies or bonded assemblies. FIGS. 51-56 illustrate non-limiting examples of die configurations that may be employed for the three-dimensional array of memory elements of the various embodiments of the present disclosure.

Referring to FIG. 51, the three-dimensional memory array 550 may be provided within a memory die 900 over a substrate 2. Upper-level metal interconnect structures 980 embedded within upper-level dielectric material layers 960 may be formed over the three-dimensional array 550, and memory-side bonding pads 988 may be formed at the top level of the upper-level dielectric material layers 960. A logic die 700 is provided, which comprises a logic-die substrate 702, a control circuit 720 including semiconductor devices configured to control operation of the three-dimensional memory array 550, logic-side metal interconnect structures 780 embedded within logic-side dielectric material layers 760, and logic-side bonding pads 788 electrically connected to a respective subset of the logic-side metal interconnect structures 780. The control circuit 720 may comprise various CMOS circuits. The memory die 900 can be bonded to the logic die 700 through bonding between mating pairs of a memory-side bonding pad 988 and a logic-side bonding pad 788.

Generally, the memory die 900 and the logic die 700 may be bonded by metal-to-metal bonding between the memory-side bonding pads 988 and the logic-side bonding pads 788, or via solder-mediated bonding such as C4 bonding or microbump bonding. If metal-to-metal bonding is employed, the memory-side bonding pads 988 directly contact the logic-side bonding pads 788, and metallic interdiffusion is induced between the material of the memory-side bonding pads 988 and the logic-side bonding pads 788. In this case, an outermost dielectric material layer among the upper-level dielectric material layers 960 may contact an outermost dielectric material layer among the logic-side dielectric material layers 760, and dielectric-to-dielectric bonding may be induced therebetween. If C4 bonding or microbump bonding is employed, a two-dimensional array of solder material portions may be interposed between, and may be bonded with, the memory-side bonding pads 988 and the logic-side bonding pads 788. A gap between the outermost dielectric material layer among the upper-level dielectric material layers 960 and the outermost dielectric material layer among the logic-side dielectric material layers 760 may be filled with an underfill material portion.

The memory die 900 and the logic die 700 may be bonded by wafer-to-wafer bonding, by die-to-die bonding, or by die-to-wafer bonding. In the case of the wafer-to-wafer bonding, a wafer including a two-dimensional array of memory dies 900 and another wafer including a two-dimensional array of logic dies 700 may be provided. Mating pairs of memory dies 900 and logic dies 700 may be bonded simultaneously by performing a metal-to-metal bonding process or a solder-mediated bonding process. In the case of die-to-die bonding, a single memory die 900 (as provided by singulation of a wafer including a two-dimensional array of memory dies 900) may be bonded to a single logic die 700 (as provided by singulation of a wafer including a two-dimensional array of logic dies 700). In the case of die-to-wafer bonding, a memory die 900 may be bonded to a selected logic die 700 located on a wafer including a two-dimensional array of logic dies 700, or a logic die 700 may be bonded to a selected memory die 900 located on wafer including a two-dimensional array of memory dies 900.

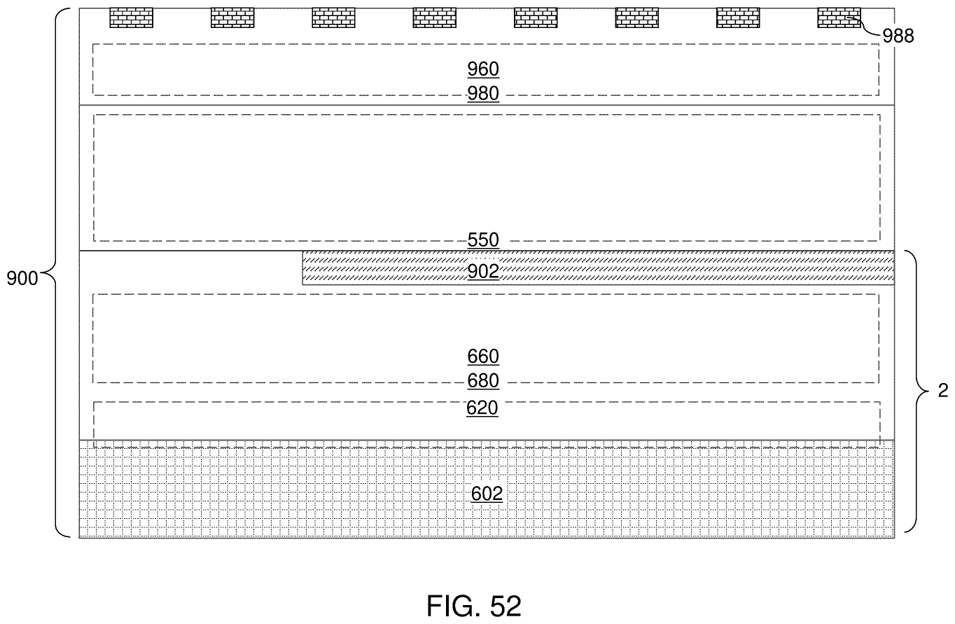

Referring to FIG. 52, a second semiconductor die containing the three-dimensional memory array 550 is illustrated. The second semiconductor die may be a memory die 900, in which the substrate 2 comprises a semiconductor material layer 902 and underlying driver circuit structures. The semiconductor material layer 902 performs the function of the substrate 2 described with reference to FIGS. 1A-1G. The underlying driver circuit structures may comprise a semiconductor substrate 602 (such as a portion of a single crystalline silicon wafer), a control circuit 620 including semiconductor devices configured to control operation of the three-dimensional memory array 550, and lower-level metal interconnect structures 680 embedded within lower-level dielectric material layers 660. The semiconductor material layer 902 may comprise a polycrystalline semiconductor material layer that may be formed by deposition of a semiconductor material over the lower-level dielectric material layers 660, or may comprise a single crystalline semiconductor material layer (such as a single crystalline silicon layer) that may be formed by a layer transfer from a source single crystalline semiconductor layer, for example, employing a hydrogen-implanted cleaving layer (commonly known as the Smart-cut™ method). The semiconductor material layer 902 may be patterned as needed. Electrical interconnection between the lower-level metal interconnect structures 680 and the upper-level metal interconnect structures 980 may be formed by metal vias that pass through the levels of the semiconductor material layer 902 and the three-dimensional memory array 550. Alternatively, the semiconductor material layer 902 may be omitted. In this case, the etch stop structure 8 located at the bottommost level of the three-dimensional memory array 550 may contact the topmost layer within the lower-level dielectric material layers 660.

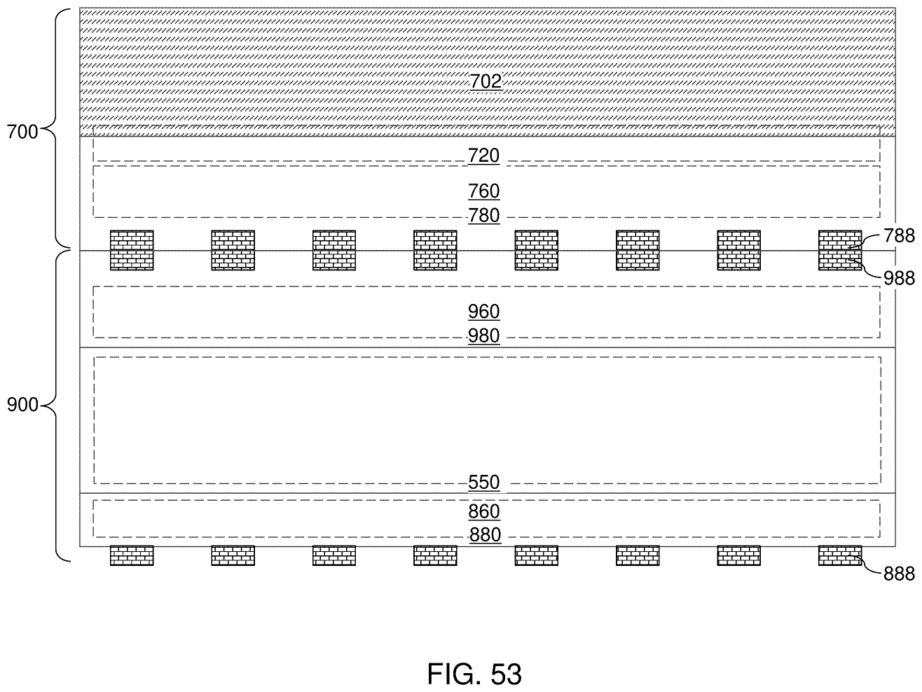

Referring to FIG. 53, a third semiconductor die containing the three-dimensional memory array 550 can be formed by removing the substrate 2, and by subsequently forming memory-die backside structures. The removal of the substrate 2 can be performed selectively to the etch stop structure 8, for example, by grinding, polishing, an anisotropic etch process, and/or an isotropic etch process. Backside metal interconnect structures 880 embedded within backside dielectric material layers 860 may be optionally formed. Backside bonding pads 888 may be formed on the backside metal interconnect structures 888, or may be formed on electrical nodes of the three-dimensional memory array 550. The backside bonding pads 888 may be metal-to-metal bonding pads, or may be solder bonding pads.

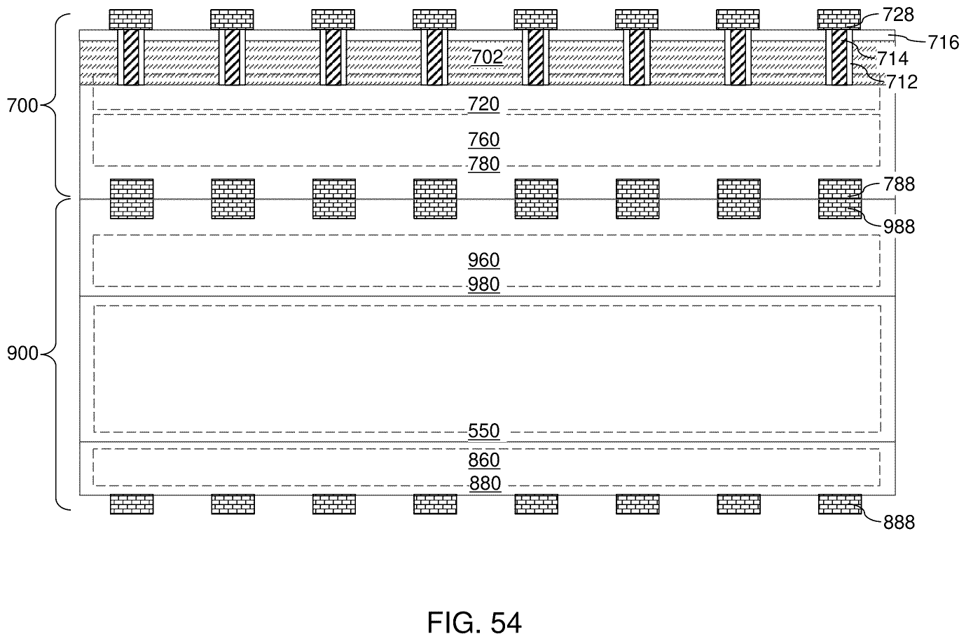

Referring to FIG. 54, a fourth semiconductor die containing the three-dimensional memory array 550 is illustrated, which may be formed by forming combinations of a through-substrate-via dielectric liner 712 and a through-substrate via structure 714 in an upper portion of the logic-side substrate 702 prior to formation of the control circuit 720, by thinning the logic-die substrate 702 from the backside after the logic die 700 is bonded to the memory die 900, by forming a logic-die backside insulating layer 716 on the backside surface of the thinned logic-side substrate 702, and by forming logic-die backside bonding pads 728. The logic-die backside bonding pads 728 may be metal-to-metal bonding pads, or may be solder bonding pads.

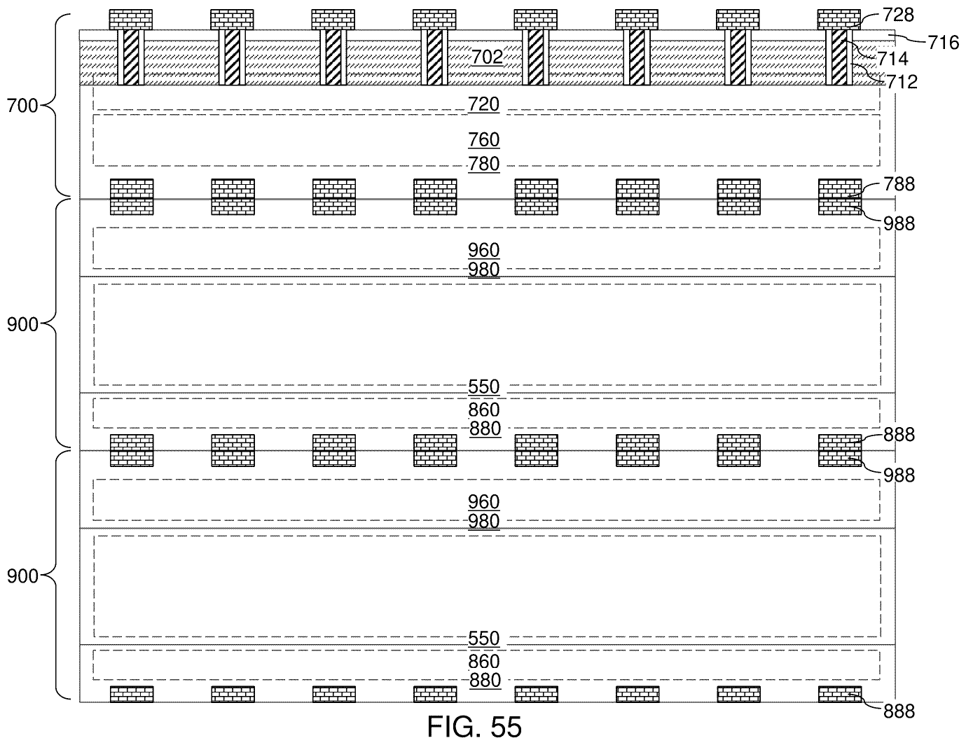

Referring to FIG. 55, a fifth semiconductor die containing the three-dimensional memory array 550 can be formed by vertically stacking multiple memory dies 900. In the illustrated example, metal-to-metal bonding is employed to vertical stack multiple memory dies 900.

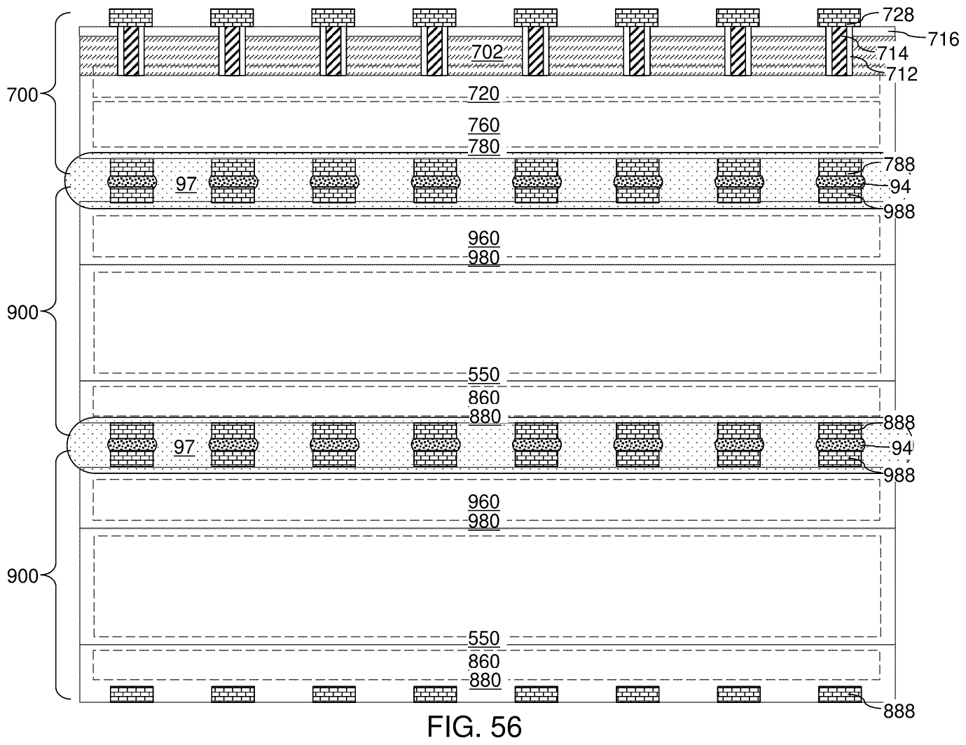

Referring to FIG. 56, a sixth semiconductor die containing the three-dimensional memory array 550 can formed by vertically stacking multiple memory dies 900. In the illustrated example, microbump bonding is employed to vertically stack multiple memory dies 900. An array of solder material portions 794 may be interposed between each vertically neighboring pair of bonding pads. An underfill material portion 797 can fill the gap between each vertically neighboring pair of semiconductor dies (700, 900).

Referring to all drawings and according to various embodiments of the present disclosure, a device structure comprising a three-dimensional array of unit cells UC is provided. Each of the unit cells UC comprises: an access field effect transistor 100 comprising a horizontally-extending semiconductor channel 14, a first gate dielectric 60, and a first gate electrode (comprising a portion of a first word line 68); and a memory field effect transistor 300 comprising a tubular-portion-containing channel 84, a second gate dielectric 30, and a second gate electrode (comprising as a portion of a second word line 38), wherein the second gate dielectric 30 comprises a memory dielectric material having at least two programmable states.

In one embodiment, the tubular-portion-containing channel 84 has a different composition than the horizontally-extending semiconductor channel 14. In one embodiment, the horizontally-extending semiconductor channel 14 comprises a silicon channel (e.g., a channel that consist of silicon and optionally p-type or n-type dopant atoms selected from boron, phosphorus, arsenic and/or antimony); and the tubular-portion-containing channel 84 comprises a silicon germanium or a metal oxide semiconductor channel.

In one embodiment, the tubular-portion-containing channel 84 surrounds a core structure (34 or 93). In the first embodiment, the core structure 34 comprises a semiconductor material having a same material composition as the horizontally-extending semiconductor channel 14 (e.g., silicon that is optionally doped with the p-type or n-type dopant atoms). In the second embodiment, the core structure 93 comprises a dielectric material. In one embodiment, the second gate dielectric 30 comprises a ferroelectric dielectric material. Alternatively, the second gate dielectric 30 comprises a charge storage material.

In one embodiment, each of the unit cells UC also comprises a doped semiconductor material portion 11 located between the horizontally-extending semiconductor channel 14 and the core structure (34 or 93). In one embodiment, the doped semiconductor material portion 11 is in contact with an end surface of the horizontally-extending semiconductor channel 14 and in contact with an end surface of the core structure (34 or 93).

In one embodiment, each of the unit cells UC also comprises a metallic material portion 92 in contact with the doped semiconductor material portion 11 located between the horizontally-extending semiconductor channel 14 and the tubular-portion-containing channel 84. In one embodiment, the metallic material portion 92 contacts an end surface of the doped semiconductor material portion 11 and an end surface of the tubular-portion-containing channel 84. In one embodiment, the metallic material portion 92 has a different material composition than the second gate electrode (as embodied as a portion of a second word line 38).

In one embodiment, the horizontally-extending semiconductor channel 14 and the tubular-portion-containing channel 84 laterally extend along a first horizontal direction hd1; the horizontally-extending semiconductor channel 14 has a first width w1 along a second horizontal direction hd2 that is perpendicular to the first horizontal direction hd1; and a width of the tubular-portion-containing channel 84 along the second horizontal direction hd2 is greater than the first width w1.

In one embodiment, each of the unit cells UC also comprises a doped semiconductor material portion 11 that comprises: a first end portion in contact with the horizontally-extending semiconductor channel 14 and having the first width w1; a second end portion that is laterally spaced from the first end portion toward the tubular-portion-containing channel 84 and having the first width w1; and a neck portion located between the first end portion and the second end portion and having a second width w2 that is less than the first width w1.

In one embodiment, an end portion of the tubular-portion-containing channel 84 is contacted by a vertical source line 46 that extends along a vertical direction. In one embodiment, each of the unit cells UC also comprises a source region 32 in contact with an end portion of the tubular-portion-containing channel 84 and in contact with a vertical source line 46 that extends along a vertical direction.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or magnetic configuration is illustrated in the present disclosure, it is understood that the present disclosure may be practiced with any other compatible structures and/or magnetic configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A device structure comprising a three-dimensional array of unit cells, wherein each of the unit cells comprises:
an access field effect transistor comprising a horizontally-extending semiconductor channel, a first gate dielectric, and a first gate electrode; and
a memory field effect transistor comprising a tubular-portion-containing channel, a second gate dielectric, and a second gate electrode,
wherein the second gate dielectric comprises a memory dielectric material having at least two programmable states.

2. The device structure of claim 1, wherein the tubular-portion-containing channel has a different composition than the horizontally-extending semiconductor channel.

3. The device structure of claim 2, wherein the tubular-portion-containing channel surrounds a core structure.

4. The device structure of claim 3, wherein:
the horizontally-extending semiconductor channel comprises a silicon channel; and
the tubular-portion-containing channel comprises a silicon germanium or a metal oxide semiconductor channel.

5. The device structure of claim 4, wherein the core structure comprises a semiconductor material having a same material composition as the horizontally-extending semiconductor channel.

6. The device structure of claim 4, wherein the core structure comprises a dielectric material.

7. The device structure of claim 3, wherein the second gate dielectric comprises a ferroelectric dielectric material.

8. The device structure of claim 3, wherein:
each of the unit cells further comprises a doped semiconductor material portion located between the horizontally-extending semiconductor channel and the core structure; and
the doped semiconductor material portion is in contact with an end surface of the horizontally-extending semiconductor channel and in contact with an end surface of the core structure.

9. The device structure of claim 8, wherein:
each of the unit cells further comprises a metallic material portion in contact with the doped semiconductor material portion located between the horizontally-extending semiconductor channel and the tubular-portion-containing channel; and
the metallic material portion contacts an end surface of the doped semiconductor material portion and an end surface of the tubular-portion-containing channel.

10. The device structure of claim 1, wherein:
the horizontally-extending semiconductor channel and the tubular-portion-containing channel laterally extend along a first horizontal direction;
the horizontally-extending semiconductor channel has a first width along a second horizontal direction that is perpendicular to the first horizontal direction; and
a width of the tubular-portion-containing channel along the second horizontal direction is greater than the first width.

11. The device structure of claim 10, wherein each of the unit cells further comprises a doped semiconductor material portion that comprises:
a first end portion in contact with the horizontally-extending semiconductor channel and having the first width;
a second end portion that is laterally spaced from the first end portion toward the tubular-portion-containing channel and having the first width; and
a neck portion located between the first end portion and the second end portion and having a second width that is less than the first width.

12. The device structure of claim 1, wherein an end portion of the tubular-portion-containing channel is contacted by a vertical source line that extends along a vertical direction.

13. The device structure of claim 1, wherein each of the unit cells further comprises a source region in contact with an end portion of the tubular-portion-containing channel and in contact with a vertical source line that extends along a vertical direction.

14. A method of forming a device structure, comprising:
forming a three-dimensional array of horizontally-extending semiconductor rails supported by a three-dimensional array of horizontally-extending sacrificial rails;
removing first portions of horizontally-extending sacrificial rails to expose sidewalls and horizontal surfaces of first portions of the horizontally-extending semiconductor rails;
depositing a first gate dielectric material and a first gate electrode material around the first portions of the horizontally-extending semiconductor channels;
removing second portions of horizontally-extending sacrificial rails to expose sidewalls and horizontal surfaces of second portions of the horizontally-extending semiconductor rails;
forming tubular-portion-containing channels on the second portions of the horizontally-extending semiconductor rails;
depositing a second gate dielectric material and a second gate electrode material around the tubular-portion-containing channels; and
patterning the first gate electrode material, the second gate electrode material, the first gate dielectric material, and the second gate dielectric material, wherein patterned portions of the first gate electrode material comprise first word lines, patterned portions of the second gate electrode material comprise second word lines, patterned portions of the first gate dielectric material comprise first gate dielectrics, and patterned portions of the second gate dielectric material comprise second gate dielectrics.

15. The method of claim 14, wherein the second gate dielectric comprises a memory dielectric material having at least two programmable states.

16. The method of claim 14, further comprising electrically doping a middle portion of each of the horizontally-extending semiconductor rails to form a doped semiconductor material portion, wherein the first portion and the second portion of each horizontally-extending semiconductor rail are laterally spaced from each other by the doped semiconductor material portion.

17. A method of forming a device structure, comprising:
forming a three-dimensional array of horizontally-extending semiconductor rails supported by a three-dimensional array of horizontally-extending sacrificial rails;
removing first portions of horizontally-extending sacrificial rails to expose sidewalls and horizontal surfaces of first portions of the horizontally-extending semiconductor rails;
depositing a first gate dielectric material and a first gate electrode material around the first portions of the horizontally-extending semiconductor channels;
removing second portions of horizontally-extending sacrificial rails to expose sidewalls and horizontal surfaces of second portions of the horizontally-extending semiconductor rails;
depositing a second gate dielectric material and a second gate electrode material around the second portions of the horizontally-extending semiconductor channels;
forming elongated cavities by removing the second portions of the horizontally-extending semiconductor rails;
forming tubular-portion-containing channels in the elongated cavities on surfaces of the second gate dielectric material; and
patterning the first gate electrode material, the second gate electrode material, the first gate dielectric material, and the second gate dielectric material, wherein patterned portions of the first gate electrode material comprise first word lines, patterned portions of the second gate electrode material comprise second word lines, patterned portions of the first gate dielectric material comprise first gate dielectrics, and patterned portions of the second gate dielectric material comprise second gate dielectrics.

18. The method of claim 17, further comprising electrically doping a middle portion of each of the horizontally-extending semiconductor rails to form a doped semiconductor material portion, wherein the first portion and the second portion of each horizontally-extending semiconductor rail are laterally spaced from each other by the doped semiconductor material portion.

19. The method of claim 18, further comprising forming metallic material portions on the doped semiconductor material portions after formation of the elongated cavities by selectively depositing a metallic material on physically exposed surfaces of the doped semiconductor material portions.

20. The method of claim 18, further comprising:
forming sacrificial perforated wall structures around a respective two-dimensional array of doped semiconductor material portions among the doped semiconductor material portions prior to removing the first portions of horizontally-extending sacrificial rails;
forming bridges-encircling cavities by removing the sacrificial perforated wall structures after formation of the tubular-portion-containing channels; and
introducing at least one isotropic etchant that etches a respective material among the first gate electrode material, the second gate electrode material, the first gate dielectric material, and the second gate dielectric material into the bridges-encircling cavities.
